(19) United States
(12) Patent Application Publication
(10) Pub. No.: US 2023/0212334 A1
(43) Pub. Date: Jul. 6, 2023

(54) POLYMER, ELECTROLUMINESCENCE MATERIAL, ELECTROLUMINESCENCE DEVICE, AND ELECTRONIC DEVICE

(71) Applicant: SAMSUNG ELECTRONICS CO., LTD., Suwon-si (KR)

(72) Inventors: Takahiro FUJIYAMA, Suwon-si (KR); Norihito ISHII, Suwon-si (KR); Fumiaki KATO, Suwon-si (KR); Masashi TSUJI, Suwon-si (KR); Naotoshi SUGANUMA, Suwon-si (KR); Yusaku KONISHI, Suwon-si (KR); Eun Joo JANG, Suwon-si (KR); Ha Il KWON, Suwon-si (KR); Hyo Sook JANG, Suwon-si (KR); Soonmin CHA, Suwon-si (KR); Tae Ho KIM, Suwon-si (KR); Wonsik YOON, Suwon-si (KR); Yuho WON, Suwon-si (KR)

(21) Appl. No.: 18/150,337

(22) Filed: Jan. 5, 2023

(30) Foreign Application Priority Data
Jan. 5, 2022 (JP) 2022-000379
Jan. 4, 2023 (KR) 10-2023-0001466

(51) Int. Cl. C08F 26/02; C08F 28/06; H10K 85/10; H10K 50/15; H10K 50/17

(52) U.S. Cl. CPC C08F 26/02; C08F 28/06; H10K 85/111; H10K 85/113; H10K 50/15; H10K 50/17; H10K 2102/331

(57) ABSTRACT

A polymer including a structural unit represented by Chemical Formula 1, an electroluminescence device material including the polymer, an electroluminescence device including the polymer or the electroluminescence device material, and an electronic device including the electroluminescence device are provided:

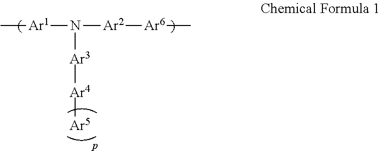

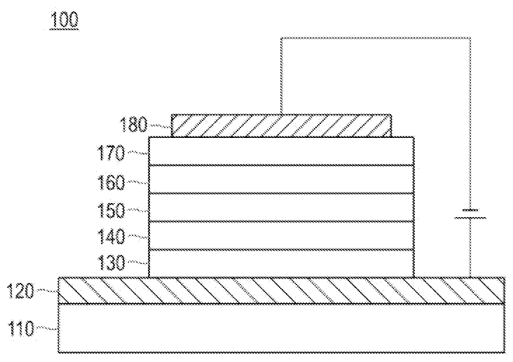

In Chemical Formula 1, the definition of each substituent is the same as described in the specification.

### CROSS-REFERENCE TO RELATED APPLICATION

This application claims priority to Japanese Patent Application No. 2022-000379 filed in the Japanese Patent Office on Jan. 5, 2022, and Korean Patent Application No. 10-2023-0001466 filed in the Korean Intellectual Property Office on Jan. 4, 2023, and all the benefits accruing therefrom under 35 U.S.C. § 119, the contents of which in their entirety are incorporated herein by reference.

### BACKGROUND OF THE INVENTION

### (a) Field of the Invention

The present invention relates to a polymer, an electroluminescence material including the polymer, an electroluminescence device including the material, and an electronic device.

### (b) Description of the Related Art

The research and development of electroluminescence devices (EL devices) are ongoing and of current interest. In particular, EL devices show promise as an inexpensive large-area full-color display device of a solid-state light-emitting type or a recording light source array.

The EL device may be a light emitting device having a thin film disposed between an anode and a cathode with the thin film having a thickness of several nanometers to several hundred nanometers. In addition, the EL device will usually include a hole transport layer, a light emitting layer, an electron transport layer, and the like.

The light emitting layer may include a fluorescent light emitting material and/or a phosphorescent light emitting material. The phosphorescent light emitting material is a material that may be expected to have higher luminous efficiency than a fluorescent light emitting material. In addition, because a phosphorescent light emitting material may cover a wide color gamut, an RGB light source requires an emission spectrum having a narrow full width at half maximum. At present, there are no commercially acceptable EL devices having a phosphorescent light emitting material that emits in a blue or deep blue region of the visible spectrum with the desired color purity and an acceptable lifetime.

A method for solving one or more of the above technical issues may include a light emitting device having an inorganic light emitting material that includes quantum dots (Patent Document 1, JP 2010-199067 A). Quantum dots (QD) are semiconductor materials having a nanocrystal structure of several nanometers in size, and therefore, quantum dots have a large surface area per unit volume. For this reason, most of the atoms of the nanocrystal are present at the surface resulting in a quantum confinement effect. Accordingly, one may control or adjust the emission wavelength by adjusting the relative size or the elemental composition of the QDs. QDs may offer EL devices with improved color purity and high PL (photoluminescence) luminous efficiency, and thus, are attracting strong interest.

### SUMMARY OF THE INVENTION

A polymer including structural unit A represented by Chemical Formula 1 according to an embodiment:

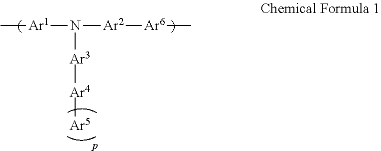

In Chemical Formula 1,

Ar¹, A², and Ar³ are each independently a substituted or unsubstituted, aromatic carbocyclic group having 6 to 60 ring-forming atoms,

Ar⁴ is a substituted or unsubstituted, condensed aromatic carbocyclic group with three or more condensed benzene rings,

Ar⁵ is a substituted or unsubstituted, aromatic carbocyclic group having 6 to 60 ring-forming atoms, or a substituted or unsubstituted, aromatic heterocyclic group having 5 to 60 ring-forming atoms,

Ar⁶ is a substituted or unsubstituted, aromatic carbocyclic group having 6 to 60 ring-forming atoms, or a substituted or unsubstituted, aromatic heterocyclic group having 5 to 60 ring-forming atoms, and

p is 0 or 1.

According to an embodiment, performance, particularly durability or lifetime of an electroluminescence device for example, a quantum dot electroluminescence device may be improved.

### BRIEF DESCRIPTION OF THE DRAWING

The drawing is a schematic view of an electroluminescence device according to an embodiment.

### DETAILED DESCRIPTION OF THE EMBODIMENTS

An electroluminescence device (e.g., quantum dot electroluminescence device) including a hole transport material described in Patent Document 1 is understood by those in the art to have insufficient or non-acceptable performance (e.g., poor lifetime). Accordingly, alternative hole transport materials are needed, particularly, for an EL device that includes quantum dots. Accordingly, the present invention may provide an EL device, for example, a quantum dot electroluminescence device, that exhibits improved performance, e.g., lifetime and/or luminous efficiency.

The inventors of the present disclosure conducted intensive research to solve the above problems. As a result, the present inventors have found that the above problems can be solved by using a polymer that includes a specific structural unit with select aromatic ring systems.

In a first embodiment, a polymer including structural unit A represented by Chemical Formula 1 is provided:

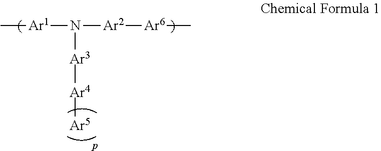

wherein, in Chemical Formula 1,

Ar¹, Ar², and Ar³ are each independently a substituted or unsubstituted divalent aromatic hydrocarbon group having 6 to 60 ring-forming atoms,

Ar⁴ is a substituted or unsubstituted condensed polycyclic aromatic hydrocarbon group with three or more condensed benzene rings,

Ar⁵ is a substituted or unsubstituted monovalent aromatic carbocyclic group having 6 to 60 ring-forming atoms, or a substituted or unsubstituted monovalent aromatic heterocyclic group having 5 to 60 ring-forming atoms,

Ar⁶ is a substituted or unsubstituted divalent aromatic carbocyclic group having 6 to 60 ring-forming atoms, or a substituted or unsubstituted divalent aromatic heterocyclic group having 5 to 60 ring-forming atoms, and

p is 0 or 1.

At times, the structural unit A represented by Chemical Formula 1 is also referred to as “structural unit A represented by Chemical Formula 1”, “structural unit A”, “structural unit A according to an embodiment”,

A structural unit below is present within structural unit A represented by Chemical Formula 1, and is at times, referred to as “structural unit X”, or “structural unit X according to an embodiment”:

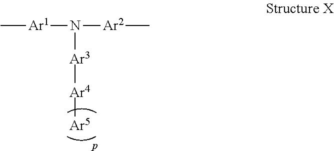

Similarly, the structural unit group “—Ar⁶—” in the structural unit A represented by Chemical Formula 1 is at times referred to as “structural unit Y” or “structural unit Y according to an embodiment.”

In addition, a polymer including a structural unit represented by Chemical Formula 1 is also referred to as a “polymer,” or “a polymer according to an embodiment”.

In a second embodiment, an electroluminescence device material including the polymer according to the first embodiment is provided.

In a third embodiment, an electroluminescence device includes a first electrode, a second electrode, and one or more layers of an organic film disposed between the first electrode and the second electrode, wherein at least one of the organic layers includes the polymer according to an embodiment.

As used herein, the electroluminescence device is simply referred to as “LED.”

The quantum dot electroluminescence device is also simply referred to as “QLED.”

An organic electroluminescence device is also simply referred to as “OLED.”

Various low-molecular materials and polymer materials are used or present as materials of a light emitting layer or a carrier transport layer of the electroluminescence device. Among these, low-molecular materials may provide improvement in terms of device efficiency and life-span. However, the use of a low-molecular material is likely to increase manufacturing costs because of the necessary to manufacture the device using a vacuum process.

On the other hand, as a polymer material, TFB or the like is known as a hole transport material (e.g., see, paragraphs [0036] and [0037] of Patent Document 1). However, the use of such a polymer material may lead to a decrease in device durability, for example, a decrease in luminescence life-span (see, Comparative Example 2-1 described herein). For this reason, development of a polymer material that may provide improving durability (luminescence life-span) is of strong interest and demand.

Following extensive research to solve the above technical issues, for example, to identify materials with both improve durability (luminescence life-span) with relatively low production costs), the inventors have sought and identified polymers including the structural unit A represented by Chemical Formula 1 and the application of such polymers to an electroluminescence device. As a result, luminescence life-span may be improved compared to known materials.

While not wishing to be bound by any particular theory, a mechanism of exerting the above-described action effect according to an embodiment is as follows. In general, a polymer material that may be used as a hole transport material is, for example, a triarylamine-based polymer material such as TFB. TFB has the following structure in which a pendent aryl group or an arylene group is bonded to a nitrogen atom.

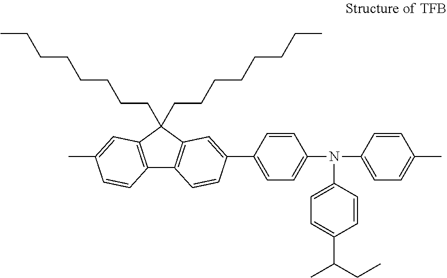 [SMILES: CCCCCCCCC1(CCCCCCCC)c2cc(C)ccc2-c2ccc(-c3ccc(N(c4ccc(C)cc4)c4ccc(C(C)CC)cc4)cc3)cc21]

The present inventors believe that the reason why the durability (luminescence life-span) of a EI device that includes a triarylamine-based polymer material such as TFB as a hole transport material may be due to a relatively weak bond between a nitrogen atom in the polymer chain and a pendent aryl group or an adjacent arylene group. Specifically, when a triarylamine-based polymer material such as TFB is used as a hole transport material electrons may leak from the light emission layer or excitons generated in the hole transport layer may come in contact the polymer material. Consequently, a bond between a nitrogen atom and a pendent aryl group or arylene group (particularly, the former) is relatively sensitive to bond-breakage, and thus, and cleavage of such a bond in the polymer likely leads to the observed insufficient durability (decrease in luminescence life-span).

In contrast, the polymer according to an embodiment may improve durability (luminescence life-span) by including a structural unit A represented by Chemical Formula 1.

Herein, the structural unit A has three aromatic hydrocarbon groups bonded to the nitrogen atom as “Ar¹, Ar², and Ar³,” and also has a substituted or unsubstituted condensed aromatic carbocyclic group with three or more condensed benzene rings as in group “Ar⁴.”

In other words, the structural unit A includes the condensed polycyclic aromatic carbocyclic group “Ar⁴” attached to “Ar³” of the pendent side chain. The condensed polycyclic aromatic carbocyclic group “Ar⁴” has a large conjugate energy, which, in turn, may provide a high conjugate stabilizing (or strengthening) effect, e.g., to the N—Ar³ bond. Accordingly, the bond between the nitrogen atom and the aryl group or adjacent arylene groups is strengthened (bonding energy is increased), and as a result, the bond(s) is difficult to break even upon contact with electrons or excitons as discussed above, and thus durability (luminescence life-span) is likely to be improved.

In addition, the inventors of the present invention also found that sufficient luminous efficiency may be achieved by applying the polymer including the structural unit A represented by Chemical Formula 1 to an electroluminescence device, in particular, a quantum dot electroluminescence device (QLED).

The electronic conjugate mechanism according to an embodiment may be summarized as follows. A valance band level of quantum dots used in quantum dot electroluminescence devices is, for example, about −5.7 eV for blue QLEDs and about −5.55 eV for red QLEDs. For this reason, a band offset from a HOMO level of the hole transport layer material used in the existing organic electroluminescence device (OLED) is large, and it may cause degradation of carrier injection efficiency and luminous efficiency. In order to solve this problem, a technique capable of lowering the band offset with the light emitting layer (quantum dot (QD) layer) by using a hole transport layer material having a deeper HOMO level of the hole transport layer is required.

In contrast, according to the polymer according to an embodiment, it is estimated that a material, e.g., a polymer, with a deep HOMO level may be obtained by having the structural unit of Chemical Formula 1, particularly by having the following structure as the structural unit X of Chemical Formula 1:

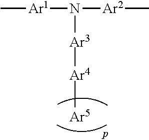

Specifically, the structural unit X has a structure in which monoamines (—(Ar¹)—N(Ar³)—(Ar²)—) are present in the main chain. Moreover, because Ar³ is a substituted or unsubstituted aromatic carbocyclic group having 6 to 60 ring-forming atoms, and Ar⁴ is a substituted or unsubstituted, condensed polycyclic aromatic carbocyclic group with three or more condensed benzene rings, rotation about the Ar³ and N, or Ar³ and Ar⁴ bond is more sterically hindered. Therefore, as present in its most stable configuration, the groups Ar³ and Ar⁴ will have a somewhat twisted (out-of-plane) structure. As a result, the extent of the conjugation is shortened, and the HOMO level of the polymer according to an embodiment is deepened.

For this reason, in a quantum dot electroluminescence device including a hole injection layer or a hole transport layer (particularly, a hole transport layer) including the polymer according to an embodiment and a light emitting layer including quantum dots, a difference (barrier) between the HOMO of the hole injection layer or the hole transport layer (particularly the hole transport layer) and the HOMO of the light emitting layer is relatively small, and thus, an ability to inject holes from the hole transport layer into the light emitting layer may be improved. In addition, because the injection ability of holes into the light emitting layer may be improved, a light emitting region may be expanded. Accordingly, an electroluminescence device exhibiting good luminous efficiency may be implemented by using the polymer according to the embodiment.

Of course, as stated above, the proposed electronic/structural mechanism is based in-part on theory, and the present disclosure or claims is not limited to the stated proposed mechanism of action. More importantly, a person of skill understands that such an electronic/structural conjugation hypothesis is provided to help explain why the inventors have observed improved device performance in an EL device, e.g., a quantum dot EL device, including a hole injection layer or a hole transport layer (particularly, a hole transport layer) including the polymer according to an embodiment.

Hereinafter, embodiments of the present disclosure will be described, however, it is to be understood that, the present disclosure is not limited to the following described embodiments. In other words, the invention may, however, be embodied in many different forms, and should not be construed as limited to the embodiments set forth herein.

It will be understood that when an element is referred to as being “on” another element, it can be directly on the other element or intervening elements may be present therebetween. In contrast, when an element is referred to as being “directly on” another element, there are no intervening elements present.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10% or ±5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to a cross section illustration that is a schematic illustration of idealized embodiment. As such, variations from the shapes of the illustration as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

As used herein, unless otherwise specified, measurements of operation and physical properties are measured under conditions of room temperature (greater than or equal to about 20° C. and less than or equal to about 25° C.)/relative humidity of greater than or equal to about 40% RH and less than or equal to about 50% RH.

In this specification, “x and y are each independently” means that x and y may be the same or different.

As used herein, “group derived from “compound z” or “group derived from “compound z”” refers to, when “compound z” is a ring-structured compound, a group with a free valence by removing hydrogen atoms directly bonded to ring-forming atoms from the ring structure.

As used herein, the number of ring-forming atoms refers to the number of atoms constituting a ring itself of a structure in which atoms are bonded in a ring (for example, a monocyclic ring, a condensed ring, and a ring-assembled) compounds (e.g., monocyclic compounds, condensed ring compounds, bridged ring compounds, carbocyclic compounds, and heterocyclic compounds). Atoms not constituting the ring (for example, a hydrogen atom terminating bonds of atoms constituting the ring) or atoms included as a substituent when the ring is substituted by a substituent are not included as ring-forming atoms. The number of ring-forming atoms described below has the same meaning unless otherwise specified. For example, a benzene ring has 6 ring-forming atoms, a naphthalene ring has 10 ring-forming atoms, a pyridine ring has 6 ring-forming atoms, and a furan ring has 5 ring-forming atoms.

When the benzene ring is substituted with, for example, an alkyl group as a substituent, the number of carbon atoms in the alkyl group is not included in the number of ring-forming atoms in the benzene ring. For this reason, the number of ring-forming atoms of the benzene ring substituted with an alkyl group is 6. Further, when the naphthalene ring is substituted with, for example, an alkyl group as a substituent, the number of atoms of the alkyl group is not included in the number of ring-forming atoms of the naphthalene ring. For this reason, the number of ring-forming atoms in the naphthalene ring in which the alkyl group is substituted is 10.

For example, the number of hydrogen atoms bonded to the pyridine ring or atoms constituting the substituent is not included in the number of ring-forming atoms of the pyridine ring. For this reason, the number of ring-forming atoms of the pyridine bonded with a hydrogen, or a substituent is 6.

As used herein, unless otherwise specified, “substituted” refers to substitution with an alkyl group, a cycloalkyl group, a hydroxyalkyl group, an alkoxyalkyl group, an alkoxy group, a cycloalkoxy group, an alkenyl group, an alkynyl group, an amino group, an aryl group, an aryl group, an oxy group, an alkylthio group, a cycloalkylthio group, an arylthio group, an alkoxy carbonyl group, an aryl oxycarbonyl group, a hydroxy group (—OH), a carboxy group (—COOH), a thiol group (—SH), or a cyano group (—CN). Moreover, if for example, a substituent is an alkyl group, the alkyl group as a substituent is never substituted with another alkyl group. Moreover, as appropriate, the substituents may be join to form a ring.

The term “aromatic carbocyclic” may include a C6 to C40 aryl group with only carbon-ring-forming atoms. The term refers to and includes both single-ring aromatic groups and polycyclic or condensed (or fused) aromatic ring systems with only carbon-ring forming atoms. The polycyclic rings may have two or more rings in which two carbons are common to two adjoining rings (the rings are “fused”) wherein at least one of the rings is an aromatic hydrocarbyl group, e.g., the other rings can be cycloalkyls, cycloalkenyls, aryl, heterocycles, and/or heteroaryls. For example, fluorene or spirobifluorene is a fused aromatic carbocyclic ring. Preferred aryl groups are those containing six to thirty carbon atoms, preferably six to twenty carbon atoms. Especially preferred is an aryl group having six ring carbons, ten ring carbons or fourteen ring carbons. Suitable aryl groups include phenyl, biphenyl, triphenyl, triphenylene, tetraphenylene, naphthalene, anthracene, phenalene, phenanthrene, fluorene, pyrene, chrysene, perylene, and azulene. Additionally, the aryl group may be optionally substituted.

The term “aromatic heterocyclic” or, at times, “heteroaryl” refers to and includes both single-ring hetero-aromatic groups and polycyclic aromatic ring systems that include at least one heteroatom. The heteroatoms include, but are not limited to O, S, N, P, B, Si and Se. In many instances, O, S or N are the preferred heteroatoms. Aromatic heterocyclic groups include single ring aromatic rings with 5 or 6 ring atoms, and the ring can have from one to three heteroatoms. An “aromatic heterocyclic” group can also have two or more rings in which two atoms are common to two adjoining rings (the rings are “fused”) wherein at least one of the rings is a heteroaryl, e.g., the other rings can be cycloalkyls, cycloalkenyls, aryl, heterocycles, and/or heteroaryls. Preferred aromatic heterocyclic groups are those containing three to thirty carbon atoms, preferably three to twenty carbon atoms. Suitable aromatic heterocyclic groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the aromatic heterocyclic group may be optionally substituted.

Herein, the alkyl group as a substituent may be either linear or branched, but examples thereof include linear and branched alkyl groups having 3 to 20 carbon atoms, e.g., 1 to 20 carbon atoms. For example, an alkyl group may be a methyl group, an ethyl group, an n-propyl group, an isopropyl group, an n-butyl group, an isobutyl group, a sec-butyl group, a tert-butyl group, an n-pentyl group, an isopentyl group, a tert-pentyl group, a neopentyl group, a 1,2-dimethyl propyl group, an n-hexyl group, an isohexyl group, a 1,3-dimethylbutyl group, a 1-isopropyl propyl group, a 1,2-dimethylbutyl group, an n-heptyl group, a 1,4-dimethyl pentyl group, a 3-ethyl pentyl group, a 2-methyl-1-isopropyl propyl group, a 1-ethyl-3-methyl butyl group, an n-octyl group, a 2-ethylhexyl group, a 3-methyl-1-isopropyl butyl group, a 2-methyl-1-isopropyl group, a 1-tert-butyl-2-methyl propyl group, an n-nonyl group, a 3,5,5-trimethyl hexyl group, an n-decyl group, an isodecyl group, an n-undecyl group, a 1-methyldecyl group, an n-dodecyl group, an n-tridecyl group, an n-tetradecyl group, an n-pentadecyl group, an n-hexadecyl group, an n-heptadecyl group, an n-octadecyl group, an n-octa decyl group, a nonadecyl group, an eicosyl group, and the like.

The cycloalkyl group as a substituent may be, for example, a cyclopropyl group, a cyclobutyl group, a cyclopentyl group, a cyclohexyl group, and the like.

The alkoxy group as a substituent may be either linear or branched, and examples thereof include a linear alkoxy group having 1 to 20 carbon atoms or a branched alkoxy group having 3 to 20 carbon atoms. For example, an alkoxy group may be a methoxy group, an ethoxy group, a propoxy group, an isopropoxy group, a butoxy group, a pentyl oxy group, a hexyloxy group, a heptyloxy group, an octyloxy group, a nonyloxy group, decyloxy group, an undecyloxy group, a dodecyloxy group, a tridecyloxy group, a tetradecyloxy group, a pentadecyloxy group, a hexadecyloxy group, a heptadecyloxy group, an octadecyloxy group, a 2-ethylhexyloxy group, a 3-ethylpentyloxy group, and the like.

The cycloalkoxy group as a substituent may be a cyclopropyloxy group, a cyclobutyloxy group, a cyclopentyloxy group, a cyclohexyloxy group, and the like.

The alkenyl group as a substituent may be, for example, a vinyl group, an allyl group, a 1-propenyl group, an isopropenyl group, a 1-butenyl group, a 2-butenyl group, a 3-butenyl group, a 1-pentenyl group, a 2-pentenyl group, a 3-pentenyl group, a 1-hexenyl group, a 2-hexenyl group, a 3-hexenyl group, a 1-heptenyl group, a 2-heptenyl group, a 5-heptenyl group, a 1-octenyl group, a 3-octenyl group, a 5-octenyl group, and the like.

The aryl group as a substituent may be a carbocyclic aromatic group of 6 to 30 carbon atoms. For example, an aryl group may be a phenyl group, a naphthyl group, a biphenyl group, a fluorenyl group, an anthryl group, a pyrenyl group, an azulenyl group, an acenaphthylenyl group, a terphenyl group, a phenanthryl group, and the like.

The aryloxy group as a substituent may be, for example, a phenoxy group, a naphthyloxy group, and the like.

### Polymer

The polymer of an embodiment includes a structural unit A represented by Chemical Formula 1. The polymer including the following structural units has a relatively strong bond between a nitrogen atom included in the main chain and a pendent aryl group or an adjacent arylene group of the main chain (high bonding energy). As a result, the nitrogen-aryl bonds are difficult to break even when the polymer comes in contact with electrons or excitons, e.g., from the light emitting layer. The resulting electroluminescence device (e.g., a quantum dot electroluminescence device) including the polymer of an embodiment (e.g., the polymer present in a hole transport layer or a hole injection layer) has improved durability (luminescence life-span).

In addition, the polymer has a deep HOMO level, which provides an electroluminescence device including the polymer of an embodiment, for example, a quantum dot electroluminescence device, having the polymer present in a hole transport layer or a hole injection layer to have good or improved luminous efficiency.

The polymer of an embodiment may include a structural unit A represented by Chemical Formula 1, or may include two or more different types of structural units A. For example, the structural unit A, may be repeat unit in the polymer. A plurality of the same or different structural units A may exist in block form, random form, alternating form, or periodic form.

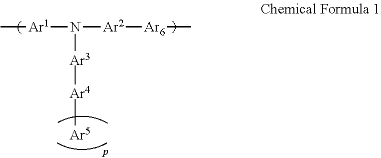

In Chemical Formula 1, the structural unit A can comprise a structural unit X (i.e., the structural unit of Chemical Formula 1 excluding Ar⁶, that is, Ar¹—N—Ar² with N having a pendent side chain attached to the N by Ar³). Moreover, if two or more types of structural units A are present, the “structural unit X” in each structural unit A may be the same or different. In Chemical Formula 1, the structural unit A also includes a structural unit Y (i.e., the structural unit represented by “Ar⁶”), and when two or more types of structural units A are present, the “structural unit Y” in each structural unit A may be the same or different.

In other words, the polymer according to an embodiment may be referred to as a copolymer of the same or different structural units A each including the same or different structural unit X and the same or different structural unit Y. The polymer according to an embodiment includes at least one structural unit A represented by Chemical Formula 1 but includes a form in which structural units X and Y are alternately polymerized, that is, an alternating copolymer.

In Chemical Formula 1, Ar¹, Ar², and Ar³ are each independently a substituted or unsubstituted, aromatic carbocyclic group having 6 to 60 ring-forming atoms. In this case, Ar¹, Ar², and Ar³ may be the same or different from each other. In an embodiment of a unit structure A, for example, Ar¹ and Ar² may be the same.

The aromatic carbocyclic groups Ar¹, Ar², and Ar³ may be monocyclic or condensed ring system. Herein, the aromatic carbocyclic group having 6 to 60 ring-forming atoms is not particularly limited, and examples thereof may include a phenylene group, an indenylene group, a naphthalenylene group, an anthracenylene group, an azulenylene group, an acenaphthenylene group, a phenalenylene group, a fluorenylene group, a phenanthrenylene group, a biphenylene group, a terphenylene group, a quaterphenylene group, a quinquephenylene group, a pyrenylene group, a spirobifluorene group, or a combination thereof.

Ar¹, Ar², and Ar³ may each independently be a substituted or unsubstituted, aromatic carbocyclic group having 6 to 30 ring-forming atoms, for example, a substituted or unsubstituted, aromatic carbocyclic group having 6 to 20 ring-forming atoms.

Further, Ar¹, Ar², and Ar³ may each independently be a substituted or unsubstituted phenylene group, a substituted or unsubstituted naphthalenylene group, and a substituted or unsubstituted fluorenylene group.

Among these, from the viewpoint of further improving durability, Ar¹ and Ar² may each independently, for example, a substituted or unsubstituted phenylene group (e.g., o, m, or p-phenylene group) or a substituted or unsubstituted fluorenylene group. For example, Ar¹ and Ar² may be an unsubstituted phenylene group and a substituted fluorenylene group, respectively. For example, Ar¹ and Ar² may be groups selected from an unsubstituted p-phenylene group and a substituted fluorenylene group, respectively.

Further, in the above embodiment, the bridge carbon of the fluorenylene group may be substituted with an alkyl group having 1 to 20 carbon atoms, for example, an alkyl group having 1 to 10 carbon atoms. Herein, as the alkyl group having 1 to 20 carbon atoms, one or two of alkyl groups, same or different, defined above may be present as substituents. Also, the alkyl group may be linear or branched, but may be, for example, be linear.

In view of the above, Ar³ may be, for example, a substituted or unsubstituted phenylene group, a substituted or unsubstituted naphthalenylene group, and a substituted or unsubstituted fluorenylene group. For example, Ar³ may be any one of groups represented by Chemical Formula 2, Chemical Formula 3, or Chemical Formula 4:

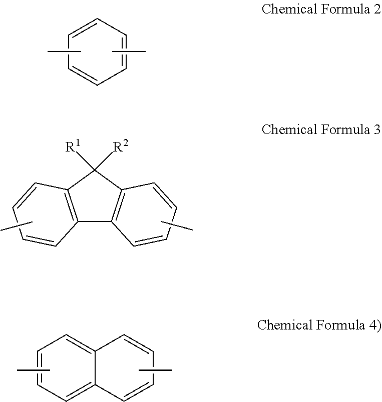

wherein, in Chemical Formula 3,

R¹ and R² are each independently a substituted or unsubstituted aromatic carbocyclic group having 6 to 30 ring-forming atoms, a substituted or unsubstituted alkyl group having 1 to 50 carbon atoms, or R¹ and R² are joined to form a ring.

R¹ and R² may be the same as or different from each other, for example, R¹ and R² may be the same as the other. For example, R¹ or R² may be an aromatic carbocyclic group with 6 to 20, 6 to 15, for example, 6 to 10, ring-forming atoms in the aromatic carbocyclic groups.

R¹ and R² may be the same as or different from each other, for example, R¹ and R² may be the same as the other. For example, R¹ or R² may be a substituted or unsubstituted alkyl group with 1 to 30, 1 to 15, 1 to 10, for example, 3 to 8 carbon atoms in the alkyl groups.

The aromatic carbocyclic groups R¹ or R² may be independently monocyclic or a condensed ring. Here, specific examples of the aromatic carbocyclic group of R¹ and R² are not particularly limited, but may be, for example, a phenyl group, a naphthyl group, a phenanthryl group, a biphenylenyl group, a triphenylenyl group, an anthryl group, a pyrenyl group, a fluorenyl group, an azulenyl group, an acenaphthenyl group, a fluoranthenyl group, a naphthacenyl group, a perylenyl group, a pentacenyl group, a terphenylenyl group, a quarterphenylenyl group, a xylenyl group, or a combination thereof.

Specific examples of the alkyl group R¹ and R² are not particularly limited, but may independently include, for example, a methyl group, an ethyl group, an n-propyl group, an isopropyl group, an n-butyl group, an s-butyl group, a tert-butyl group, an i-butyl group, a 2-ethyl butyl group, a 3,3-dimethylbutyl group, an n-pentyl group, an i-pentyl group, an neopentyl group, a tert-pentyl group (t-pentyl group), a cyclopentyl group, a 1-methyl pentyl group, a 3-methyl pentyl group, a 2-ethyl pentyl group, a 4-methyl-2-pentyl group, an n-hexyl group, a 1-methyl hexyl group, a 2-ethylhexyl group, a 2-butyl hexyl group, a cyclohexyl group, a 4-methylcyclohexyl group, a 4-tert-butylcyclohexyl group (4-t-butylcyclohexyl group), an n-heptyl group, a 1-methyl heptyl group, a 2,2-dimethylheptyl group, a 2-ethyl heptyl group, a 2-butyl heptyl group, an n-octyl group, a tert-octyl group (t-octyl group), a 2-ethyl octyl group, a 2-butyl octyl group, a 2-hexyl octyl group, a 3,7-dimethyl octyl group, a cyclooctyl group, an n-nonyl group, an n-decyl group, an adamantyl group, a 2-ethyl decyl group, a 2-butyl decyl group, a 2-hexyl decyl group, a 2-octyldecyl group, an n-undecyl group, an n-dodecyl group, a 2-ethyl dodecyl group, a 2-butyl dodecyl group, a 2-hexyl dodecyl group, a 2-octyldecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-icosyl group, a 2-ethyl icosyl group, a 2-butyl icosyl group, a 2-hexyl icosyl group, a 2-octyl icosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and the like.

Among them, from the viewpoint of further improving durability, Ar³ may be any one of the groups represented by Chemical Formula 2 or Chemical Formula 3. For example, it may be an unsubstituted phenylene groups (o, m, or p-phenylene group), 9,9-diphenylfluorenylene group, or a 9,9-dialkylfluorenylene group.

For example, Ar³ may be a substituted or unsubstituted phenylene group (o, m, or p-phenylene group) or a 9,9-dialkylfluorenylene group.

In addition to durability and considering the viewpoint of improving hole injection or transportability and obtaining good luminous efficiency, Ar³ may be, for example, a 9,9-dialkylfluorenylene group (particularly, a form in which 2nd and 7th positions are bonded to N (nitrogen atom) and Ar⁴, respectively).

With respect to the 9,9-dialkylfluorenylene group as a preferred form of Ar³, the number of carbon atoms of the alkyl group bonded to the 9th position may be the same as the number of carbon atoms of the alkyl group as R¹ and R² in Chemical Formula 3. Also, the alkyl group may be linear or branched, e.g., may be linear.

With respect to Ar¹, Ar², and Ar³, by combining them as described above, the conjugate stabilization effect by Ar⁴ is more likely to be distributed in the molecule, and thus, the bond between the nitrogen atom and each of Ar¹, Ar², and Ar³ is strengthened (bonding energy is increased), and high durability of an EL device may be obtained.

In Chemical Formula 1, Ar⁴ is a substituted or unsubstituted condensed aromatic carbocyclic group in which three or more benzene rings are condensed. In other words, Ar⁴ is a condensed aromatic carbocyclic group formed by condensation of three or more benzene rings, and the condensed aromatic hydrocarbon group may be substituted or unsubstituted. Because the polymer of an embodiment includes a condensed aromatic hydrocarbon group Ar⁴ in a pendent side chain of the polymer, the polymer may have relatively high durability due to its conjugate stabilization effect. Therefore, in order to obtain a high conjugate stabilization effect, the conjugate energy of Ar⁴ may be greater than or equal to about 2.5 eV, for example, greater than or equal to about 2.8 eV, and for example, greater than or equal to about 3.0 eV.

In fact, the upper limit of the conjugate energy of Ar⁴ is not particularly limited, but there is a possibility that the polymer absorbs light in the visible light region as the conjugate energy increases. Therefore, when the polymer of an embodiment is used in a hole injection layer or a hole transport layer (e.g., the hole transport layer), the conjugate energy of Ar⁴ may be less than or equal to about 6.0 eV, for example, less than or equal to about 5.5 eV, in terms of suppressing visible light absorption by these layers.

The method for determining the conjugate energy is as follows. The conjugate energy can be determined by the method reported by Dewar and Gleicher et al. (J. Am. Chem. Soc. 87685 (1965)) incorporated herein by reference. Dewar and Gleicher et al., describe and use semiempirical molecular orbital methods, calculated heats of atomization of a series of chain-linked hydrocarbons and found that the heats of atomization of these compounds are the same as the sum of energies of each bond. Specifically, it is calculated by assigning a unique reference bond energy to each bond of C═C, C—C, and C—H. The value of the conjugate energy in the specification of the present application shall be a value calculated according to this method.

Since the conjugate energy of Ar⁴ is within the above desirable range, the number of rings of the condensed aromatic carbocyclic group Ar⁴ may be 3 to 8, 3 to 5, 3 or 4, or for example 3. Examples of the condensed aromatic carbocyclic group may include a monovalent or divalent group derived from anthracene (conjugate energy: 3.08 eV), phenanthrene (conjugate energy: 3.43 eV); tetracene (conjugate energy: 3.81 eV), chrysene (conjugate energy: 4.51 eV), pyrene (conjugate energy: 3.97 eV), triphenylene (conjugate energy: 5.20 eV), benzo[a]anthracene; or condensed aromatic carbocyclic compounds such as pentacene and perylene (conjugate energy: 5.06 eV).

Among them, Ar⁴ may be a monovalent or divalent group derived from a compound of substituted or unsubstituted anthracene, substituted or unsubstituted phenanthrene, substituted or unsubstituted tetracene, substituted or unsubstituted chrysene, substituted or unsubstituted pyrene, substituted or unsubstituted triphenylene, and substituted or unsubstituted benzo[a]anthracene. For example, Ar⁴ may be a monovalent or divalent group derived from a compound of substituted or unsubstituted anthracene, substituted or unsubstituted phenanthrene, substituted or unsubstituted tetracene, or substituted or unsubstituted chrysene.

In other words, in Chemical Formula 1, Ar⁴ may be a substituted or unsubstituted anthracenyl group, a substituted or unsubstituted phenanthrenyl group, a substituted or unsubstituted tetracenyl group, a substituted or unsubstituted chrysenyl group, or a substituted or unsubstituted anthracenyl group, a substituted or unsubstituted phenanthrenylene group, a substituted or unsubstituted tetracenylene group, or a substituted or unsubstituted chrysenylene group. For example, Ar⁴ may be a substituted or unsubstituted anthracenyl group, a substituted or unsubstituted phenanthrenyl group, a substituted or unsubstituted anthracenylene group, or a substituted or unsubstituted phenanthrenylene group.

In particular, Ar⁴ may be, for example, a substituted or unsubstituted anthracenyl group or a substituted or unsubstituted anthracenylene group, for example, a substituted or unsubstituted anthracenylene group (in particular, 9th and 10th positions are bonded to Ar³ and Ar⁵, respectively), that is, a substituted or unsubstituted 9,10-anthracenylene group).

In Chemical Formula 1, p represents the number of groups Ar⁵ in structural unit A and p is 0 or 1. In other words, when p is 0, Ar⁵ group(s) are absent.

In Chemical Formula 1, when p is 0, Ar⁴ is a substituted or unsubstituted monovalent condensed aromatic carbocyclic group with three or more condensed benzene rings.

In Chemical Formula 1, when p is 0, Ar⁴ is a substituted or unsubstituted monovalent condensed aromatic hydrocarbon group with three or more condensed benzene rings.

From the viewpoint of improving durability and obtaining sufficient luminous efficiency by obtaining a polymer having a deep HOMO level and applying the polymer to an electroluminescence device (particularly, a quantum dot electroluminescence device (QLED)), p may be 1.

In Chemical Formula 1, when p is 1, Ar⁵ is a substituted or unsubstituted, monovalent aromatic carbocyclic group having 6 to 60 ring-forming atoms or a substituted or unsubstituted, monovalent aromatic heterocyclic group having 5 to 60 ring-forming atoms. The aromatic carbocyclic group and aromatic heterocyclic group as Ar⁵ may be monocyclic or condensed.

In the present specification, “aromatic heterocyclic group” means a substituent derived from an aromatic compound in which one or more hetero atoms (e.g., nitrogen atom (N), oxygen atom (O), phosphorus atom (P), sulfur atom (S), silicon atom (Si), selenium atom (Se), etc.) as ring-forming atoms and the remaining ring-forming atoms are carbon atoms (C).

Specific examples of the aromatic heterocyclic group having 5 to 60 ring-forming atoms are not particularly limited, and examples thereof may include a monovalent group derived from an aromatic heterocyclic compound such as pyridine, pyrazine, pyridazine, pyrimidine, triadine, quinoline, isoquinoline, quinoxaline, quinazoline, naphthylidine, acridine, phenazine, benzoquinoline, benzoisoquinoline, phenanthridine, phenanthroline, benzoquinone, coumarin, fluorenone, furan, thiophene, benzofuran, benzothiophene, dibenzofuran, dibenzothiophene, pyrrole, indole, carbazole, imidazole, benzimidazole, pyrazole, indazole, oxazole, isoxazole, benzooxazole, benzoisoxazole, thiazole, isothiazole, benzothiazole, benzoisothiazole, imidazolinone, benzimidazolinone, imidazopyridine, imidazo pyrimidine, azadibenzofuran, azacarbazole, azadibenzothiophene, diazadibenzofuran, diazacarbazole, diazadibenzothiophene, xanthone, thioxanthone, and a combination thereof.

Ar⁵ may be a substituted or unsubstituted aromatic carbocyclic group having 6 to 30 ring-forming atoms, or a substituted or unsubstituted aromatic heterocyclic group having 5 to 30 ring-forming atoms, and may be a substituted or unsubstituted aromatic hydrocarbon group having 6 to 15 ring-forming atoms, or a substituted or unsubstituted aromatic heterocyclic group having 5 to 15 ring-forming atoms.

Ar⁵ may be a substituted or unsubstituted phenyl group, a substituted or unsubstituted naphthyl group, a substituted or unsubstituted fluorenyl group, a substituted or unsubstituted dibenzofuranyl group, or a substituted or unsubstituted dibenzothienyl group.

Further, Ar⁵ may be a substituted or unsubstituted naphthyl group, a substituted or unsubstituted fluorenyl group, a substituted or unsubstituted dibenzofuranyl group, or a substituted or unsubstituted dibenzothienyl group.

Among these, from the viewpoint of further improving durability of a device (or polymer in a device), in Chemical Formula 1, p is 1, and at the same time, Ar⁵ may be a group represented by Chemical Formula 5 or Chemical Formula 6:

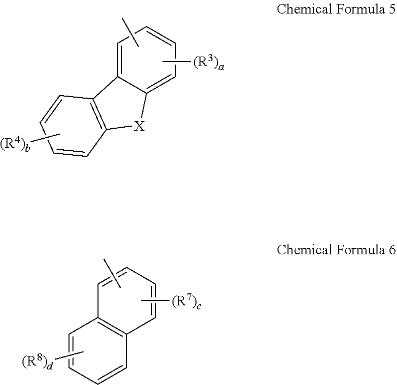

wherein, in Chemical Formula 5, R³ and R⁴ may each independently be a substituted or unsubstituted aromatic carbocyclic group having 6 to 30 ring-forming atoms, a substituted or unsubstituted alkyl group having 1 to 50 carbon atoms, or two adjacent R³ and two adjacent R⁴ may be joined to form a ring.

The number of ring-forming atoms in the aromatic carbocyclic group R³ and R⁴ may be 6 to 20, 6 to 15, or 6 to 10. Also, the number of carbon atoms in the alkyl group R³ and R⁴ may be 1 to 30, 1 to 15, or 1 to 10. Since the specific examples of the aromatic carbocyclic group and the alkyl group as R³ and R⁴ are the same as the specific examples of the aromatic carbocyclic group and the alkyl group exemplified for R¹ and R², respectively, descriptions thereof are omitted.

The aromatic carbocyclic group or alkyl group as R³ may be bonded to the aromatic carbocyclic group or alkyl group as R⁴ through a single bond.

In Chemical Formula 5, a is 0, 1, 2, or 3, and b is 0, 1, 2, 3, or 4, and when a or b is 2 or more, each R³ or each R⁴ may be the same or different, where a and b respectively represent the number of substituent groups R³ and R⁴ for ring-forming atoms included in the structure of Chemical Formula 5.

When a or b is 0, it means that R³ or R⁴, respectively, are absent (i.e., the corresponding ring forming atom are unsubstituted. In other words, in Chemical Formula 5, the ring-forming atom described so that the substituent R³ or R⁴ may be bonded is unsubstituted, indicating that a hydrogen atom is bonded to the ring-forming atom.

The indice a may be 0, 1 or 2, may be 0 or 1, or may be 0.

The indice b may be 0, 1 or 2, may be 0 or 1, or may be 0.

In Chemical Formula 5, X may be —C(R⁵)(R⁶)—, —O—, or —S—, and among them, from the viewpoint of further improving durability, X may be —C(R⁵)(R⁶)— or —S—.

In Chemical Formula 5, when X is —C(R⁵)(R⁶)—, R⁵ and R⁶ are each independently a substituted or unsubstituted aromatic carbocyclic group having 6 to 30 ring-forming atoms, a substituted or unsubstituted alkyl group having 1 to 50 carbon atoms, or R⁵ and R⁶ may join to form a ring.

R⁵ and R⁶ may be the same or different, although R⁵ and R⁶ may be the same.

The number of ring-forming atoms in the aromatic carbocyclic group as R⁵ and R⁶ may be 6 to 20, 6 to 15, or 6 to 10. Also, the number of carbon atoms in the alkyl group as R⁵ and R⁶ may be 1 to 30, 1 to 15, or 1 to 10.

Specific examples of the aromatic carbocyclic group and alkyl group as R⁵ and R⁶ are the same as the specific examples of the aromatic carbocyclic group and alkyl group exemplified for R¹ and R², respectively, and thus descriptions thereof are omitted.

On the other hand, the aromatic carbocyclic group or alkyl group as R⁵ may be bonded to the aromatic carbocyclic group or alkyl group as R⁶ through a single bond.

From the viewpoint of further improving durability, R⁵ and R⁶ may each independently be a substituted or unsubstituted linear or branched alkyl group having 1 to 10 carbon atoms and a substituted or unsubstituted linear alkyl group having 1 to 10 carbon atoms.

In Chemical Formula 6, R⁷ and R⁸ may each independently be a substituted or unsubstituted aromatic carbocyclic group having 6 to 30 ring-forming atoms, or a substituted or unsubstituted alkyl group having 1 to 50 carbon atoms. Alternatively, two adjacent R⁷ and R⁸ may be joined to form a ring, or a R⁷ and a R⁸ may join to form a ring.

The number of ring-forming atoms in the aromatic carbocyclic group as R⁷ and R⁸ may be 6 to 20, 6 to 15, or 6 to 10. The number of carbon atoms in the alkyl group as R⁷ and R⁸ may be 1 to 30, 1 to 15, or 1 to 10.

In addition, specific examples of the aromatic carbocyclic group and alkyl group as R⁷ and R⁸ are the same as the specific examples of the aromatic carbocyclic group and alkyl group exemplified for R¹ and R², respectively, and thus descriptions thereof are omitted.

On the other hand, the aromatic carbocyclic group or the alkyl group as R⁷ may be bonded to the aromatic carbocyclic group or the alkyl group as R⁸ through a single bond.

The indice c in Chemical Formula 6 is 0, 1, 2, or 3, and d is 0, 1, 2, 3, or 4, and when any one of c or d is 2 or more, each R⁷ or each R⁸ may be the same or different.

The c and d represent the number of substituent groups R⁷ and R⁸ substituted on ring-forming atoms included in the structure of Chemical Formula 6, respectively.

When c or d is 0, it means that R⁷ or R⁸ corresponding to them does not exist. In other words, in Chemical Formula 6, the ring-forming atom described as to which the substituent R⁷ or R⁸ may be bonded is unsubstituted.

The c may be 0, 1 or 2, may be 0 or 1, or may be 0.

The d may be 0, 1 or 2, may be 0 or 1, or may be 0.

In addition, from the viewpoint of improving durability and obtaining sufficient luminous efficiency, in Chemical Formula 1, p is 1, and at the same time, Ar⁵ may be a group represented by Chemical Formula 5.

In this case, the group represented by Chemical Formula 5 may be represented by (501) to (515):

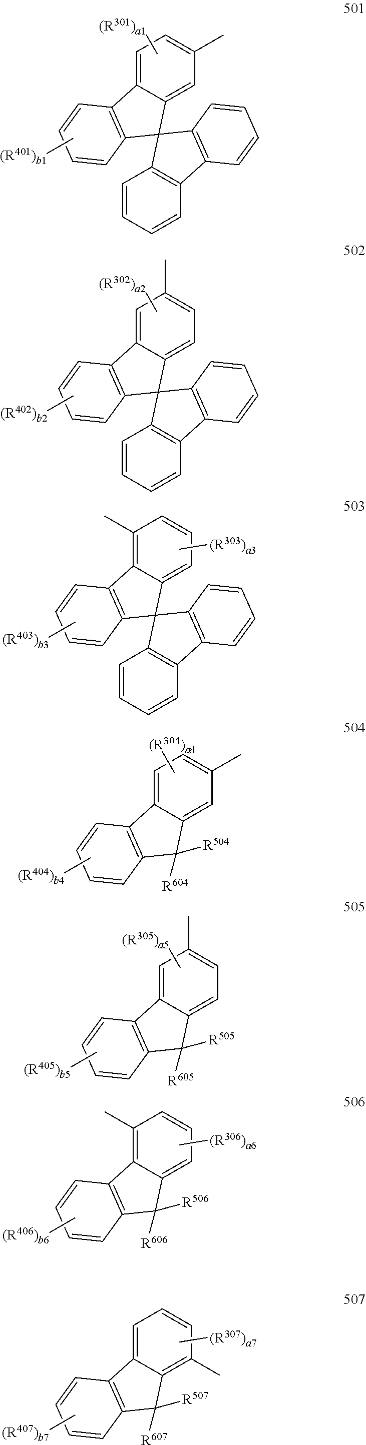

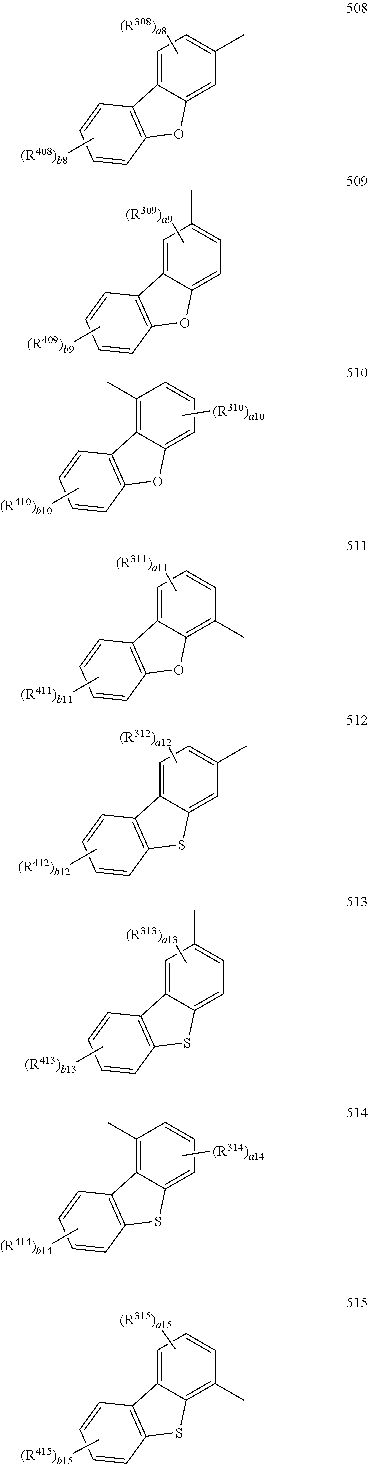

In the groups represented by (501) to (515), R³⁰¹ to R³¹⁵ and R⁴⁰¹ to R⁴¹⁵ are each independently a substituted or unsubstituted aromatic carbocyclic group having 6 to 30 ring-forming atoms, a substituted or unsubstituted alkyl group having 1 to 50 carbon atoms, or two adjacent R³⁰¹ or R⁴⁰¹, two adjacent R³⁰² or R⁴⁰², two adjacent R³⁰³ or R⁴⁰³, two adjacent R³⁰⁴ or R⁴⁰⁴ two adjacent R³⁰⁵ or R⁴⁰⁵, two adjacent R³⁰⁶ or R⁴⁰⁶, two adjacent R³⁰⁷ or R⁴⁰⁷, two adjacent R³⁰⁸ or R⁴⁰⁸, two adjacent R³⁰⁹ or R⁴⁰⁹, two adjacent R³¹⁰ or R⁴¹⁰, two adjacent R³¹¹ or R⁴¹¹, two adjacent R³¹² or R⁴¹², two adjacent R³¹³ or R⁴¹³, two adjacent R³¹⁴ or R⁴¹⁴, or two adjacent R³¹⁵ or R⁴¹⁵, may be joined to form a ring.

In the groups (501) to (515), R³⁰¹ to R³¹⁵ are the same as R³ in Chemical Formula 5, and R⁴⁰¹ to R⁴¹⁵ are each the same as R⁴ in Chemical Formula 5.

The number of ring-forming atoms of the aromatic carbocyclic group as R³⁰¹ to R³¹⁵ and R⁴⁰¹ to R⁴¹⁵ may be 6 to 20, for example, 6 to 15, or for example, 6 to 10. In addition, the number of carbon atoms in the alkyl group as R³⁰¹ to R³¹⁵ and R⁴⁰¹ to R⁴¹⁵ may be 1 to 30, 1 to 15, or 1 to 10.

In addition, specific examples of the aromatic hydrocarbon group and alkyl group as R³⁰¹ to R³¹⁵ and R⁴⁰¹ to R⁴¹⁵ are the same as the specific examples of the aromatic hydrocarbon group and alkyl group exemplified for R¹ and R², respectively, and thus descriptions thereof are omitted.

On the other hand, the aromatic hydrocarbon group or alkyl group as R³⁰¹ to R³¹⁵ may be bonded to the aromatic hydrocarbon group or alkyl group as R⁴⁰¹ to R⁴¹⁵ through a single bond.

In the group represented by (501) to (515), a1 to a15 are each independently 0, 1, 2 or 3, and b1 to b15 are each independently 0, 1, 2, 3; or 4, and when any one of a1 to a15 or b1 to b15 is 2 or more, each R³⁰¹, each R³⁰², each R³⁰³, each R³⁰⁴, each R³⁰⁵, each R³⁰⁶, each R³⁰⁷, each R³⁰⁸, each R³⁰⁹, each R³¹⁰, each R³¹¹, each R³¹², each R³¹³, each R³¹⁴, each R³¹⁵, each R⁴⁰¹, each R⁴⁰², each R⁴⁰³, each R⁴⁰⁴, each R⁴⁰⁵, each R⁴⁰⁶, each R⁴⁰⁷, each R⁴⁰⁸, each R⁴⁰⁹, each R⁴¹⁰, each R⁴¹¹, each R⁴¹², each R⁴¹³, each R⁴¹⁴, or each R⁴¹⁵, may be the same or different.

In the groups represented by (501) to (515), a1 to a15 and b1 to b15 represent the numbers of R³⁰¹ to R³¹⁵ and R⁴⁰¹ to R⁴¹⁵ substituted on ring-forming atoms contained in the groups represented by (501) to (515), respectively, and a1 to a15 are 0, 1, 2 or 3 and b1 to b15 are 0, 1, 2, 3 or 4.

If a1, a2, a3, a4, a5, a6, a7, a8, a9, a10, a11, a12, a13, a14 or a15 are 0, the corresponding R³⁰¹, R³⁰², R³⁰³, R³⁰⁴, R³⁰⁵, R³⁰⁶, R³⁰⁷, R³⁰⁸, R³⁰⁹, R³¹⁰, R³¹¹, R³¹², R³¹³, R³¹⁴, or R³¹⁵ are not present. In other words, in the above (501) to (515), the ring-forming atoms described as to which the substituents R³⁰¹, R³⁰², R³⁰³, R³⁰⁴, R³⁰⁵, R³⁰⁶, R³⁰⁷, R³⁰⁸, R³⁰⁹, R³¹⁰, R³¹¹, R³¹², R³¹³, R³¹⁴ or R³¹⁵ may be bonded are unsubstituted, indicating that that a hydrogen atom is bonded to the ring-forming atom.

Similarly, if b1, b2, b3, b4, b5, b6, b7, b8, b9, b10, b11, b12, b13, b14 or b15 are 0, the corresponding R⁴⁰¹, R⁴⁰², R⁴⁰³, R⁴⁰⁴, R⁴⁰⁵, R⁴⁰⁶, R⁴⁰⁷, R⁴⁰⁸, R⁴⁰⁹, R⁴¹⁰, R⁴¹¹, R⁴¹², R⁴¹³, R⁴¹⁴, or R⁴¹⁵ are not present.

In other words, in the groups represented by (501) to (515), the ring-forming atoms described as to which the substituents R⁴⁰¹, R⁴⁰², R⁴⁰³, R⁴⁰⁴, R⁴⁰⁵, R⁴⁰⁶, R⁴⁰⁷, R⁴⁰⁸, R⁴⁰⁹, R⁴¹⁰, R⁴¹¹, R⁴¹², R⁴¹³, R⁴¹⁴, or R⁴¹⁵ may be bonded are unsubstituted, indicating that a hydrogen atom is bonded to the ring-forming atom.

Further, when any one of a1 to a15 or b1 to b15 is 2 or more, each R³⁰¹, each R³⁰², each R³⁰³, each R³⁰⁴, each R³⁰⁵, each R³⁰⁶, each R³⁰⁷, each R³⁰⁸, each R³⁰⁹, each R³¹⁰, each R³¹¹, each R³¹², each R³¹³, each R³¹⁴, each R³¹⁵, each R⁴⁰¹, each R⁴⁰², each R⁴⁰³, each R⁴⁰⁴, each R⁴⁰⁵, each R⁴⁰⁶, each R⁴⁰⁷, each R⁴⁰⁸, each R⁴⁰⁹, each R⁴¹⁰, each R⁴¹¹, each R⁴¹², each R⁴¹³, each R⁴¹⁴, or each R⁴¹⁵ may be the same or different.

The a1 to a15 may each independently be 0, 1 or 2, may be 0 or 1, or may be 0.

The b1 to b15 may each independently be 0, 1 or 2, may be 0 or 1, or may be 0.

In the groups represented by (504) to (507), R⁵⁰⁴ to R⁵⁰⁷ and R⁶⁰⁴ to R⁶⁰⁷ are each independently a substituted or unsubstituted aromatic carbocyclic group having 6 to 30 ring-forming atoms, a substituted or unsubstituted alkyl group having 1 to 50 carbon atoms, or two adjacent R⁵⁰⁴ and R⁶⁰⁴, two adjacent R⁵⁰⁵ and R⁶⁰⁵, two adjacent R⁵⁰⁶ and R⁶⁰⁶, or two adjacent R⁵⁰⁷ and R⁶⁰⁷, may be joined to form a ring.

In the groups represented by (504) to (507), R⁵⁰⁴ to R⁵⁰⁷ are the same as R⁵ in Chemical Formula 5, and R⁶⁰⁴ to R⁶⁰⁷ are each the same as R⁶ in Chemical Formula 5.

R⁵⁰⁴ and R⁶⁰⁴, R⁰⁵ and R⁶⁰⁵, R⁵⁰⁶ and R⁶⁰⁶, and R⁵⁰⁷ and R⁶⁰⁷ may be the same or different, although R⁰⁴ and R⁶⁰⁴, R⁰⁵ and R⁶⁰⁵, R⁵⁰⁶ and R⁶⁰⁶, and R⁵⁰⁷ and R⁶⁰⁷, may be the same respectively.

The number of ring-forming atoms of the aromatic hydrocarbon groups of R⁰⁴ to R⁵⁰⁷ and R⁶⁰⁴ to R⁶⁰⁷ may be 6 to 20, for example, 6 to 15, or 6 to 10.

In addition, the number of carbon atoms in the alkyl groups of R⁰⁴ to R⁵⁰⁷ and R⁶⁰⁴ to R⁶⁰⁷ may be 1 to 30, for example, 1 to 15, 1 to 10, or 1 to 3.

Specific examples of the aromatic hydrocarbon group and alkyl group as R⁵⁰⁴ to R⁵⁰⁷ and R⁶⁰⁴ to R⁶⁰⁷ are the same as the specific examples of the aromatic hydrocarbon group and alkyl group exemplified for R¹ and R², respectively, and thus descriptions thereof are omitted.

On the other hand, the aromatic carbocyclic group or alkyl group as R⁵⁰⁴ to R⁵⁰⁷ may be bonded to the aromatic hydrocarbon group or alkyl group as R⁶⁰⁴ to R⁶⁰⁷ through a single bond.

From the viewpoint of further improving durability and obtaining sufficient luminous efficiency, R⁵⁰⁴ to R⁵⁰⁷ and R⁶⁰⁴ to R⁶⁰⁷ may each independently be a substituted or unsubstituted linear or branched alkyl group having 1 to 10 carbon atoms or a substituted or unsubstituted linear alkyl group having 1 to 10 carbon atoms, for example, a substituted or unsubstituted linear alkyl group having 1 to 3 carbon atoms.

Among the above, the group represented by Chemical Formula 5 may be any one of the groups represented by (504) to (507) and (512) to (515). In other words, in Chemical Formula 1, p is 1, and at the same time, Ar⁵ may be any one of groups represented by (504) to (507) and (512) to (515) above.

### Examples of Structural Unit X

In Chemical Formula 1, as examples of the structural unit X, Ar¹, Ar², and Ar³ are each independently groups represented by Chemical Formula 2 or Chemical Formula 3, p is 0 or 1, and when p is 1, Ar⁴ may be a substituted or unsubstituted anthracenylene group or a substituted or unsubstituted phenanthrenylene group, and when p is 0, Ar⁴ may be a substituted or unsubstituted anthracenyl group or a substituted or unsubstituted phenanthrenyl group, and when p is 1, Ar⁵ may be a group represented by (504) to (507) or a group represented by (512) to (515).

For example, Ar¹ and Ar² are groups represented by Chemical Formula 2, Ar³ is a group represented by Chemical Formula 2 or Chemical Formula 3, p is 0 or 1, and when p is 1, Ar⁴ may be a substituted or unsubstituted anthracenyl group or a substituted or unsubstituted phenanthrenyl group, or when p is 0, Ar⁴ may be a substituted or unsubstituted anthracenyl group or a substituted or unsubstituted phenanthrenyl group, or when p is 1, Ar⁵ may a group represented by (504) to (507) or (512) to (515).

For example, Ar¹ and Ar² are groups represented by Chemical Formula 2, Ar³ is a group represented by Chemical Formula 2 or Formula 3, p is 0 or 1, and when p is 1, Ar⁴ may be an unsubstituted anthracenylene group or an unsubstituted phenanthrenylene group, or when p is 0, Ar⁴ may be an unsubstituted anthracenyl group or an unsubstituted phenanthrenyl group, or when p is 1, Ar⁵ may be a group represented by (504) to (507) or (512) to (515), and a4 to a7, a12 to a15, b4 to b7, and b12 to b15 are 0.

The polymer including the structural unit X as described above has improved durability, e.g., in an EL device such as in a hole transport layer of an EL device, due to the conjugate stabilization effect of Ar⁴. Moreover, the polymer having the structural unit X as described above has a deep HOMO level. Accordingly, the luminous efficiency of the LED (e.g., QLED) with the polymer according to the embodiment may be improved.

Examples of the structural unit X according to an embodiment include the following structures.

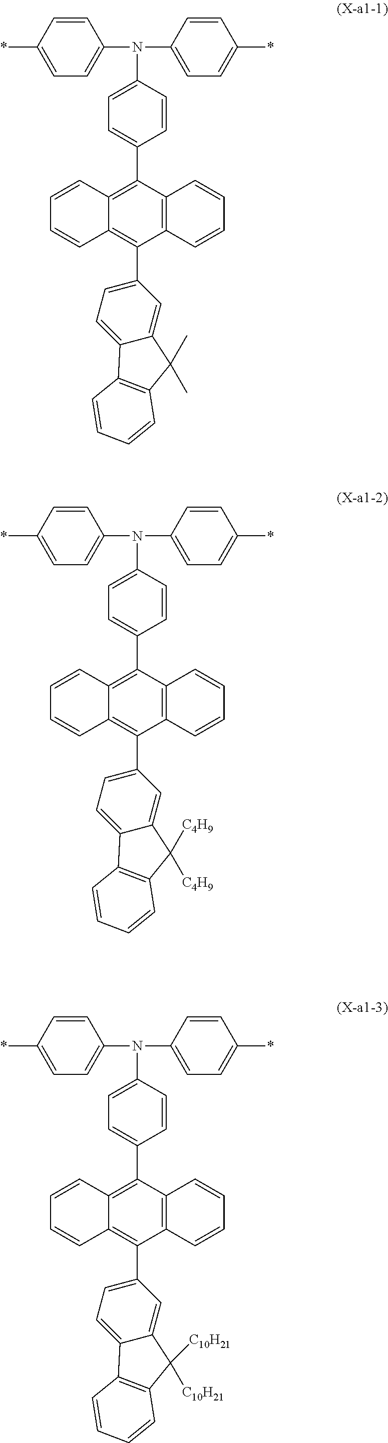

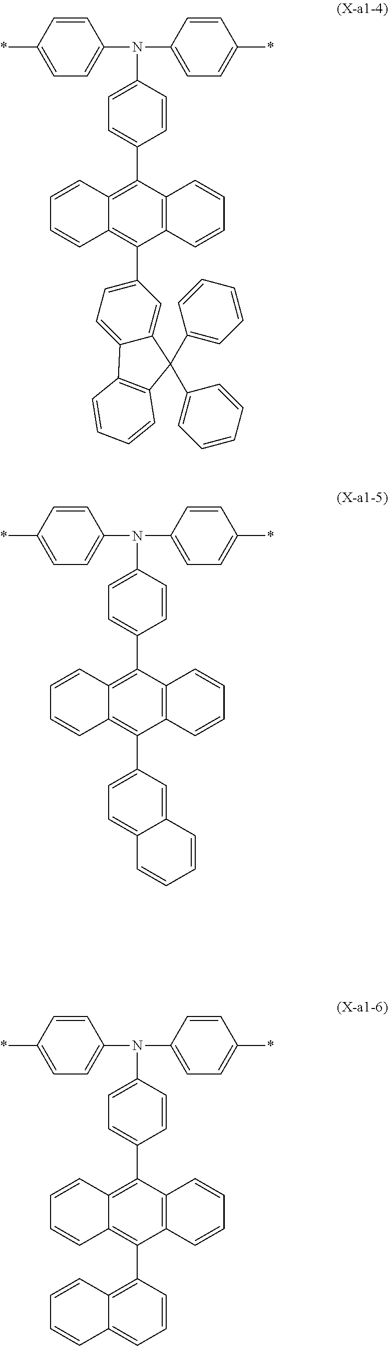

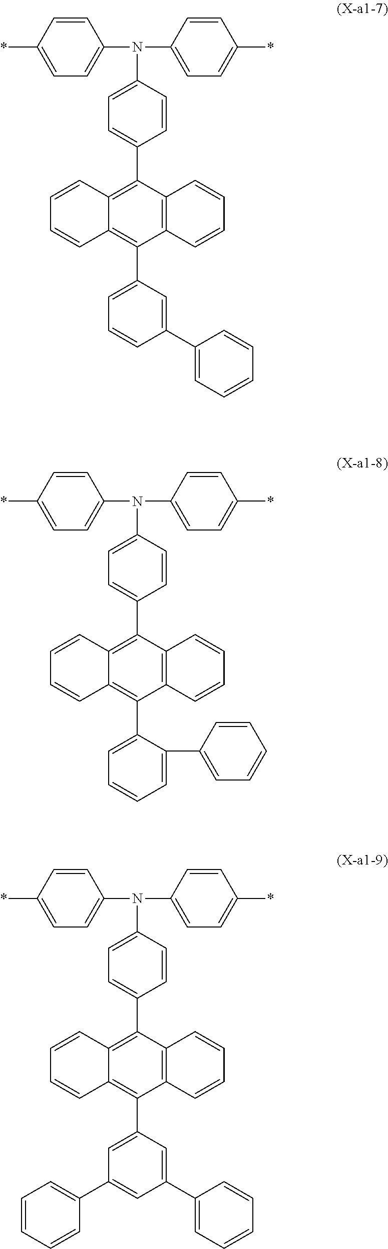

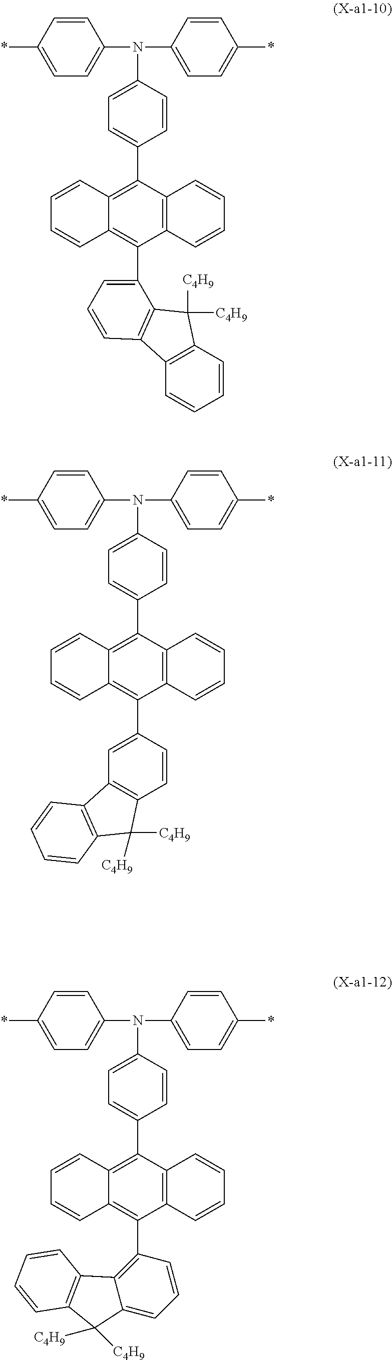

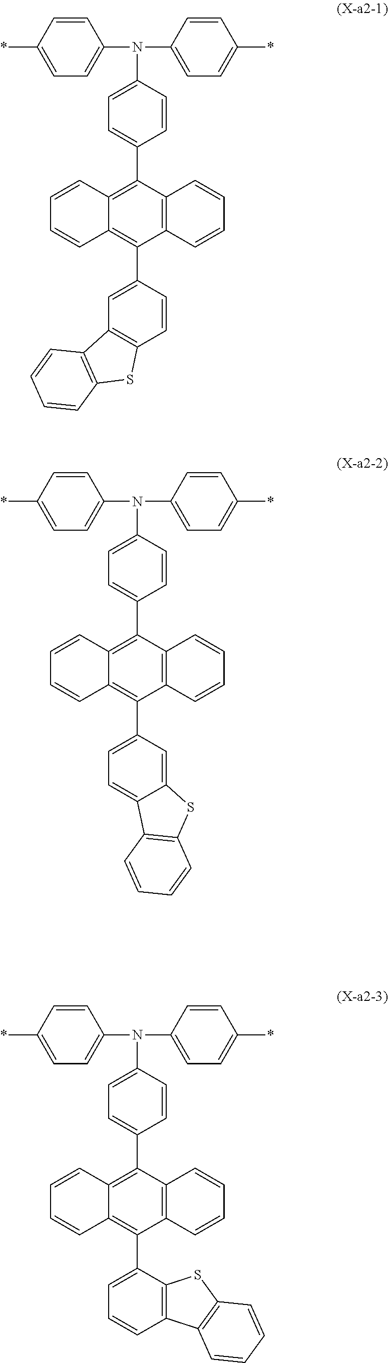

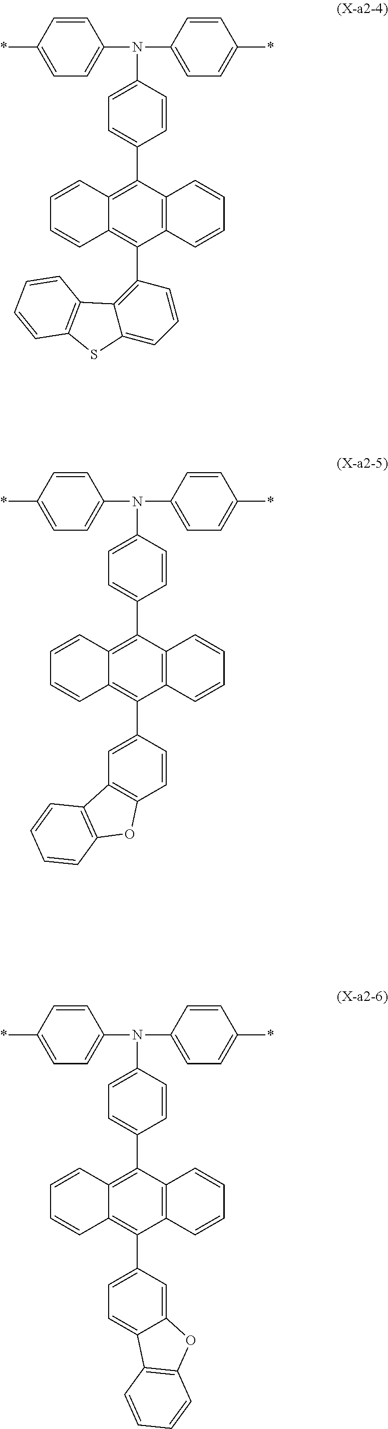

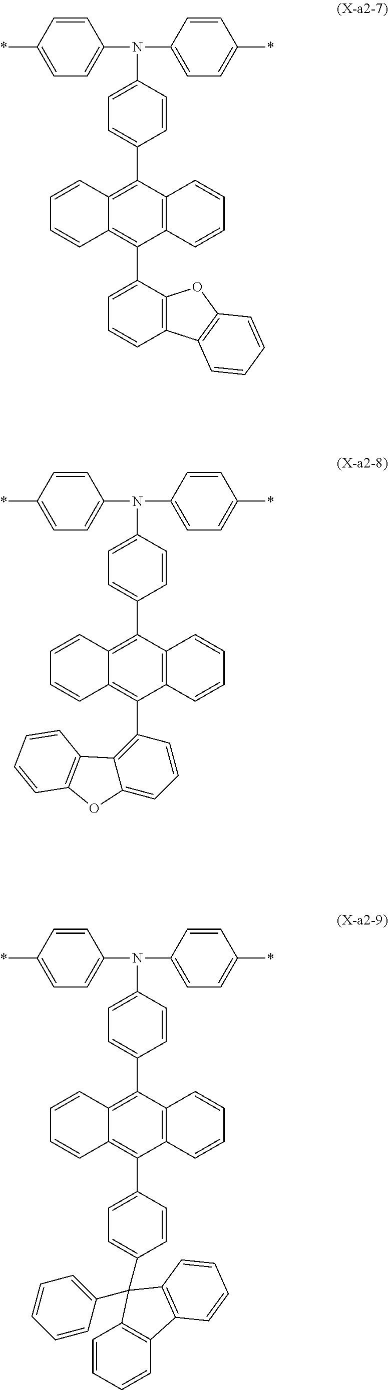

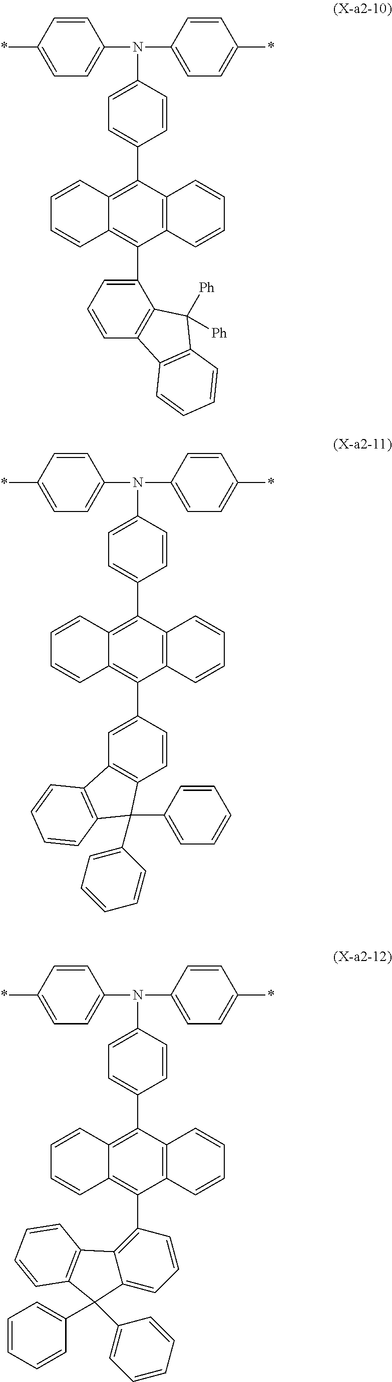

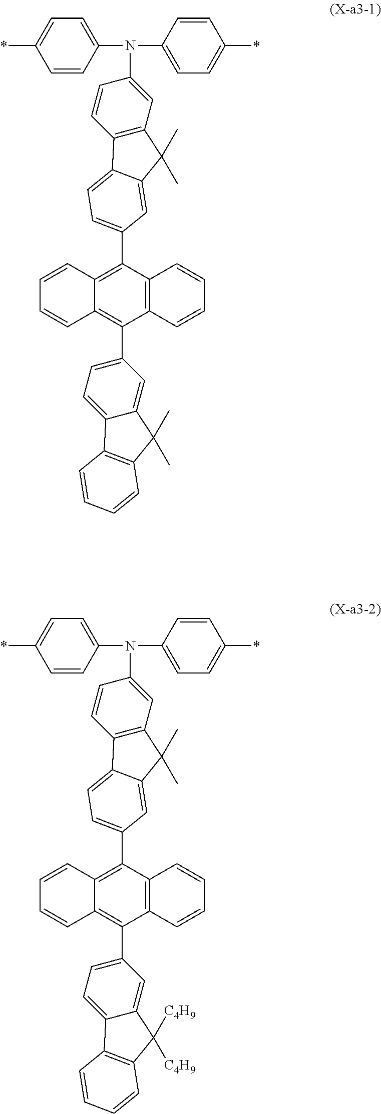

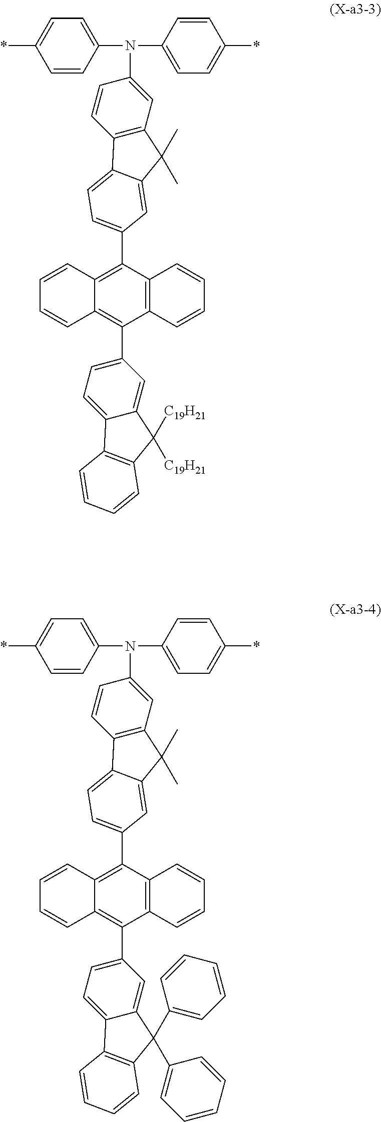

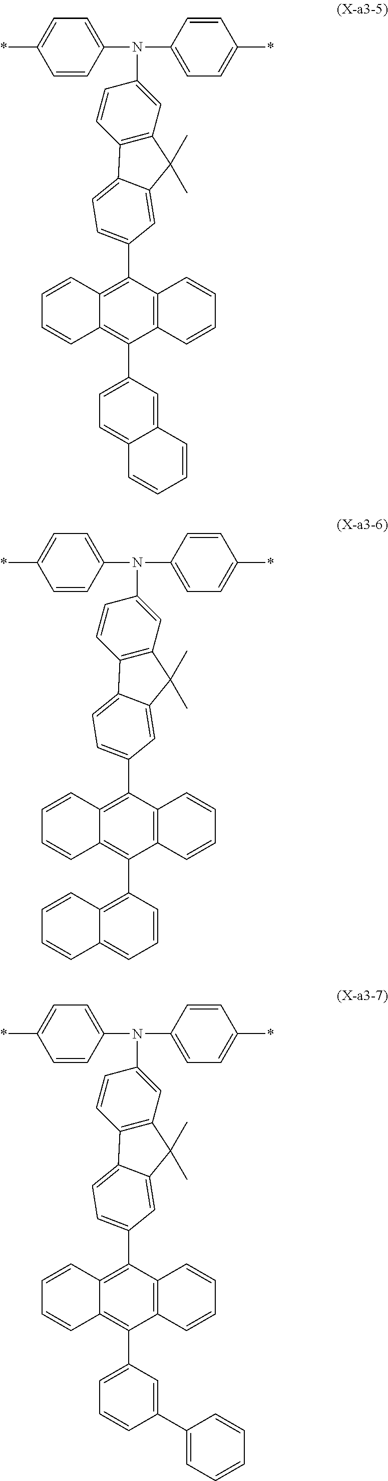

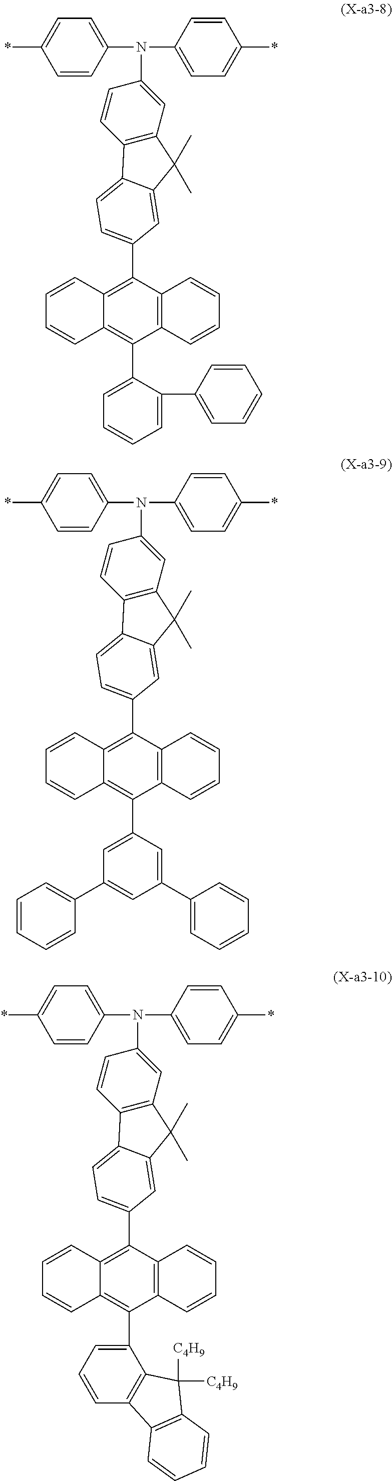

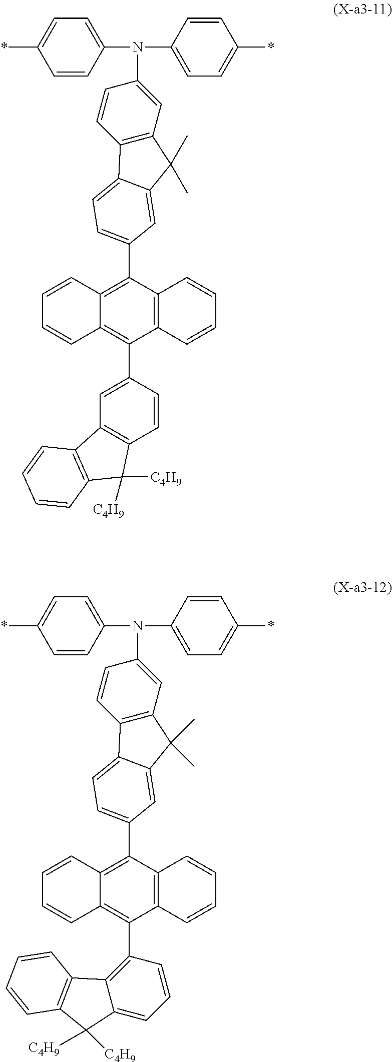

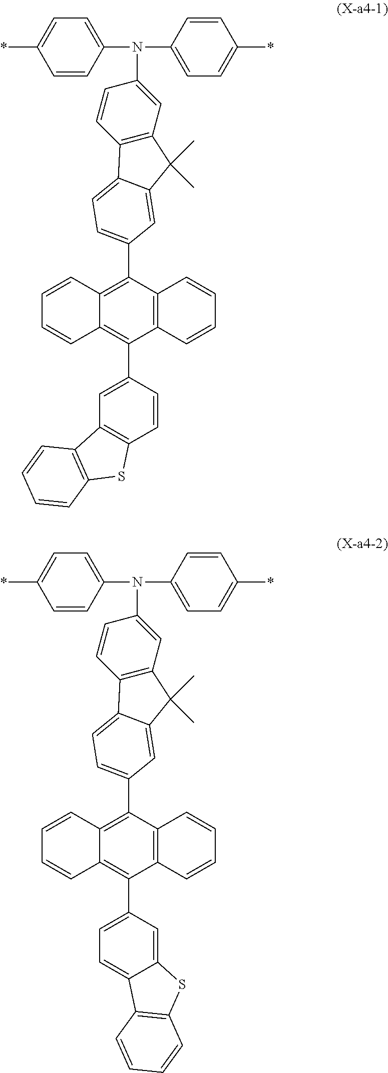

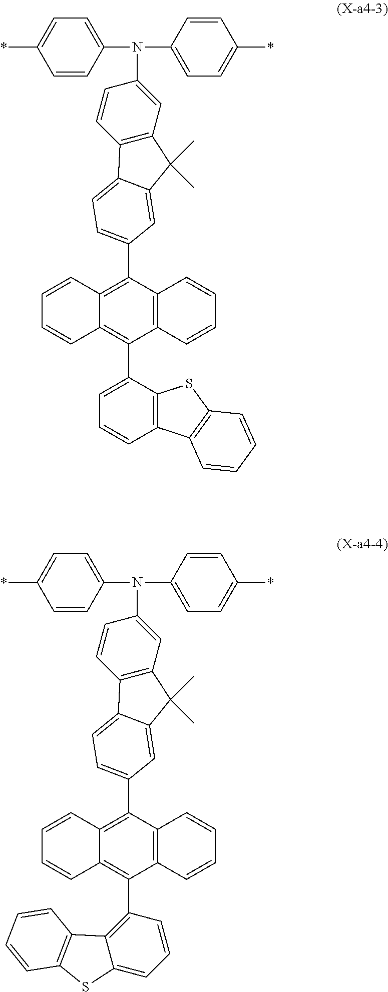

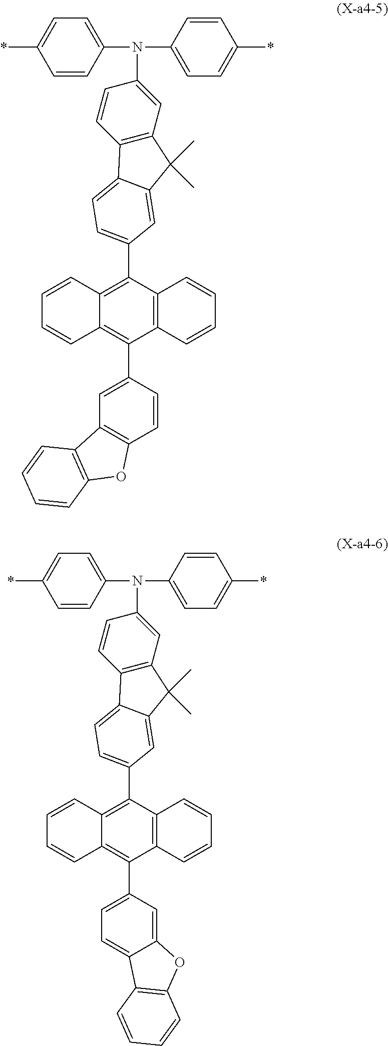

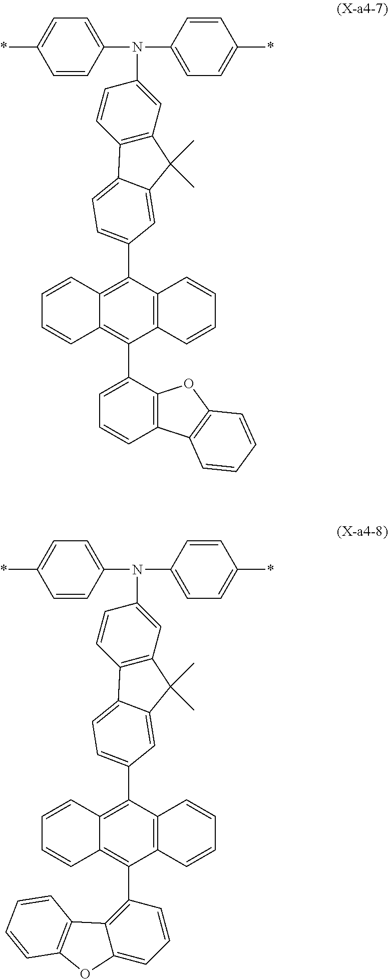

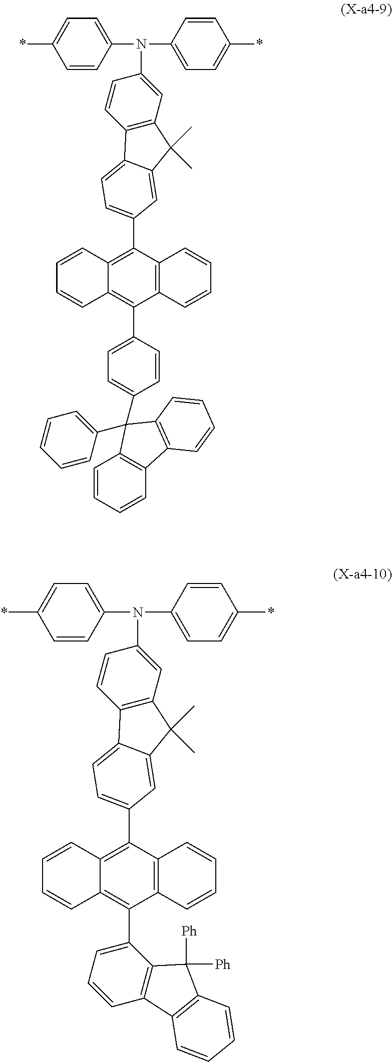

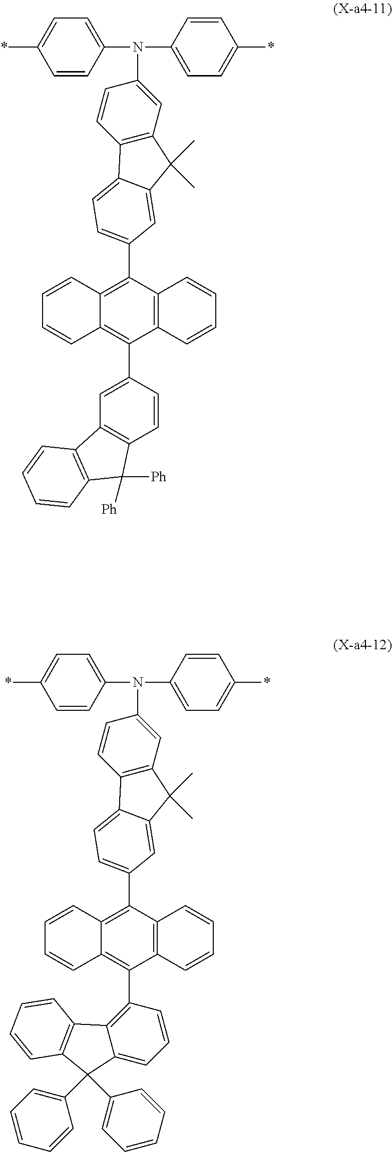

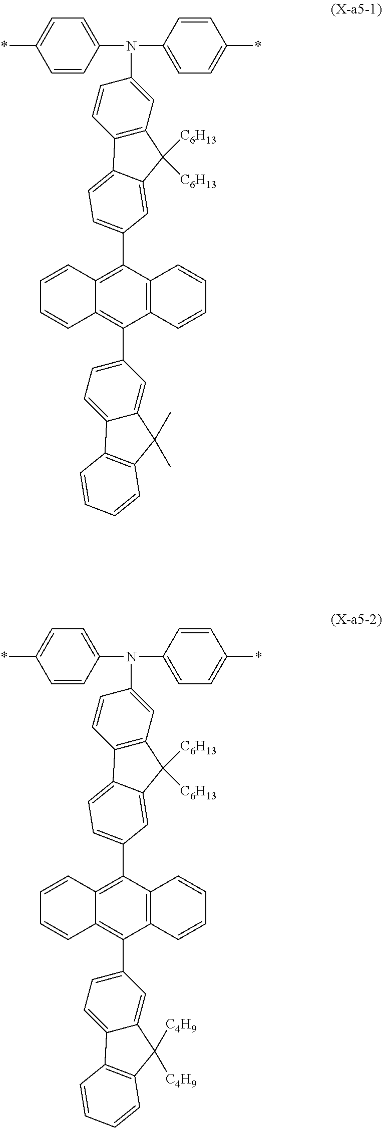

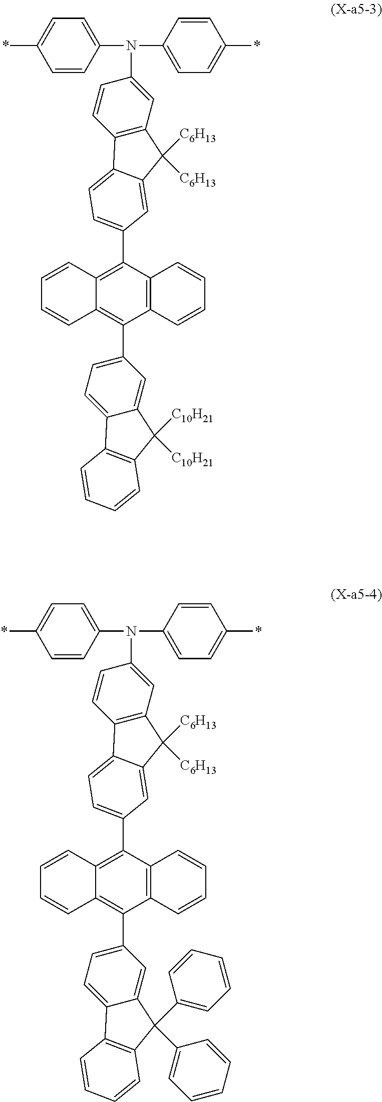

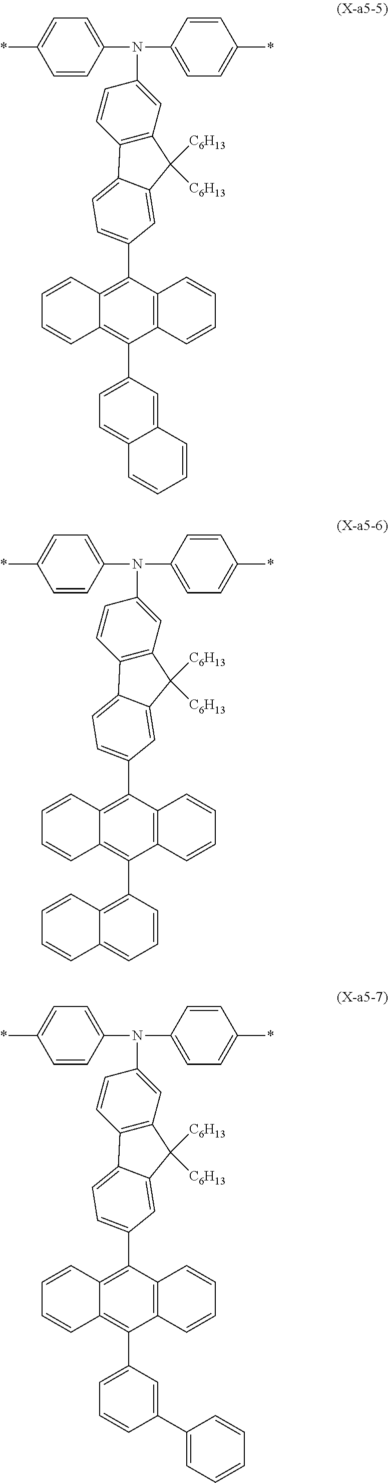

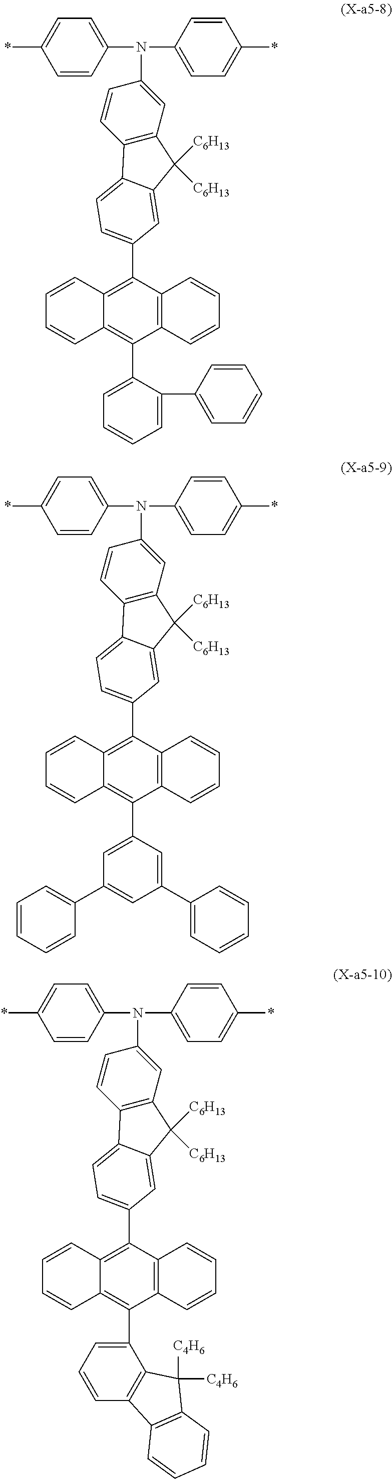

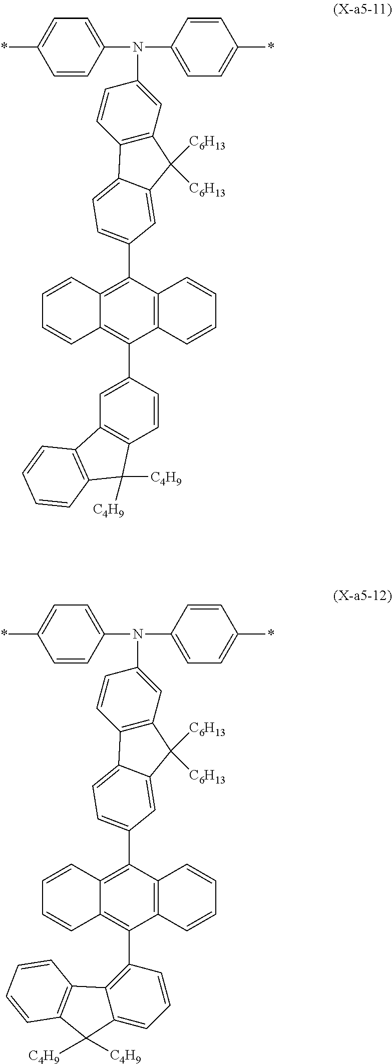

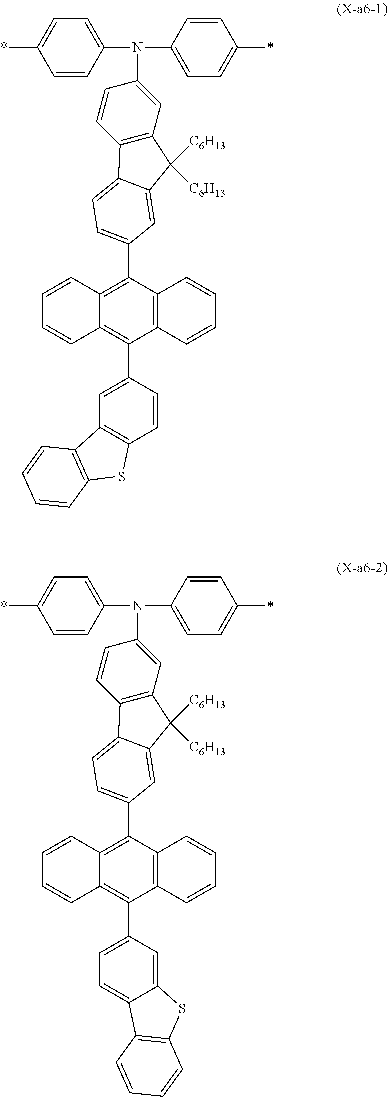

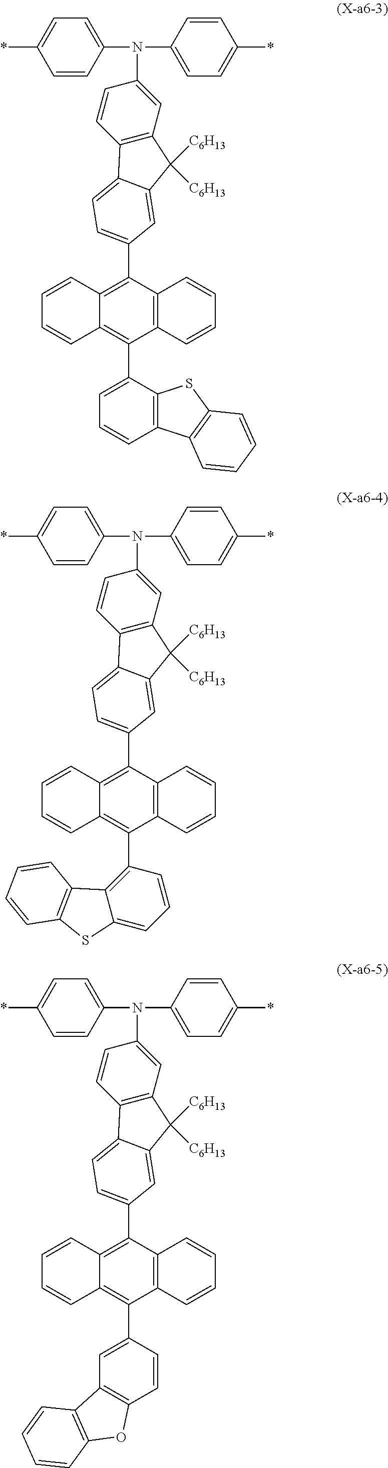

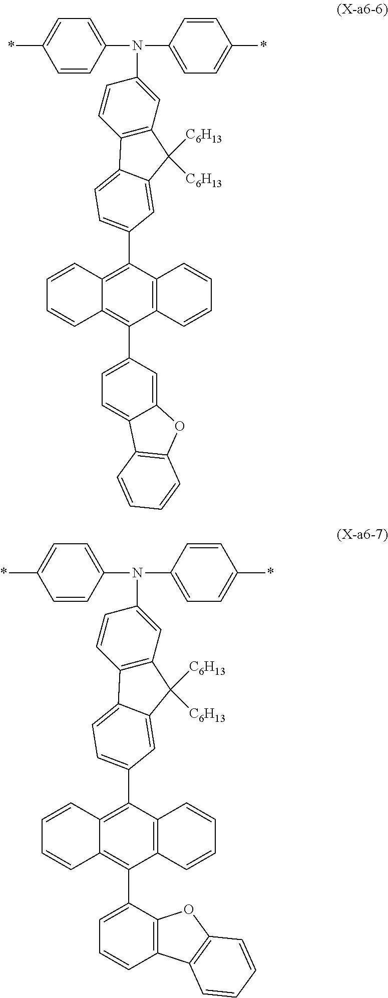

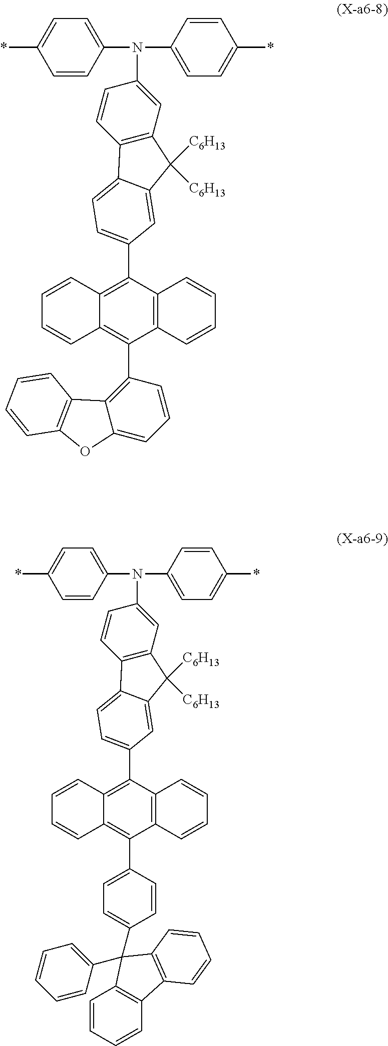

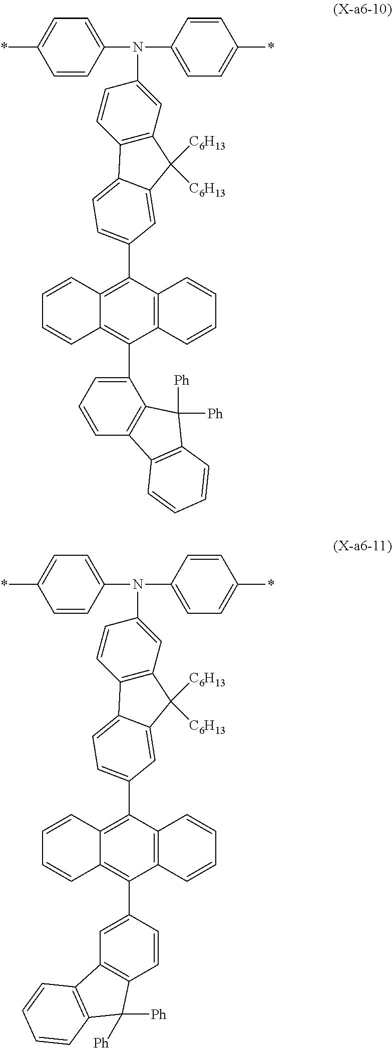

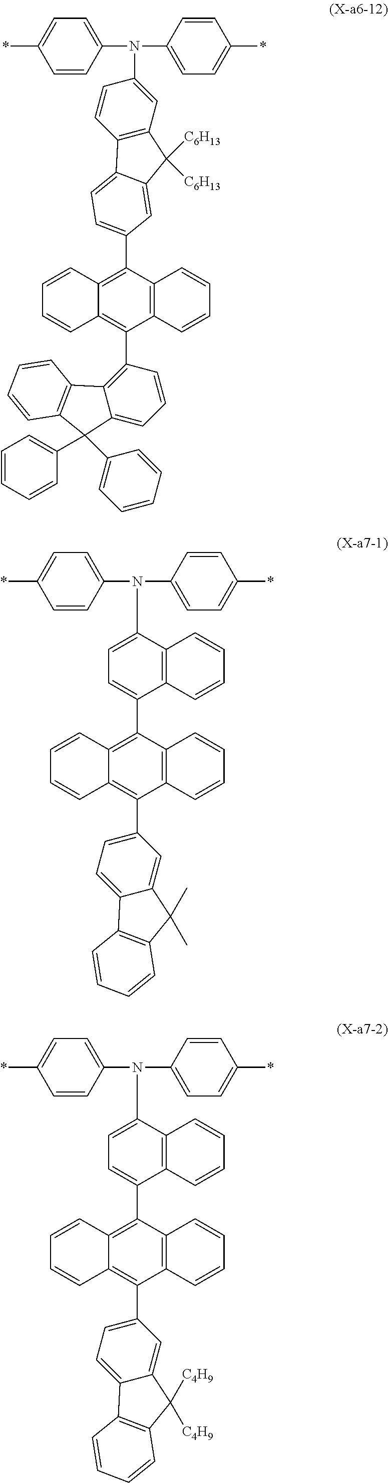

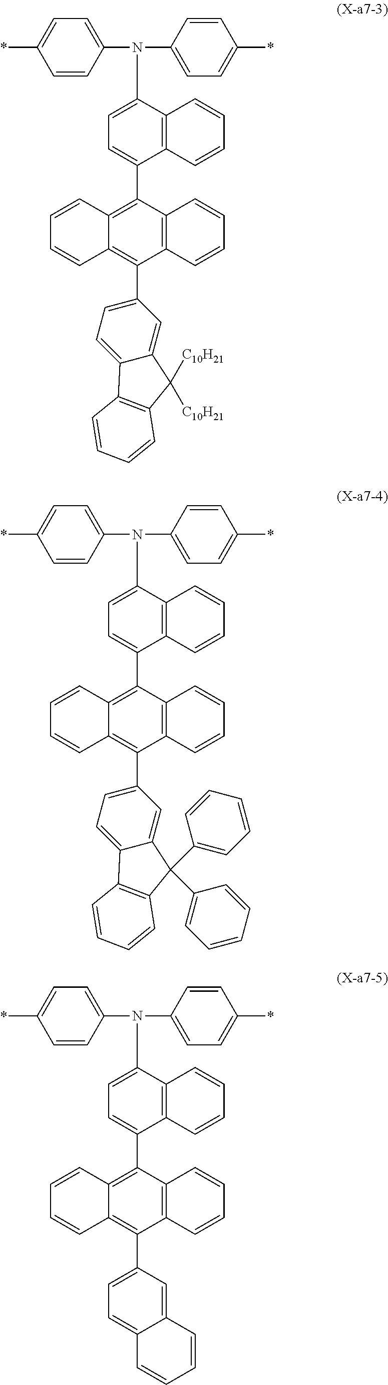

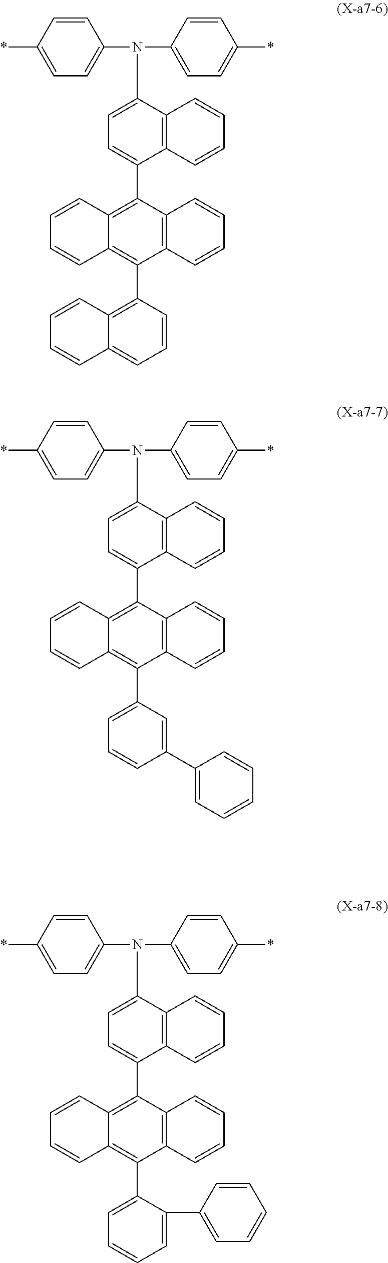

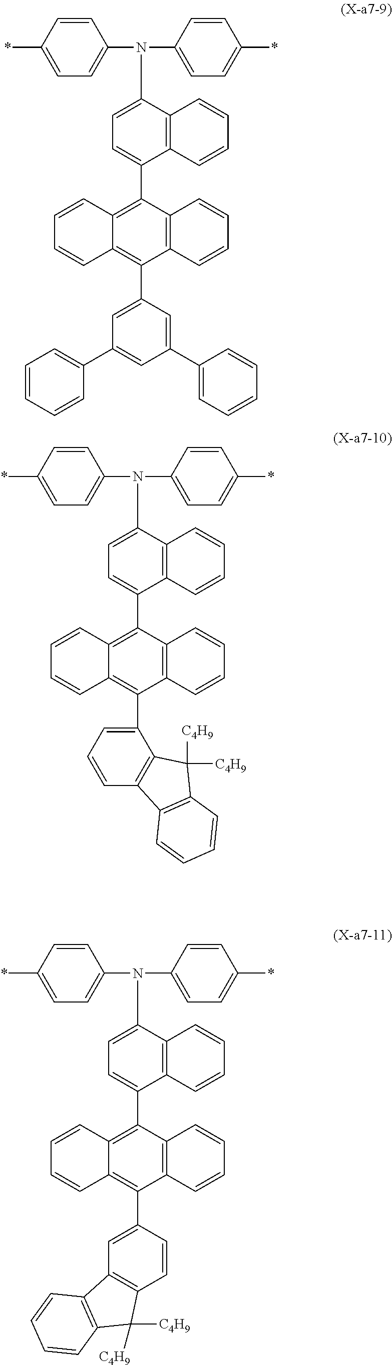

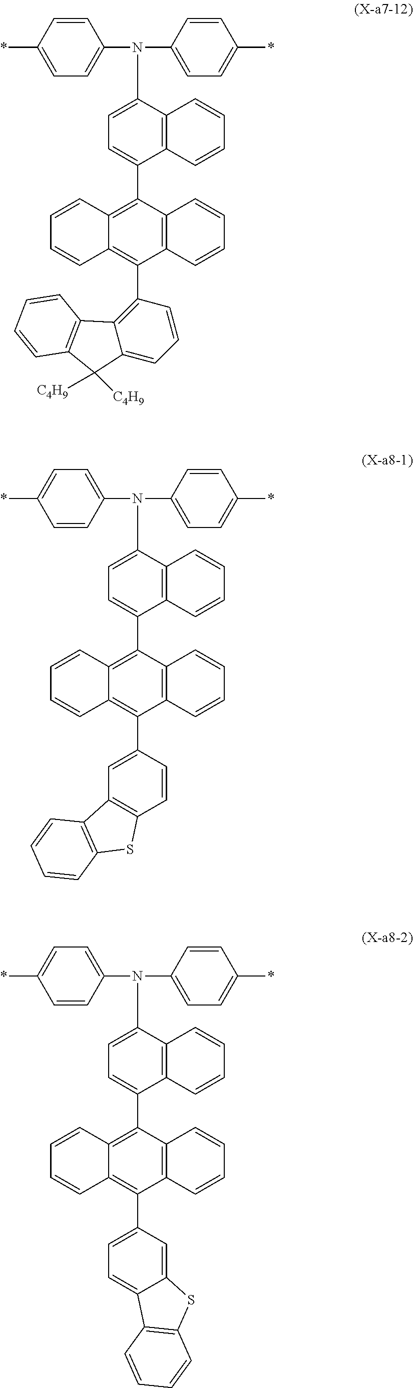

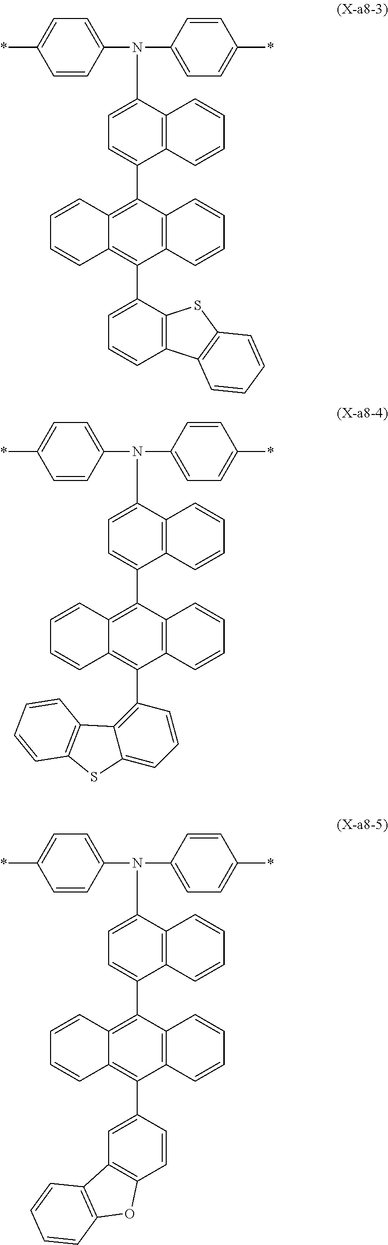

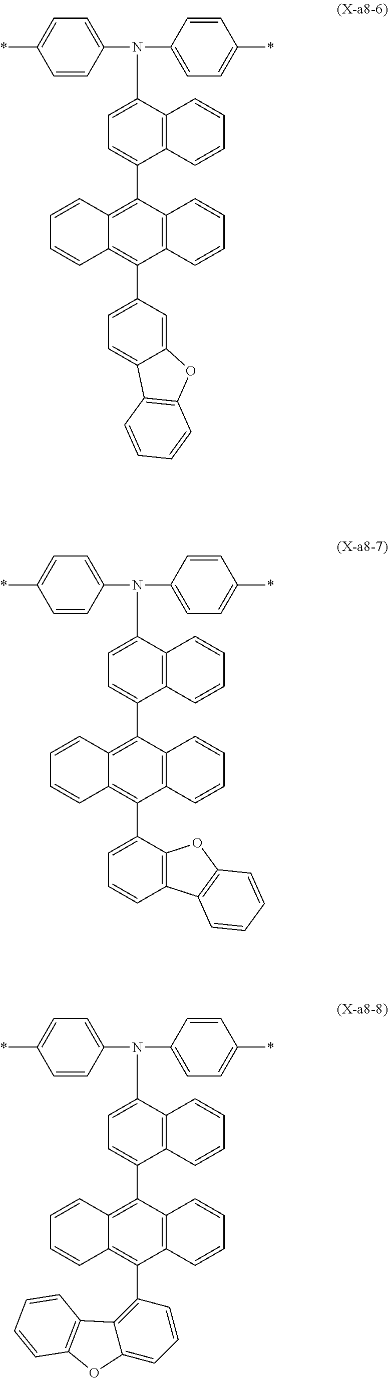

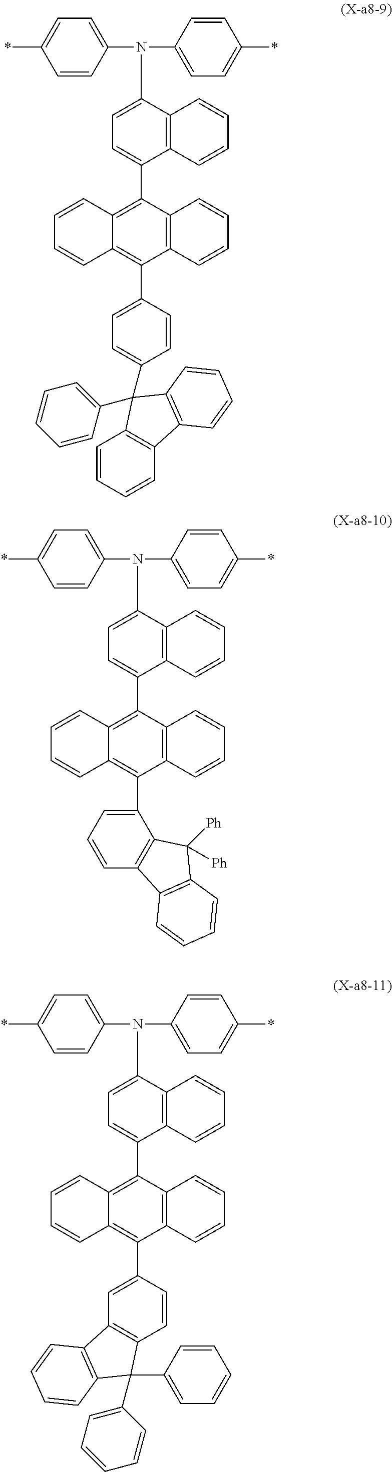

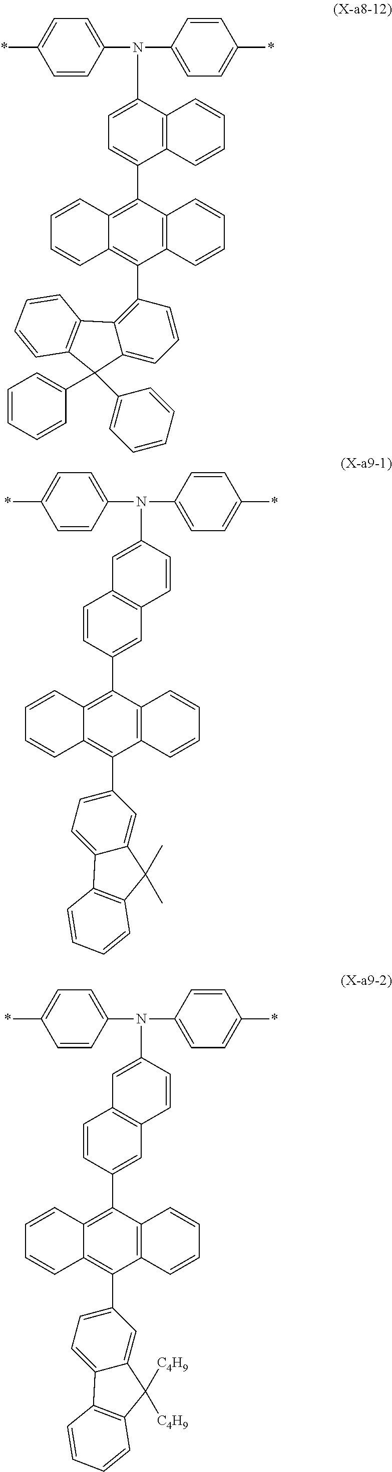

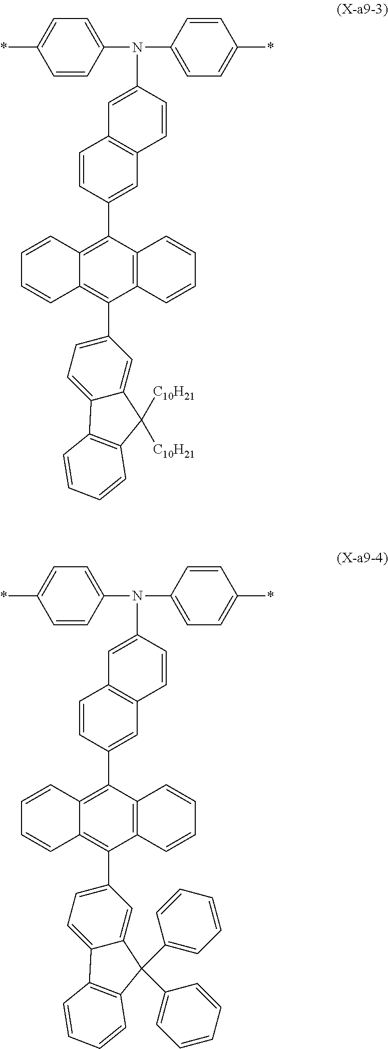

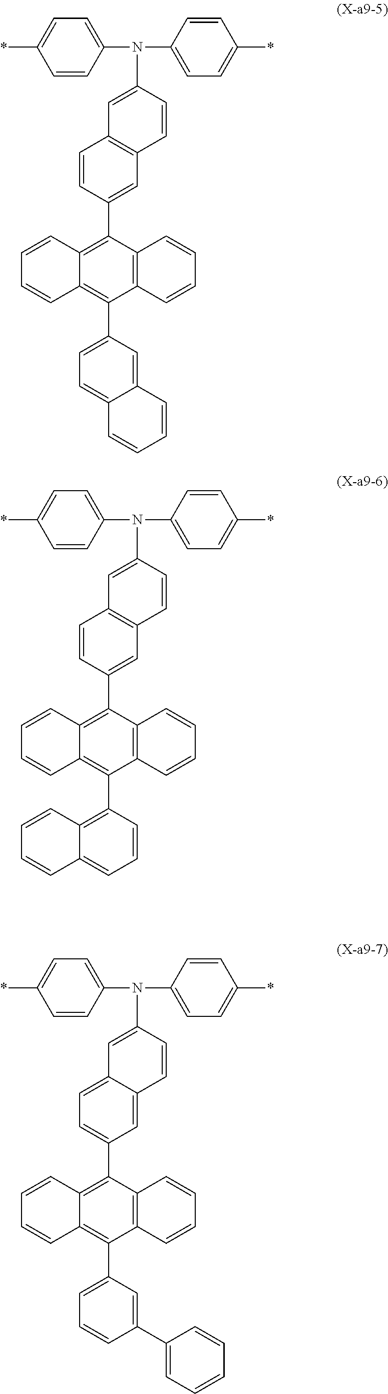

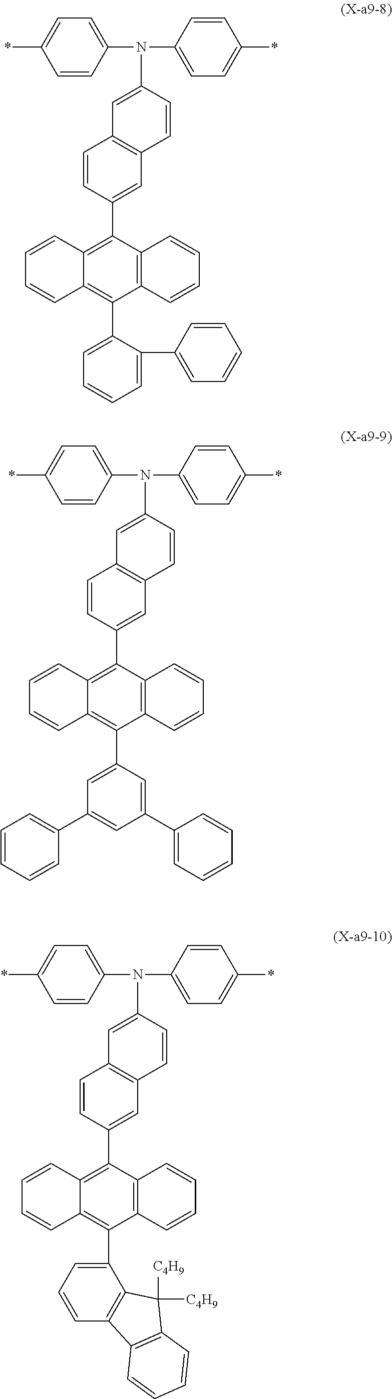

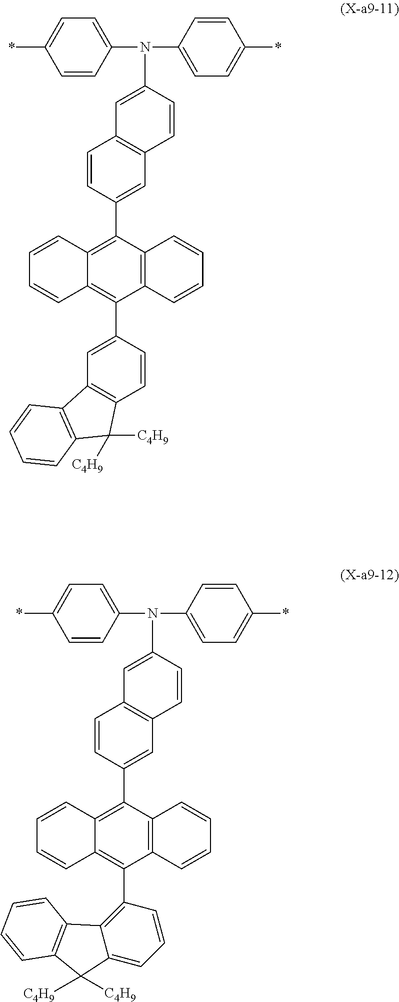

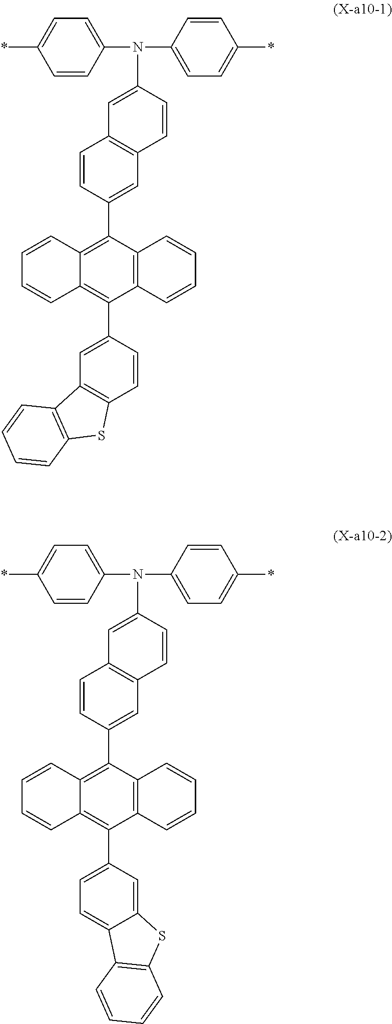

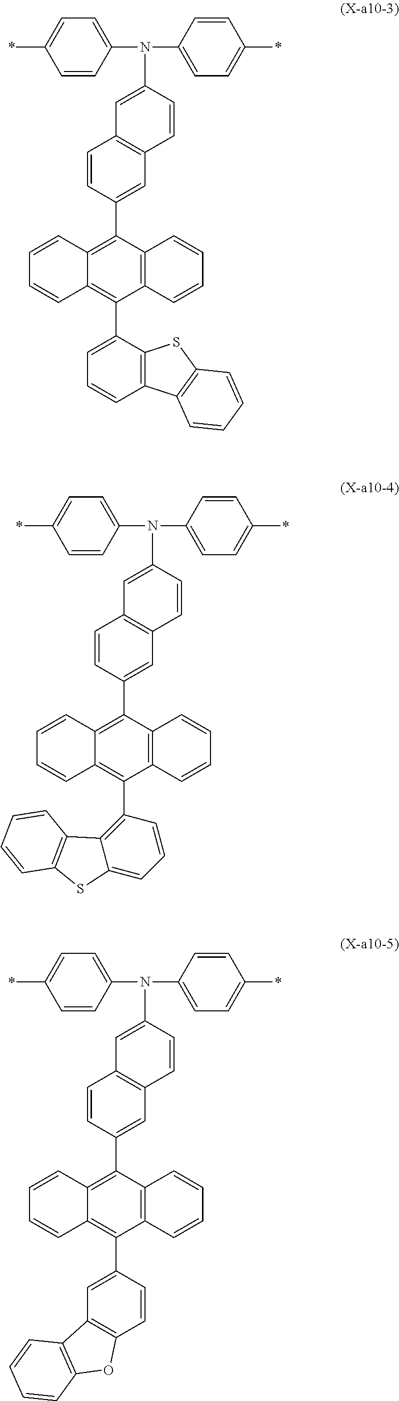

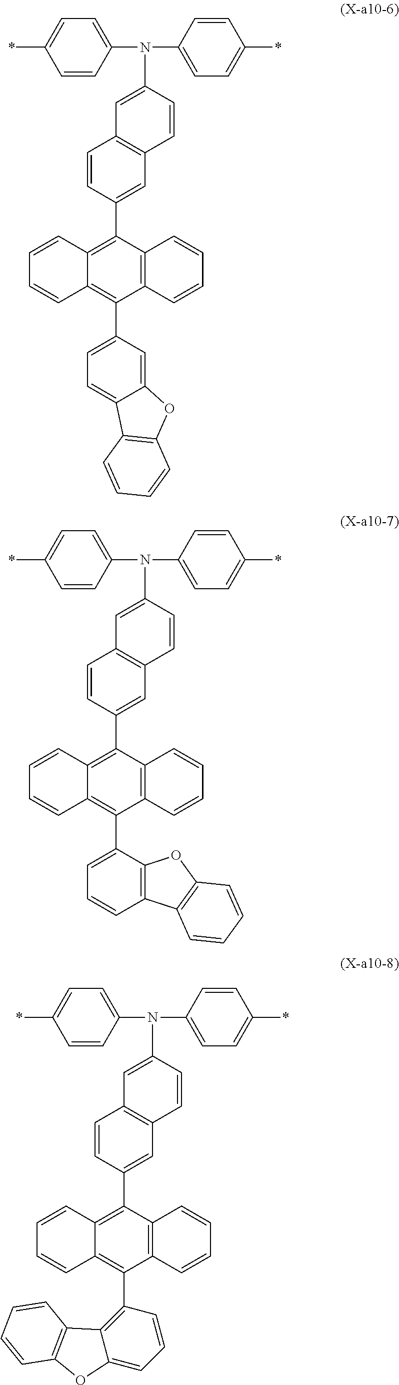

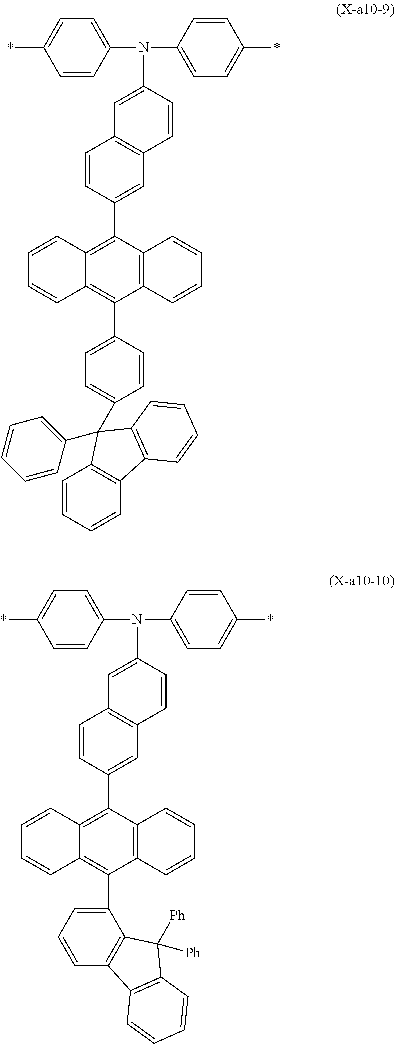

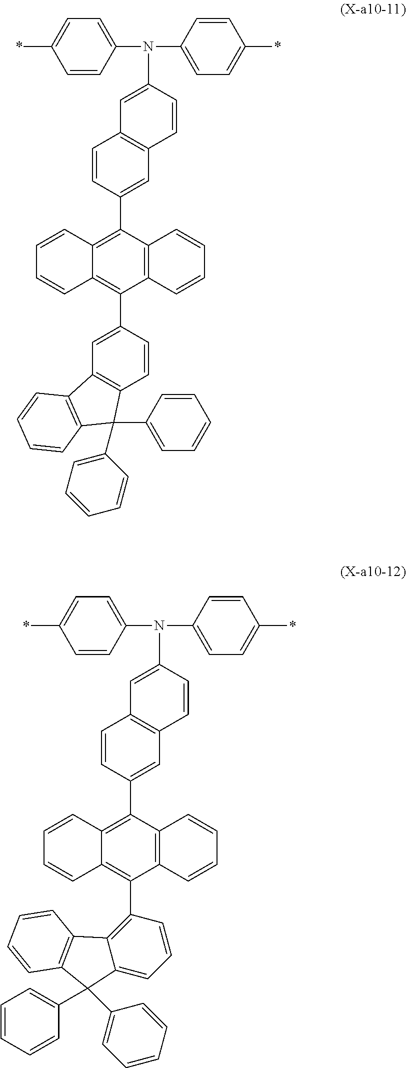

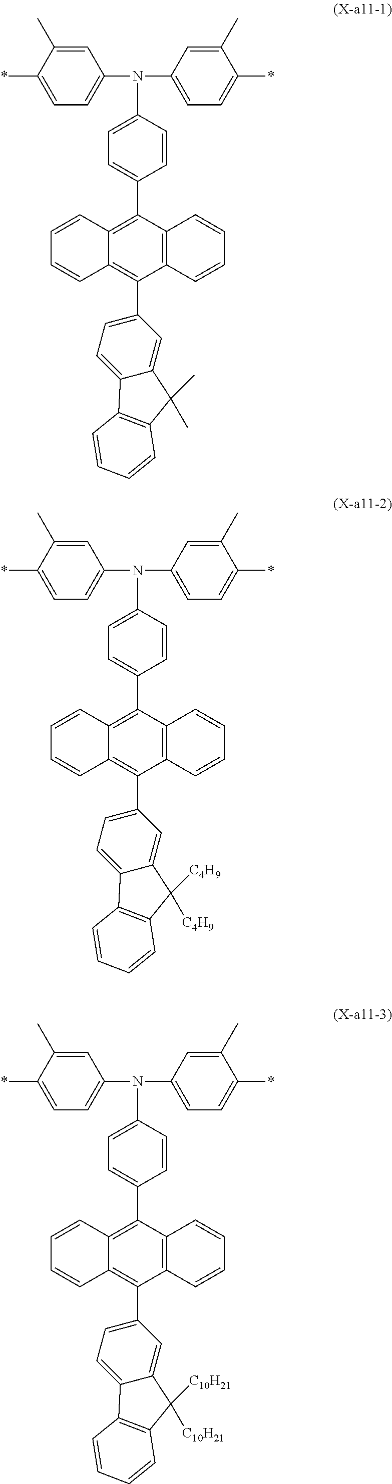

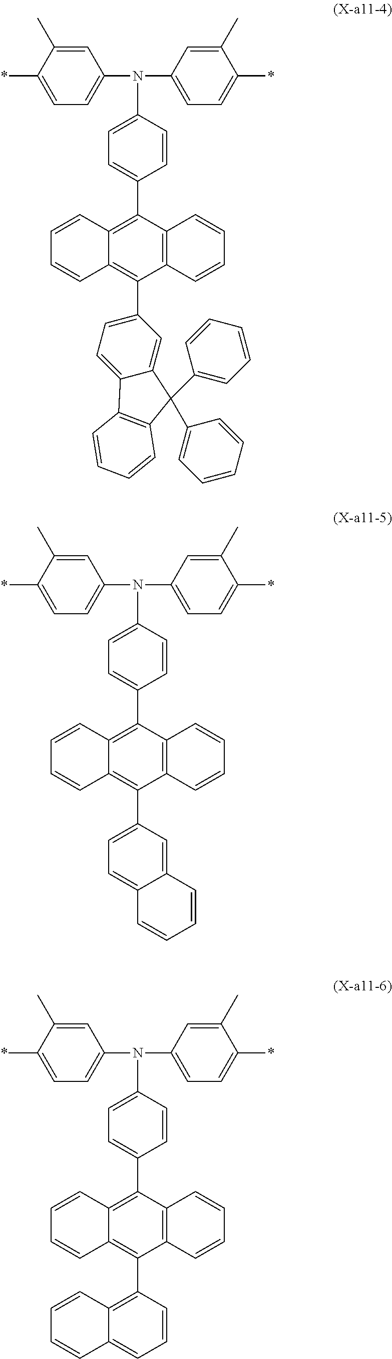

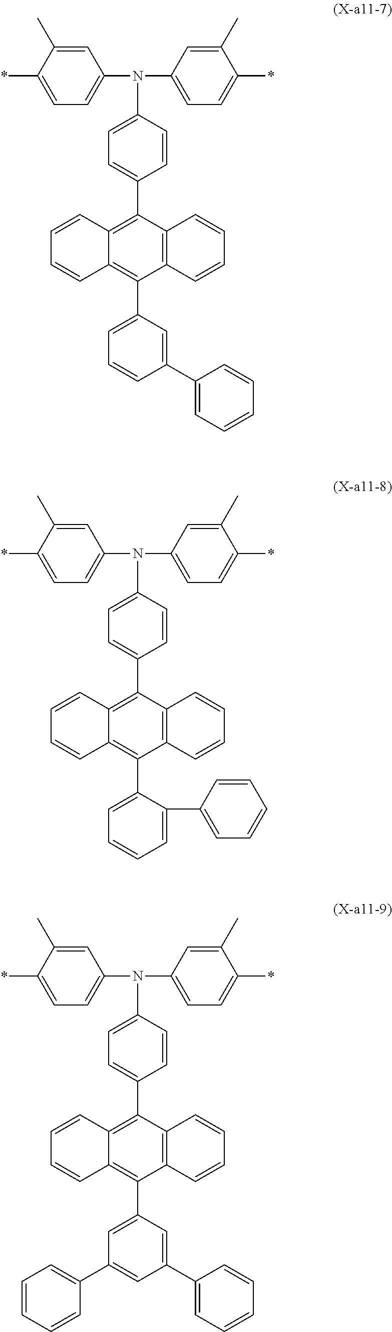

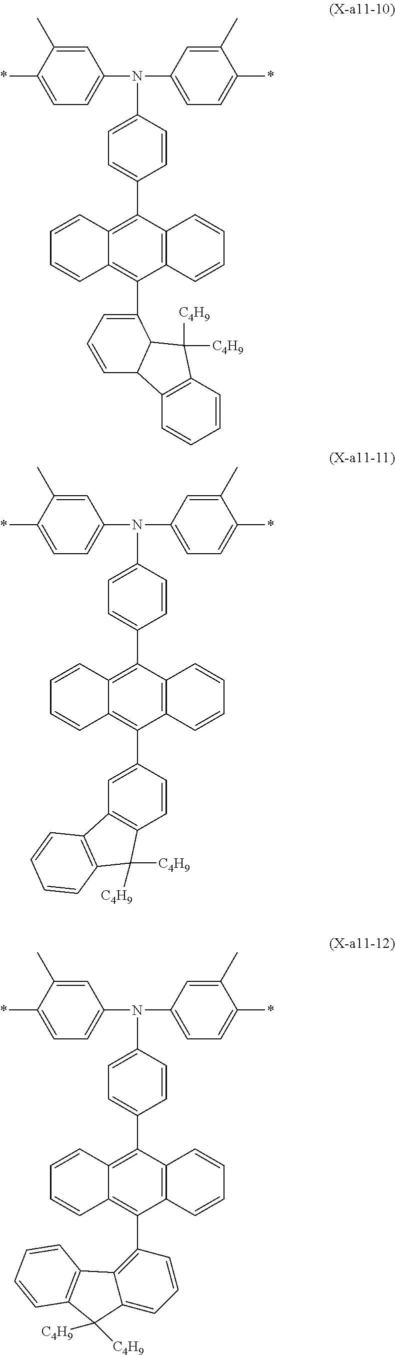

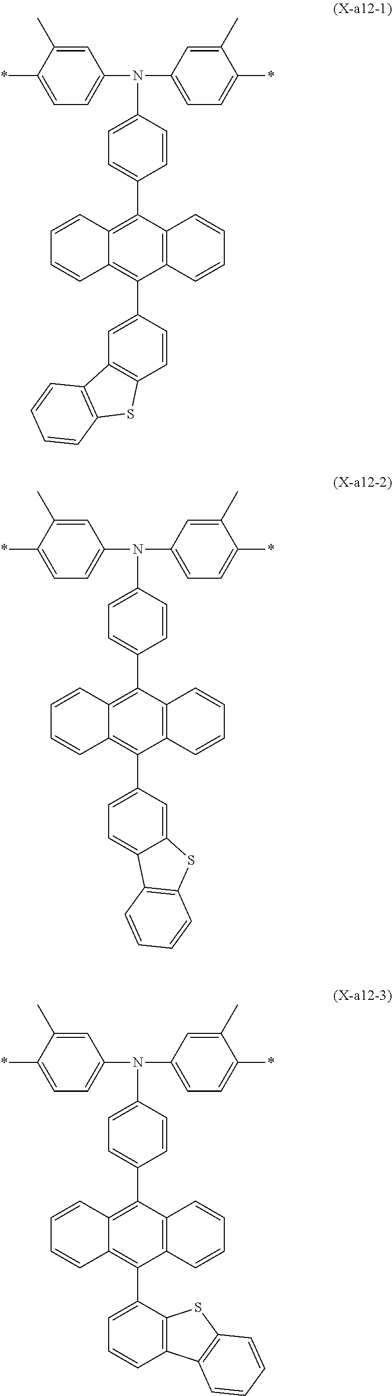

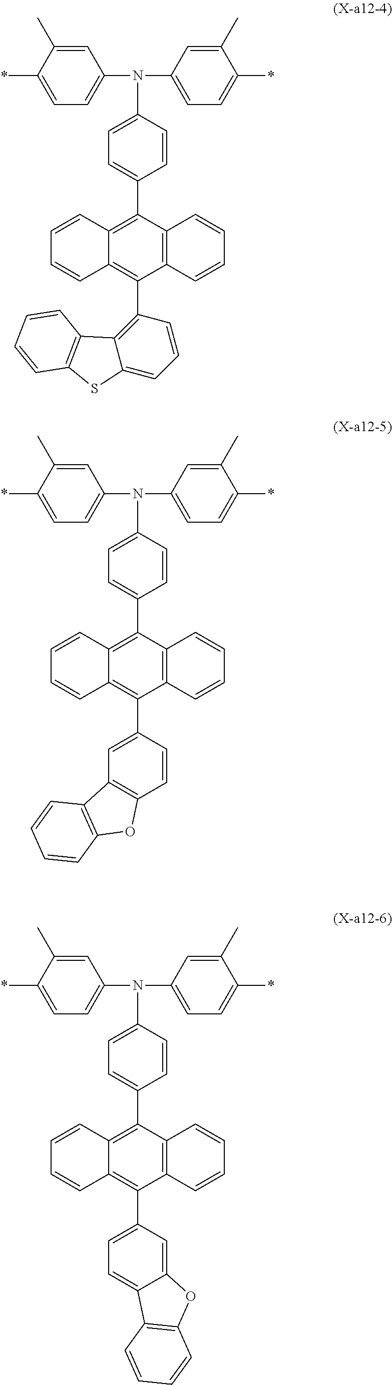

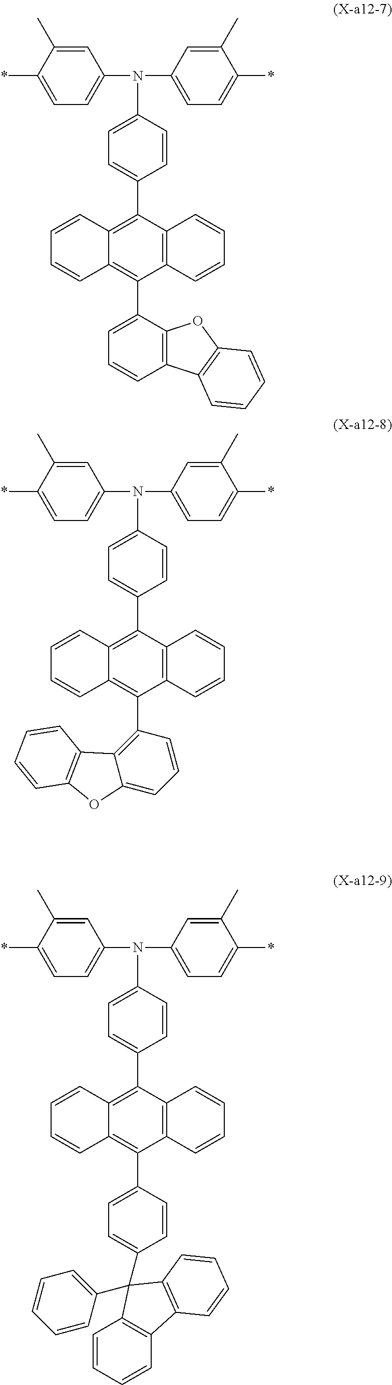

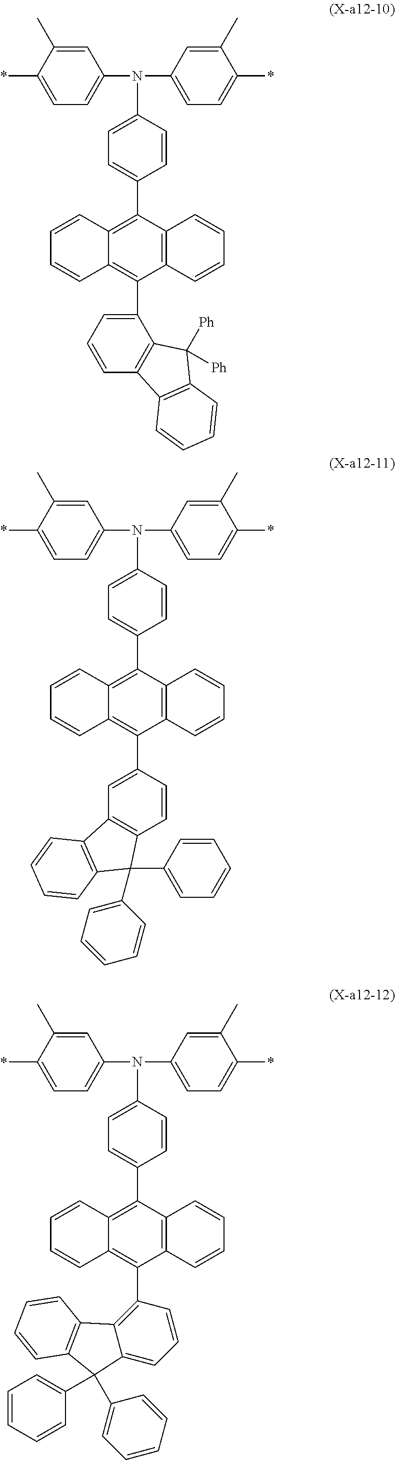

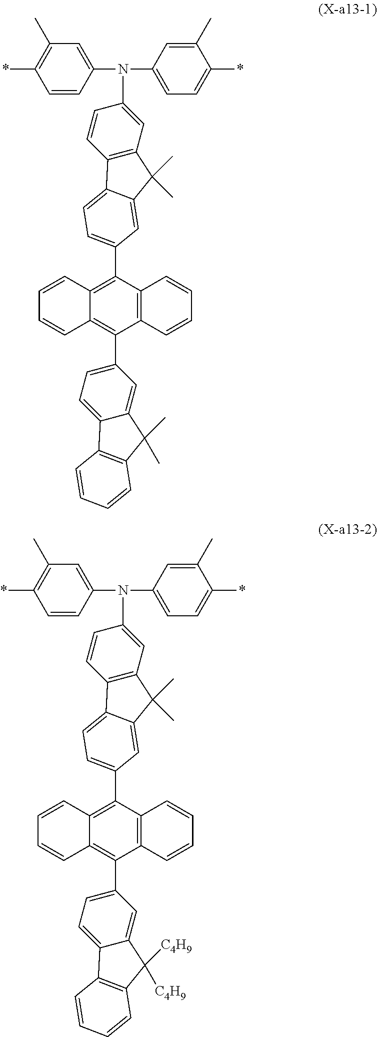

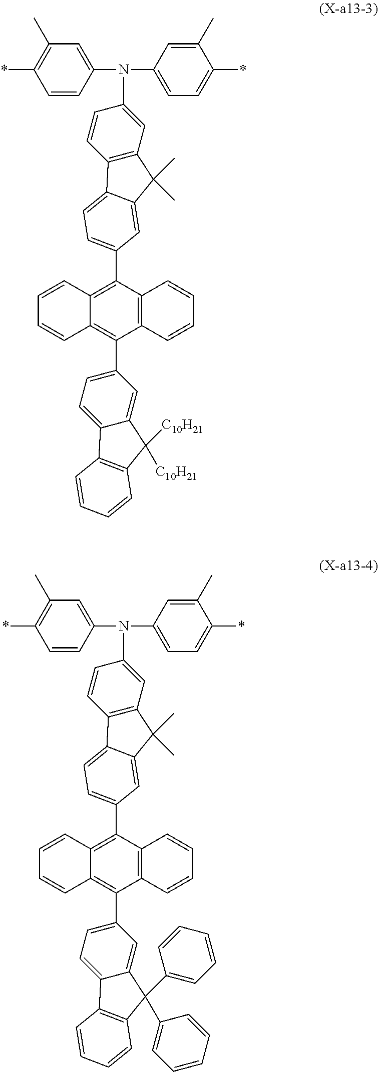

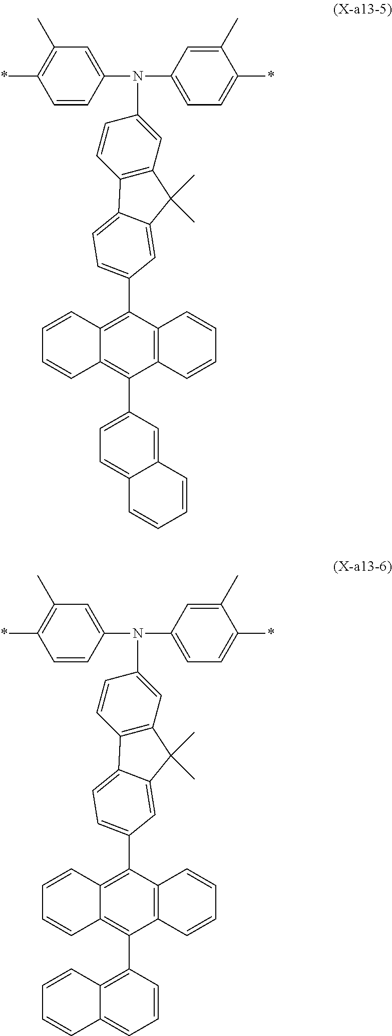

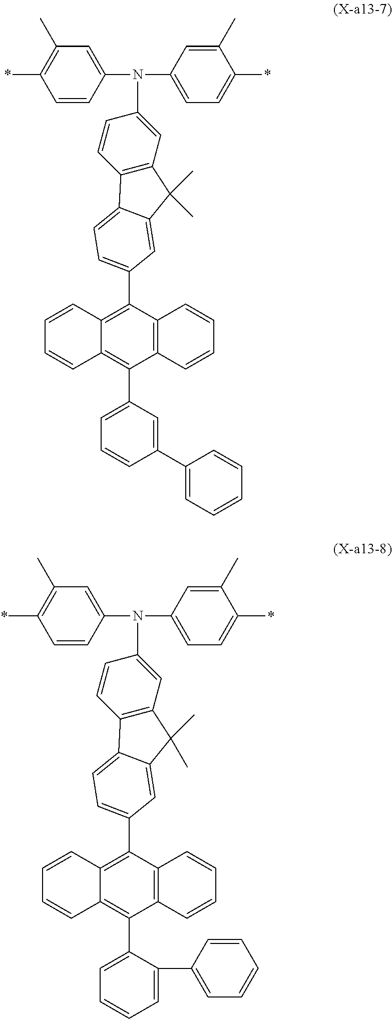

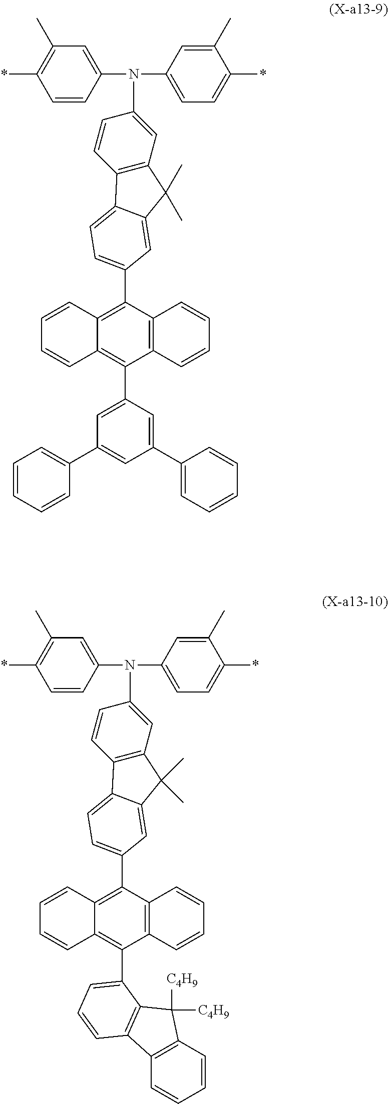

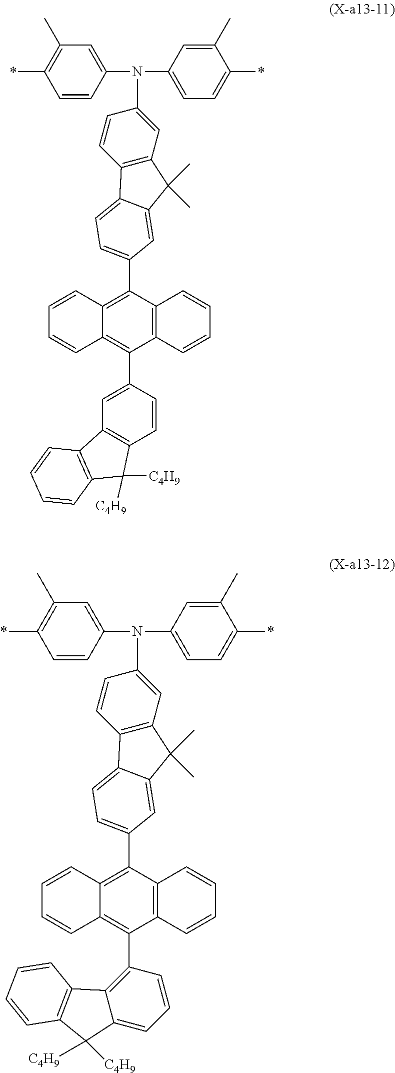

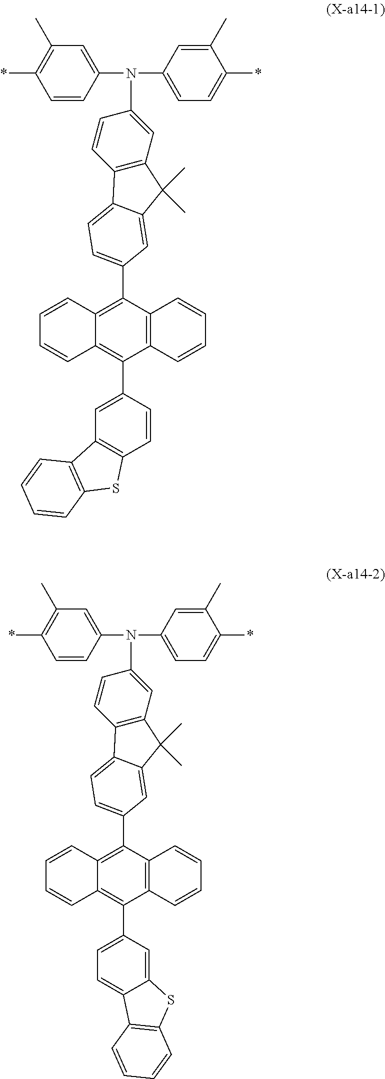

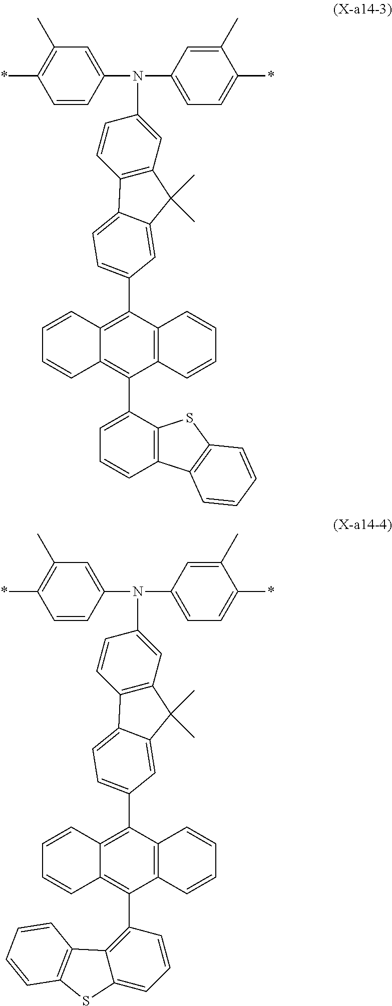

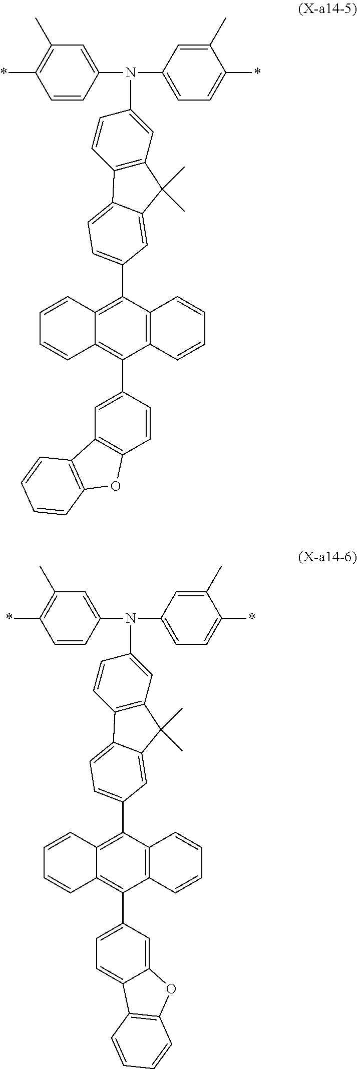

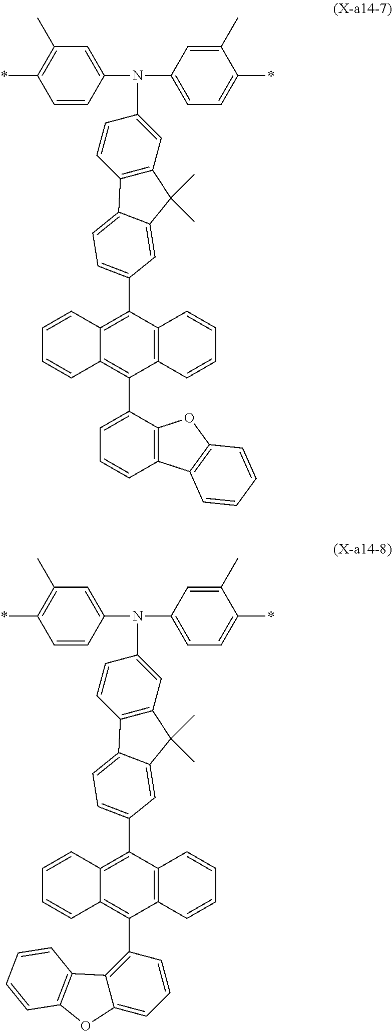

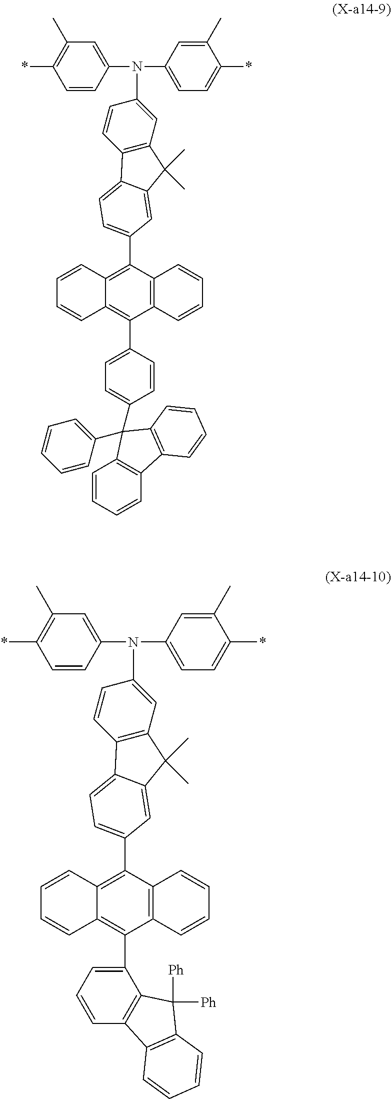

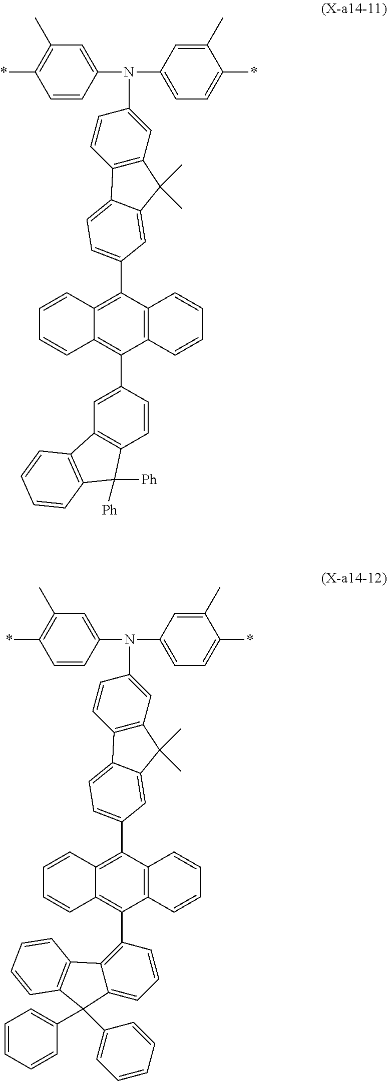

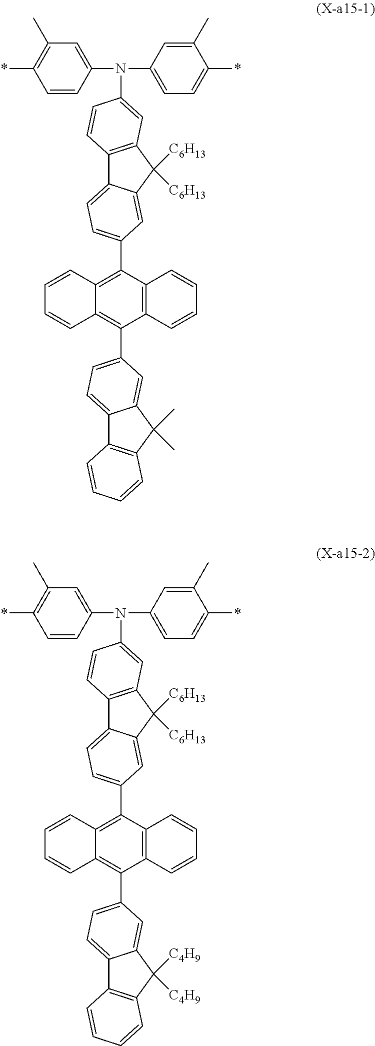

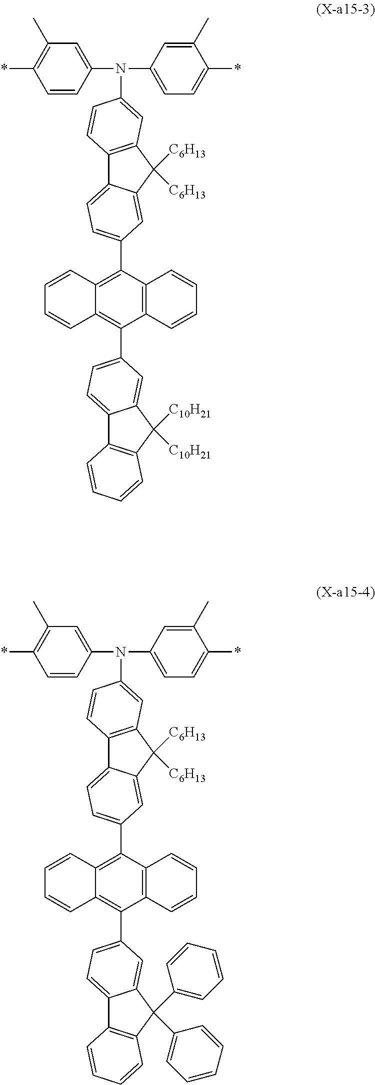

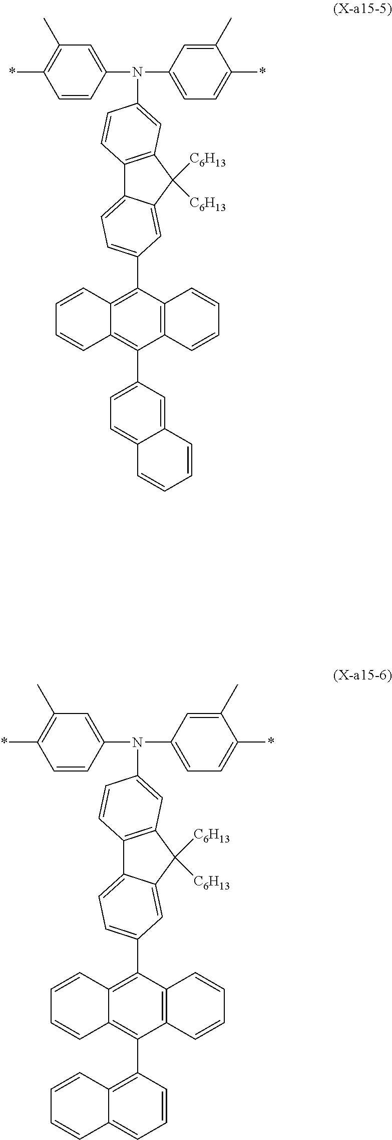

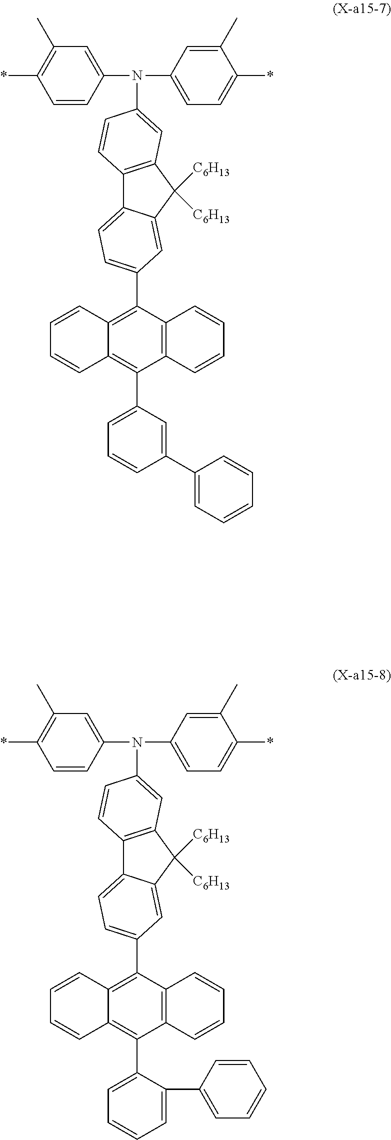

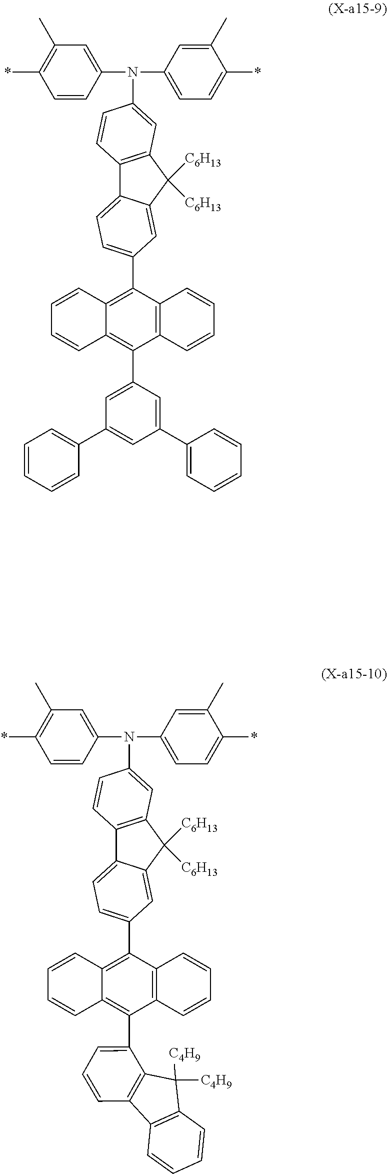

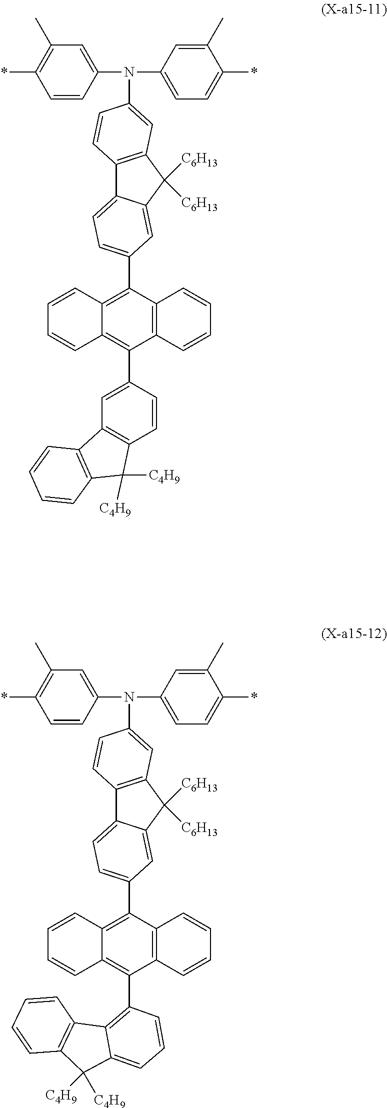

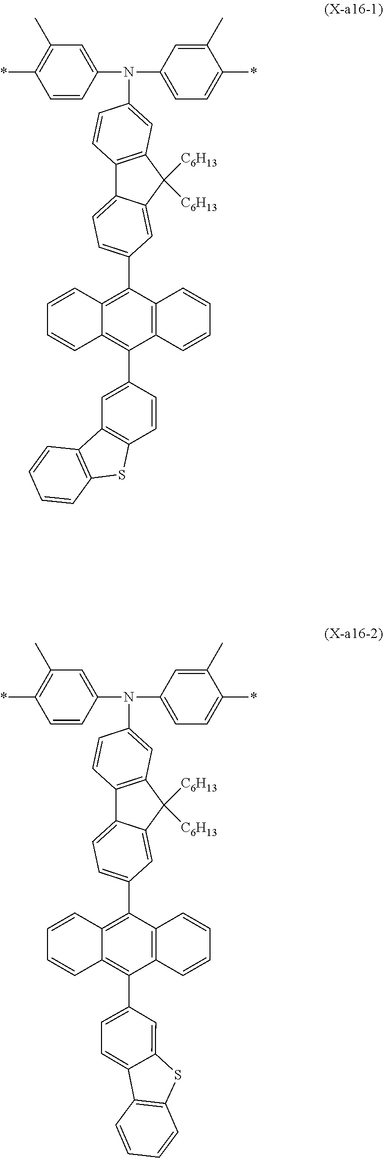

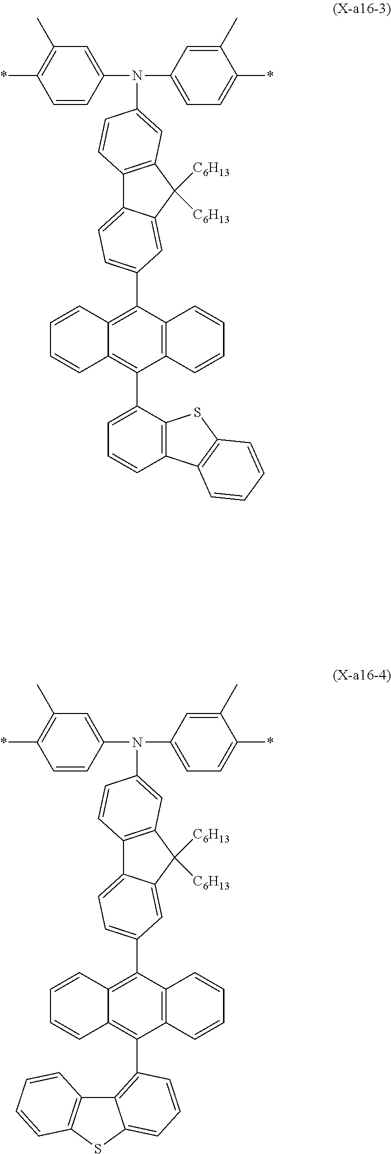

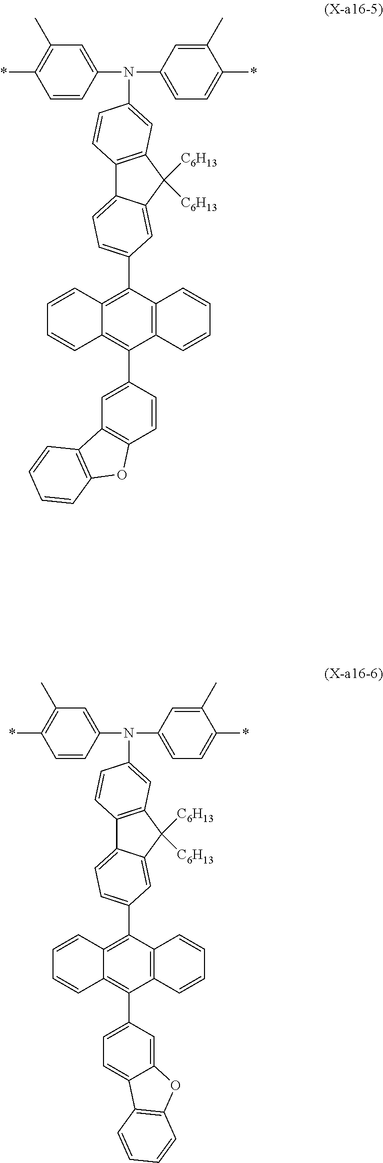

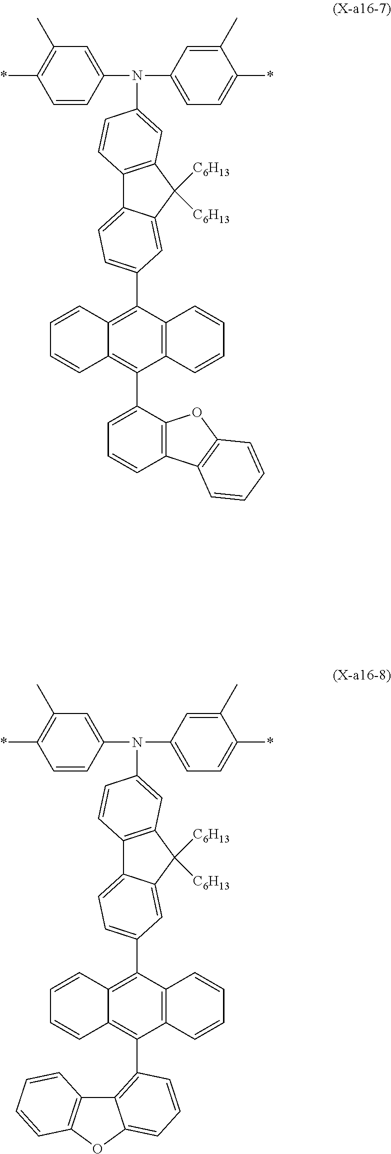

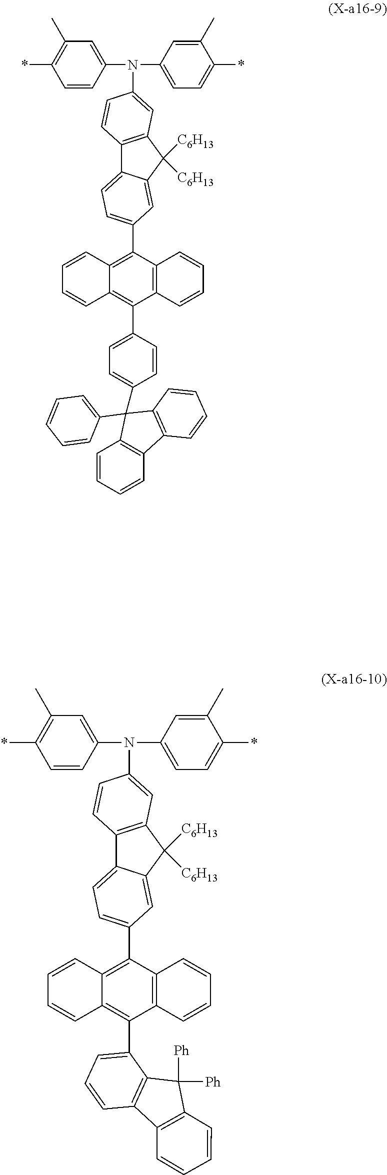

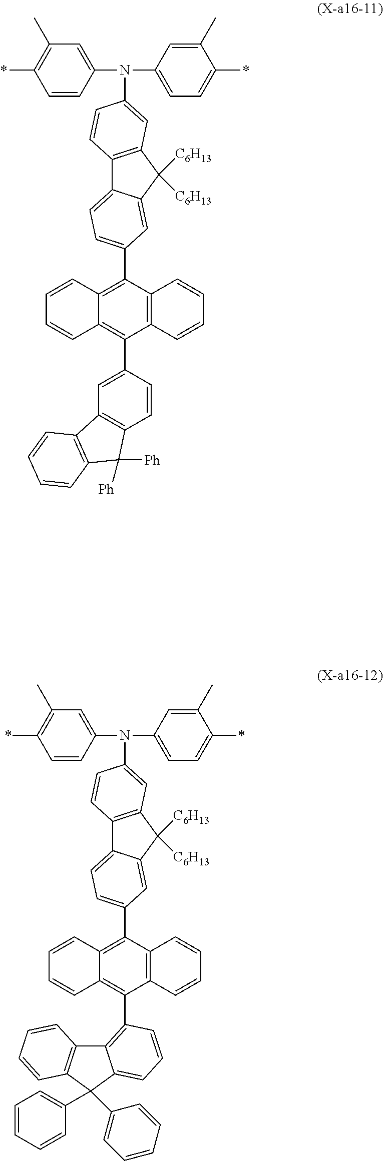

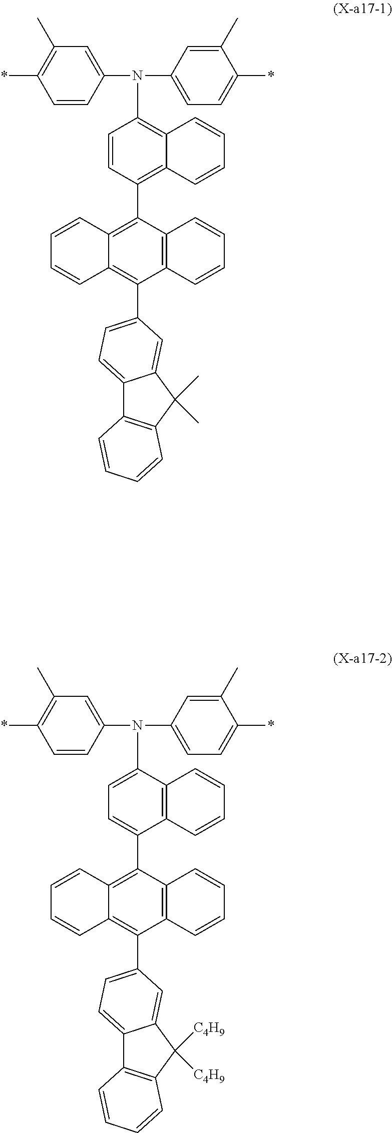

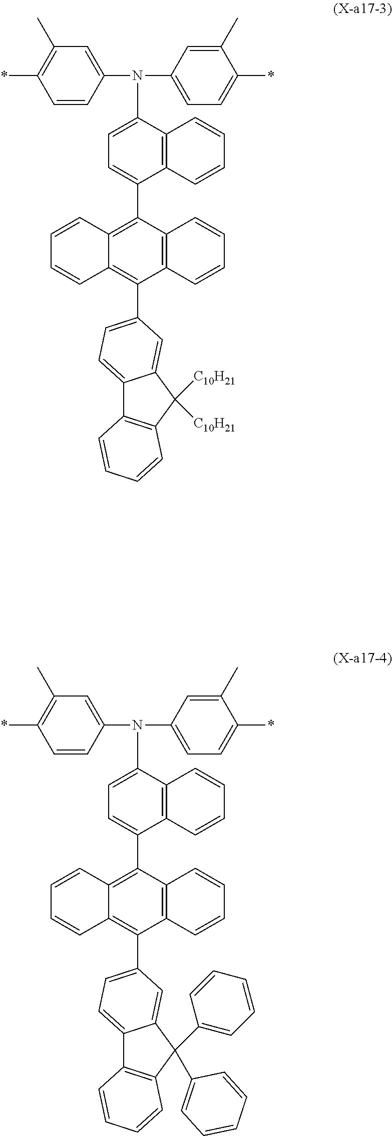

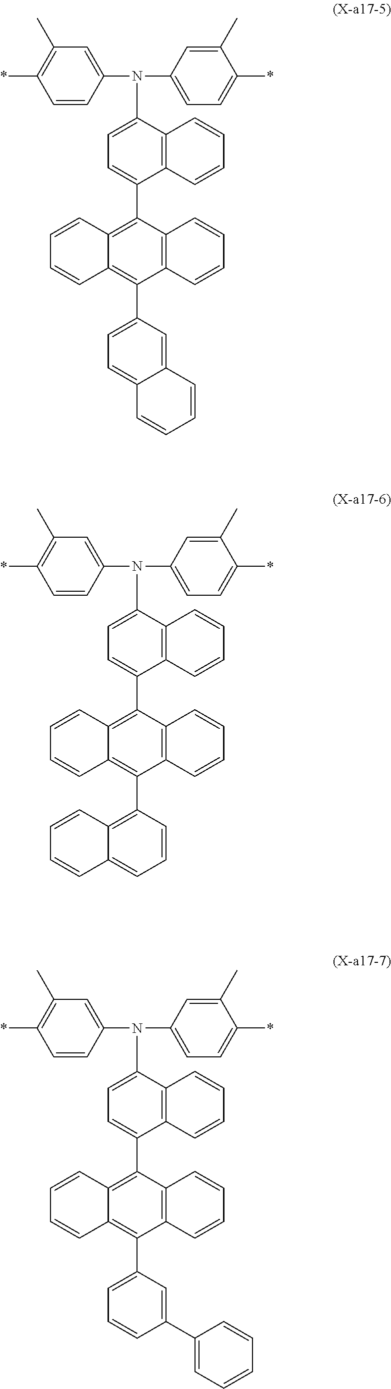

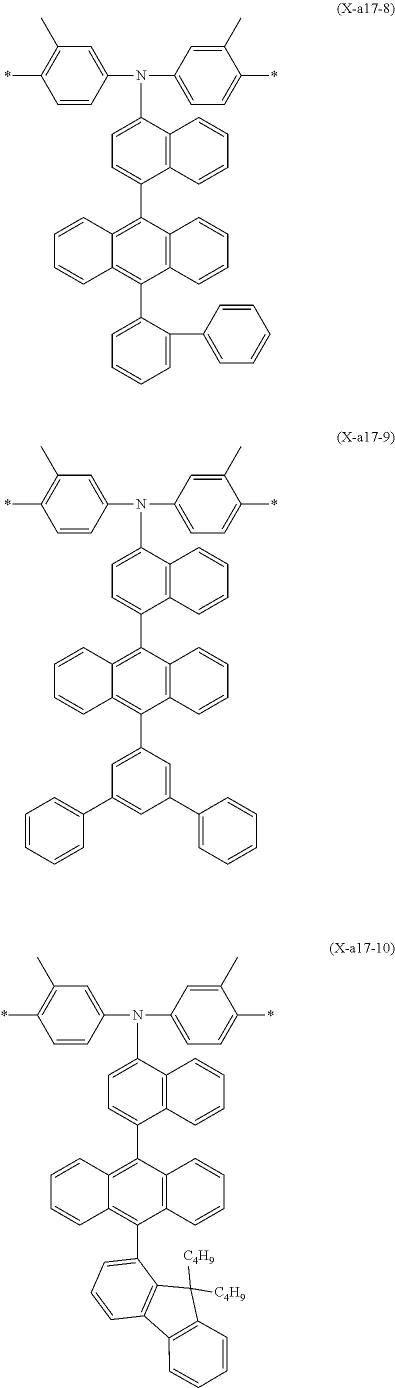

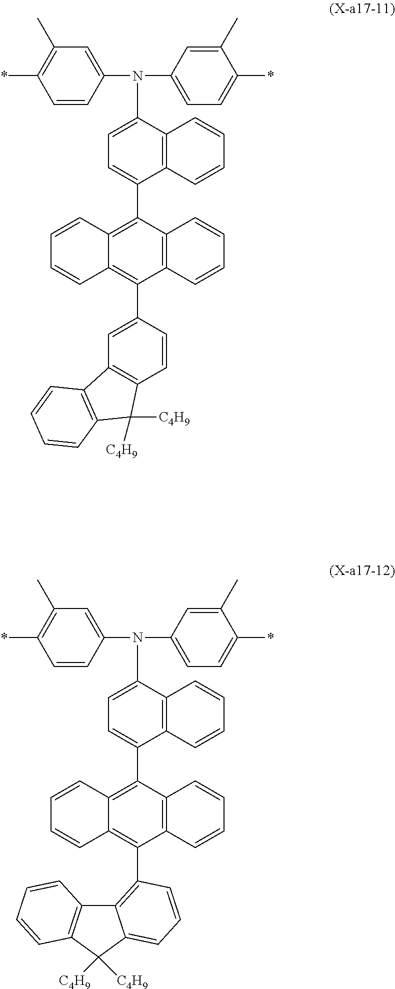

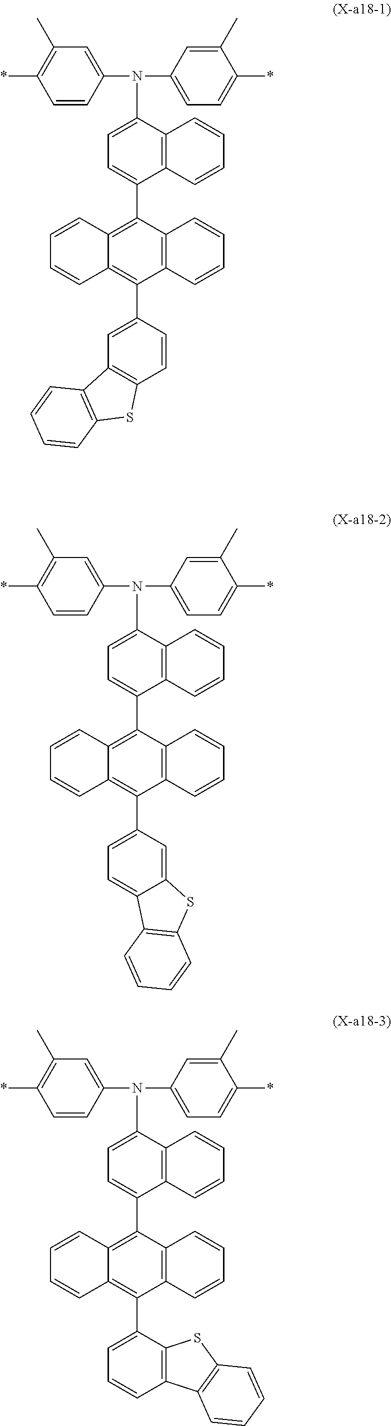

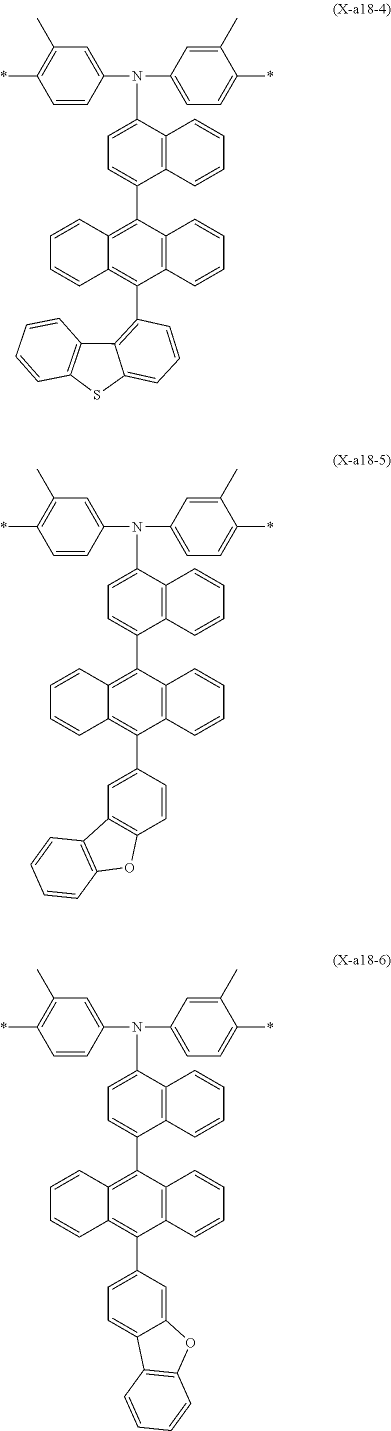

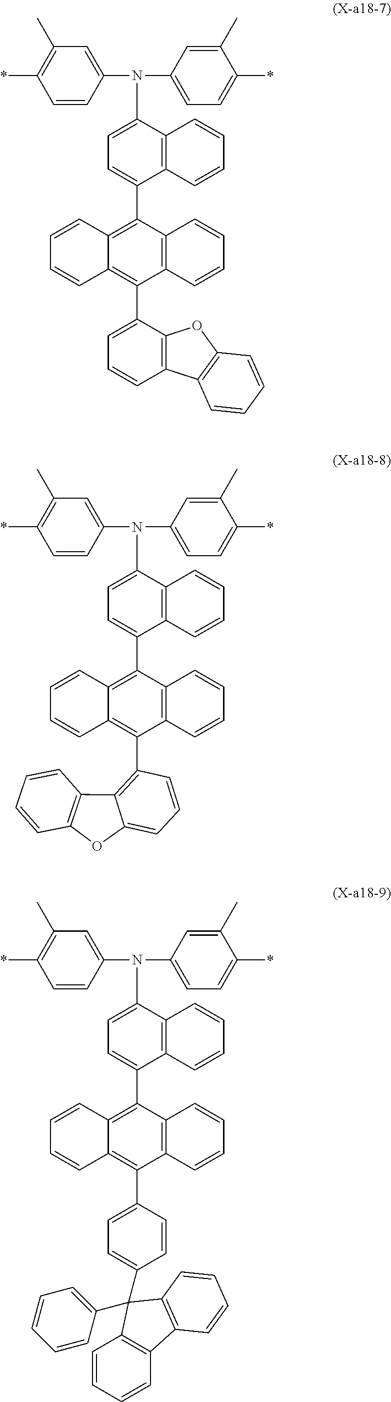

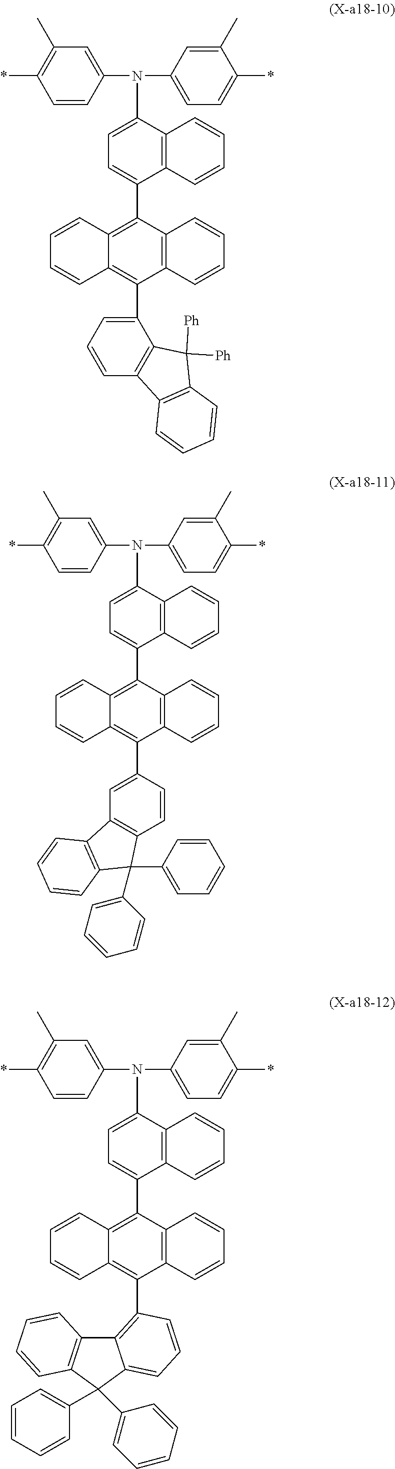

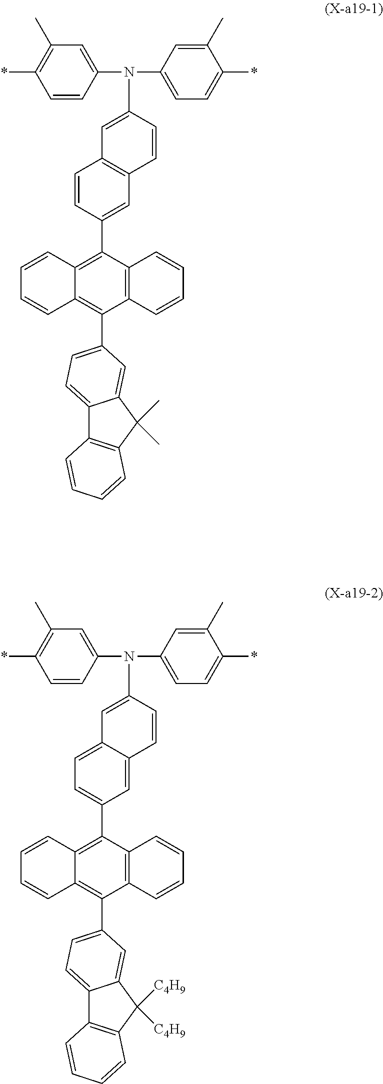

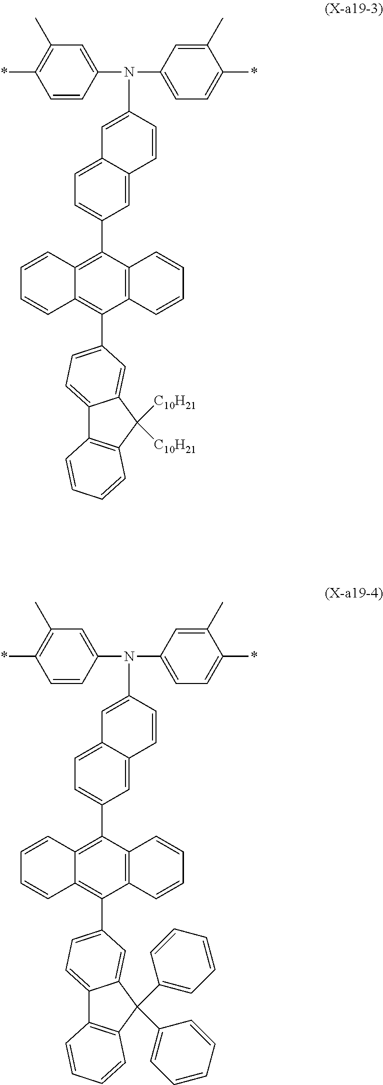

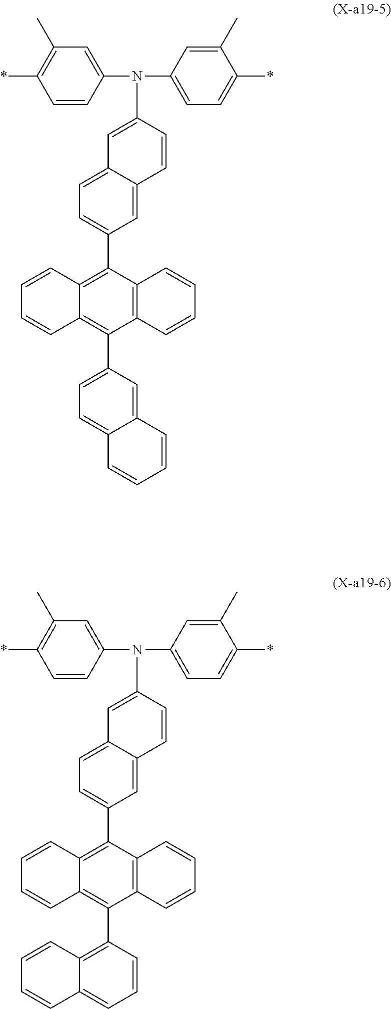

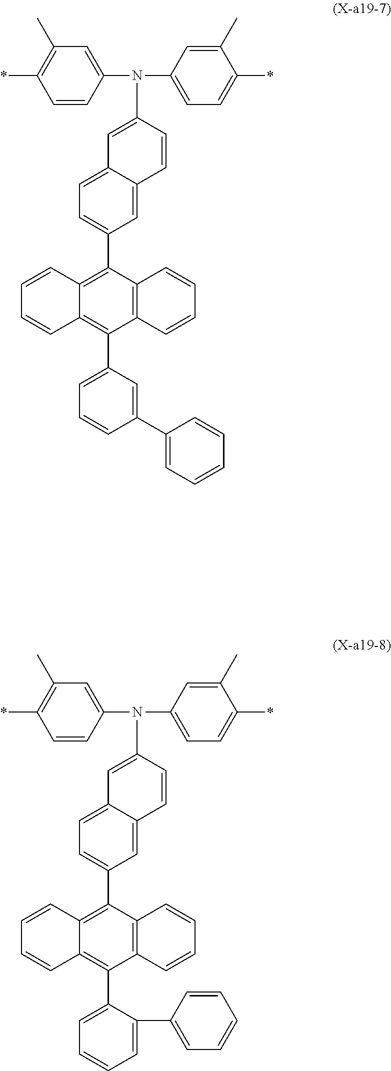

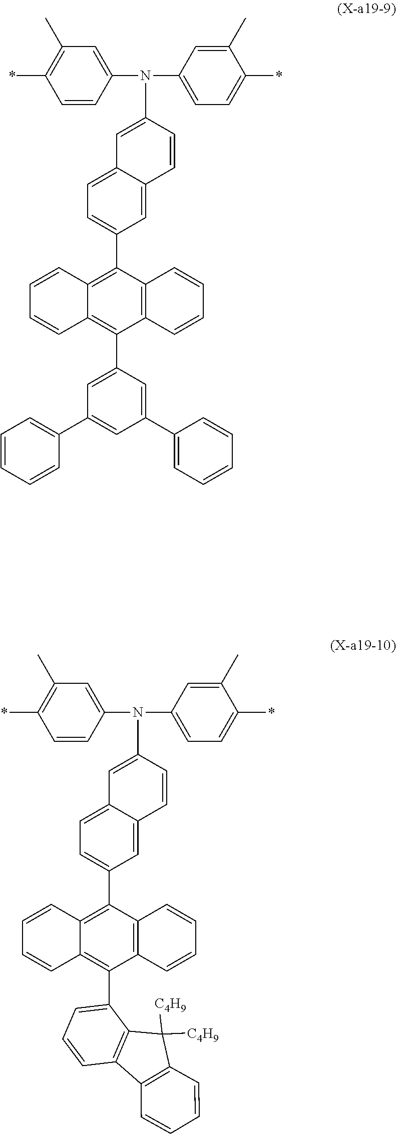

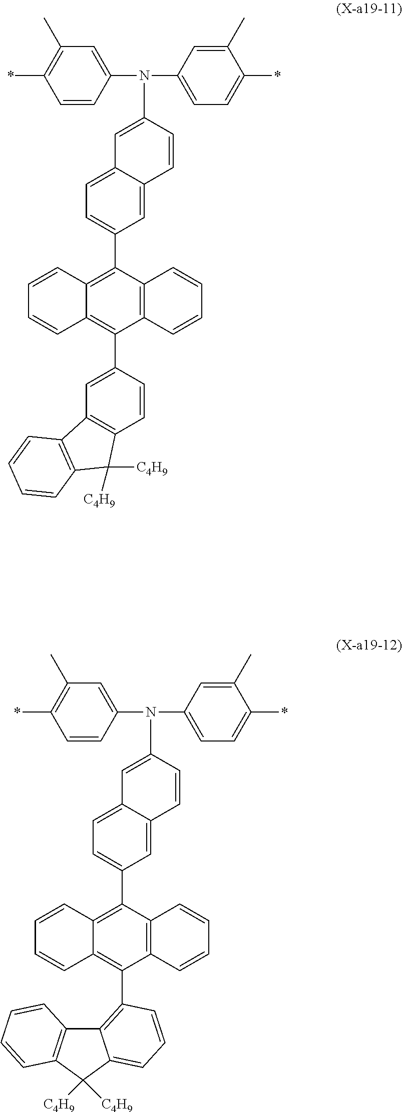

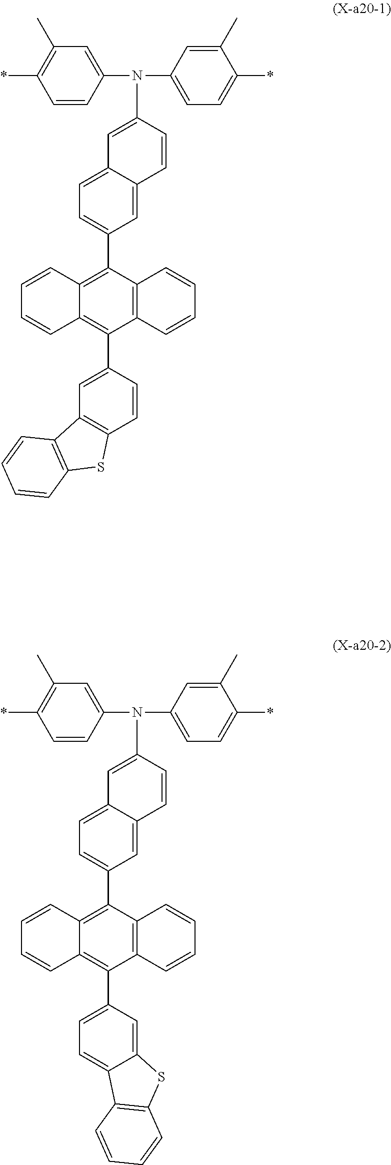

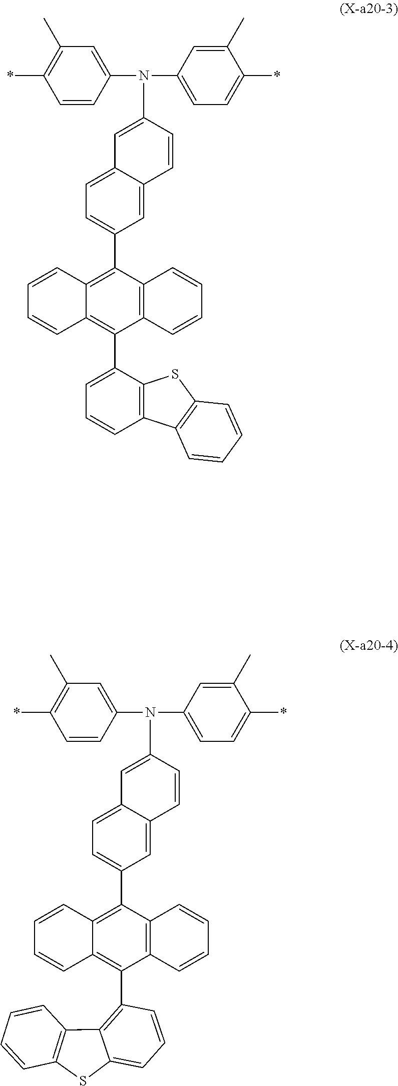

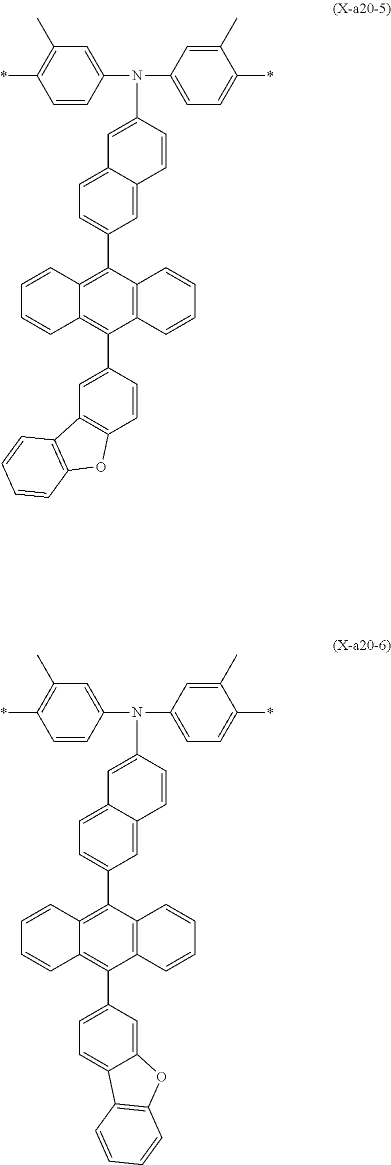

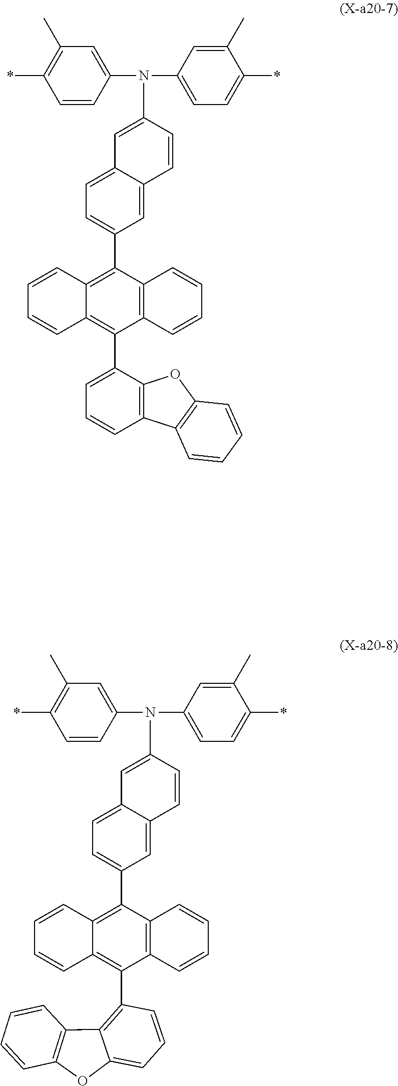

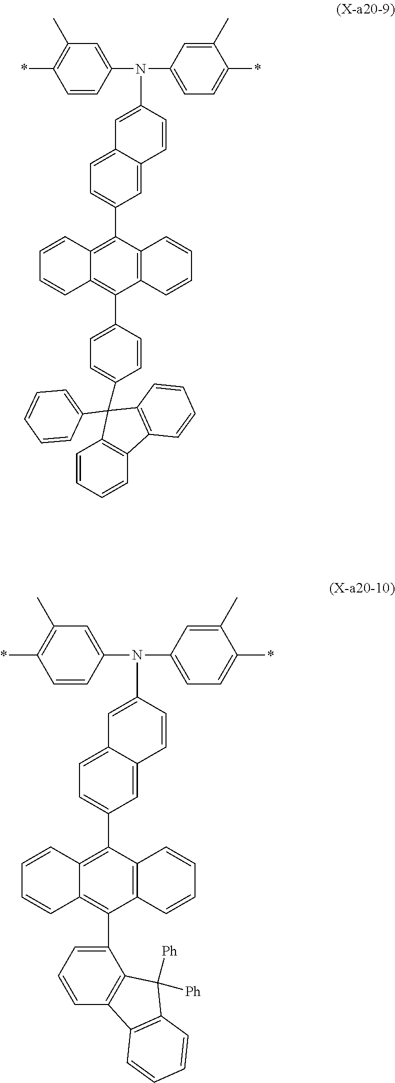

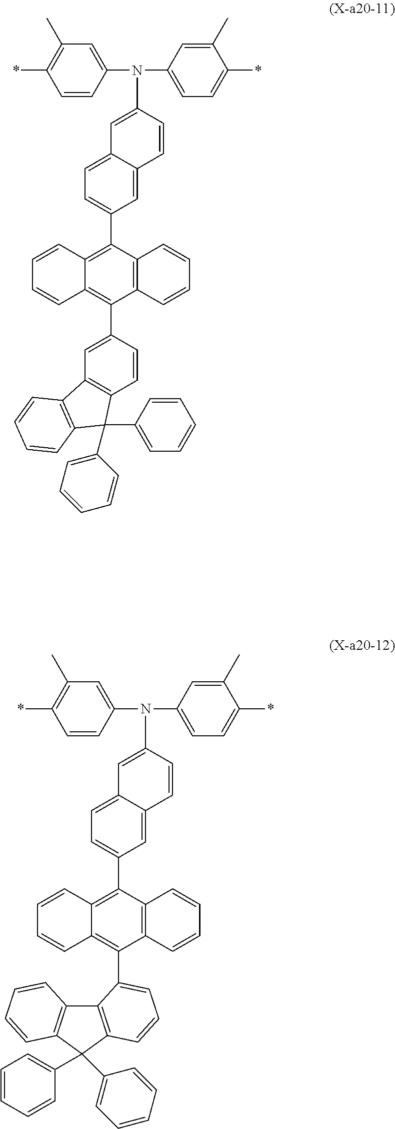

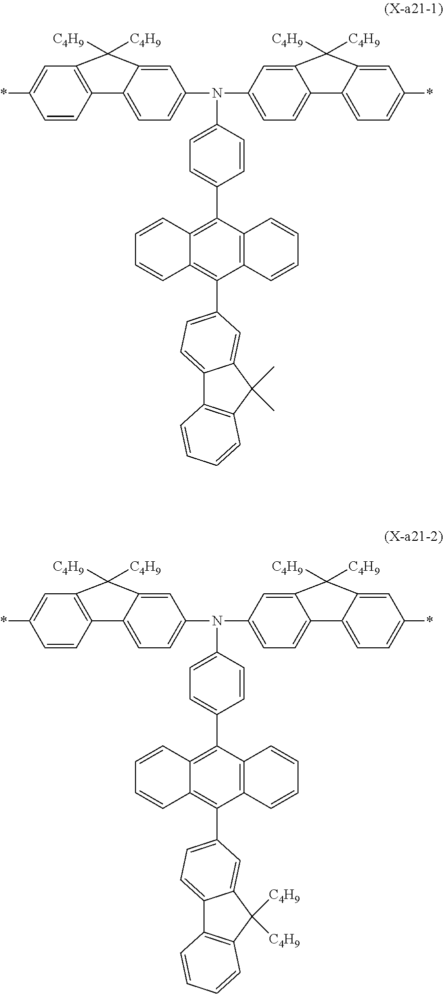

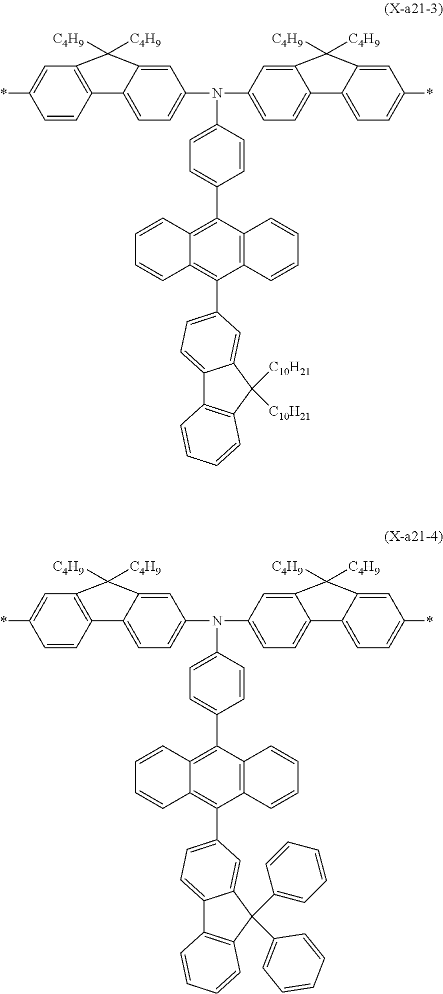

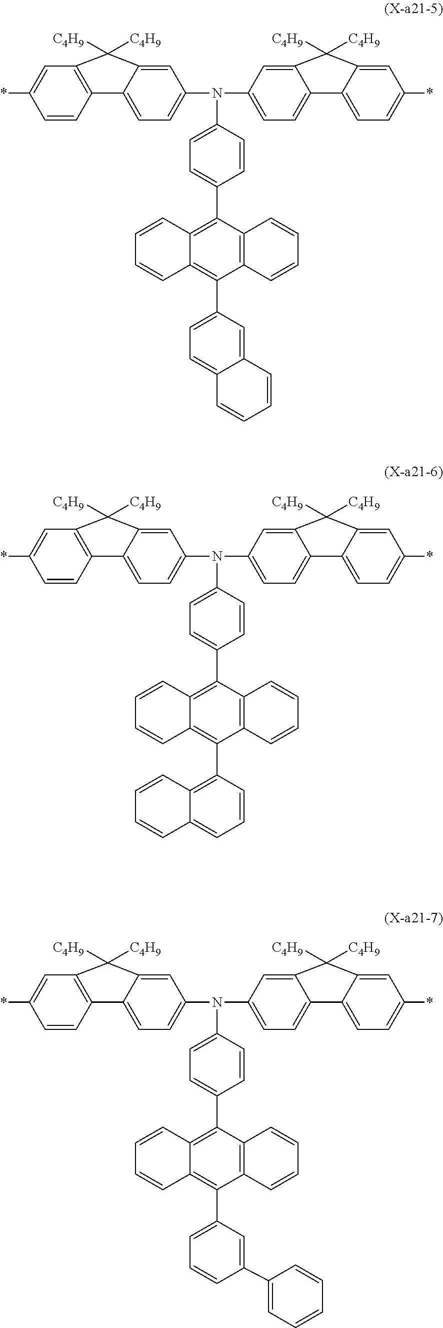

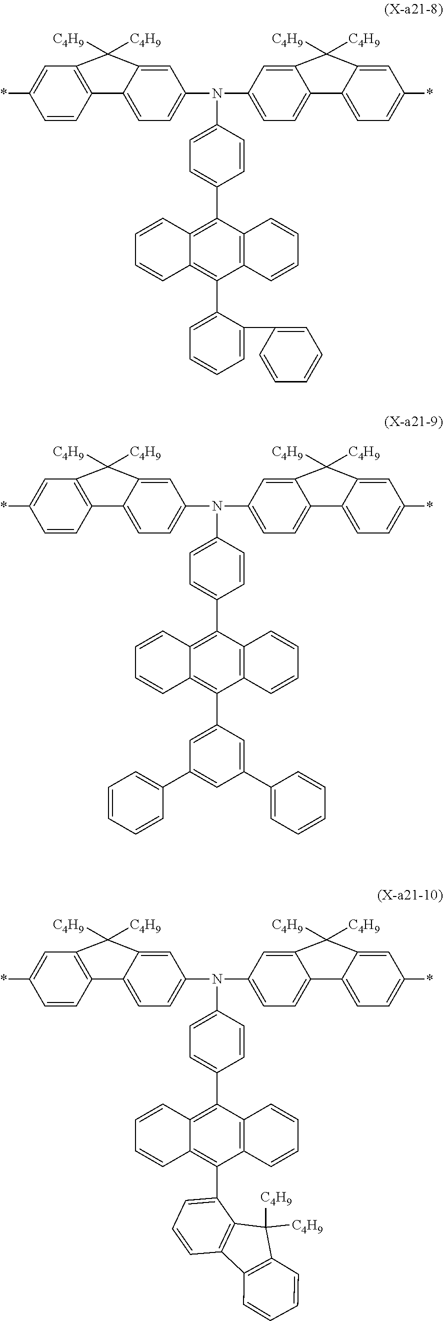

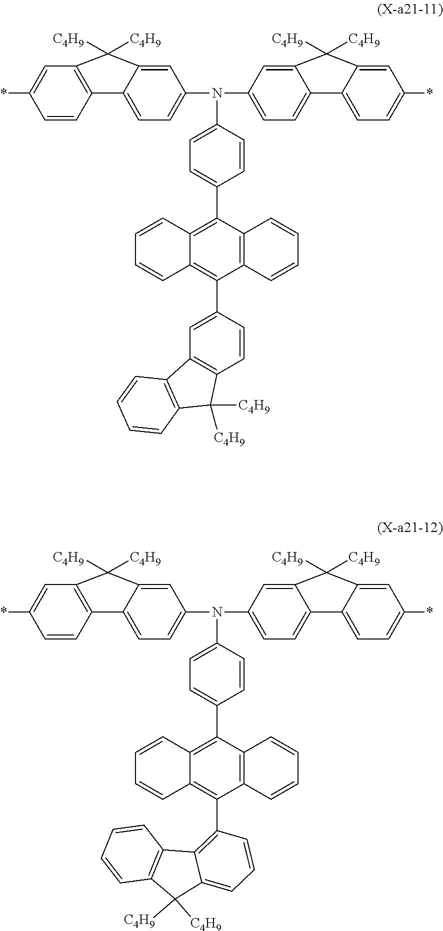

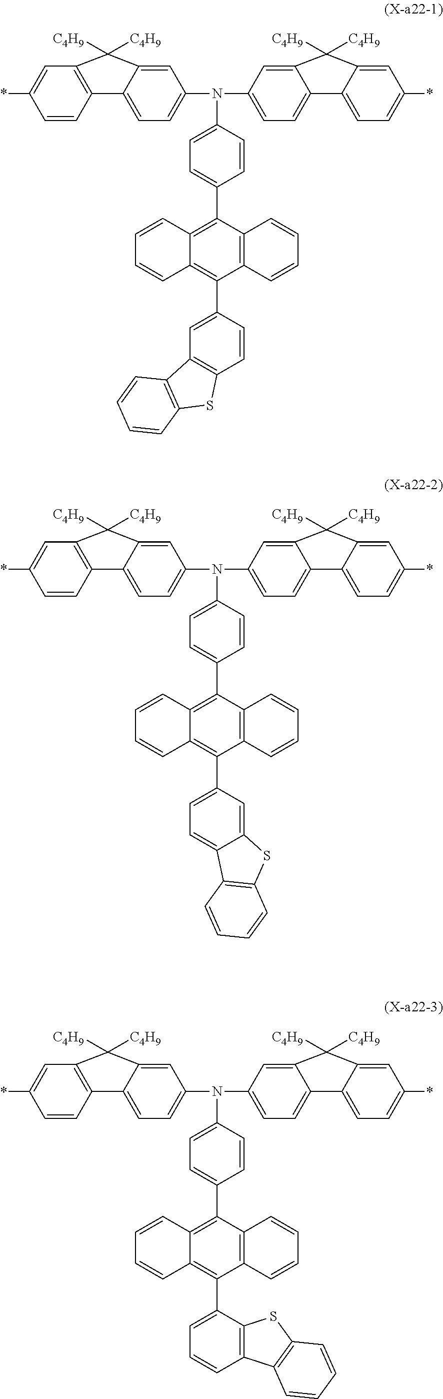

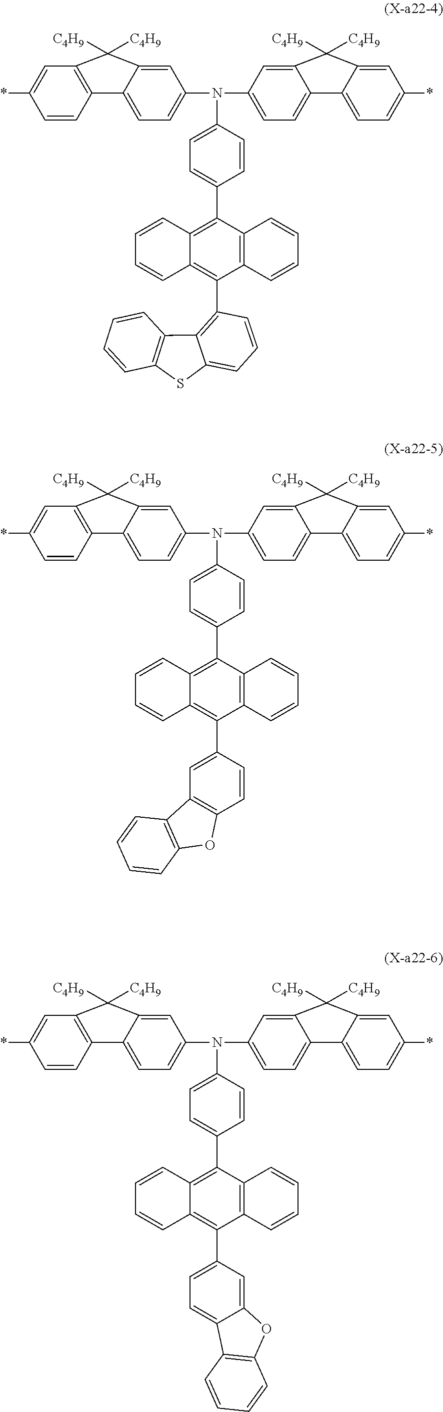

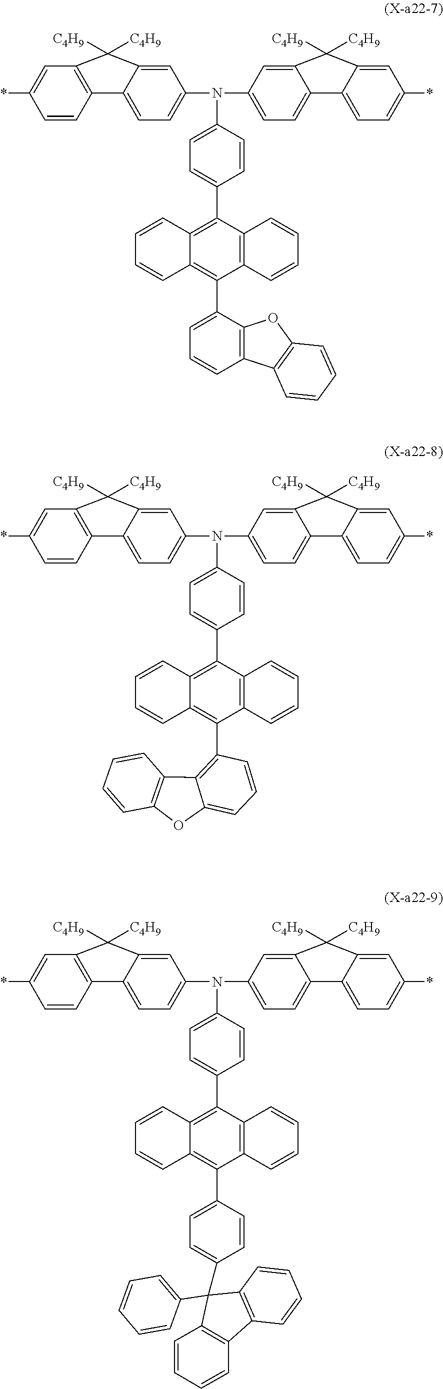

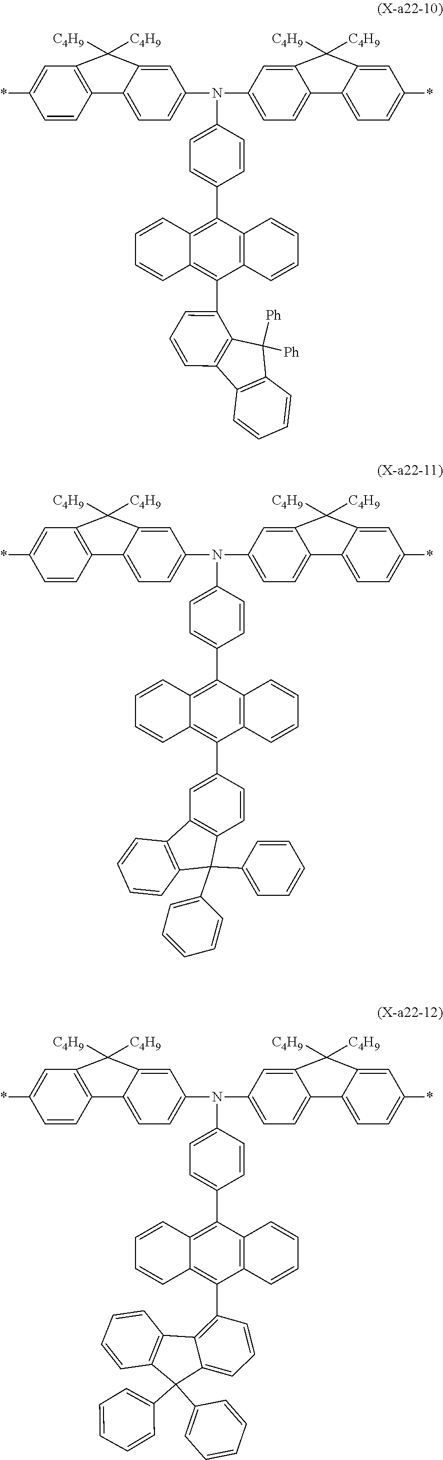

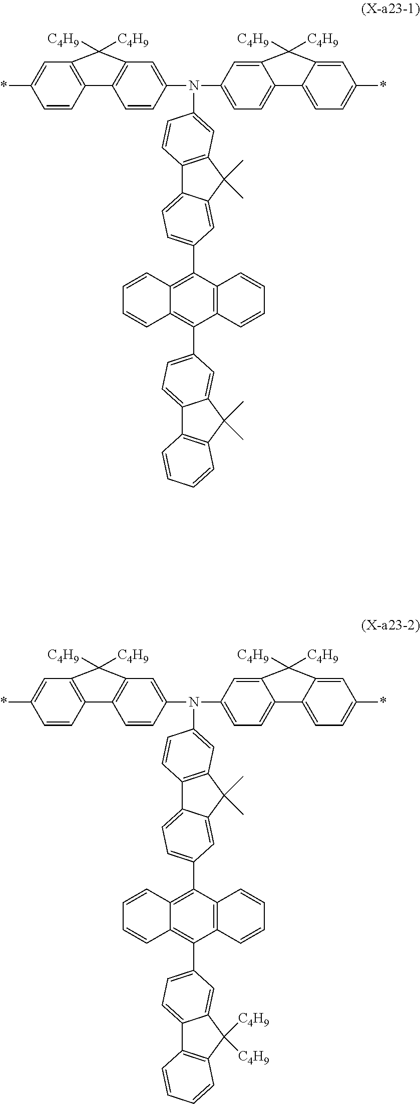

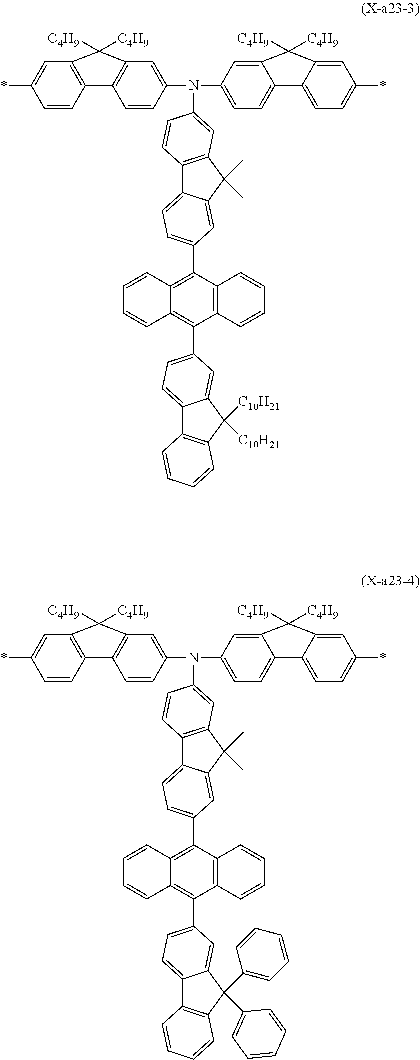

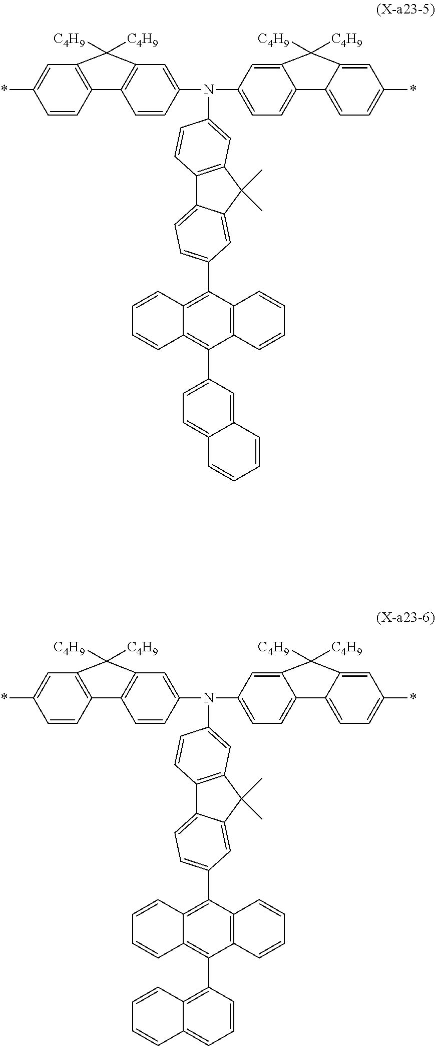

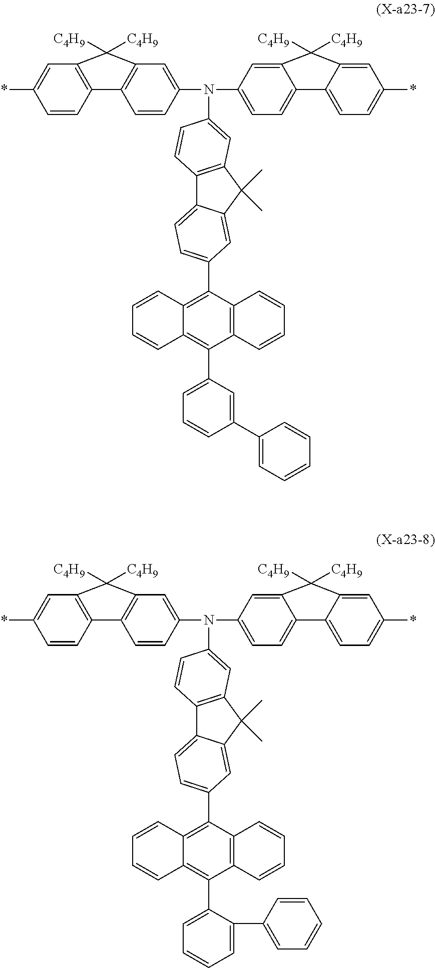

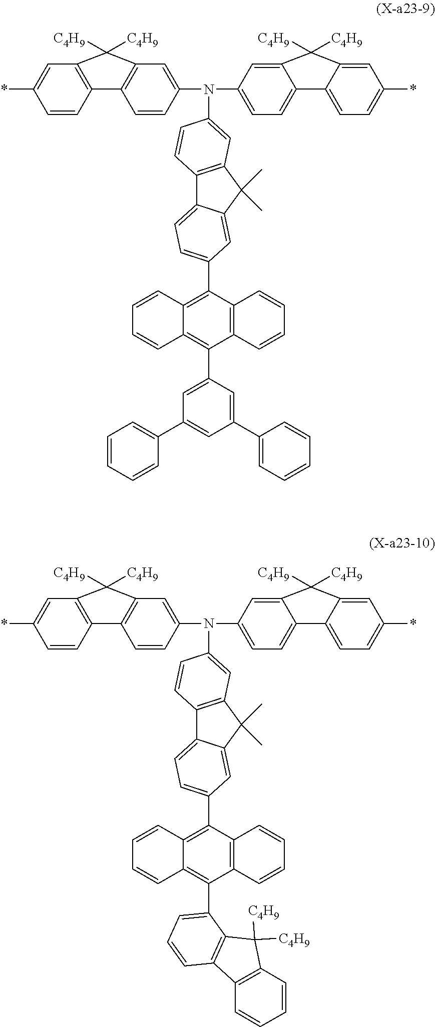

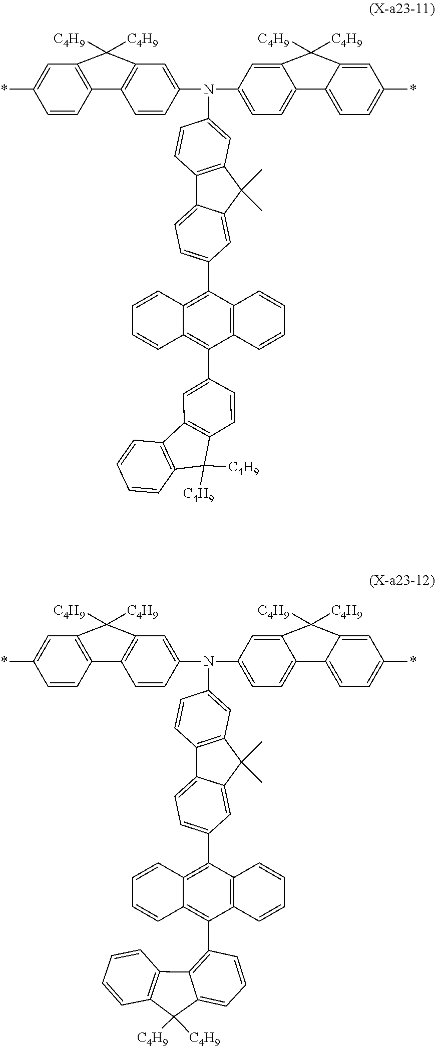

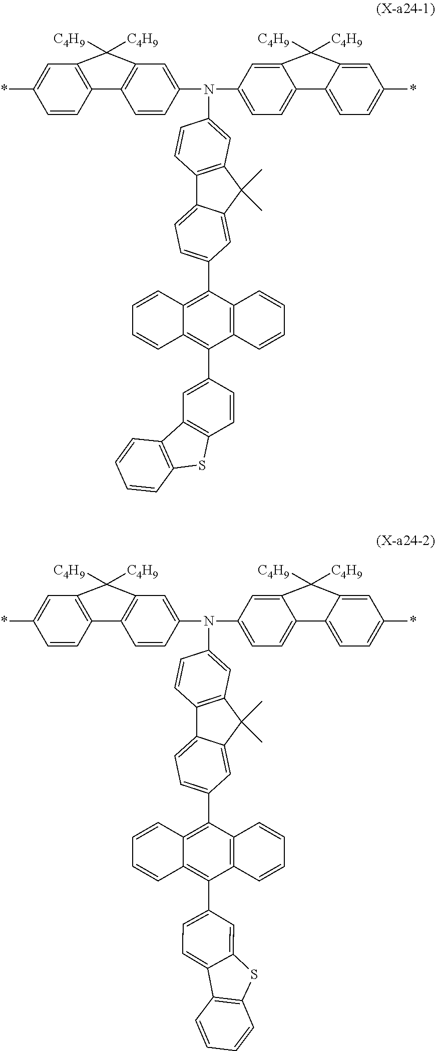

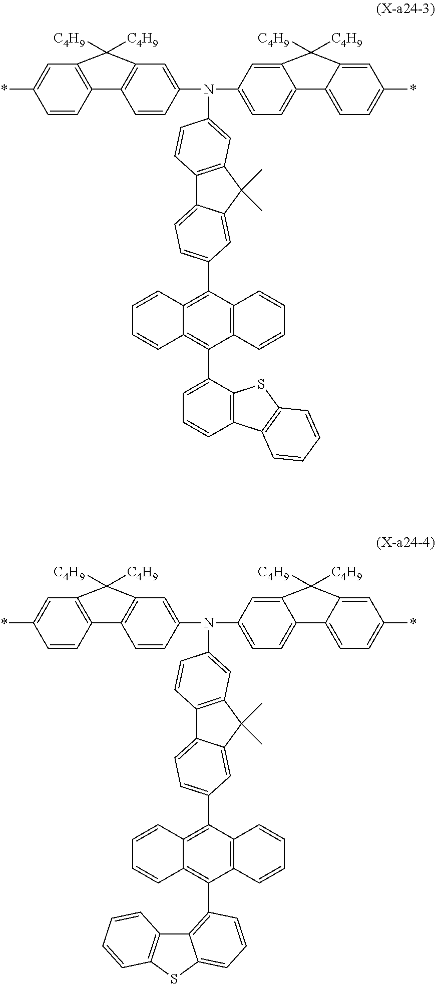

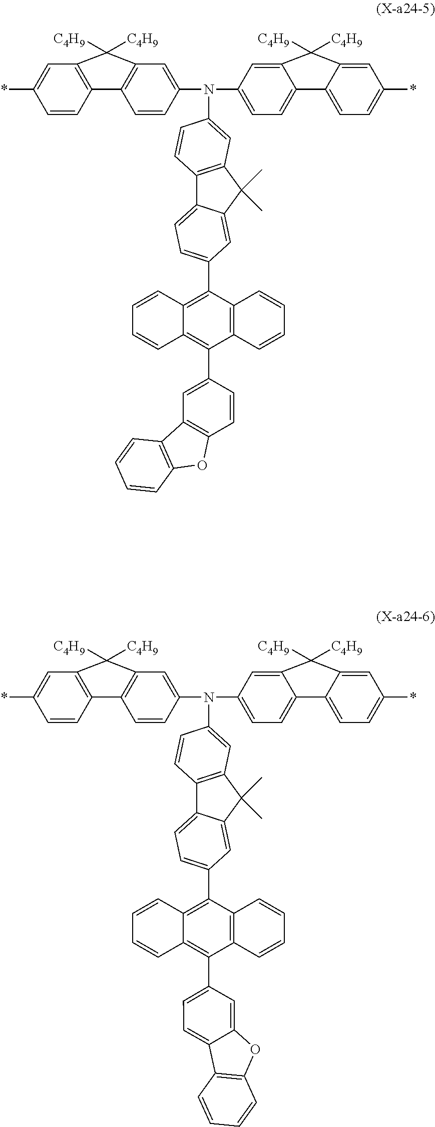

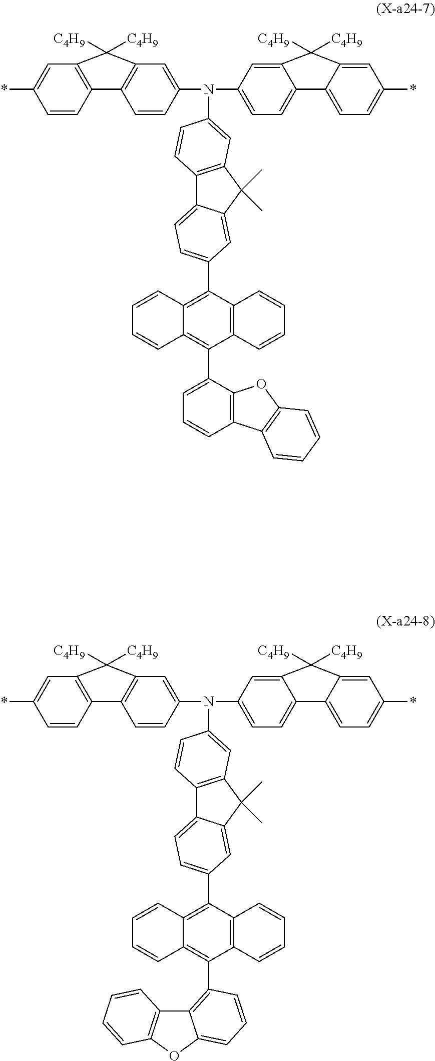

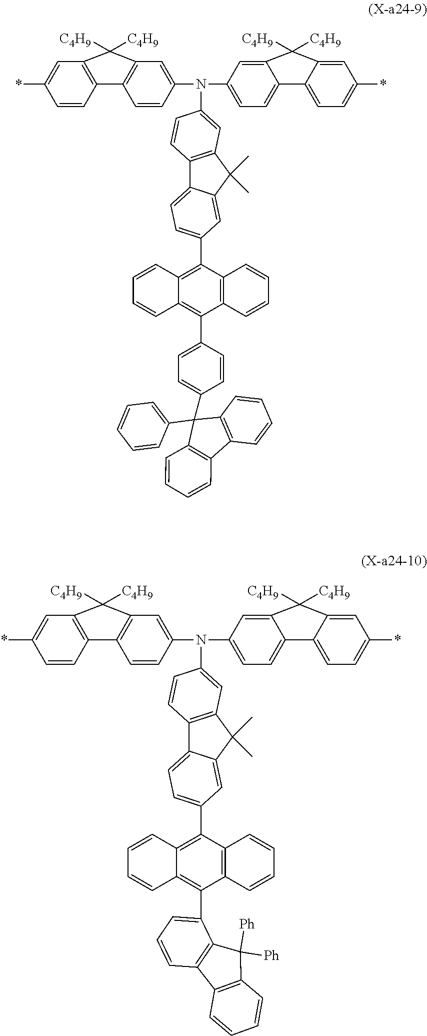

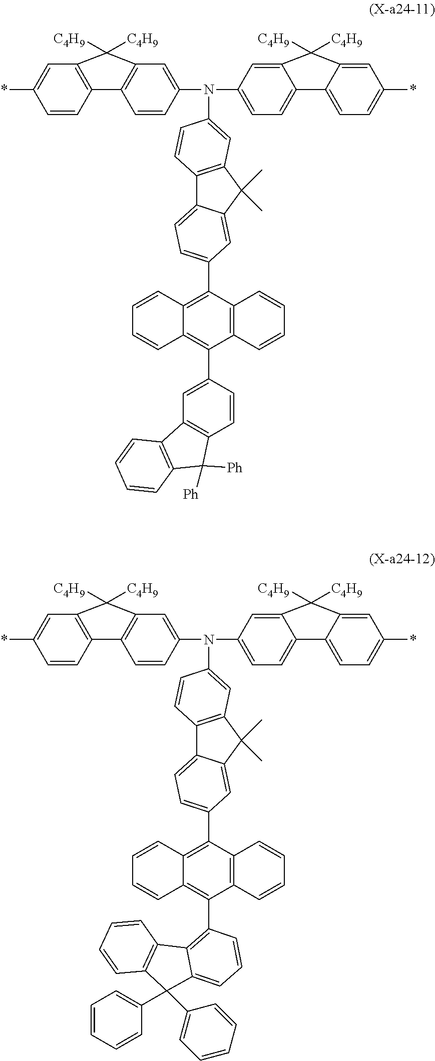

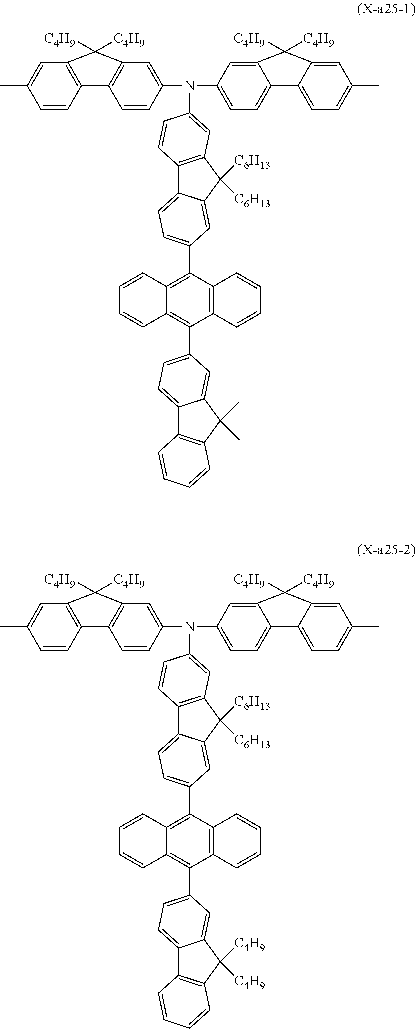

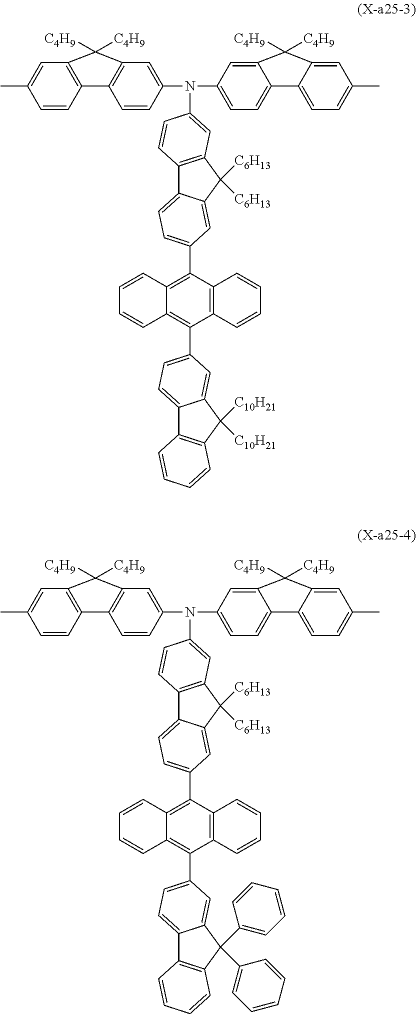

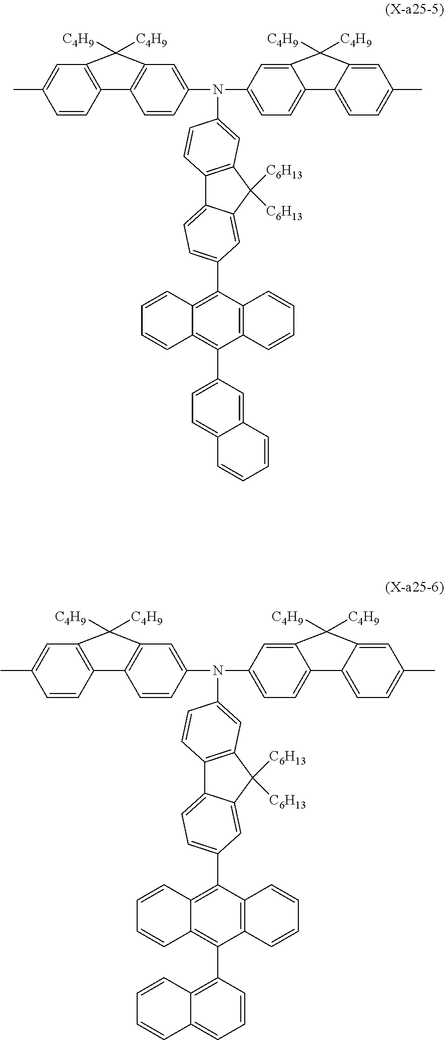

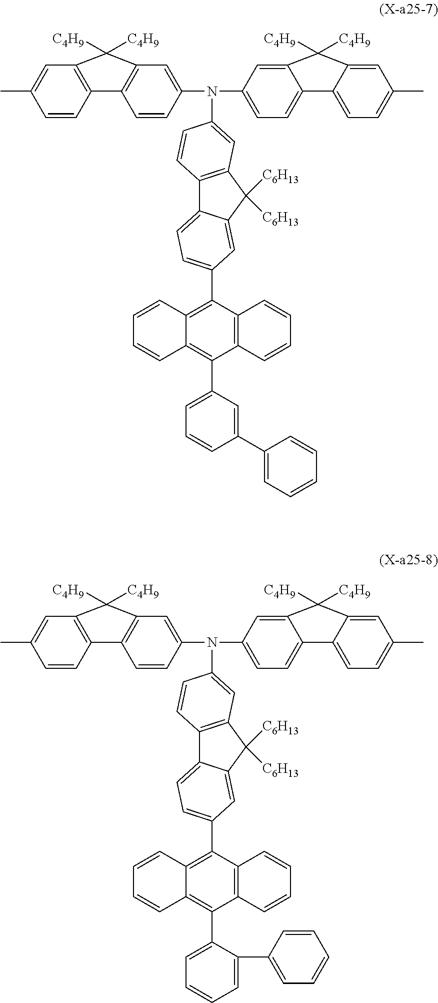

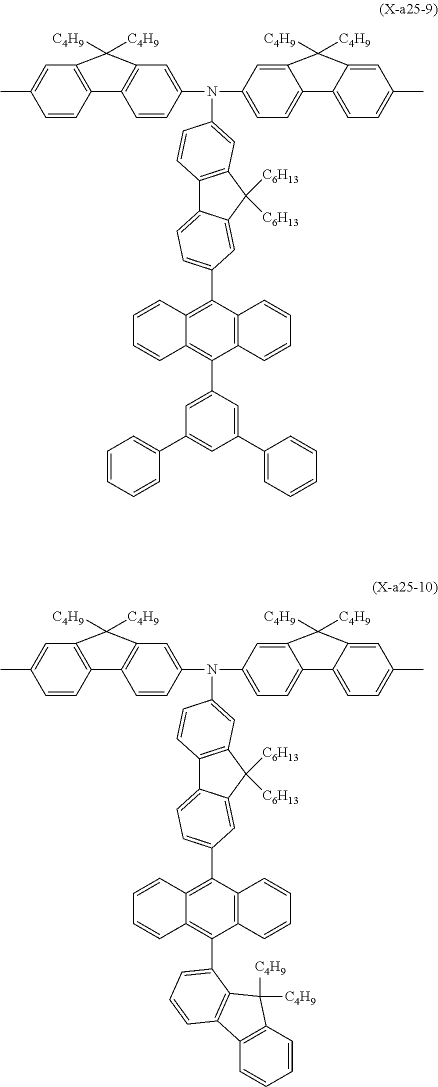

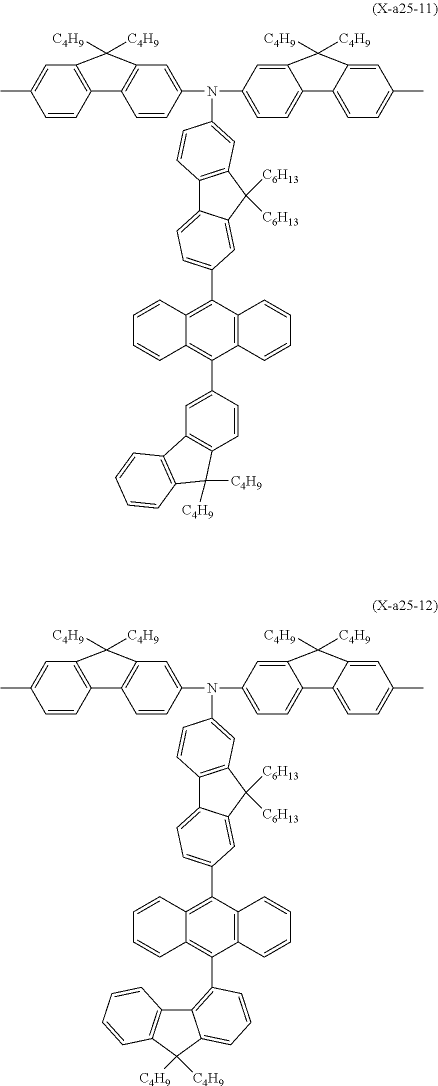

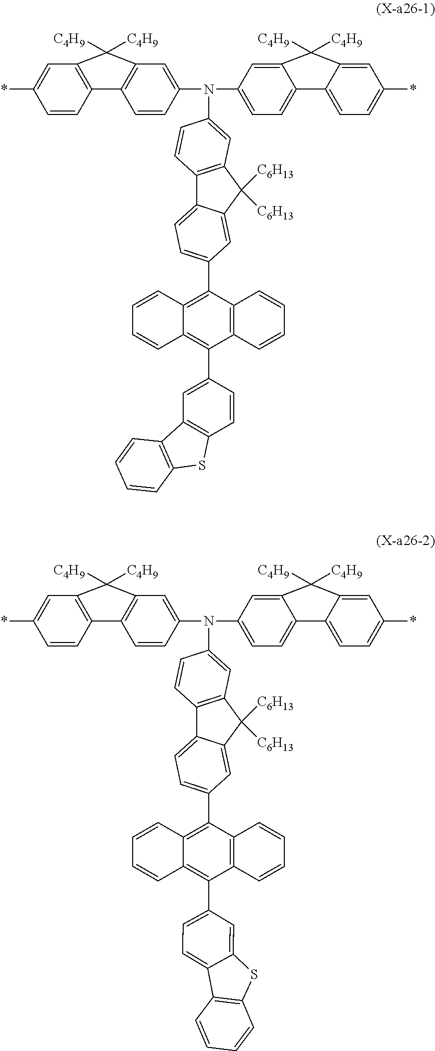

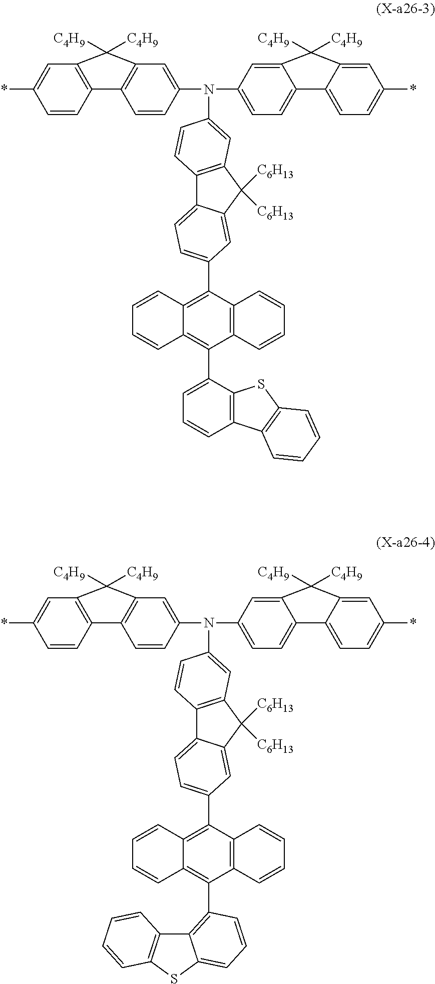

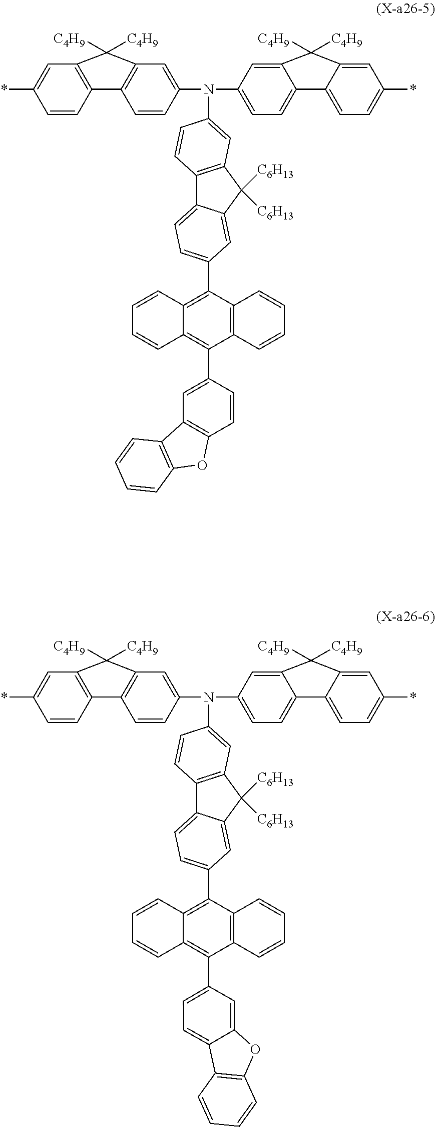

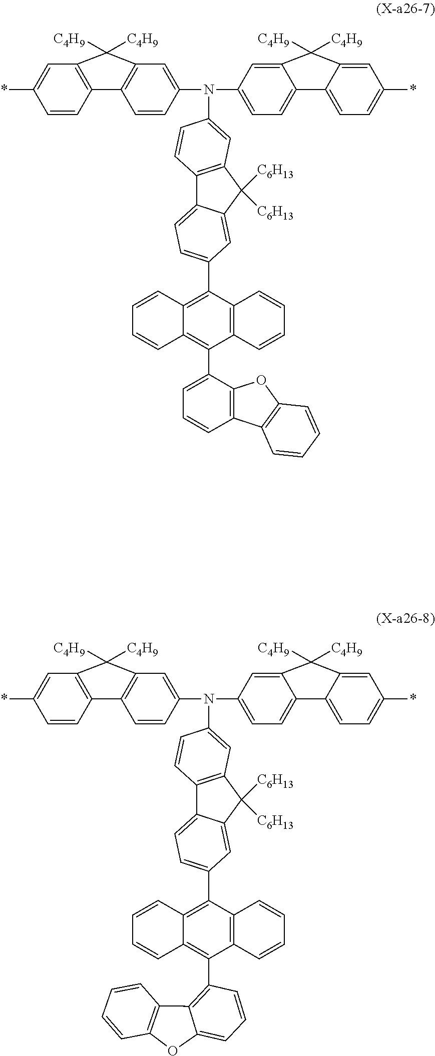

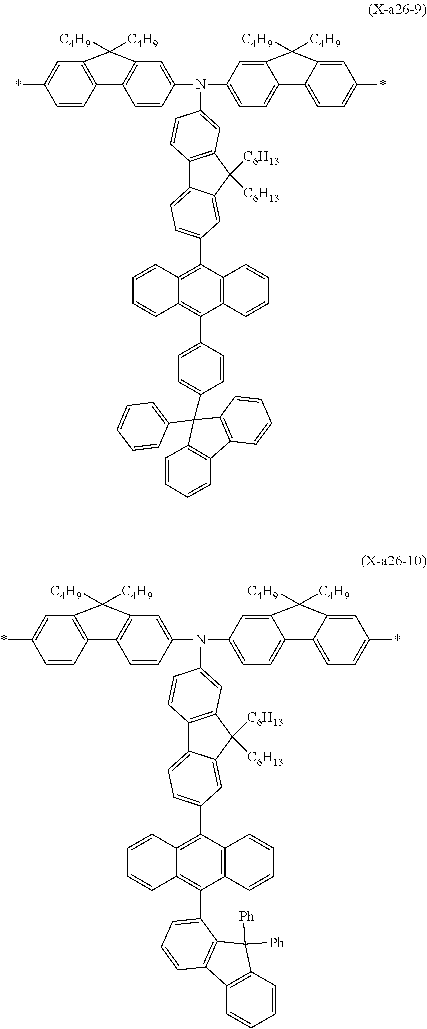

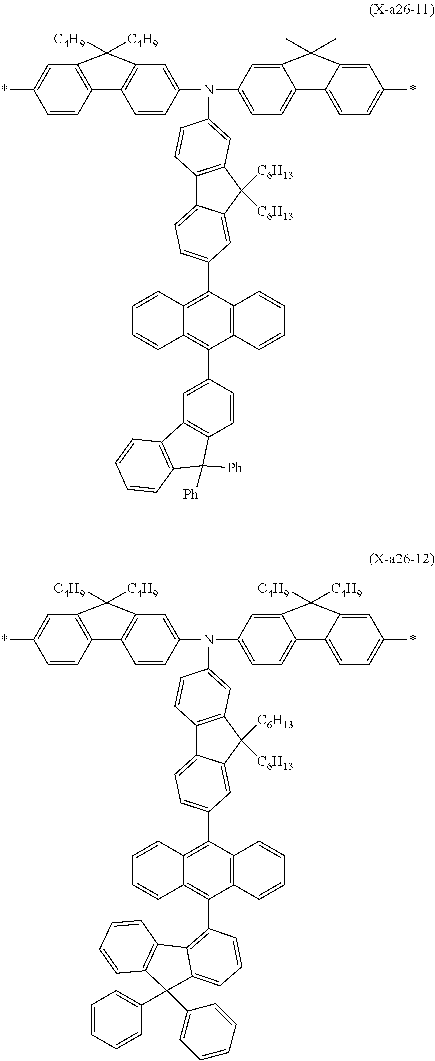

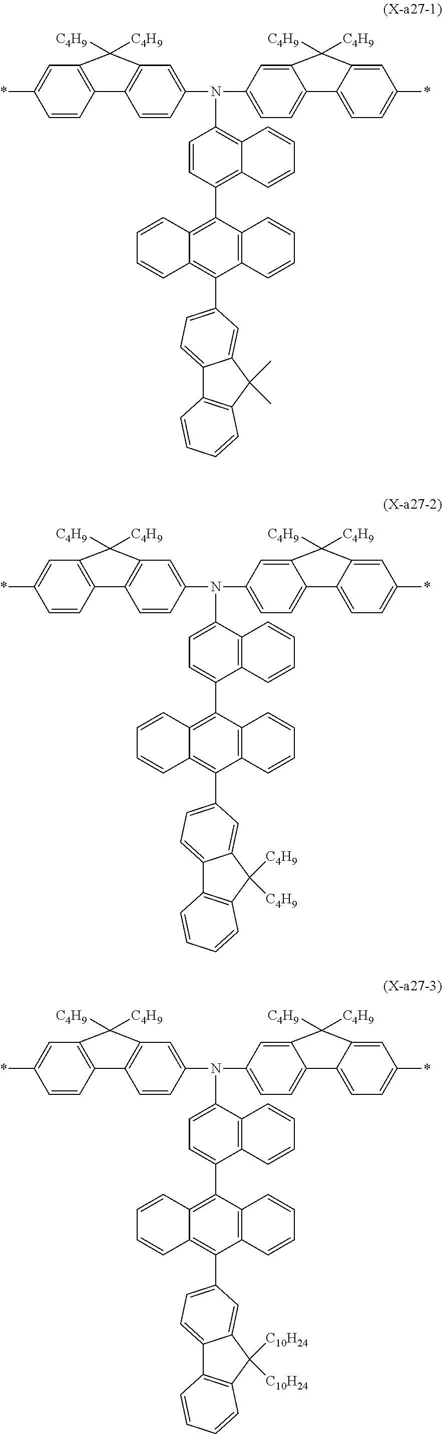

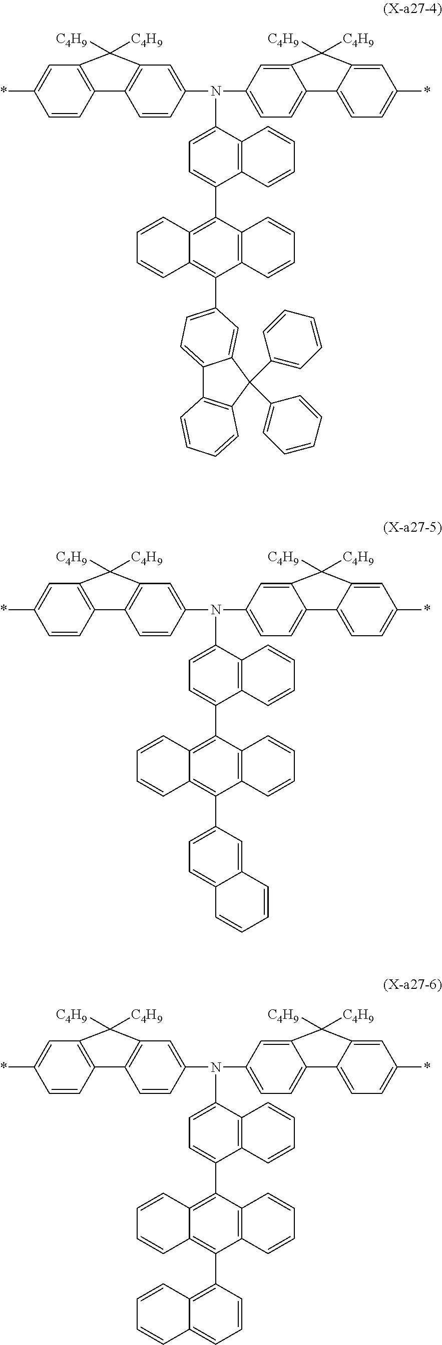

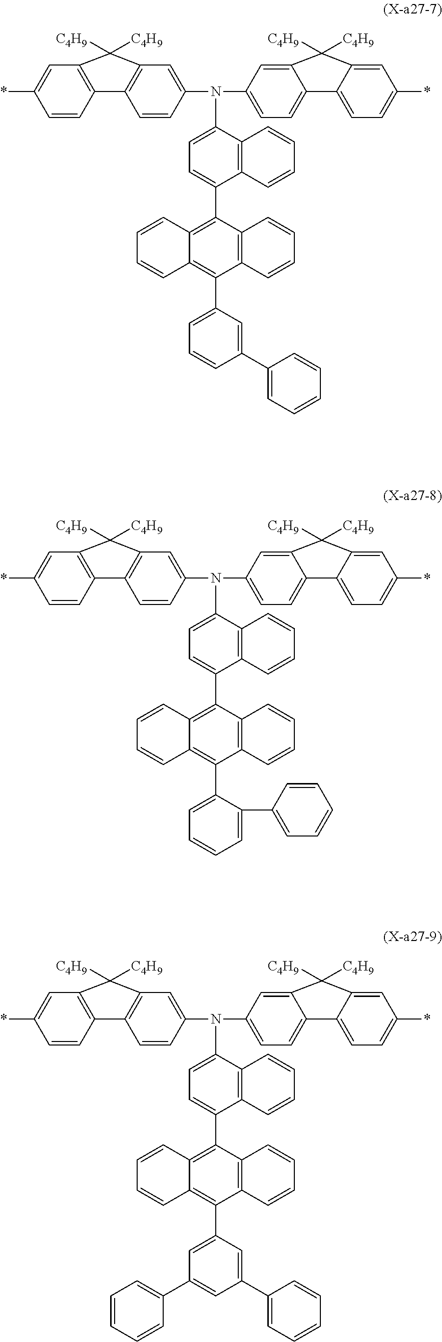

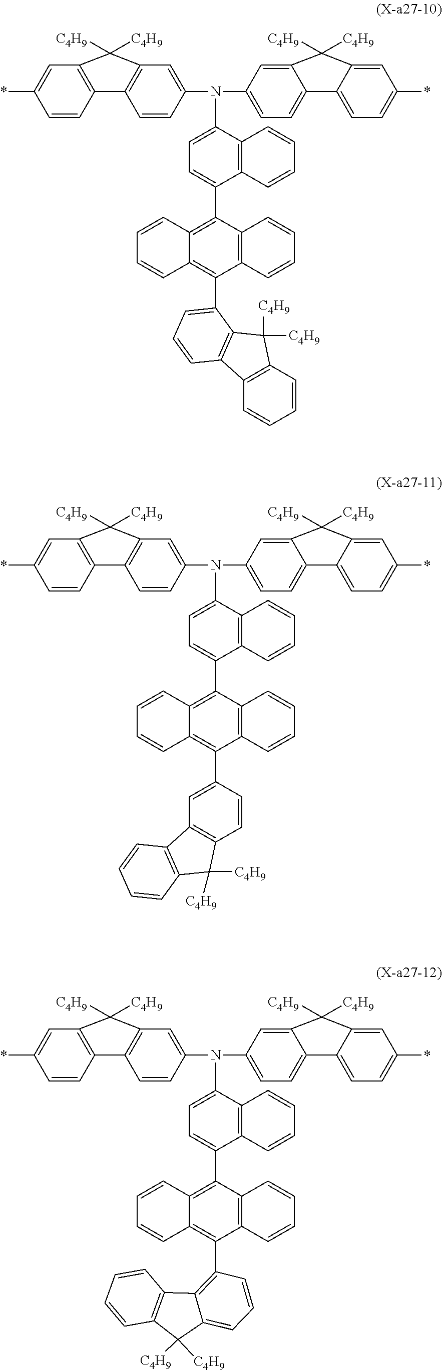

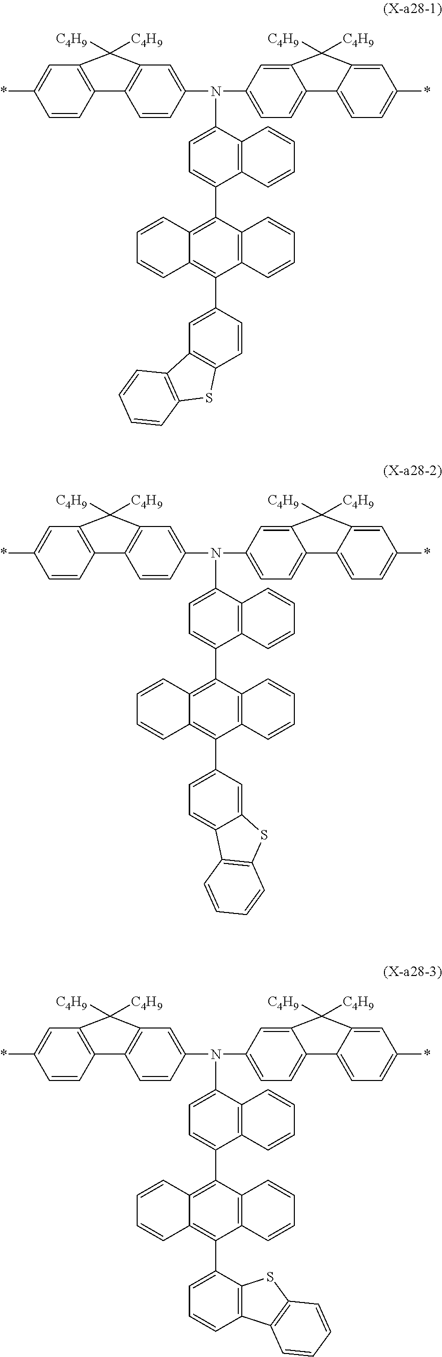

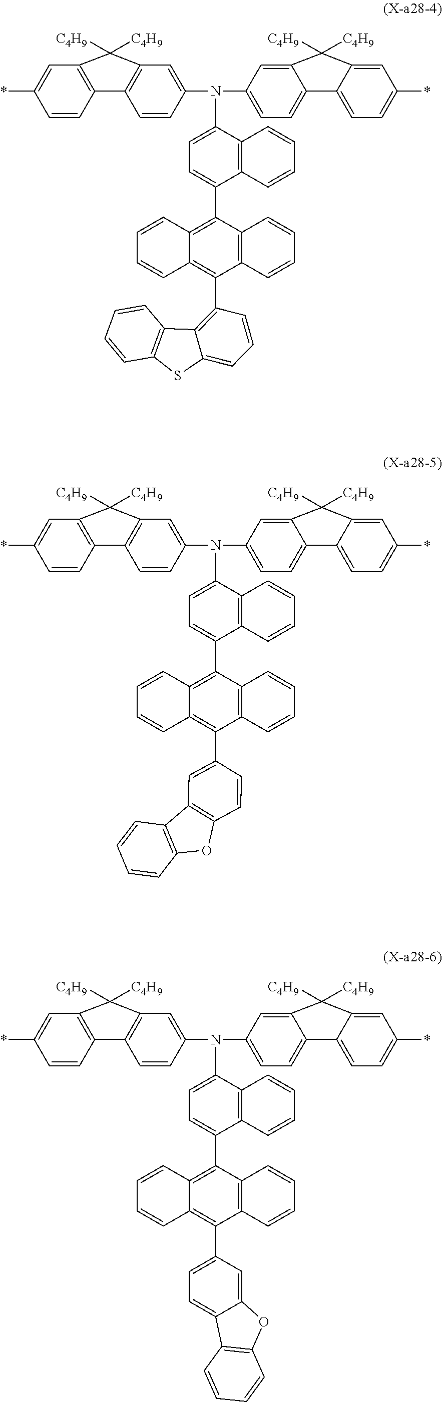

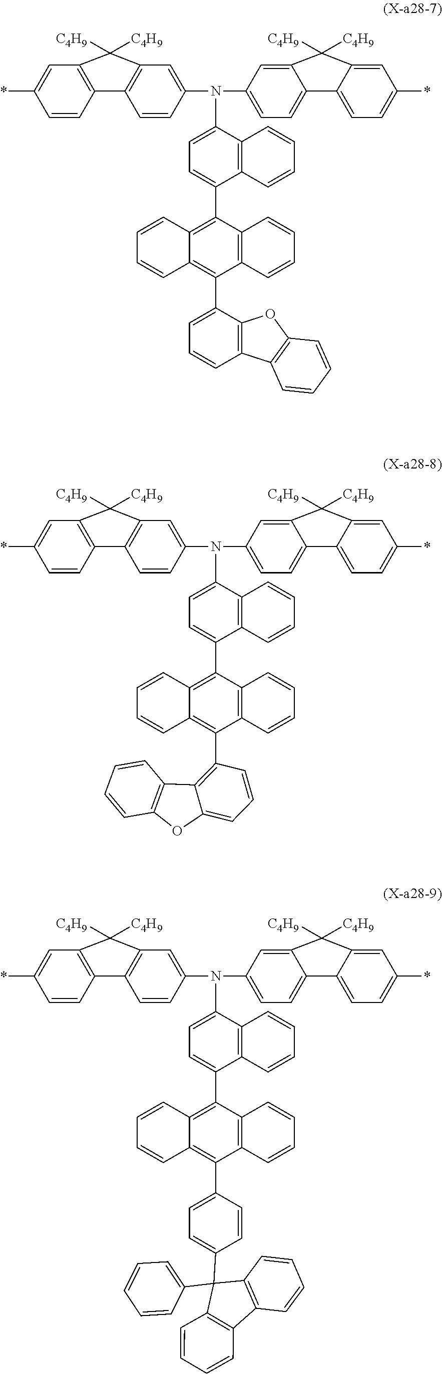

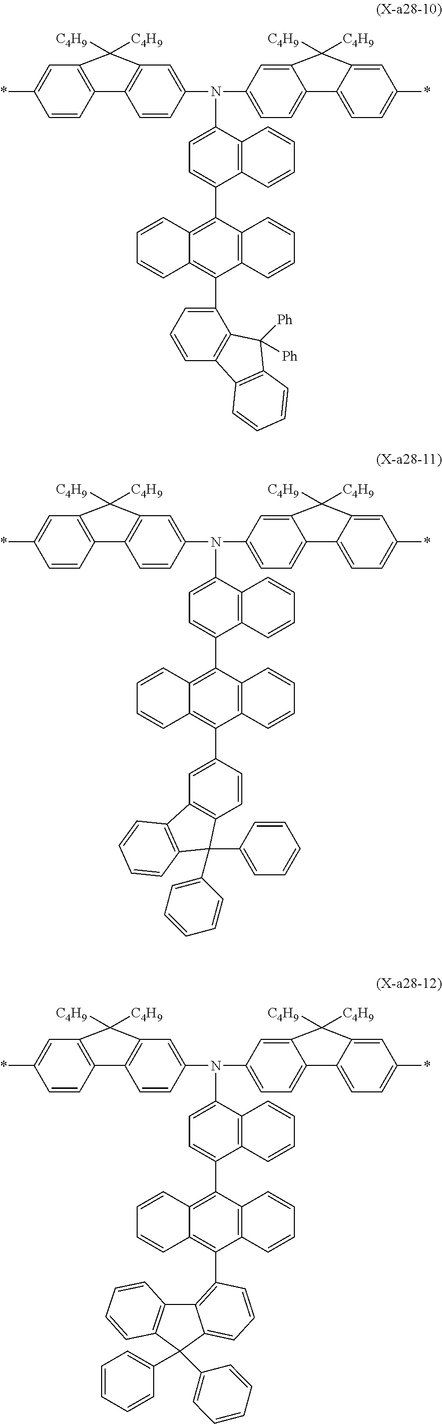

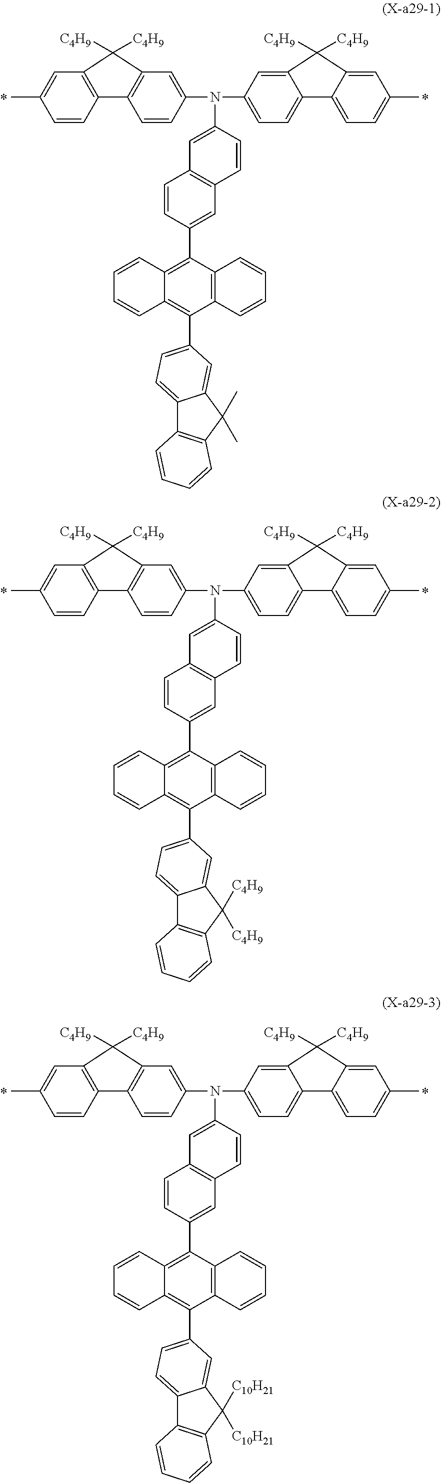

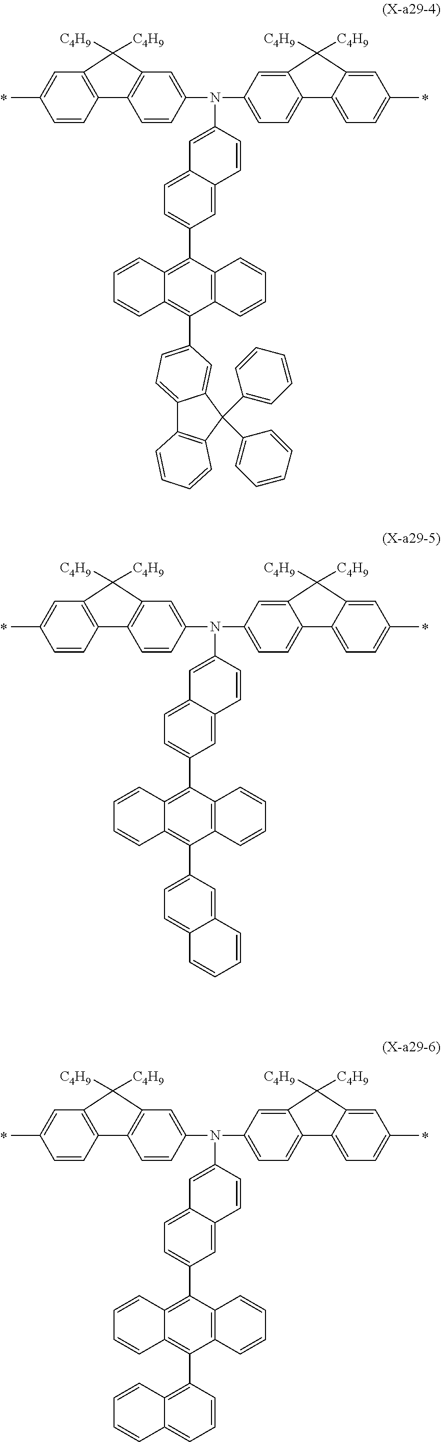

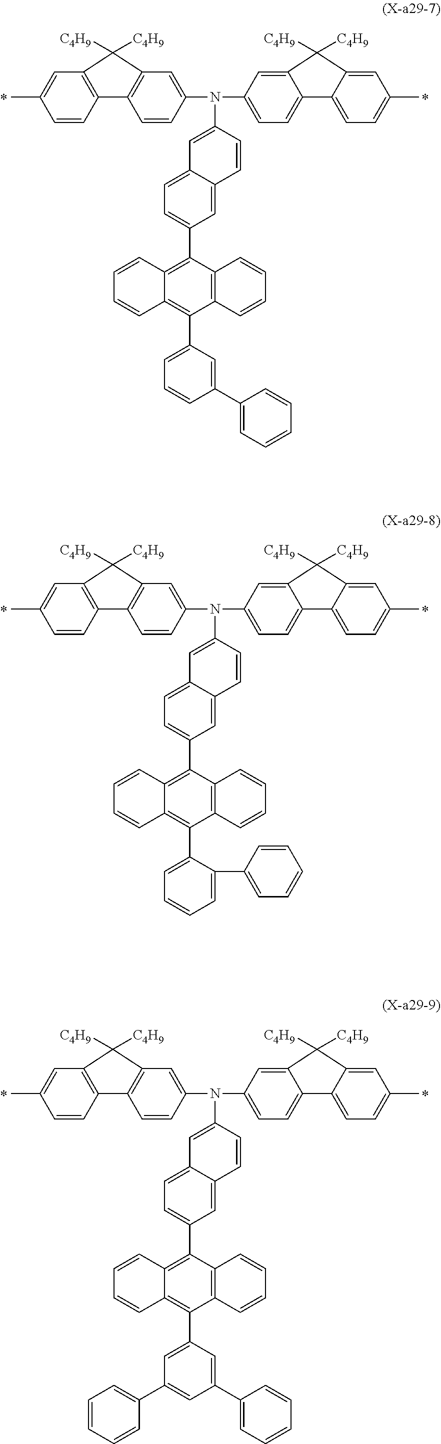

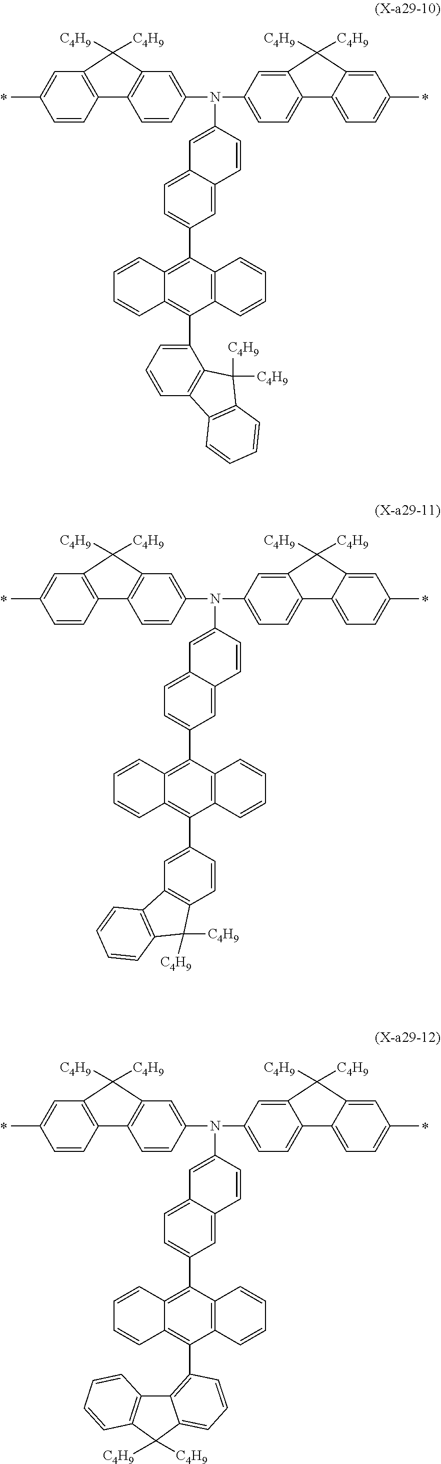

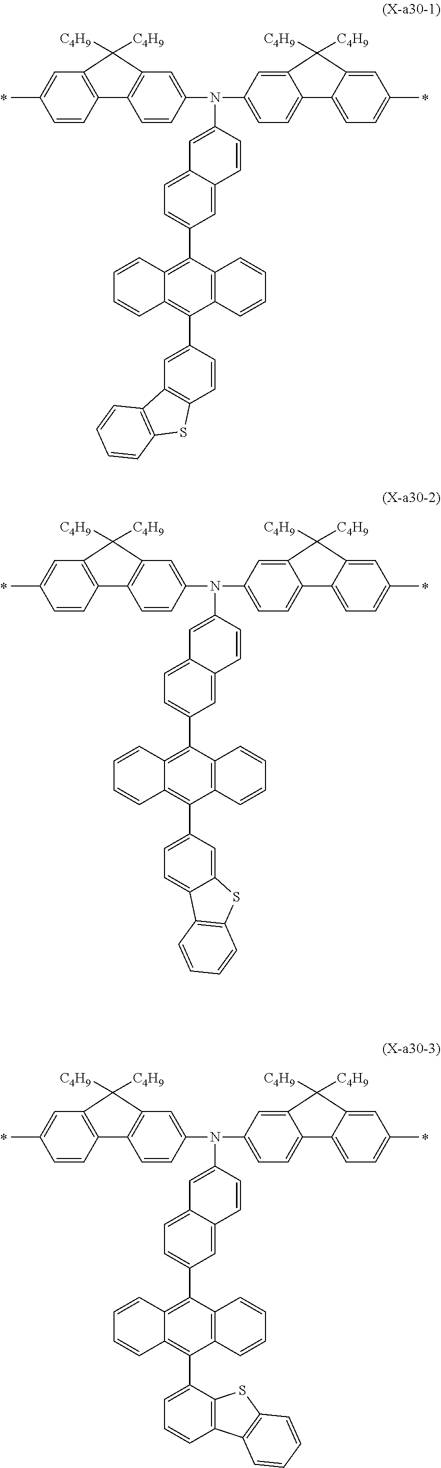

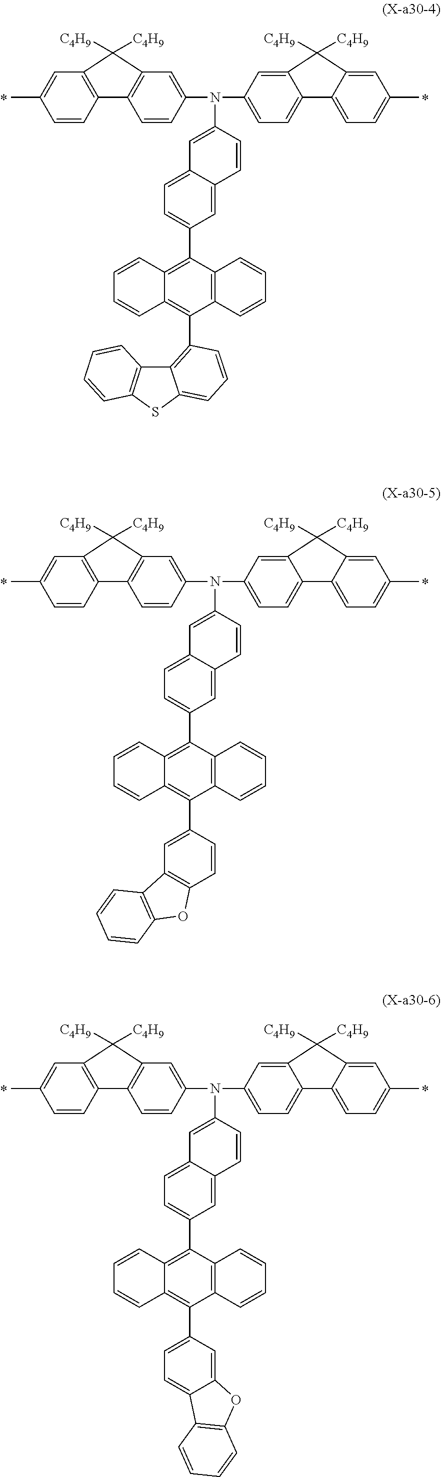

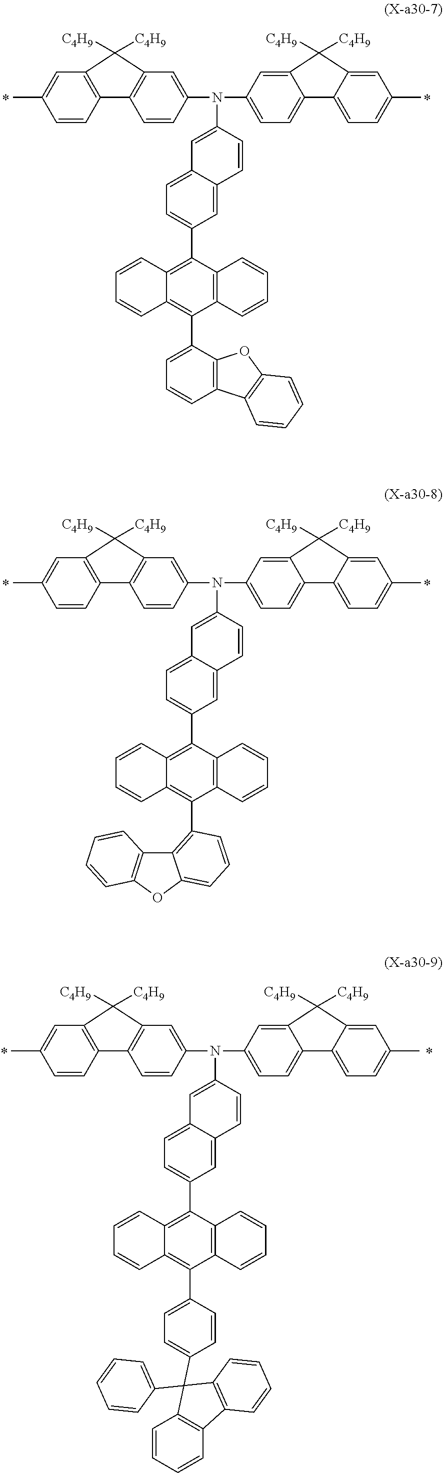

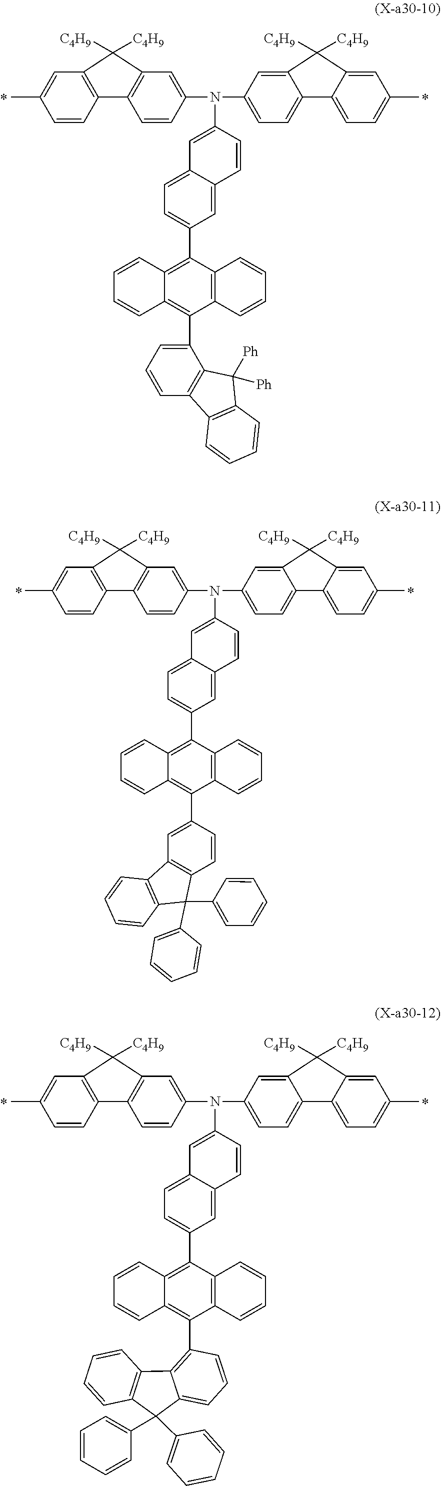

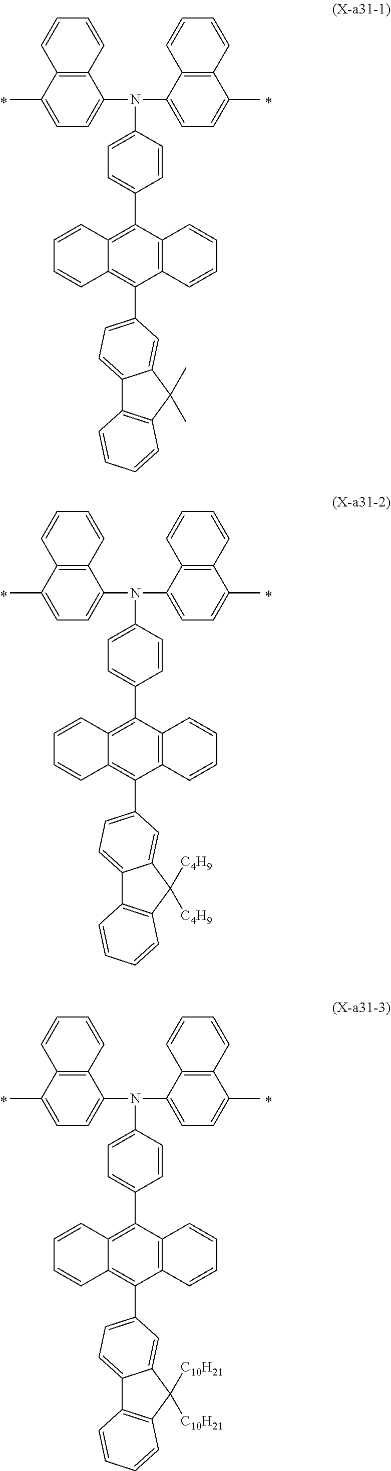

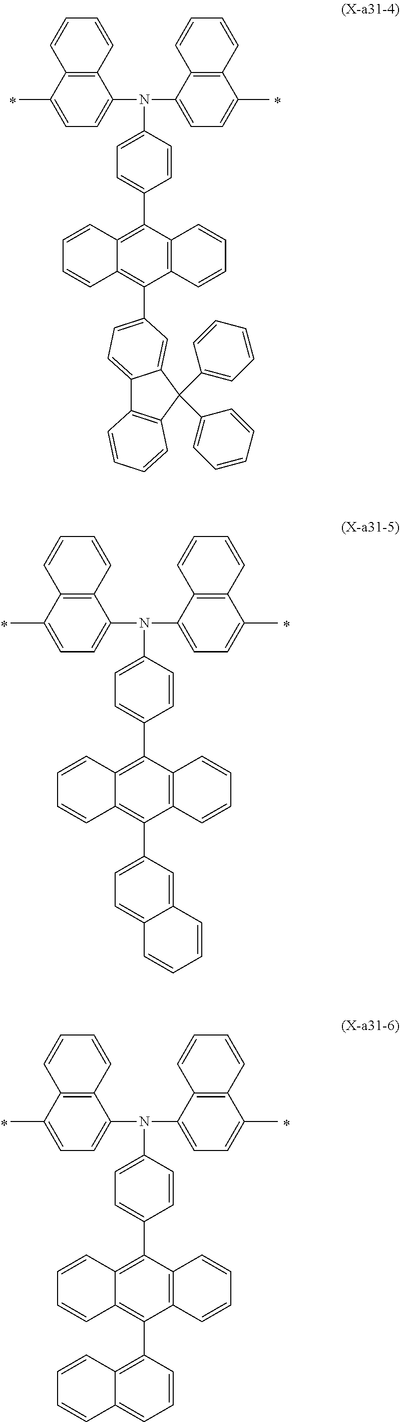

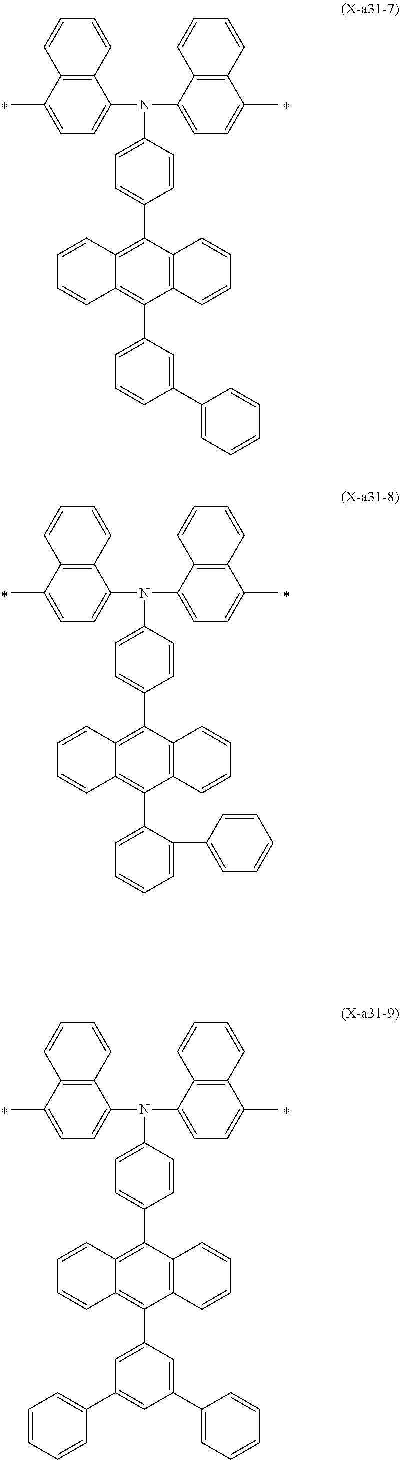

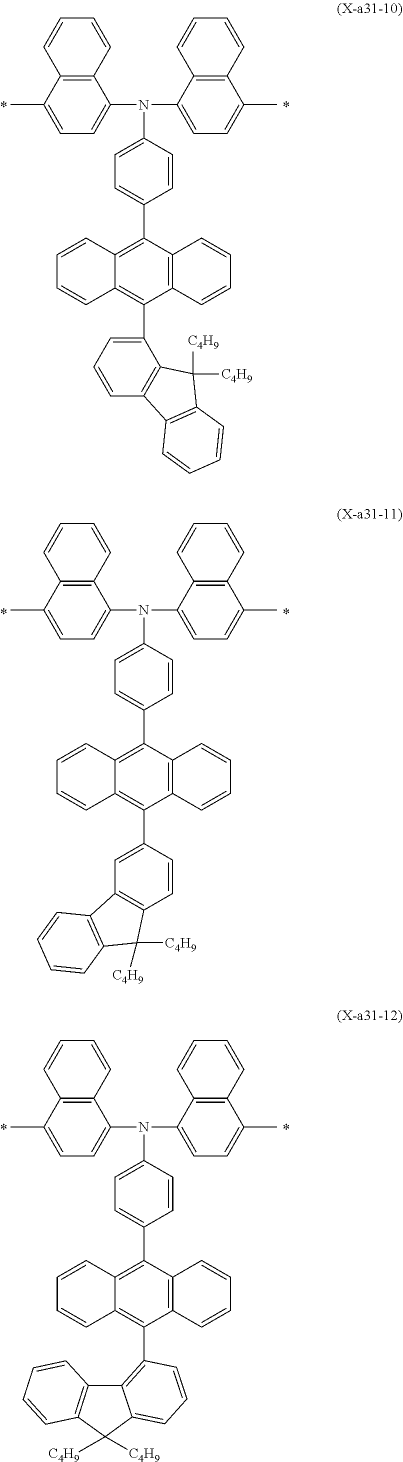

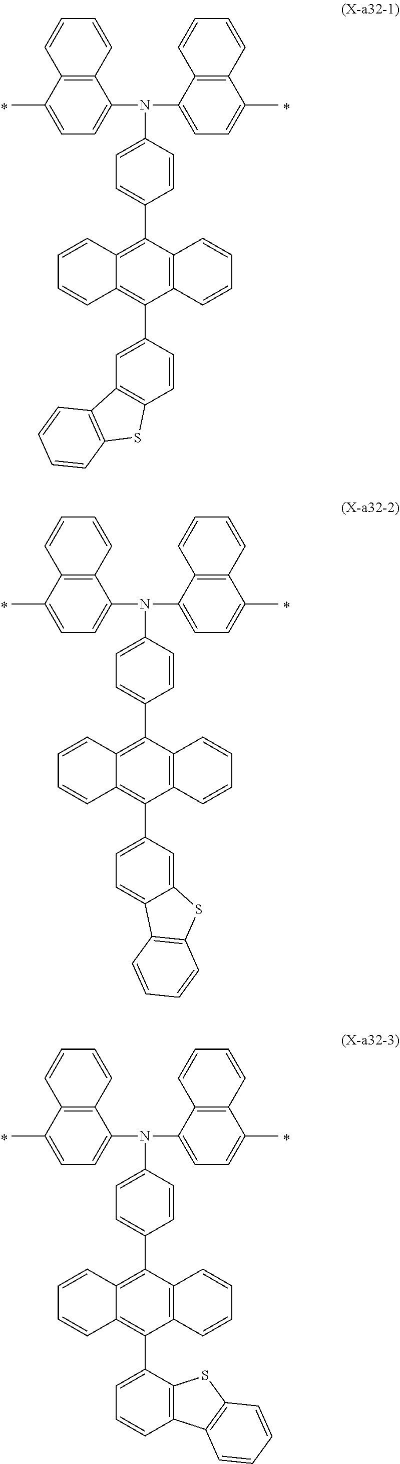

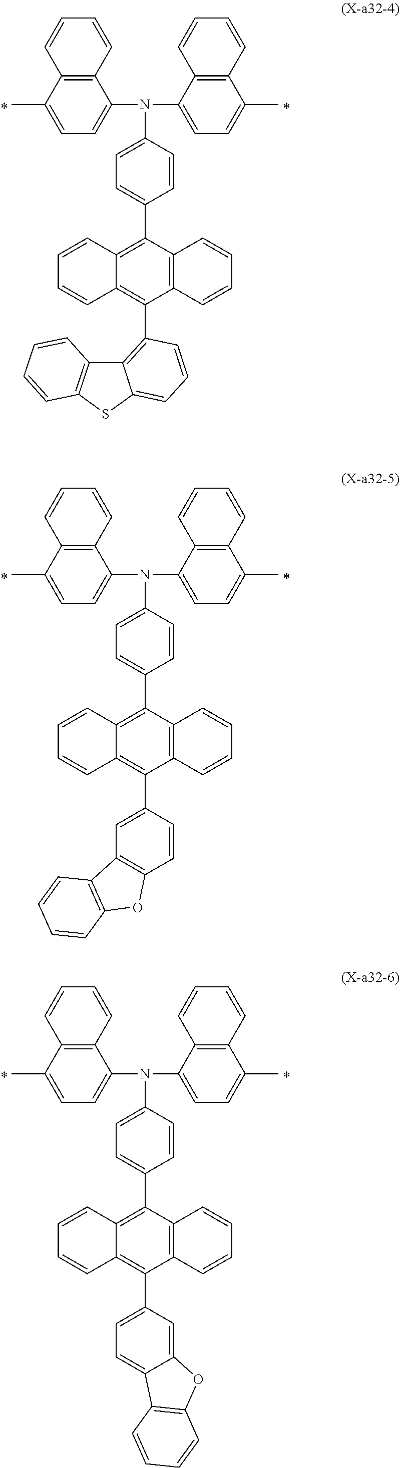

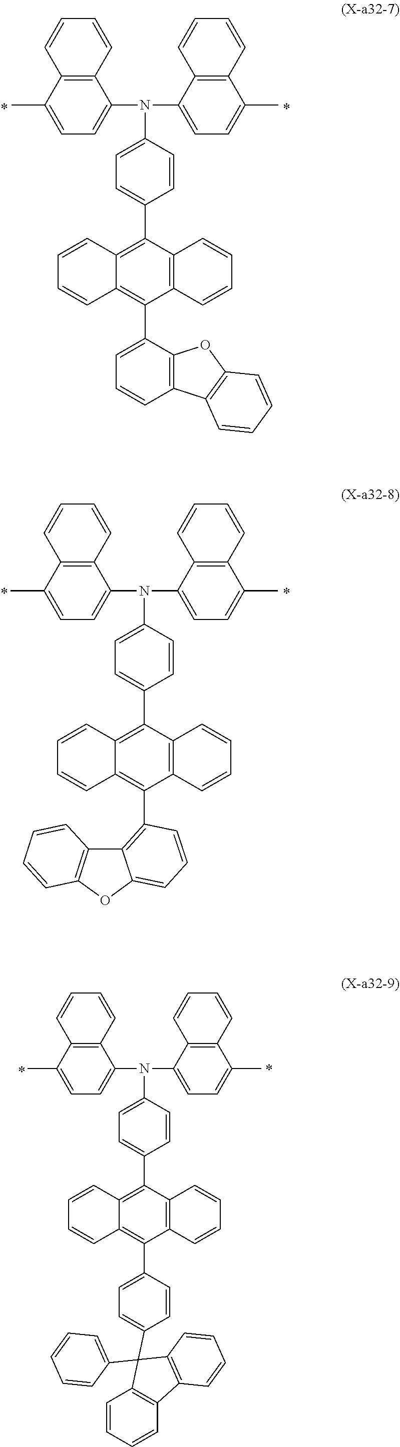

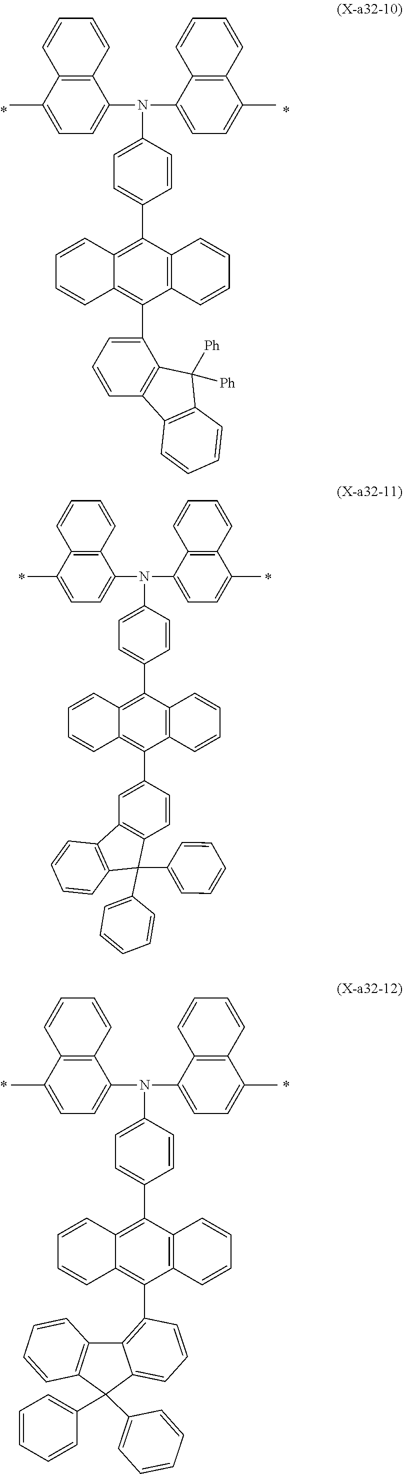

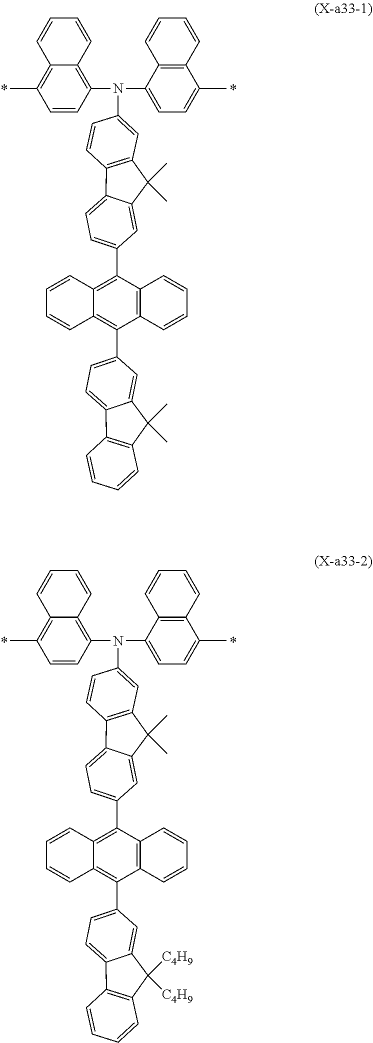

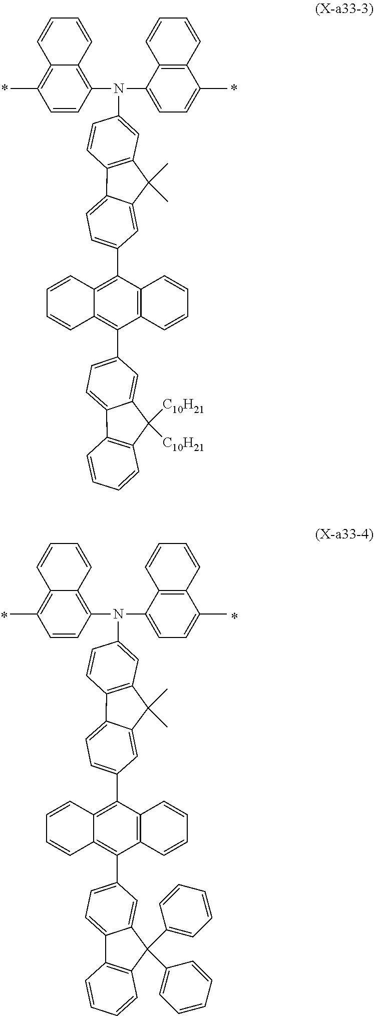

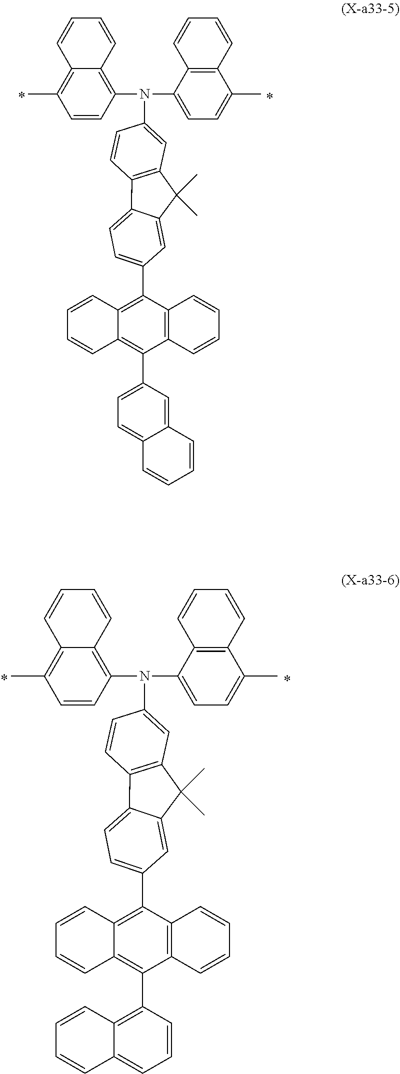

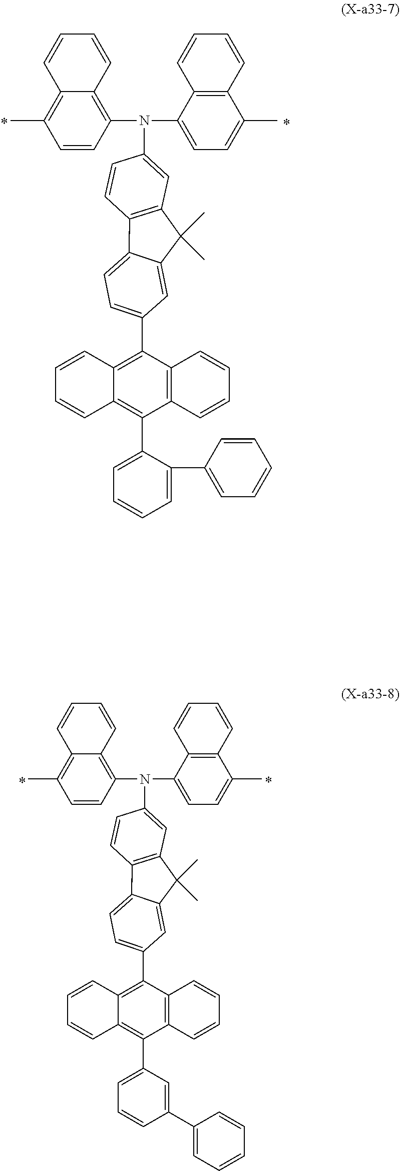

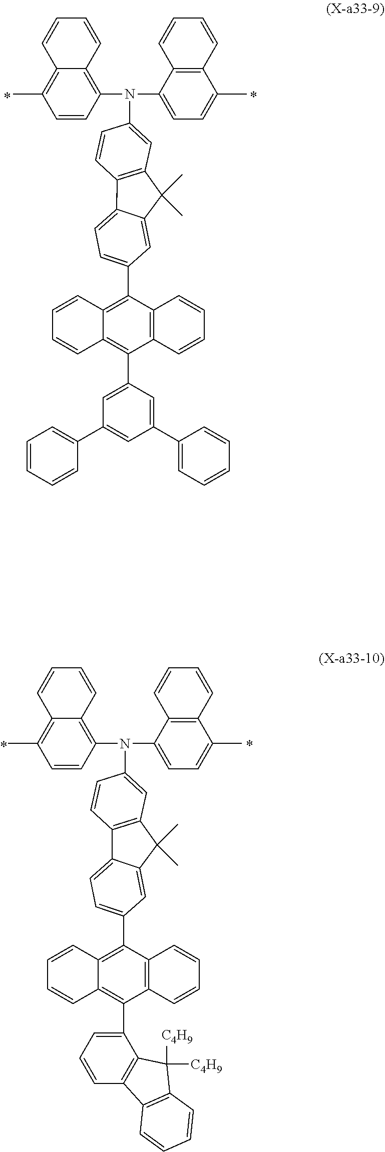

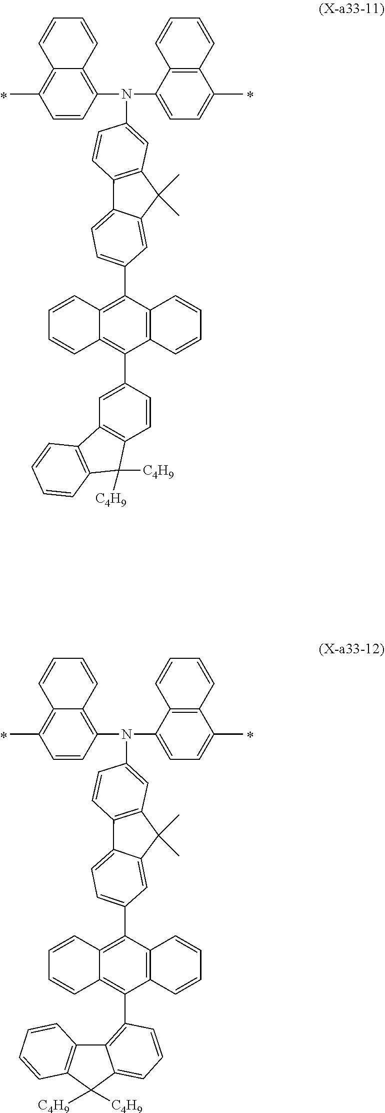

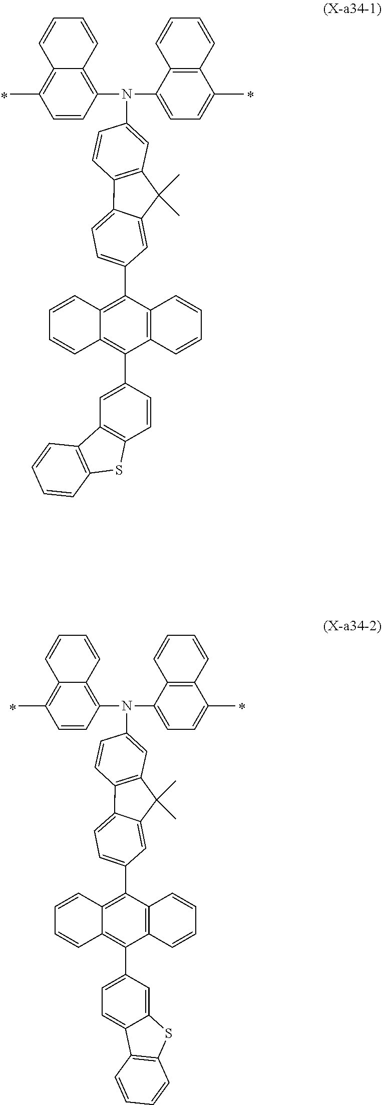

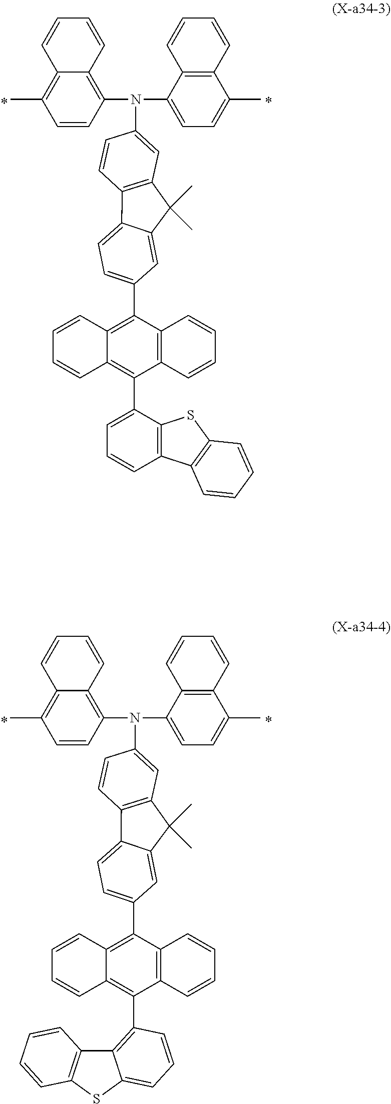

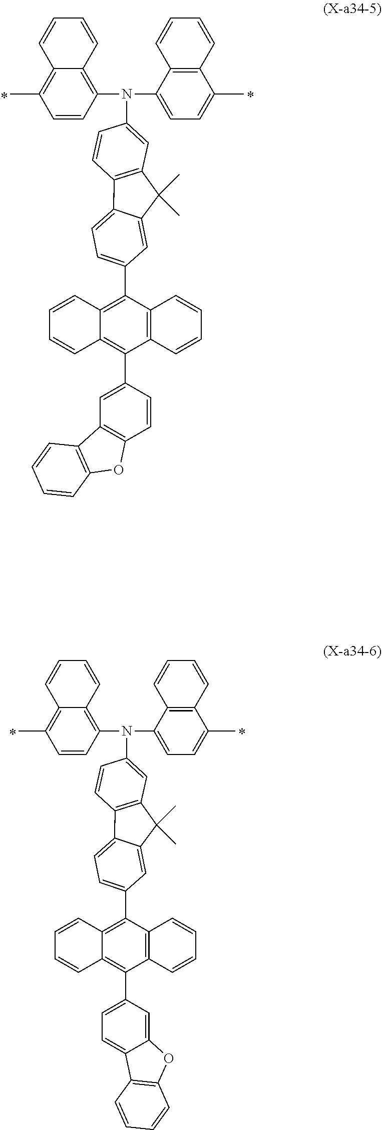

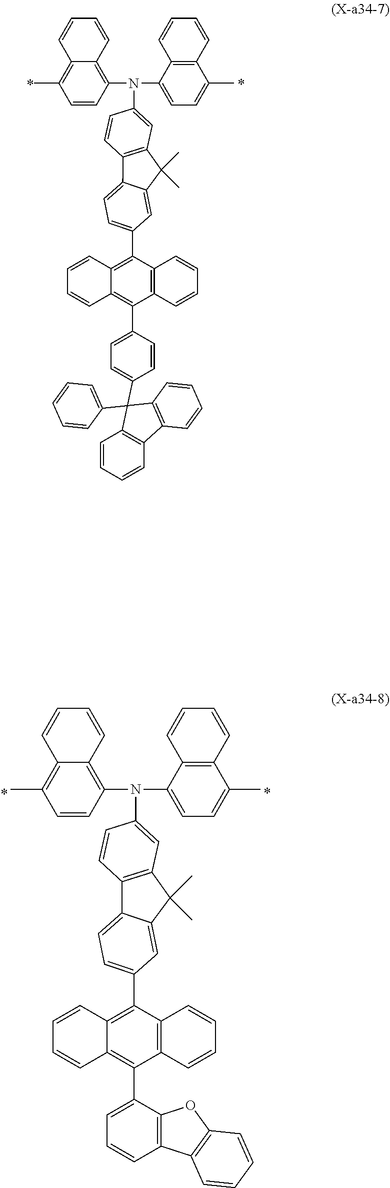

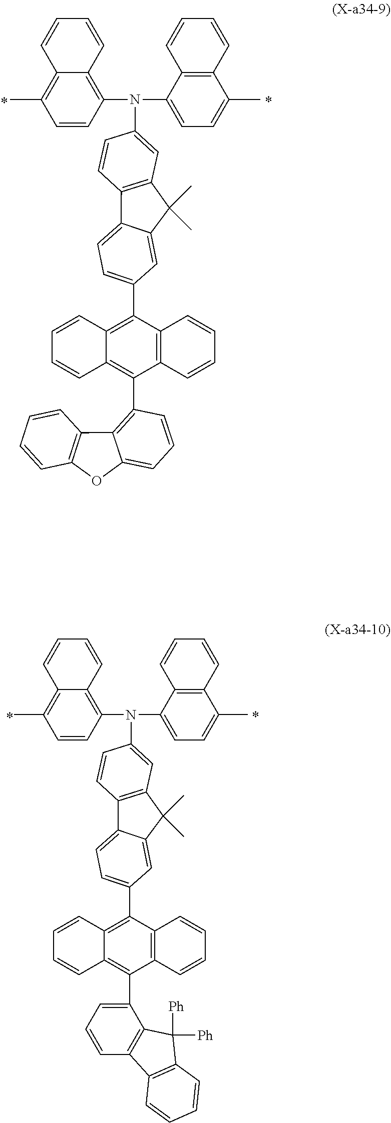

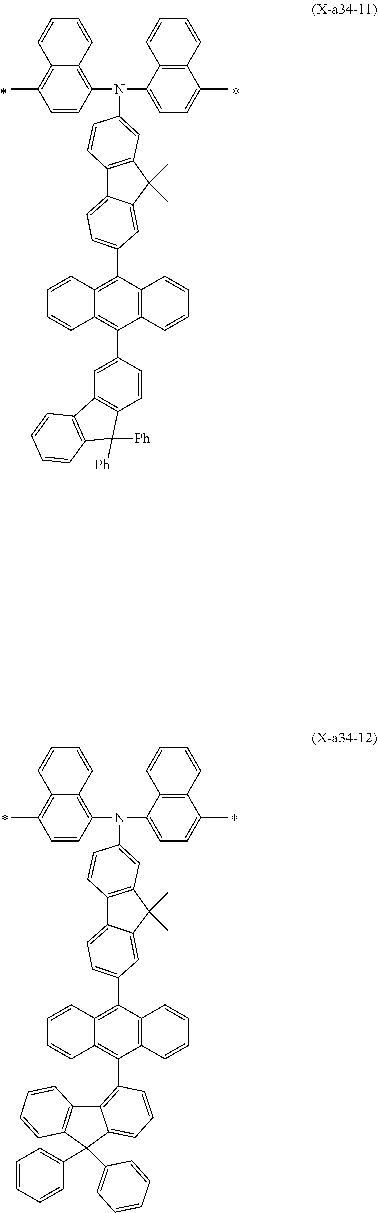

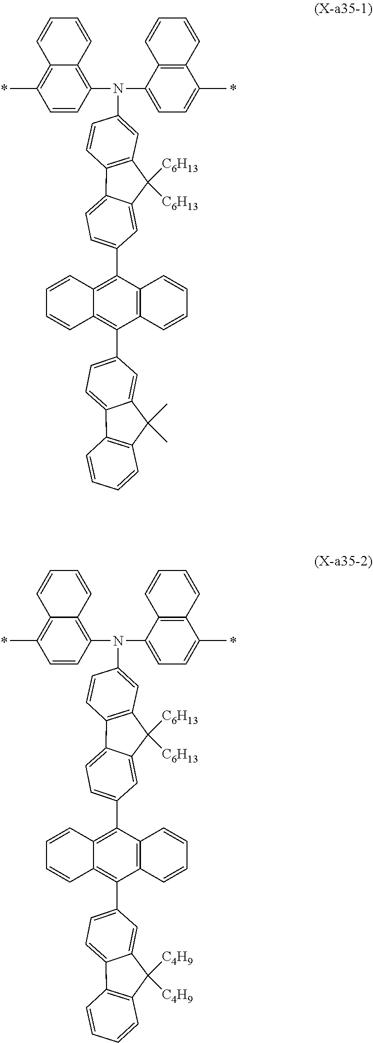

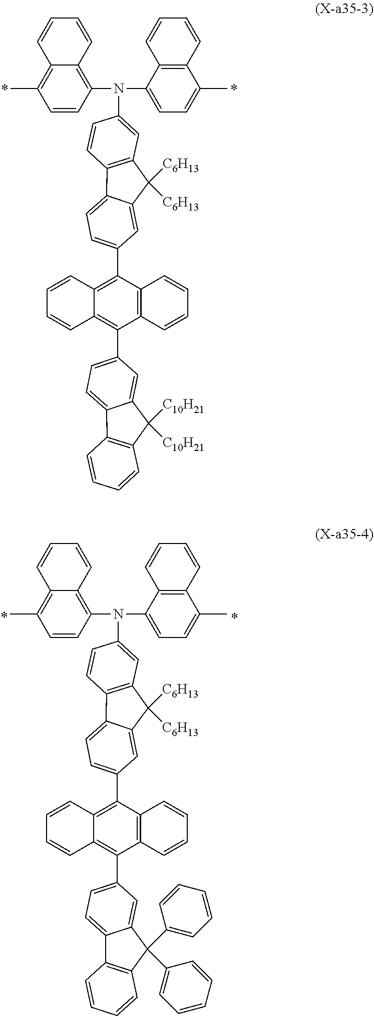

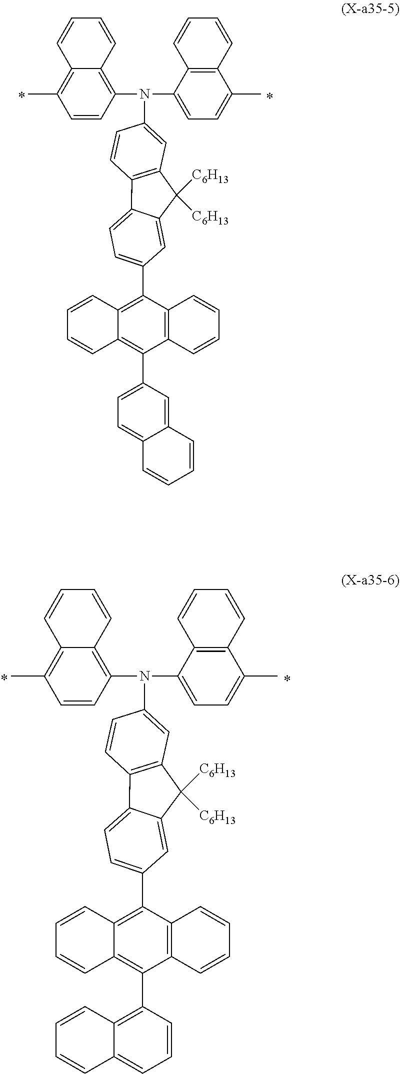

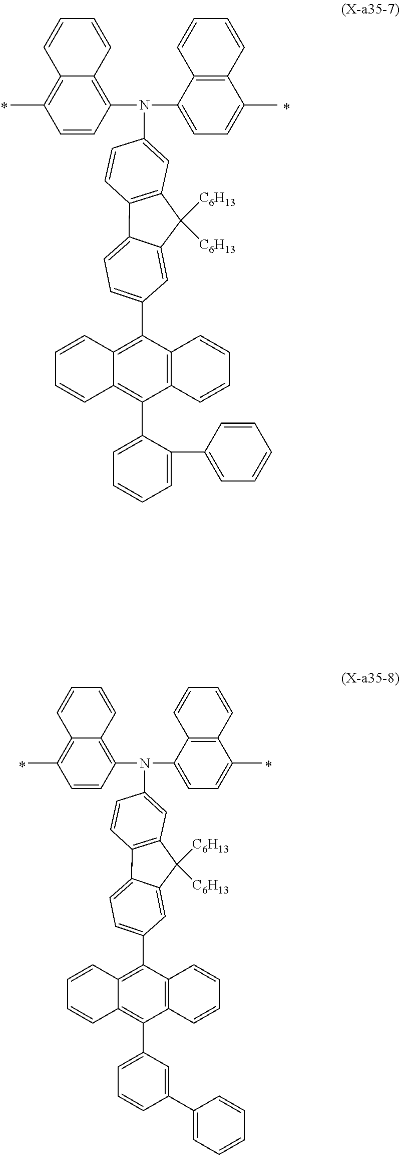

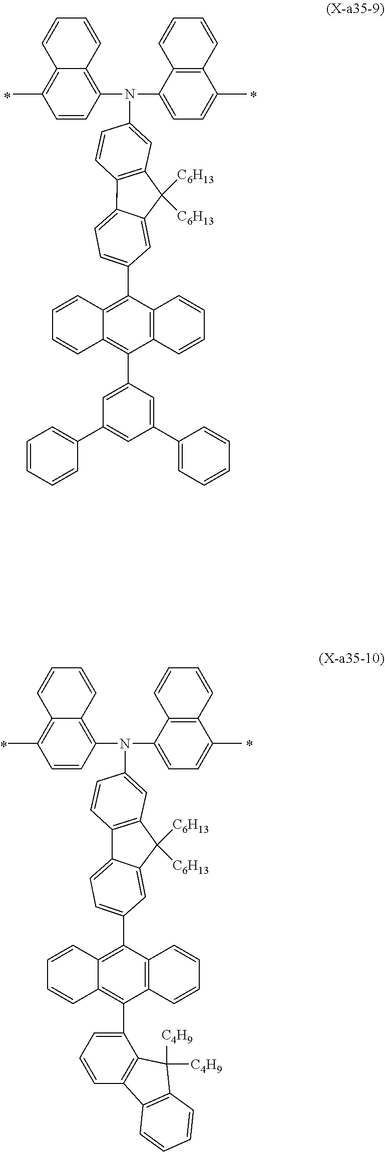

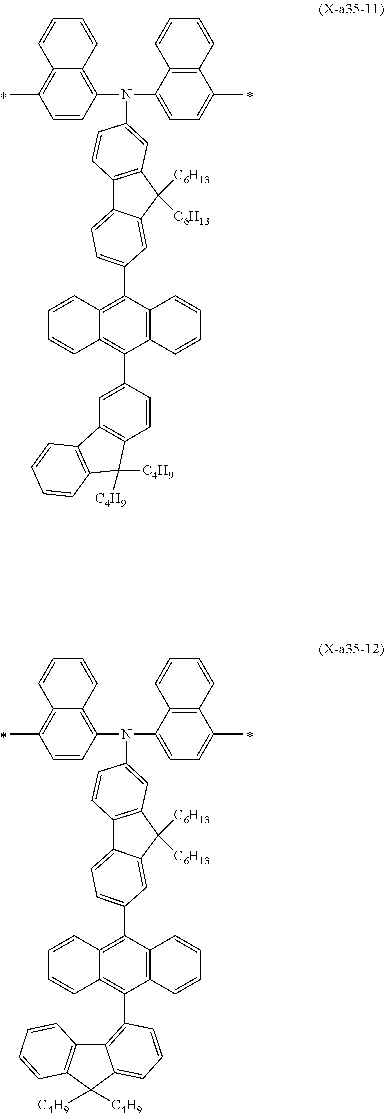

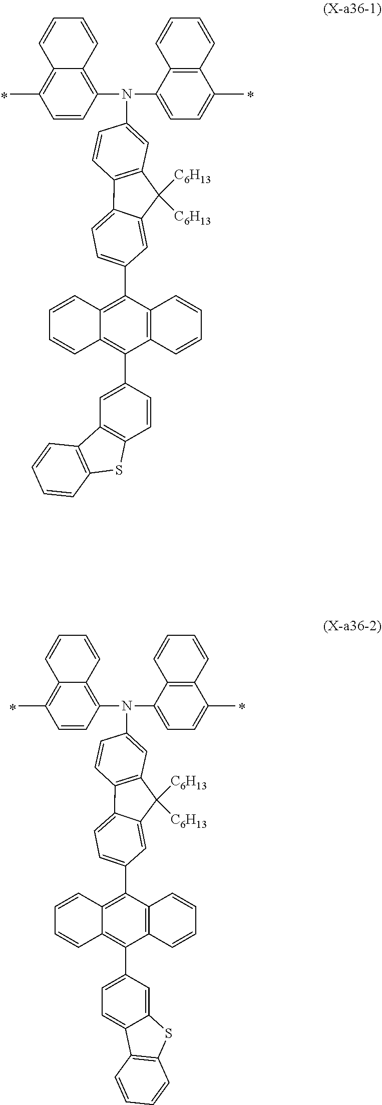

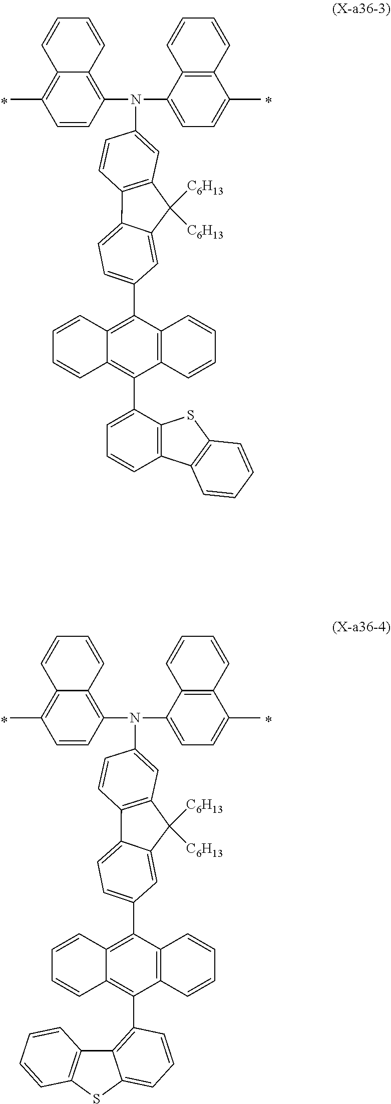

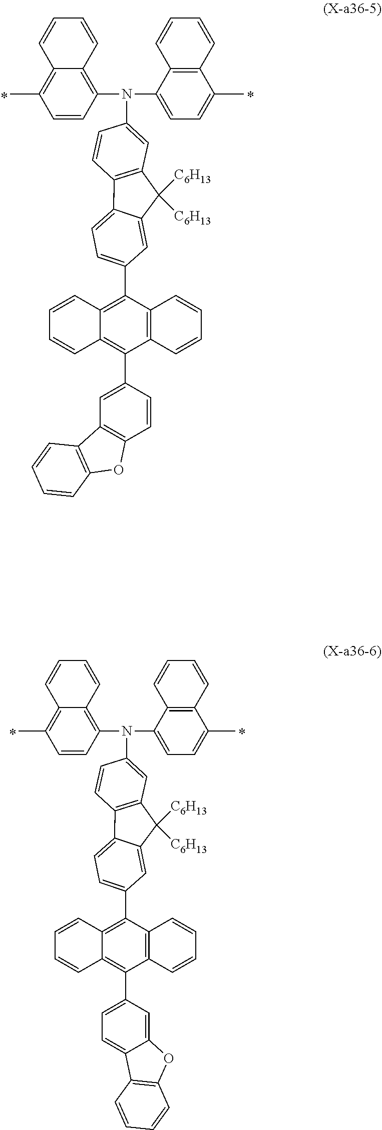

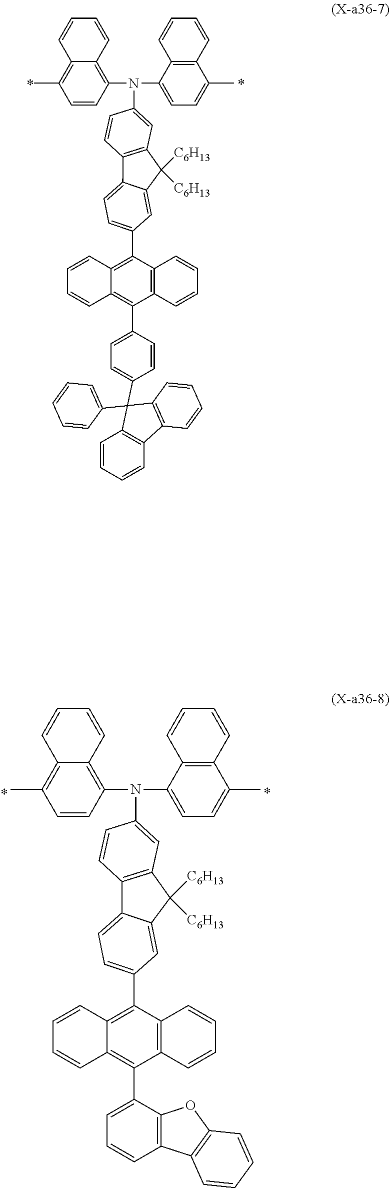

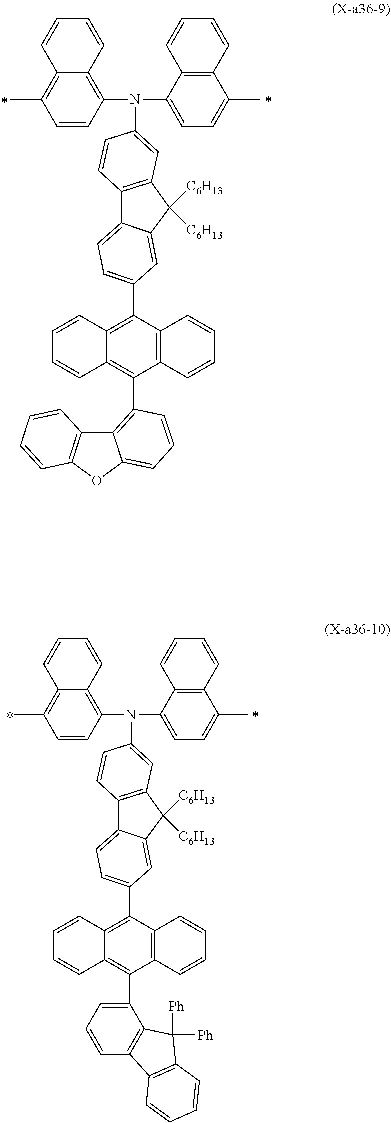

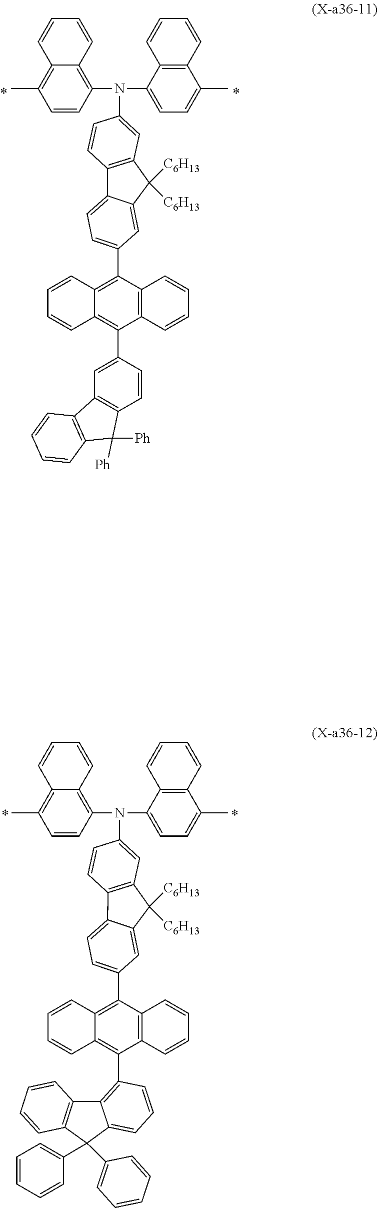

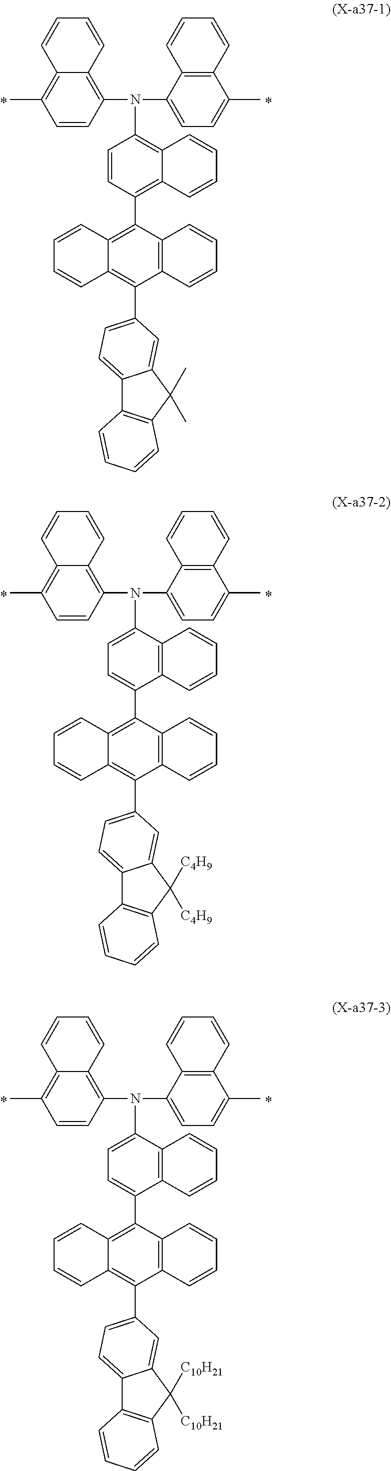

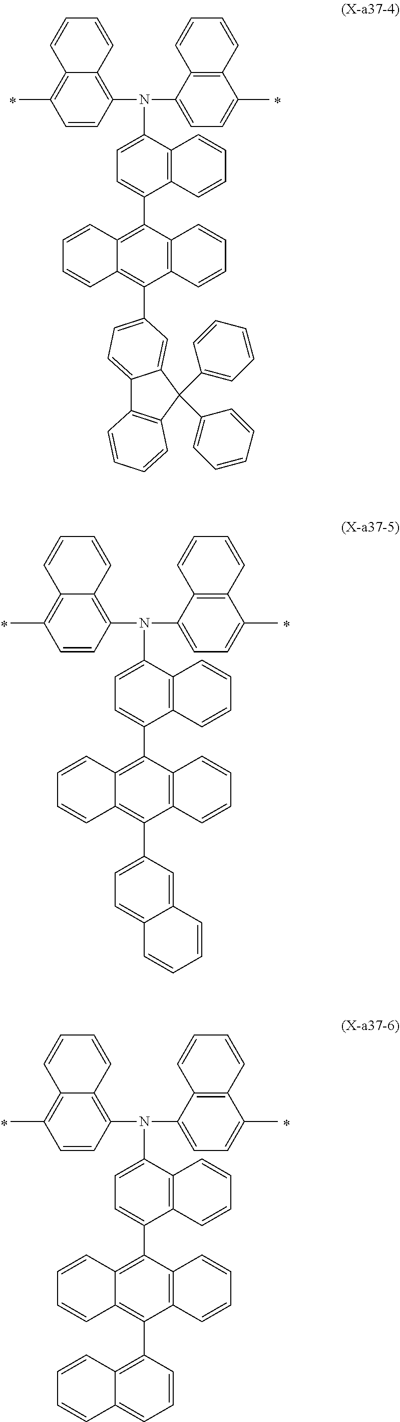

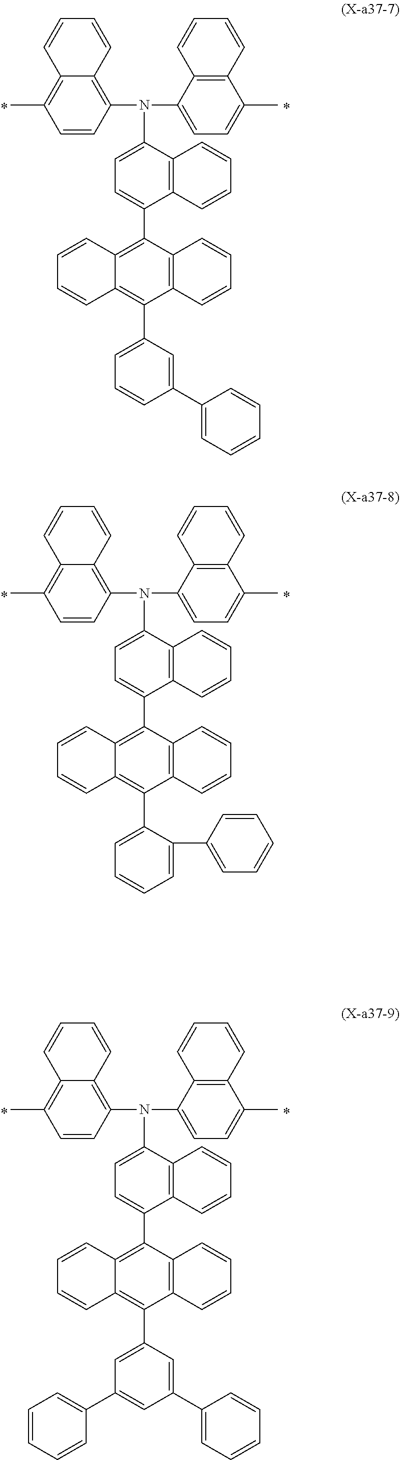

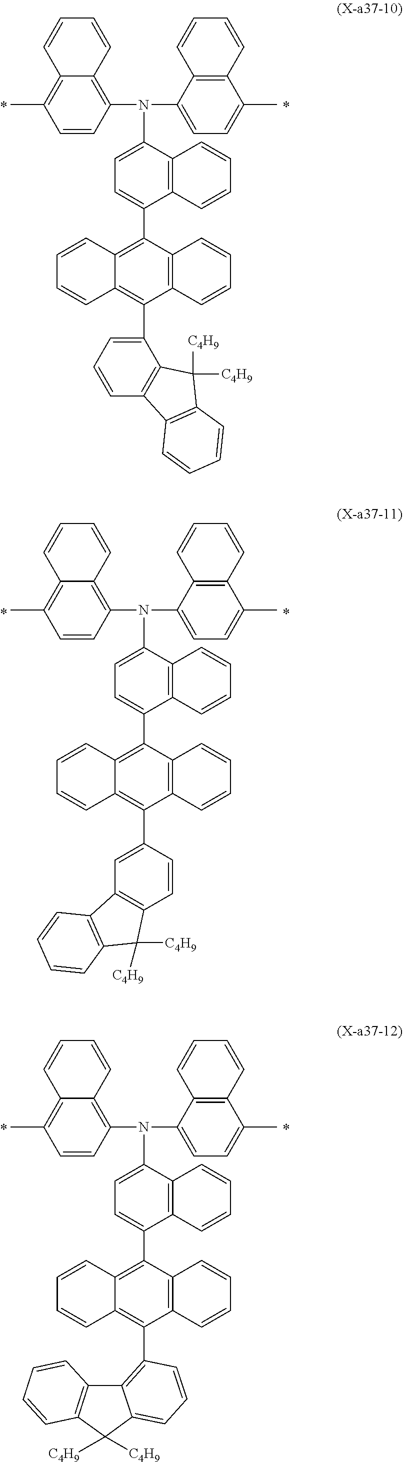

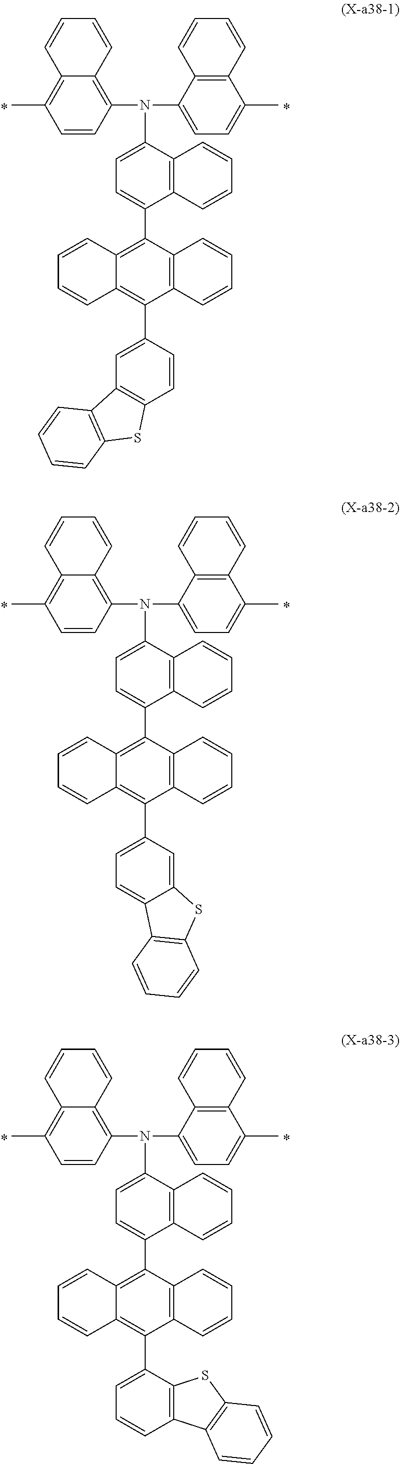

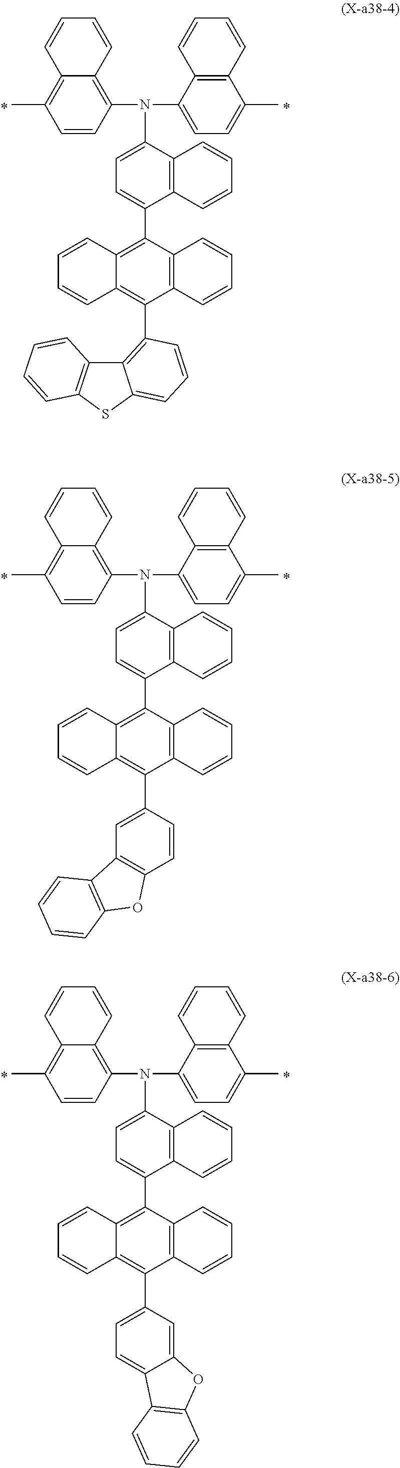

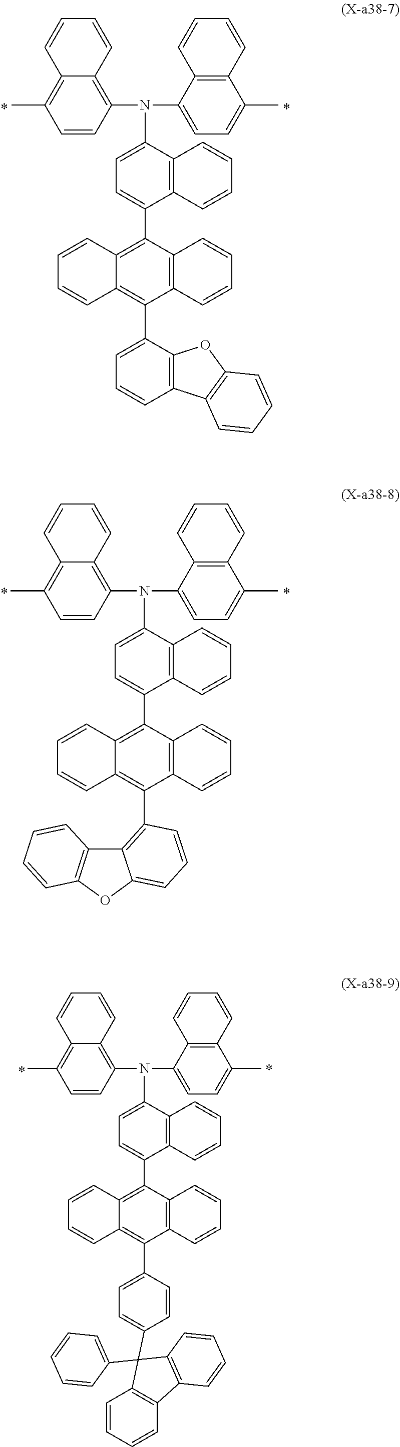

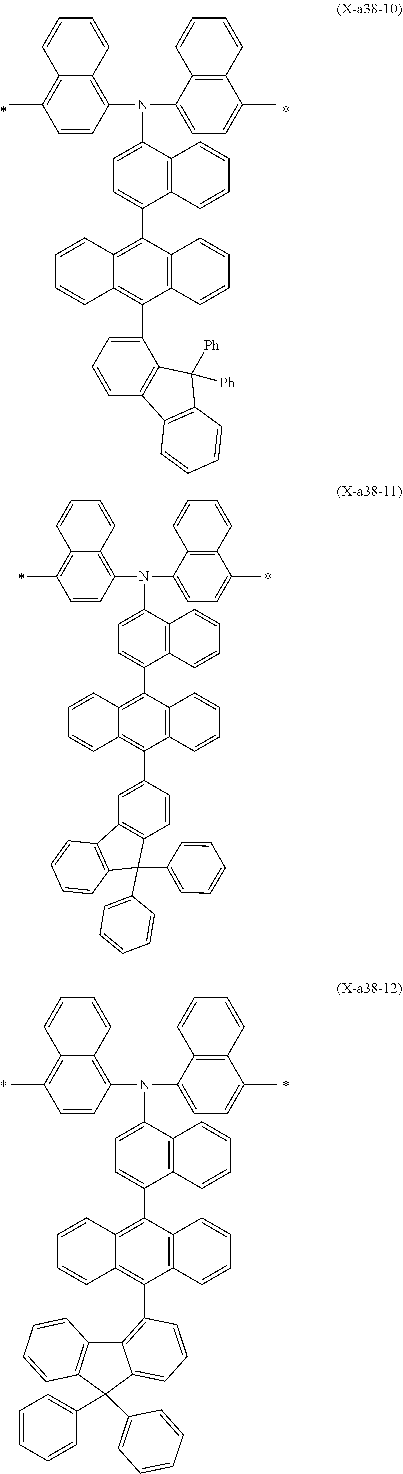

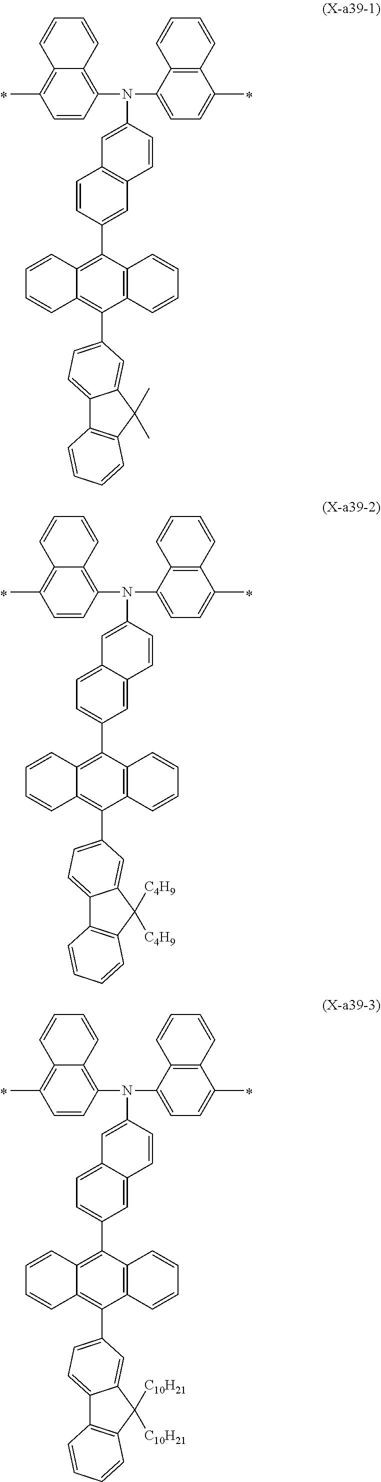

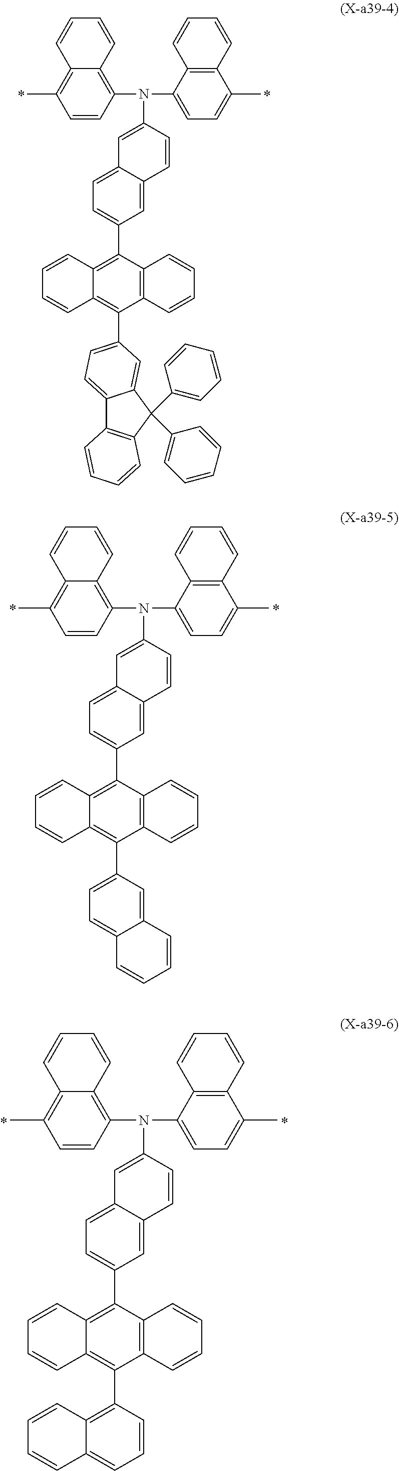

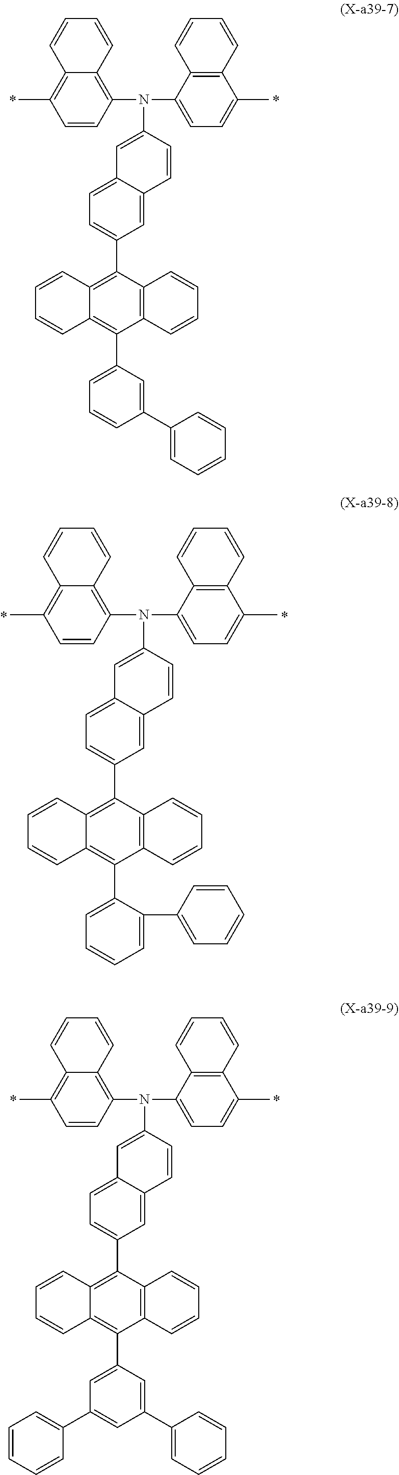

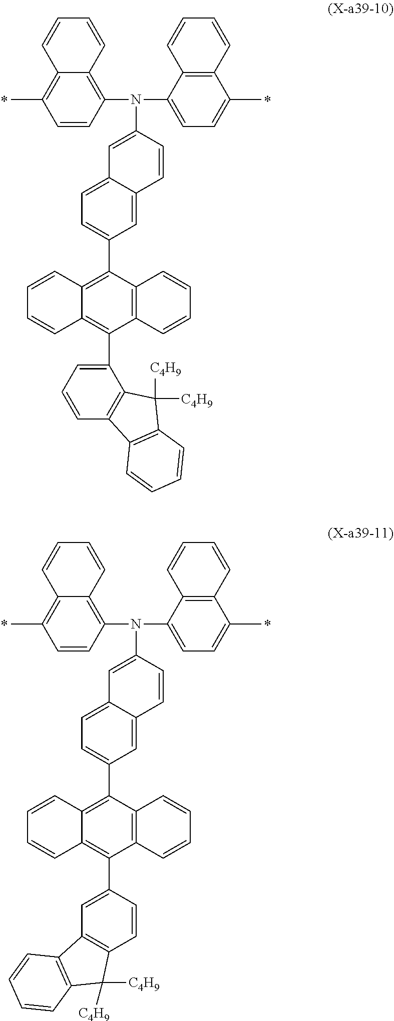

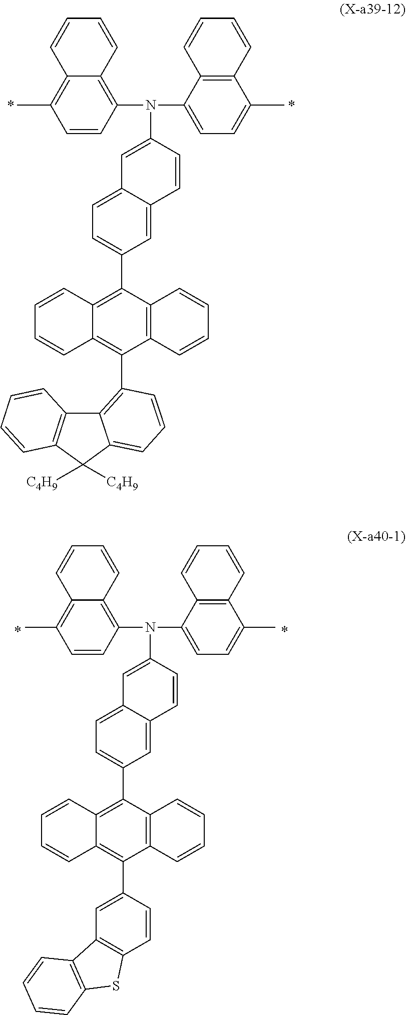

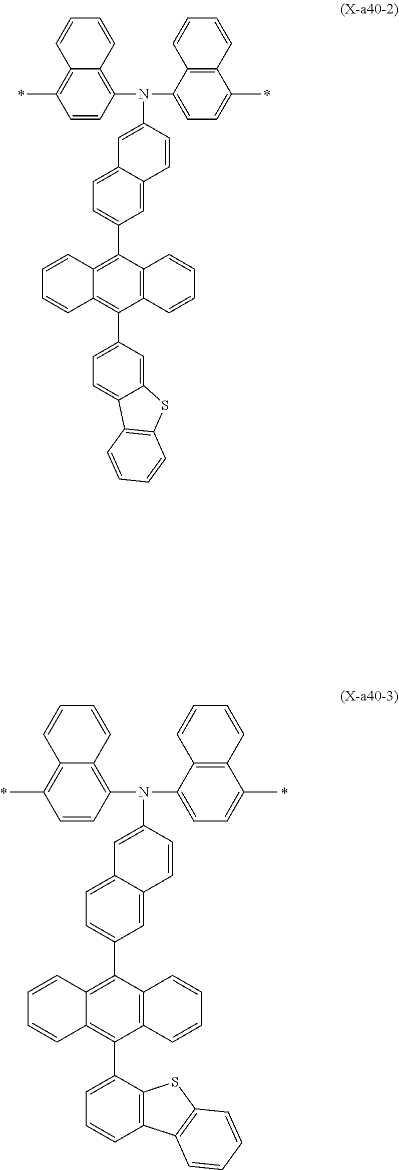

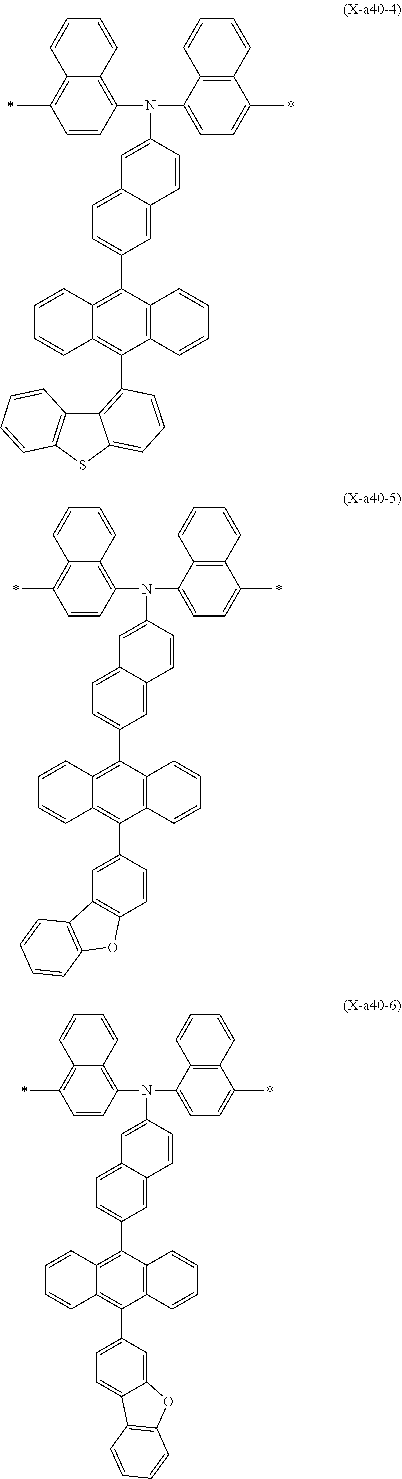

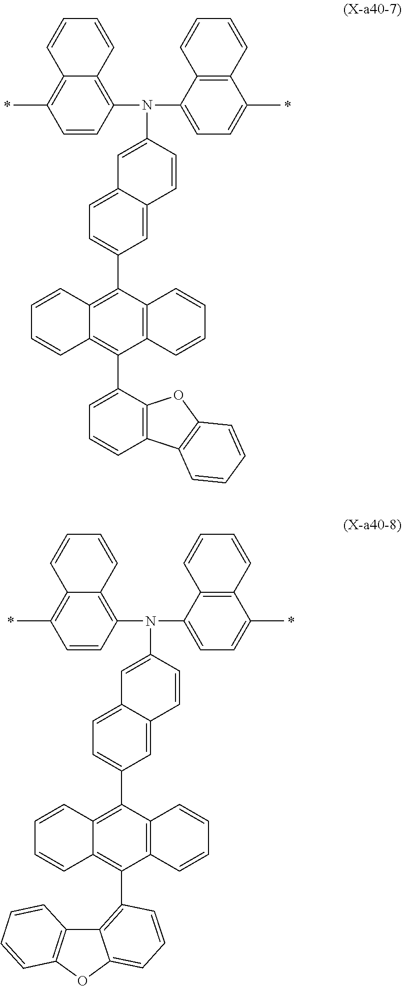

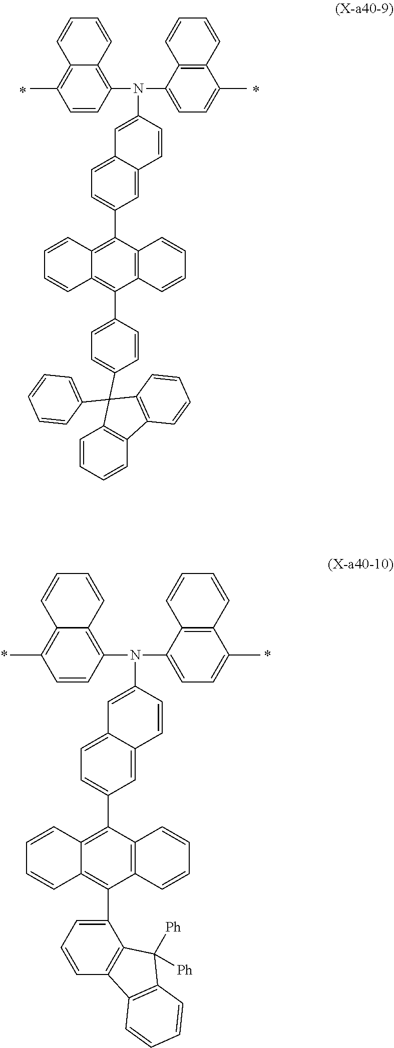

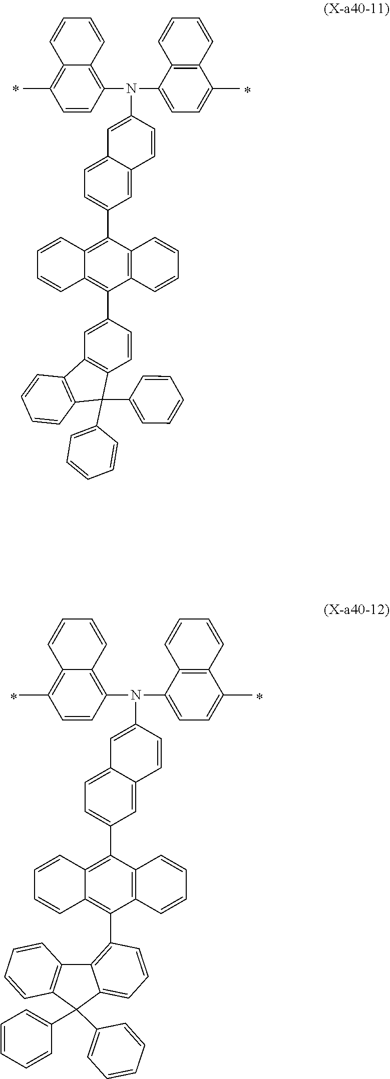

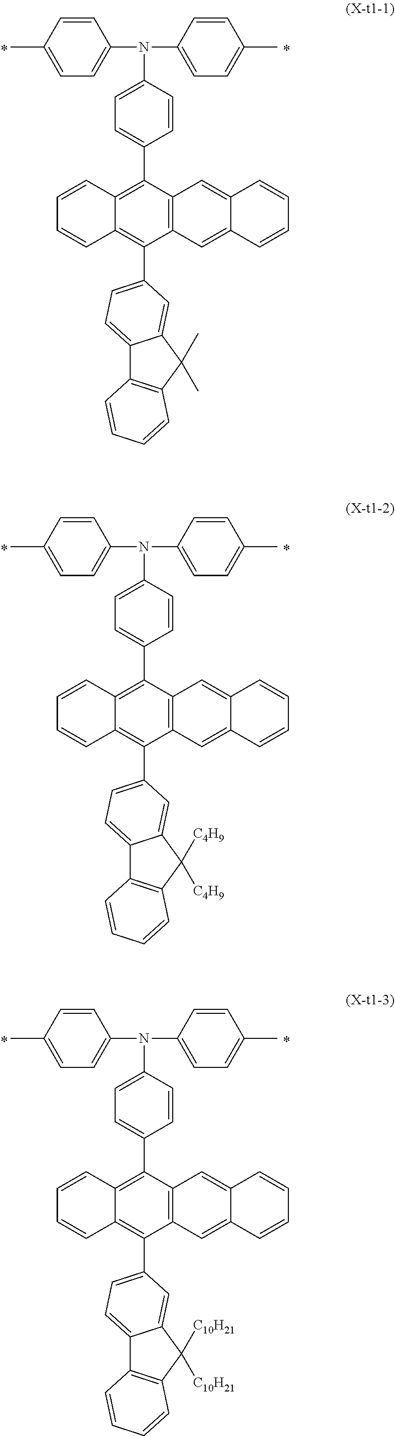

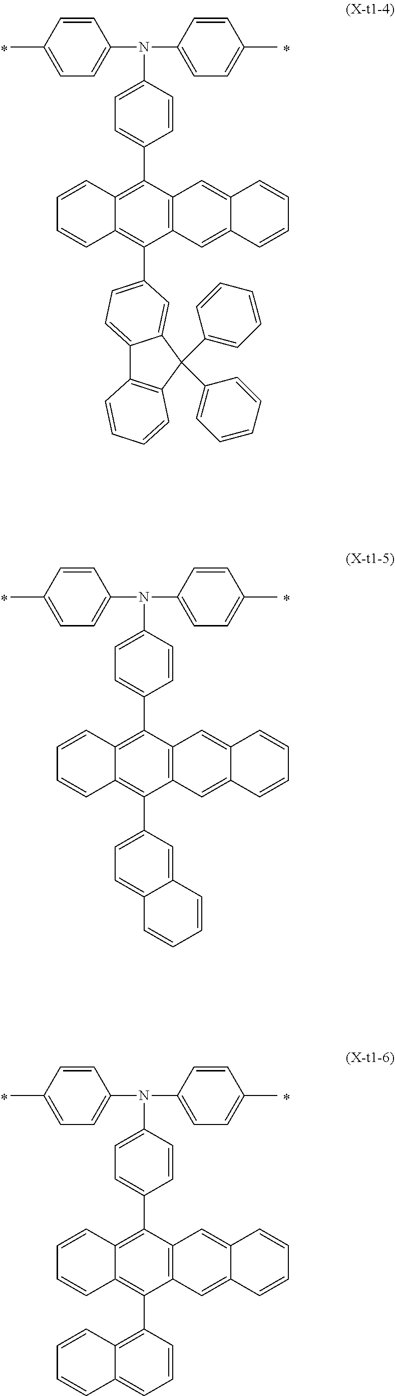

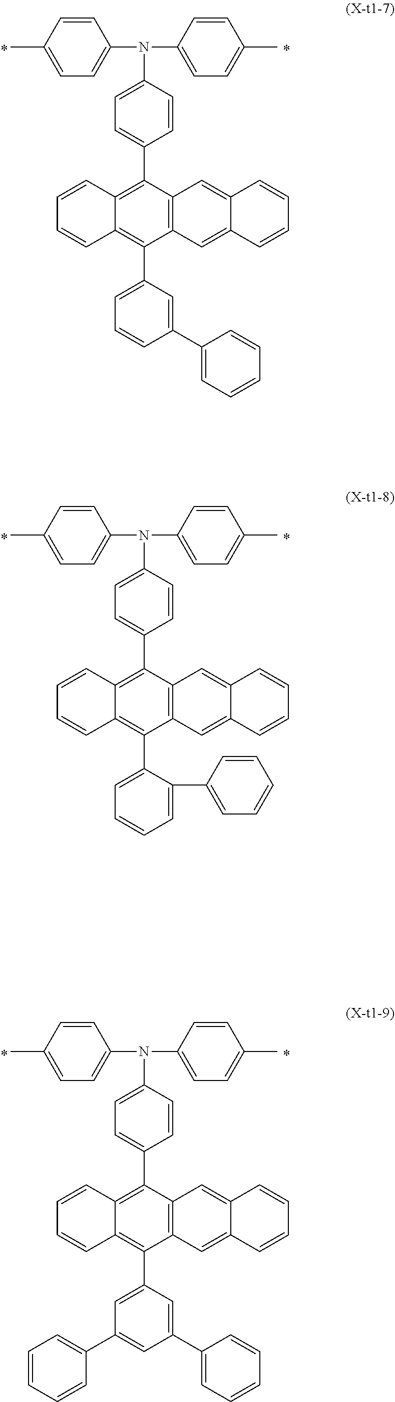

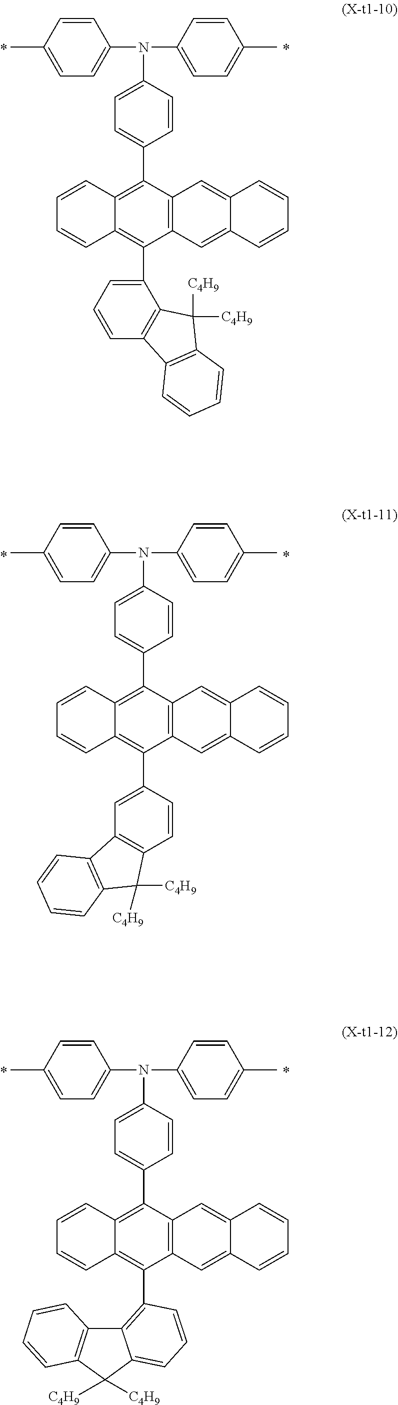

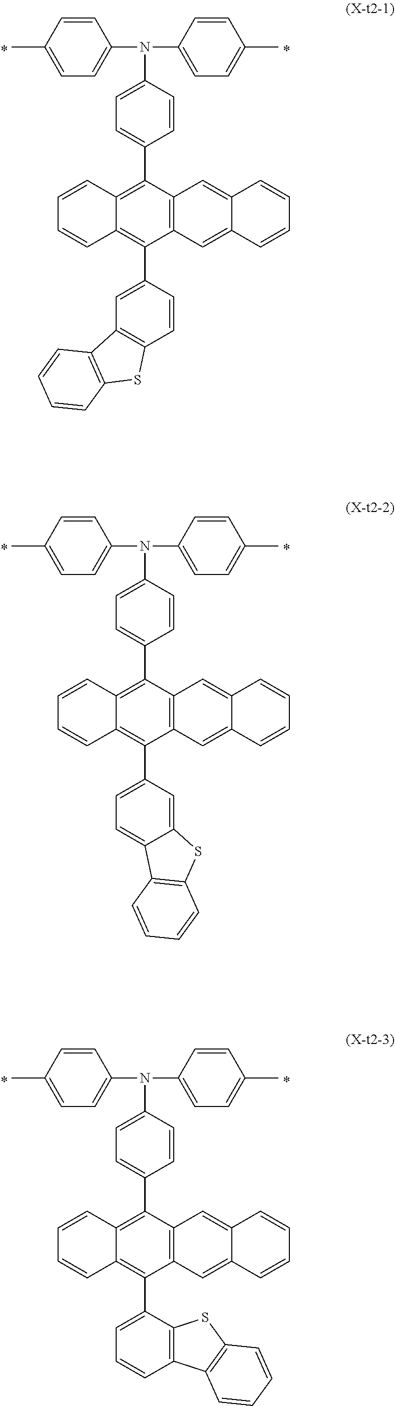

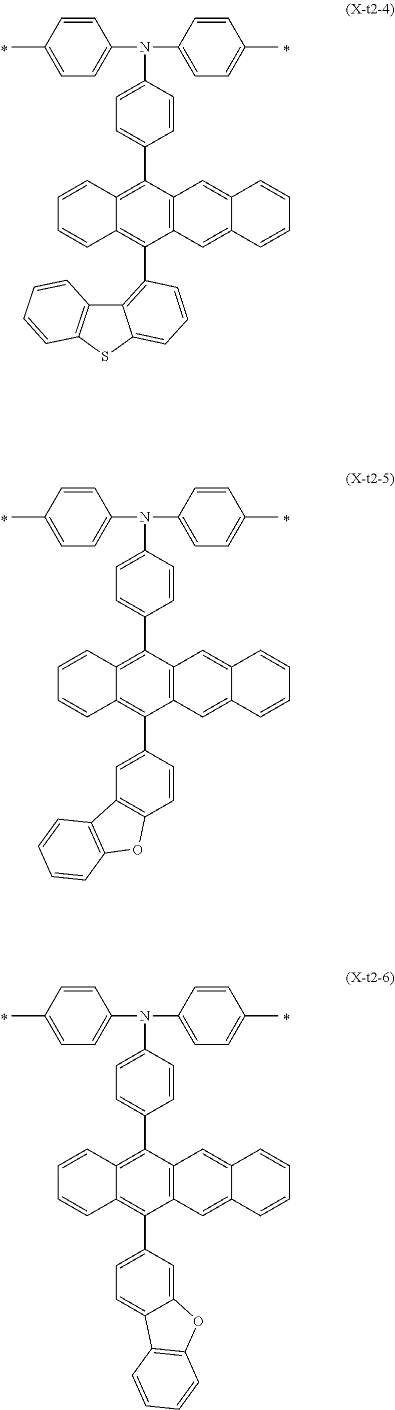

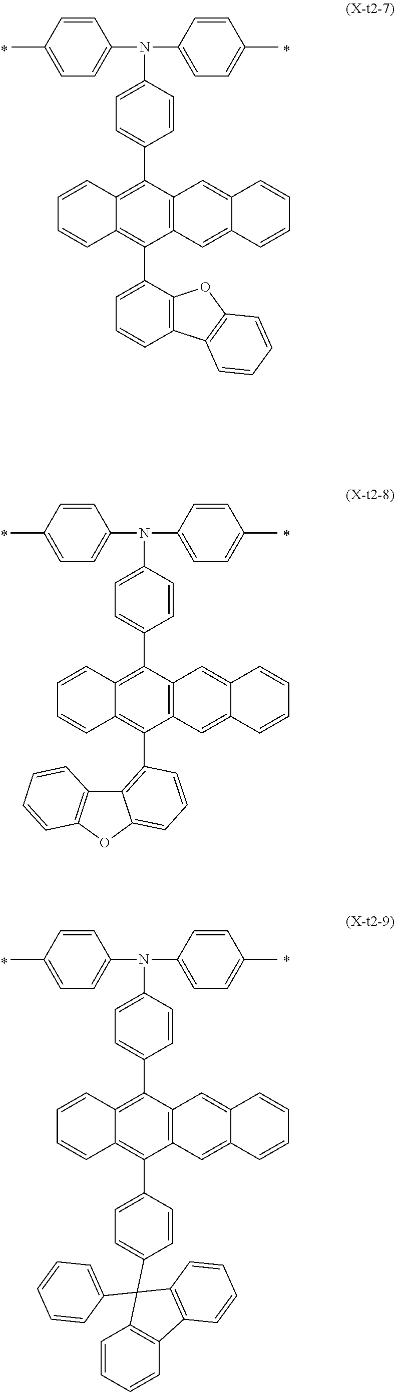

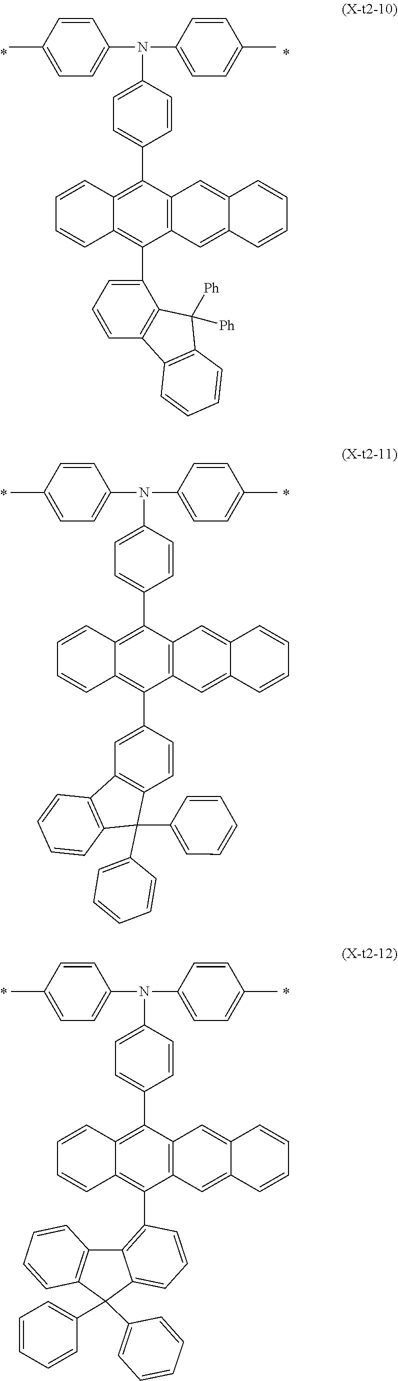

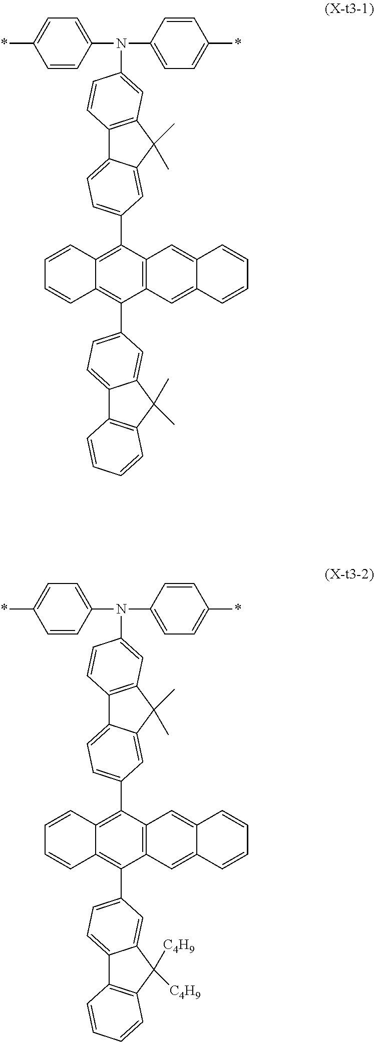

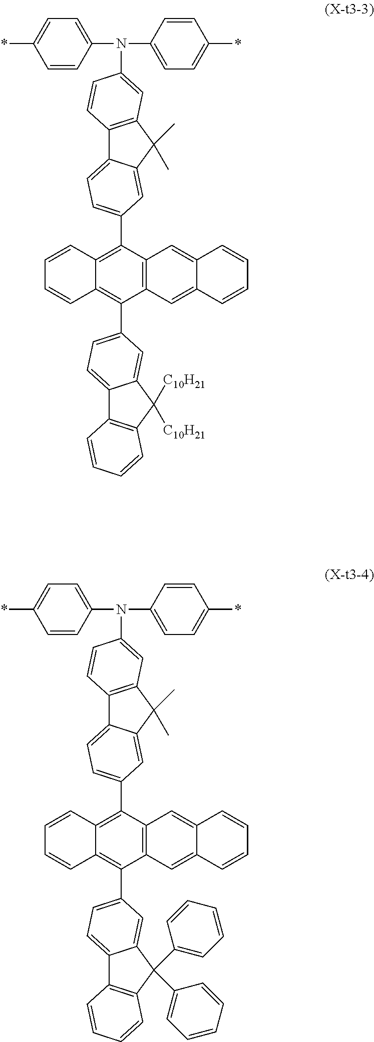

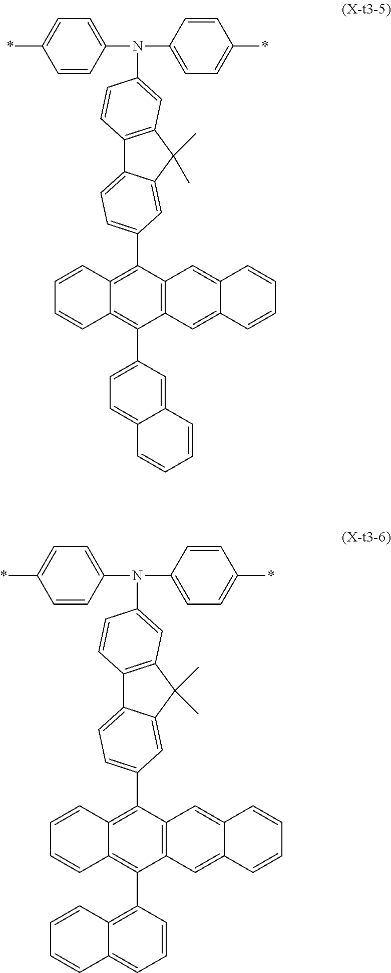

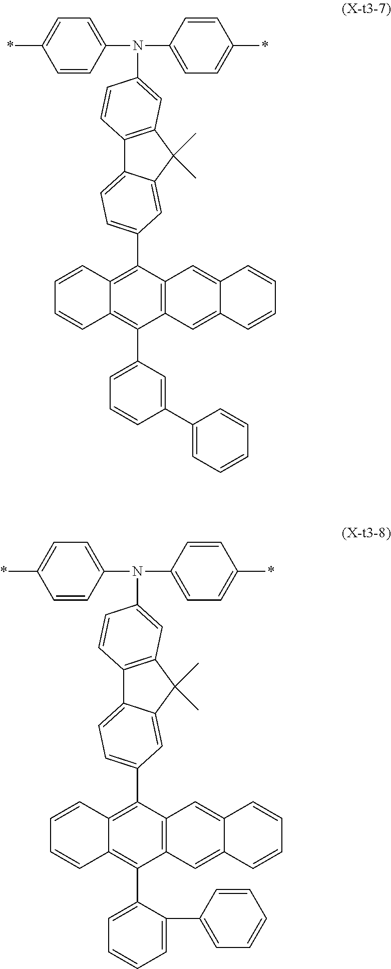

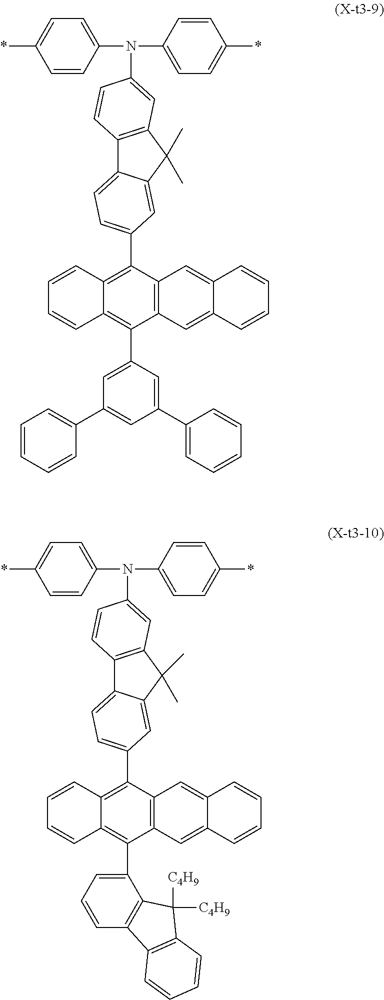

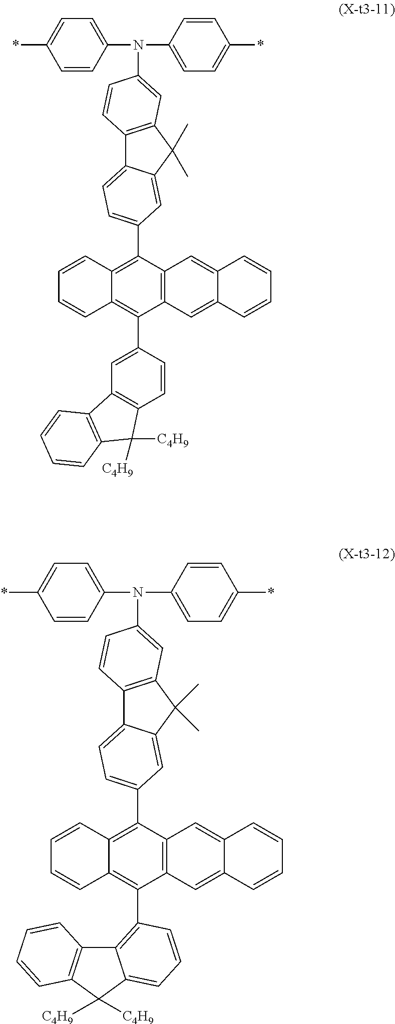

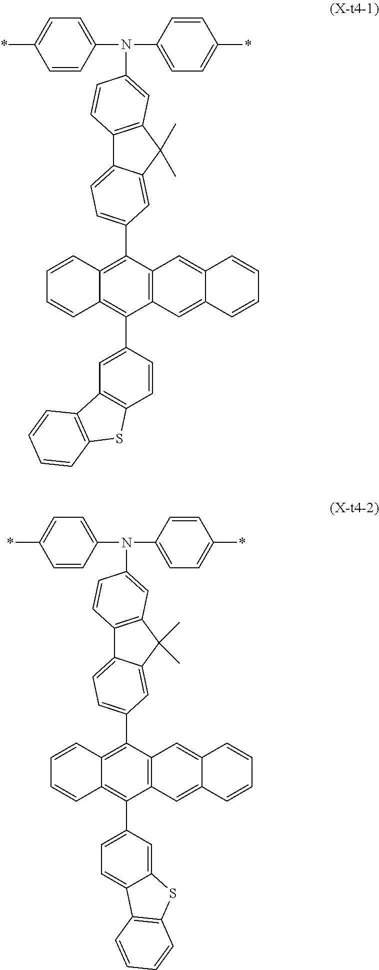

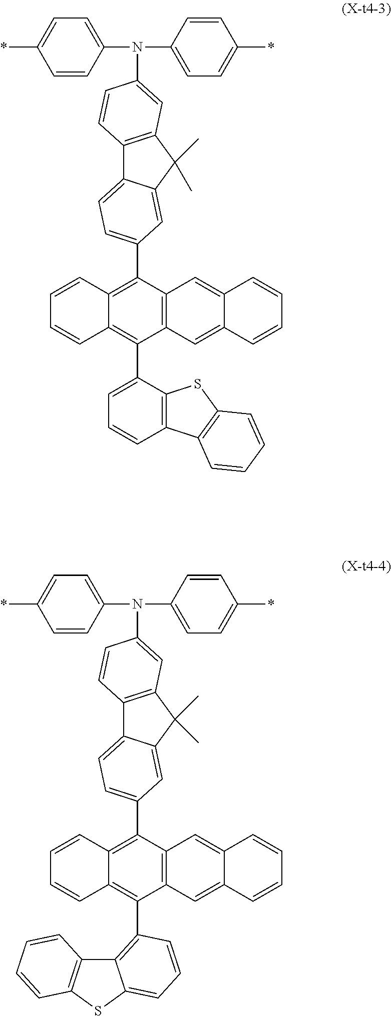

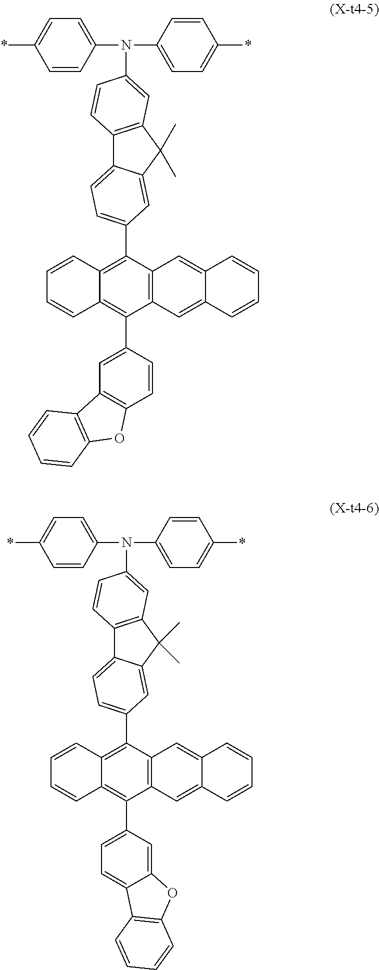

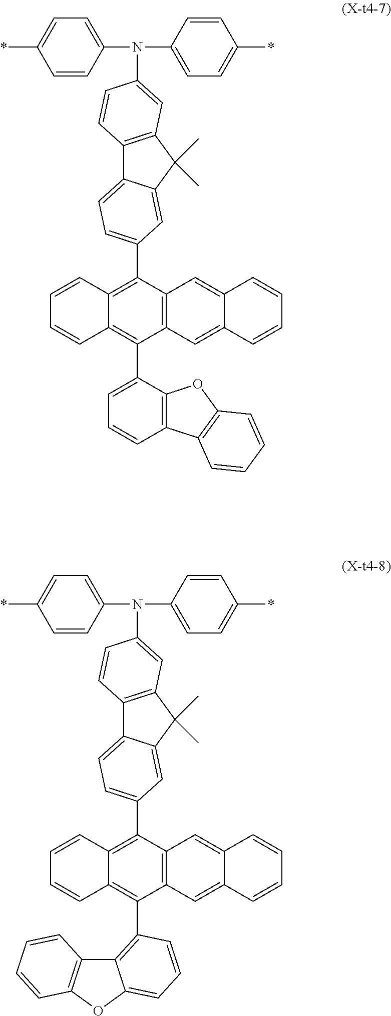

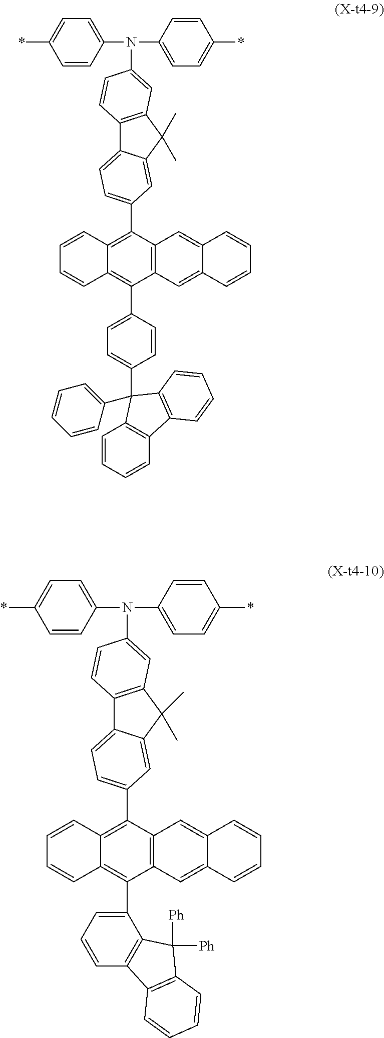

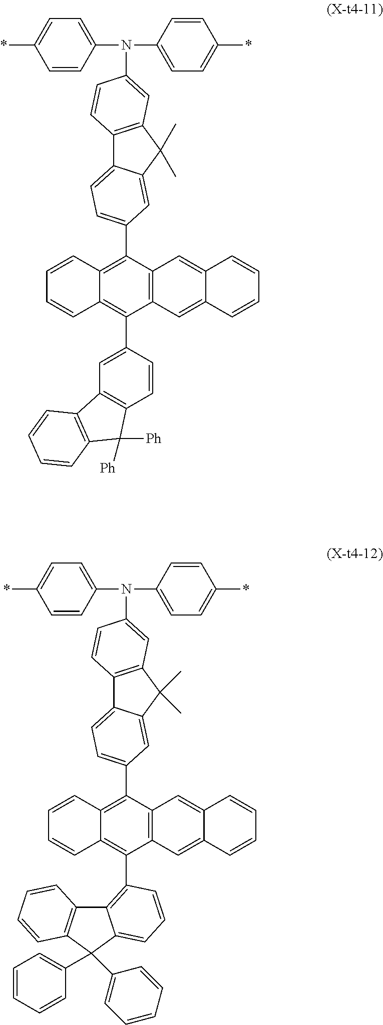

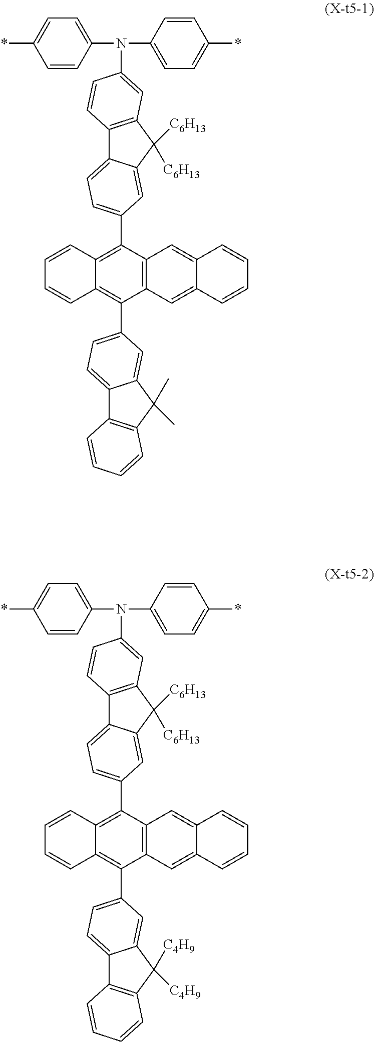

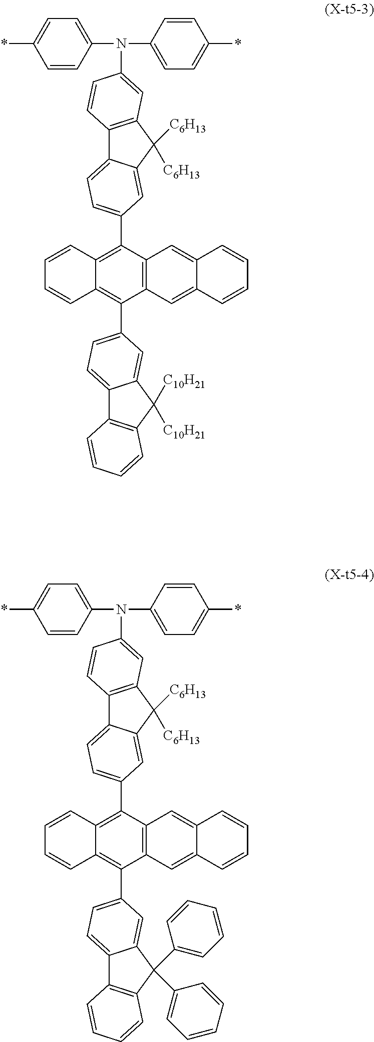

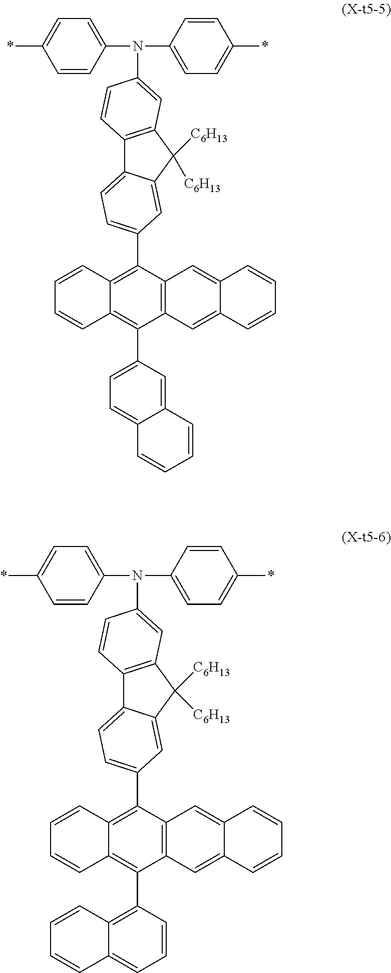

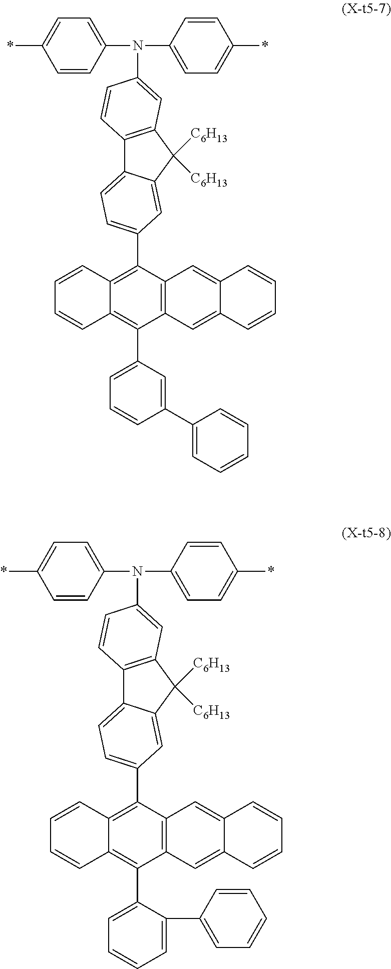

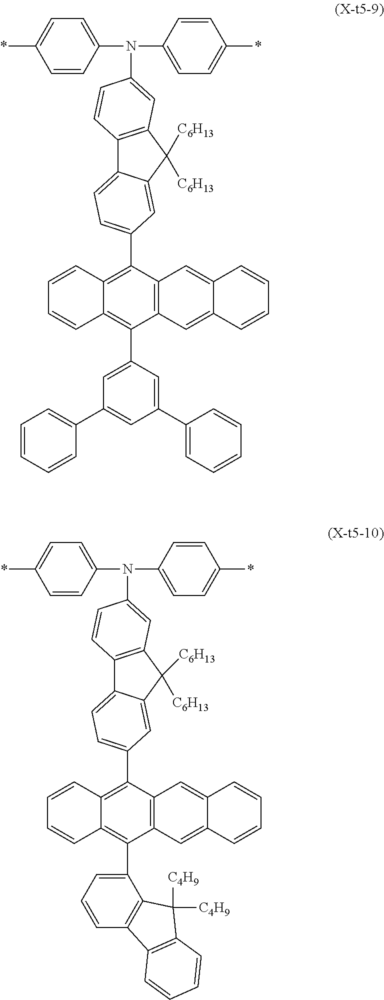

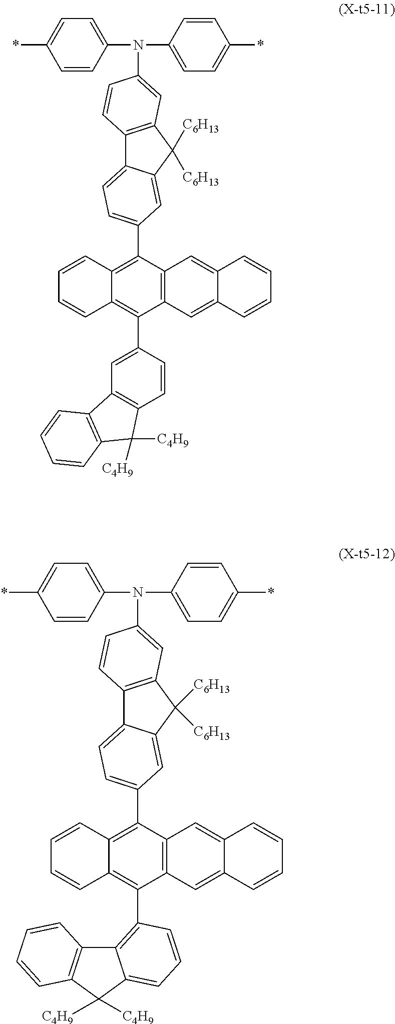

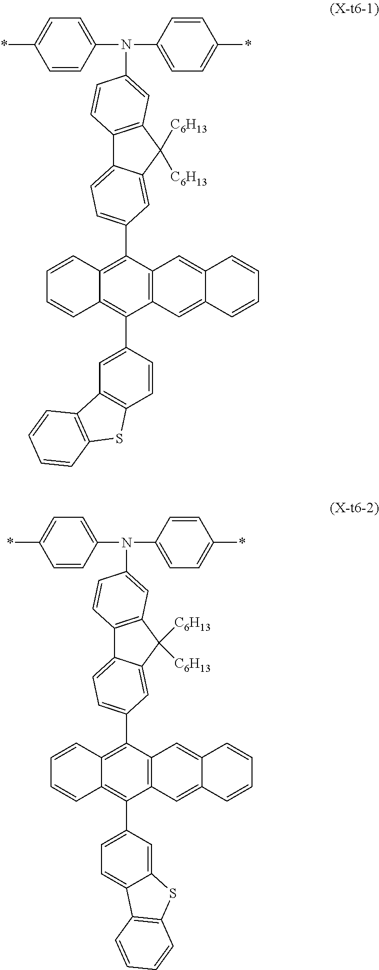

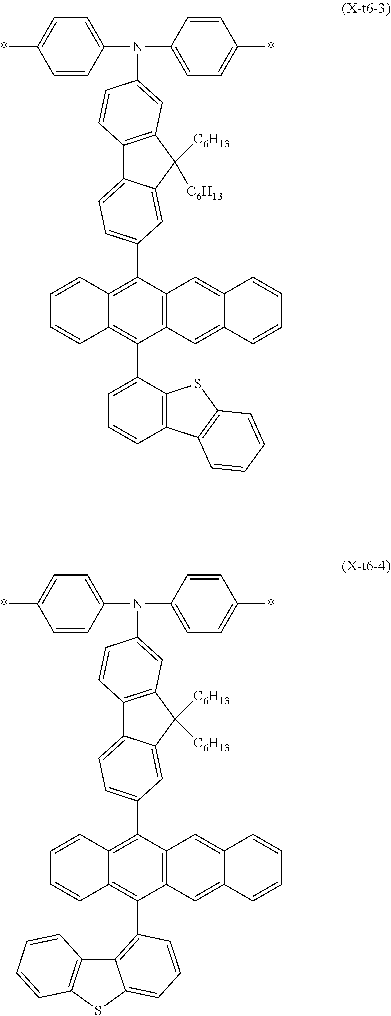

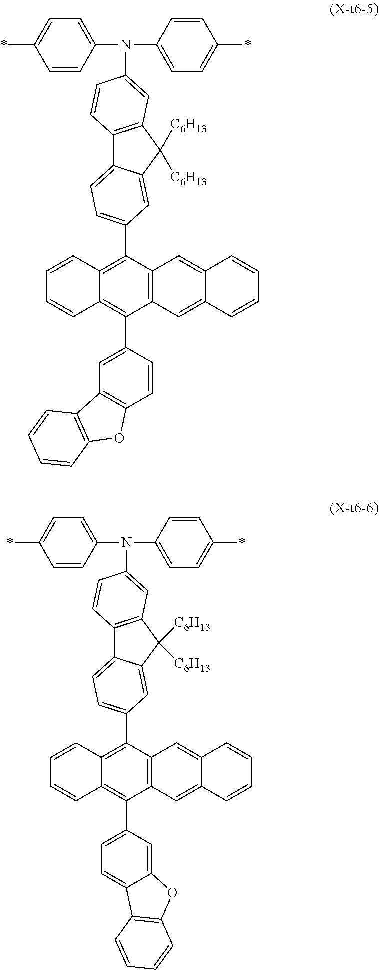

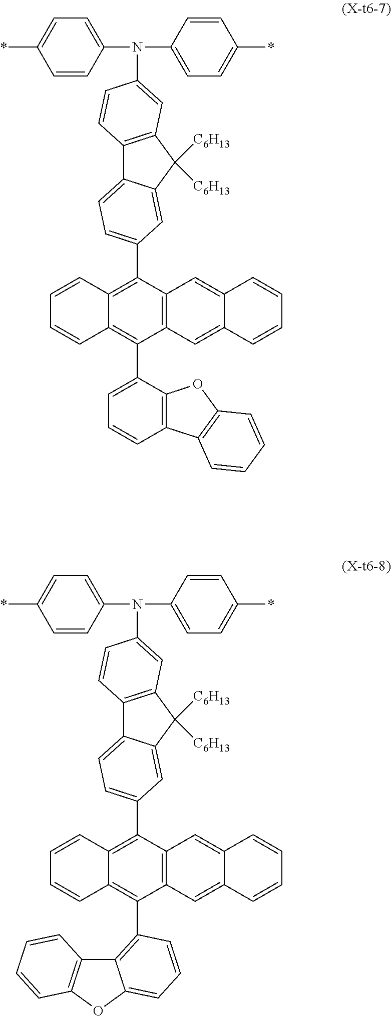

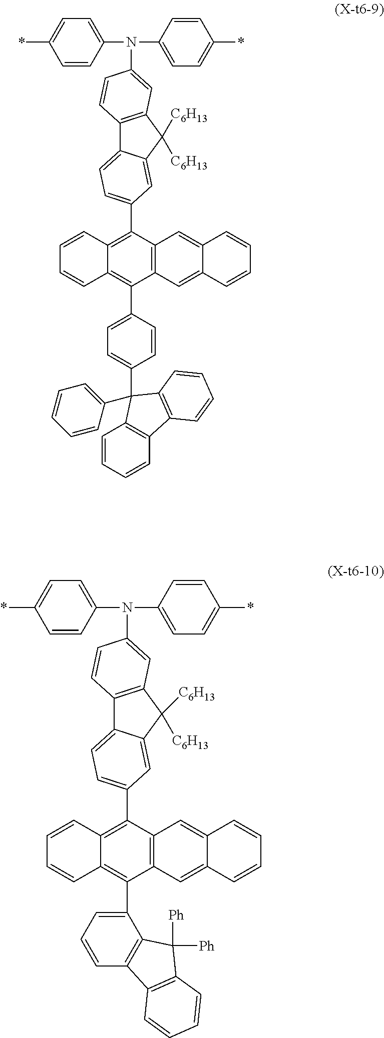

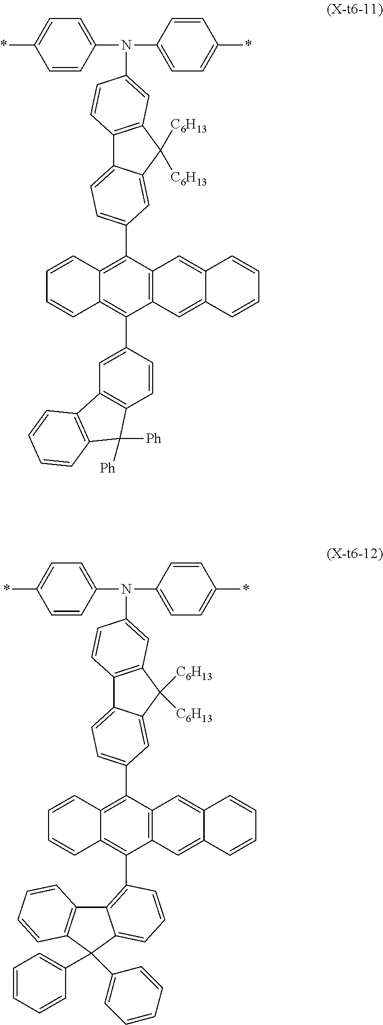

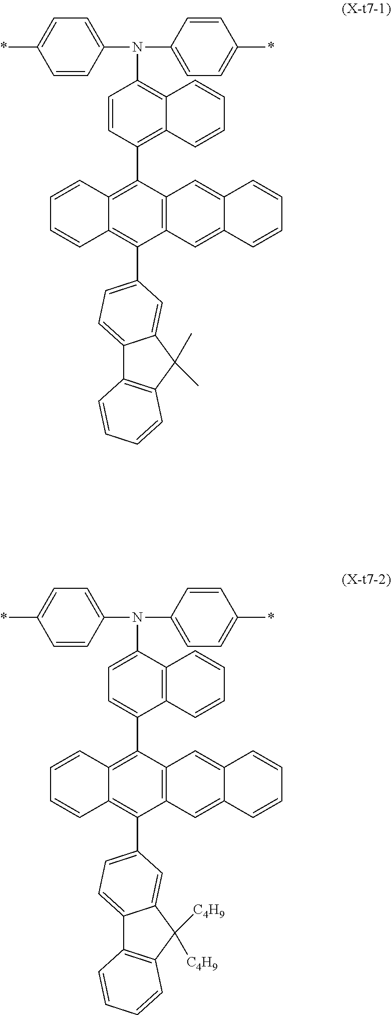

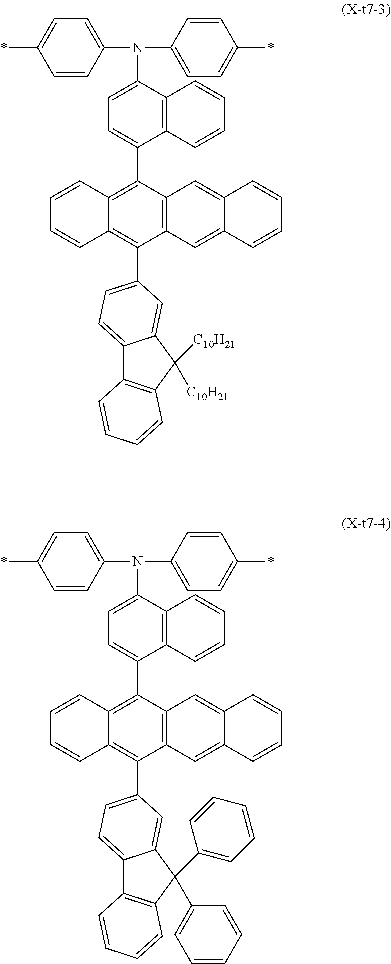

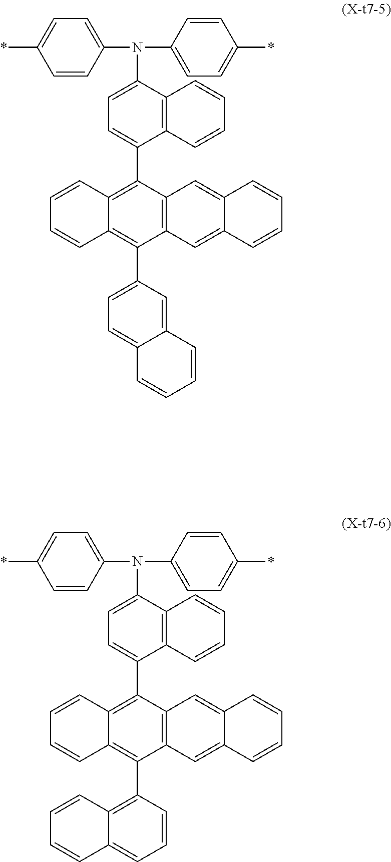

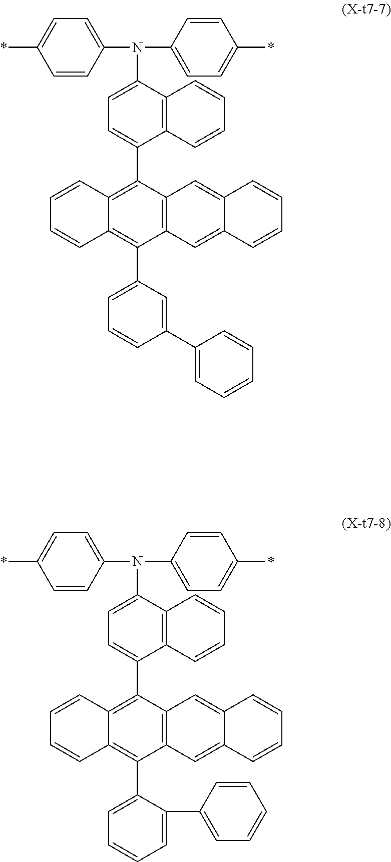

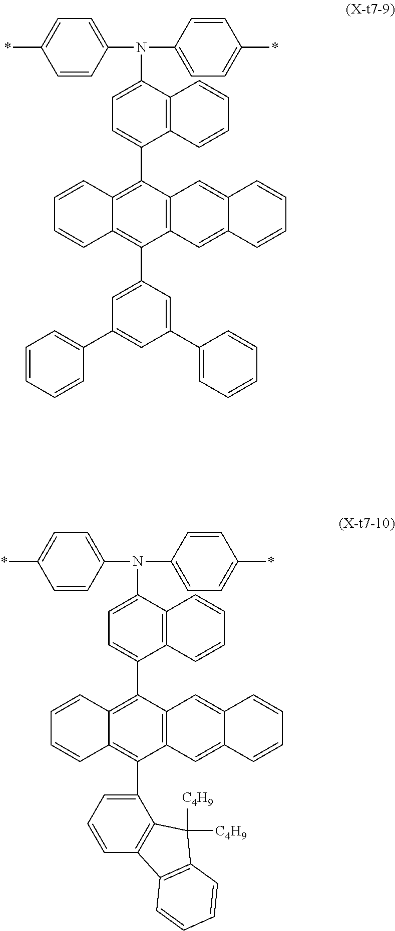

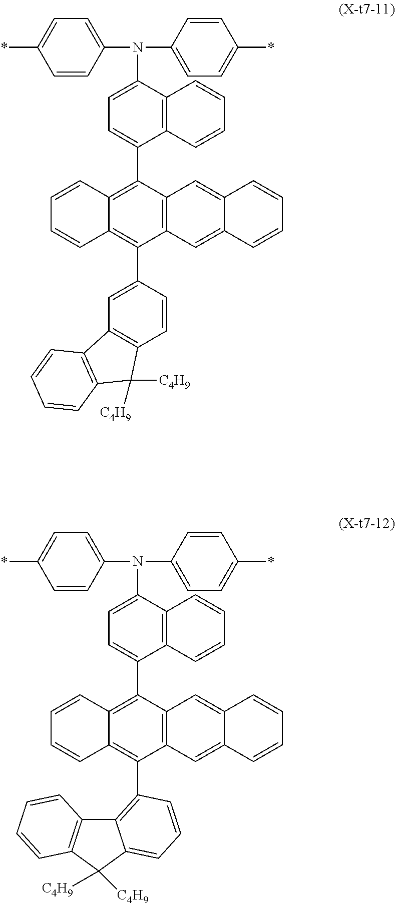

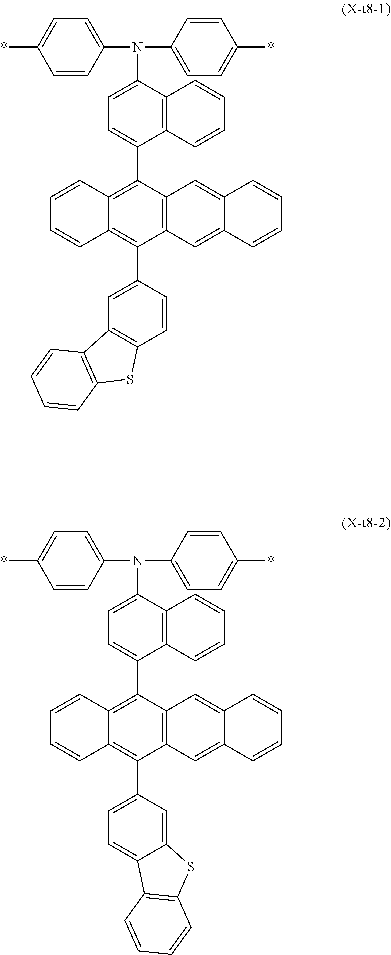

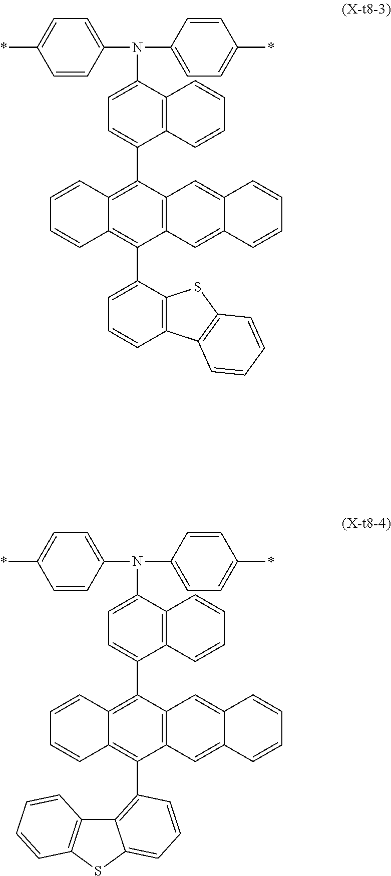

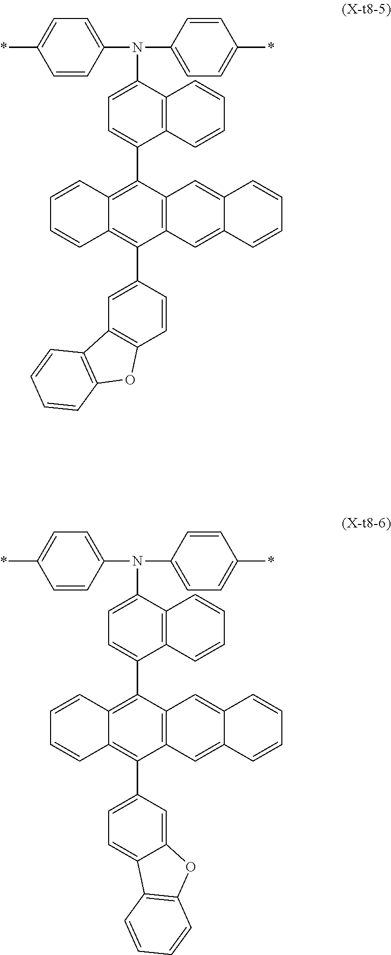

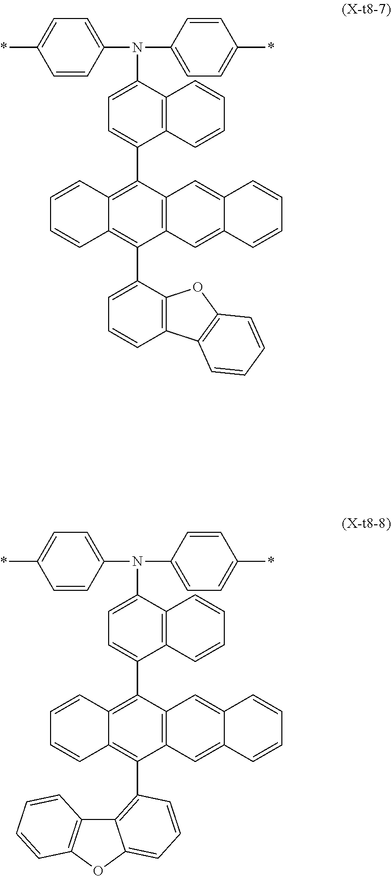

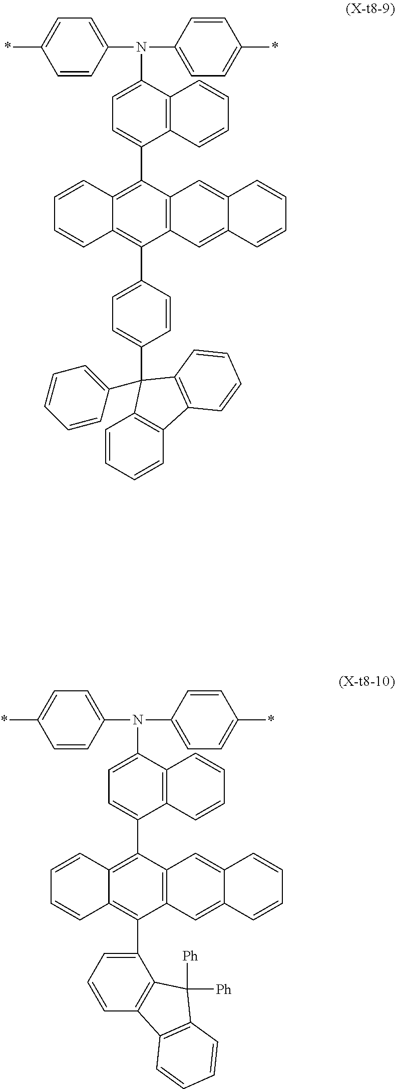

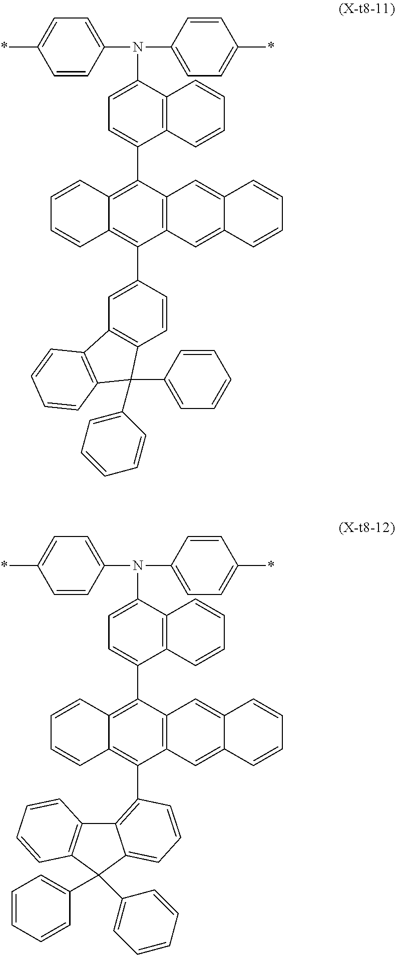

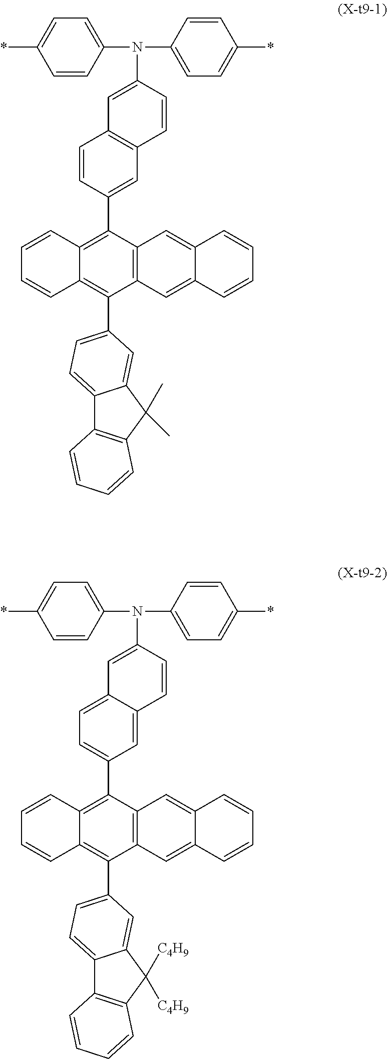

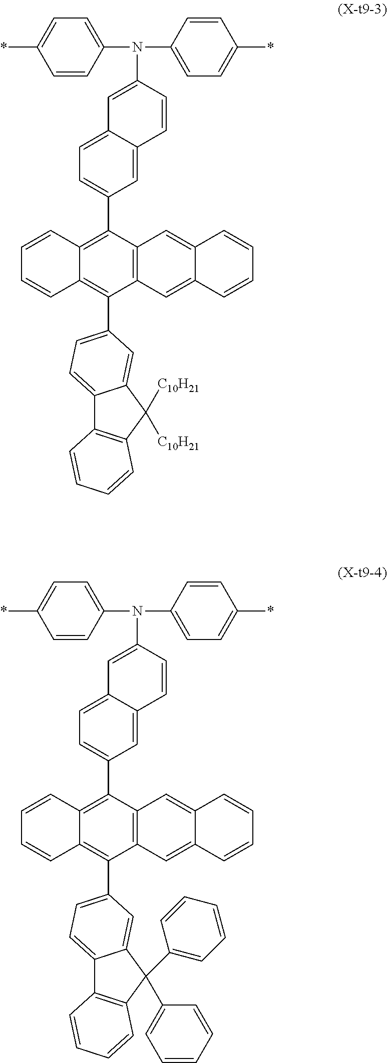

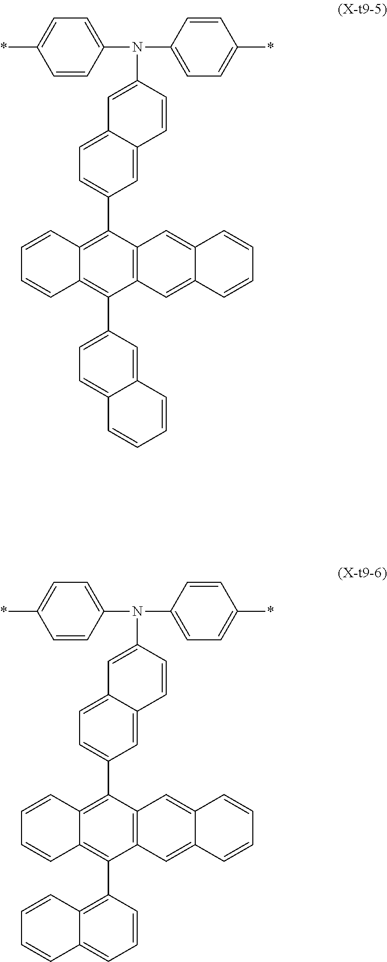

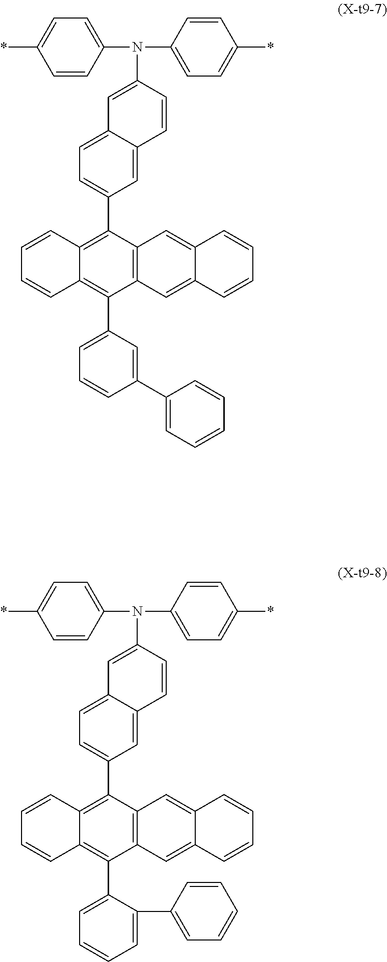

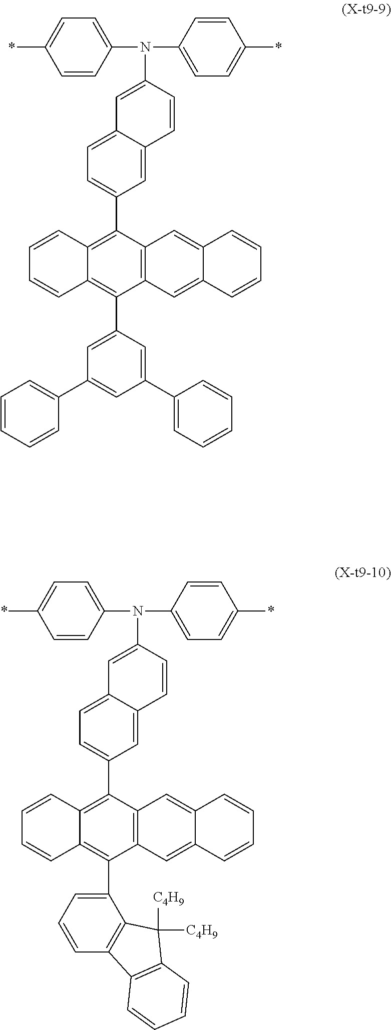

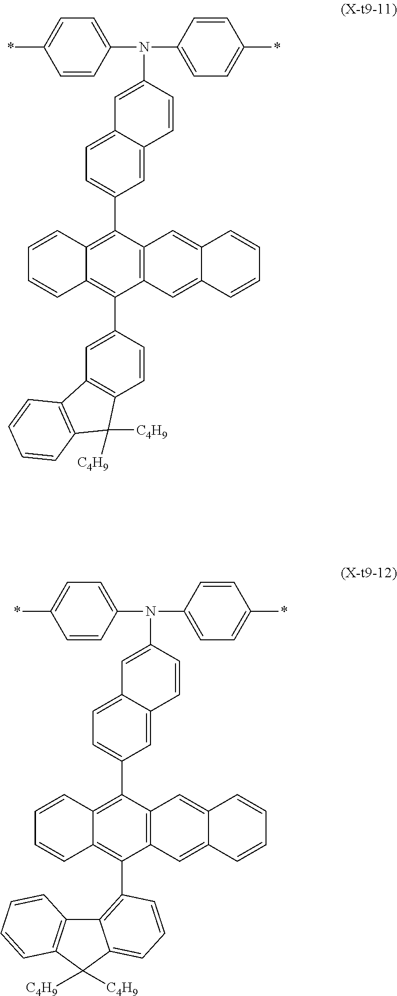

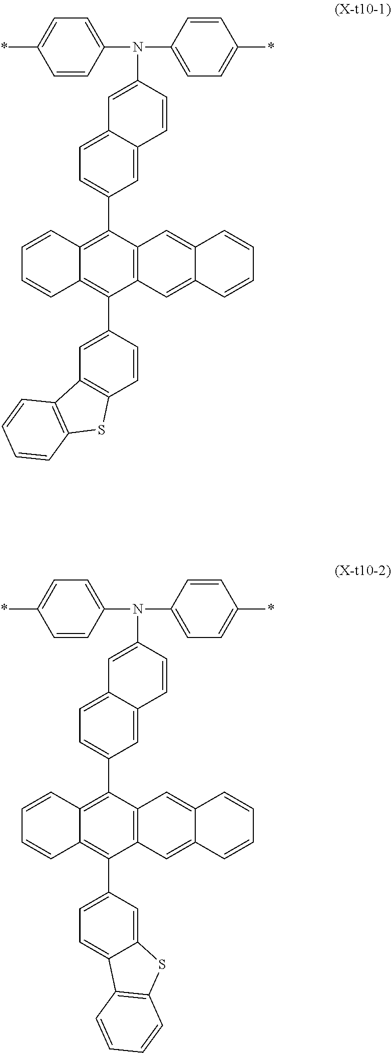

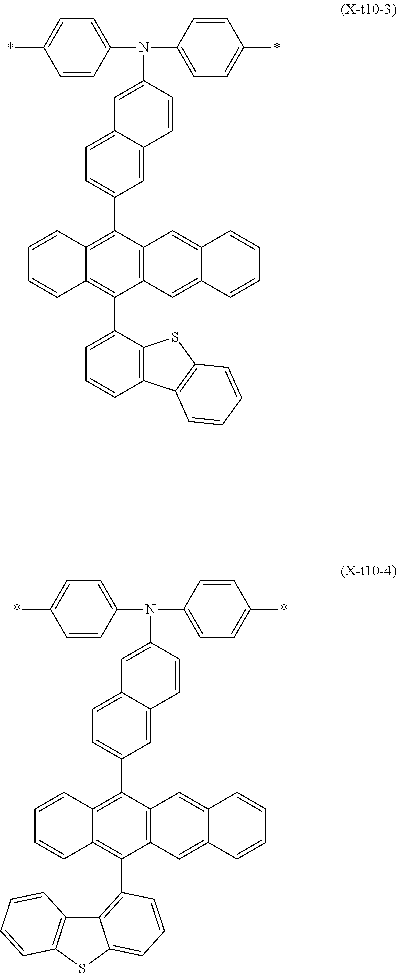

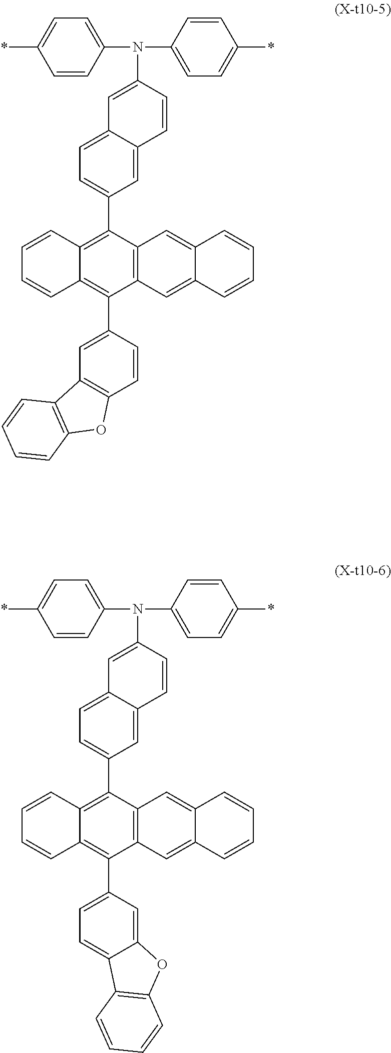

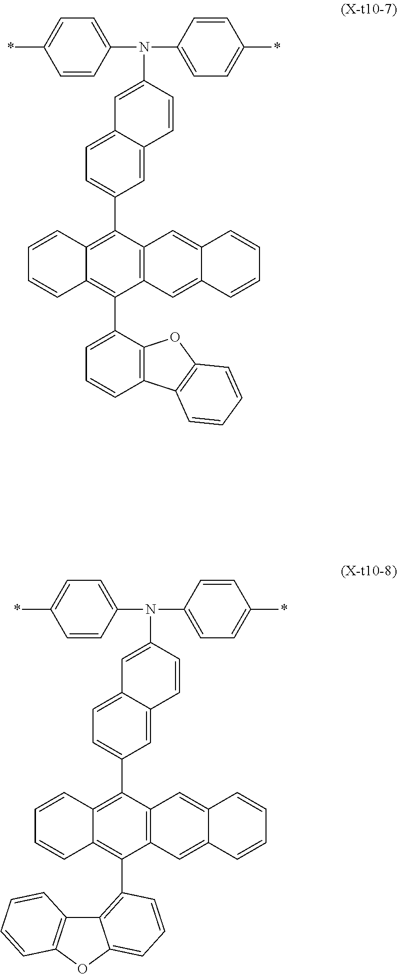

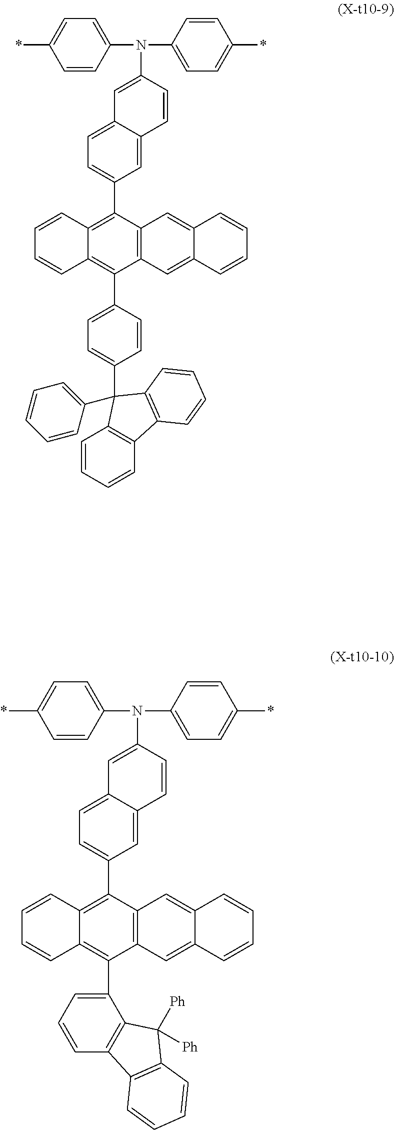

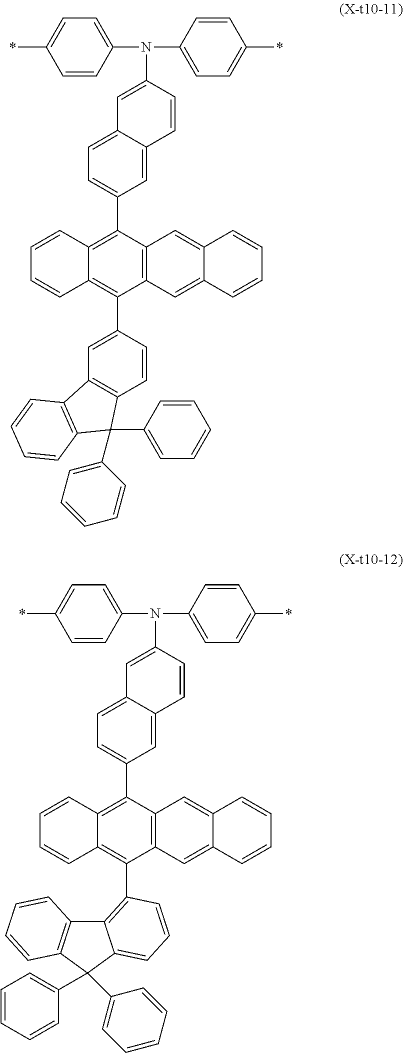

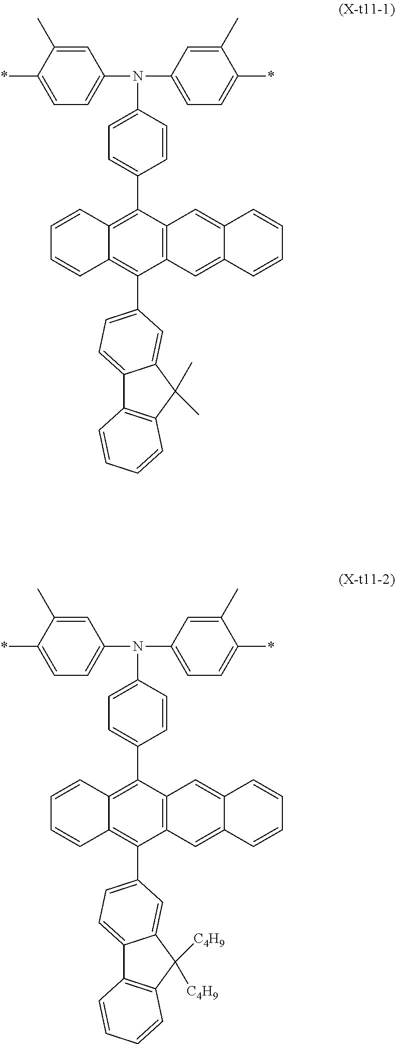

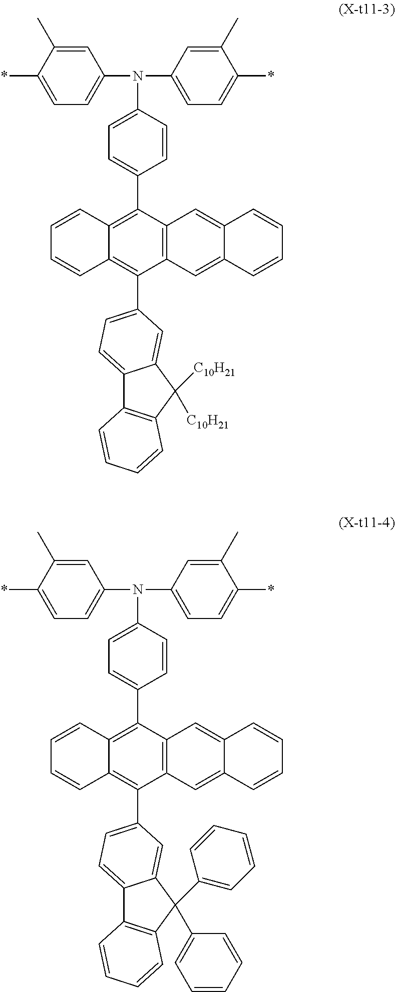

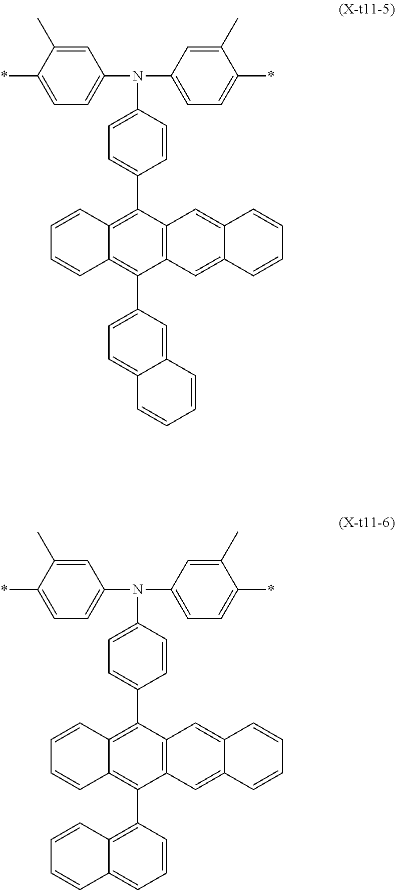

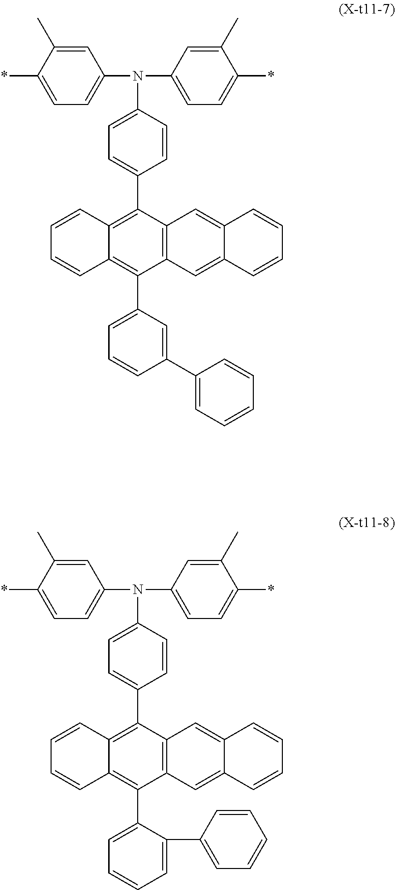

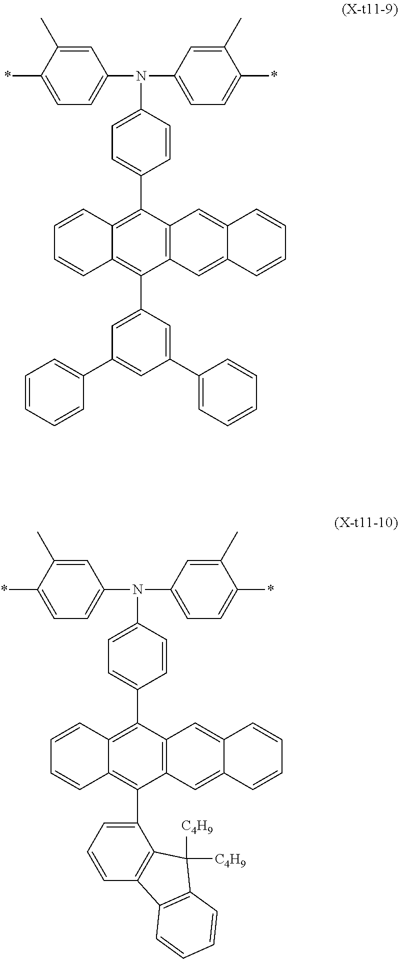

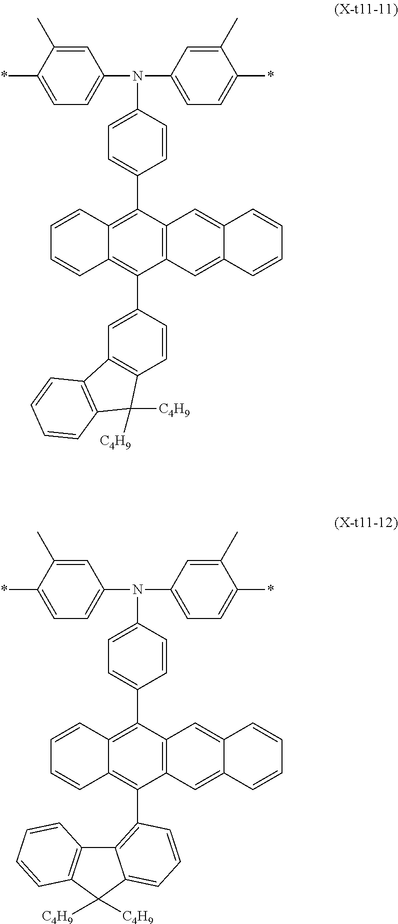

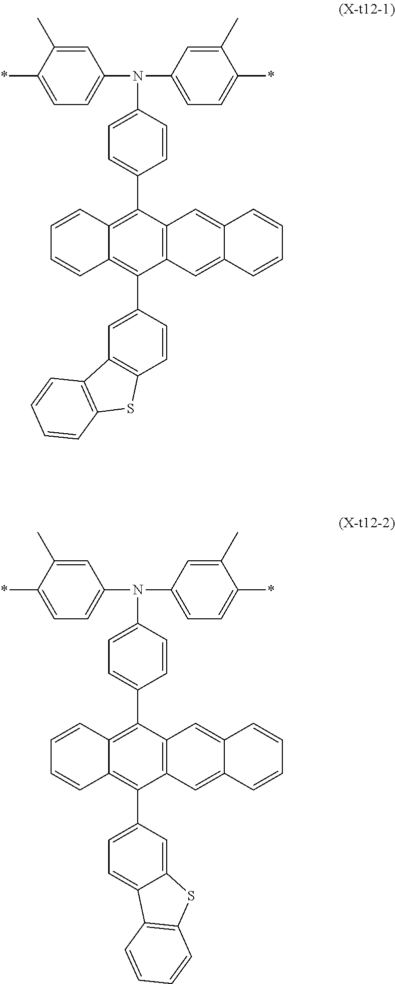

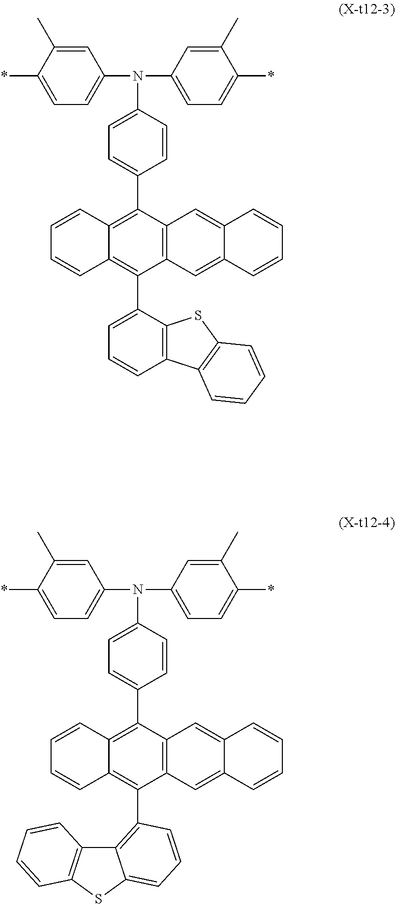

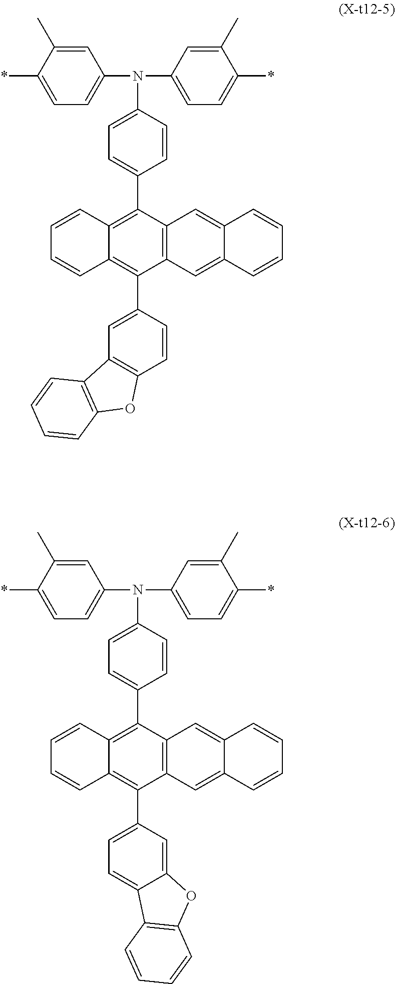

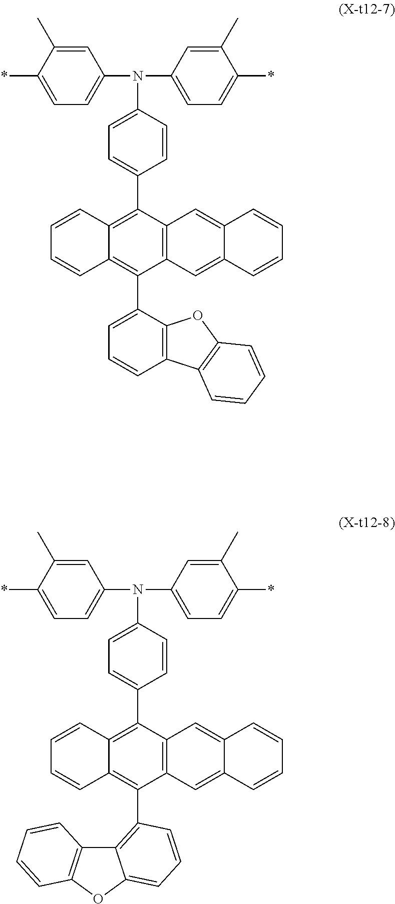

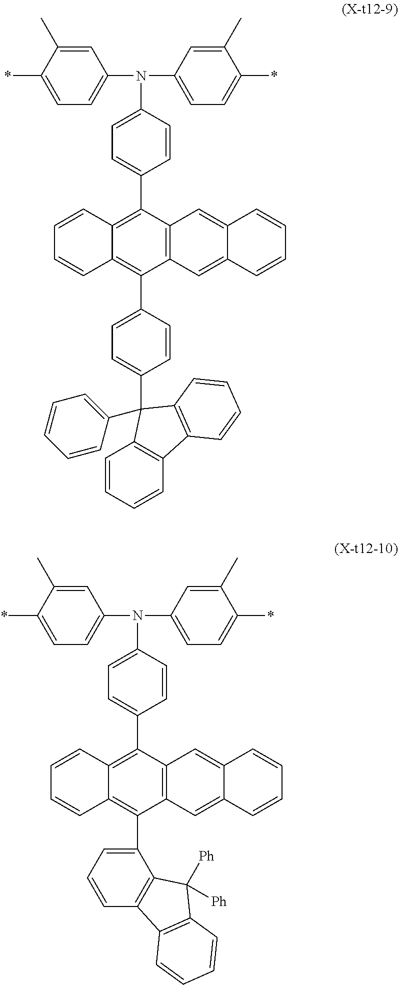

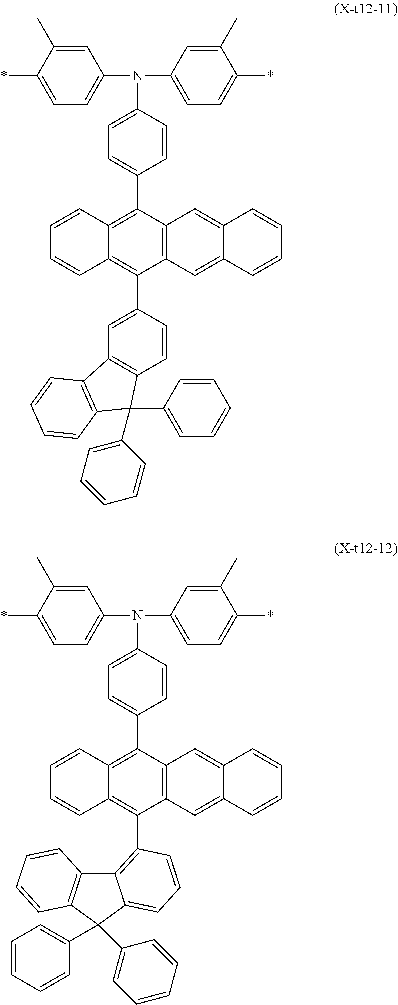

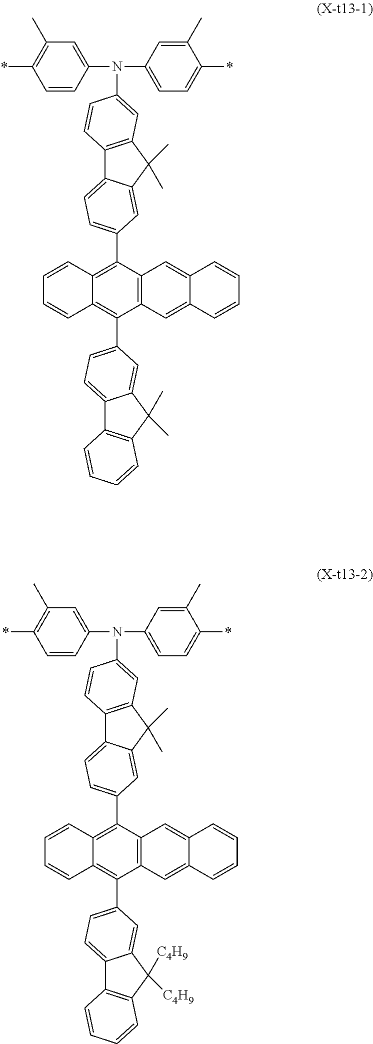

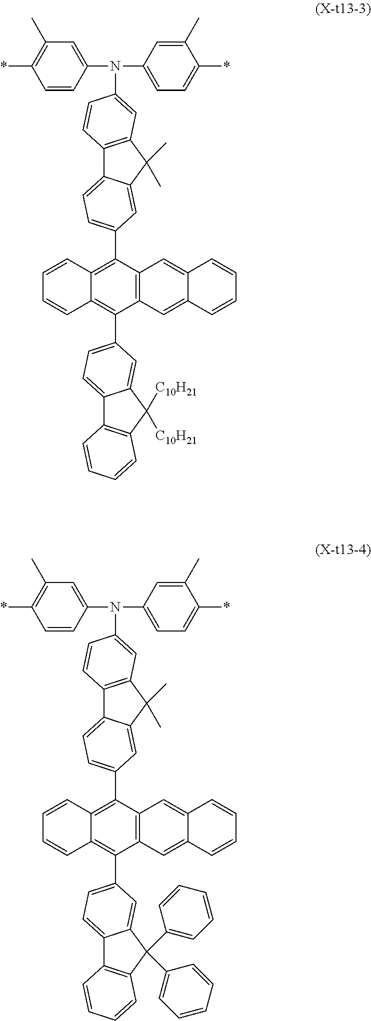

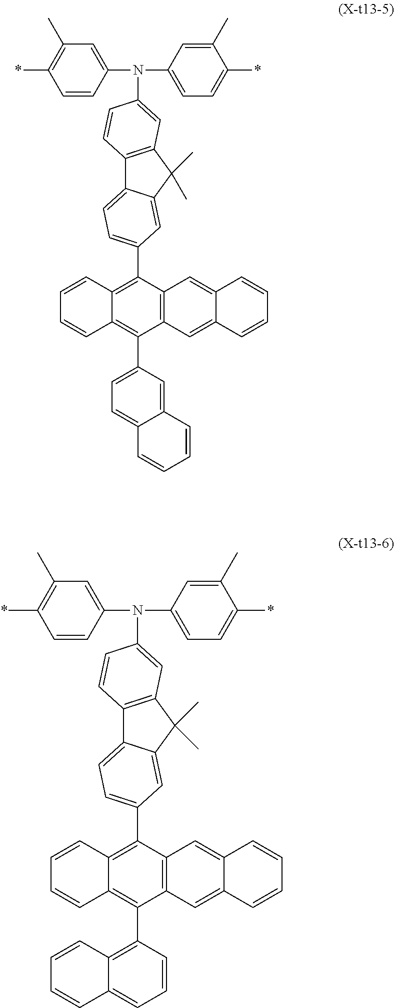

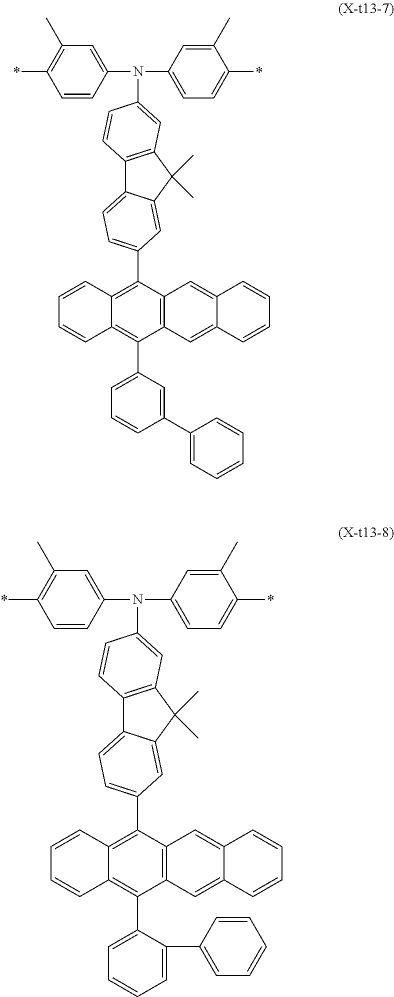

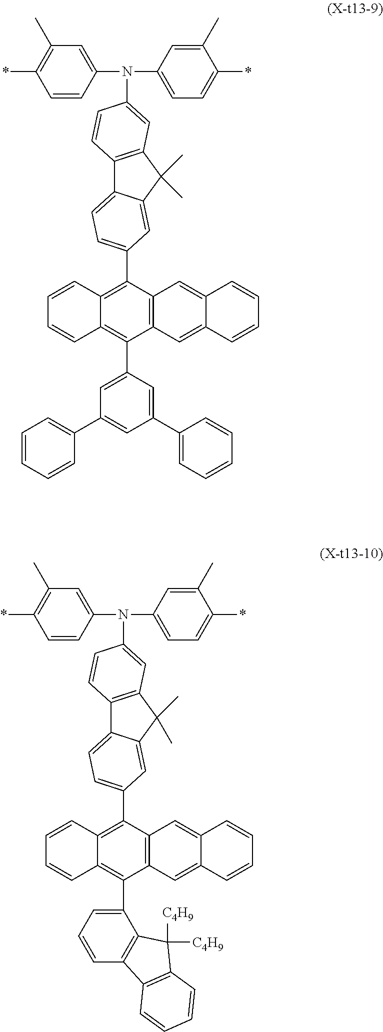

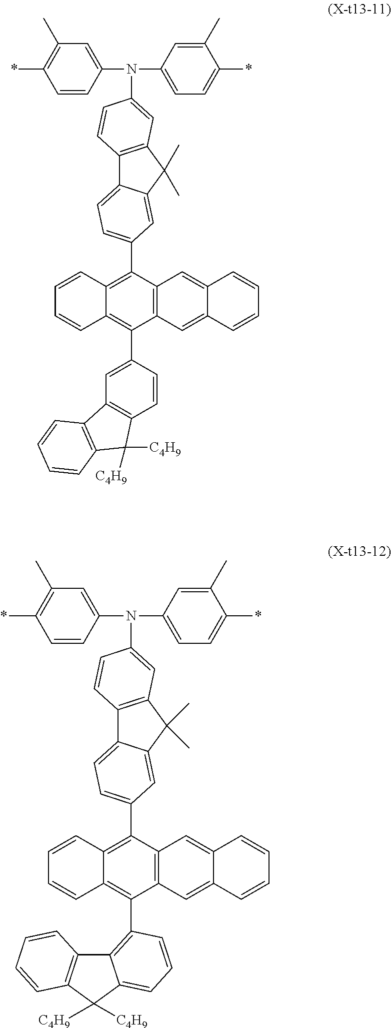

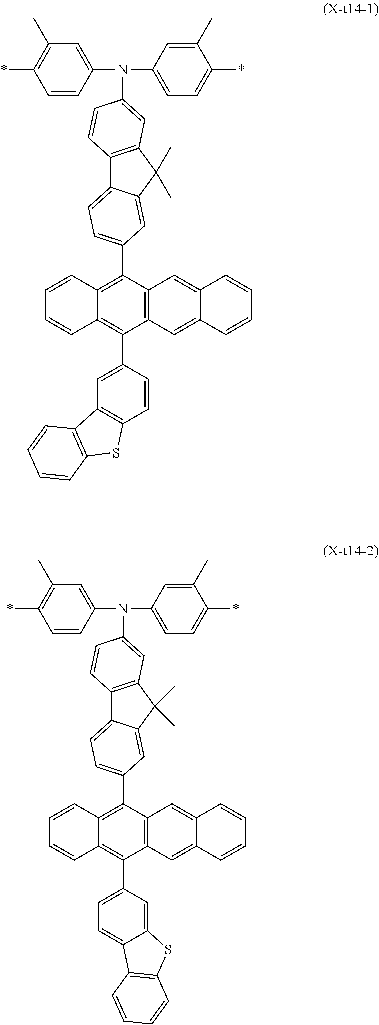

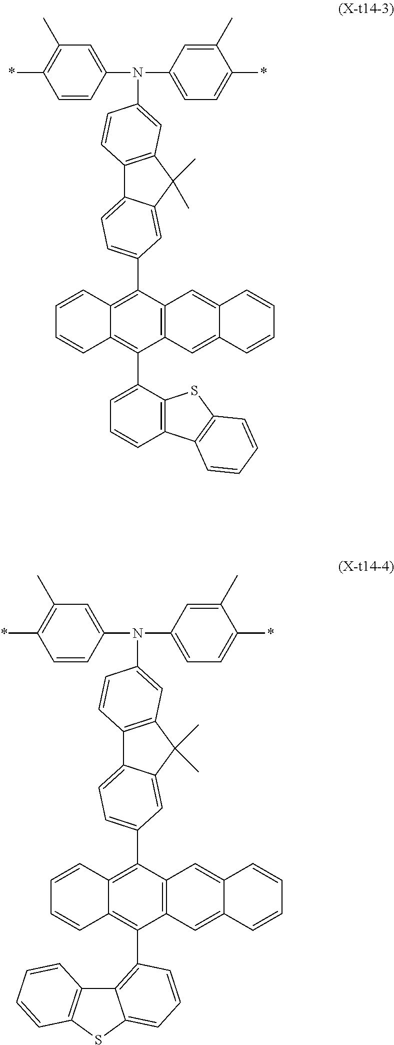

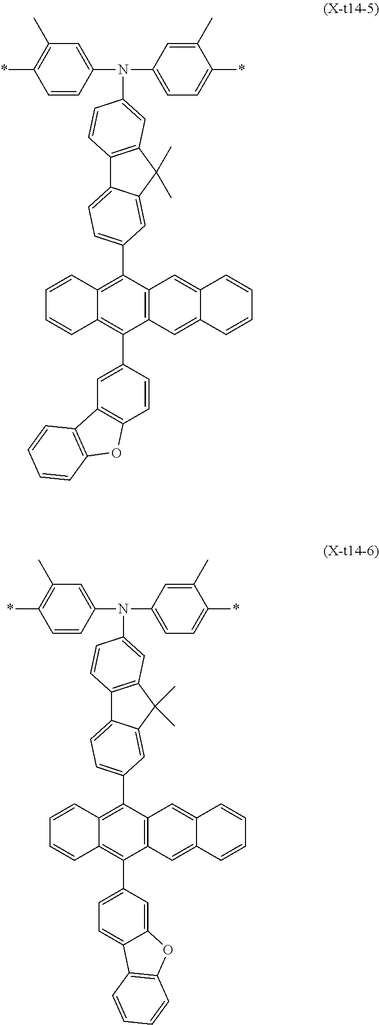

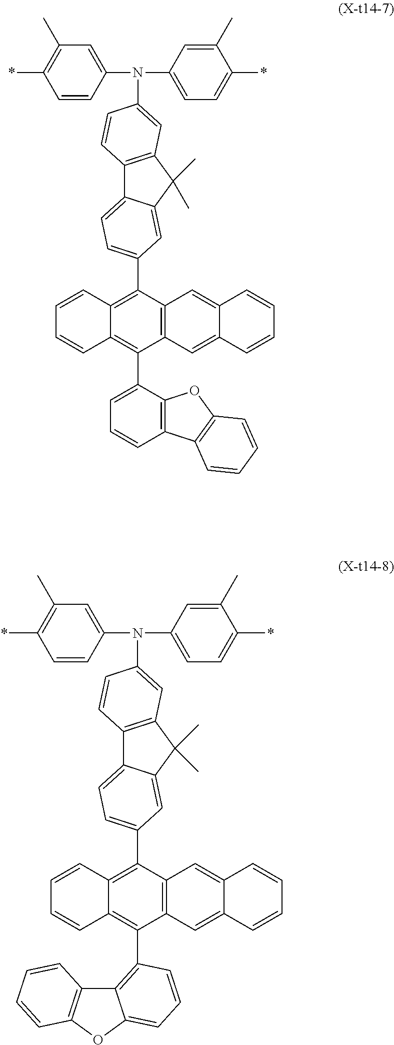

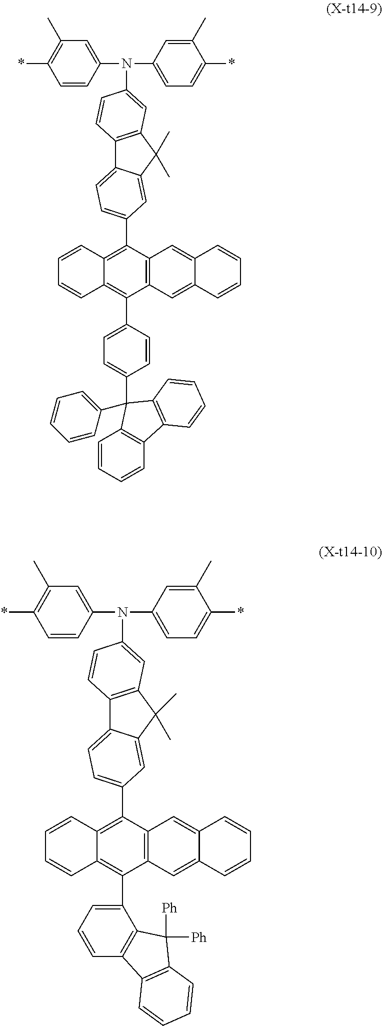

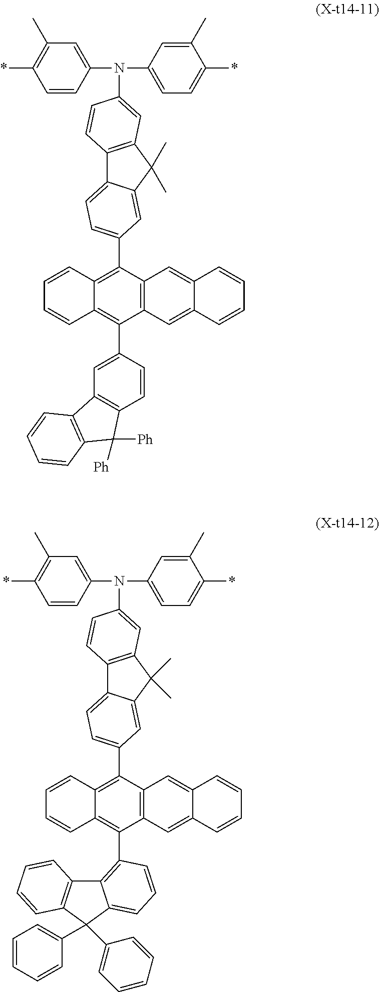

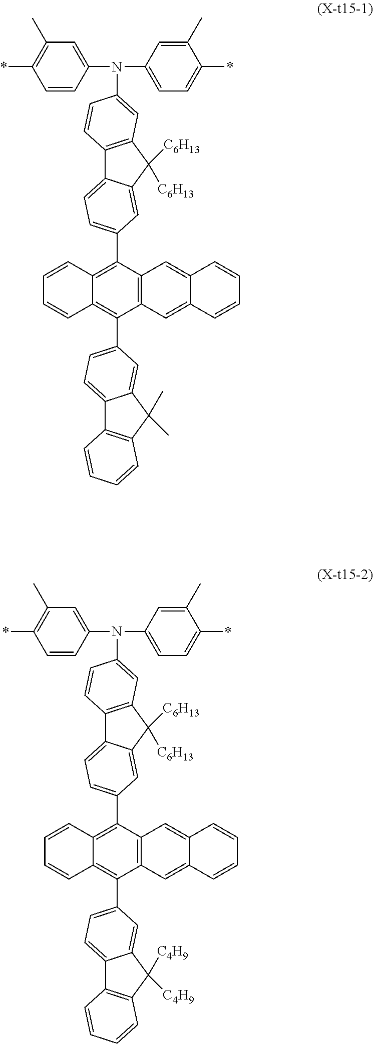

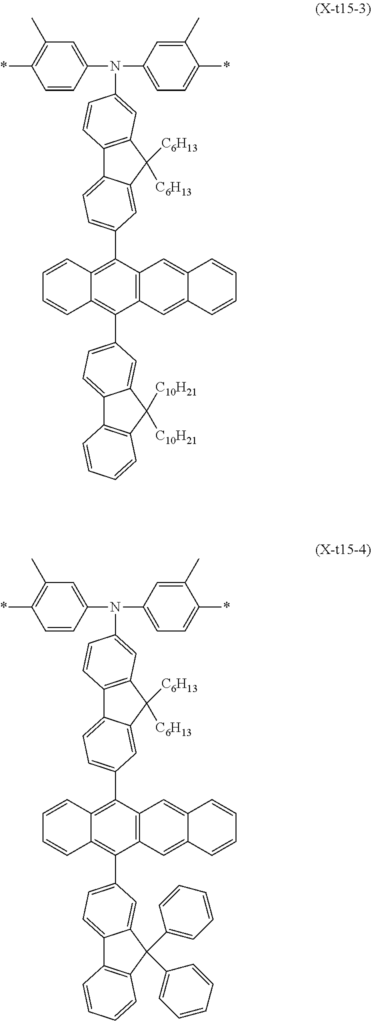

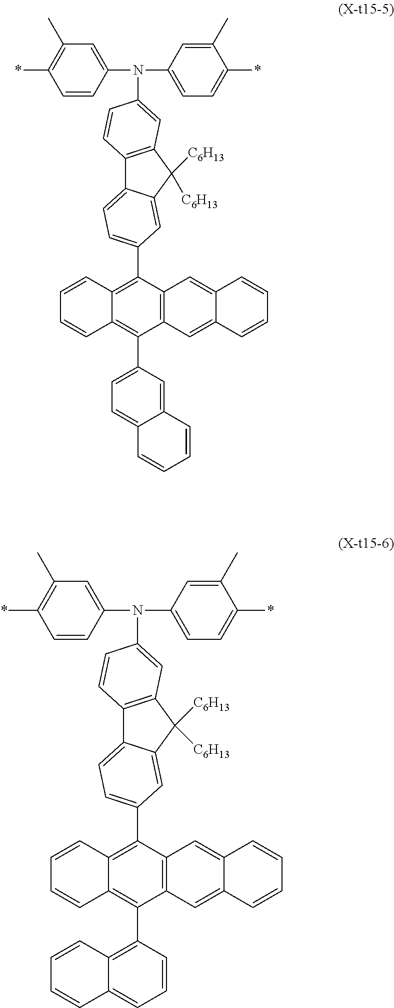

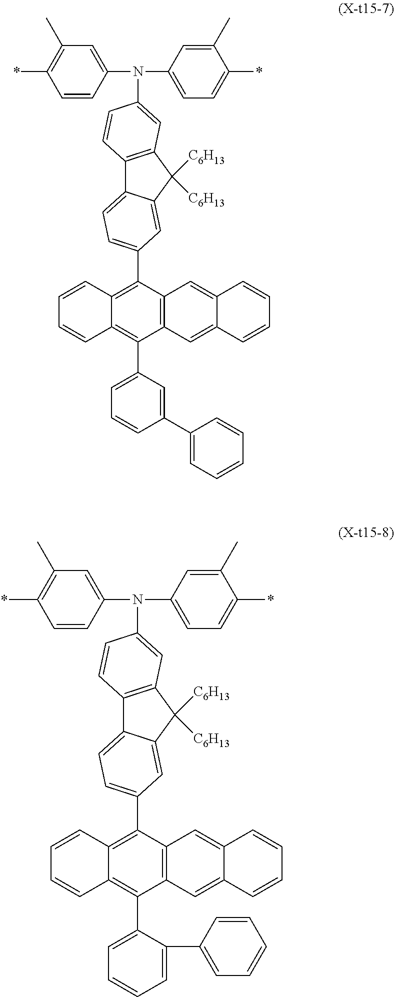

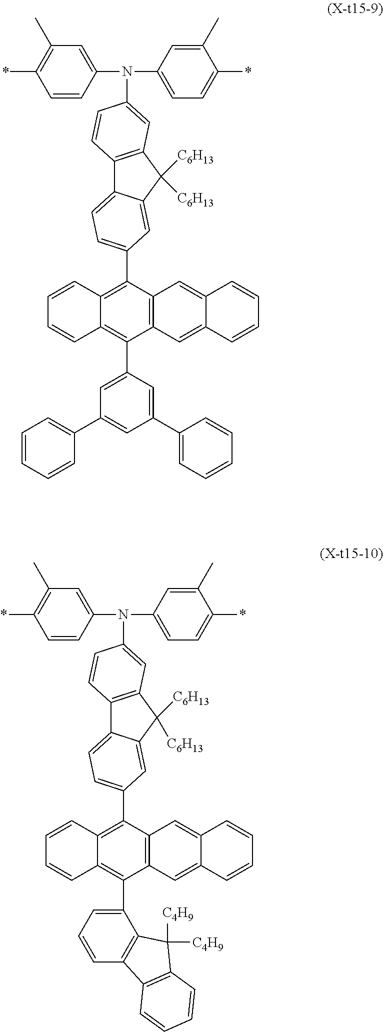

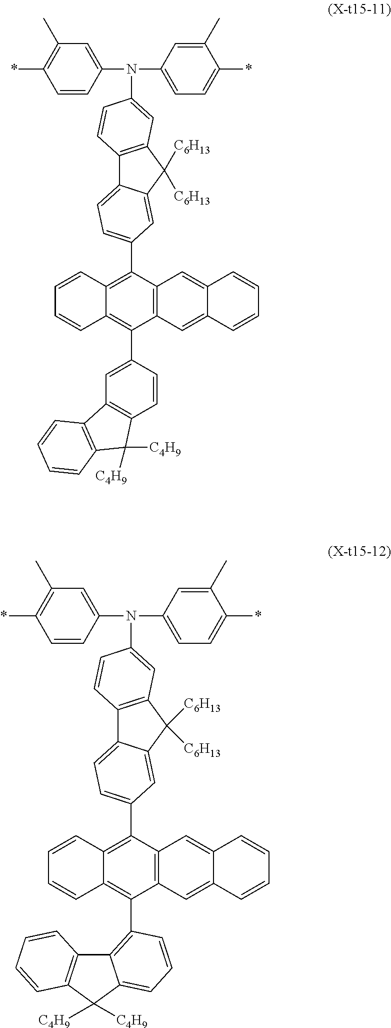

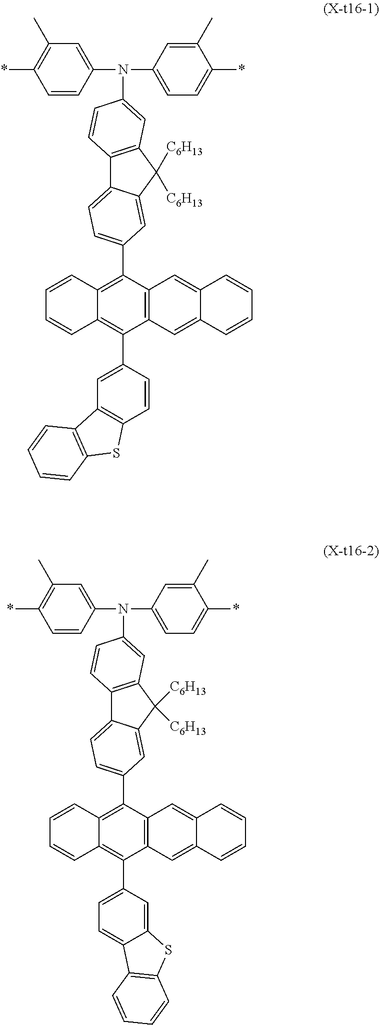

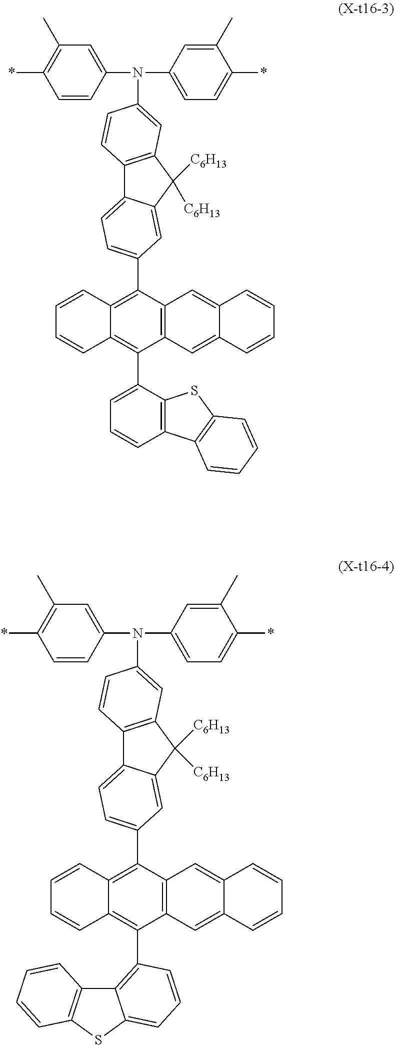

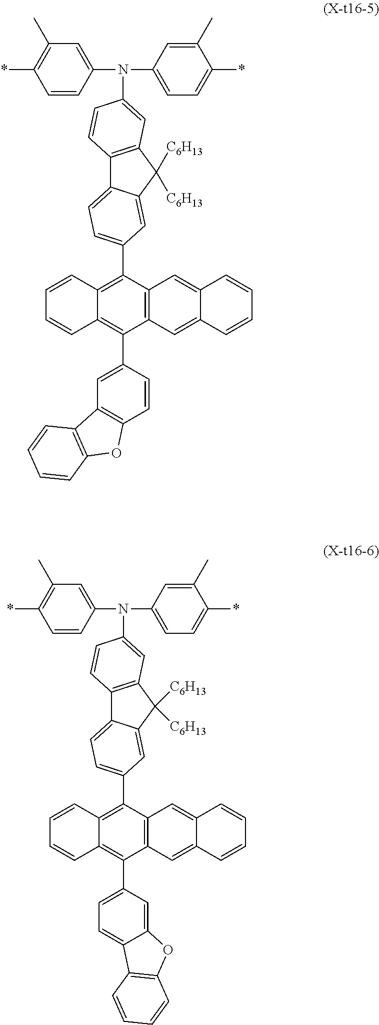

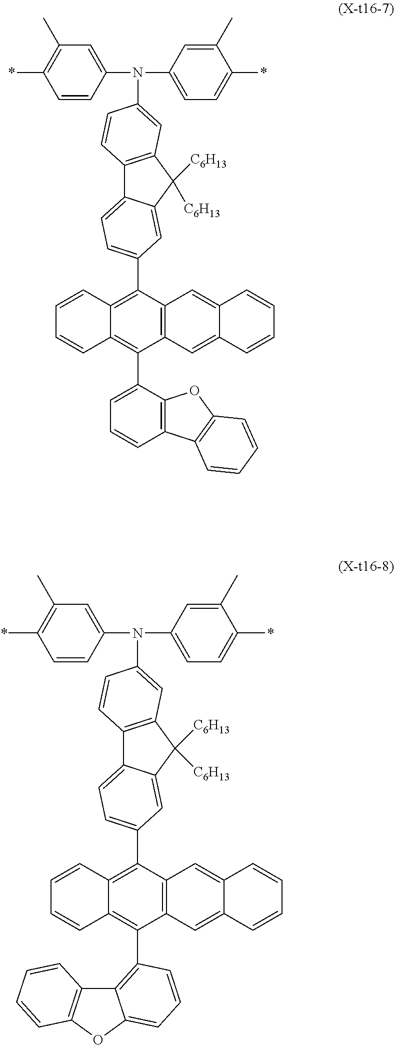

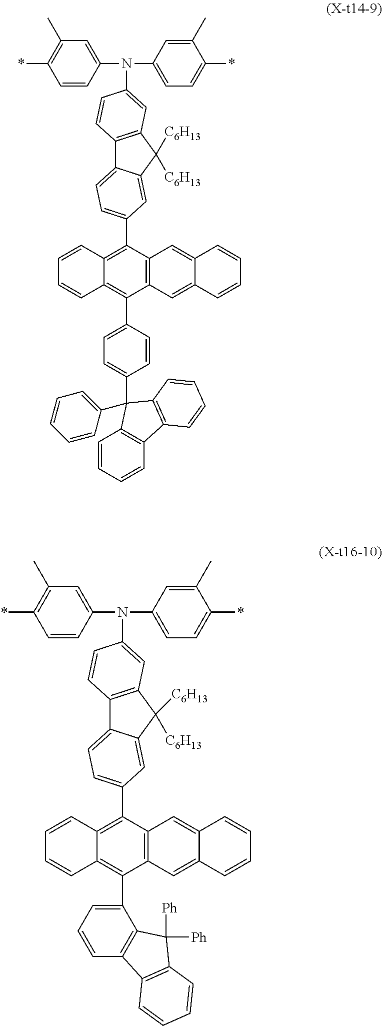

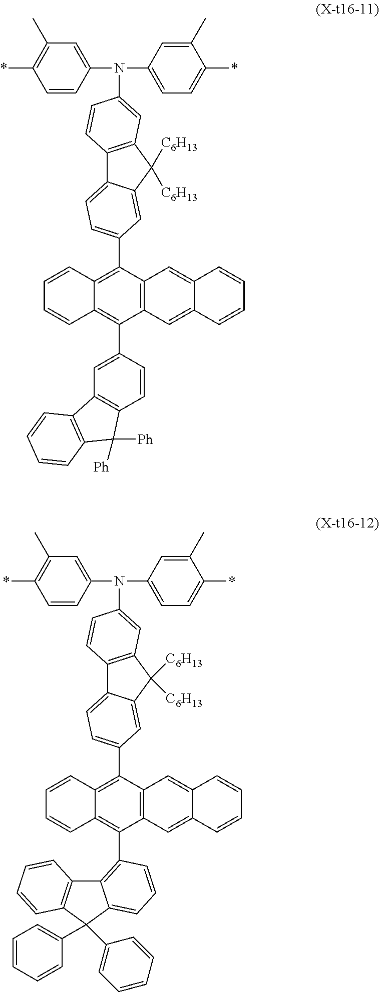

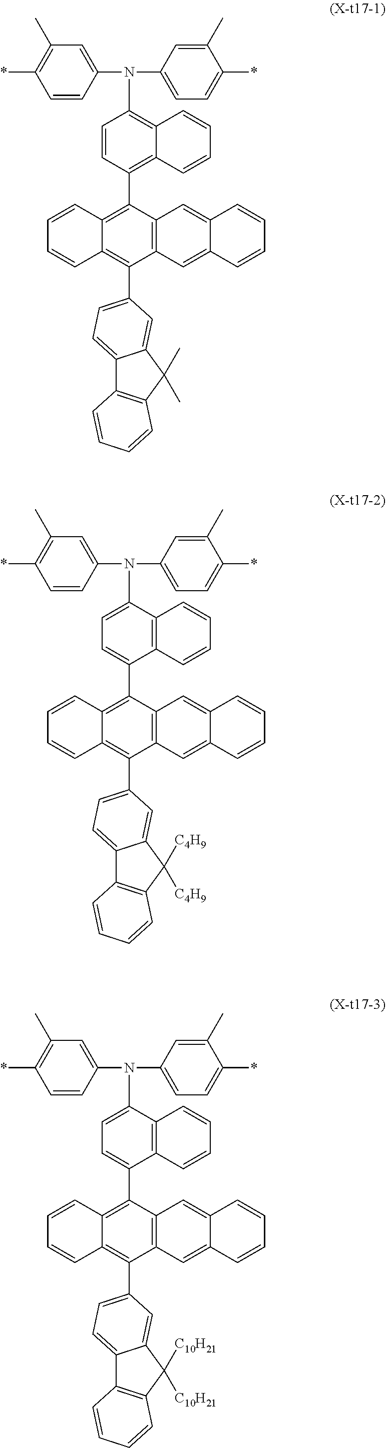

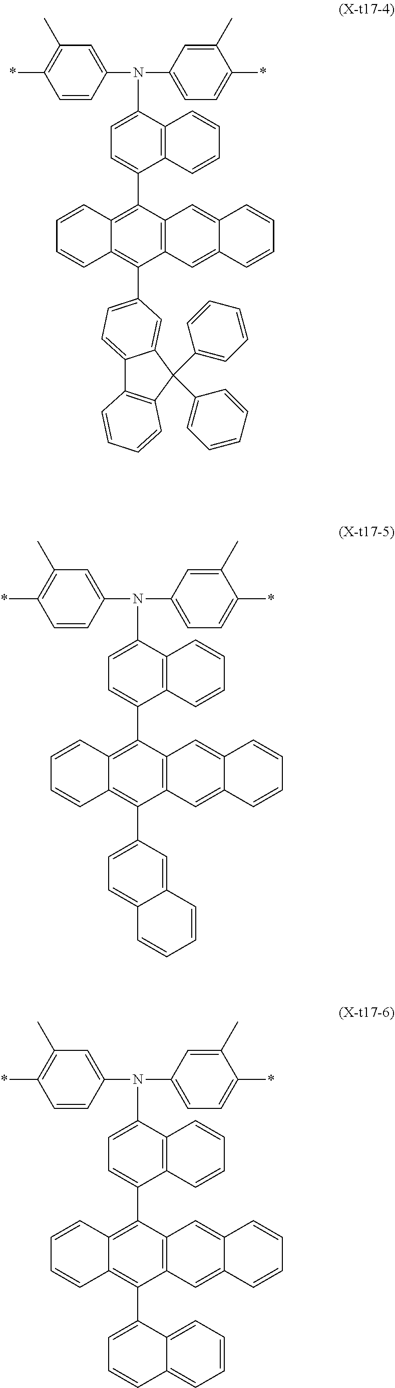

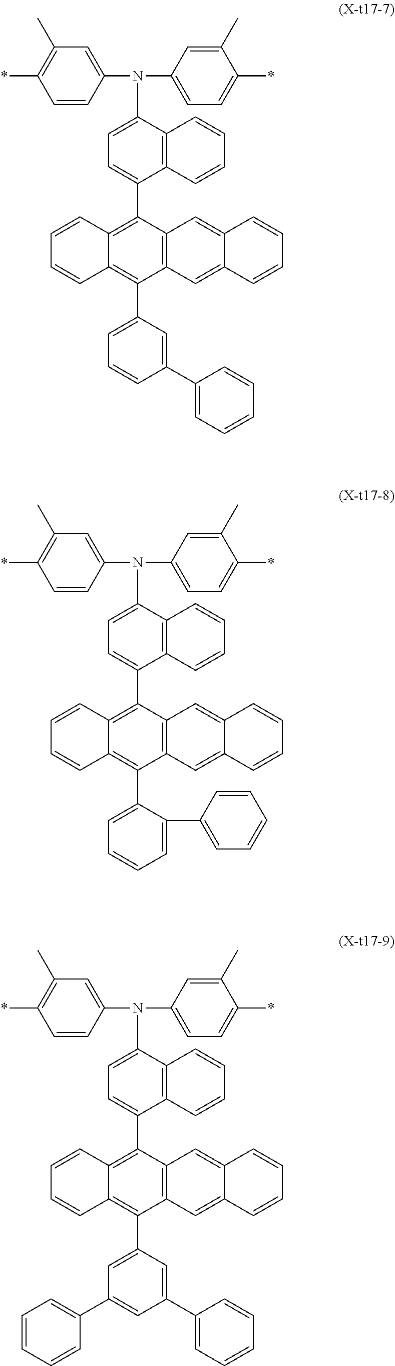

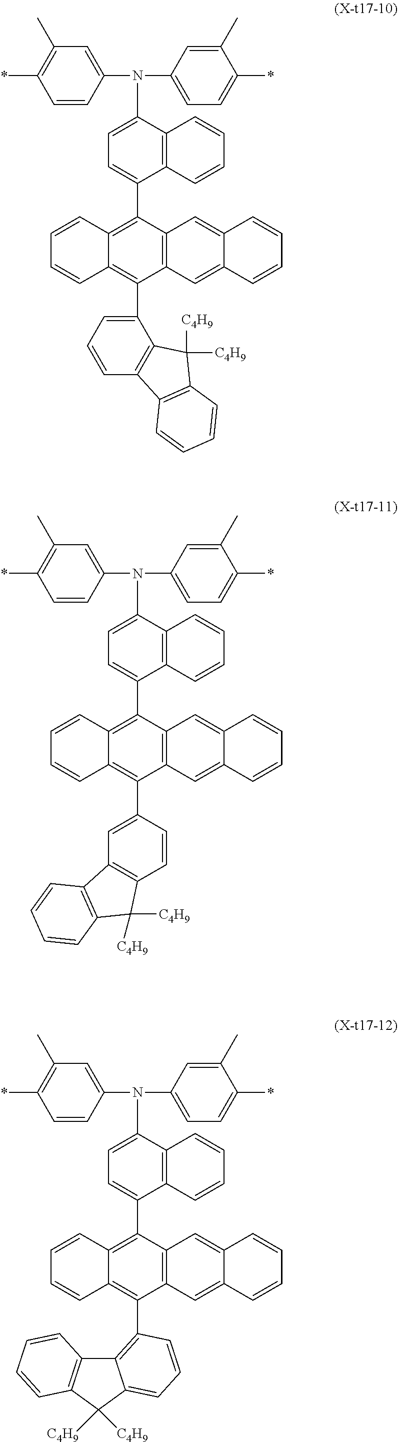

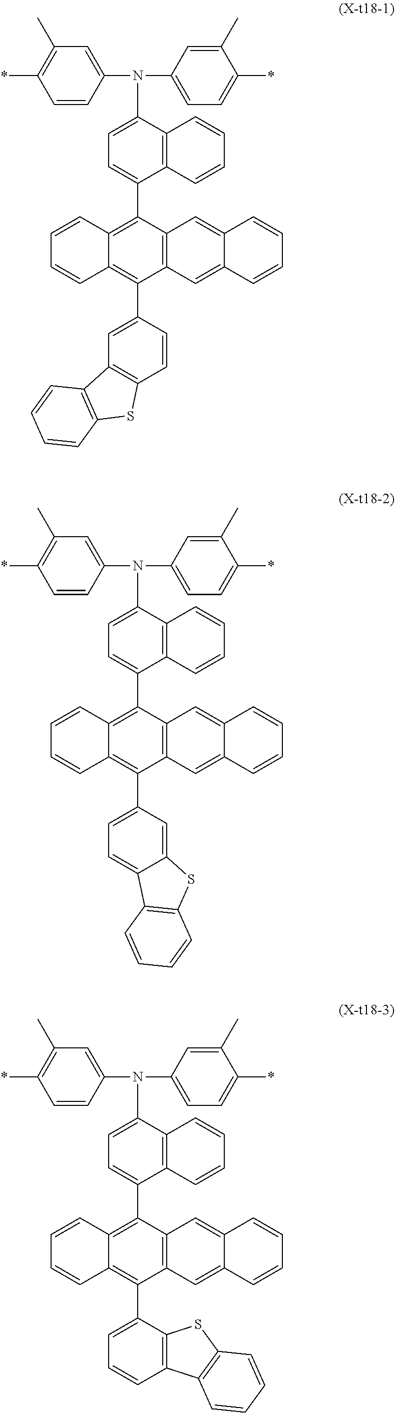

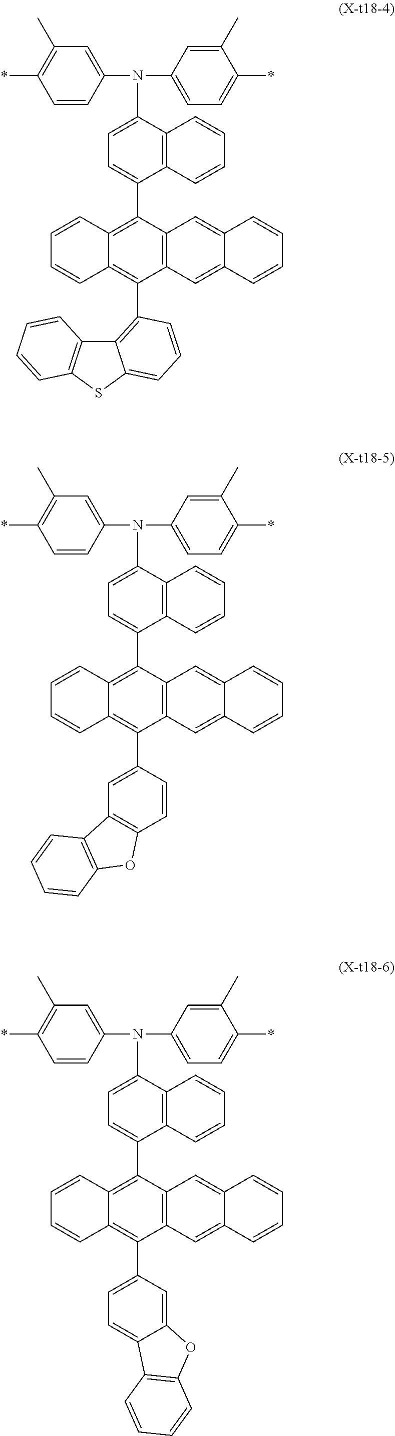

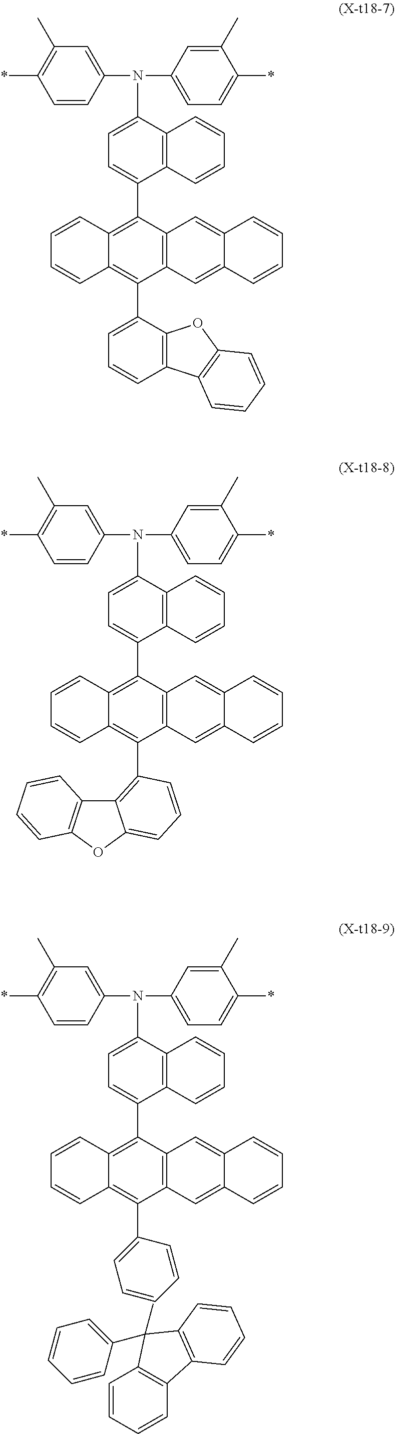

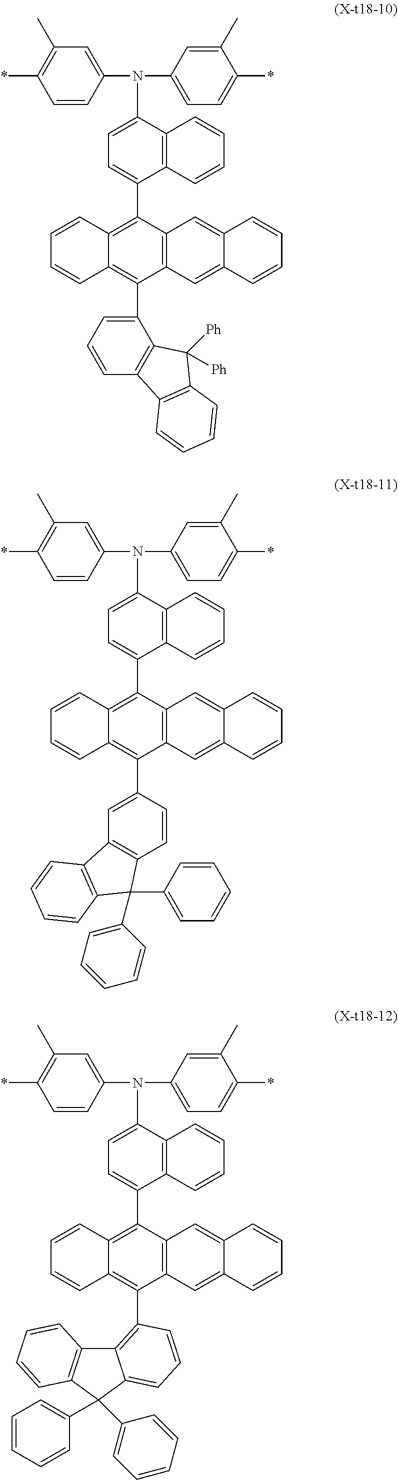

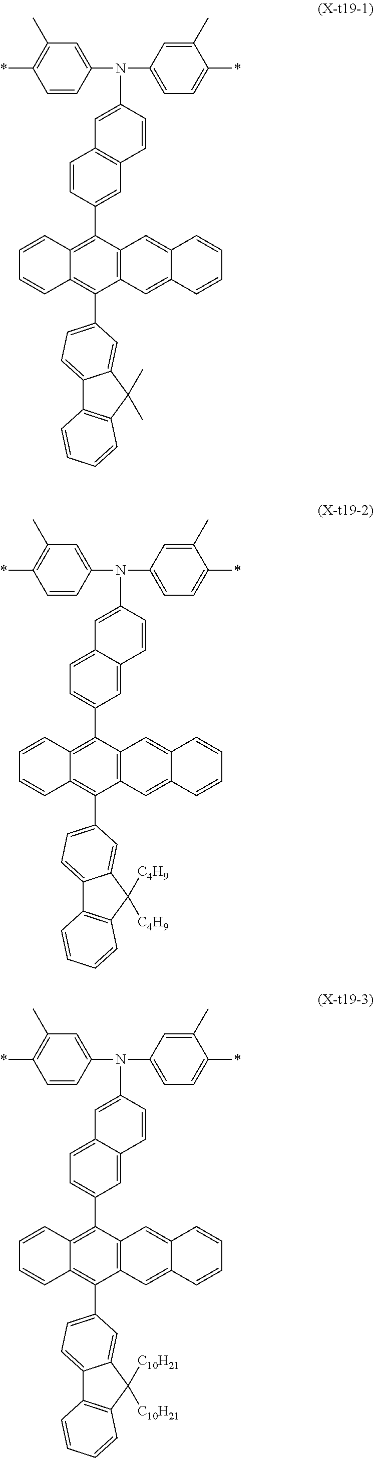

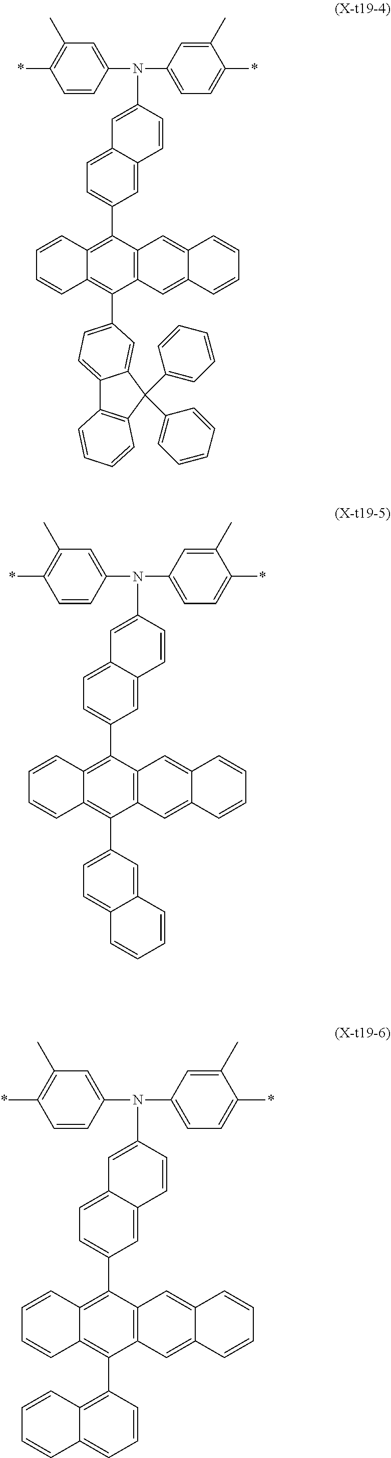

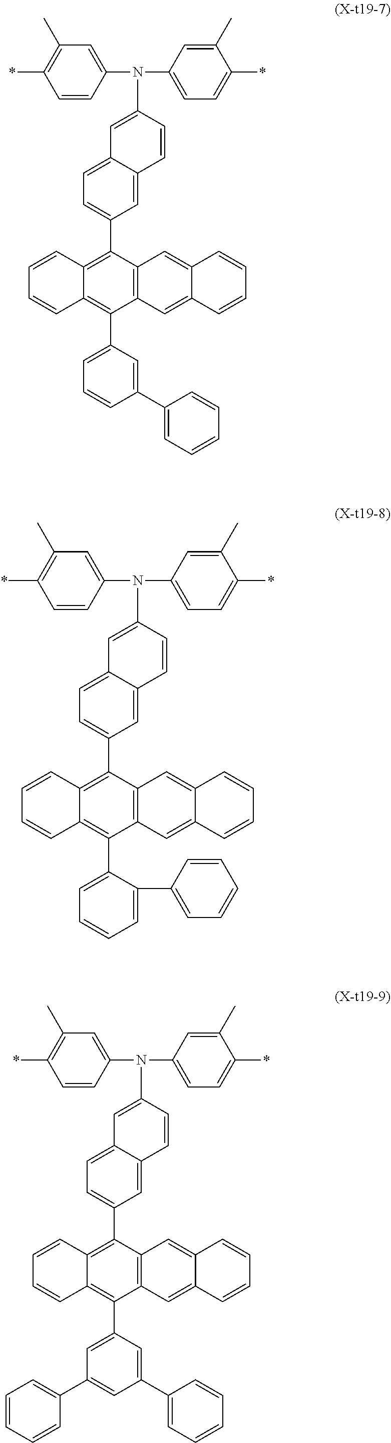

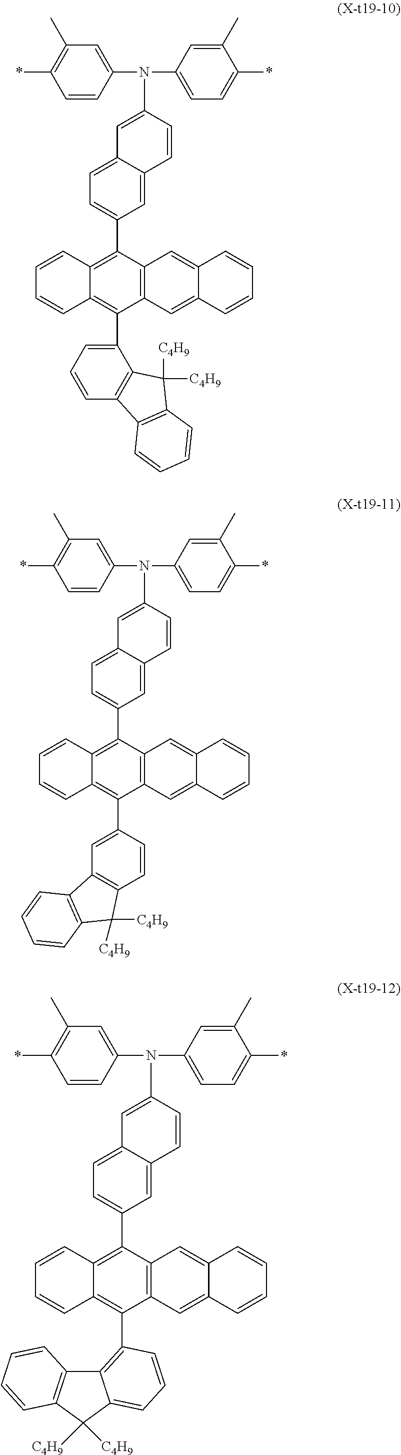

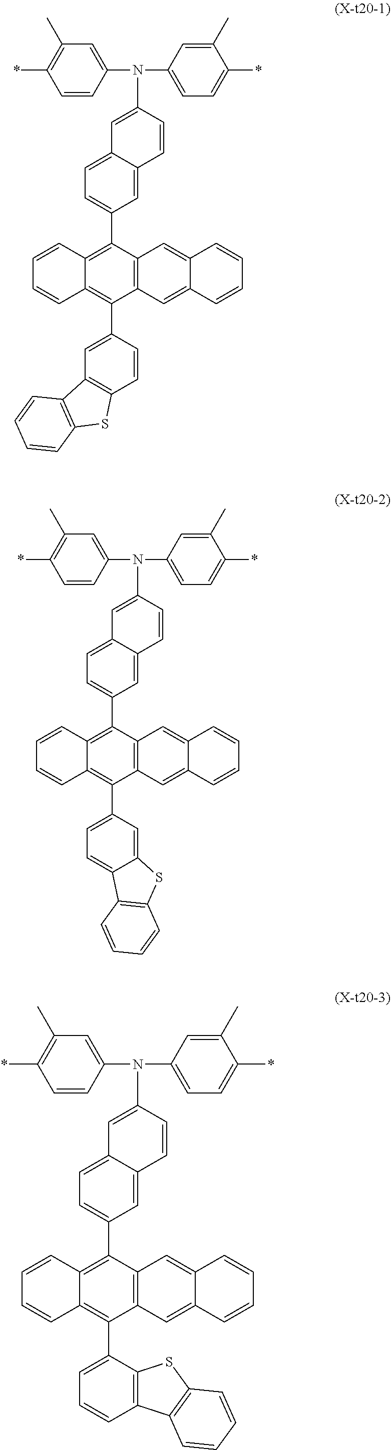

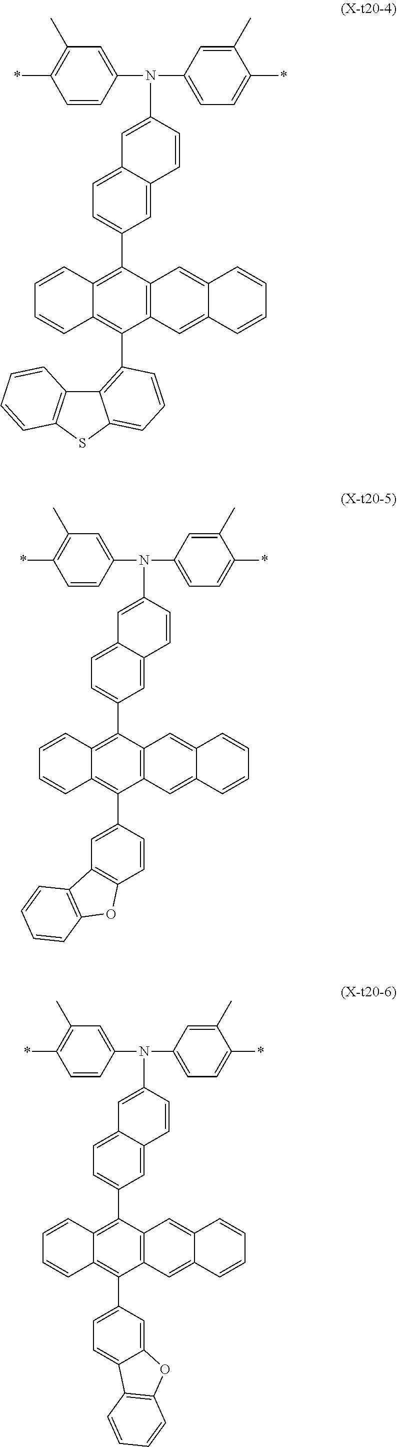

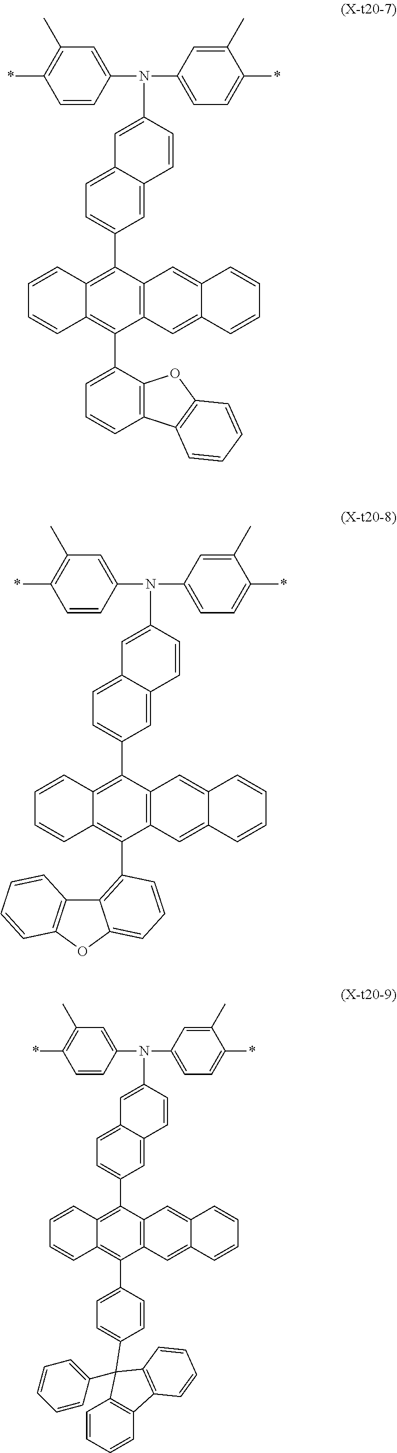

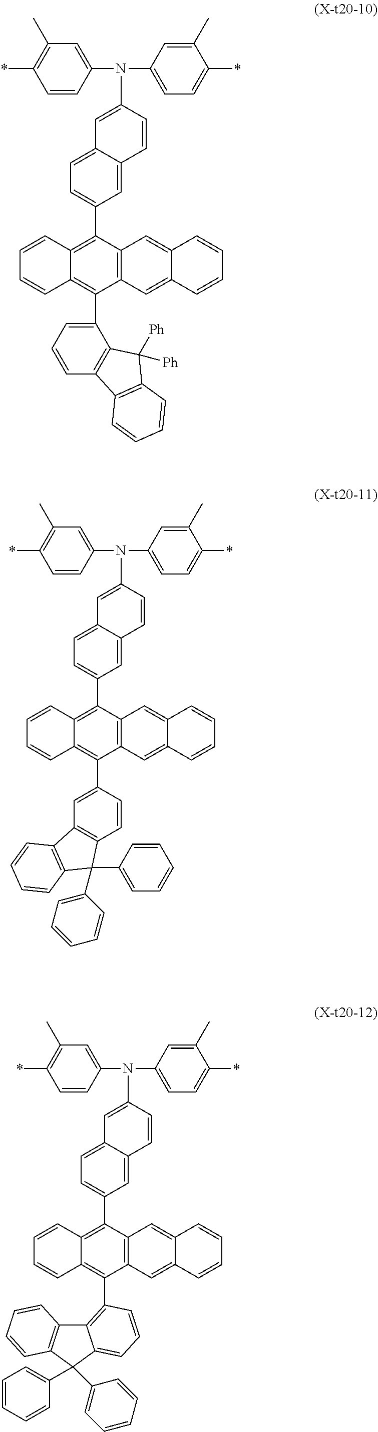

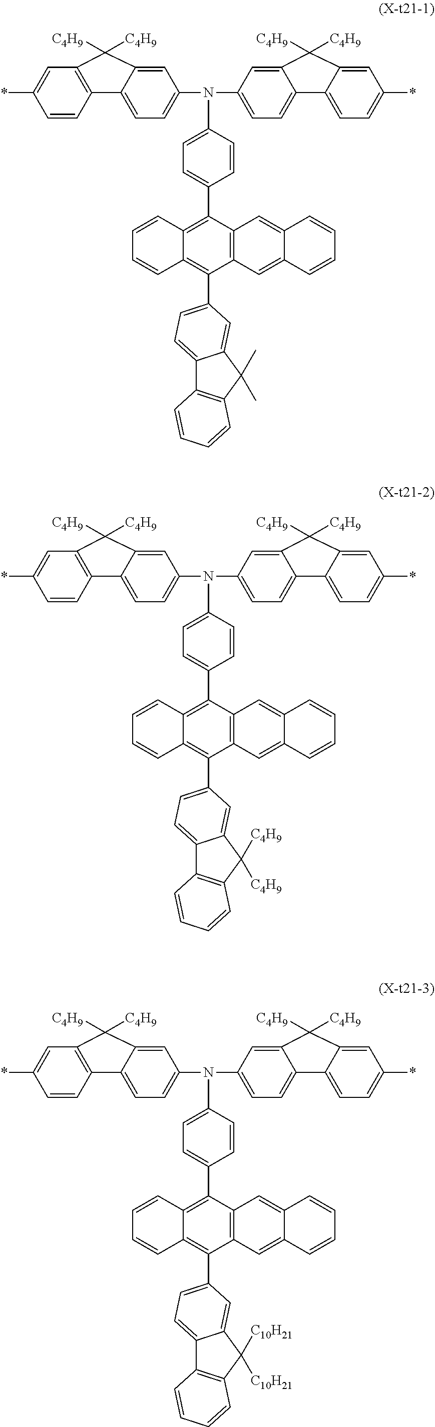

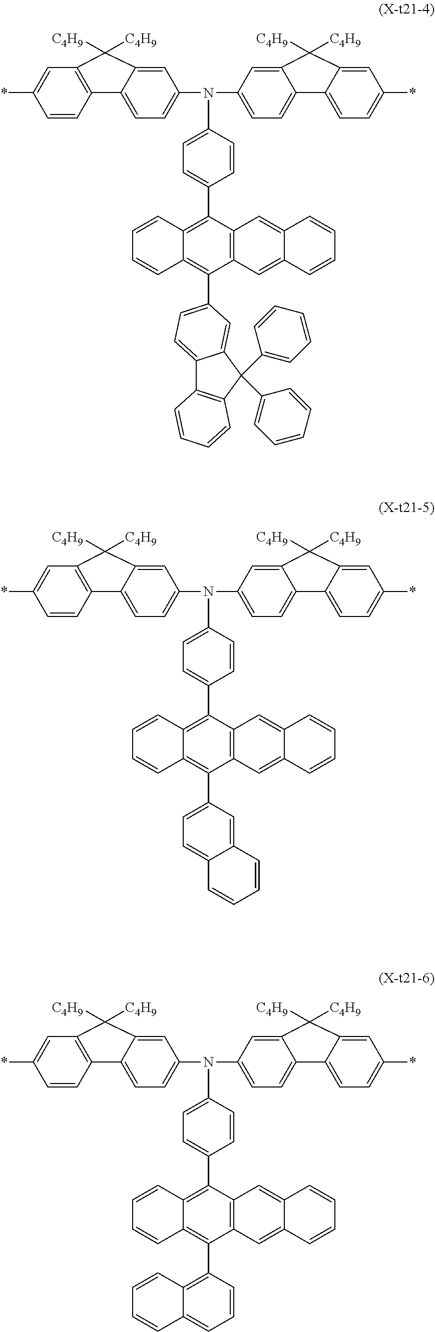

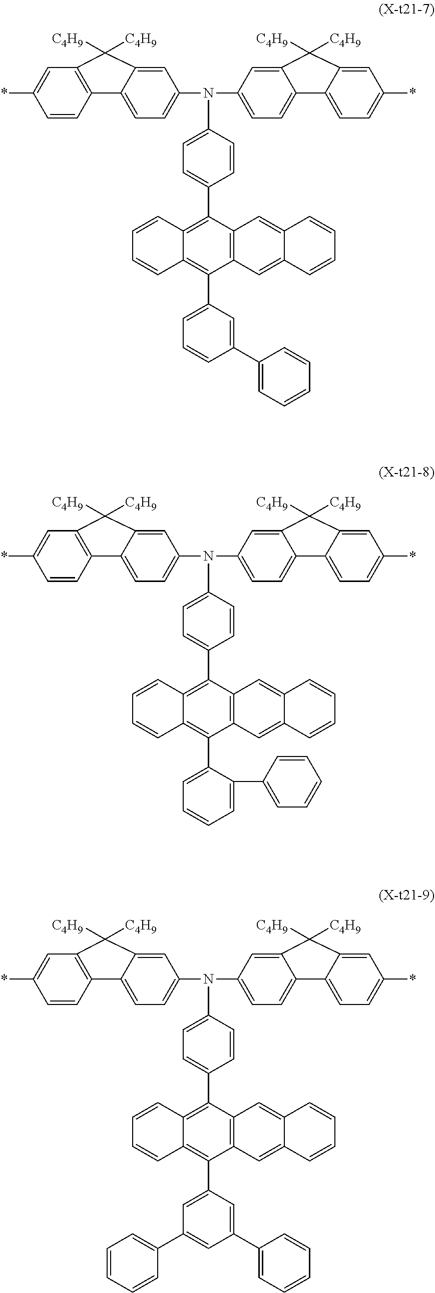

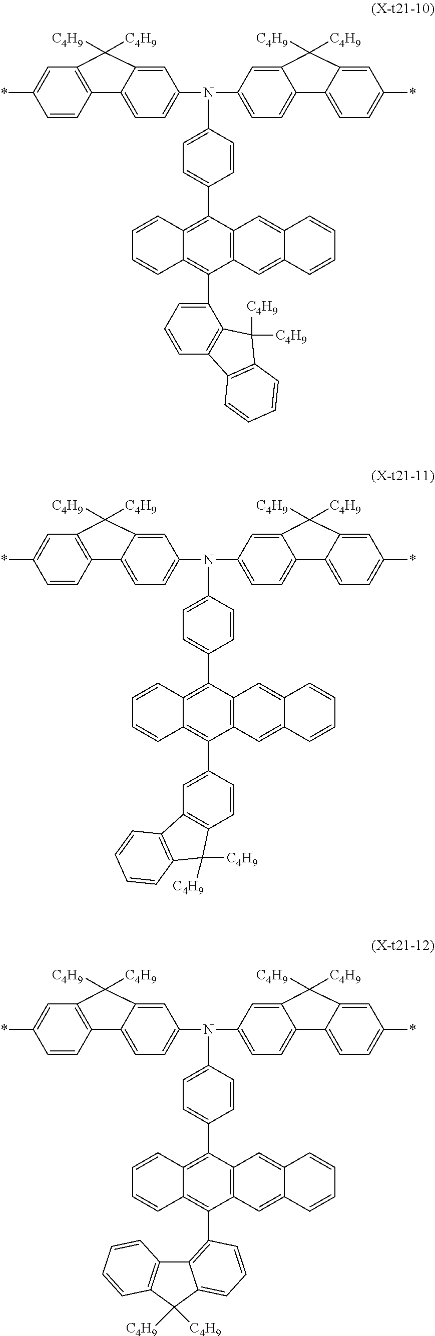

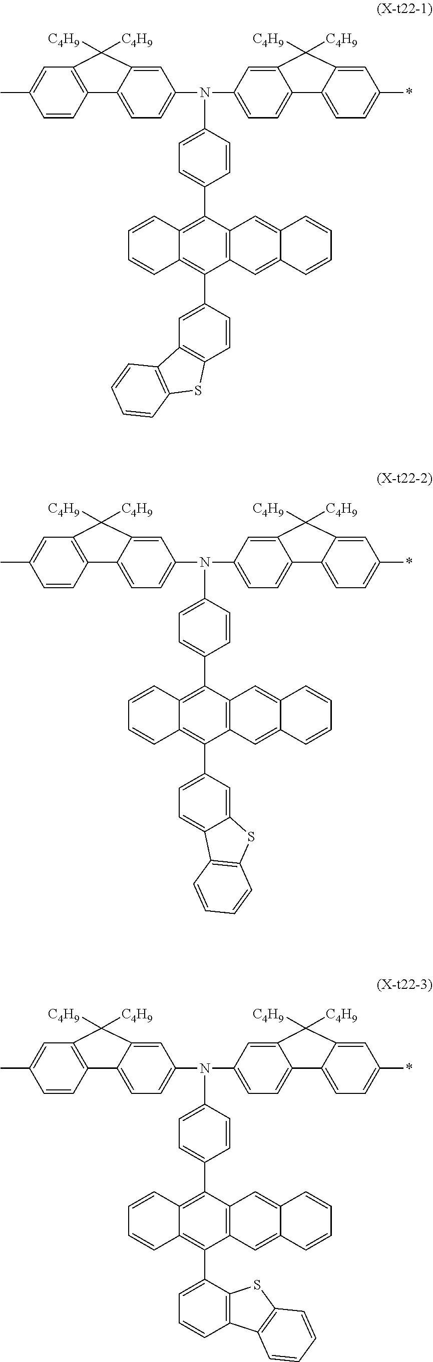

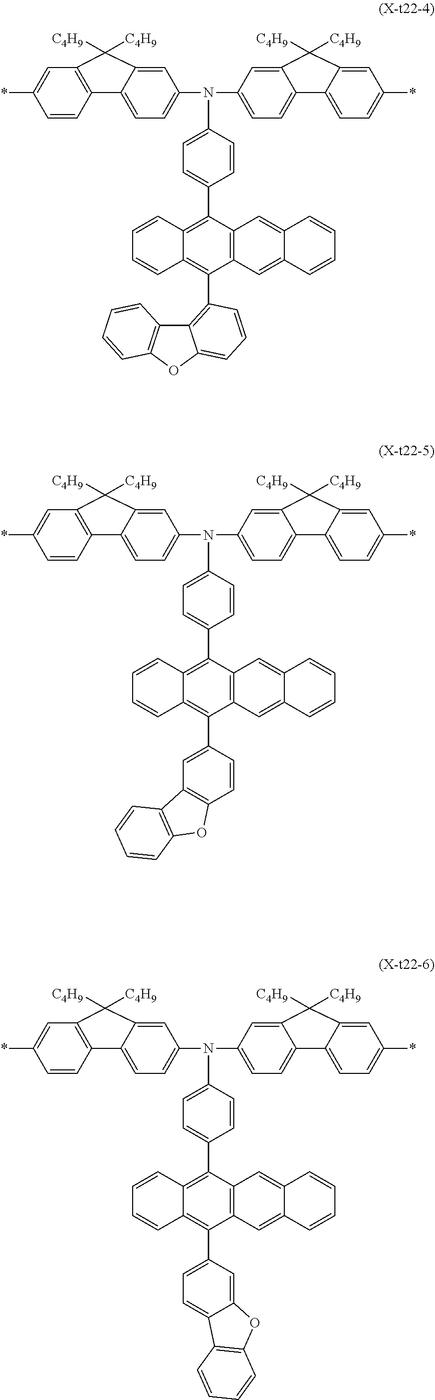

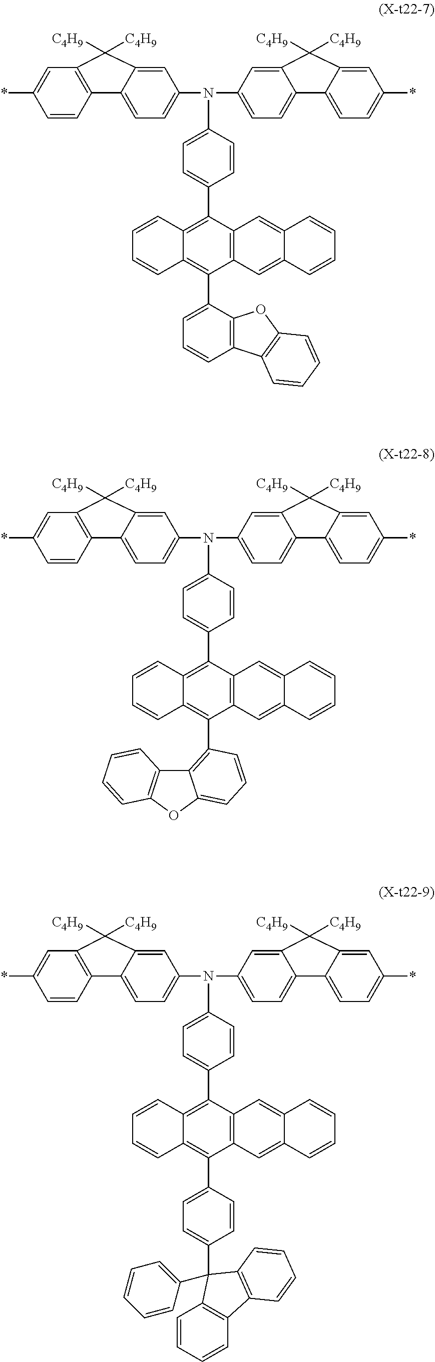

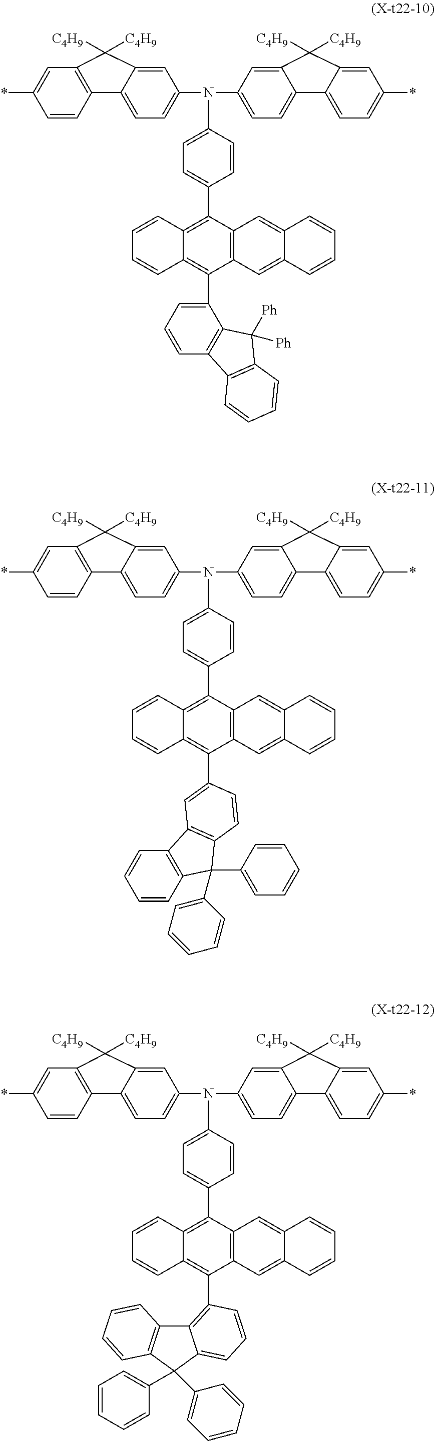

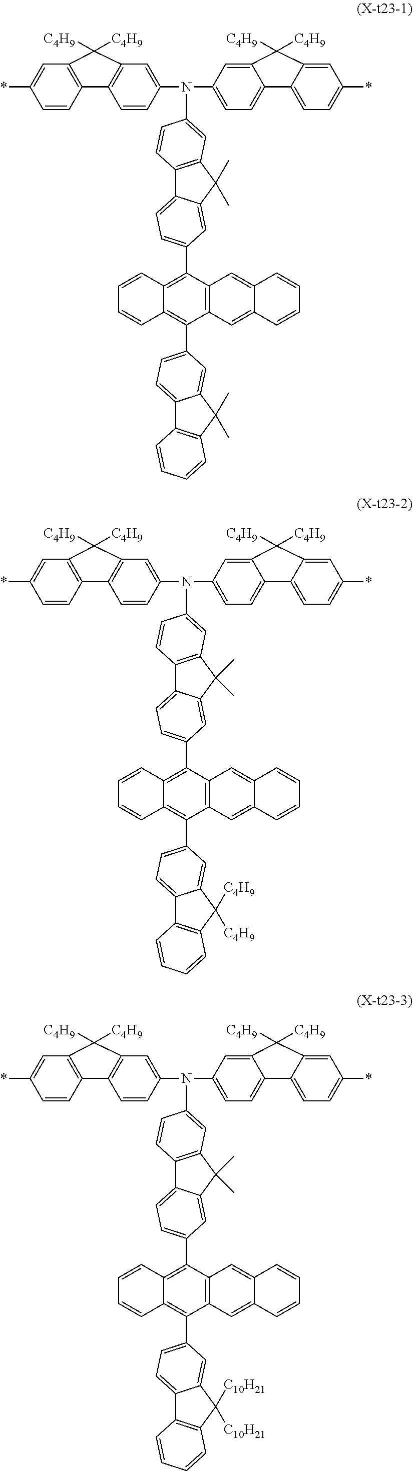

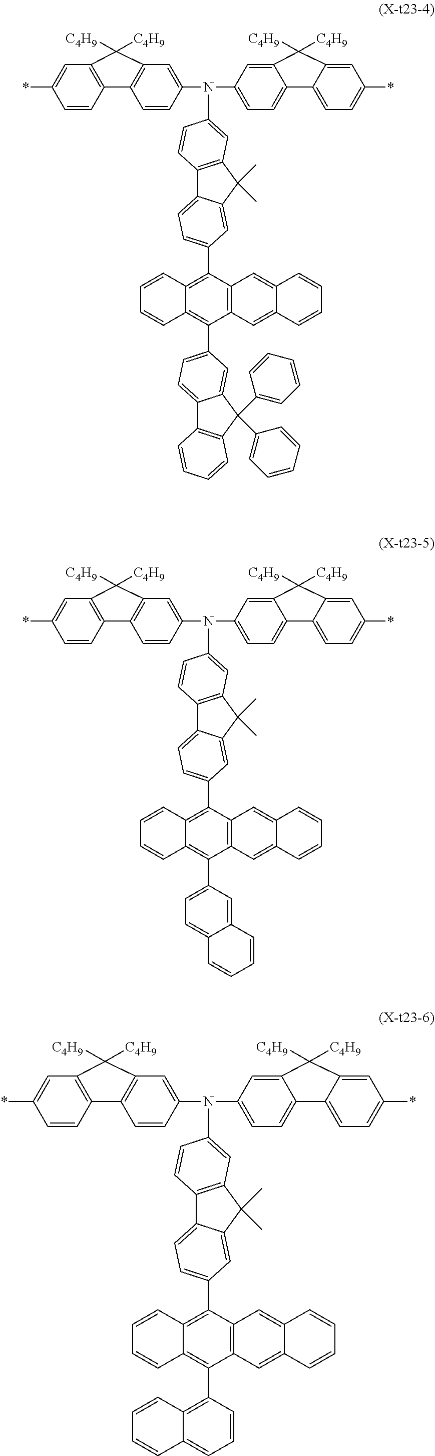

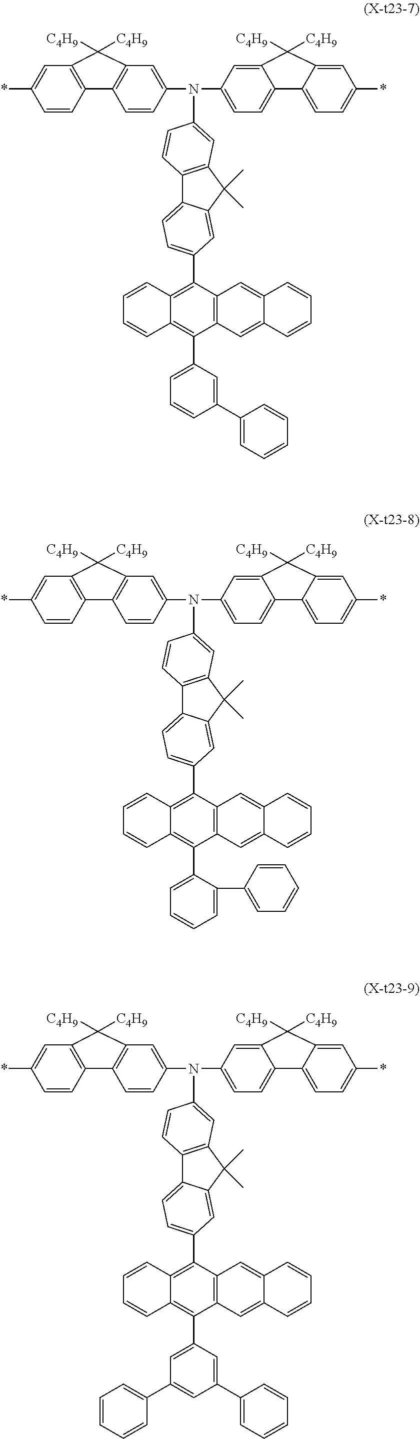

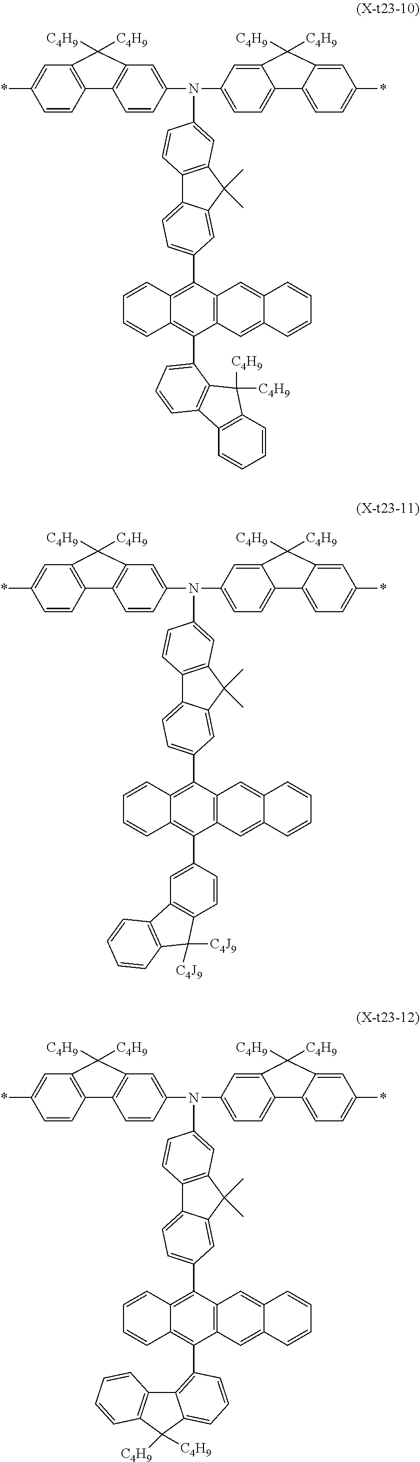

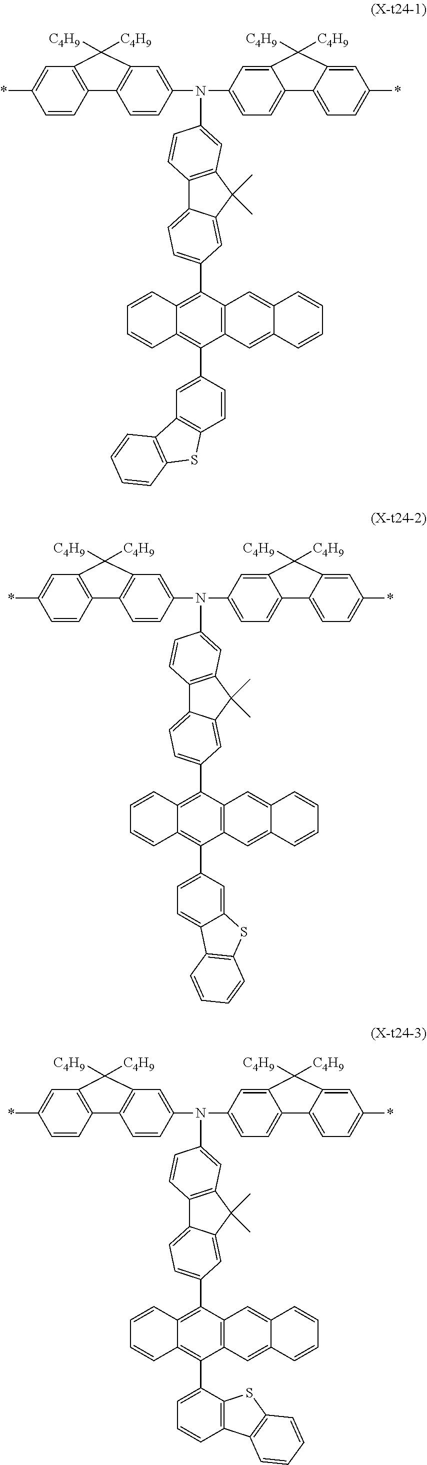

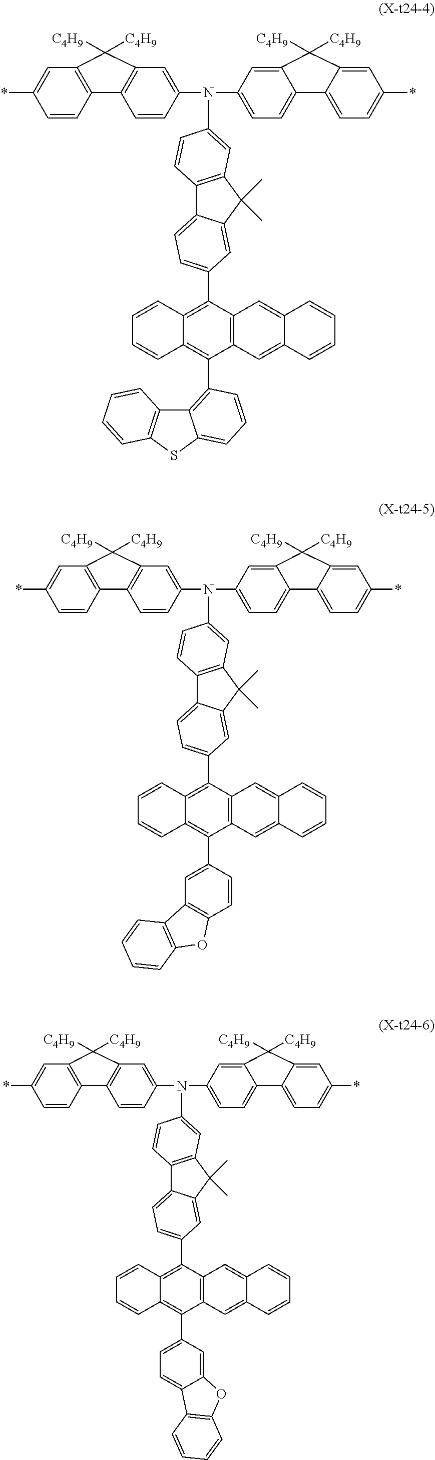

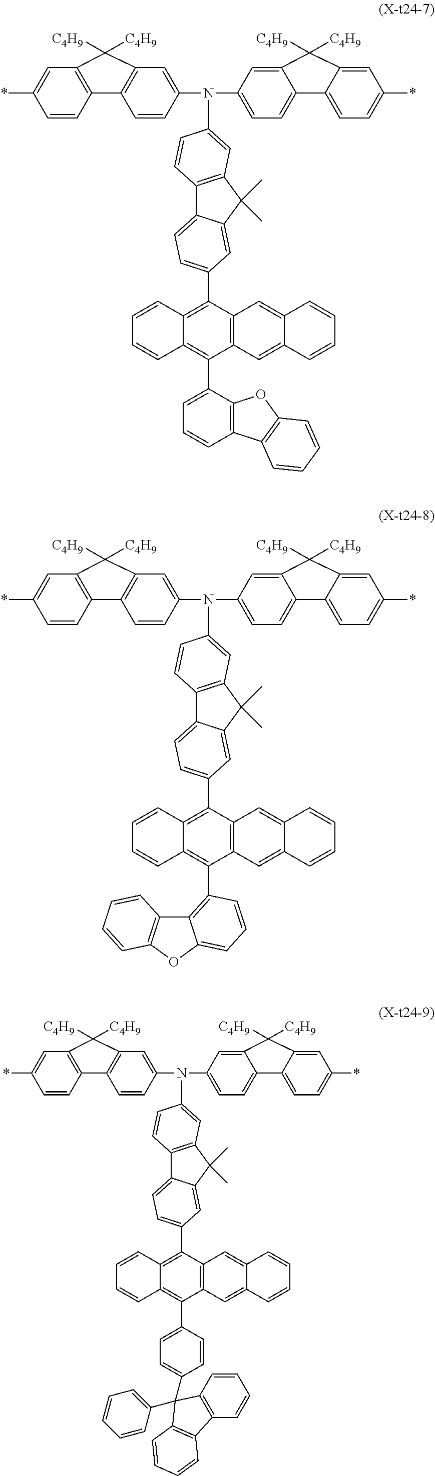

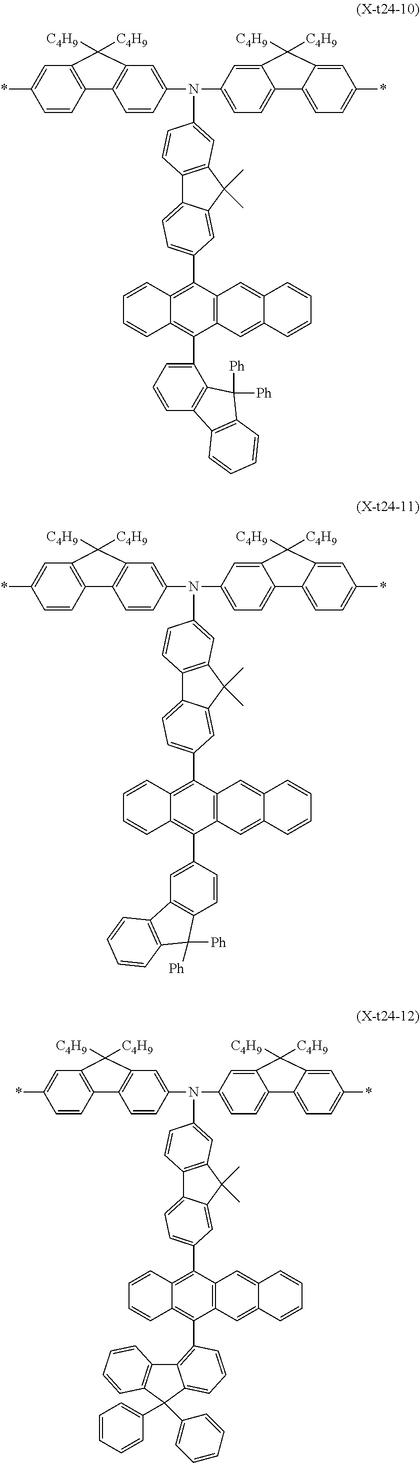

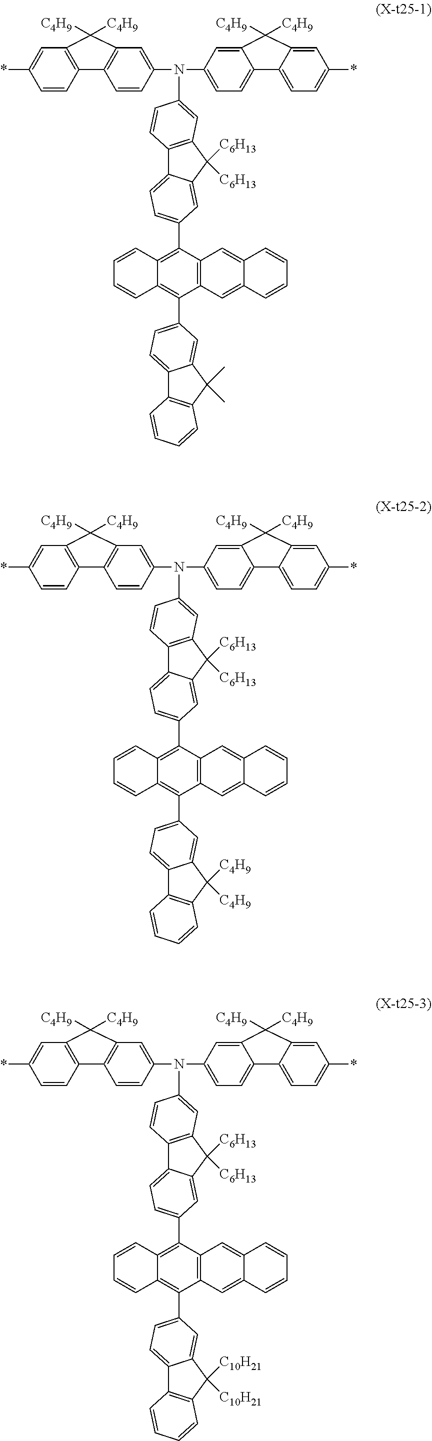

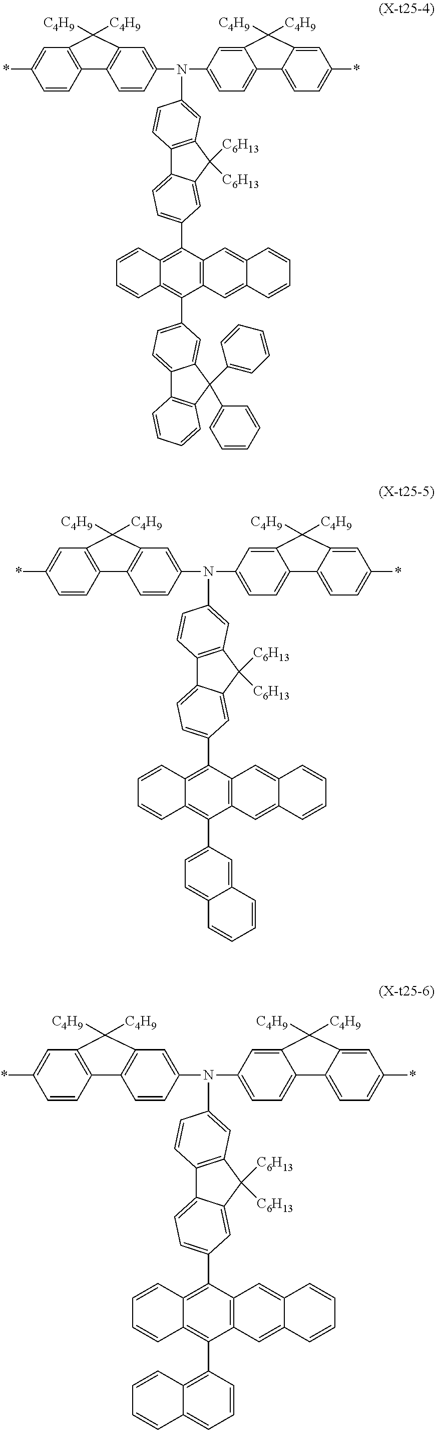

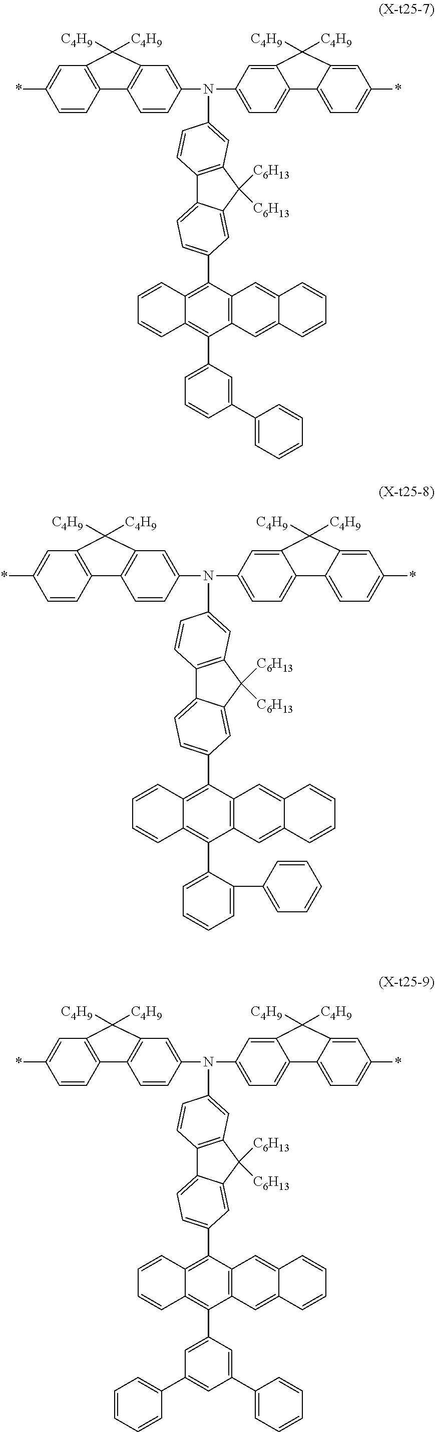

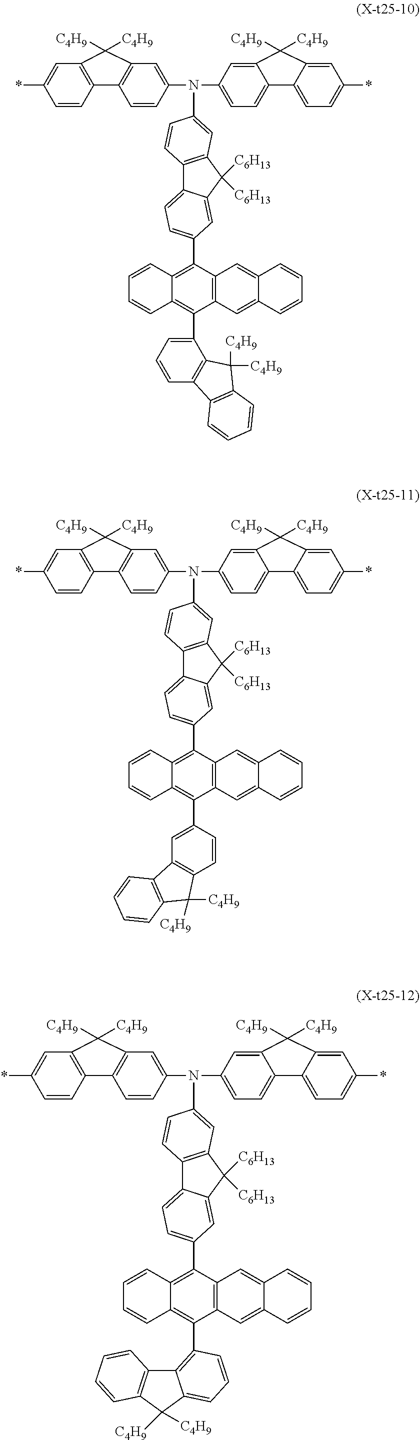

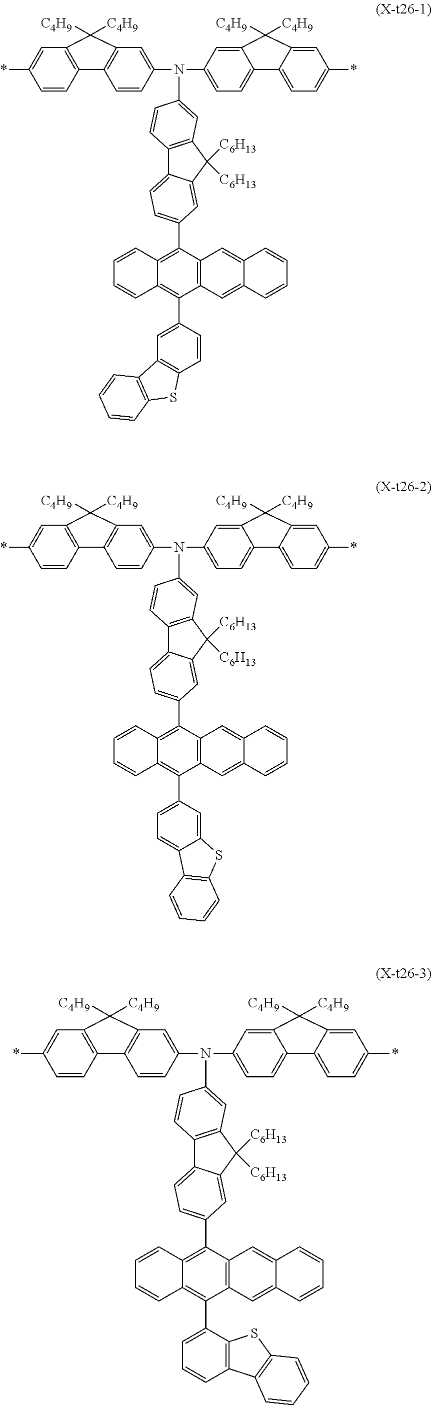

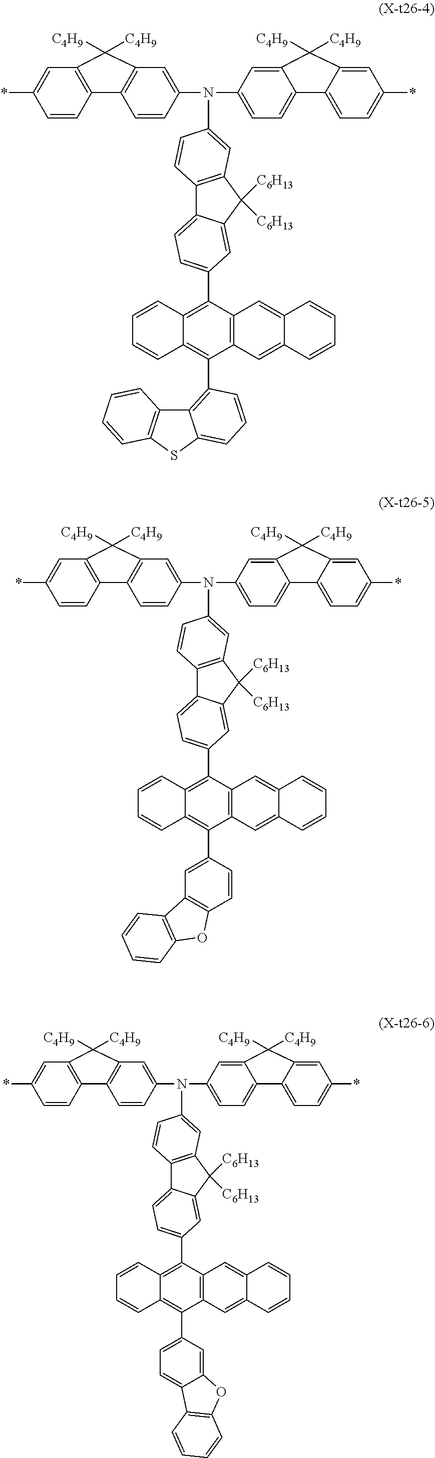

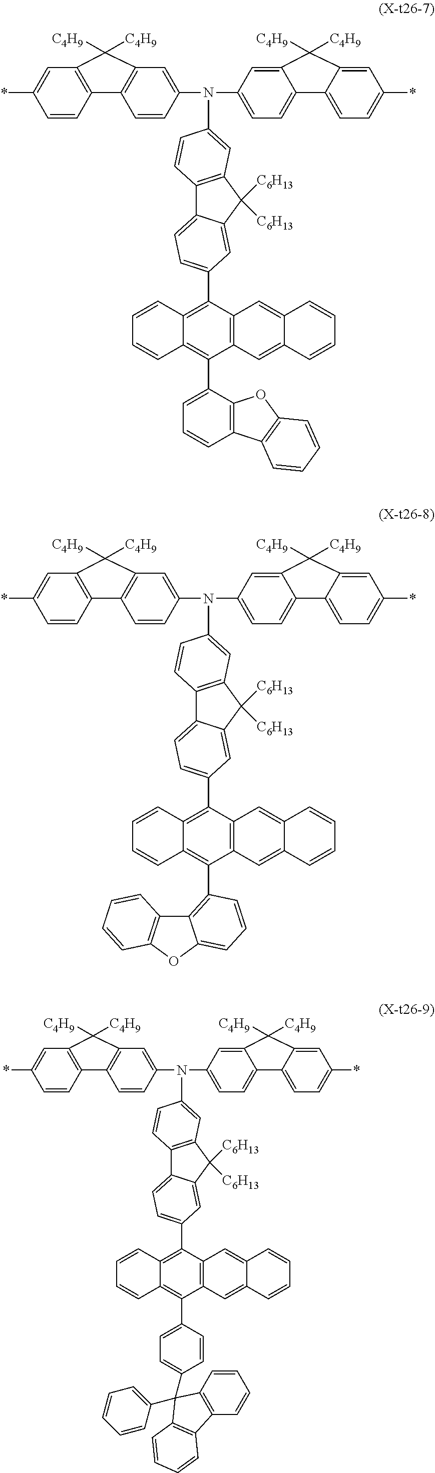

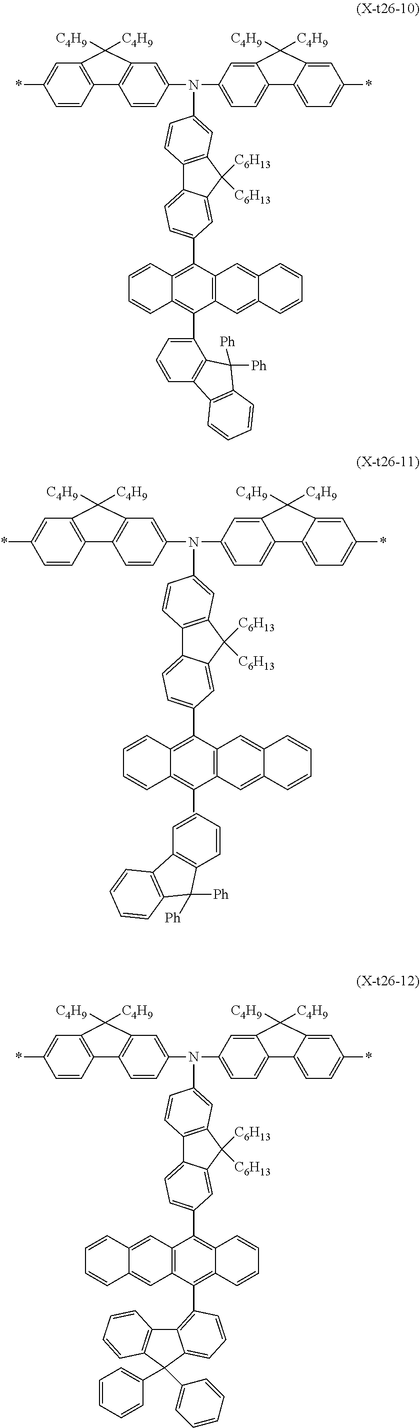

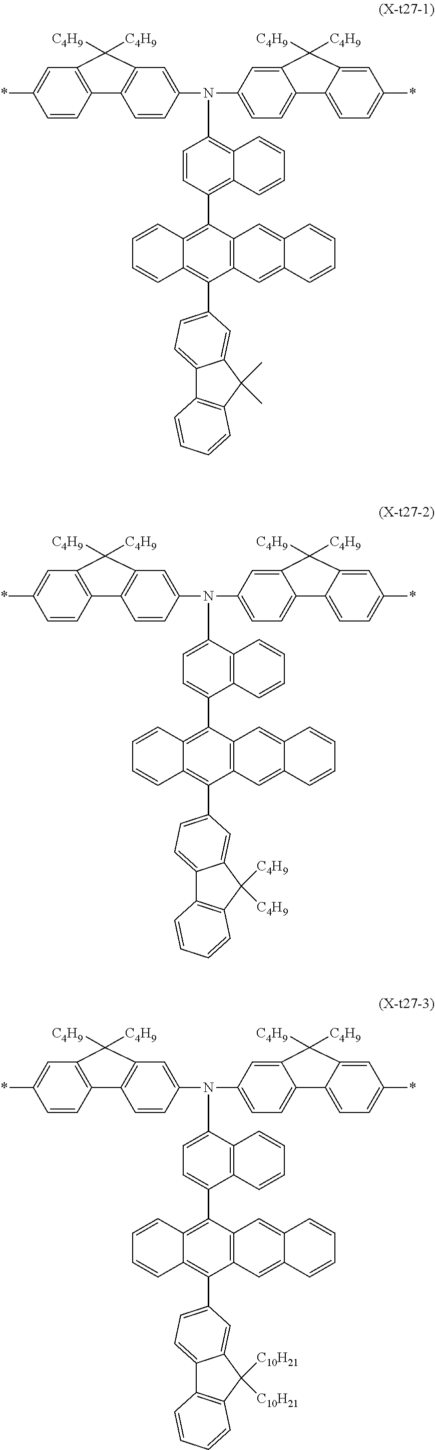

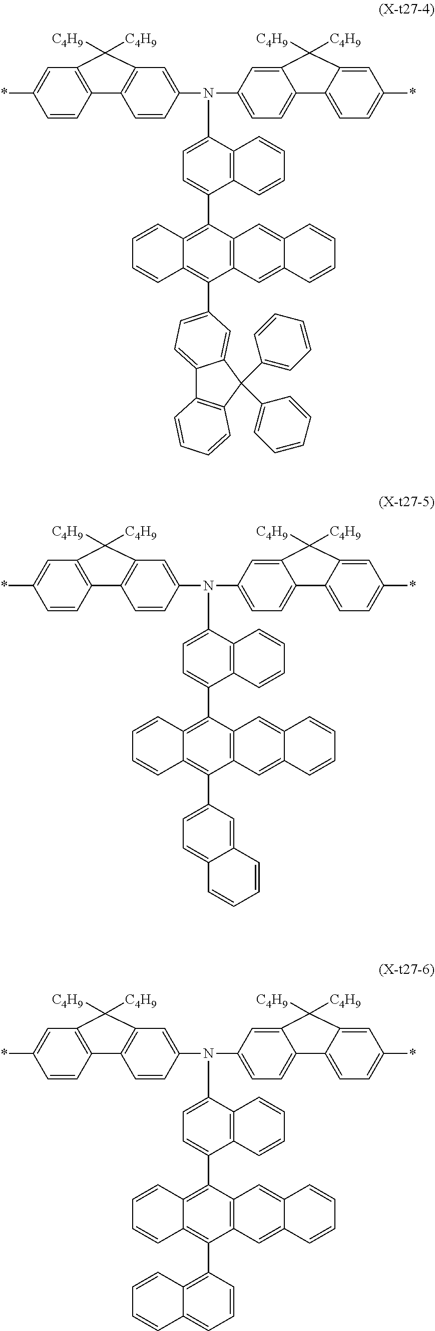

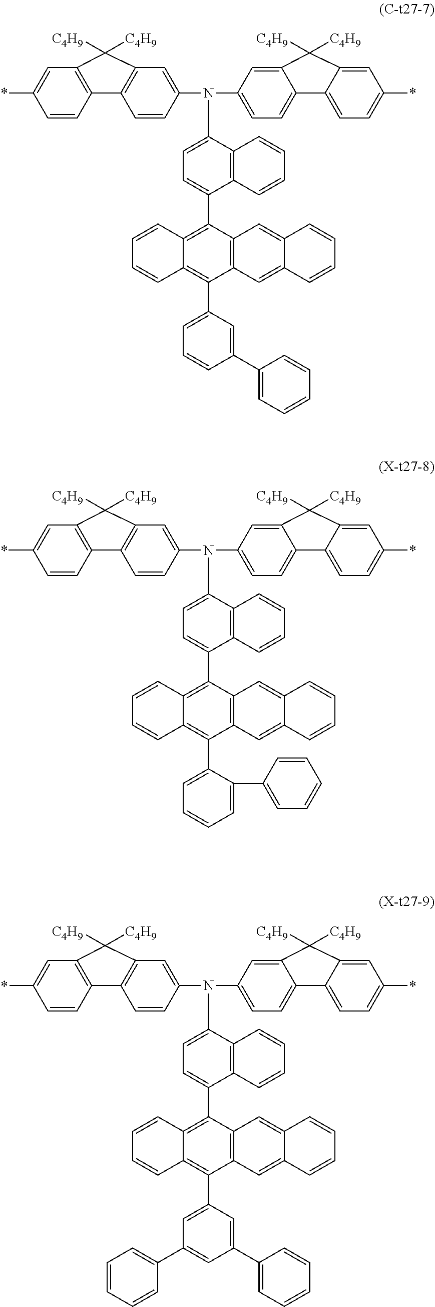

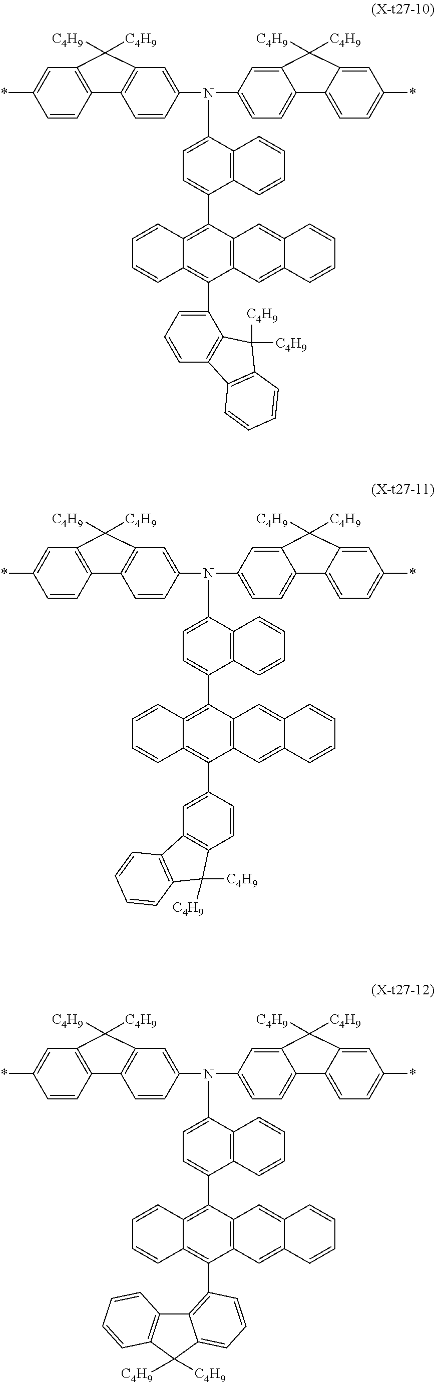

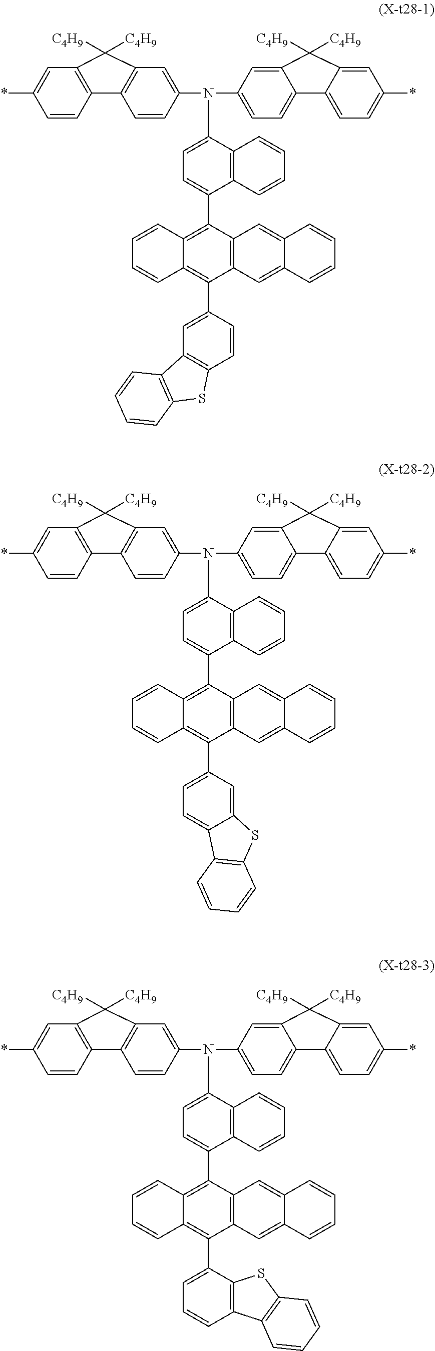

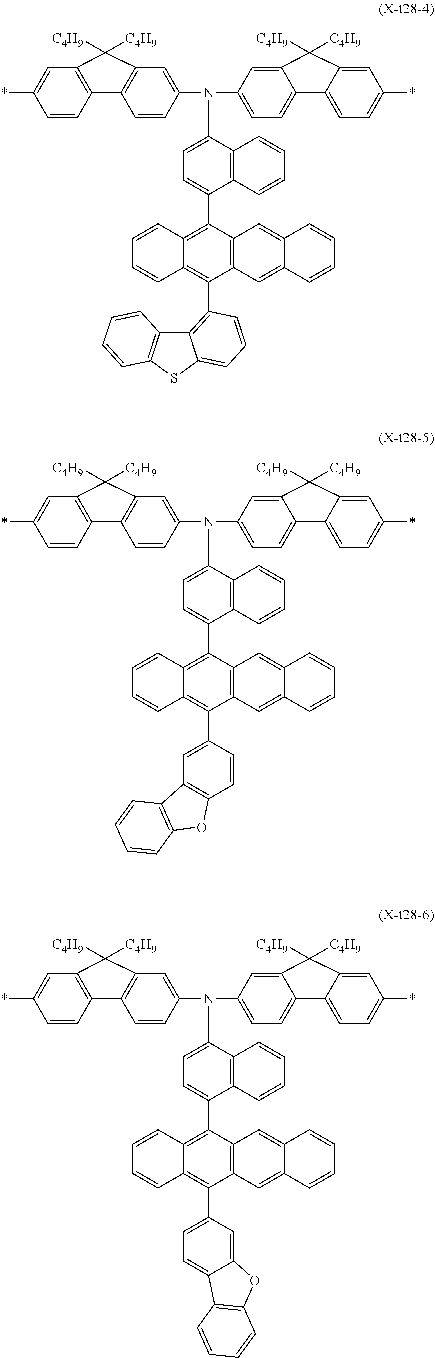

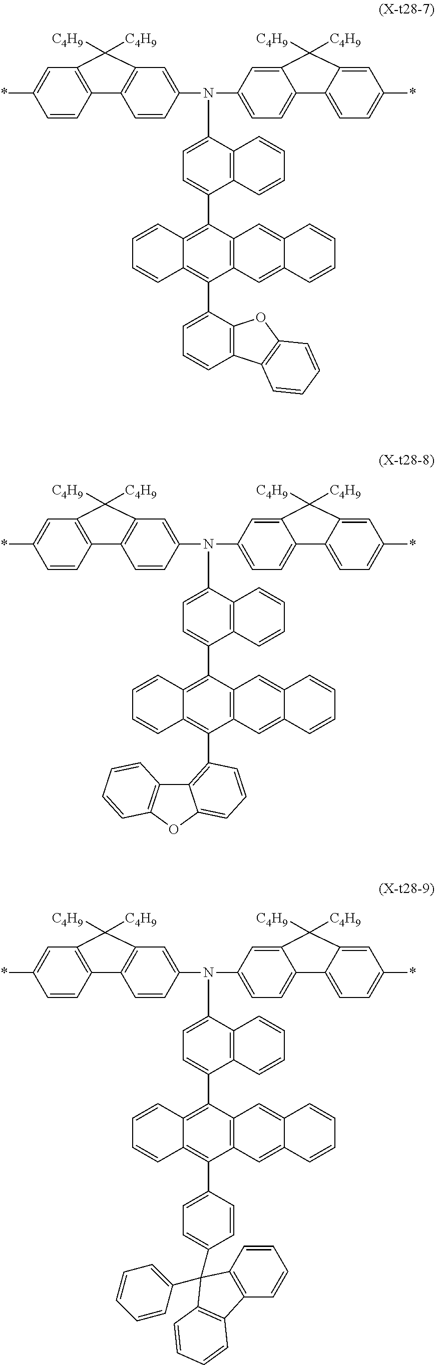

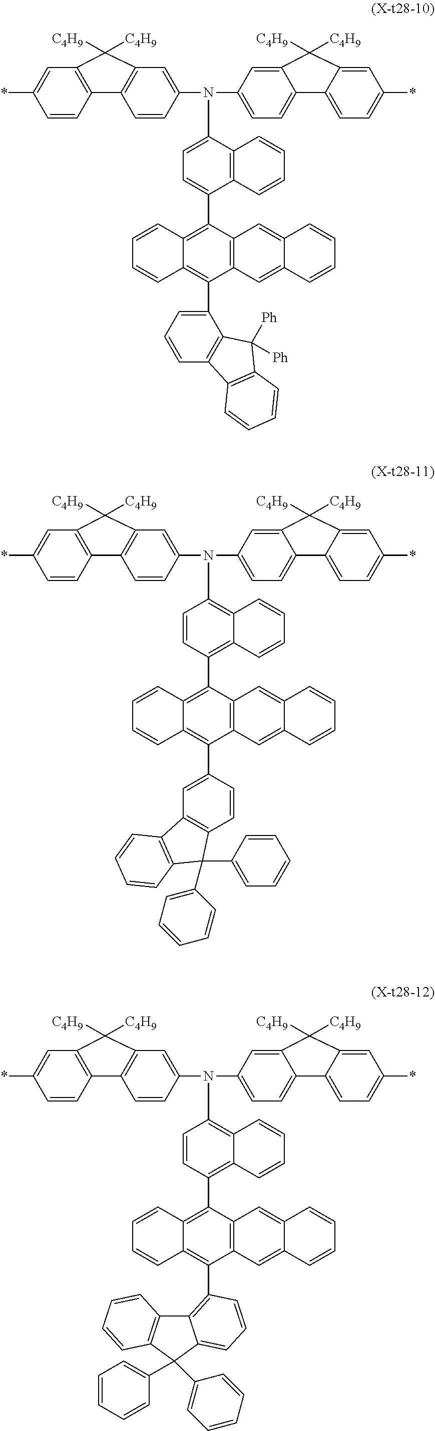

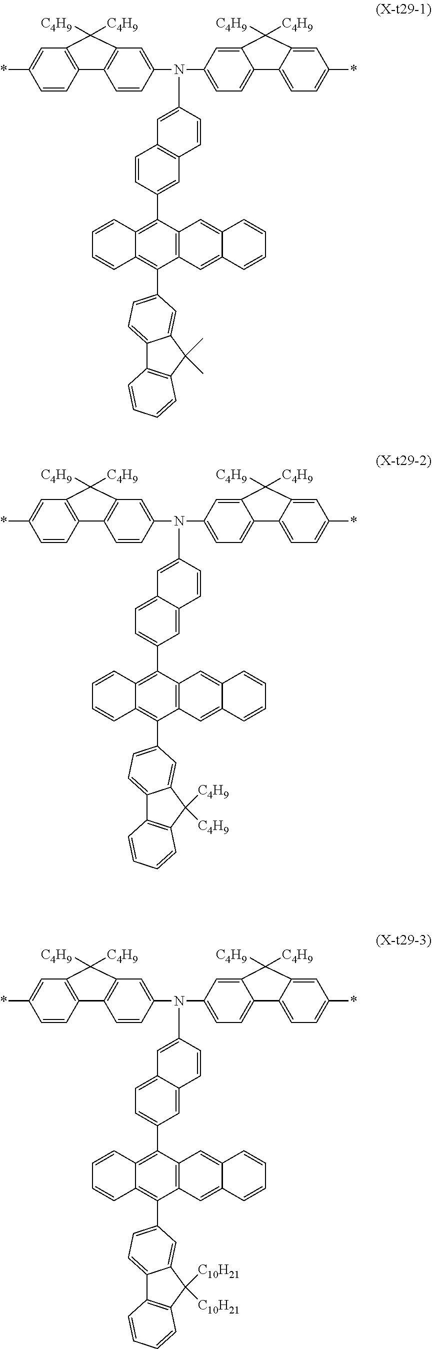

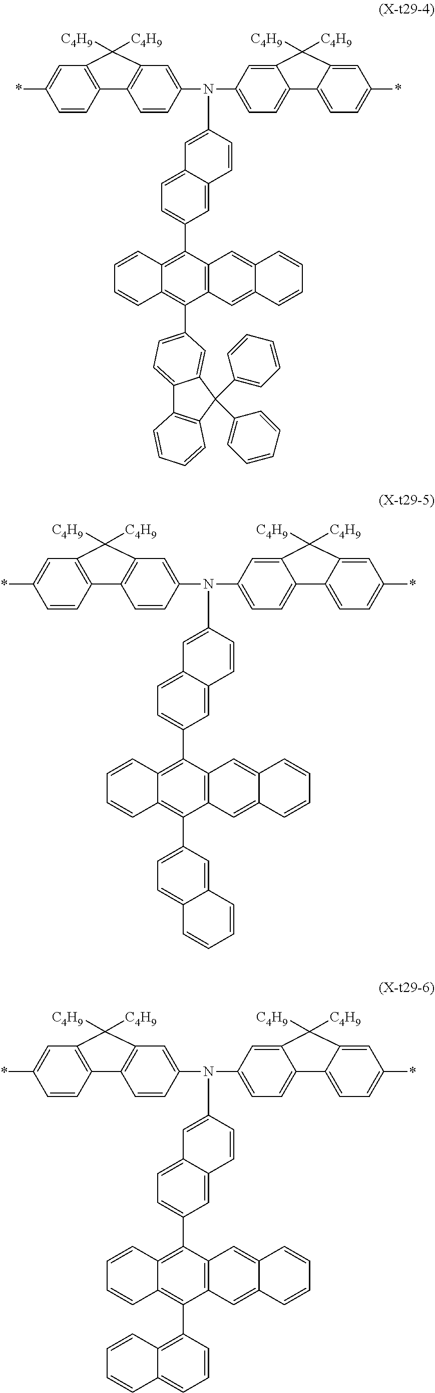

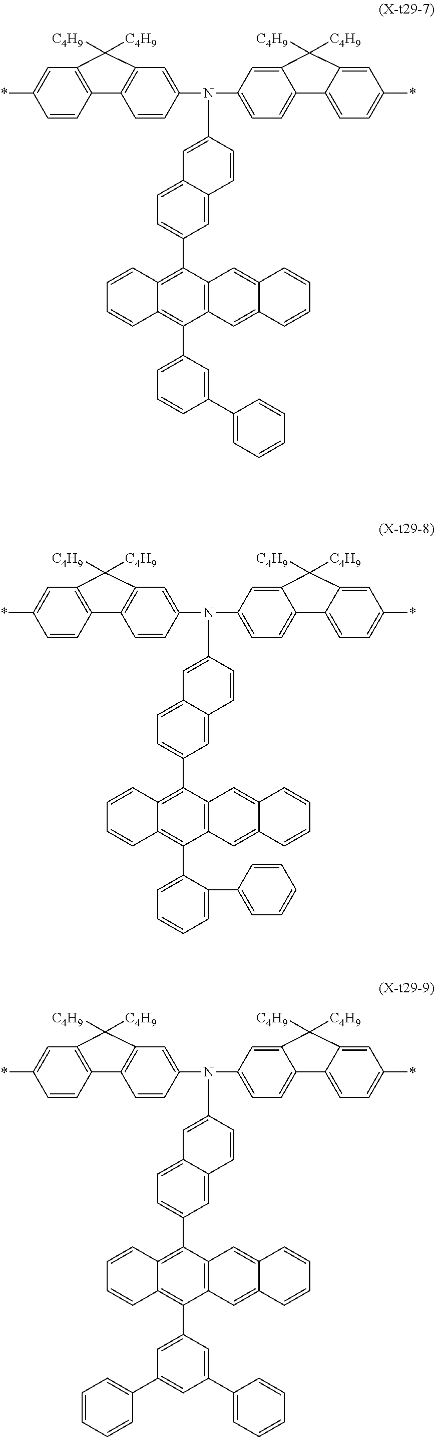

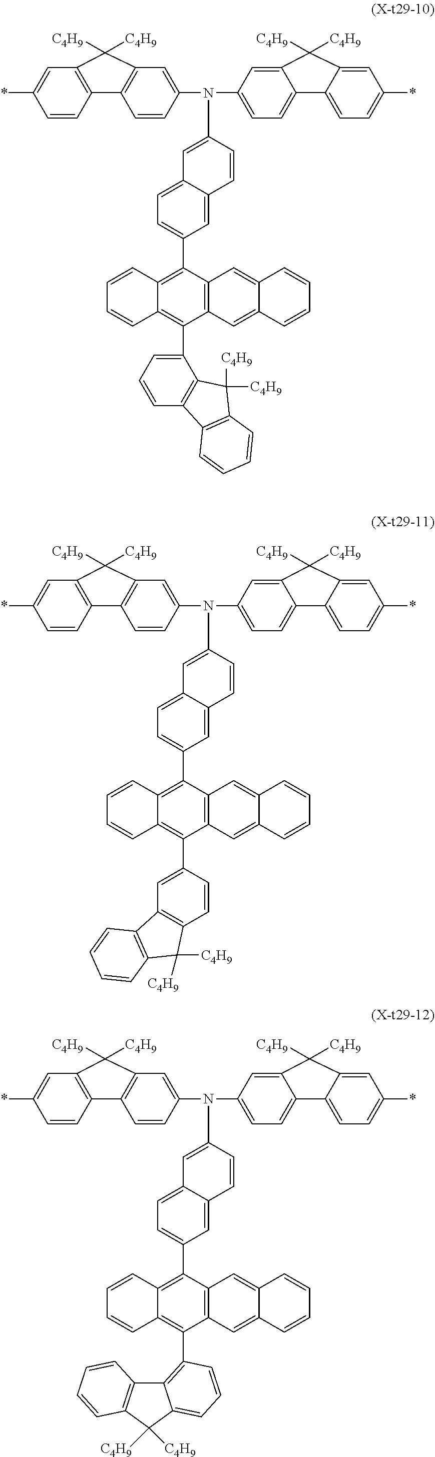

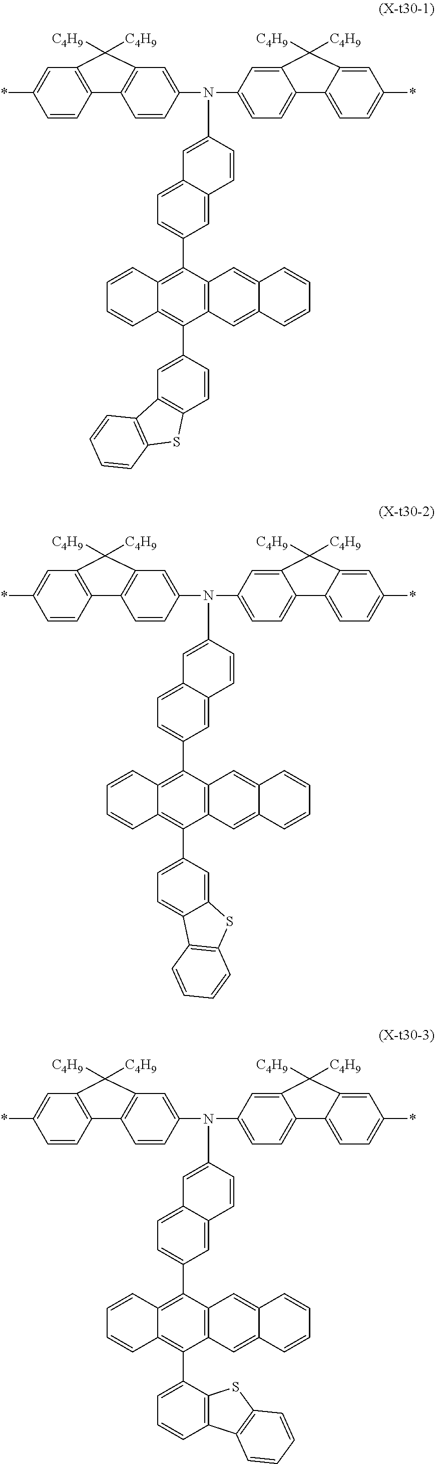

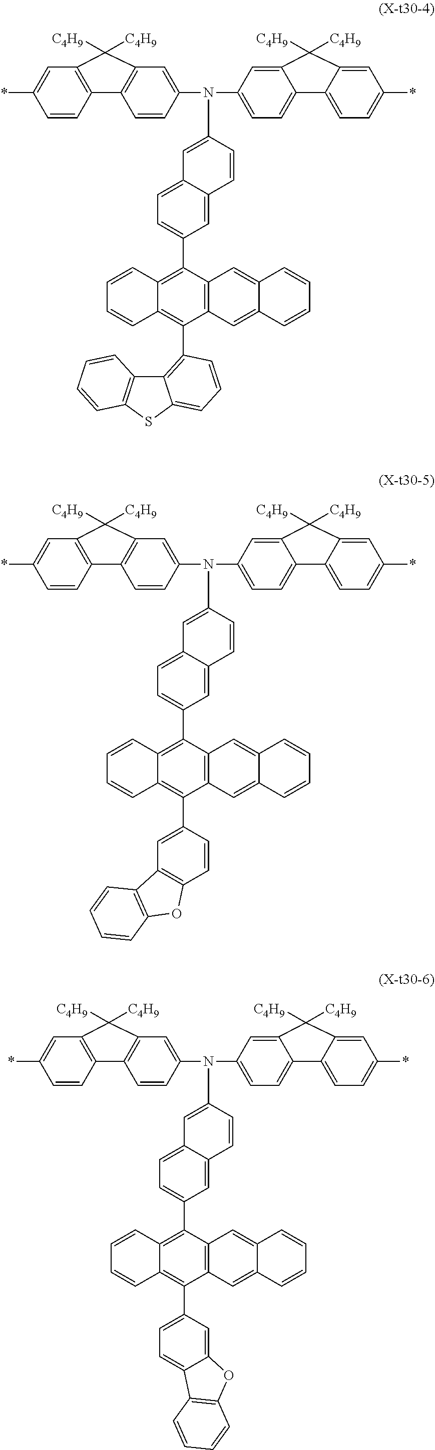

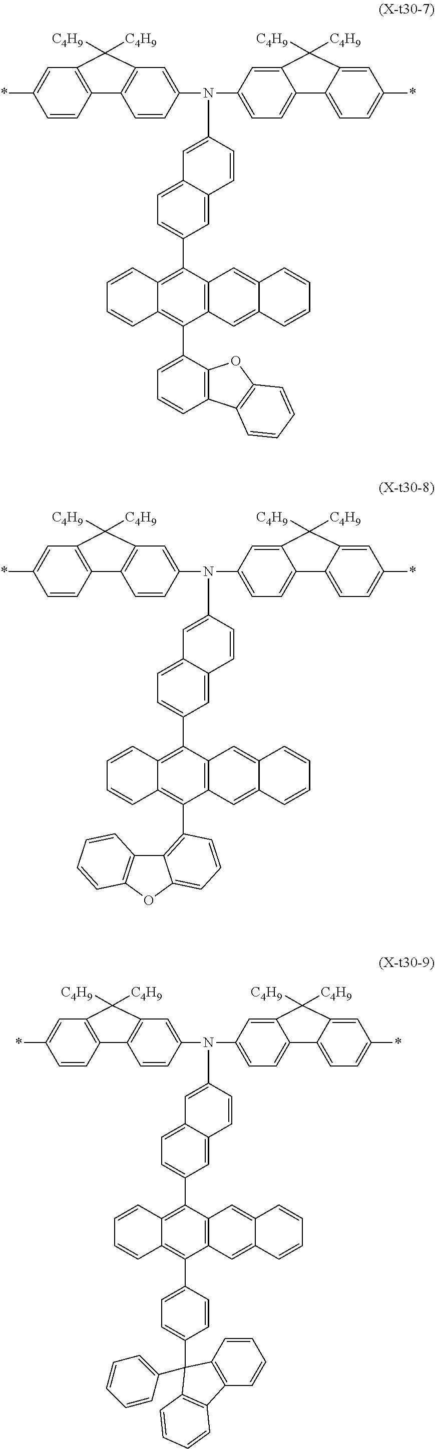

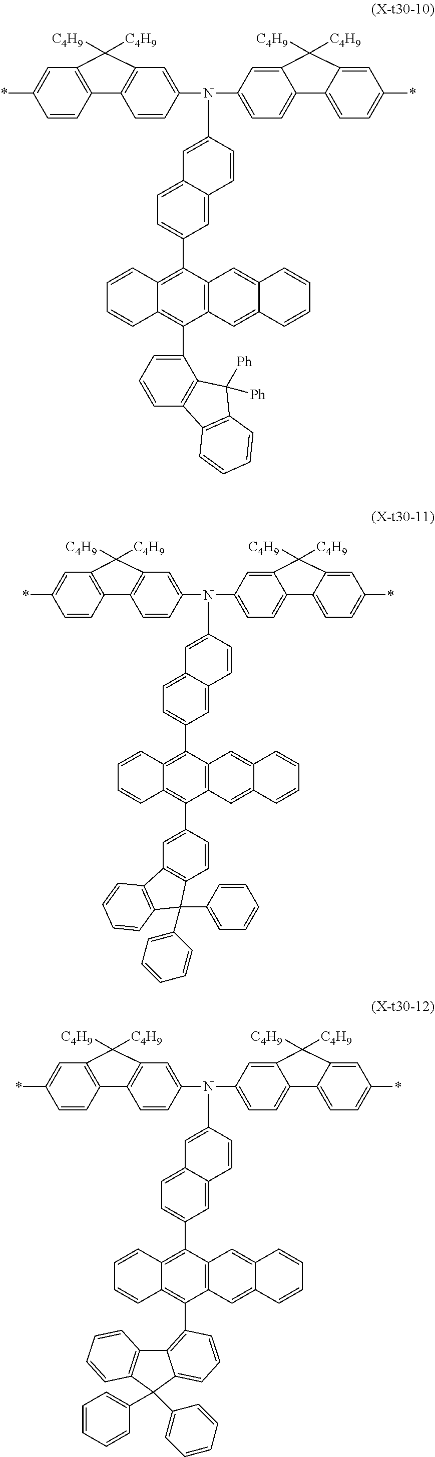

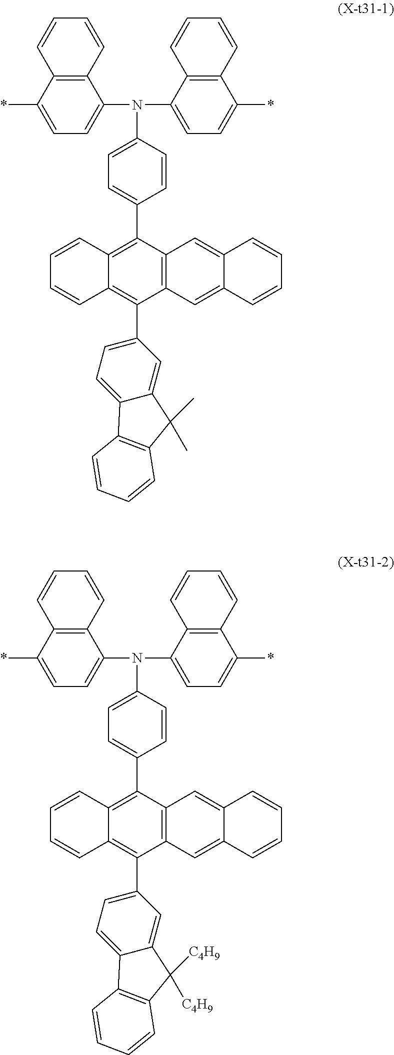

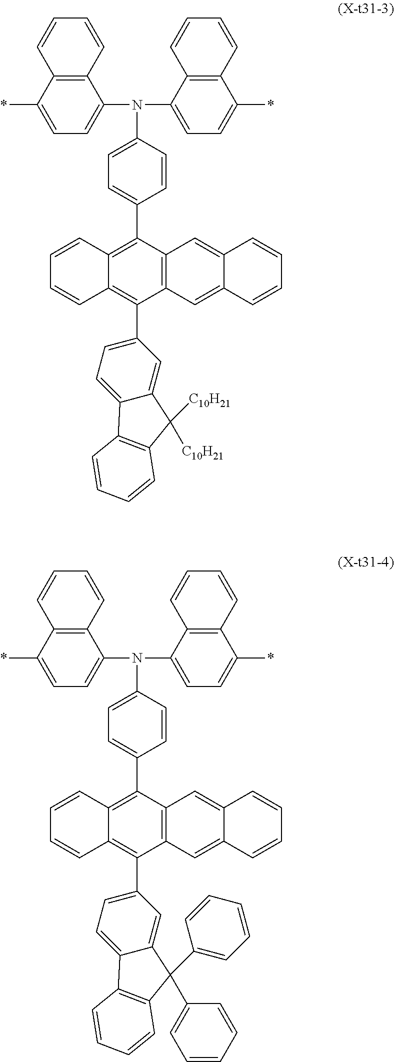

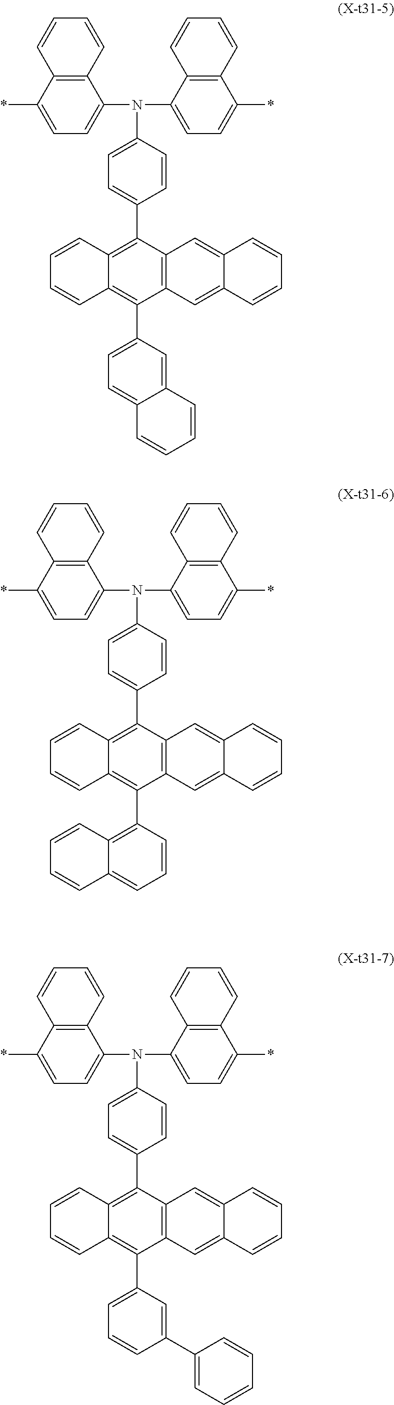

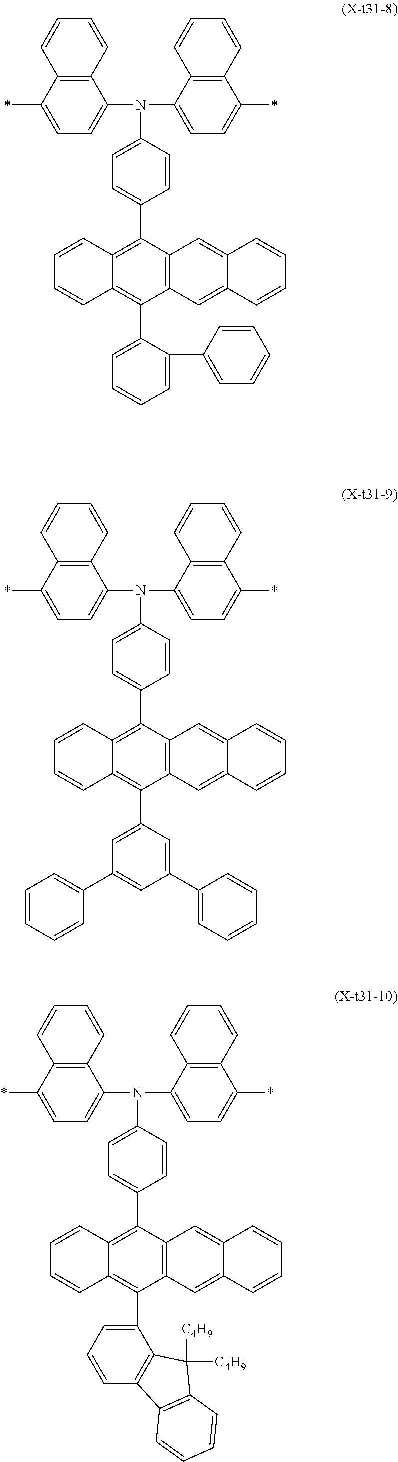

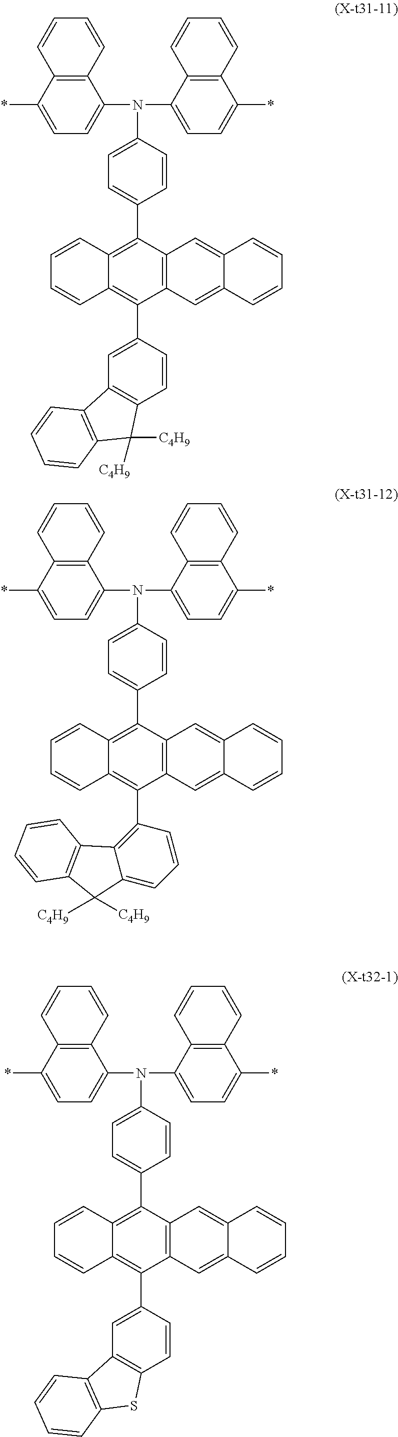

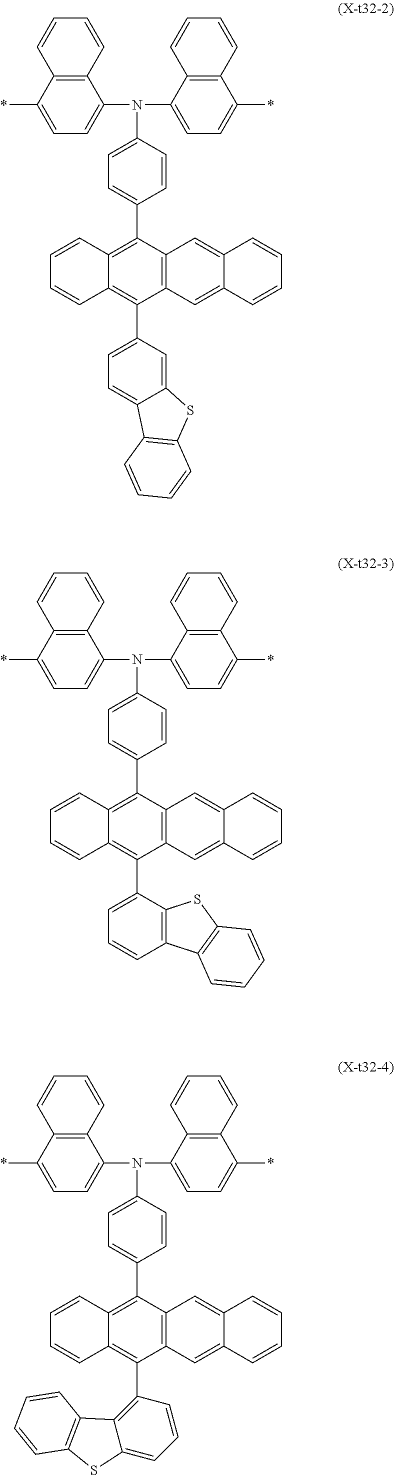

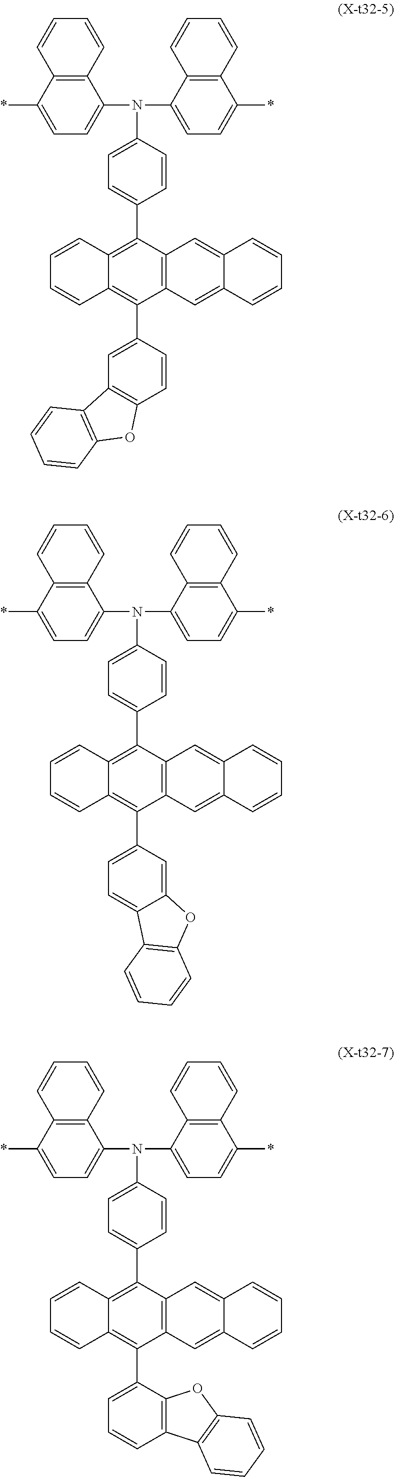

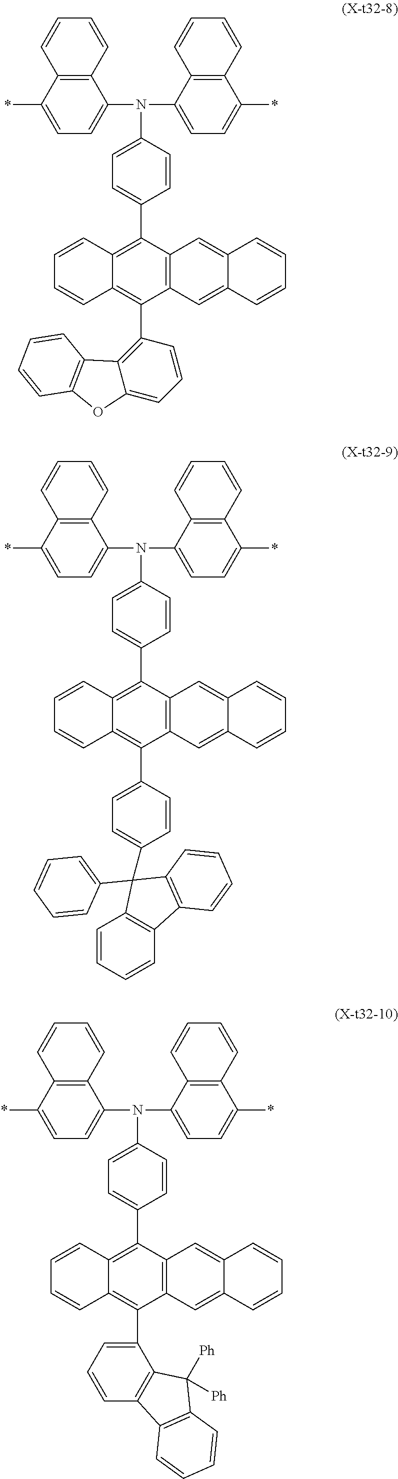

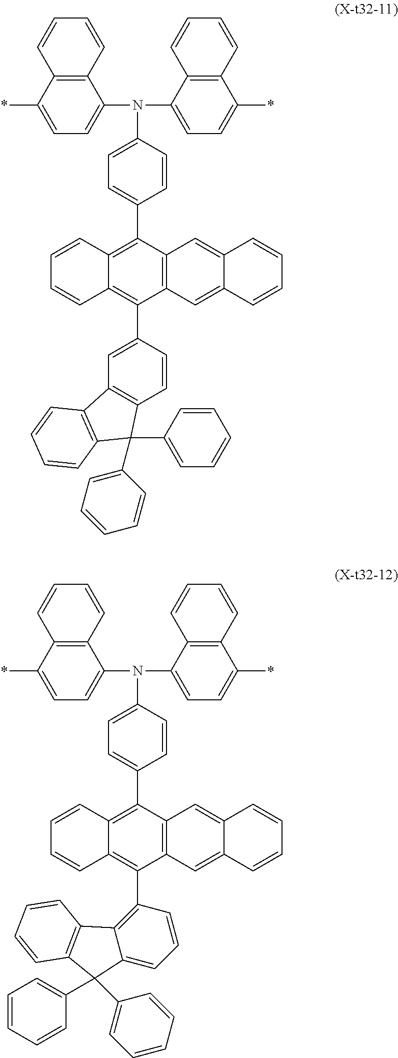

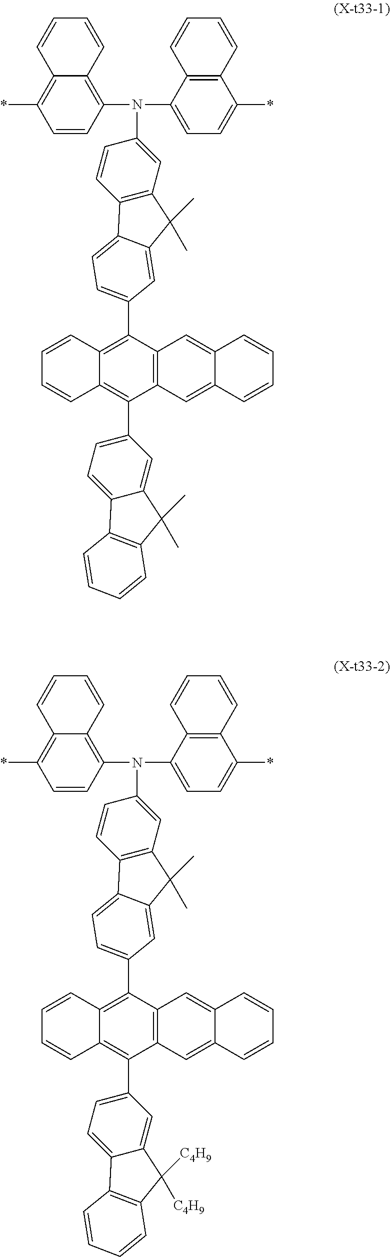

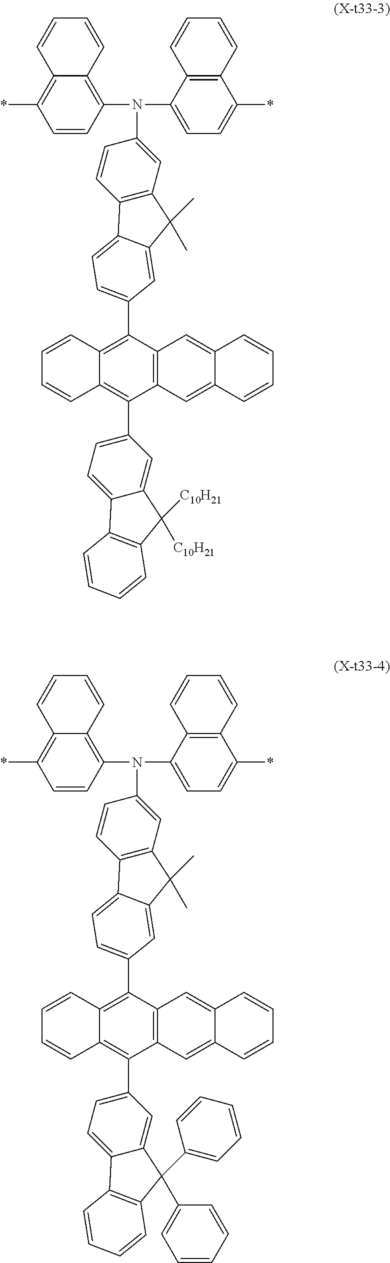

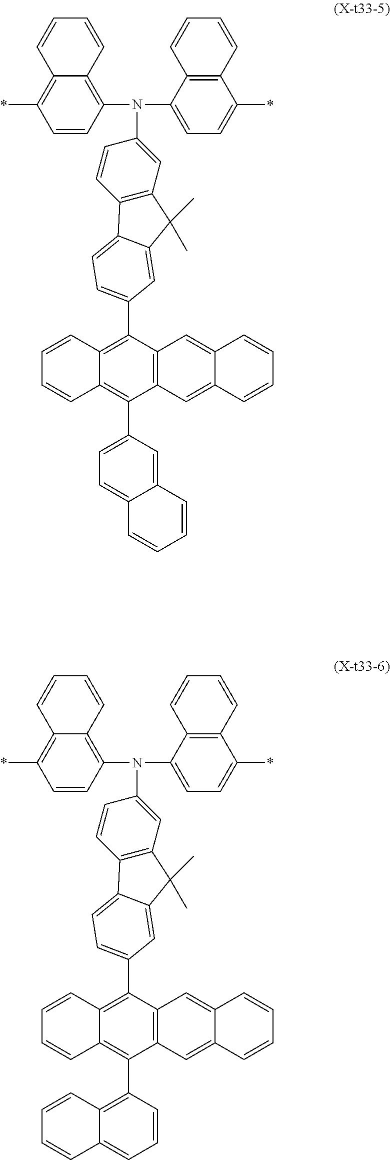

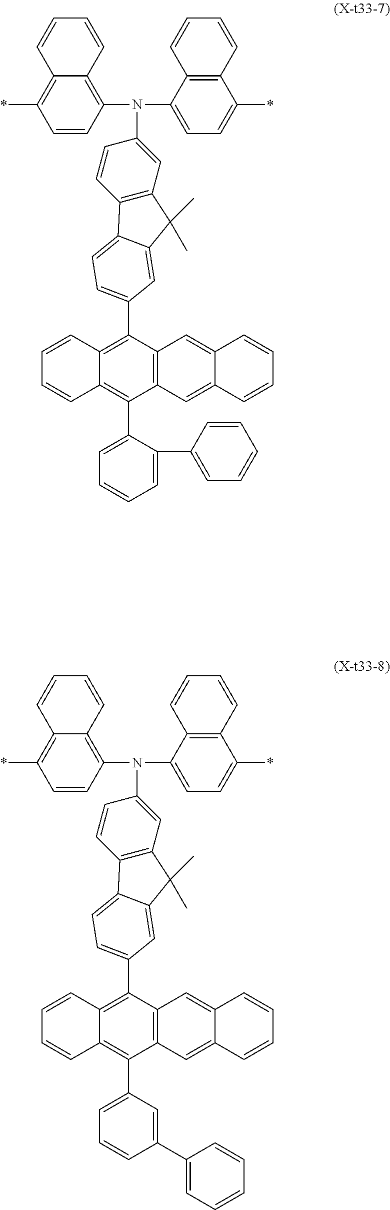

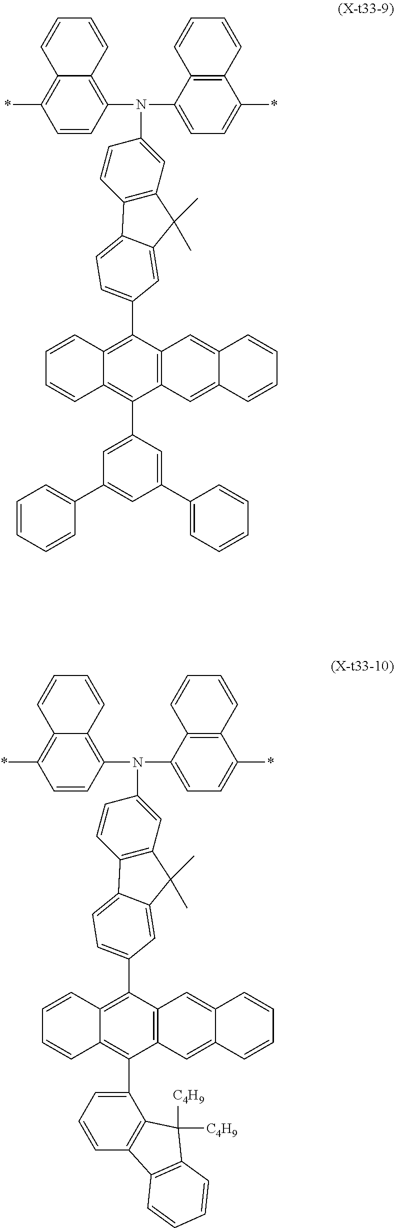

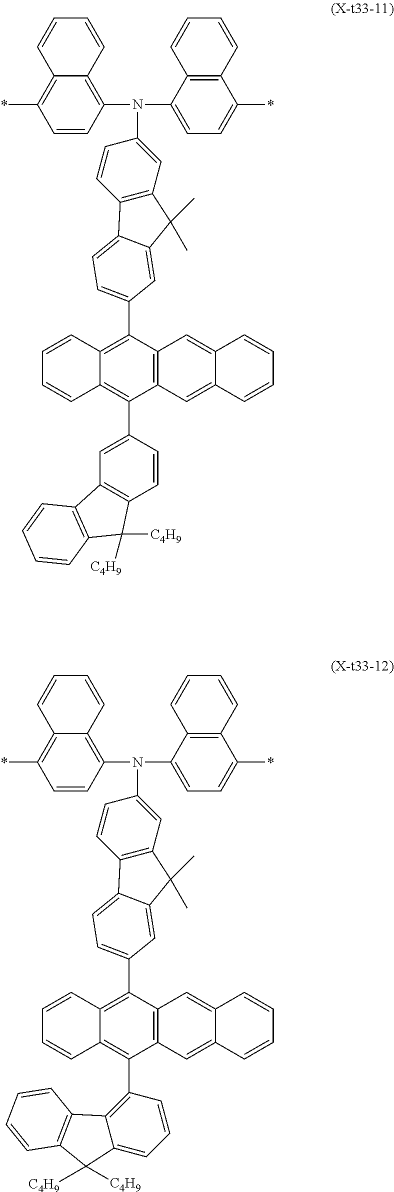

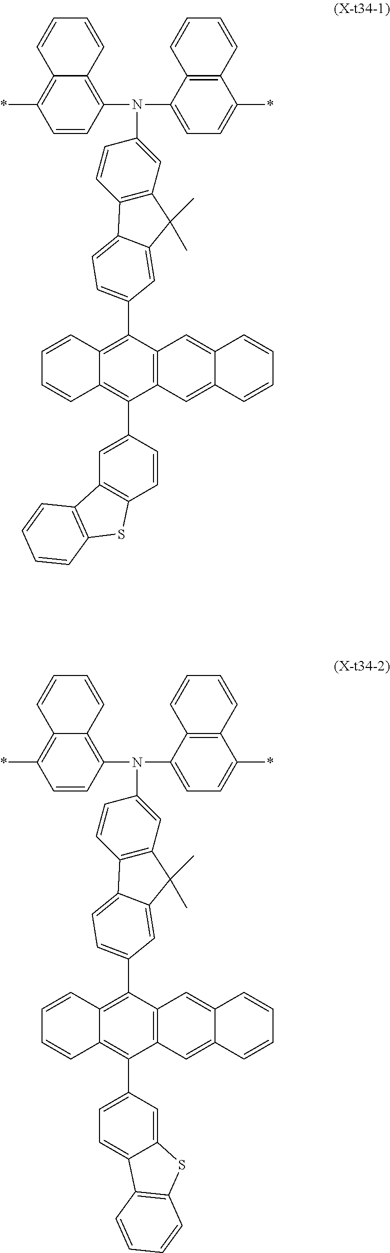

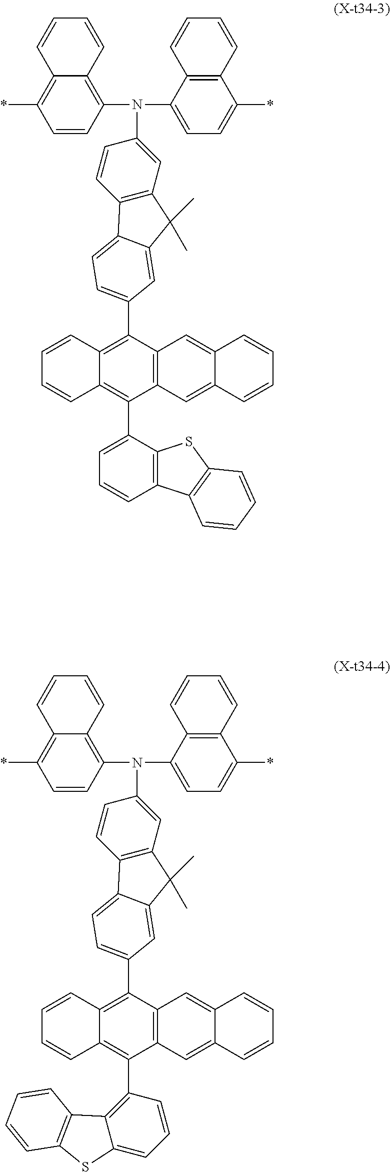

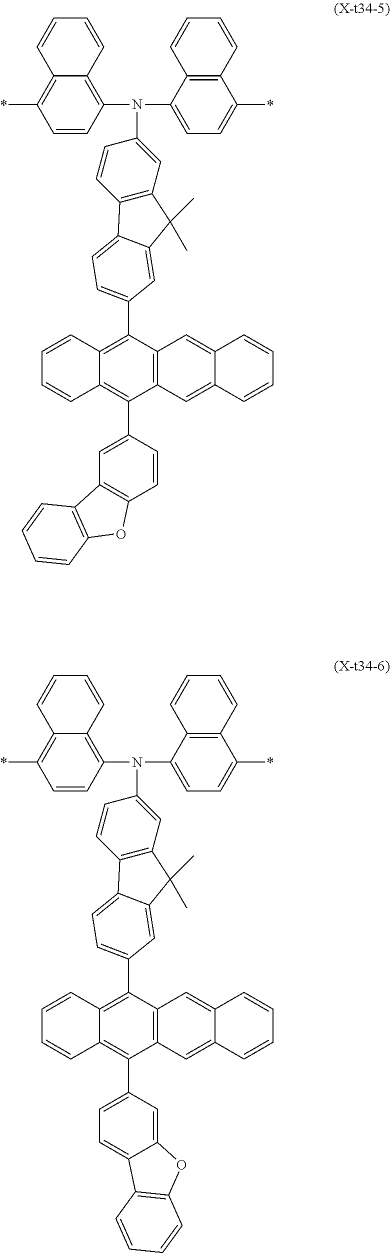

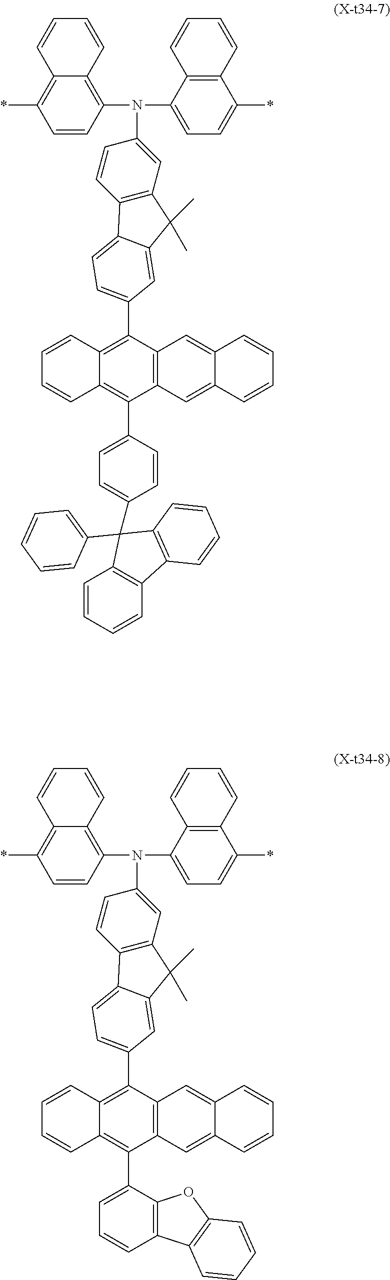

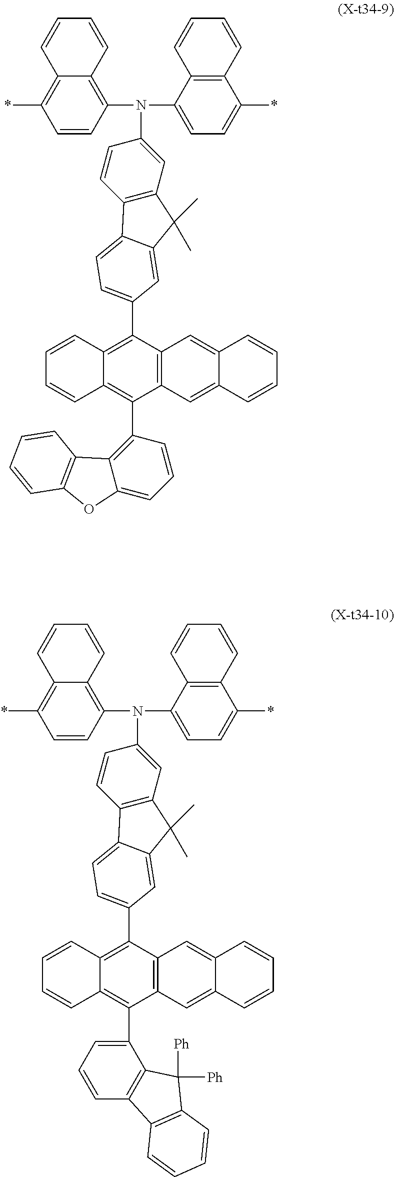

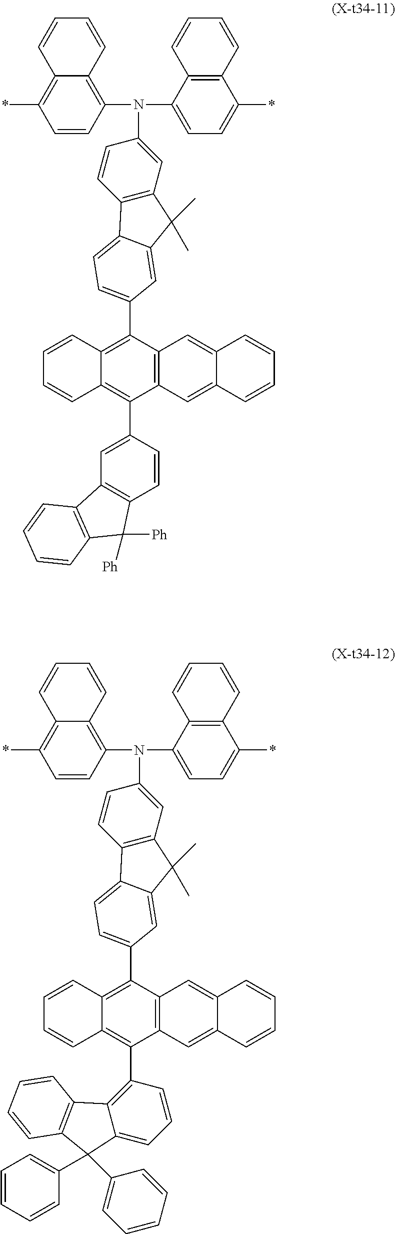

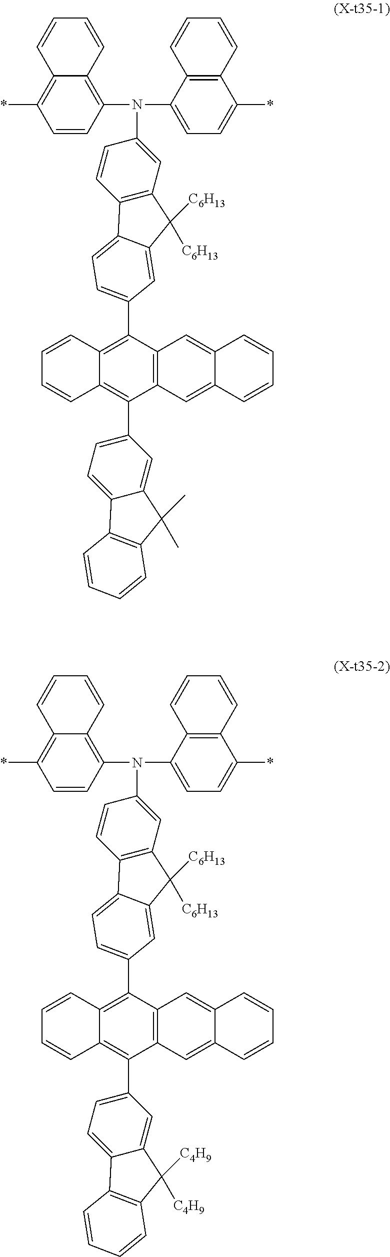

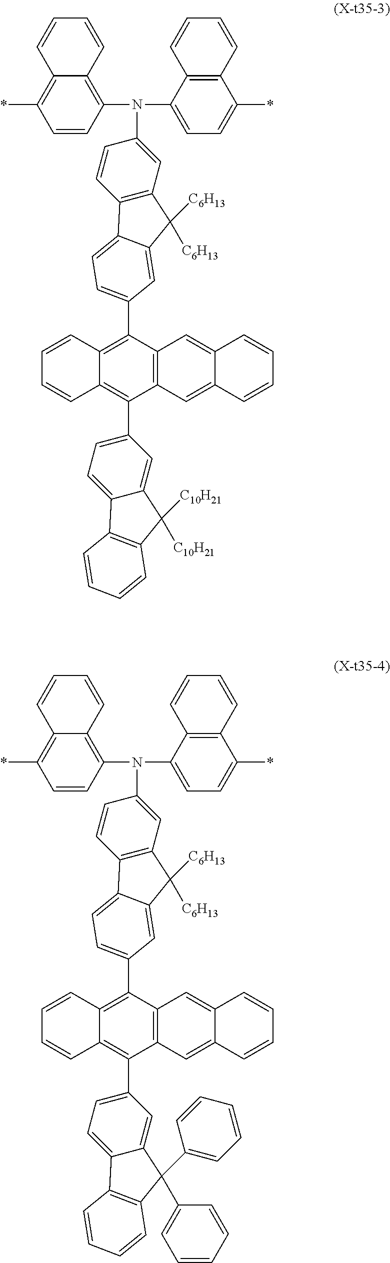

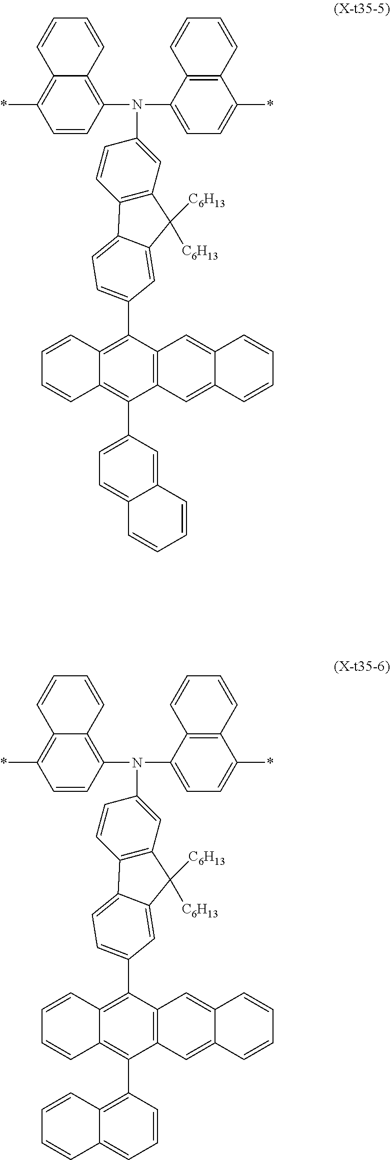

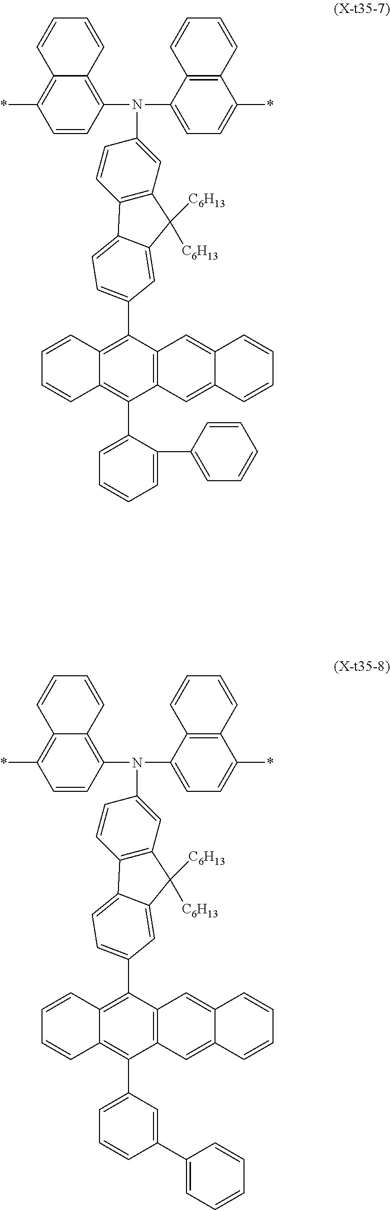

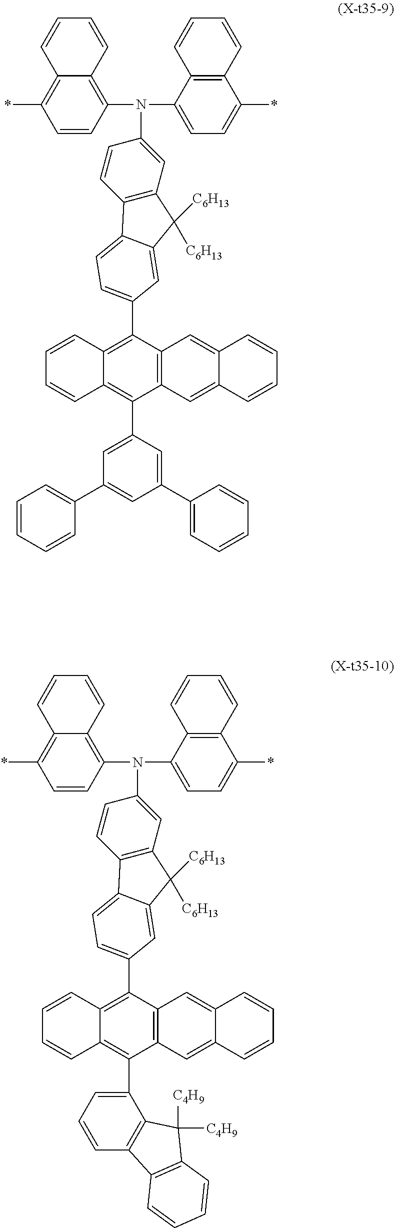

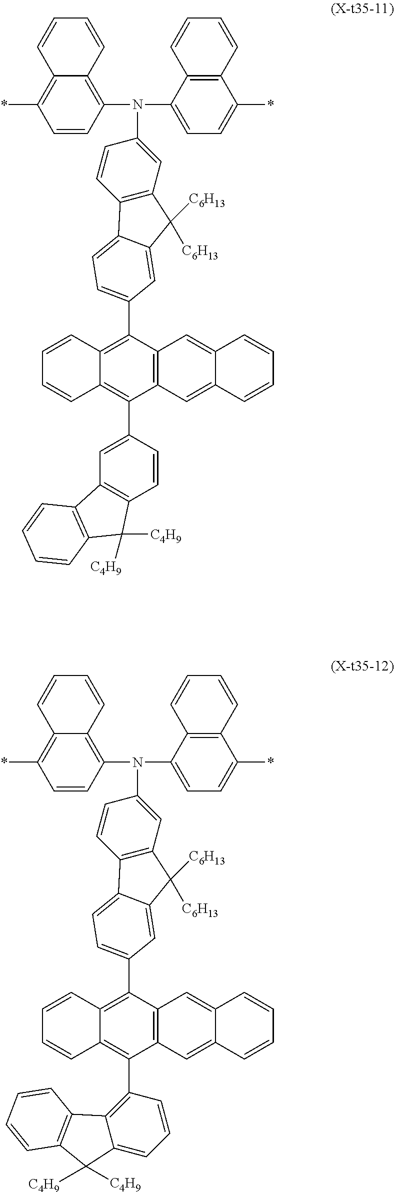

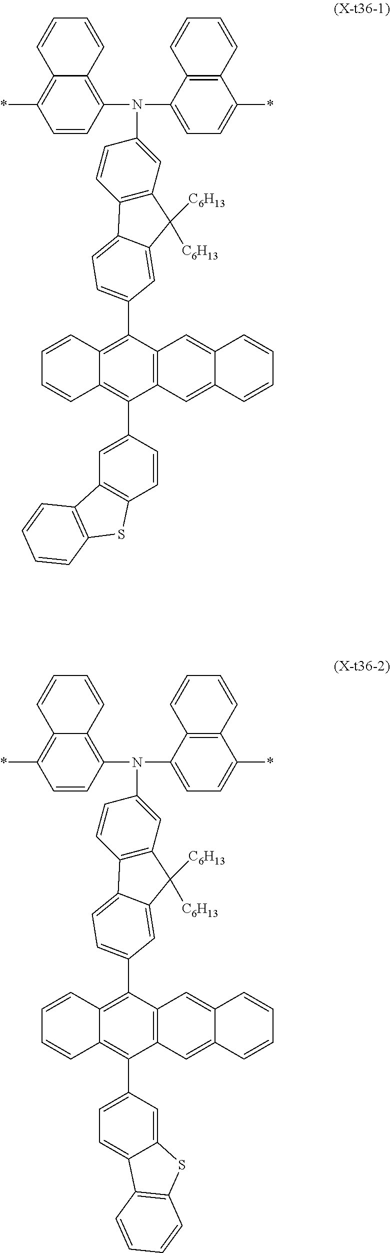

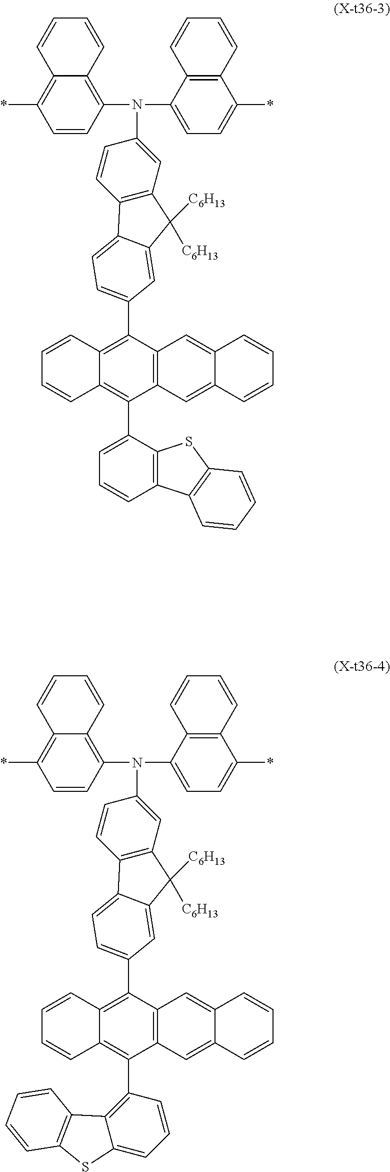

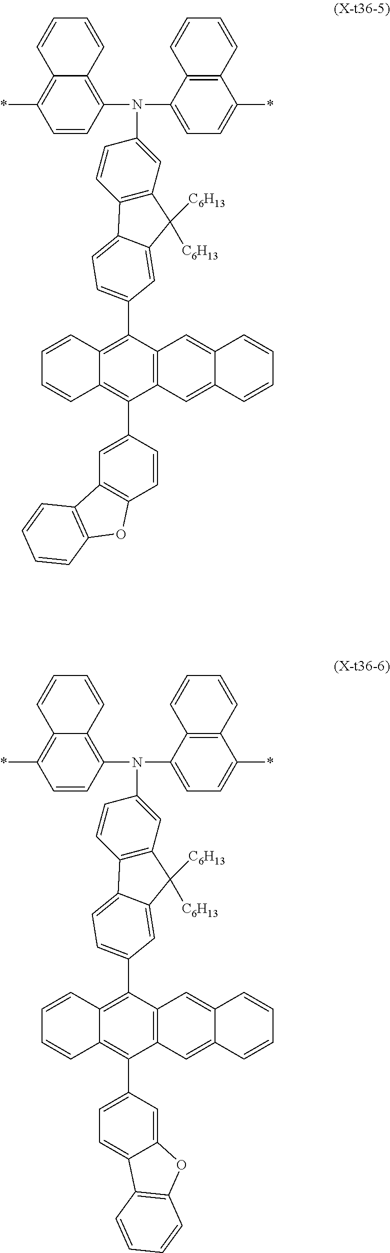

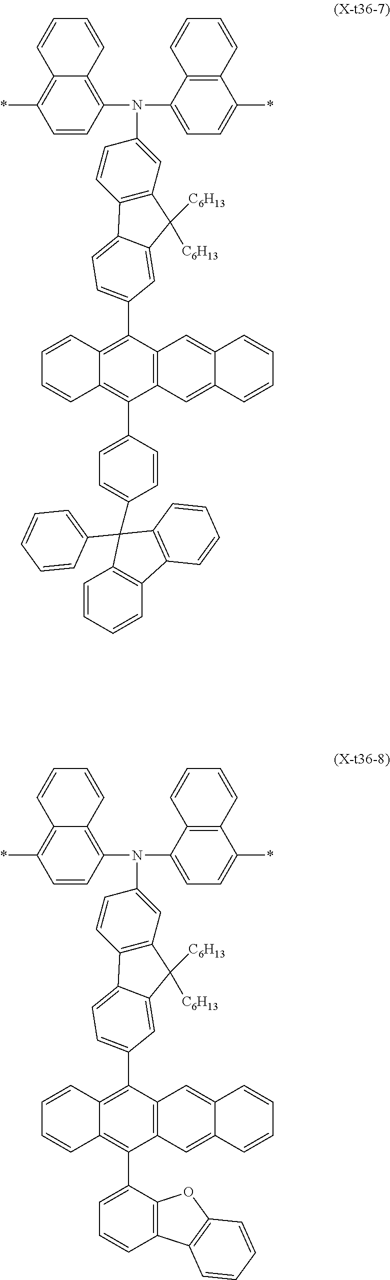

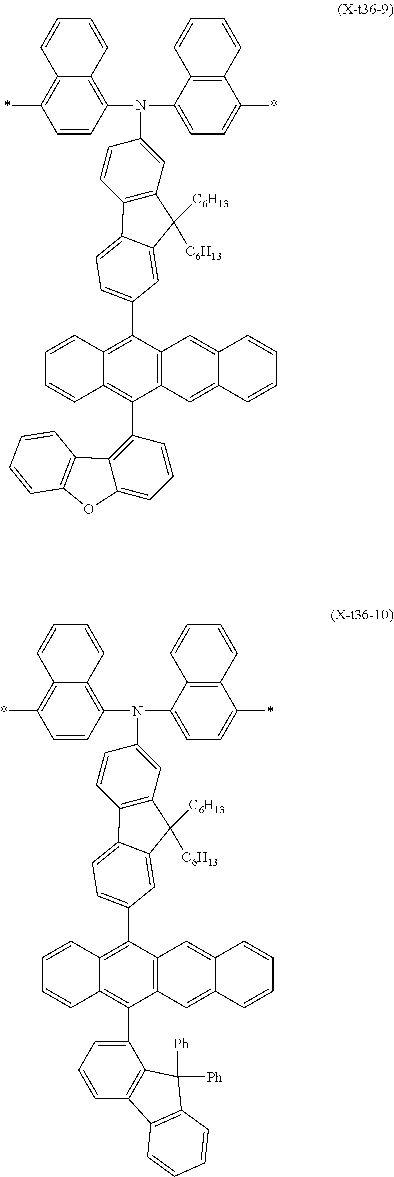

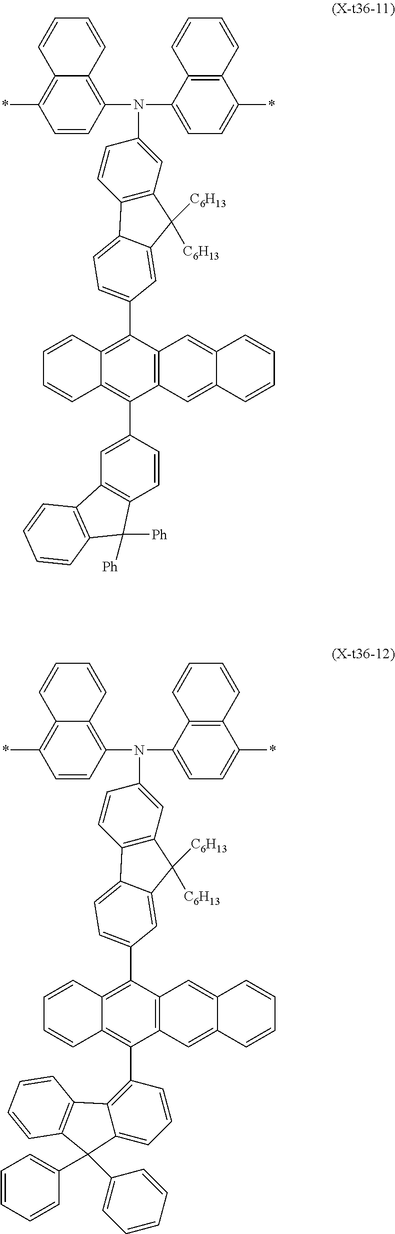

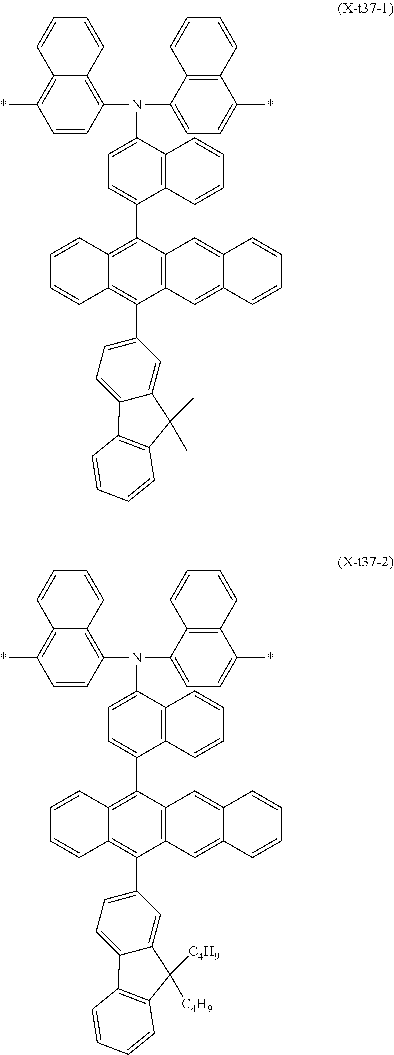

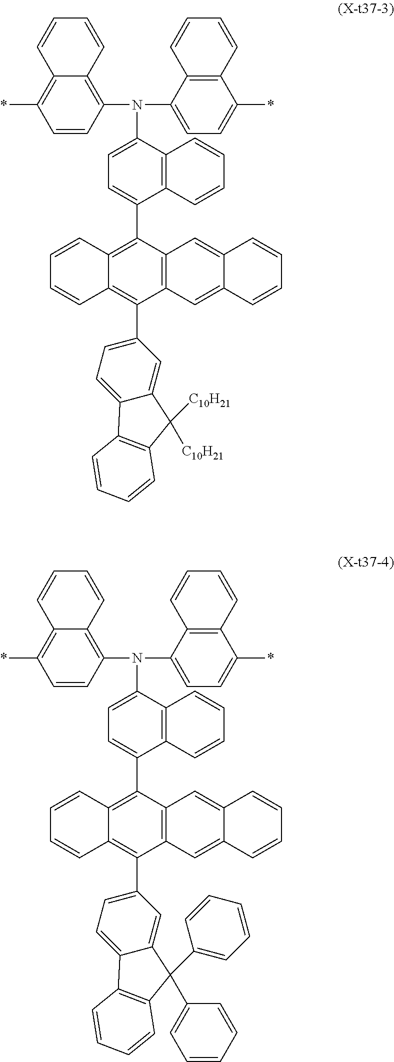

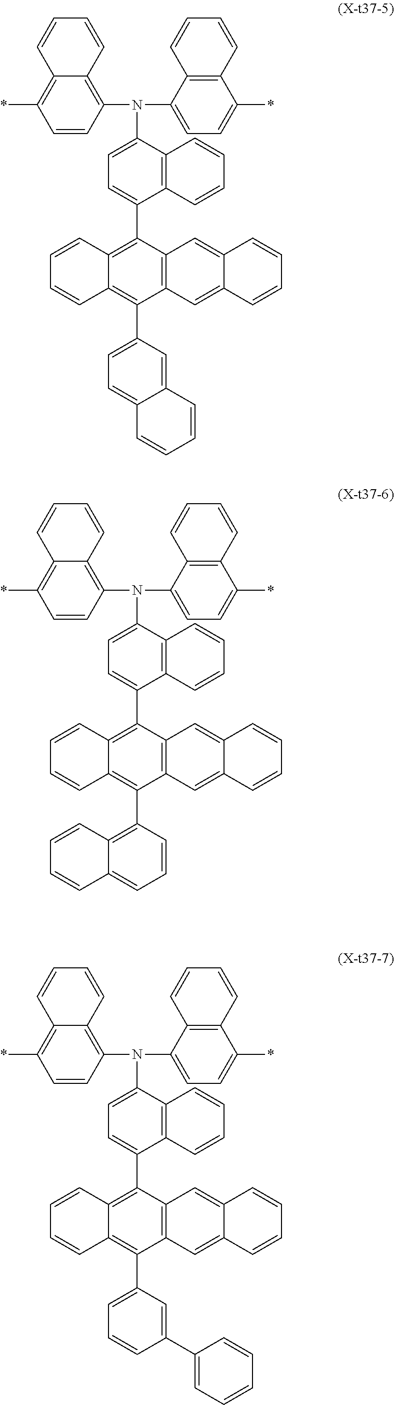

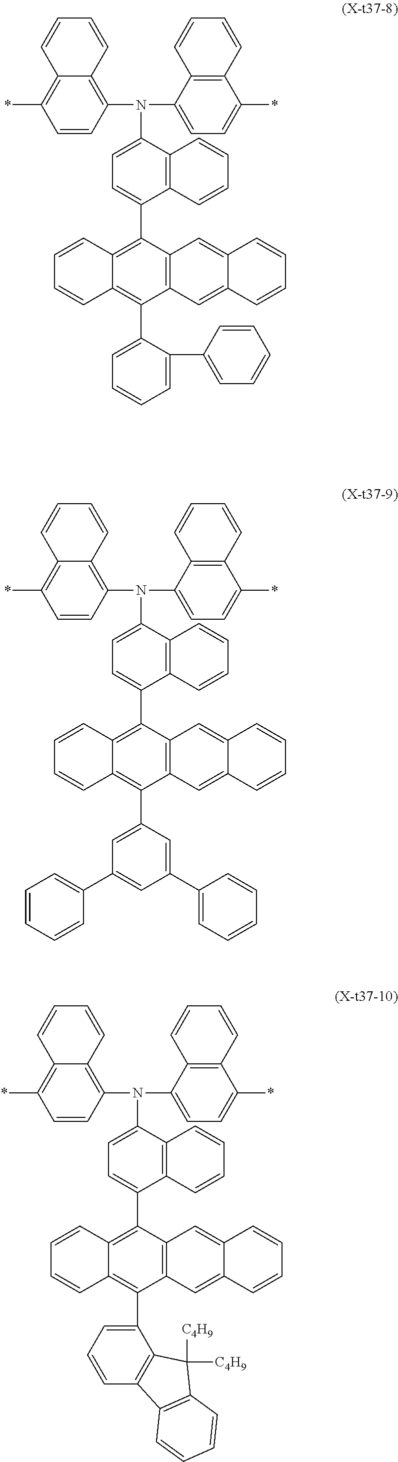

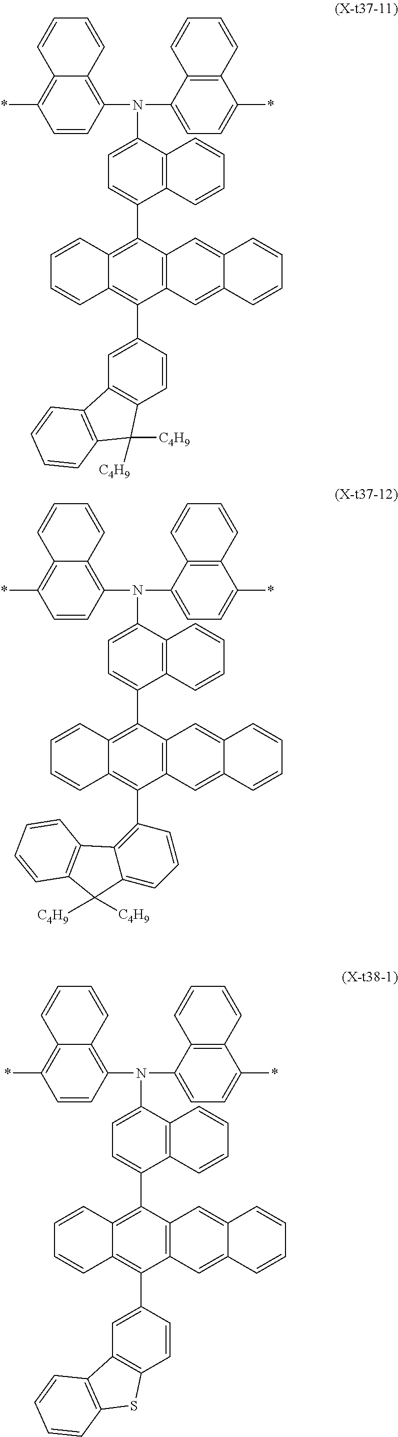

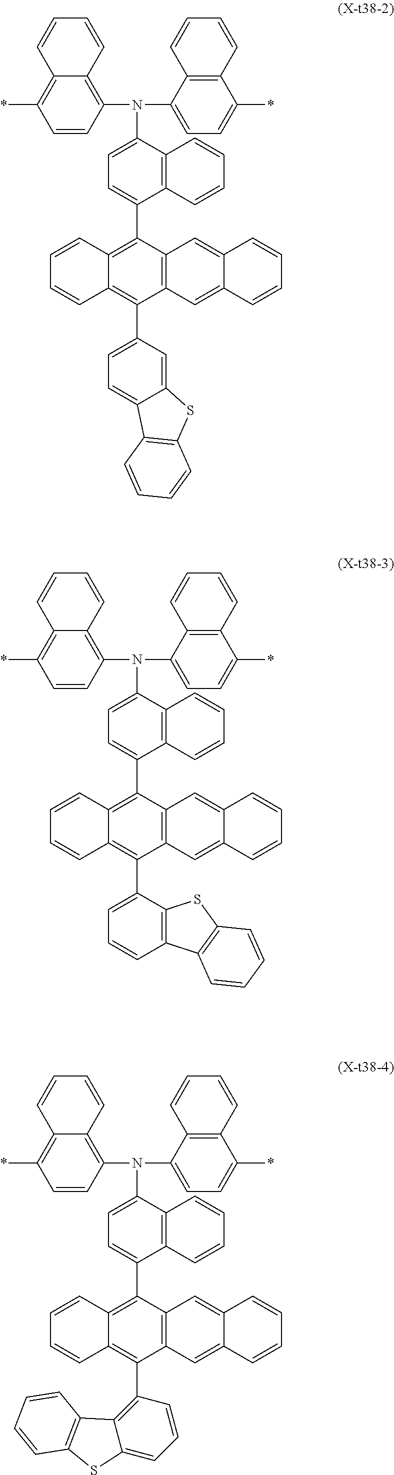

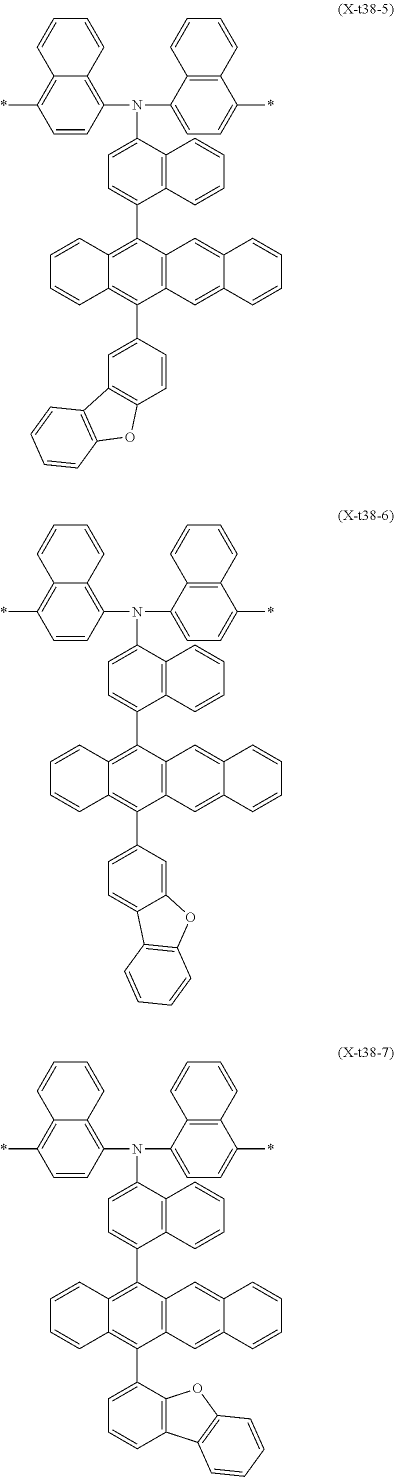

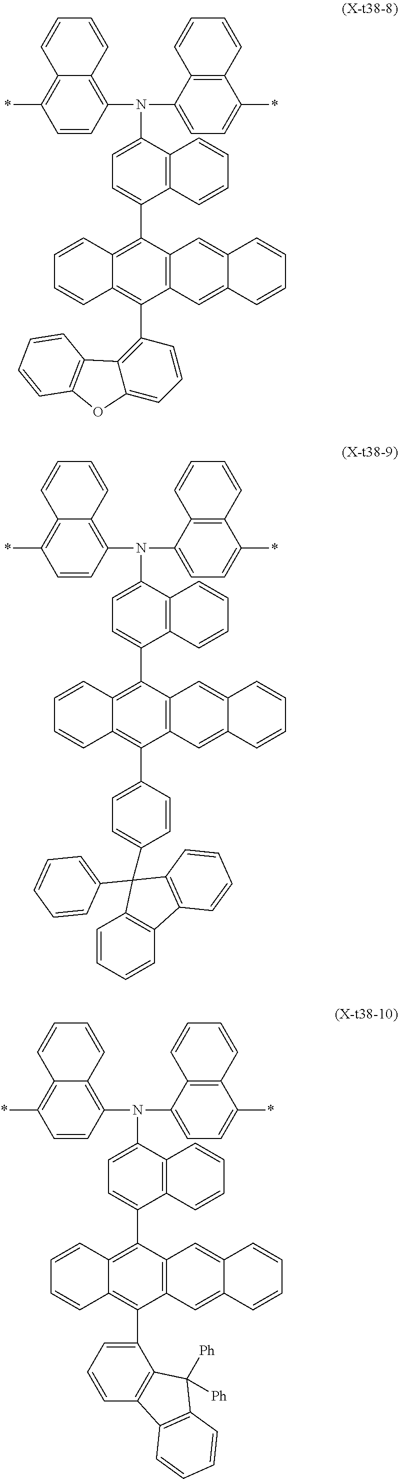

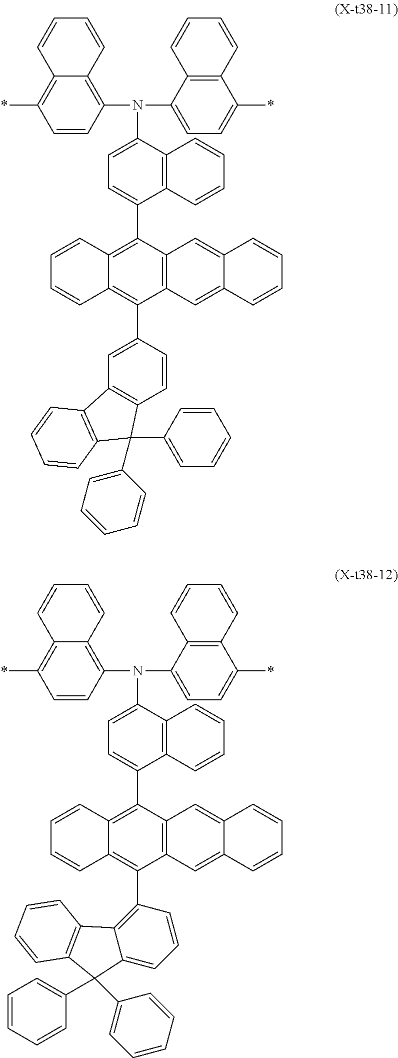

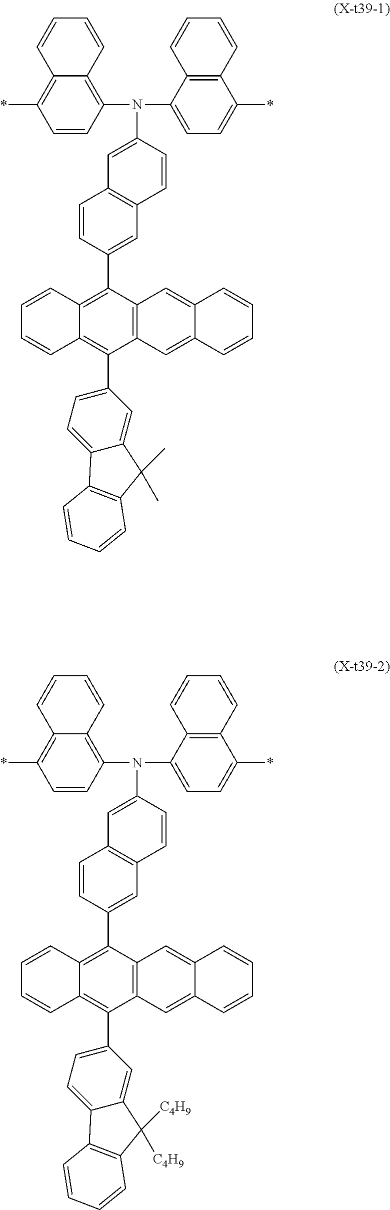

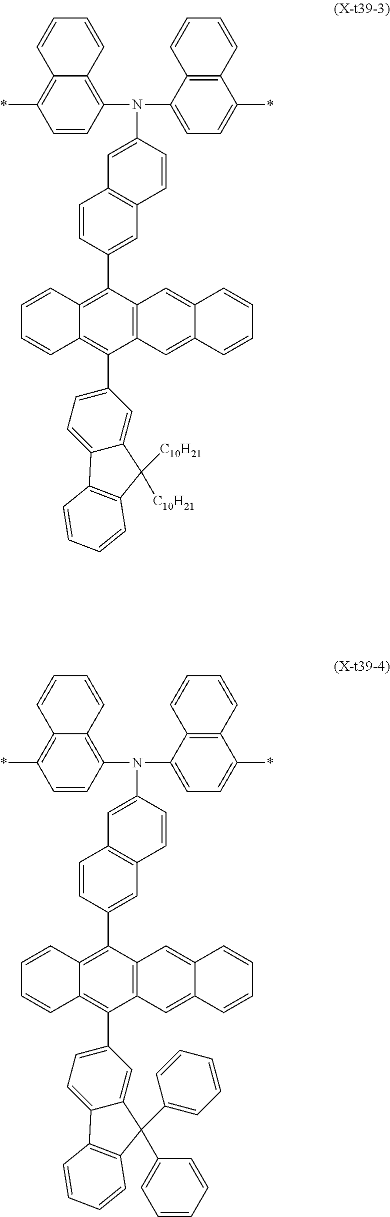

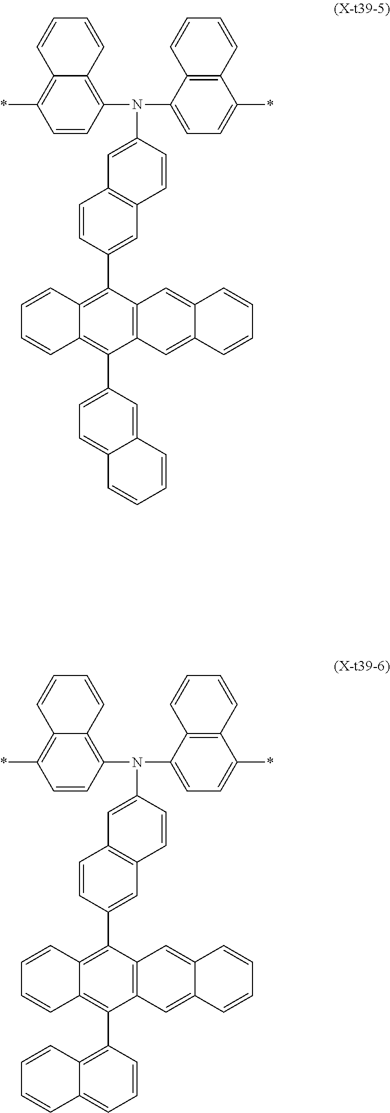

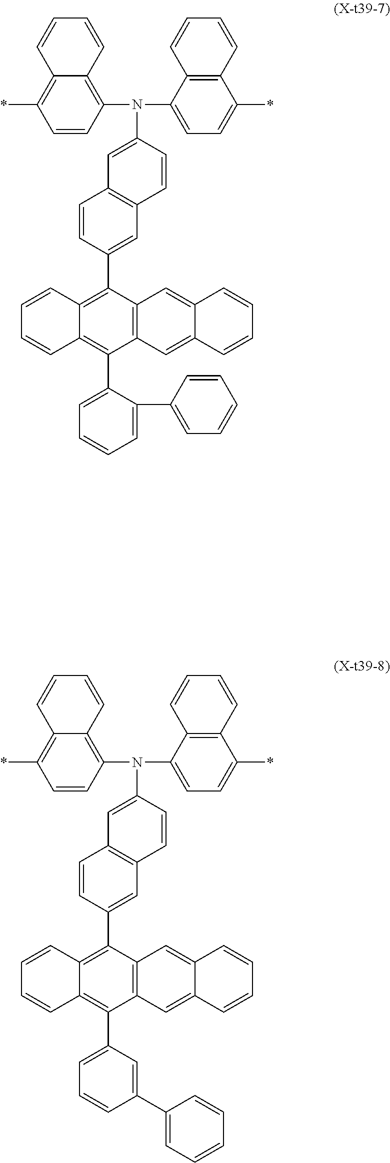

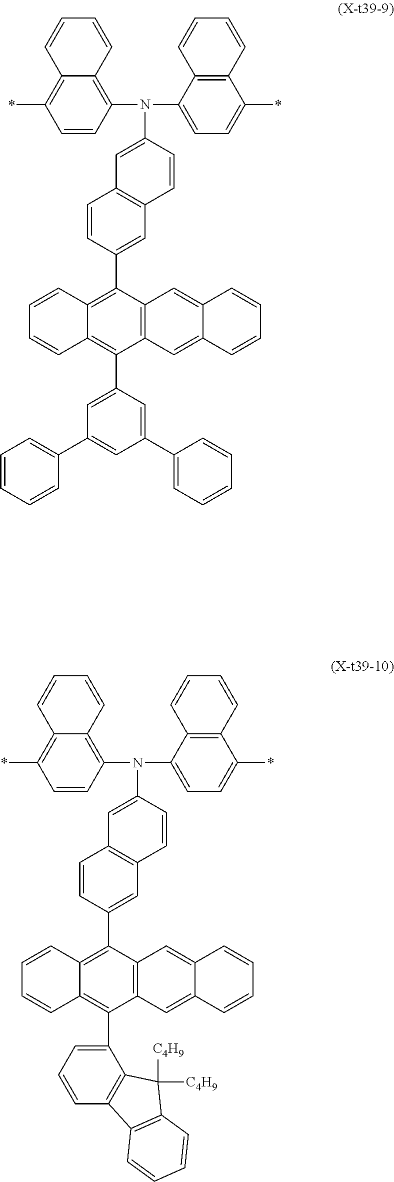

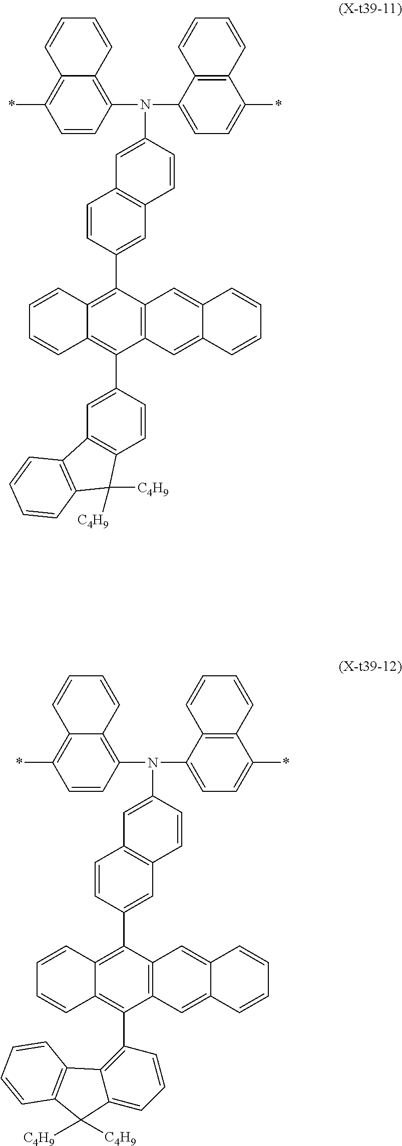

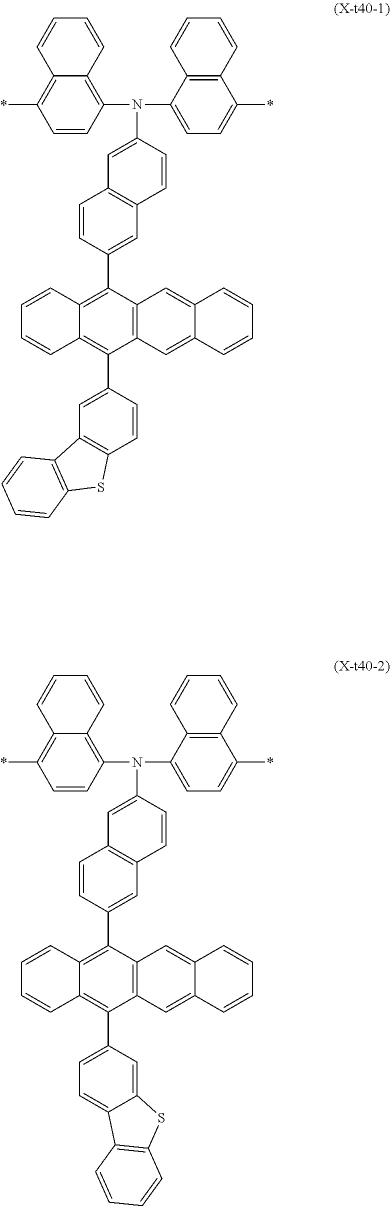

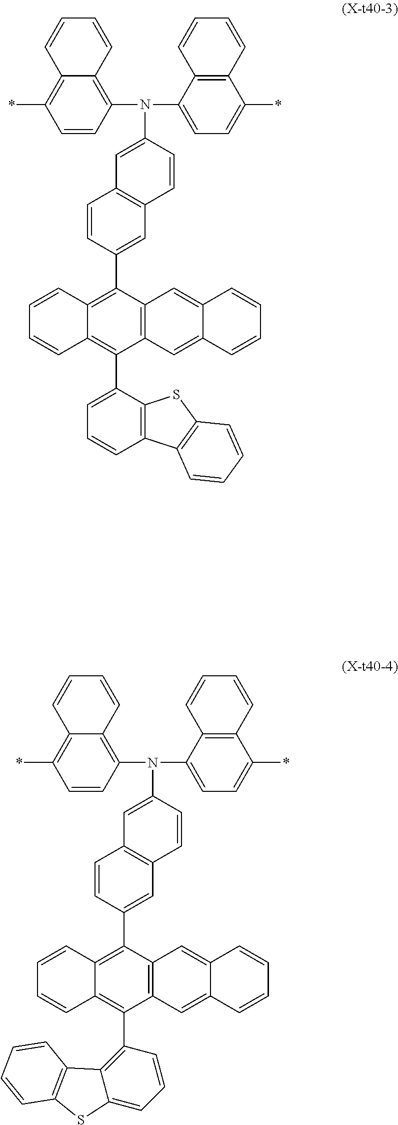

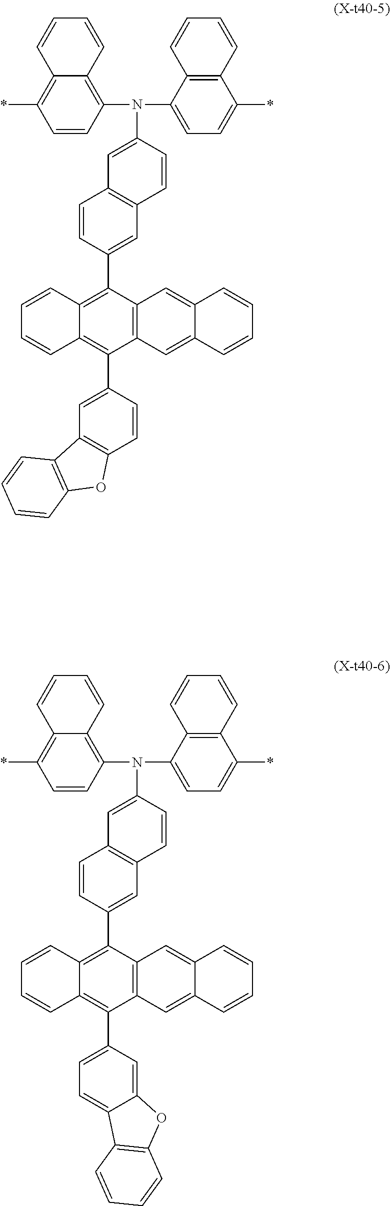

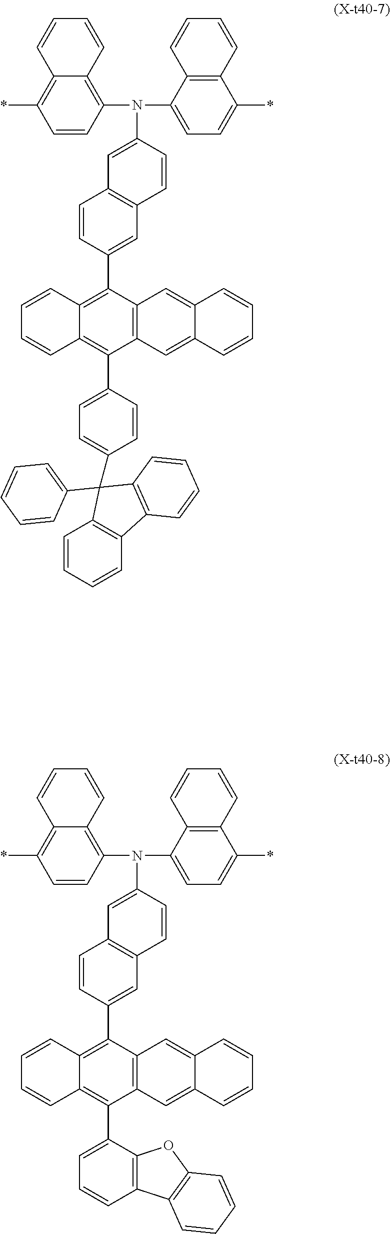

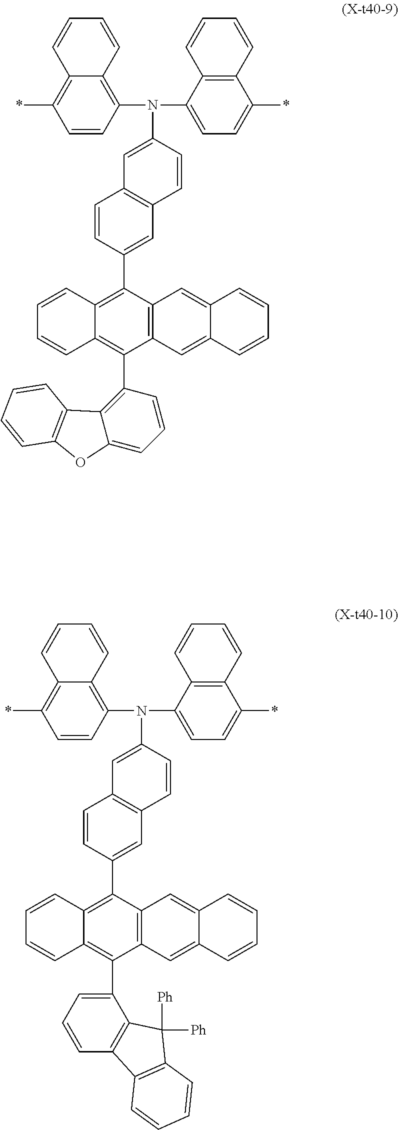

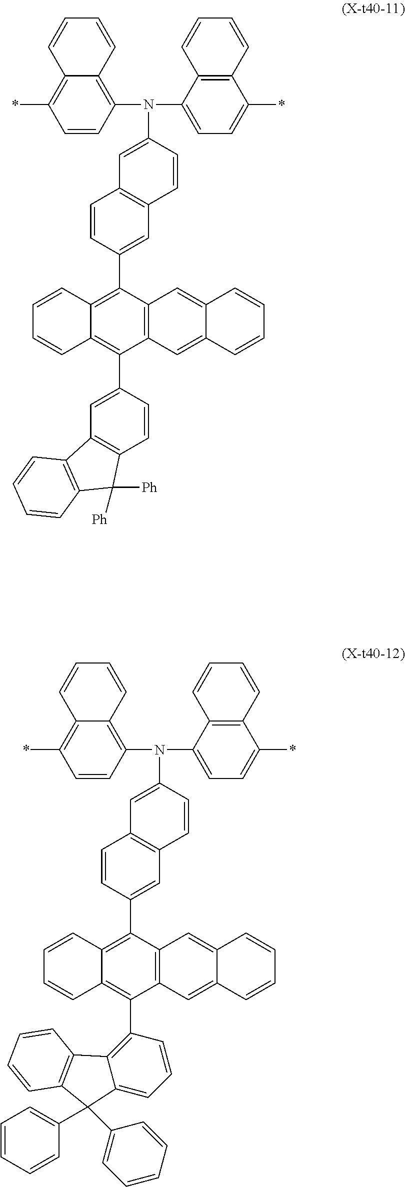

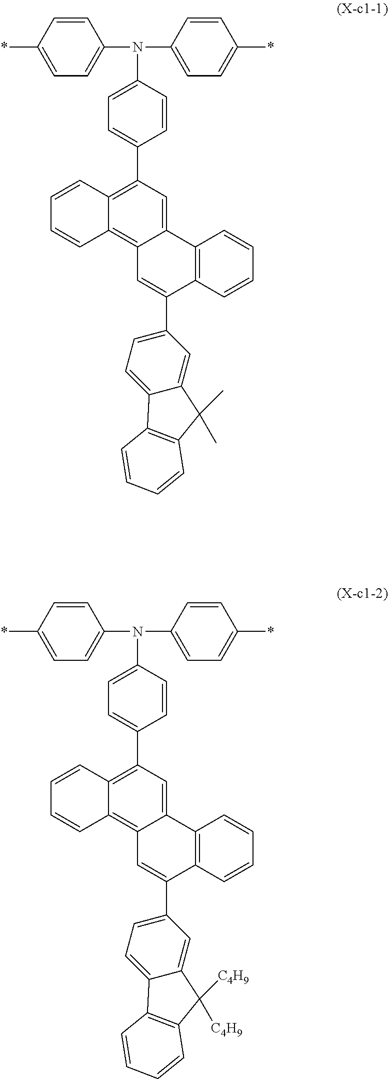

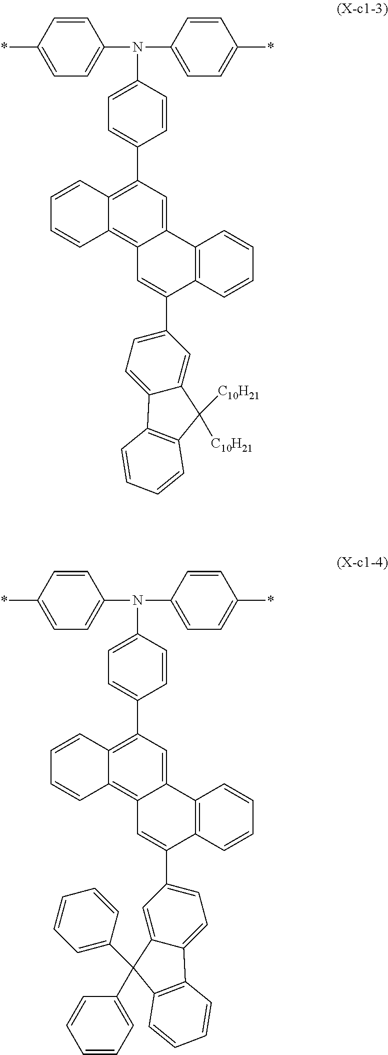

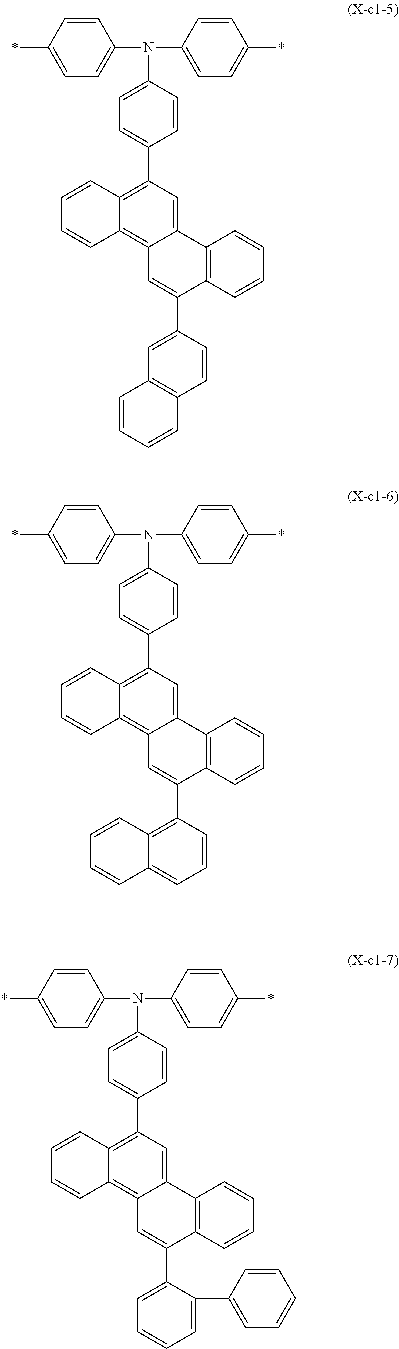

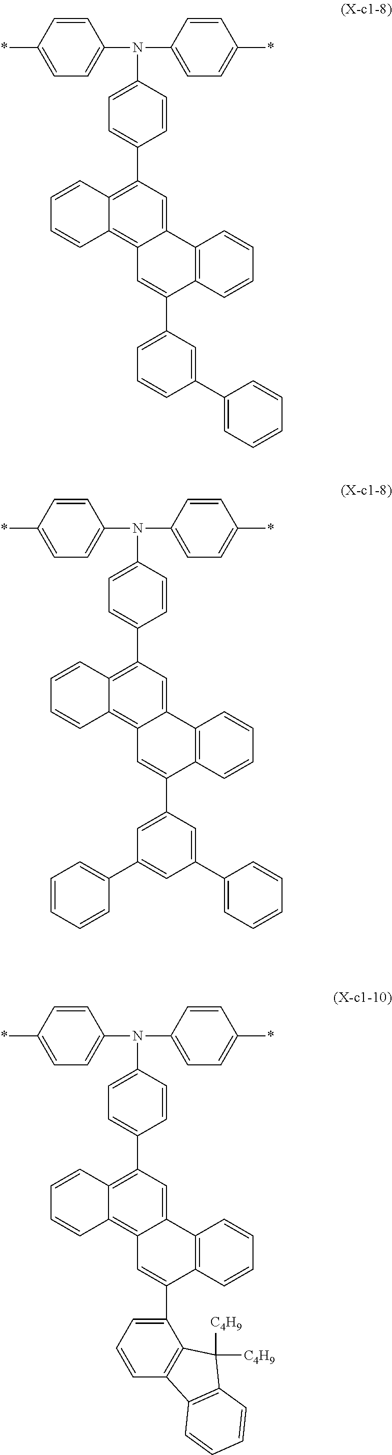

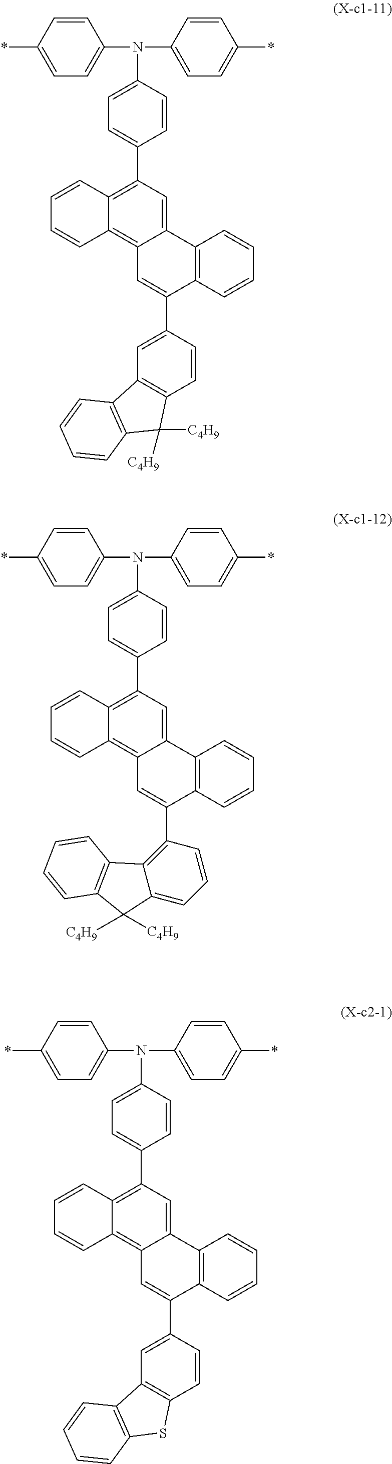

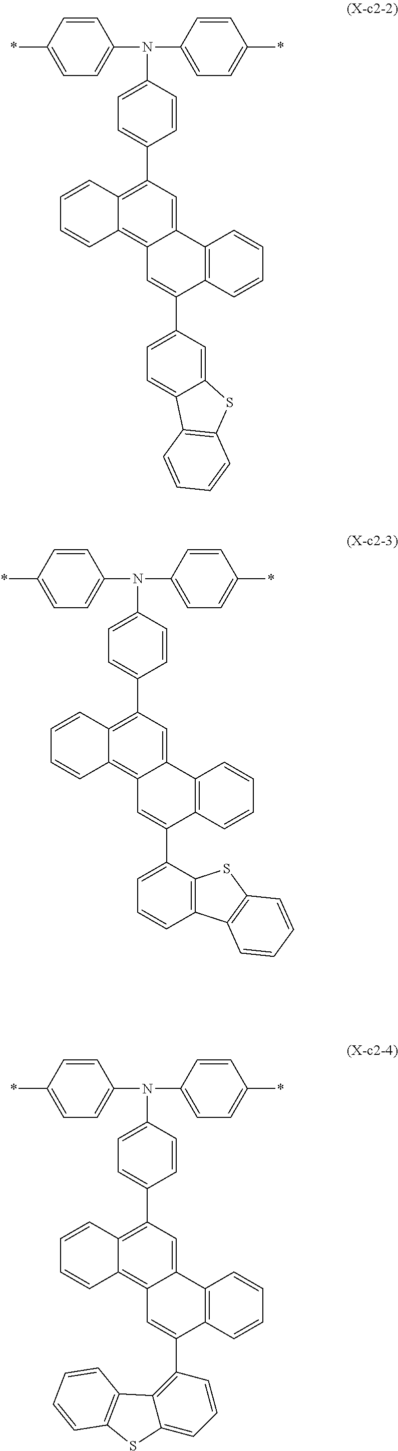

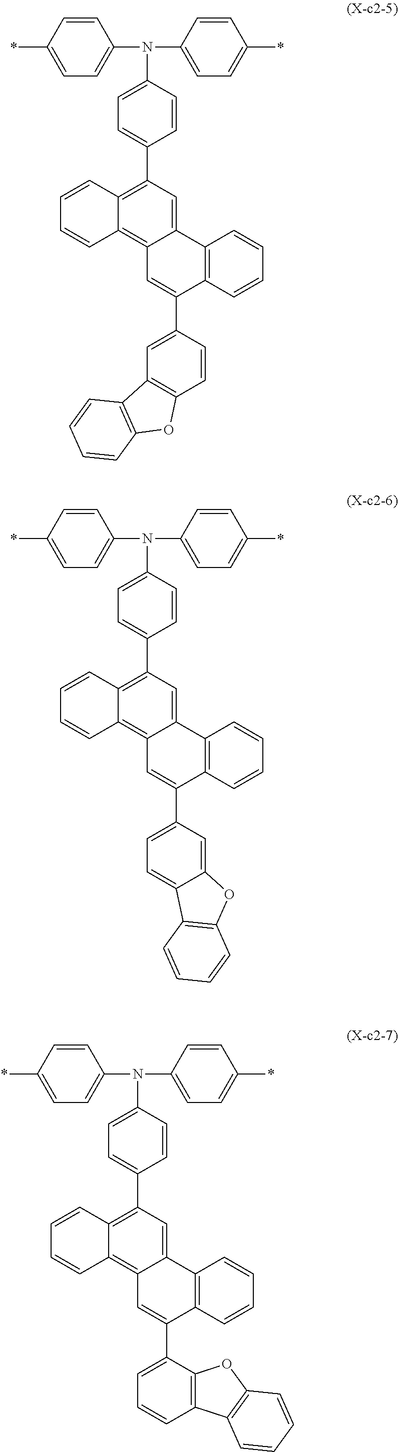

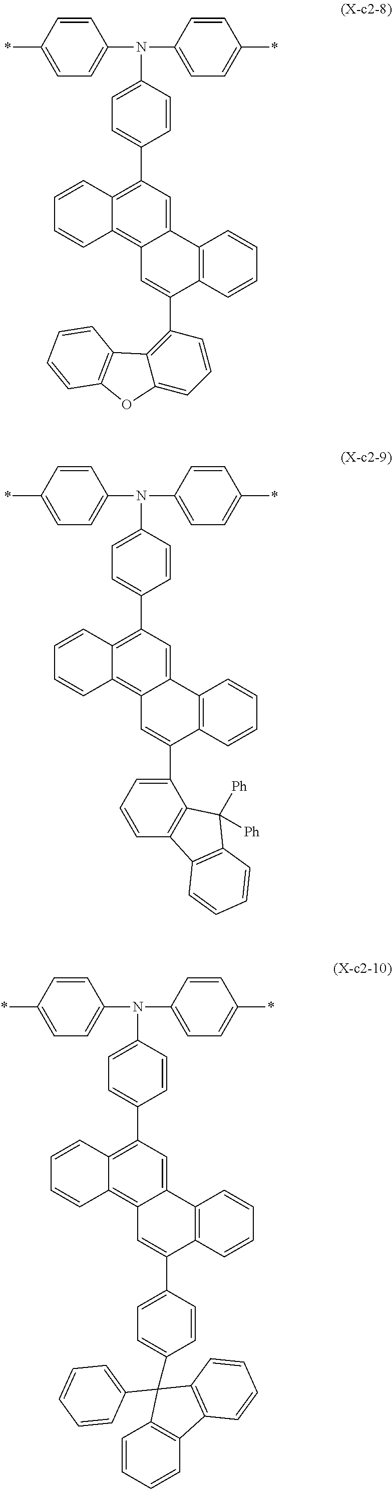

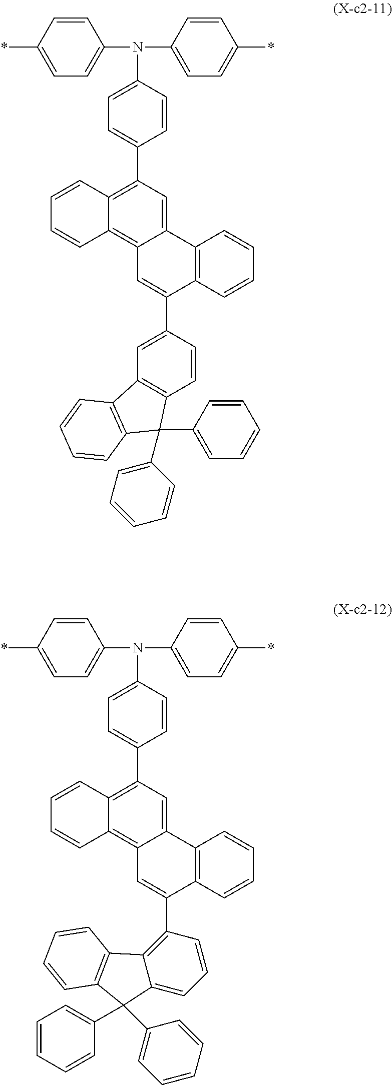

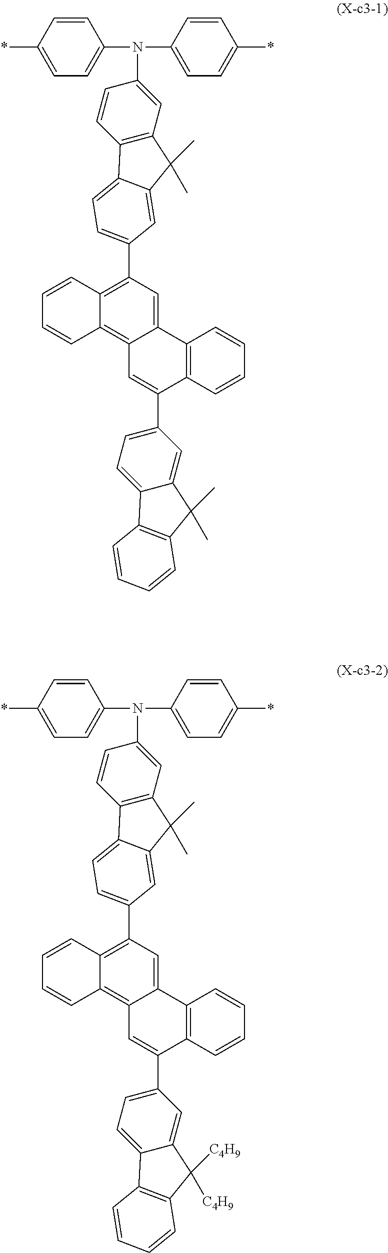

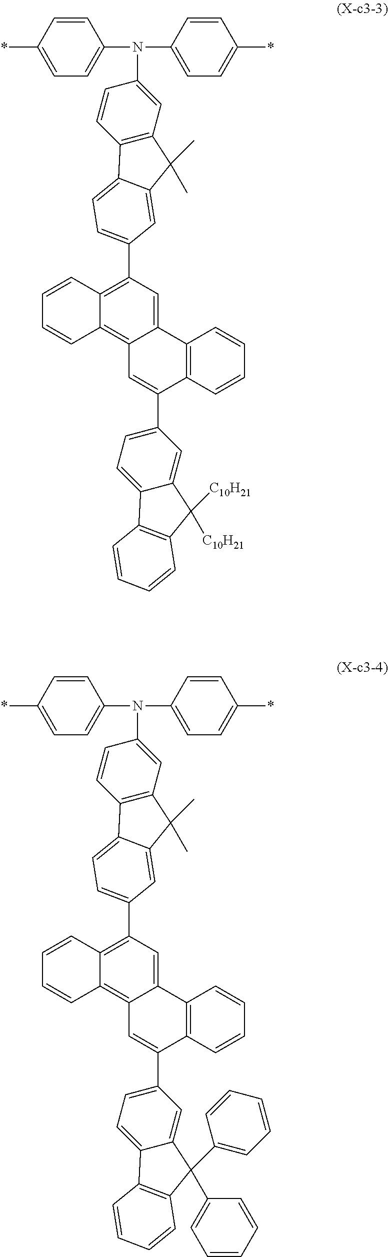

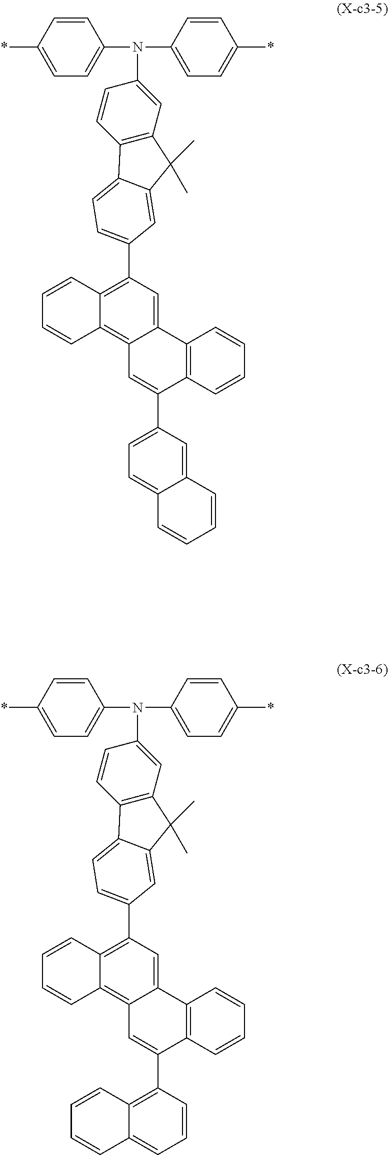

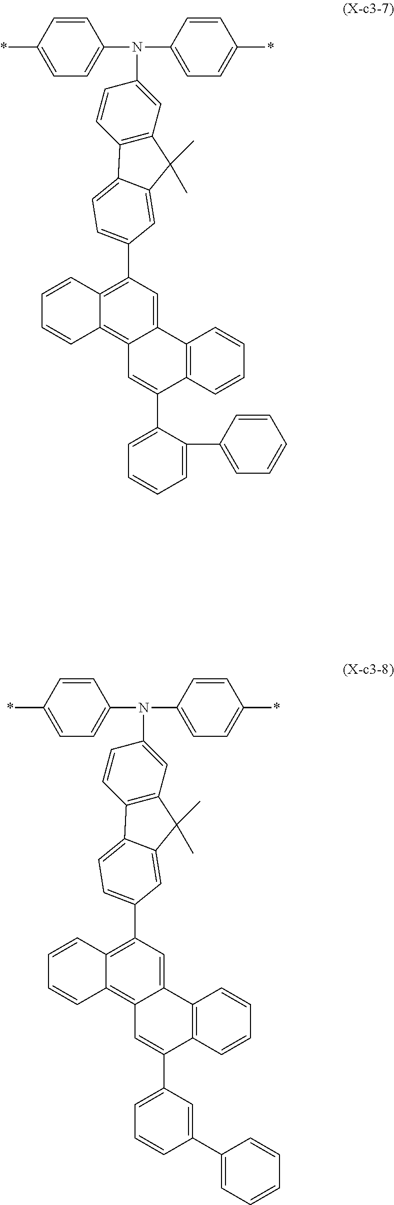

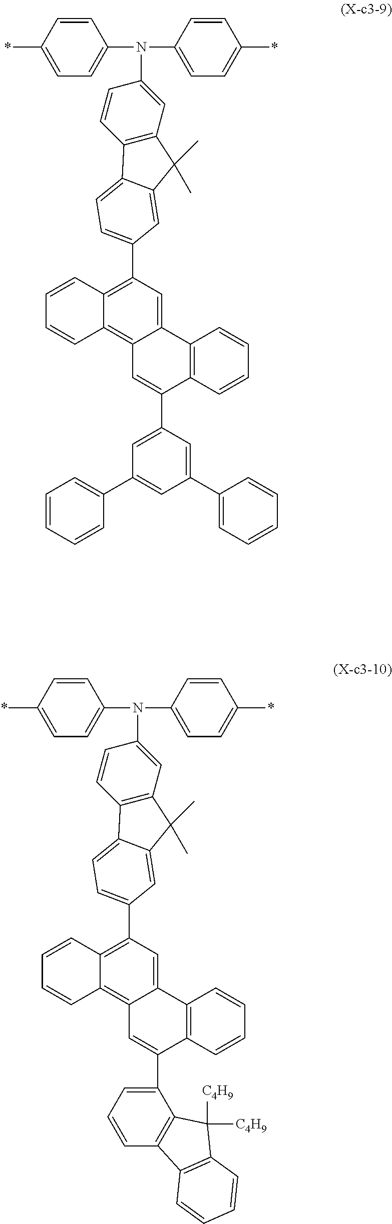

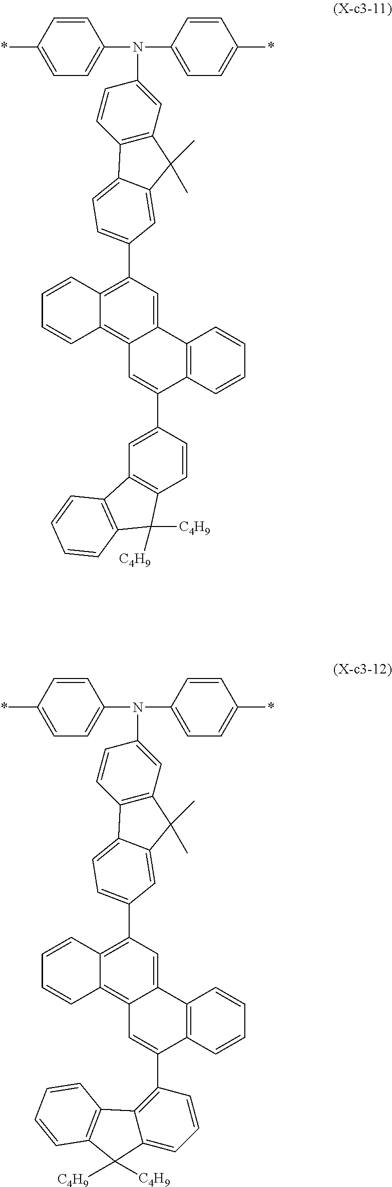

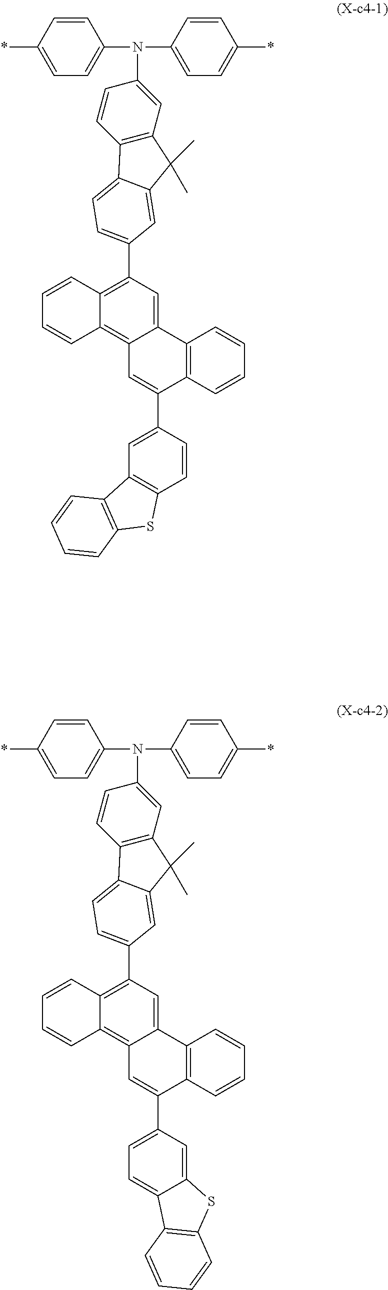

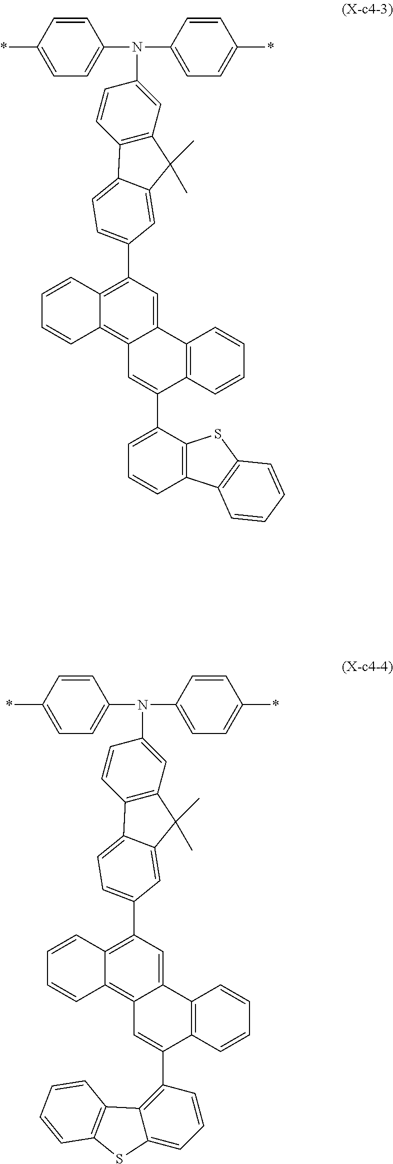

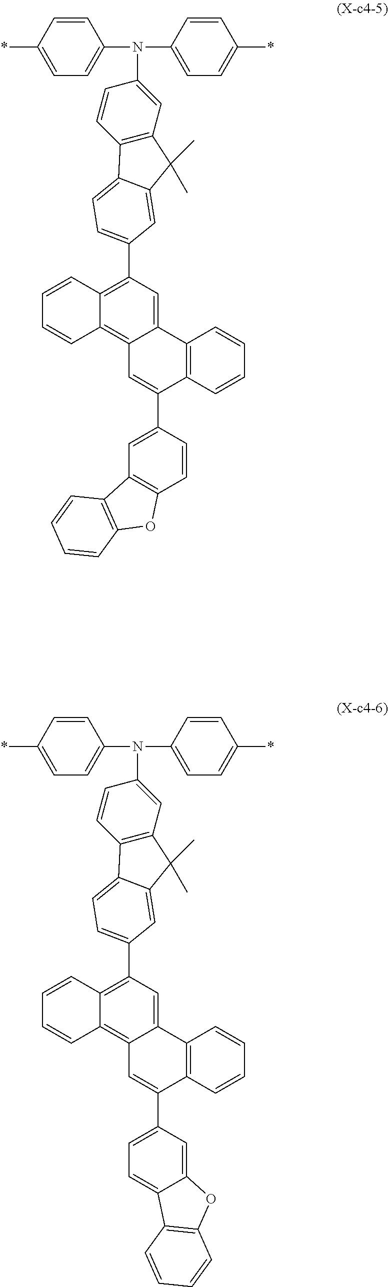

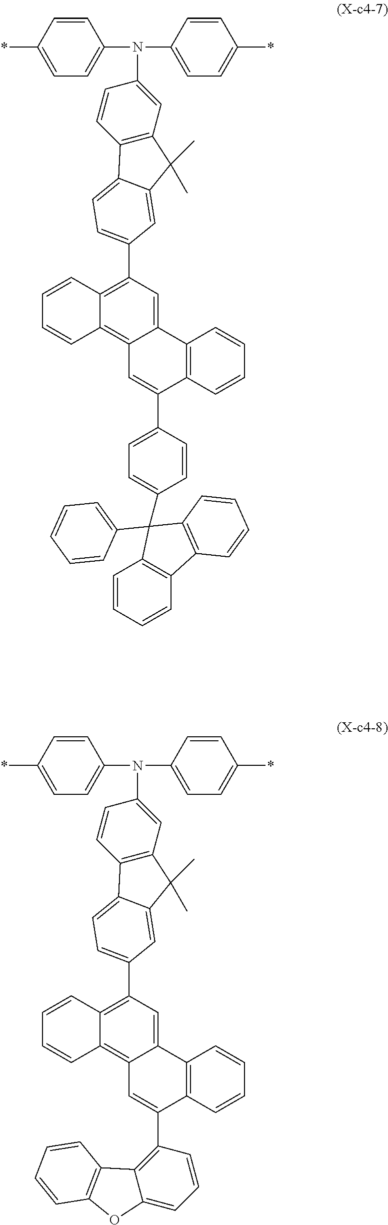

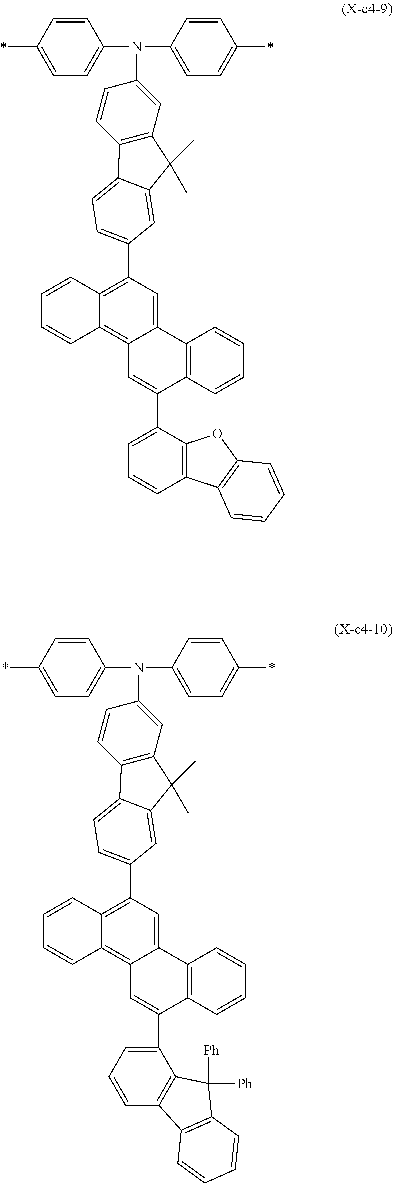

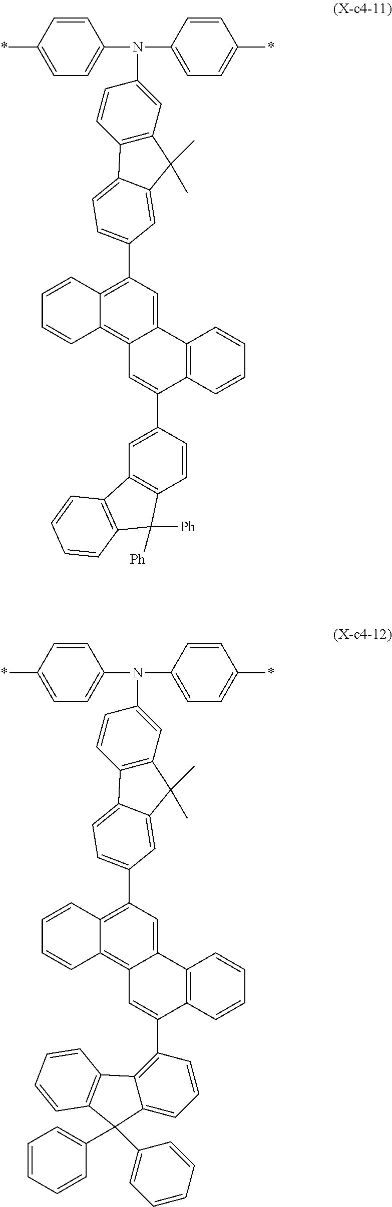

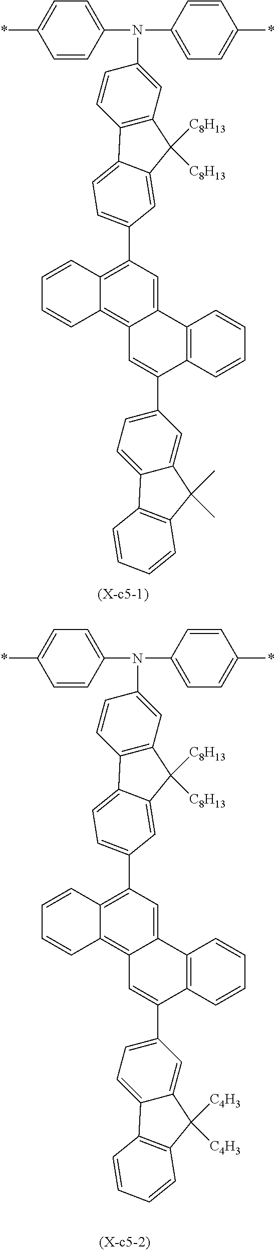

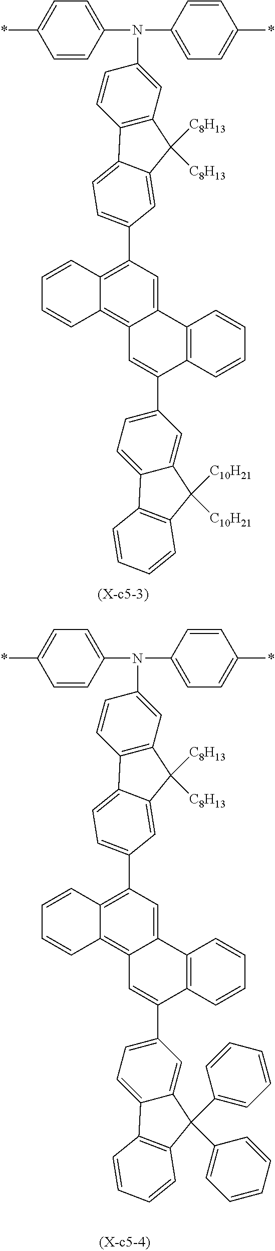

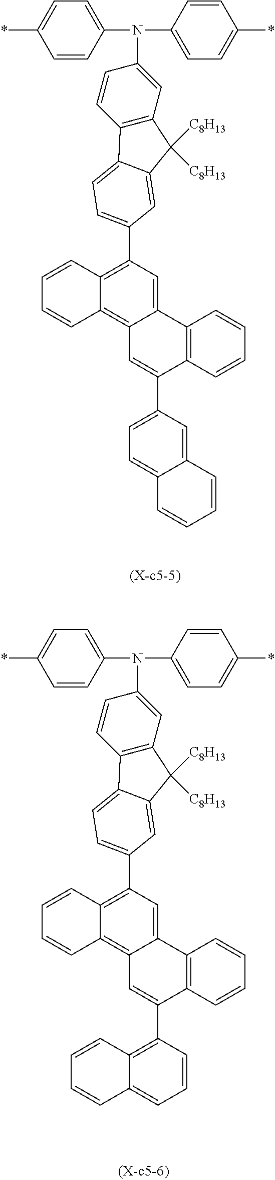

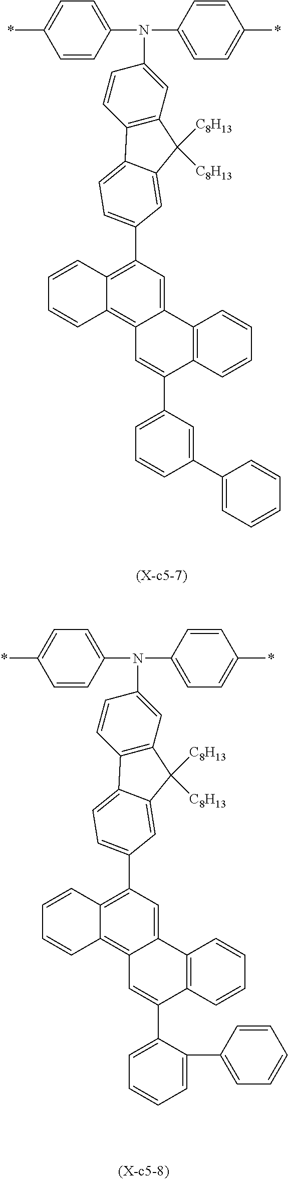

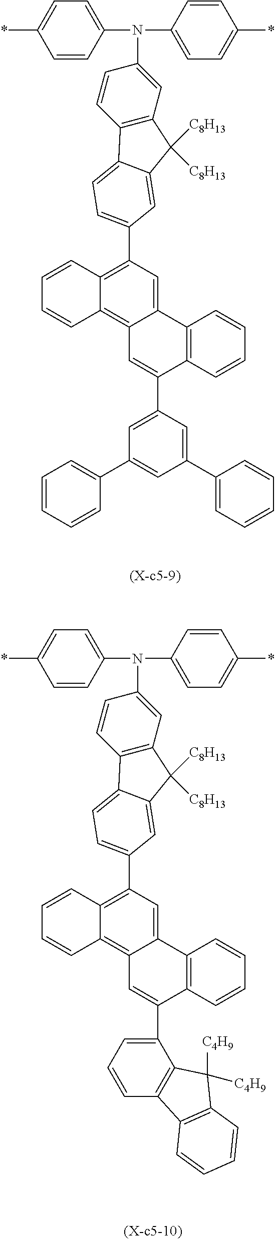

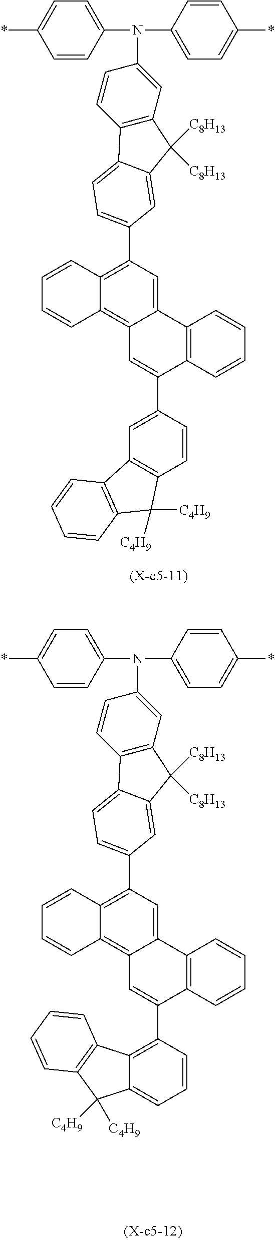

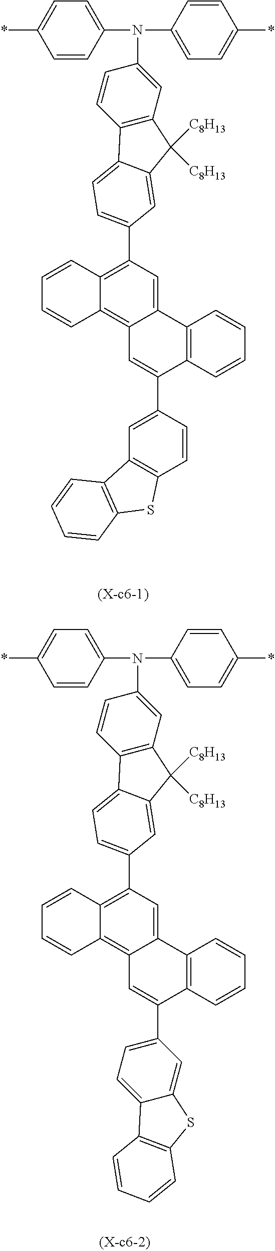

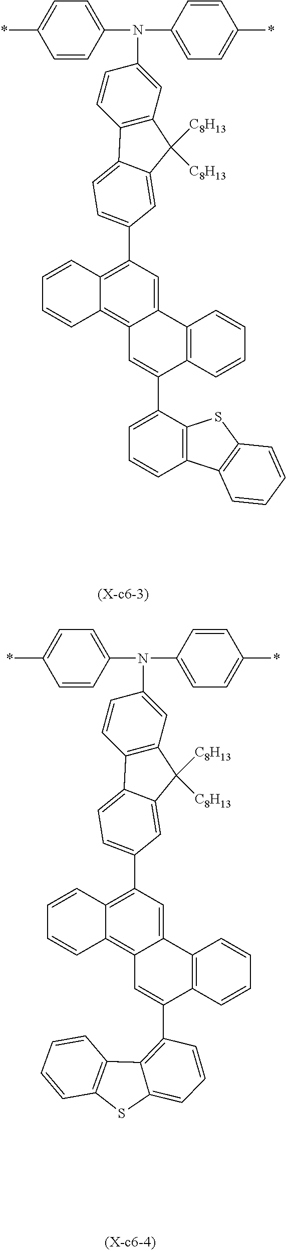

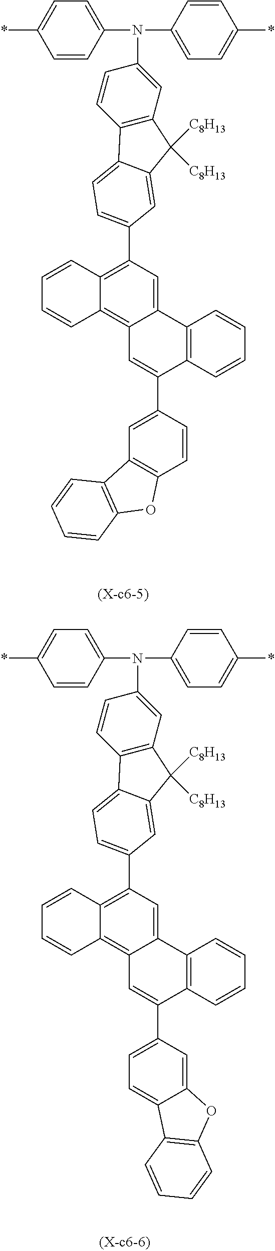

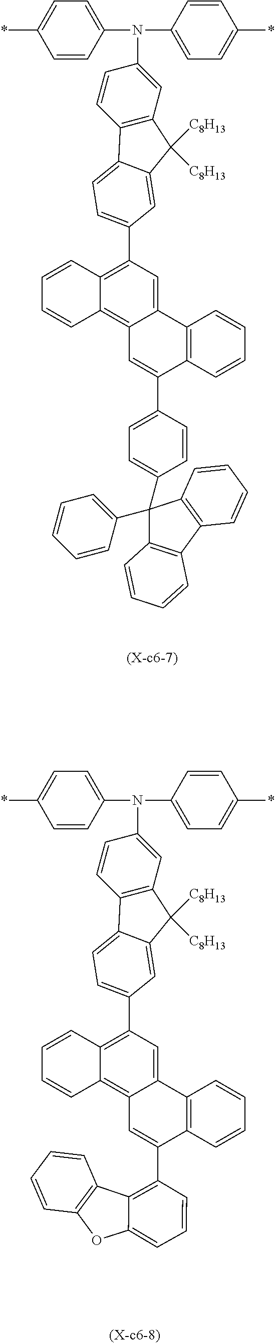

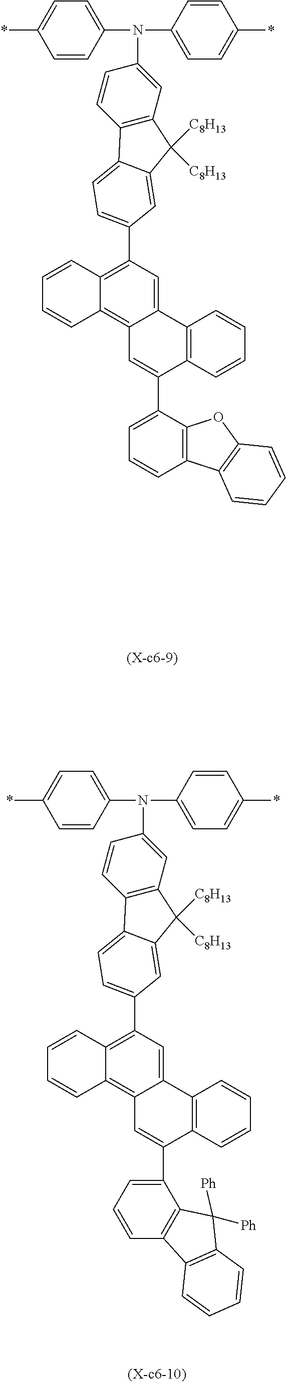

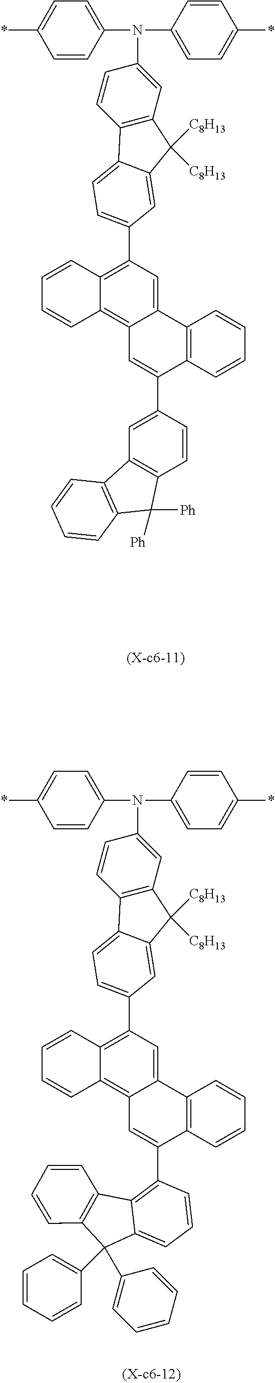

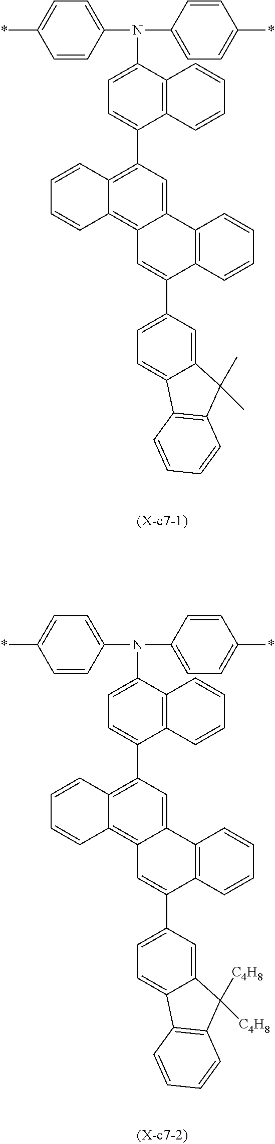

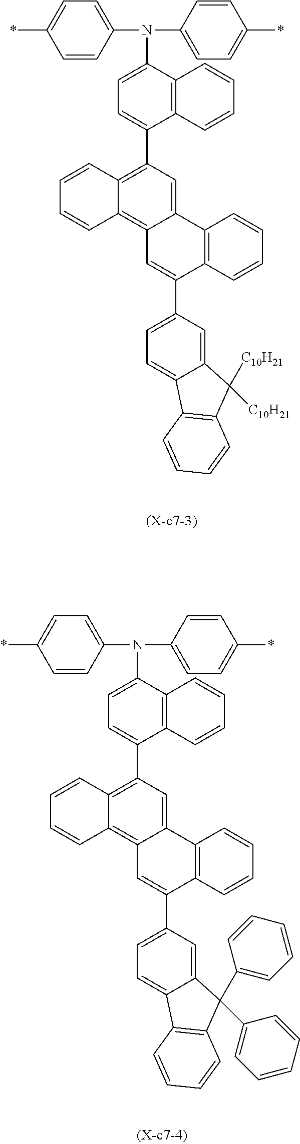

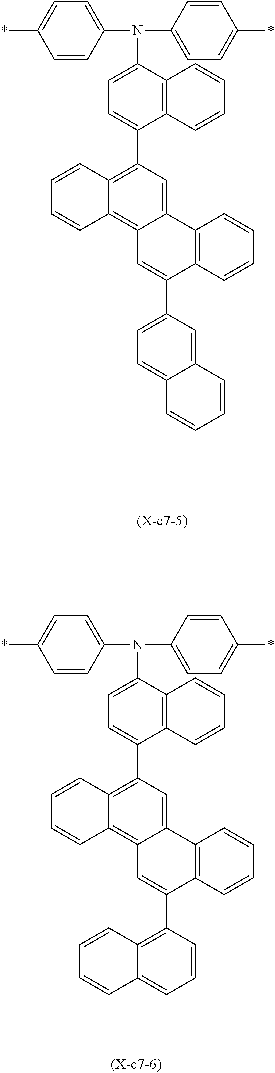

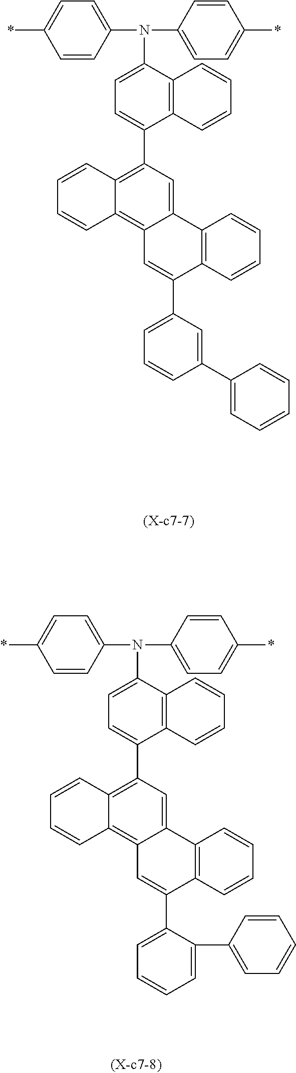

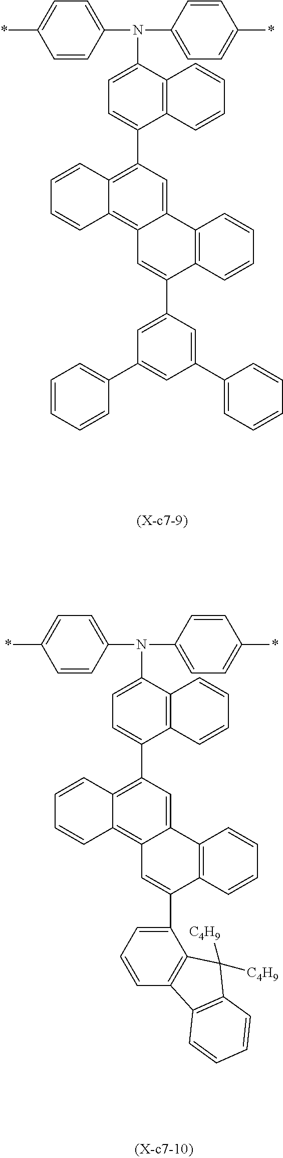

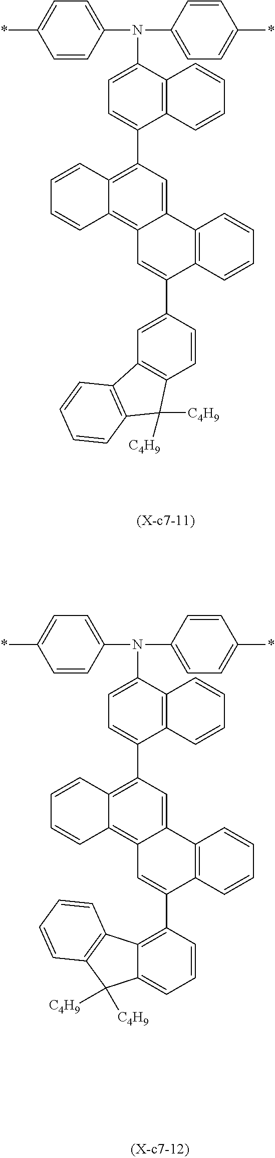

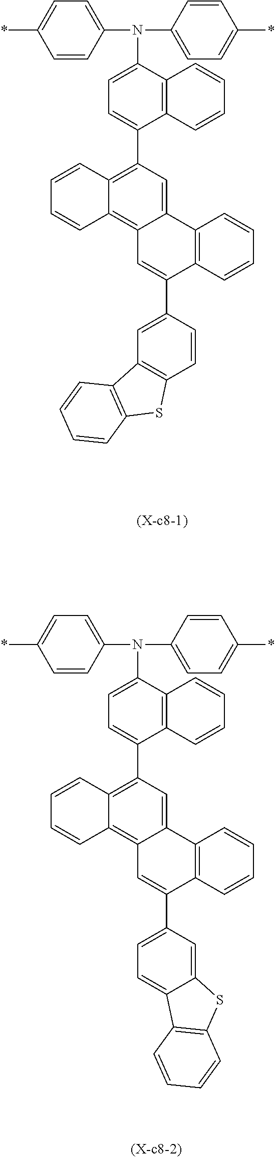

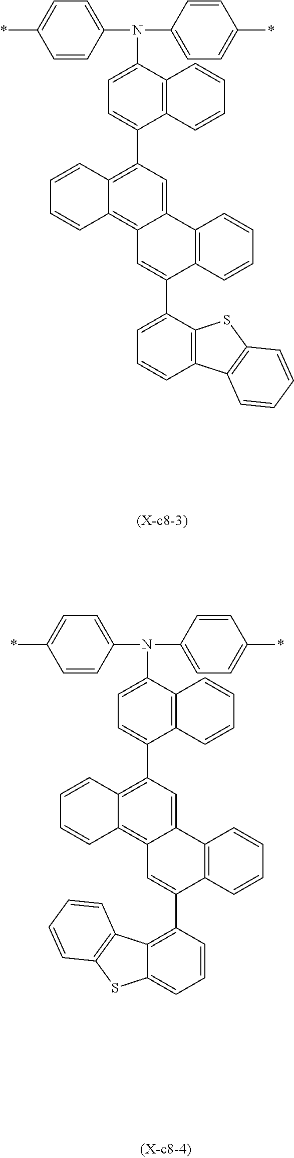

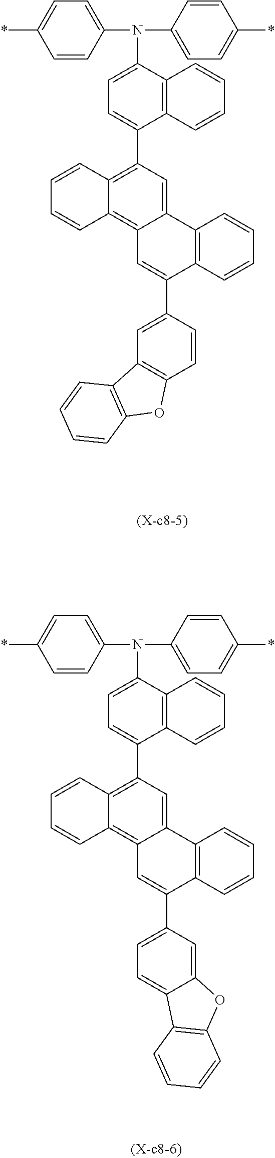

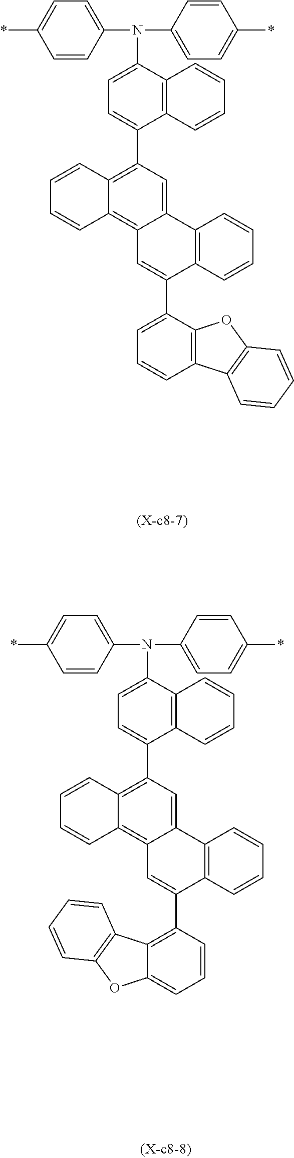

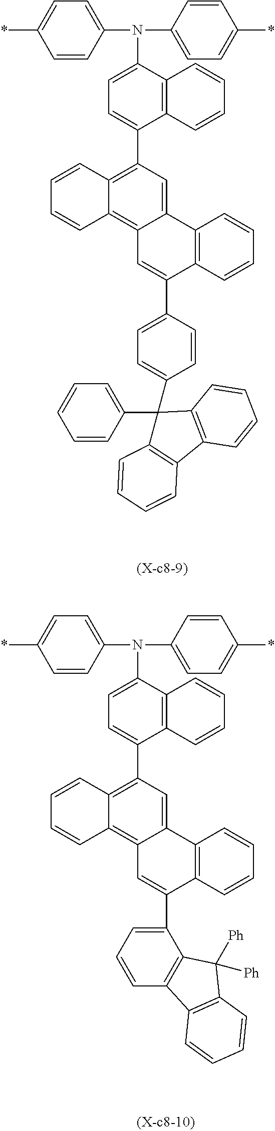

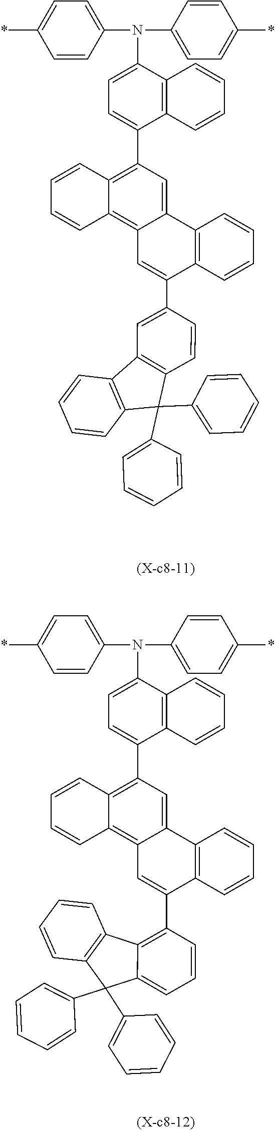

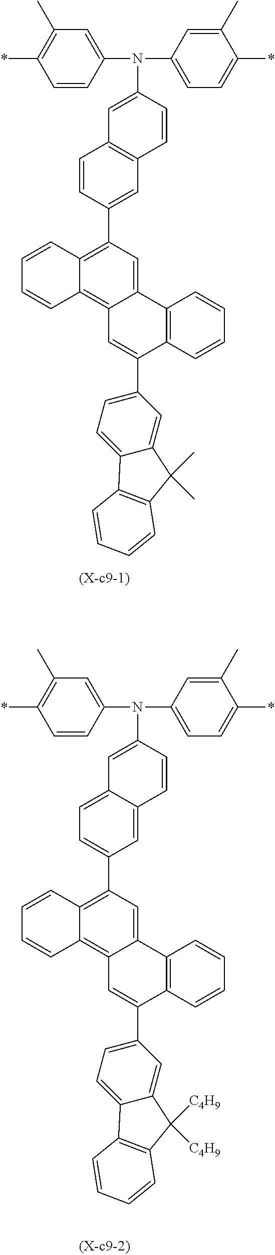

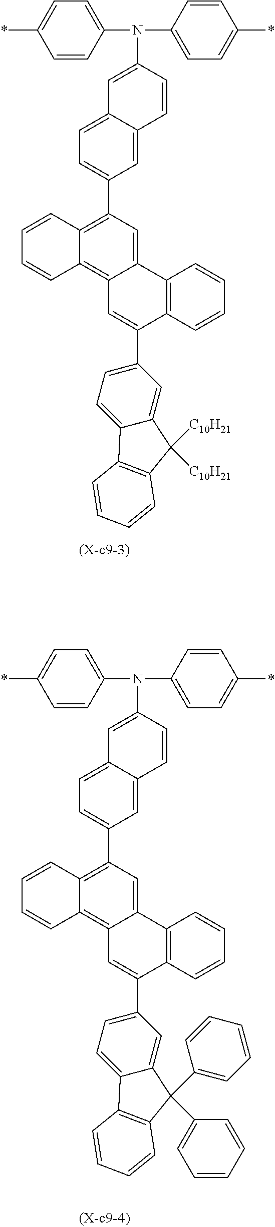

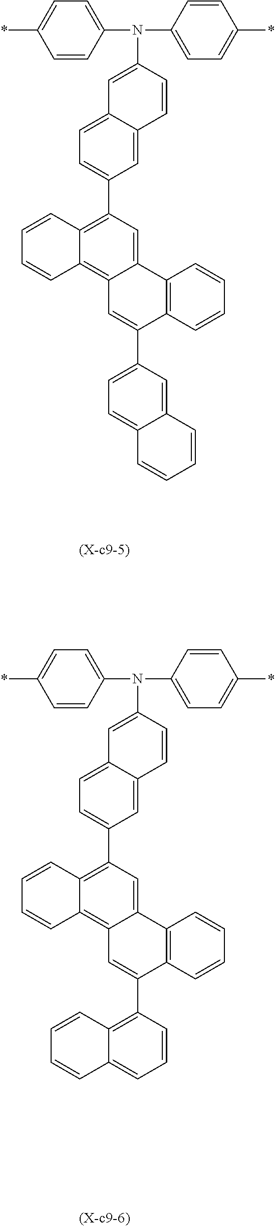

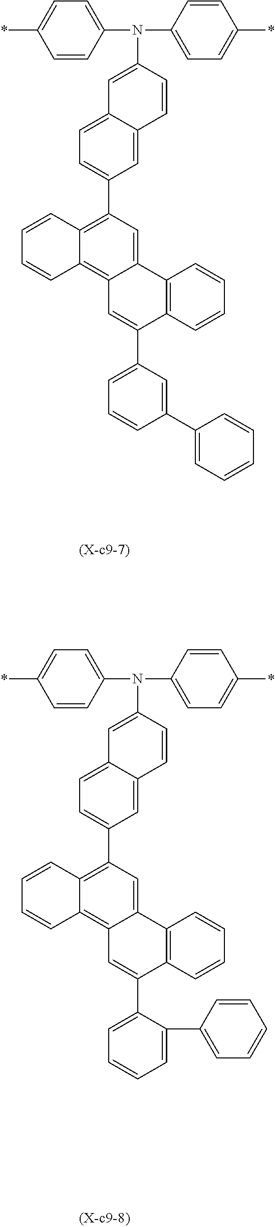

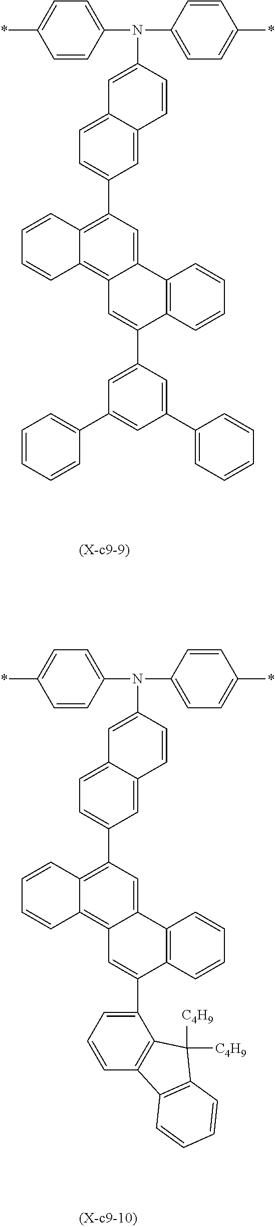

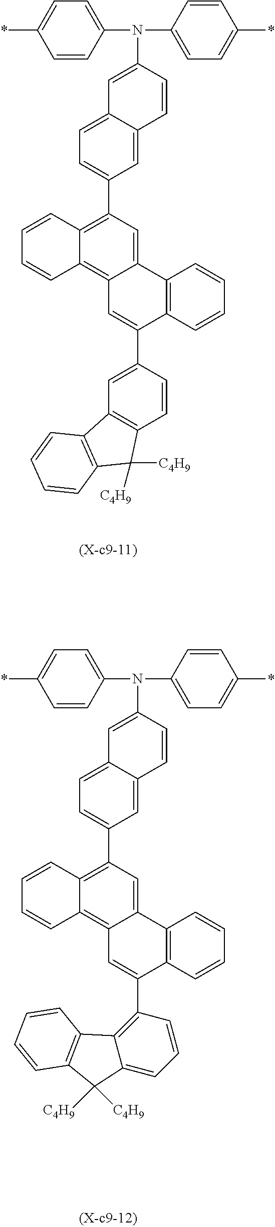

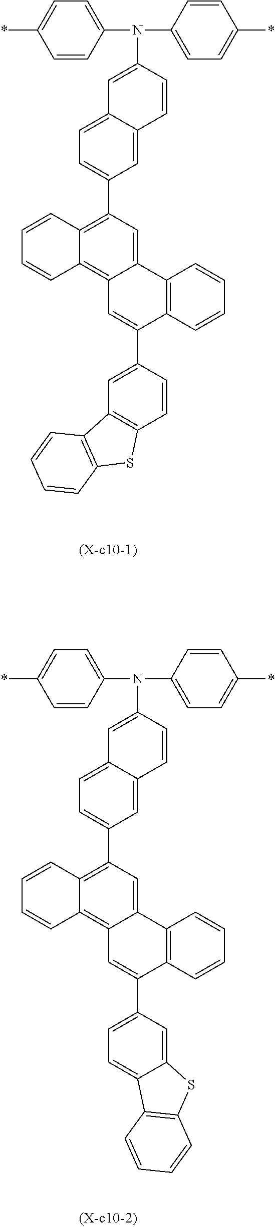

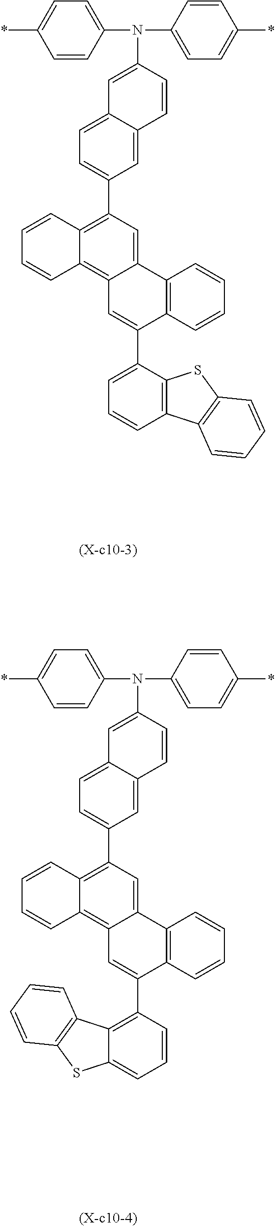

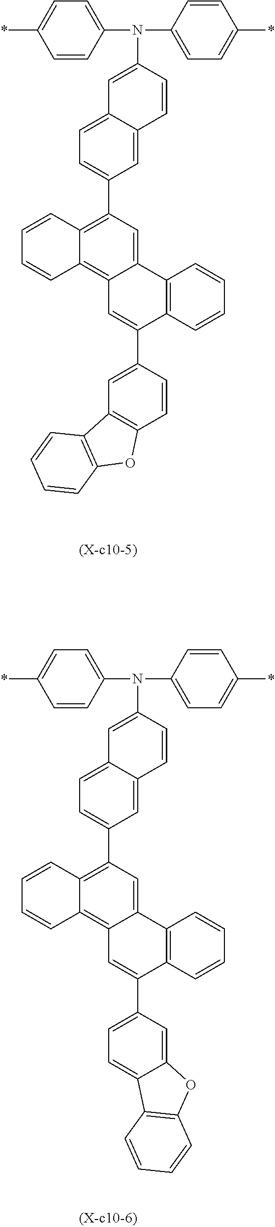

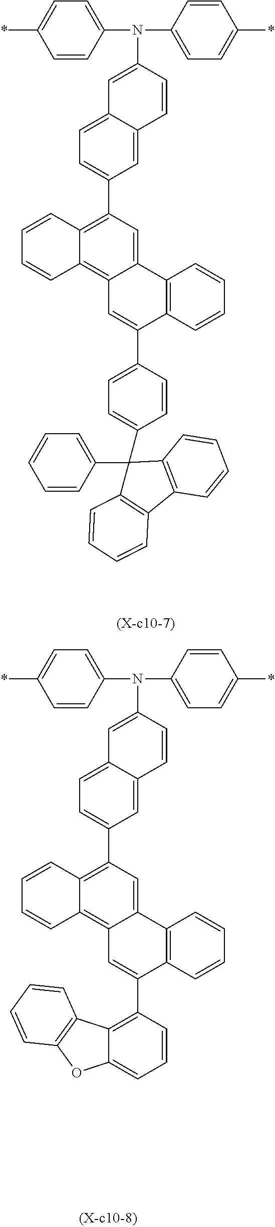

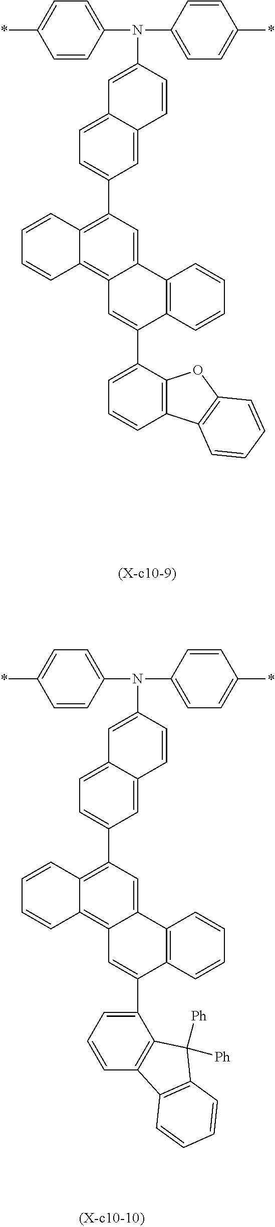

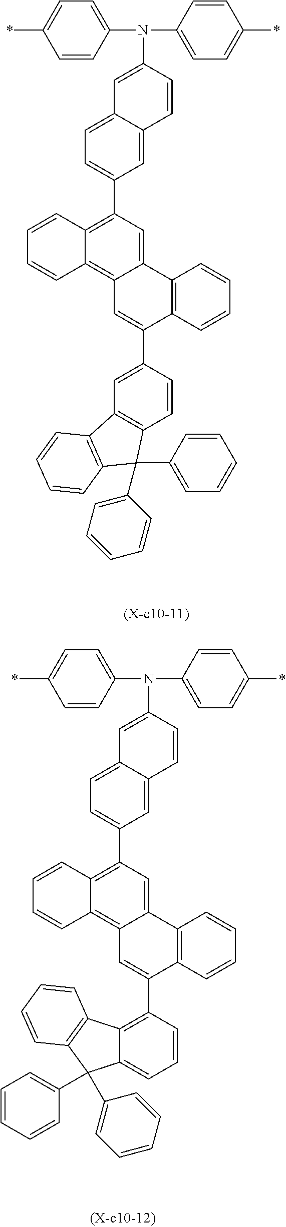

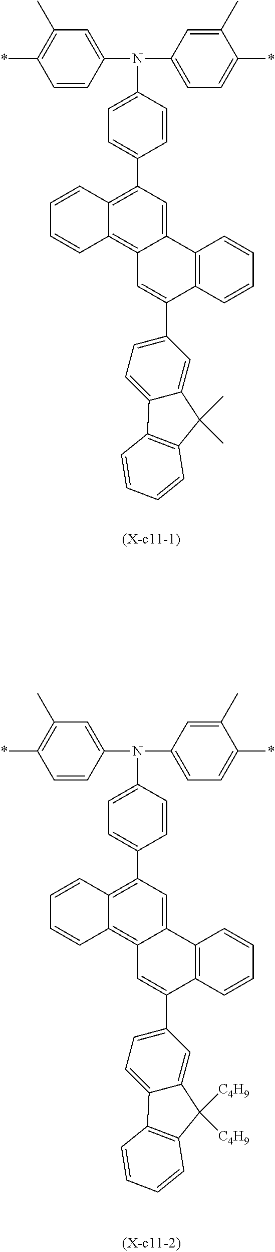

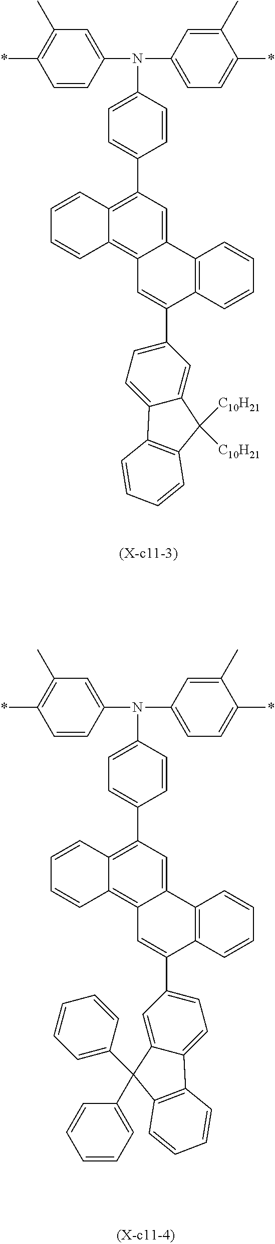

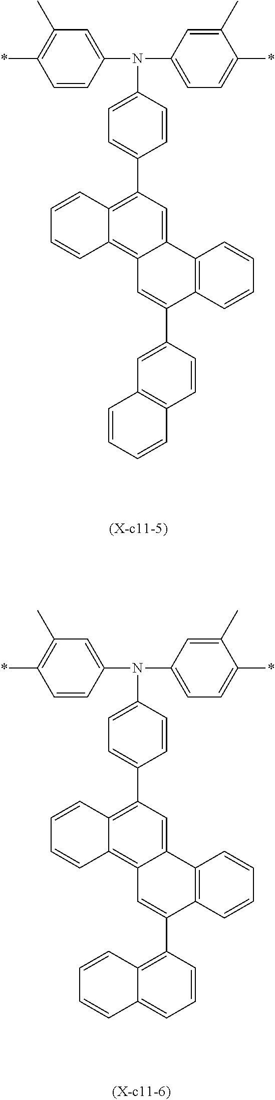

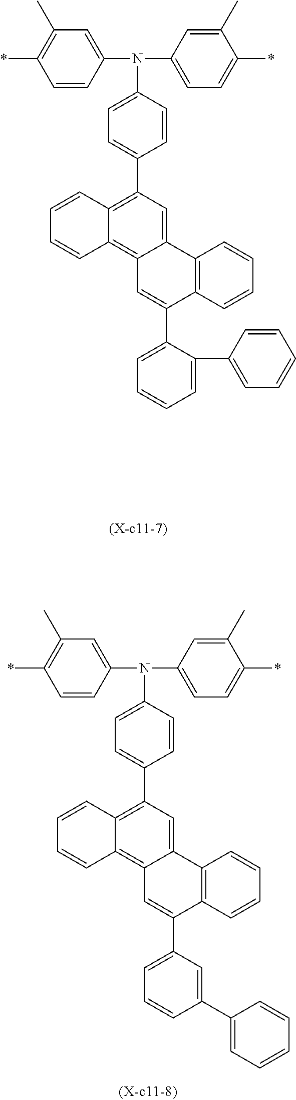

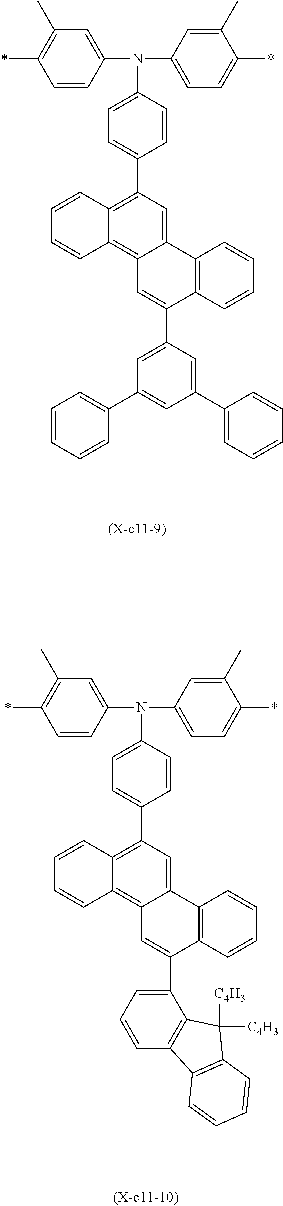

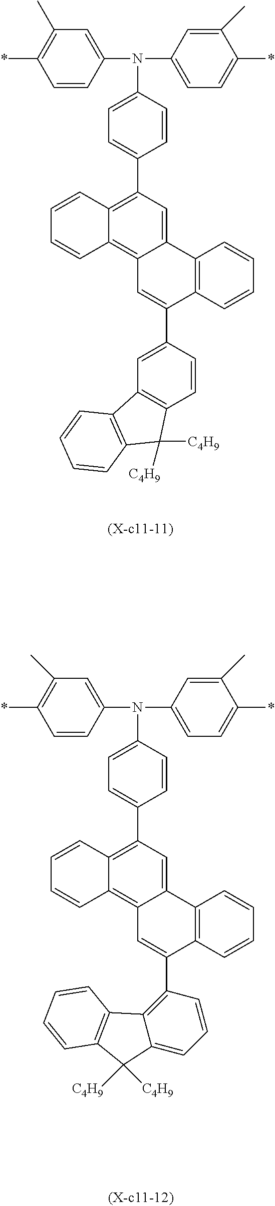

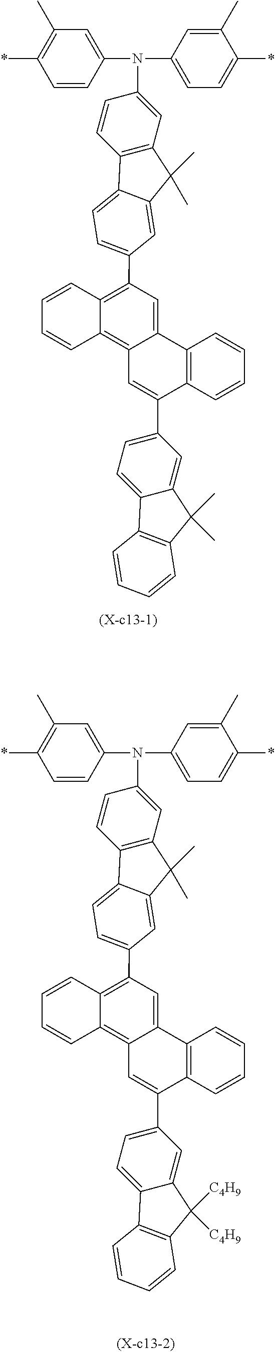

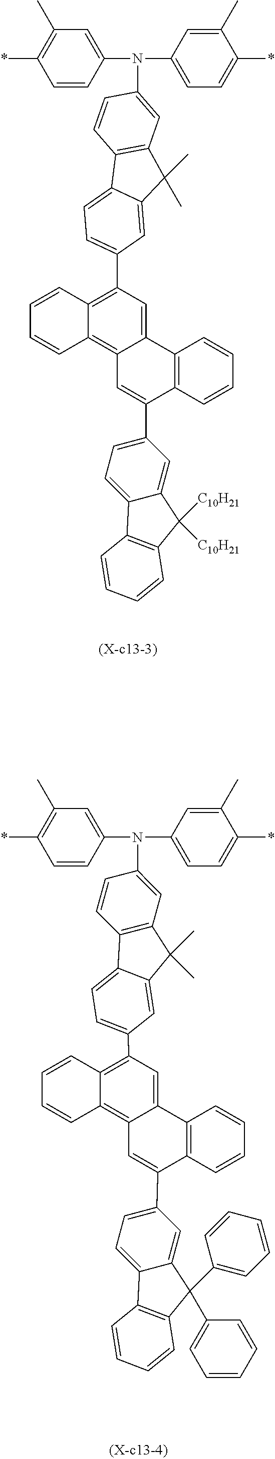

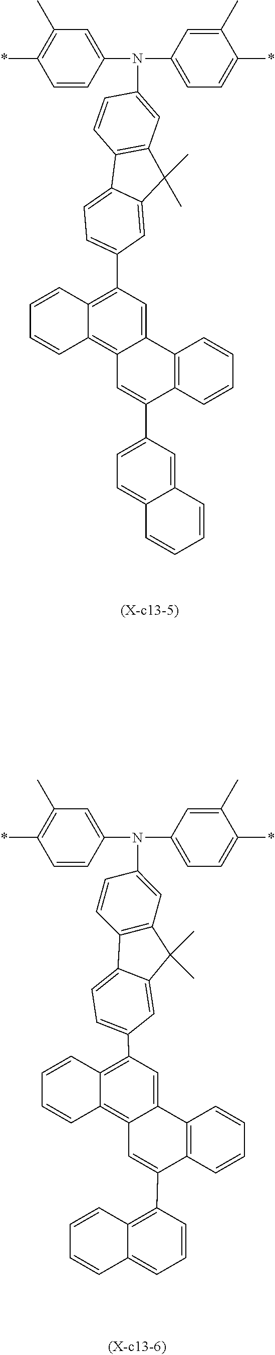

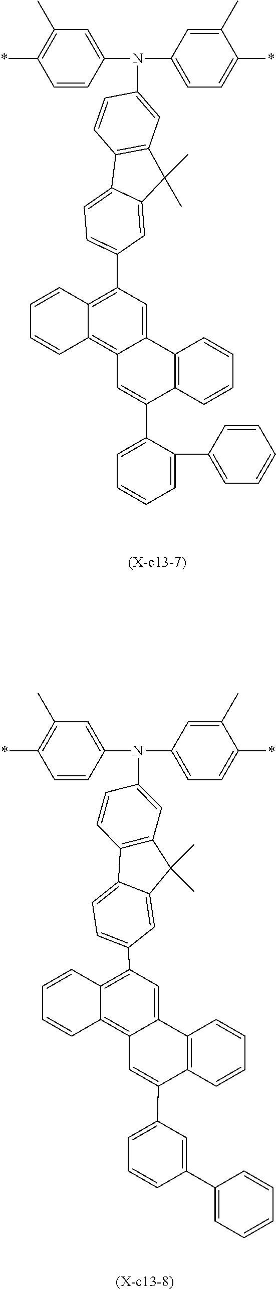

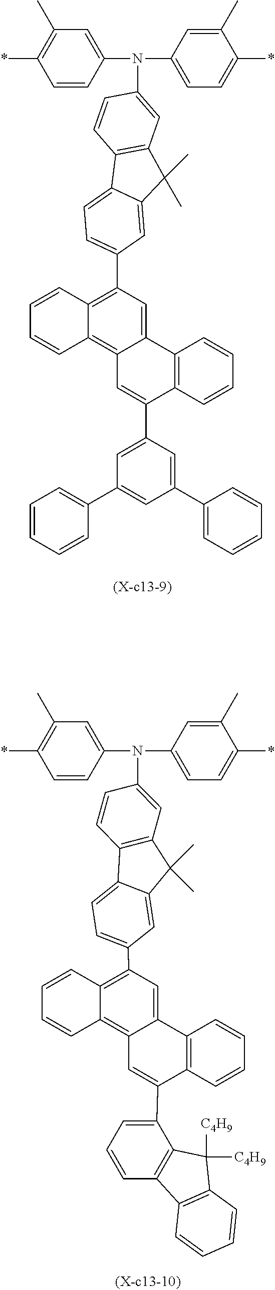

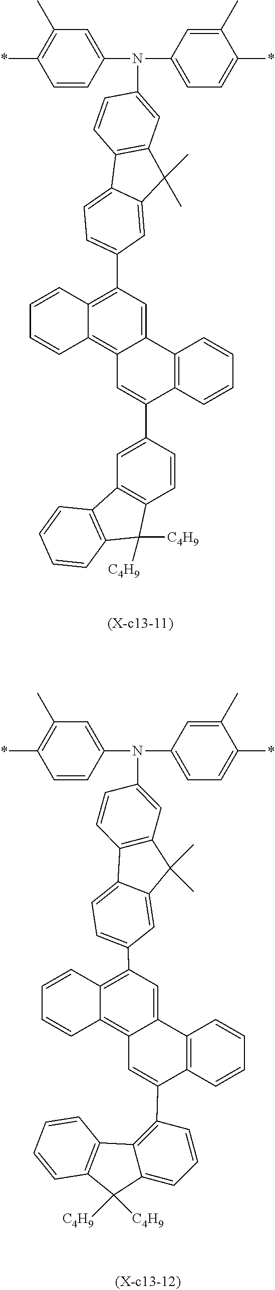

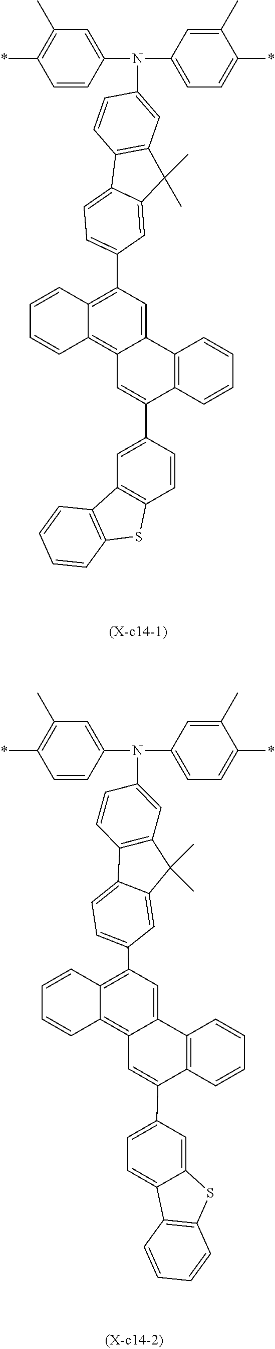

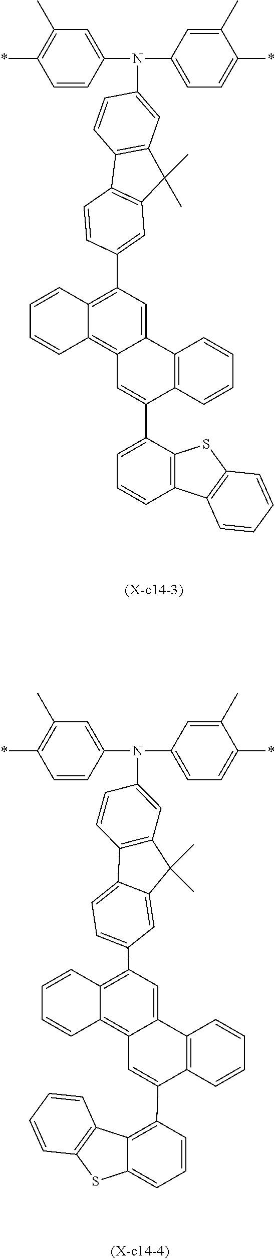

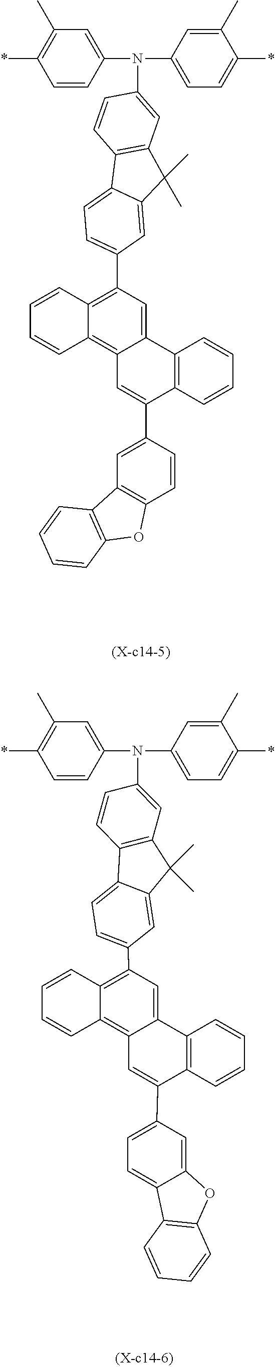

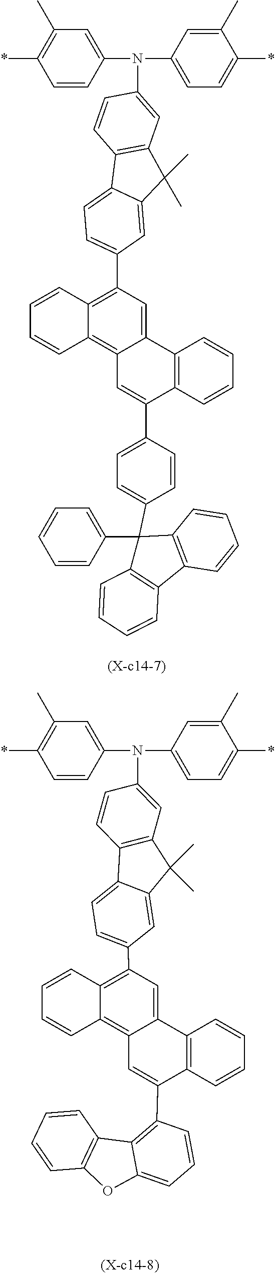

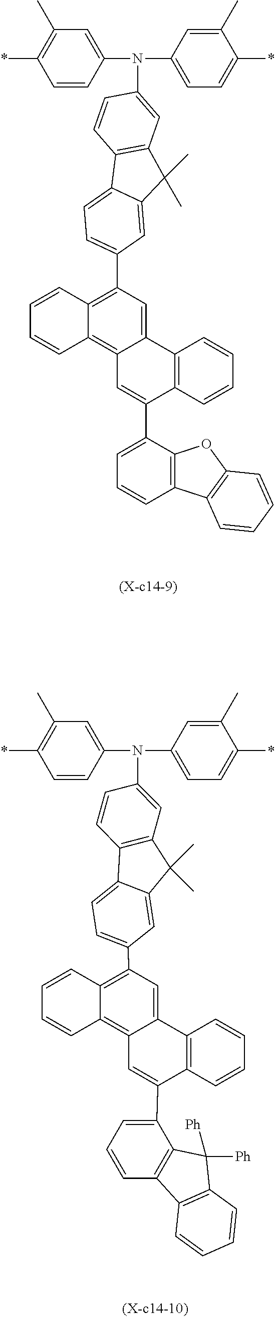

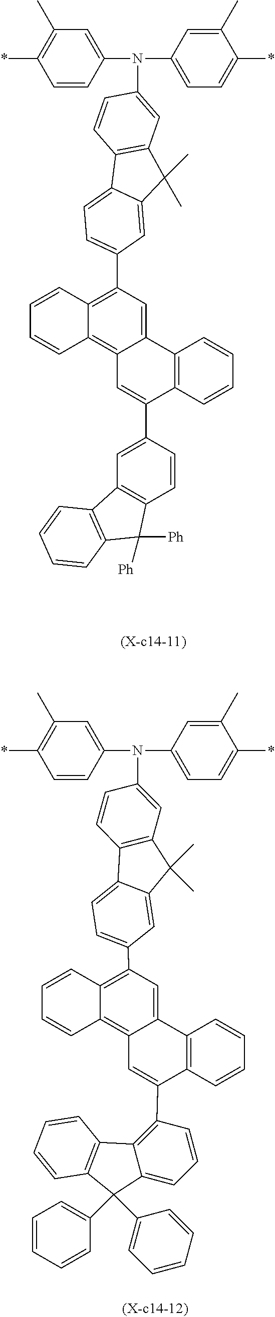

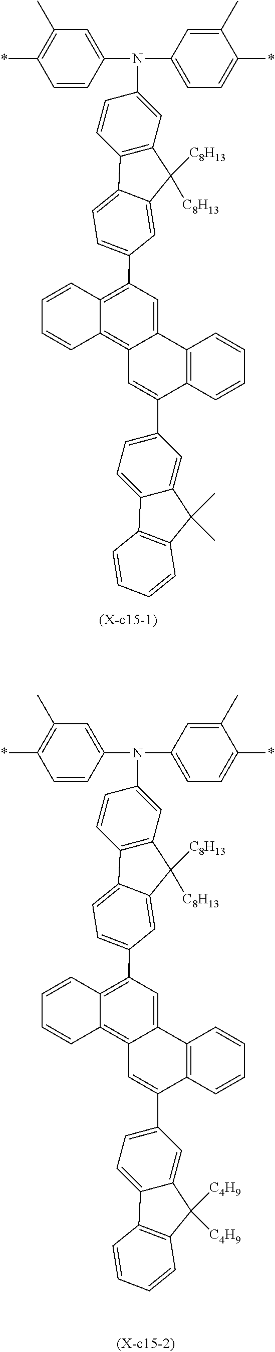

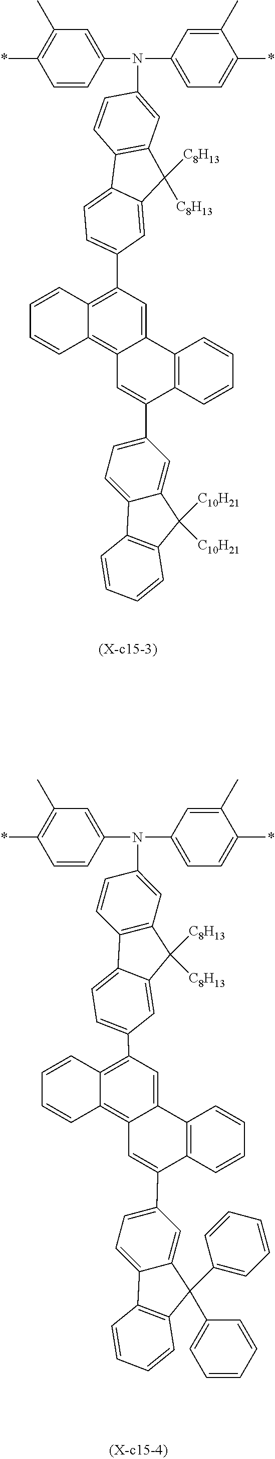

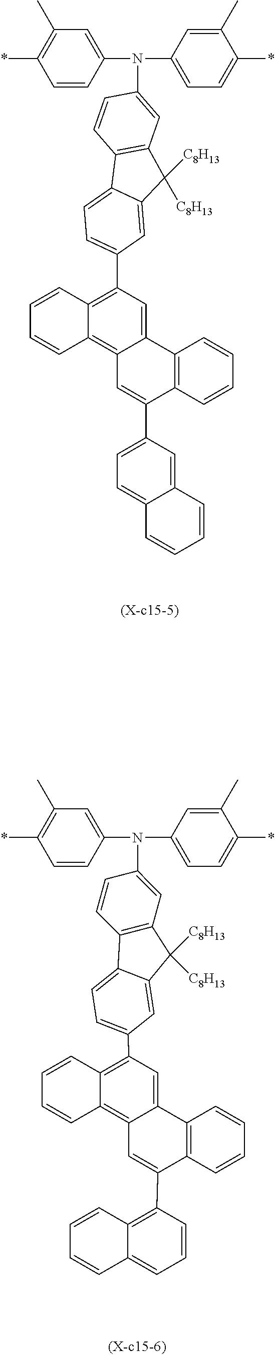

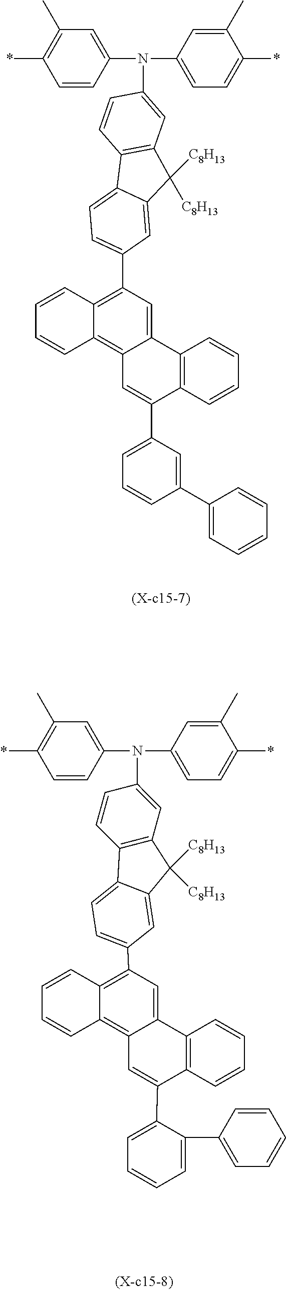

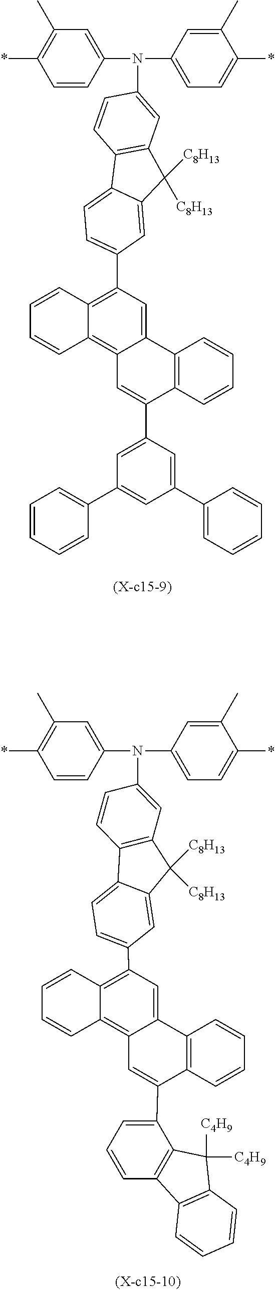

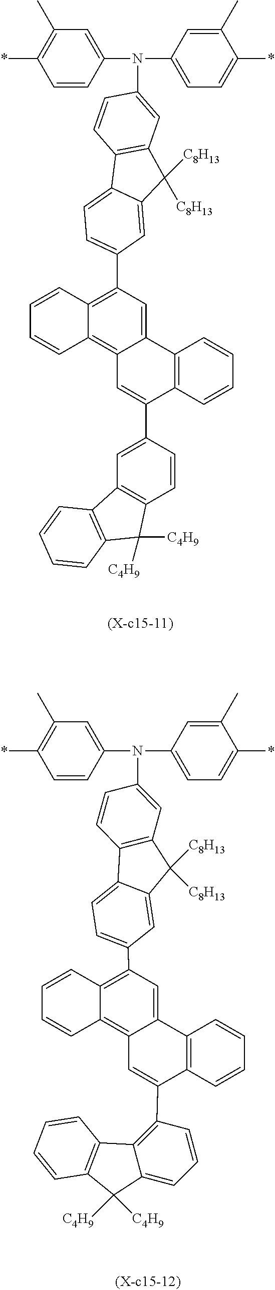

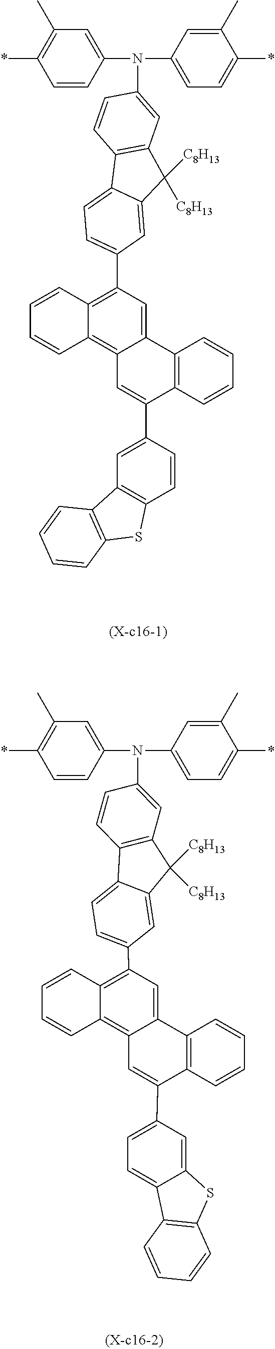

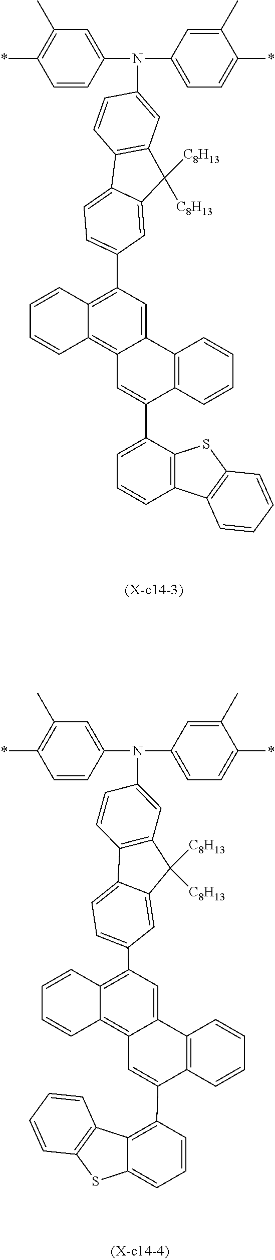

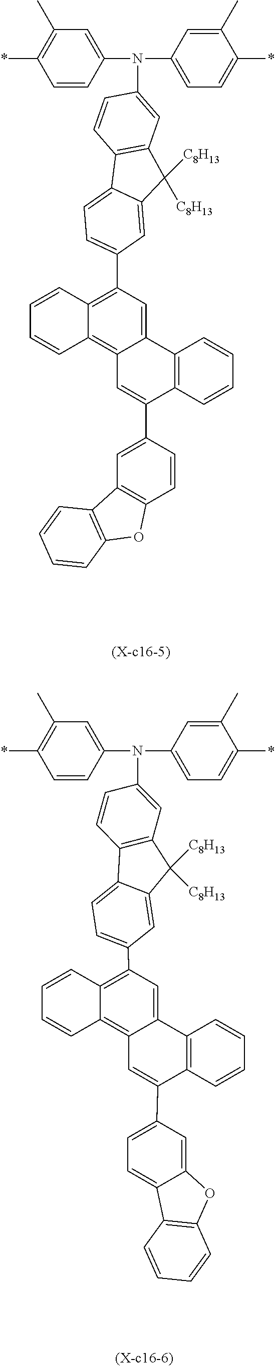

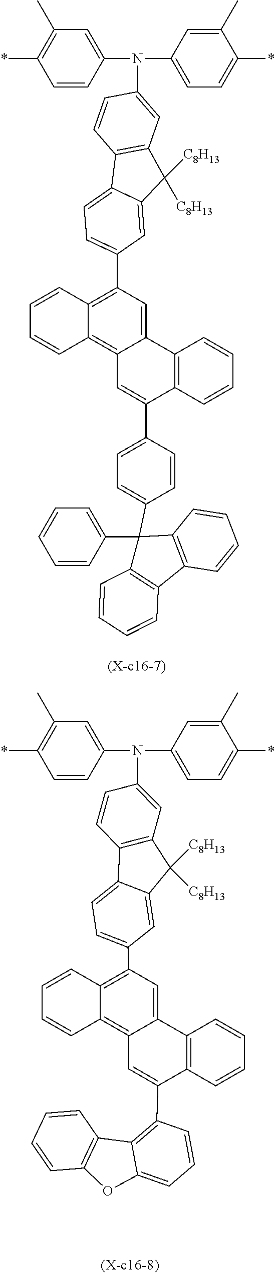

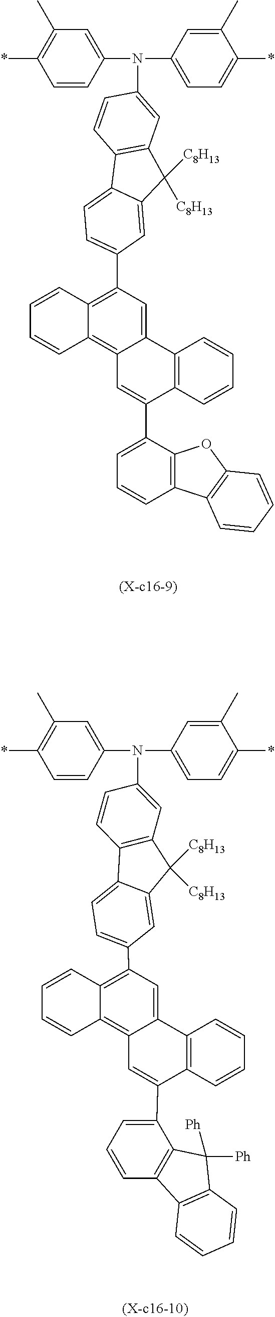

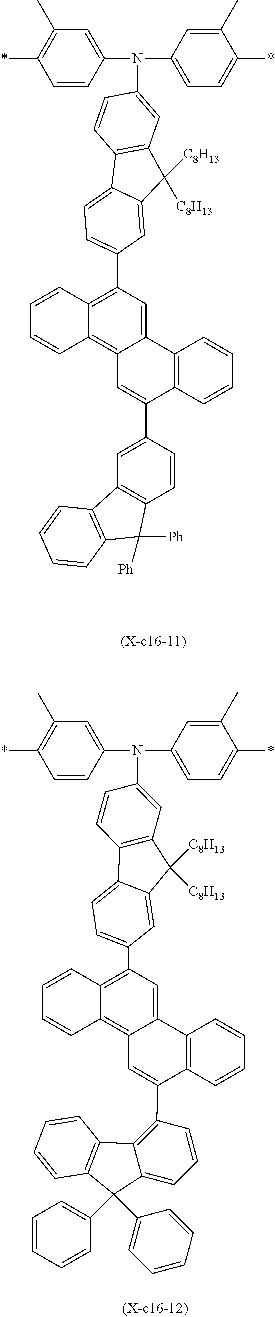

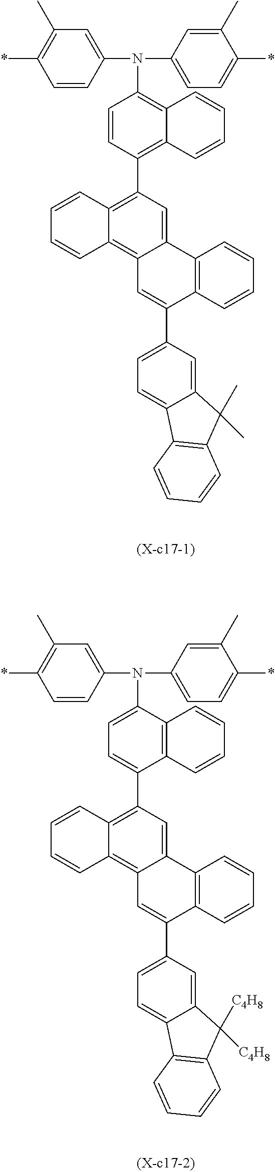

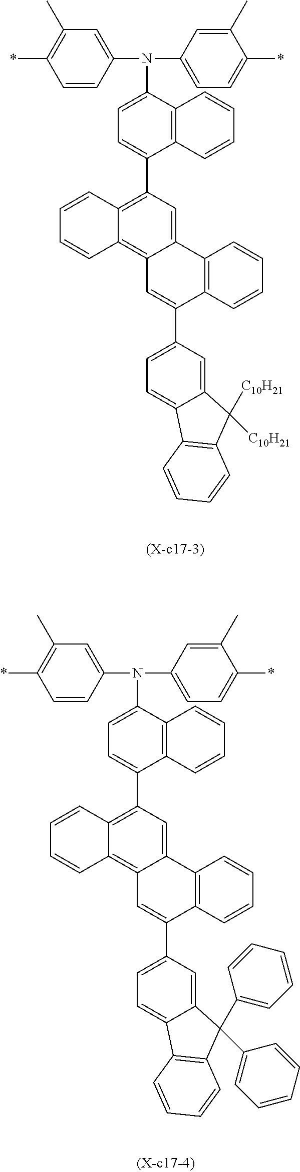

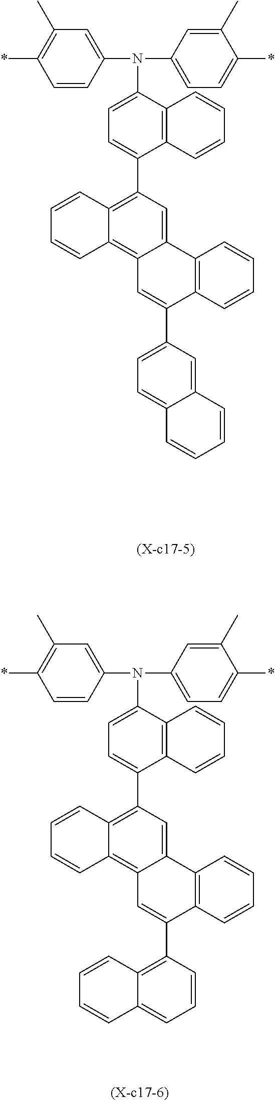

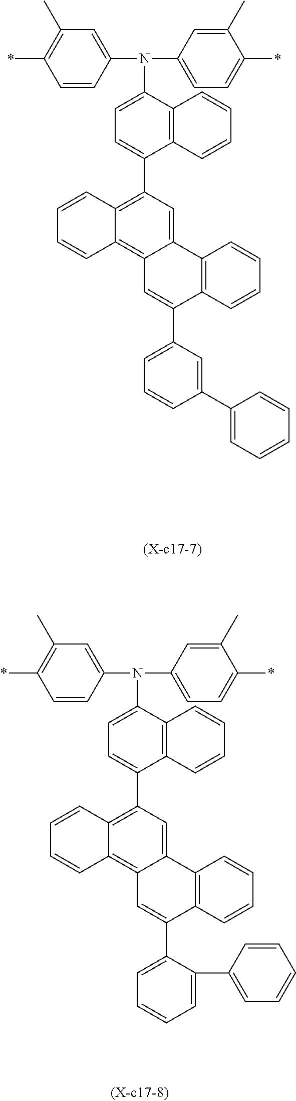

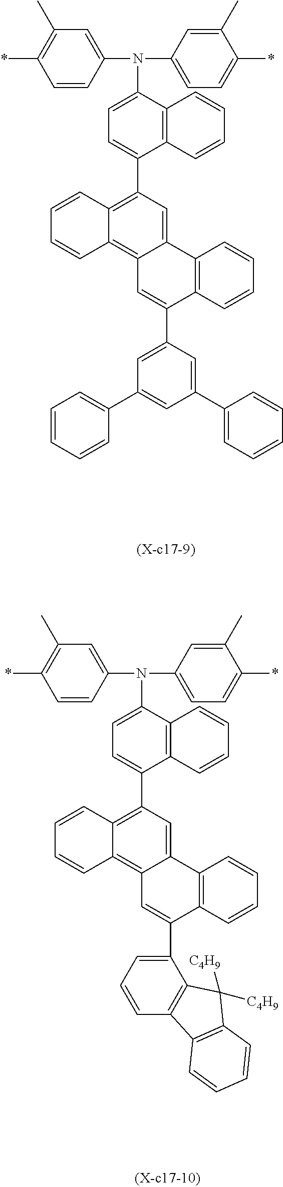

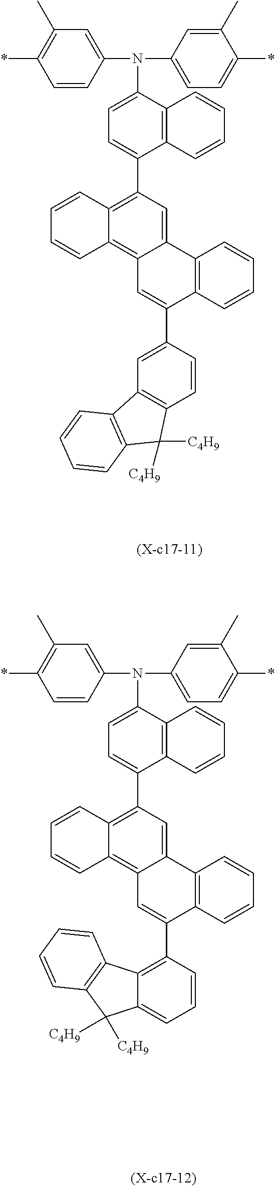

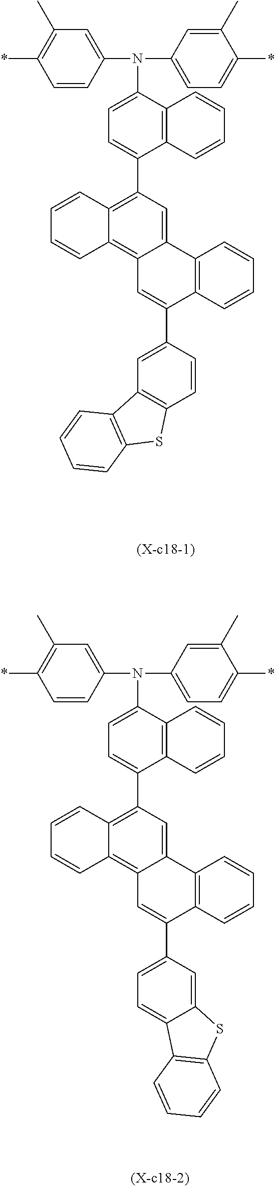

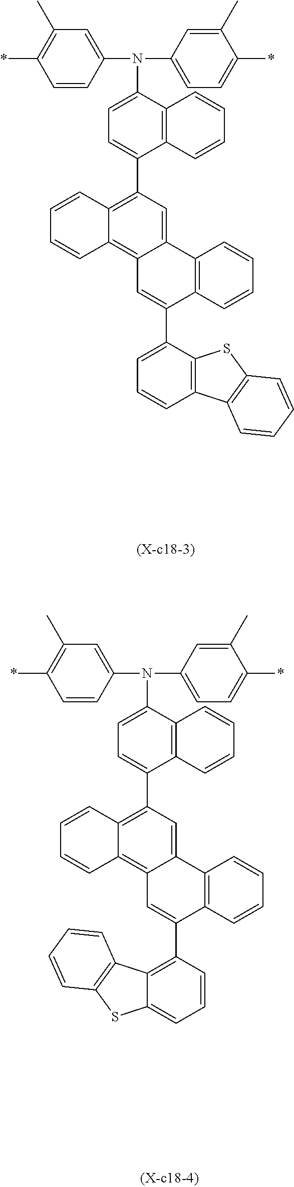

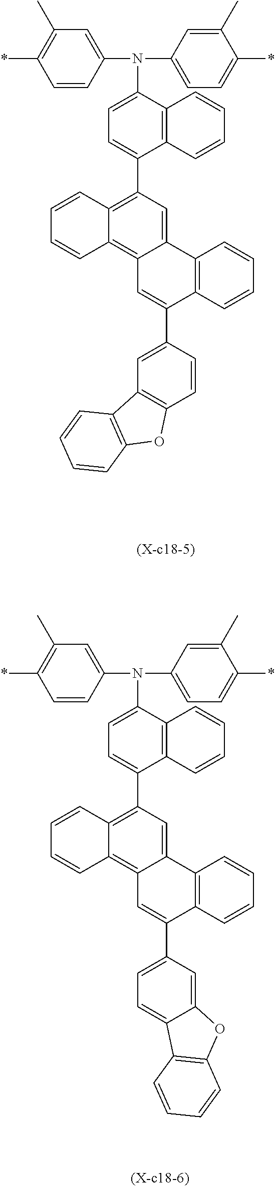

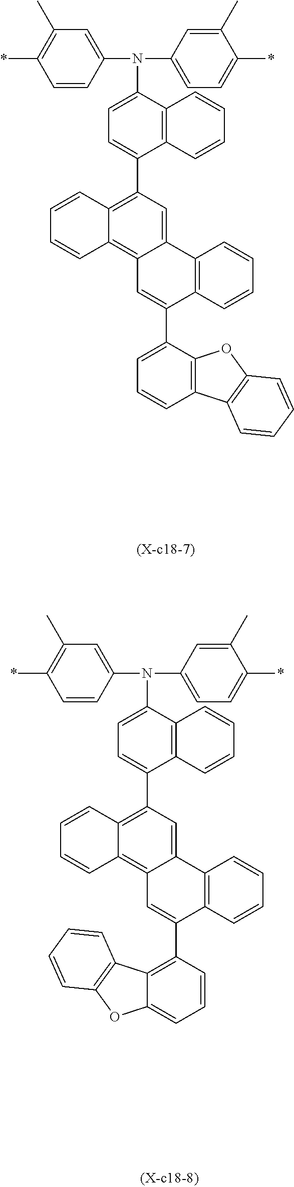

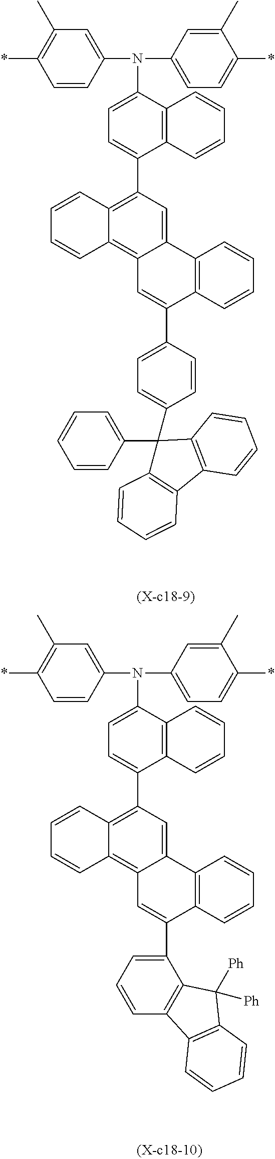

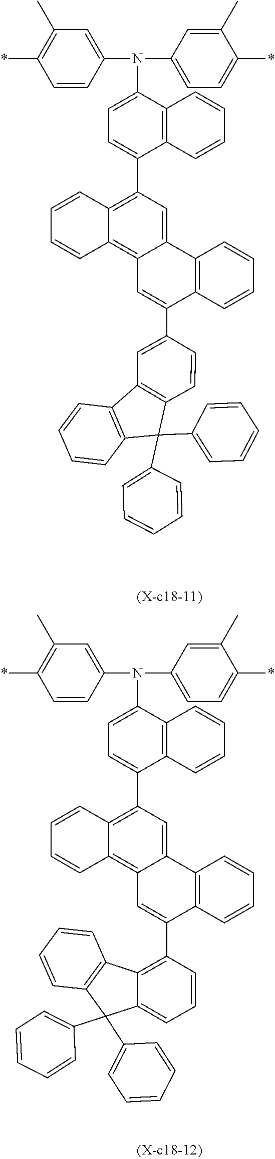

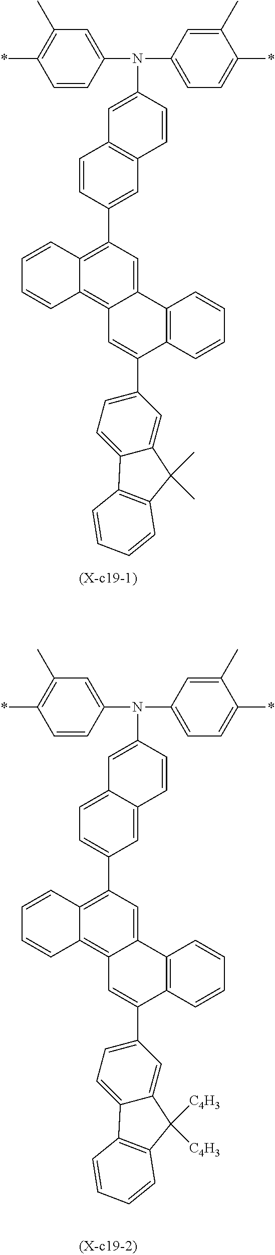

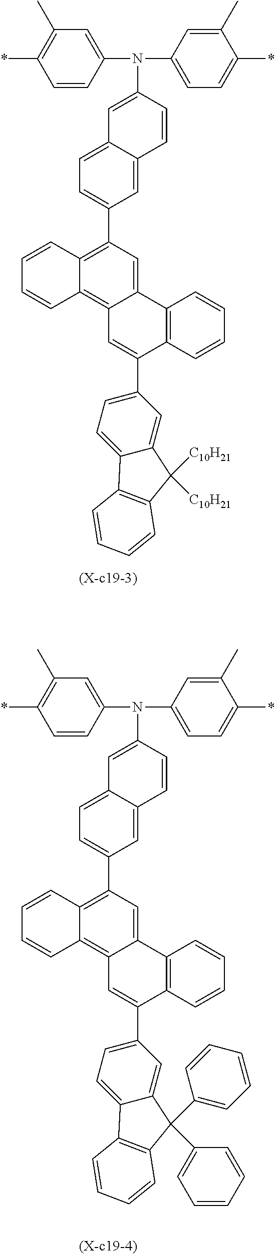

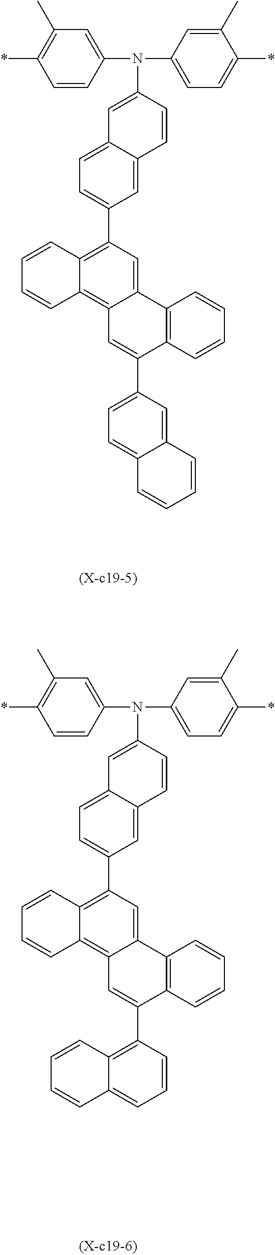

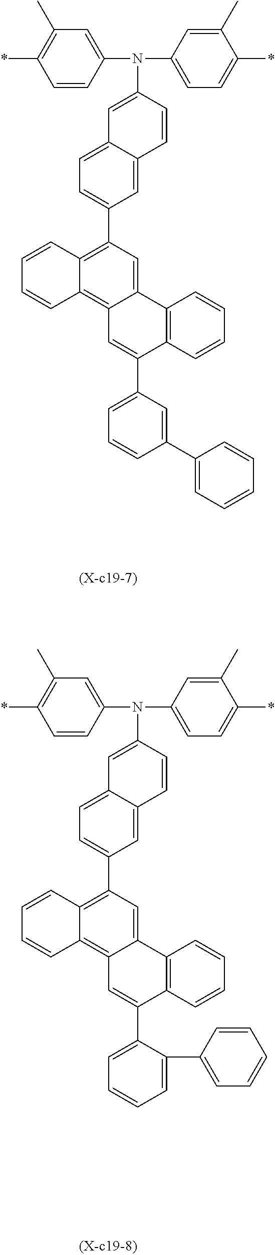

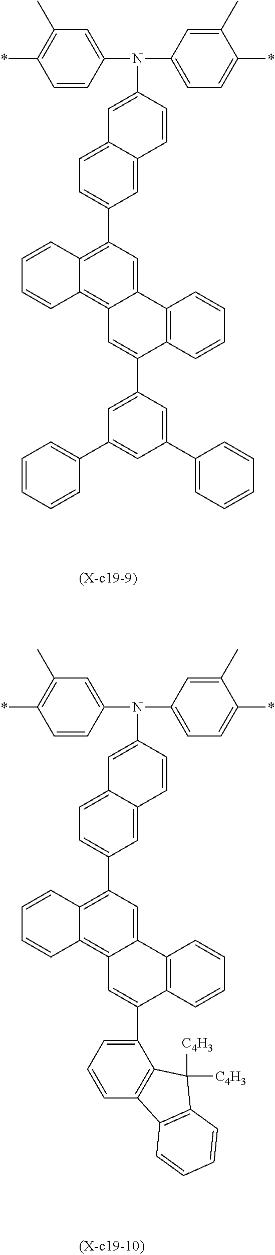

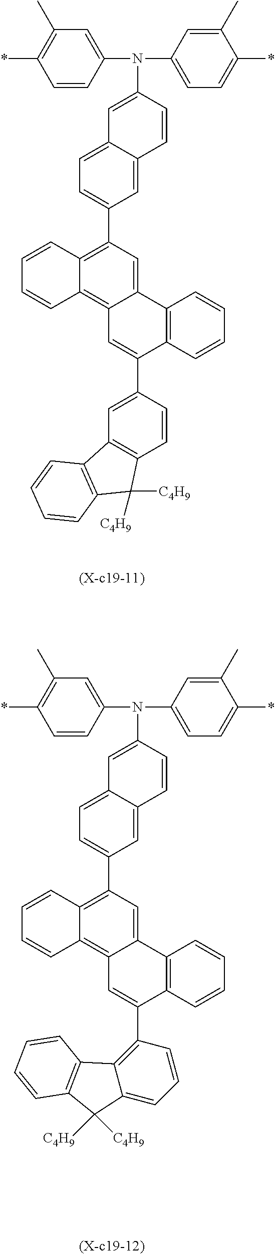

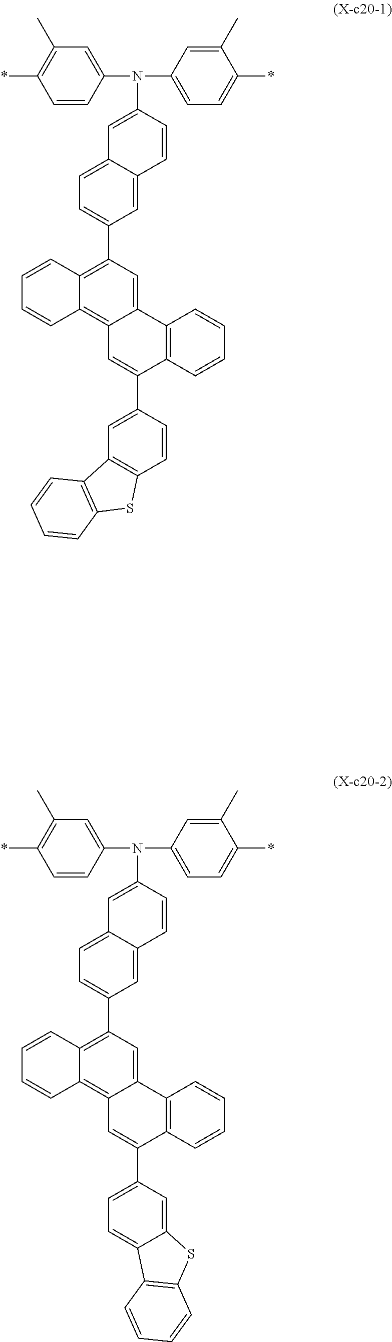

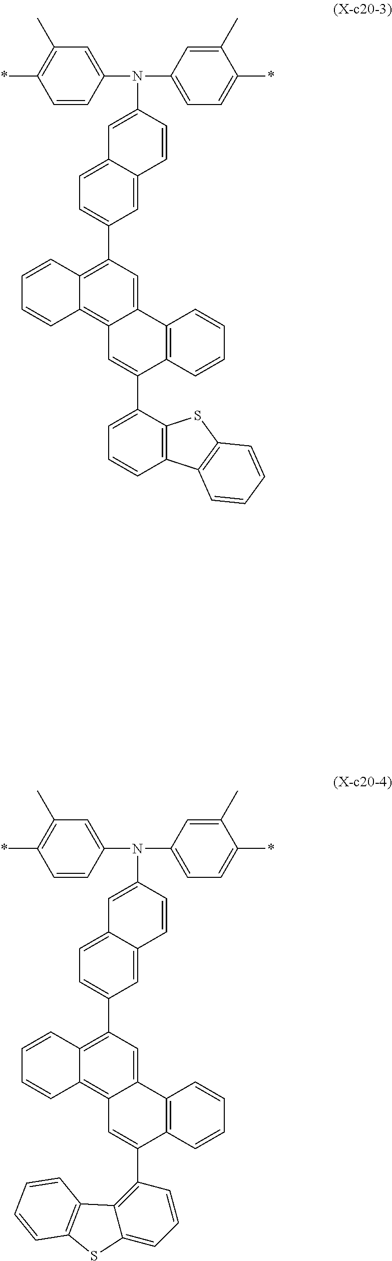

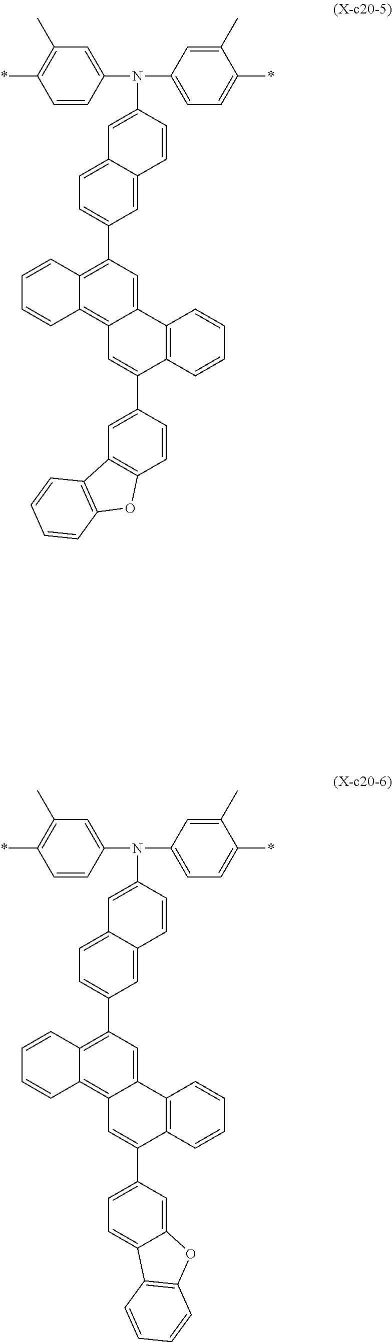

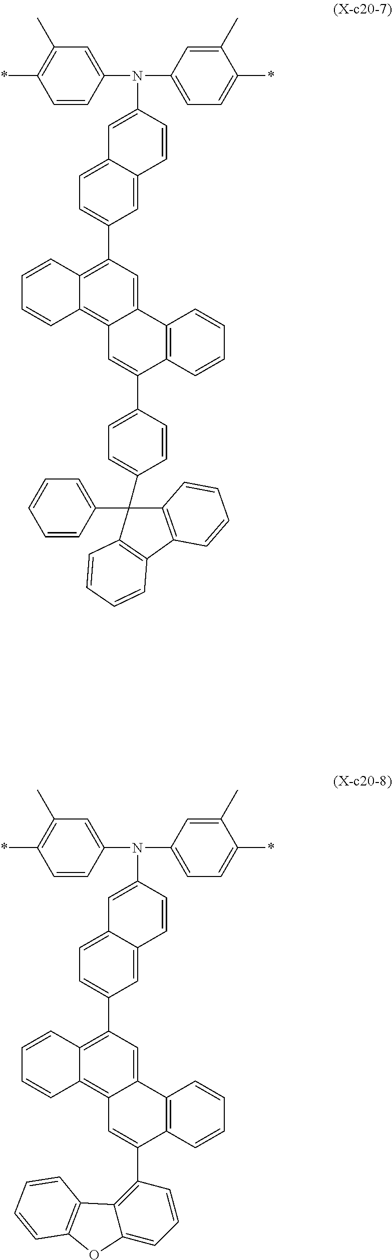

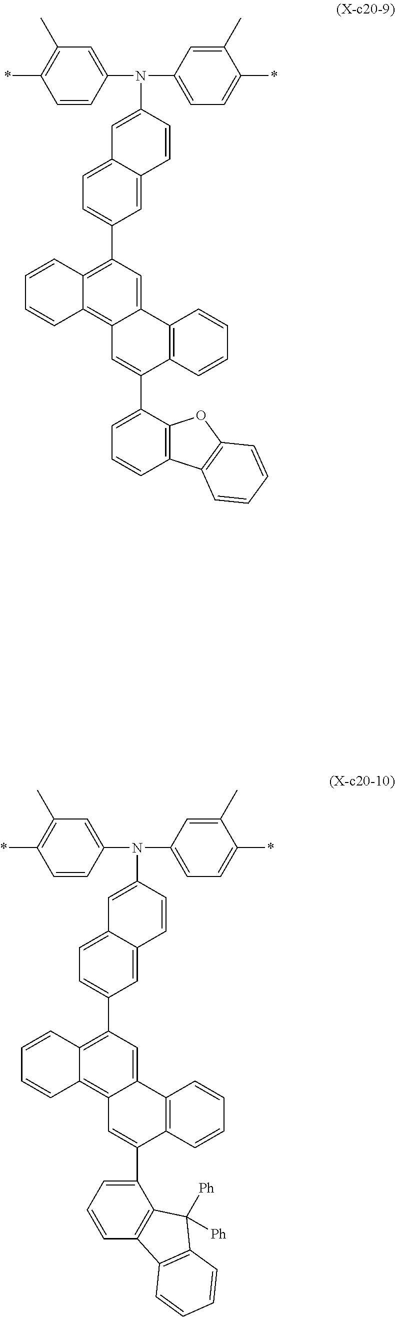

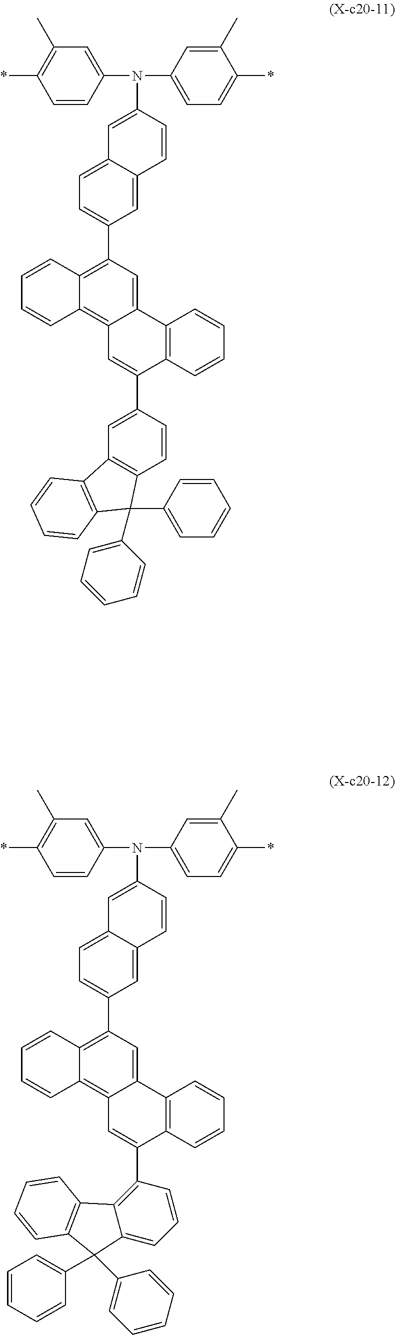

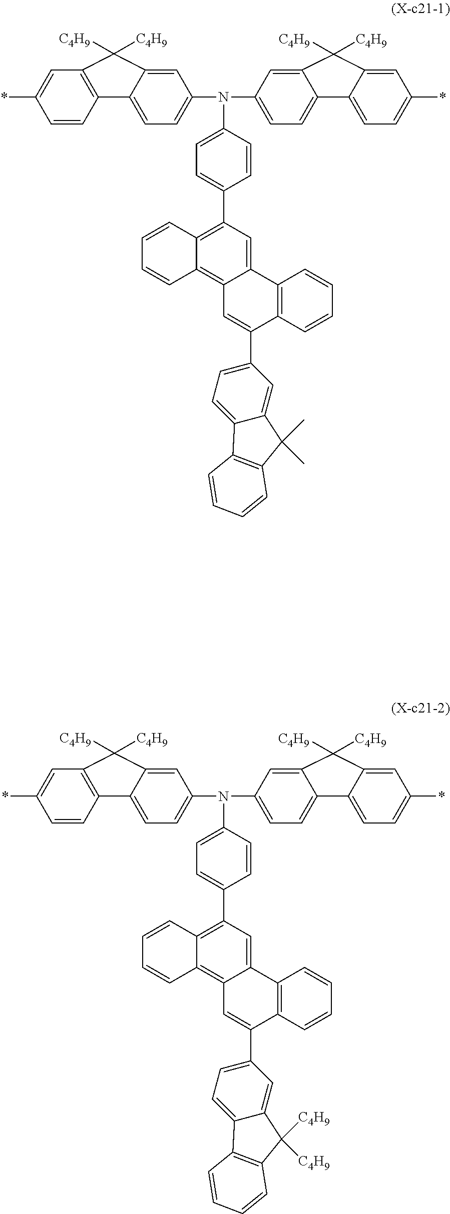

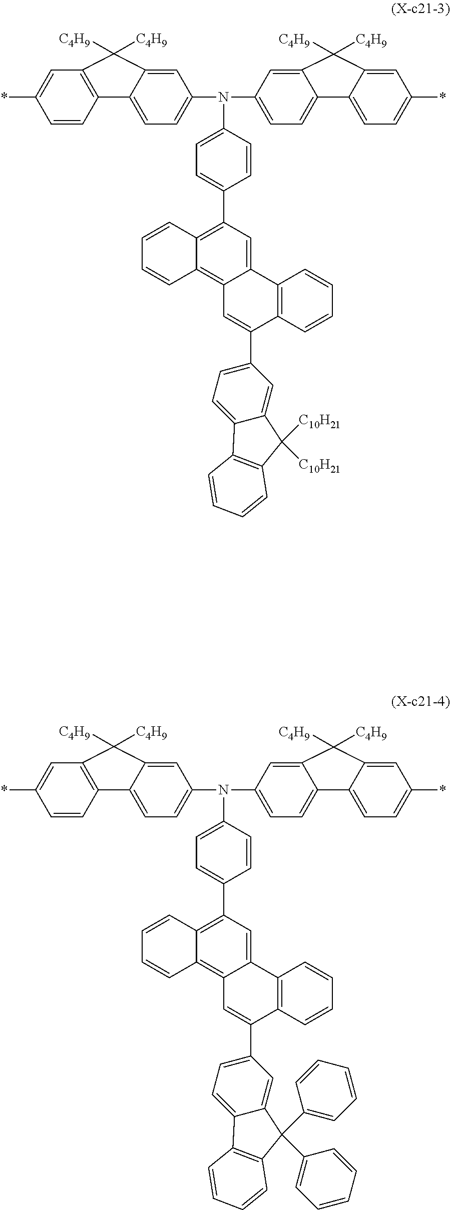

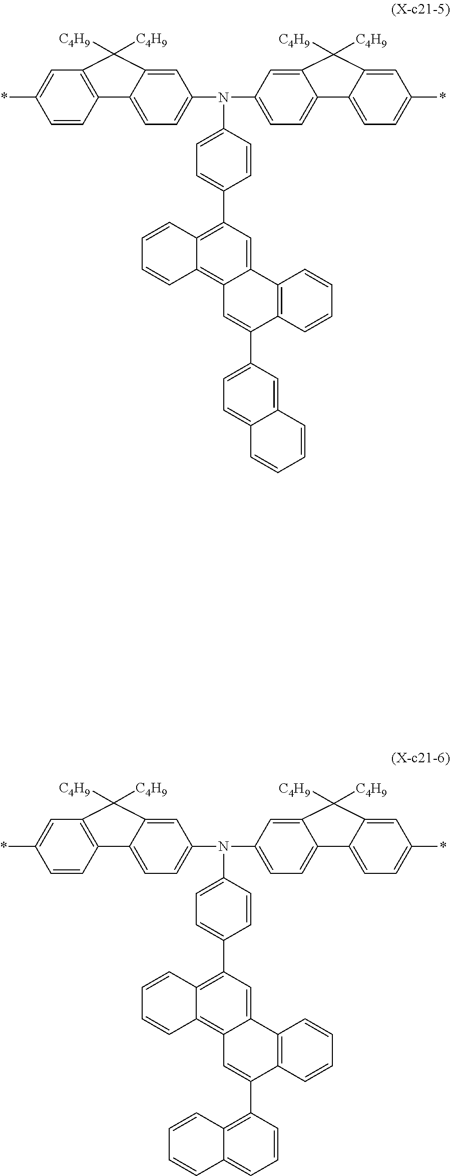

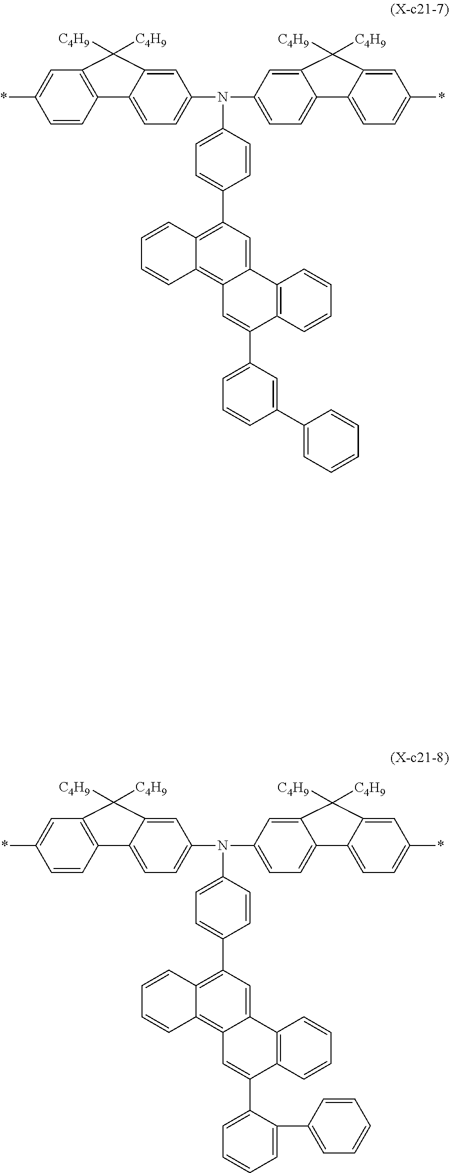

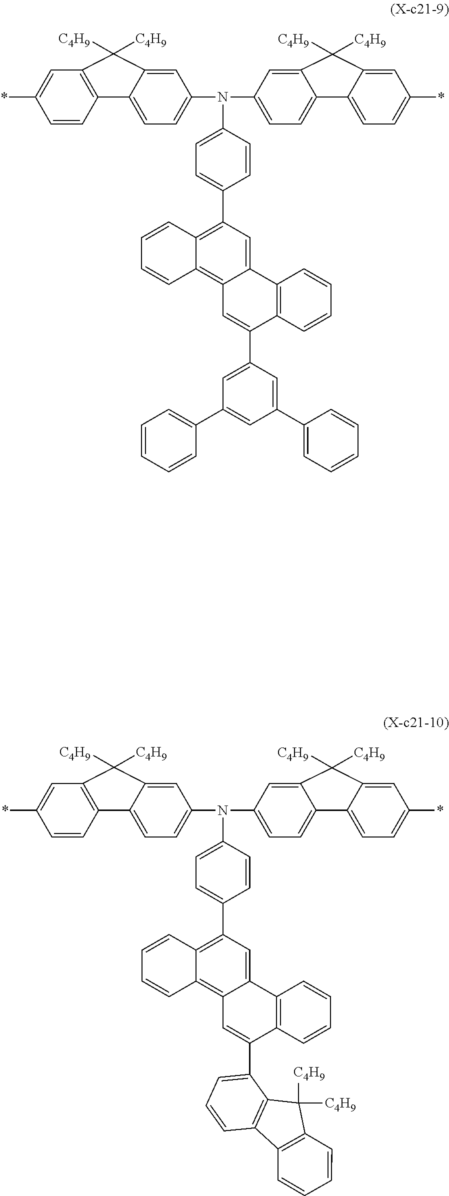

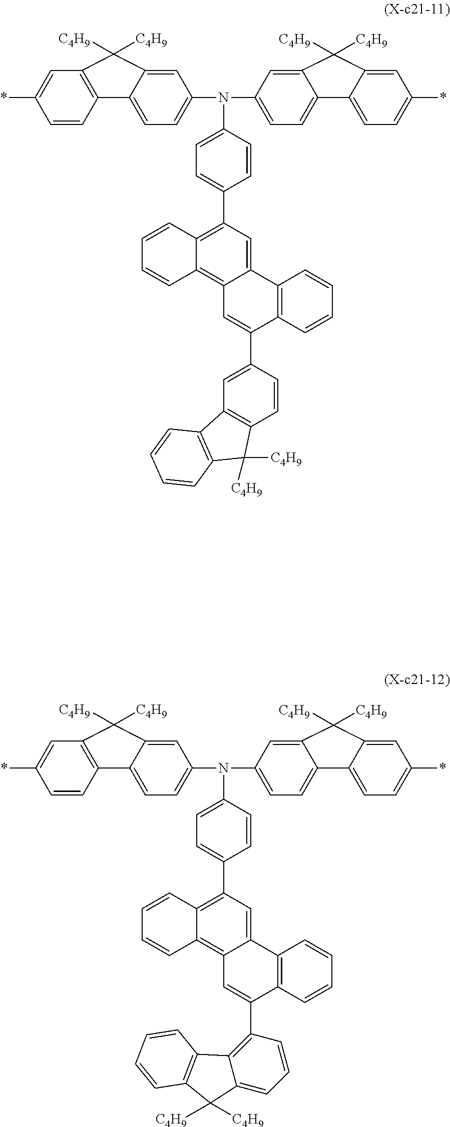

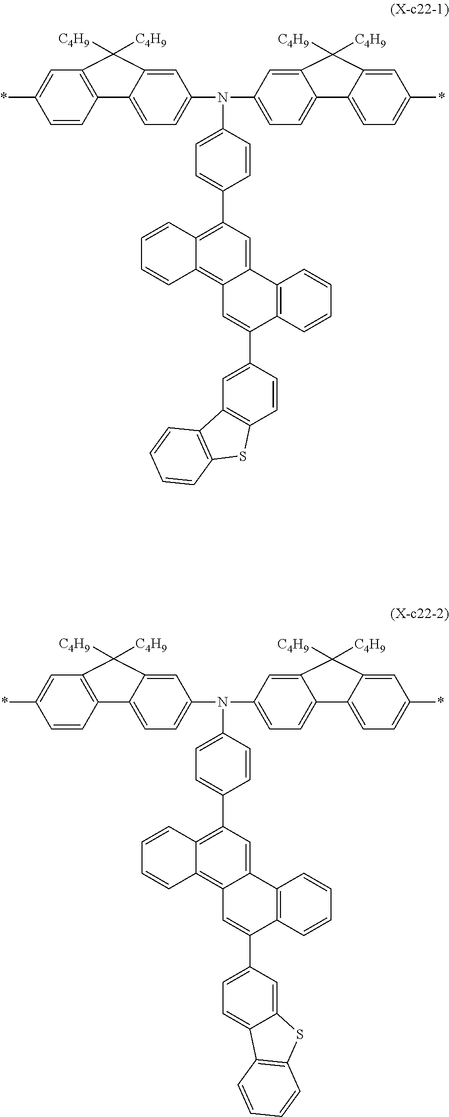

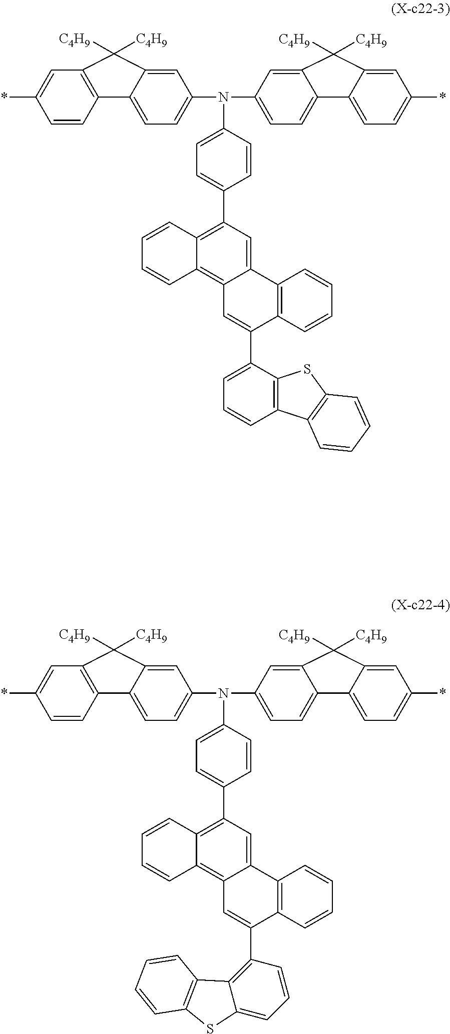

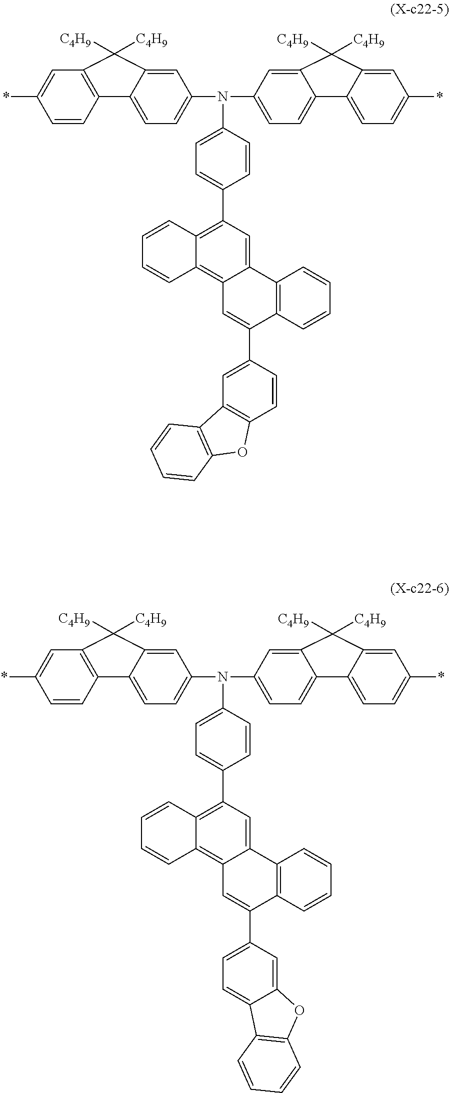

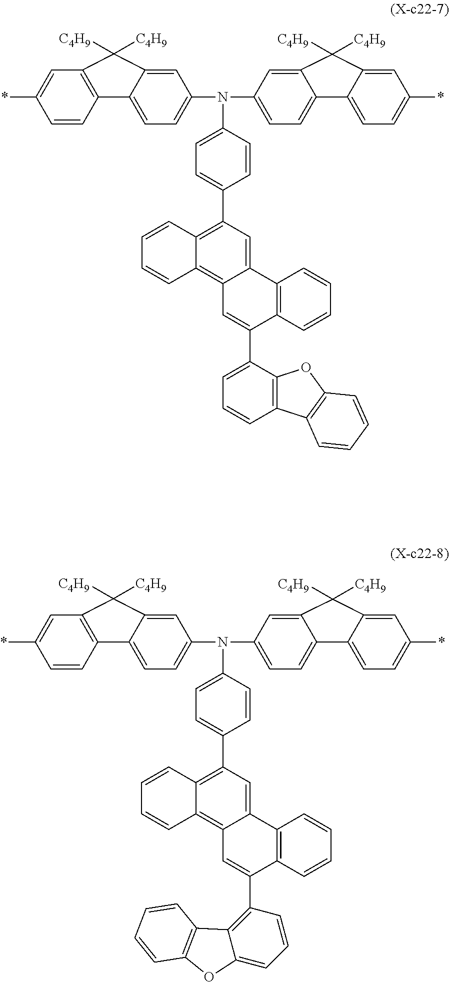

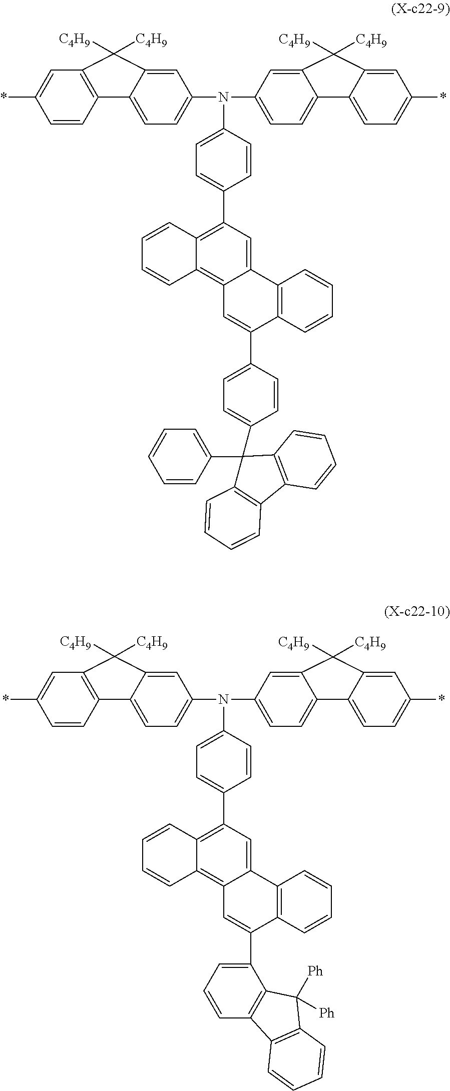

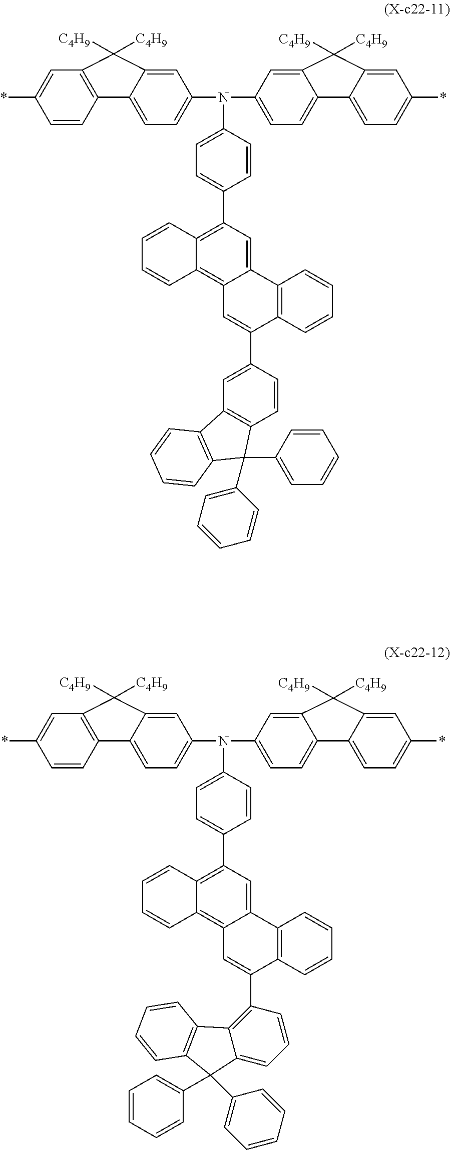

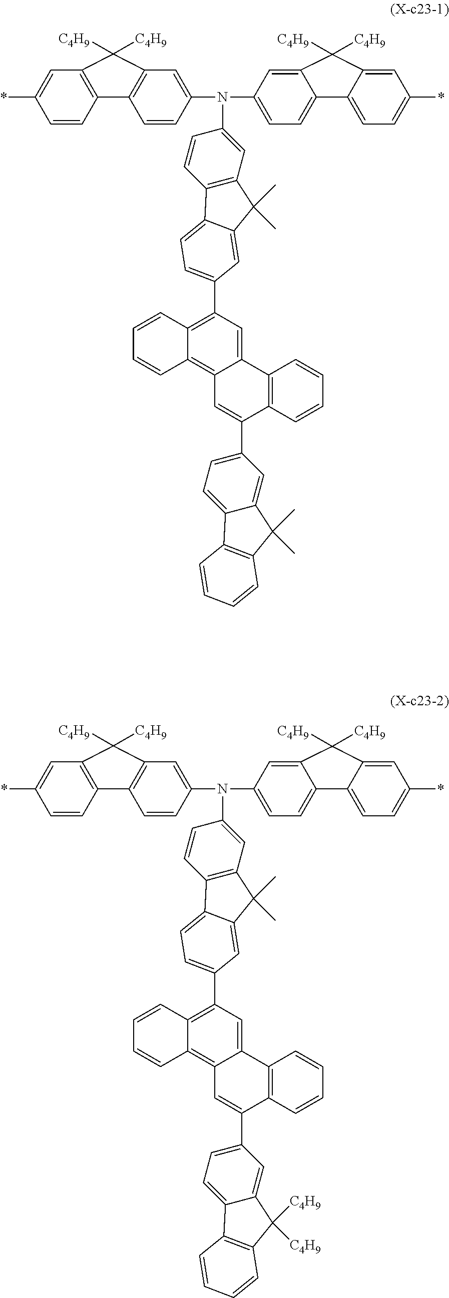

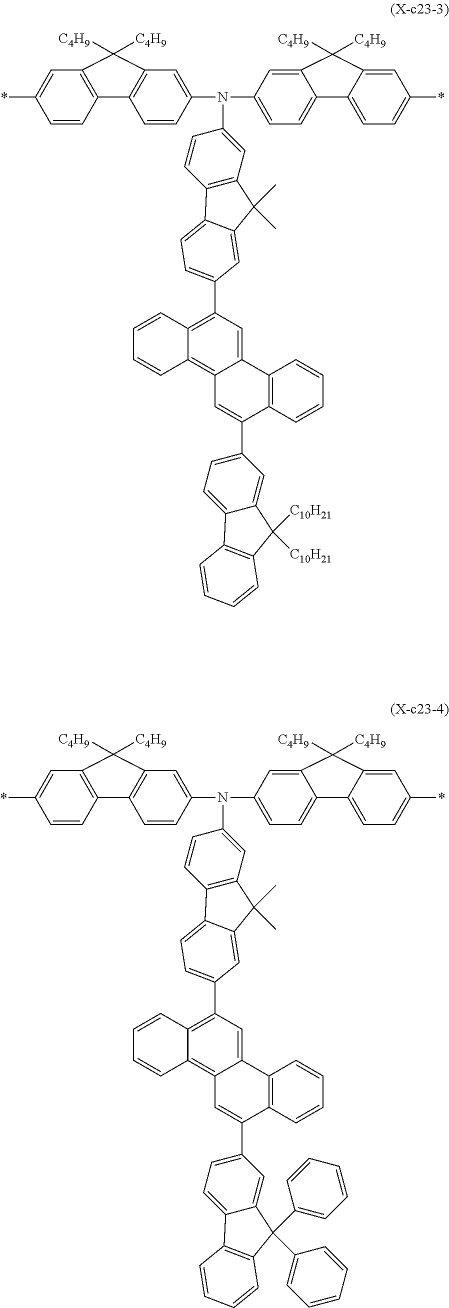

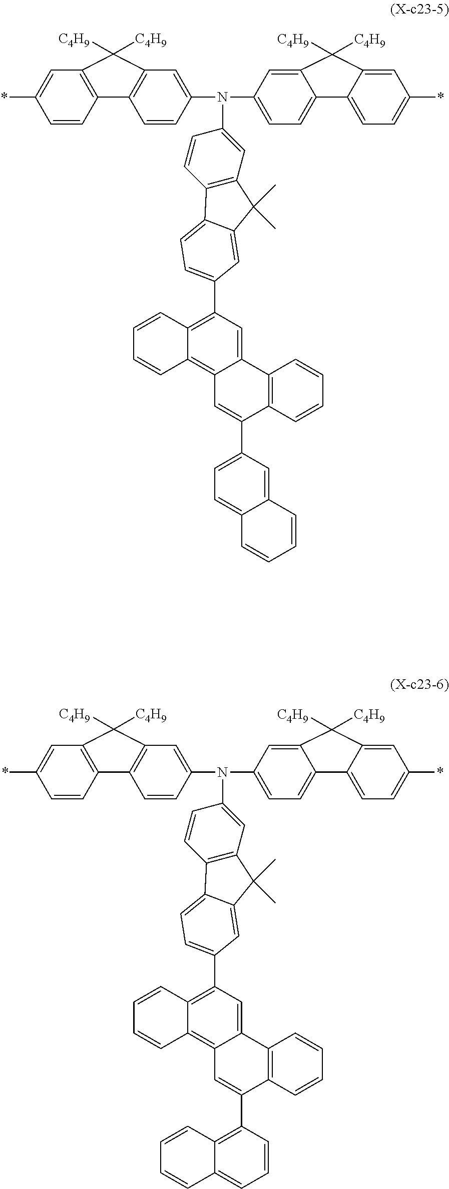

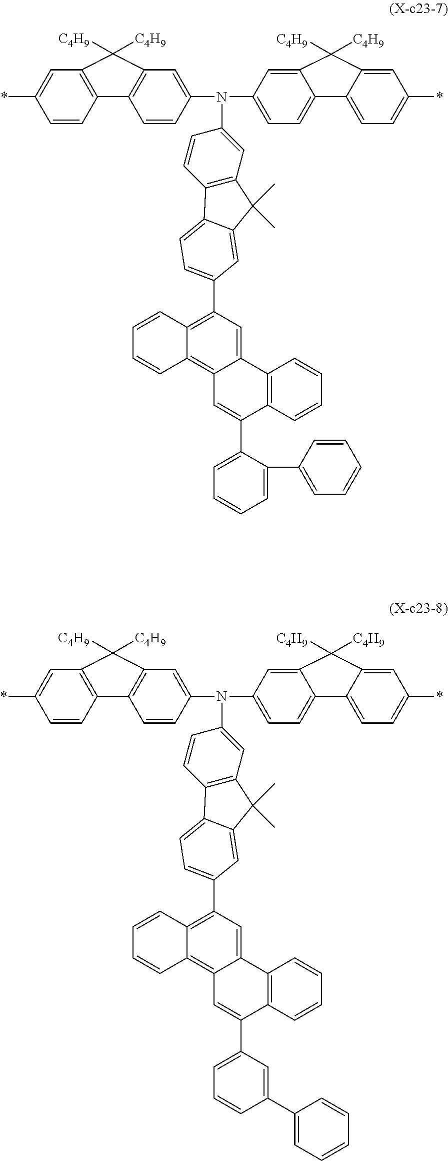

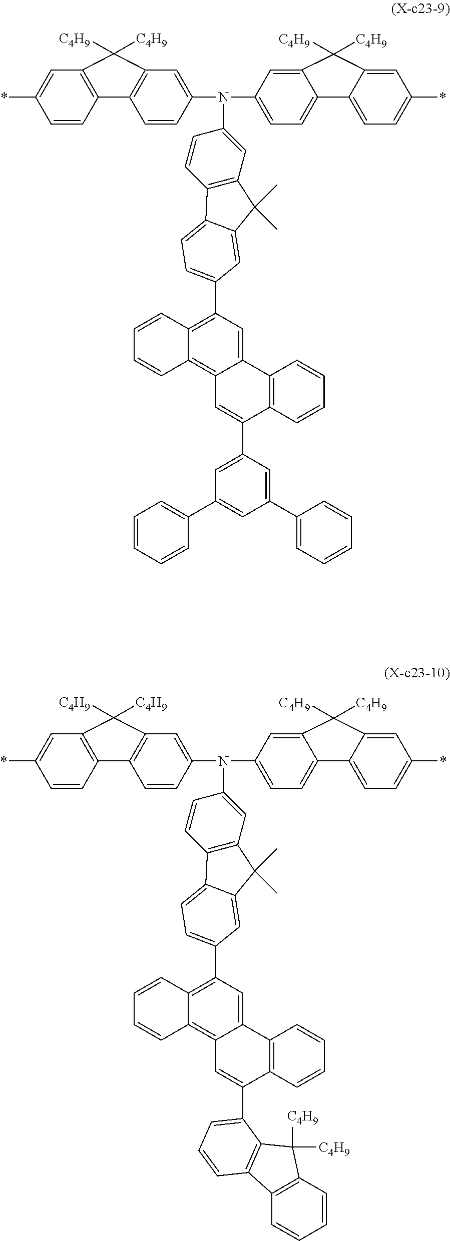

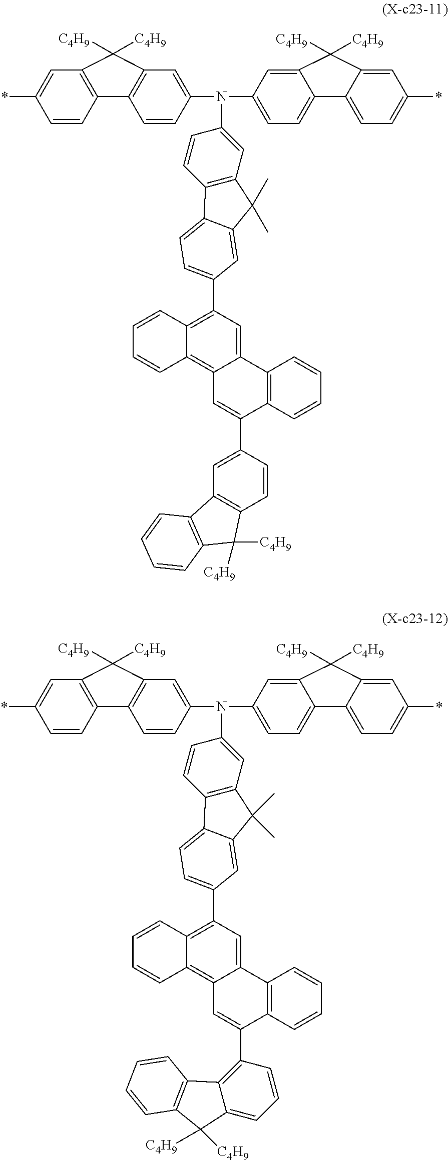

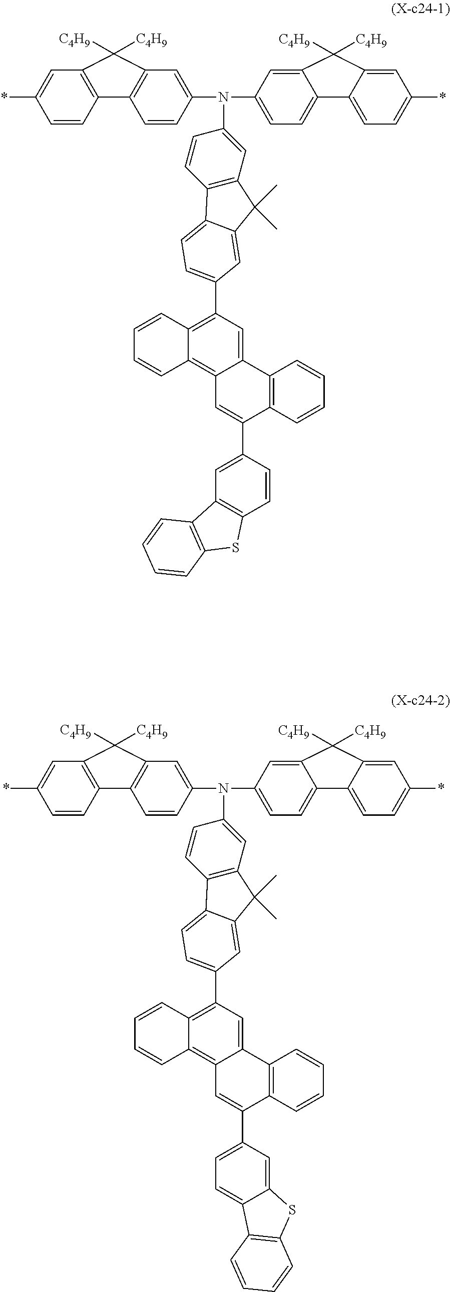

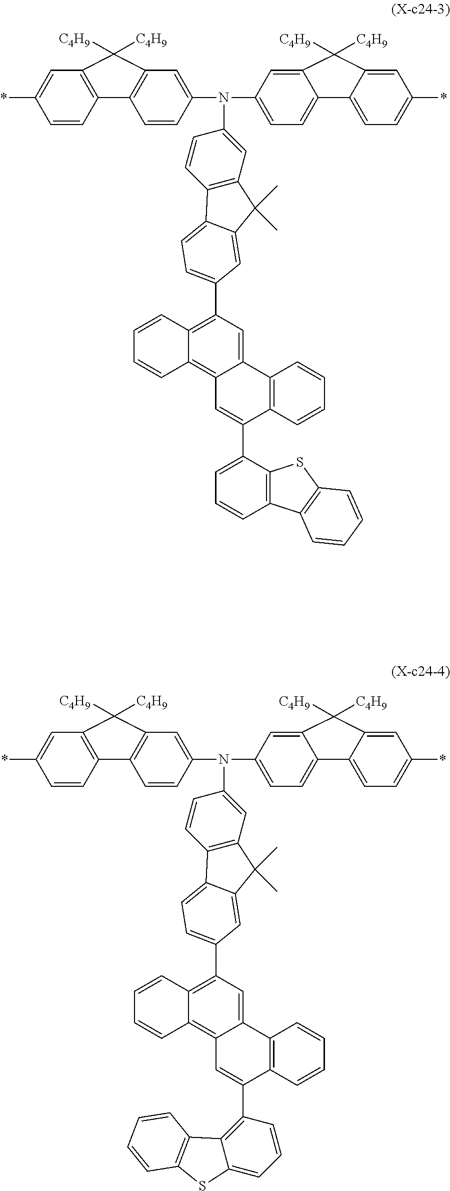

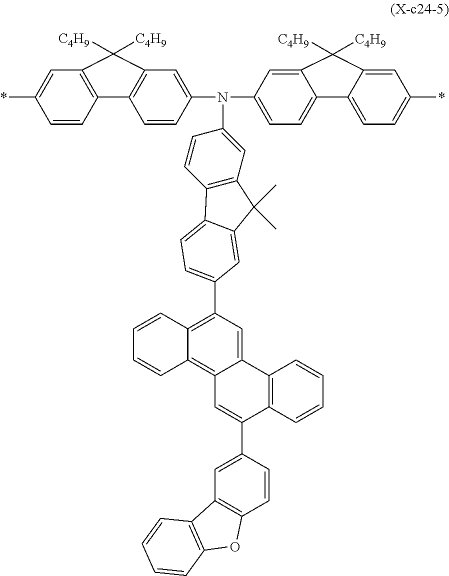

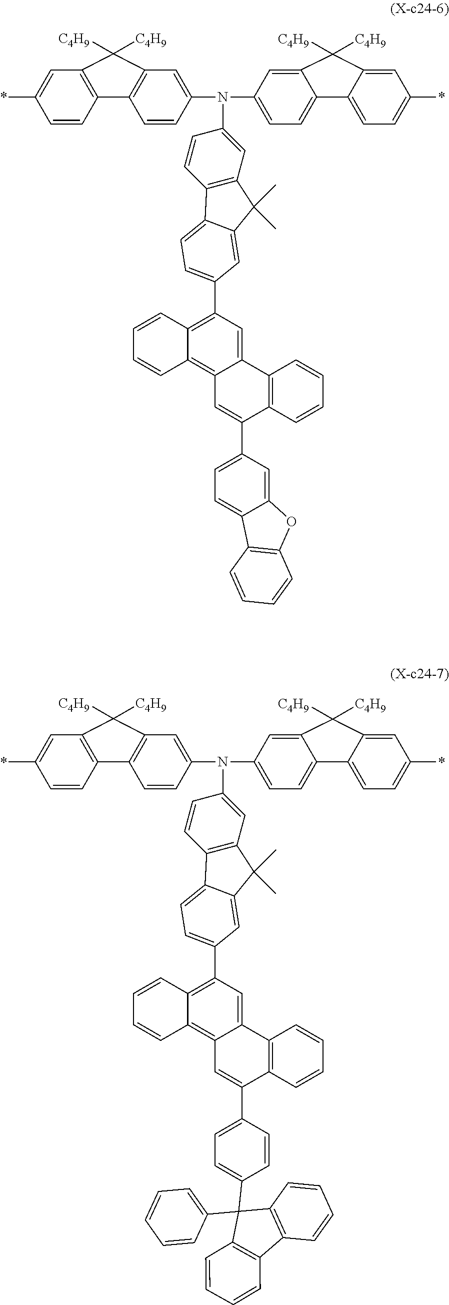

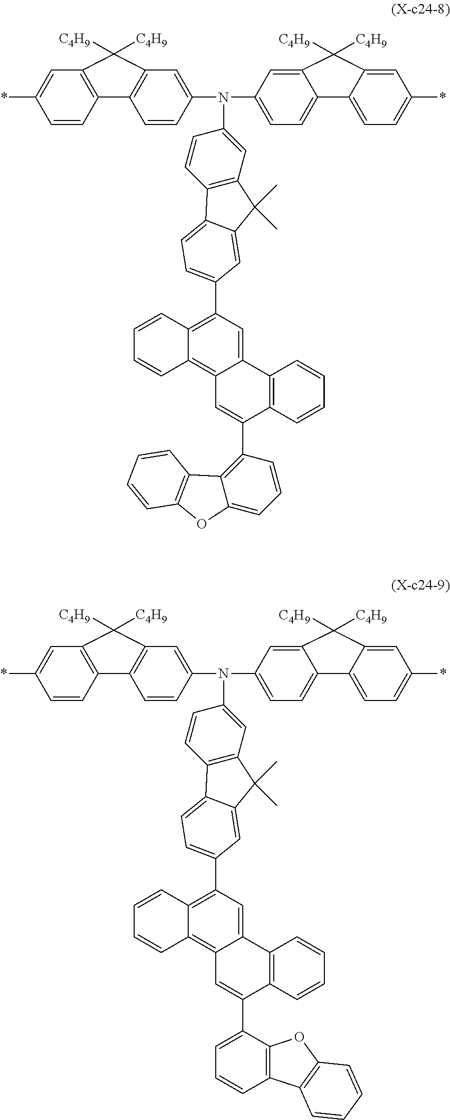

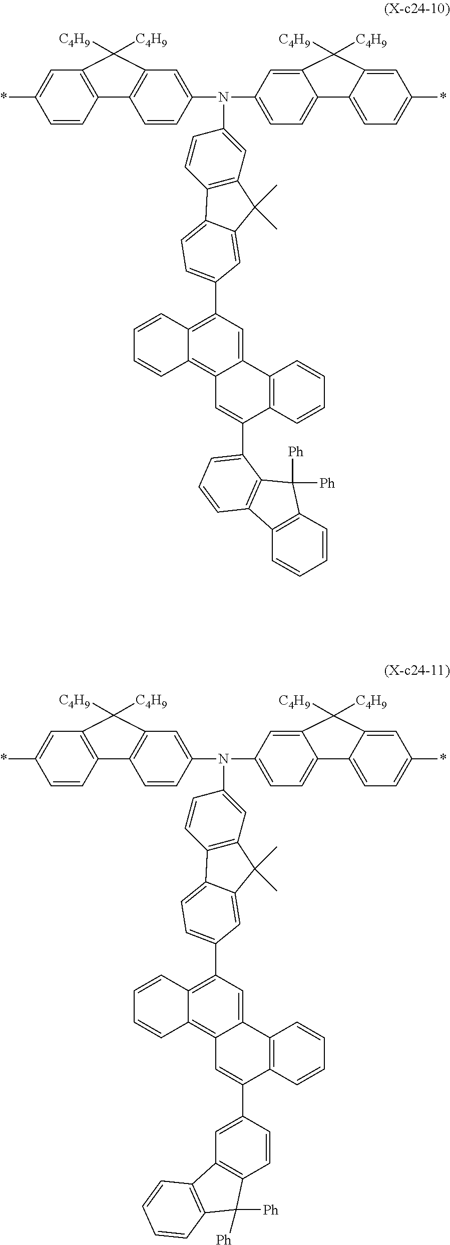

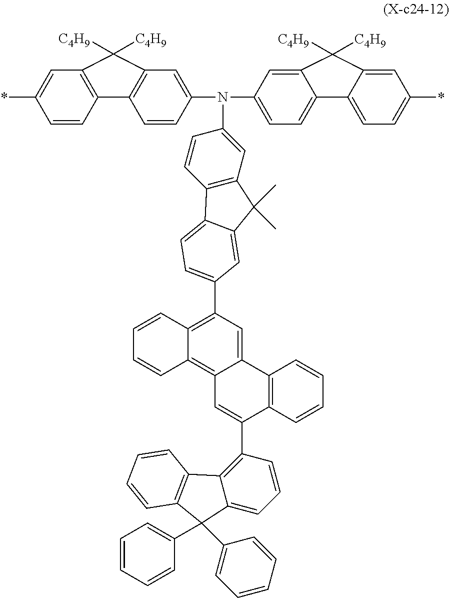

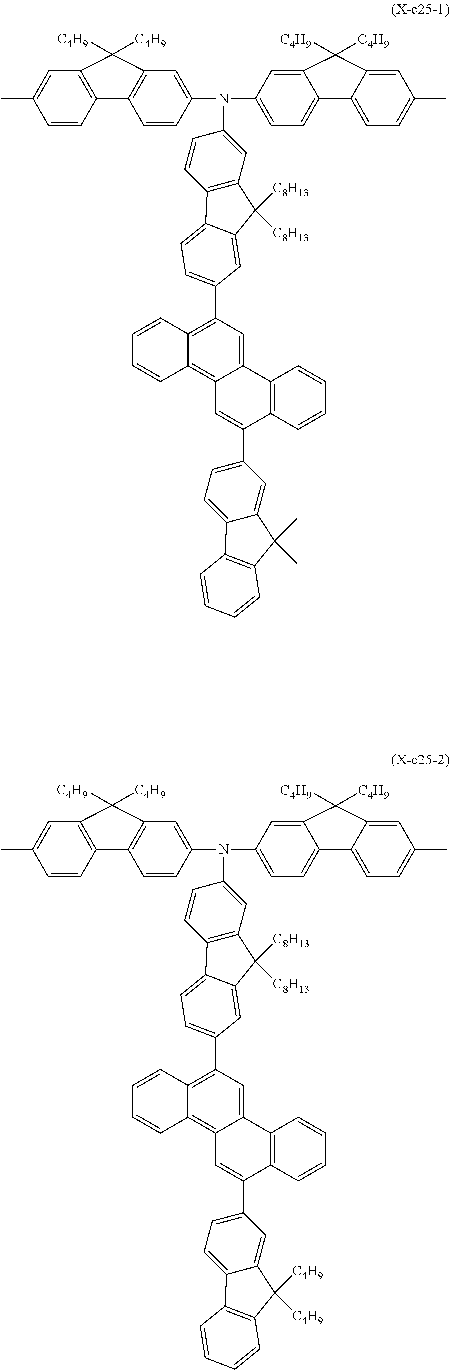

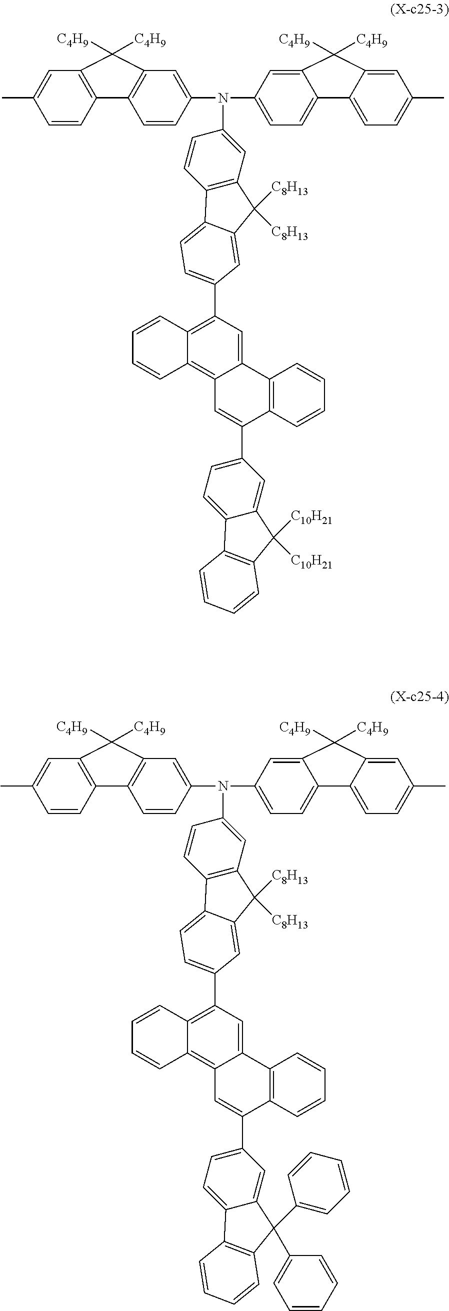

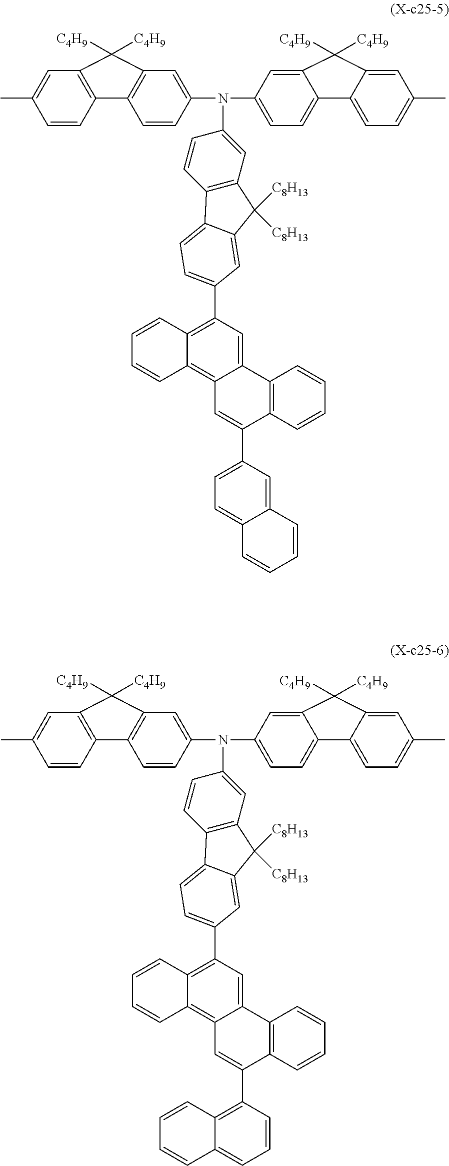

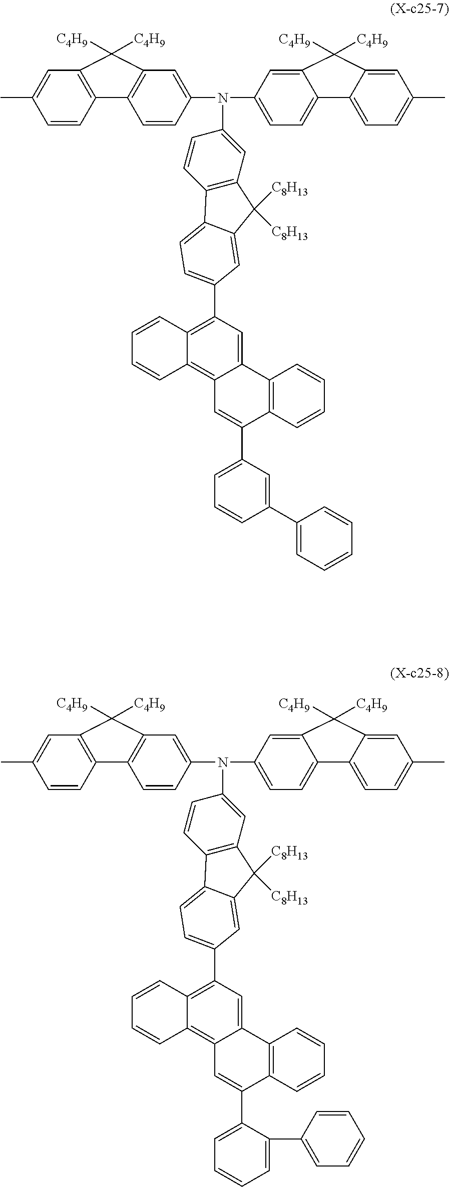

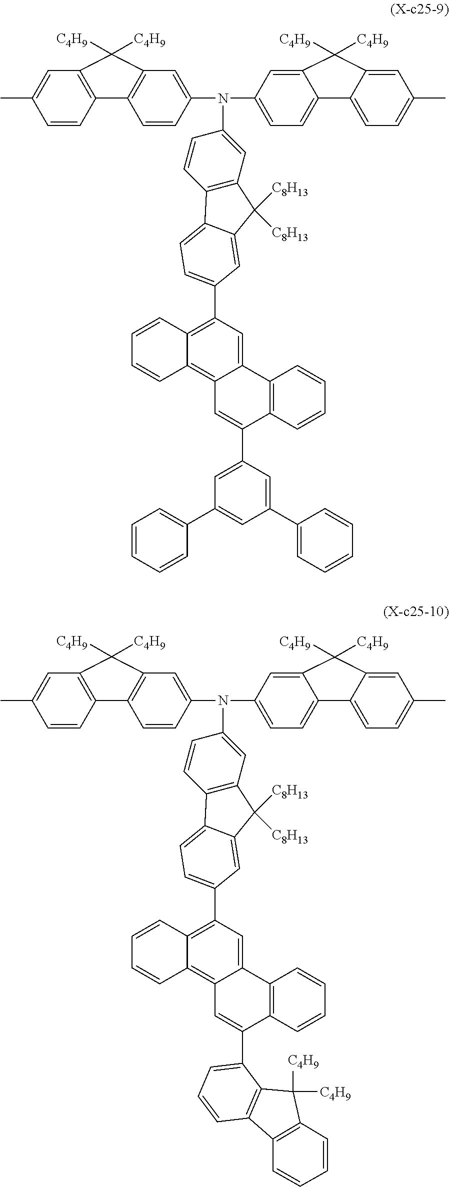

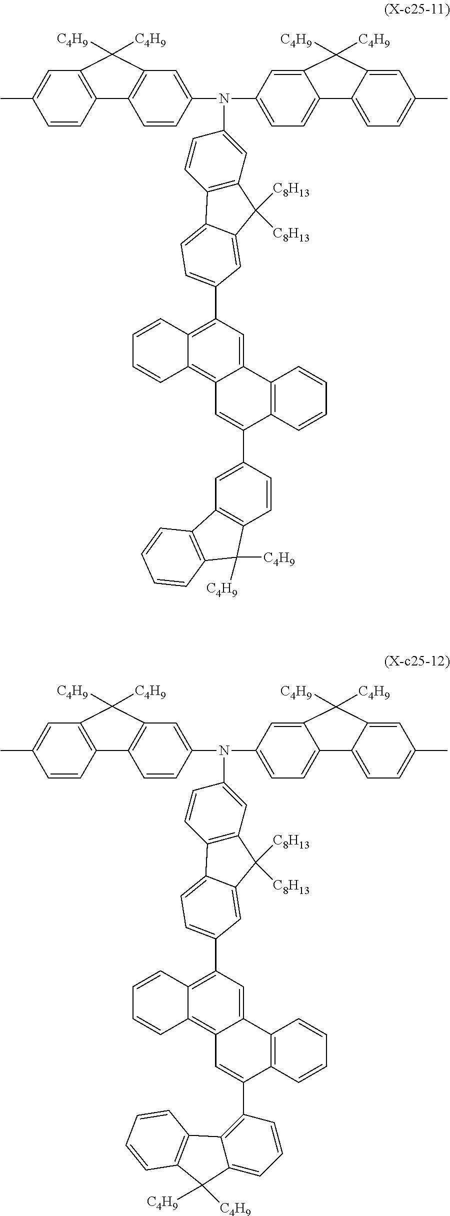

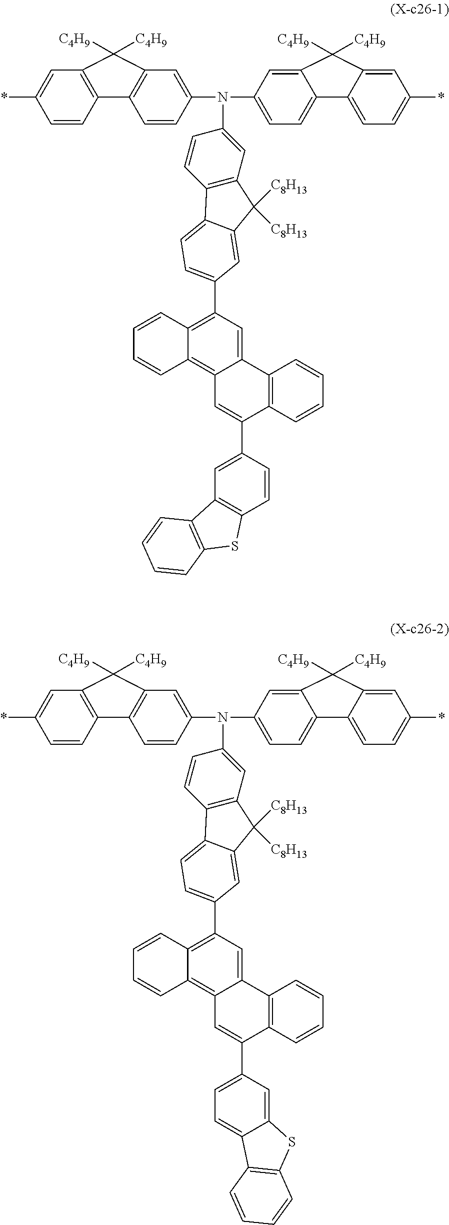

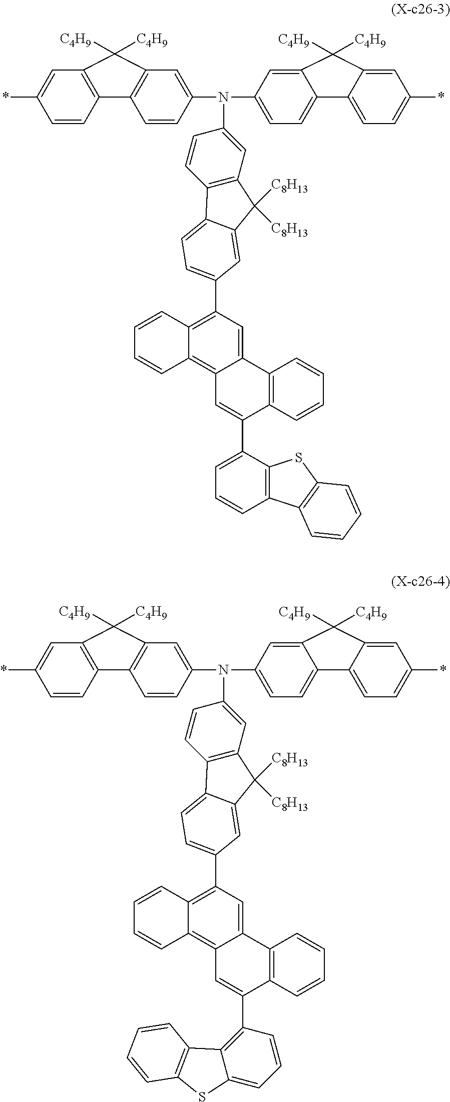

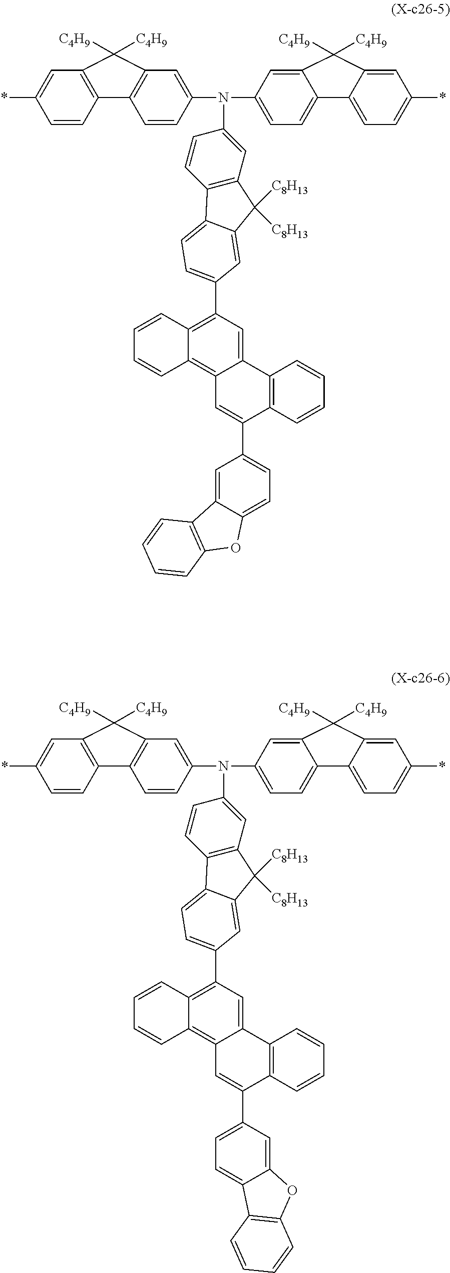

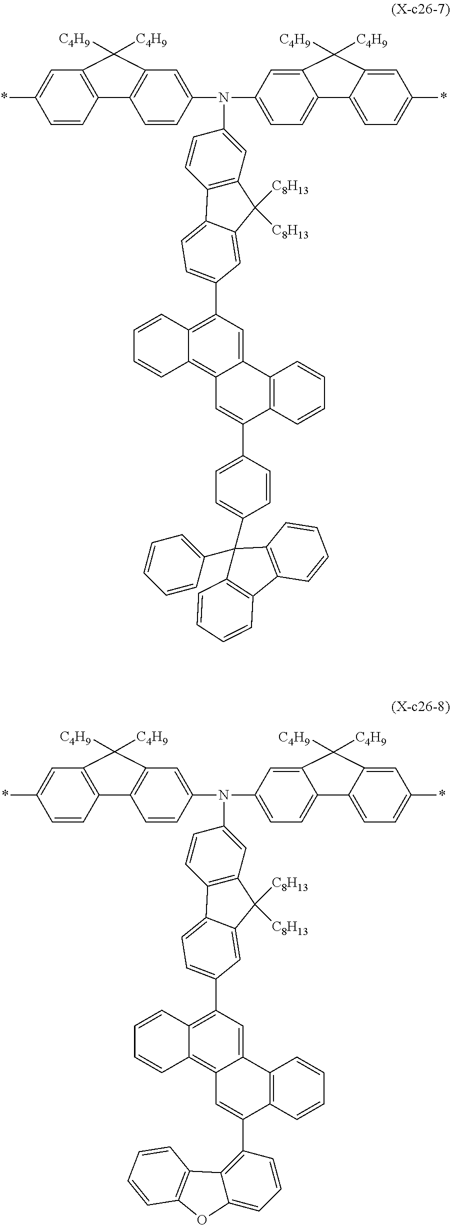

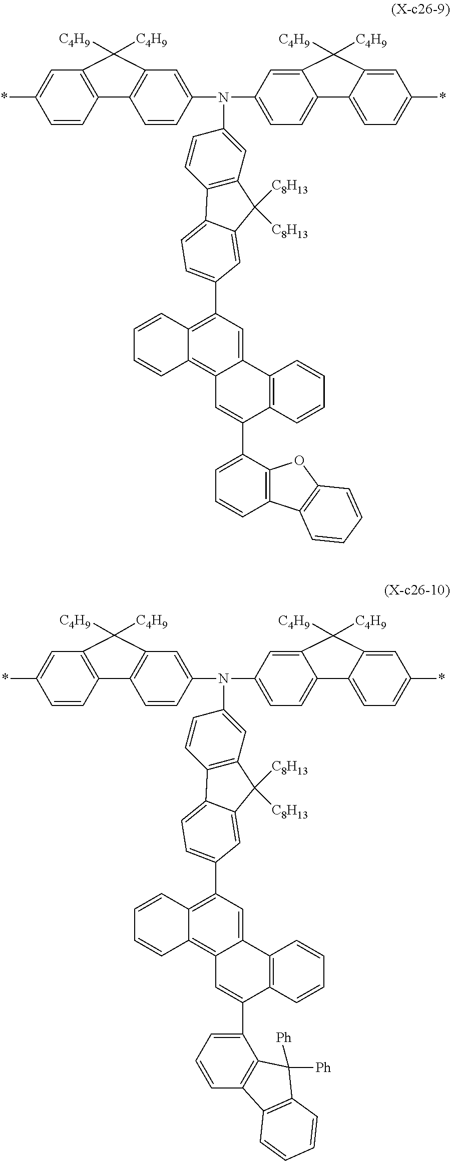

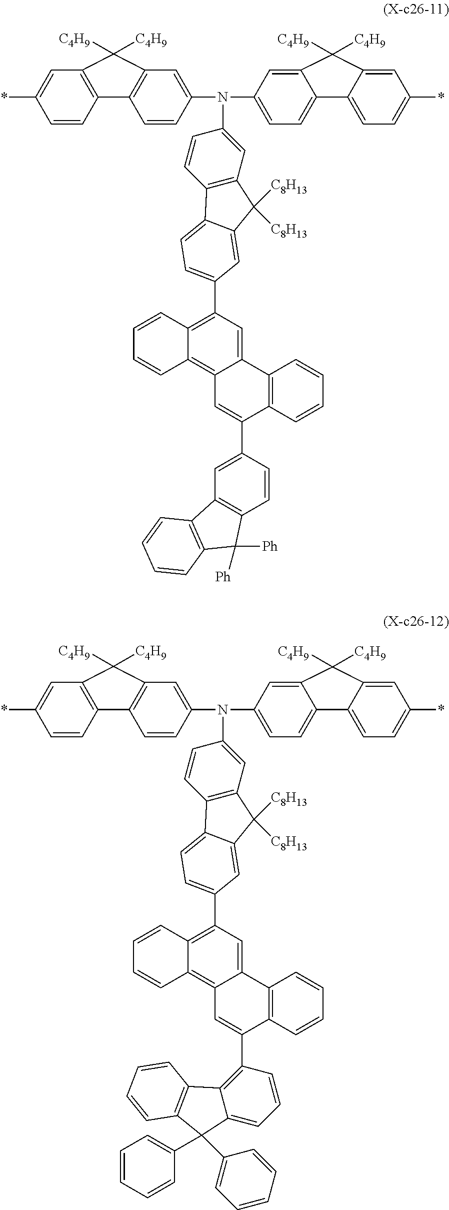

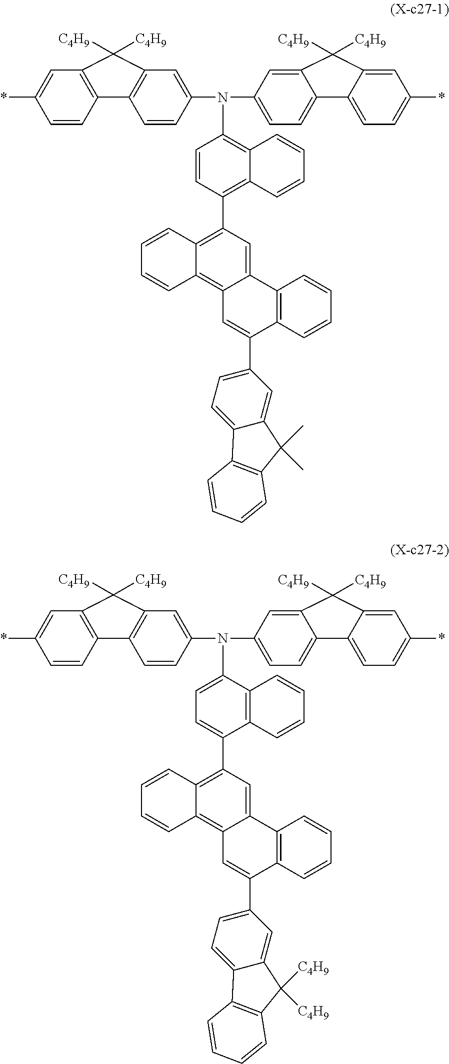

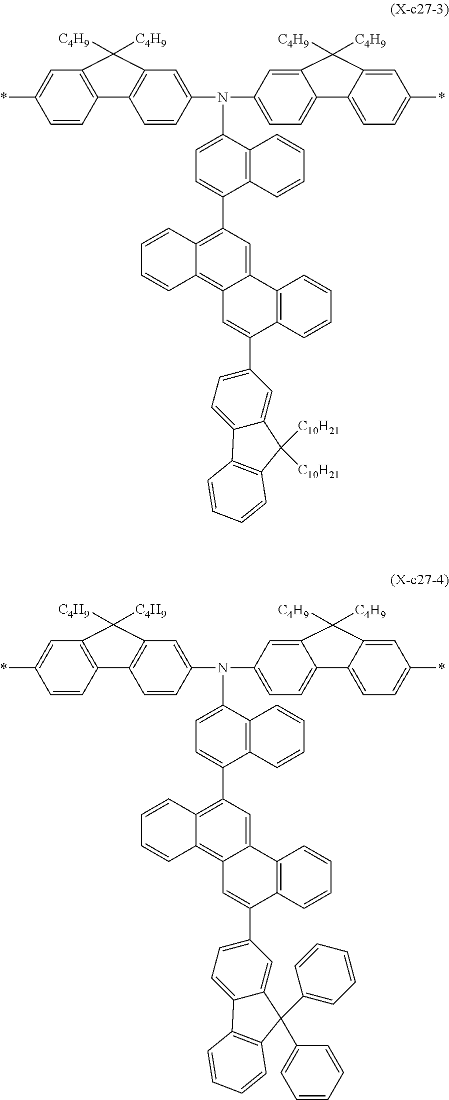

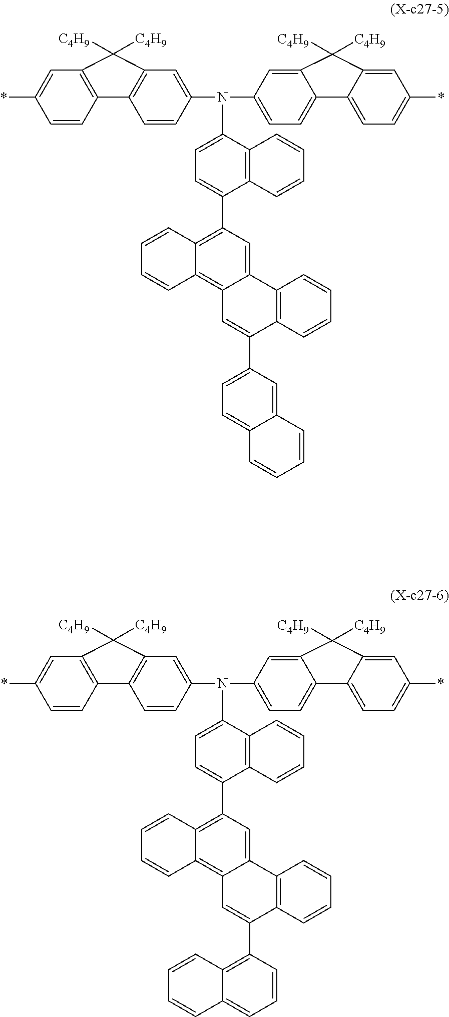

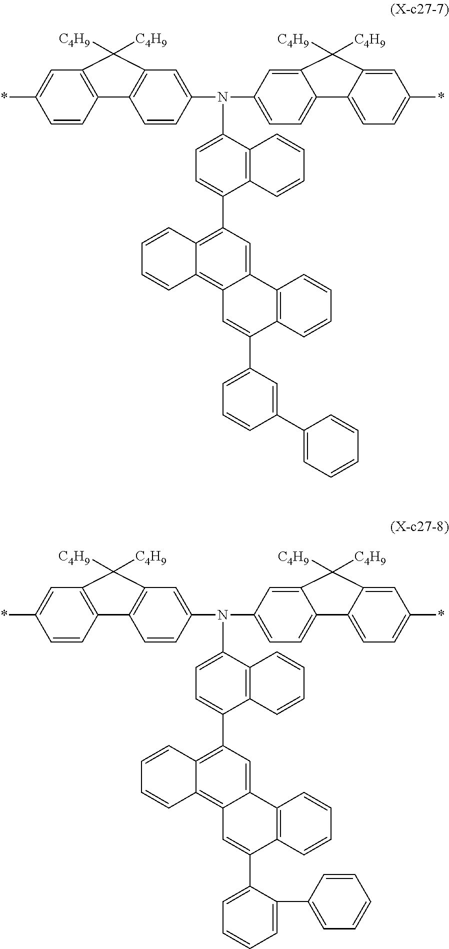

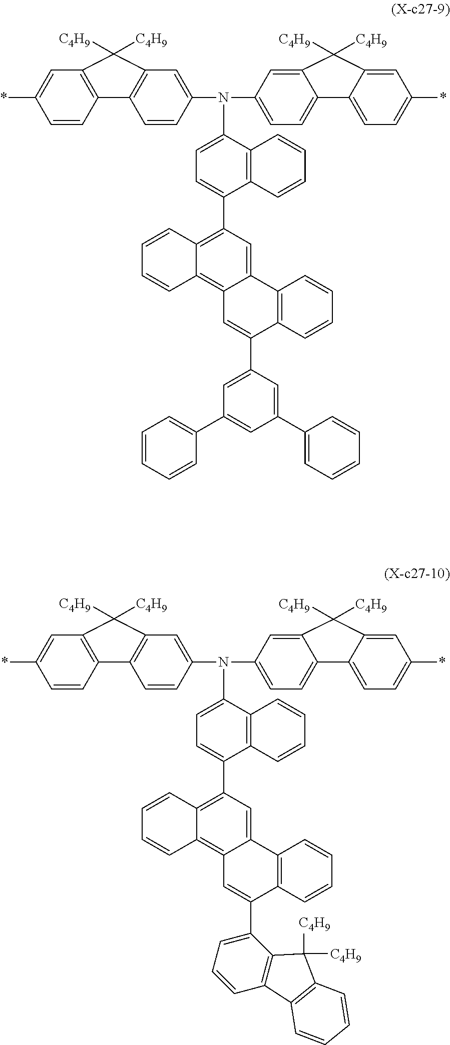

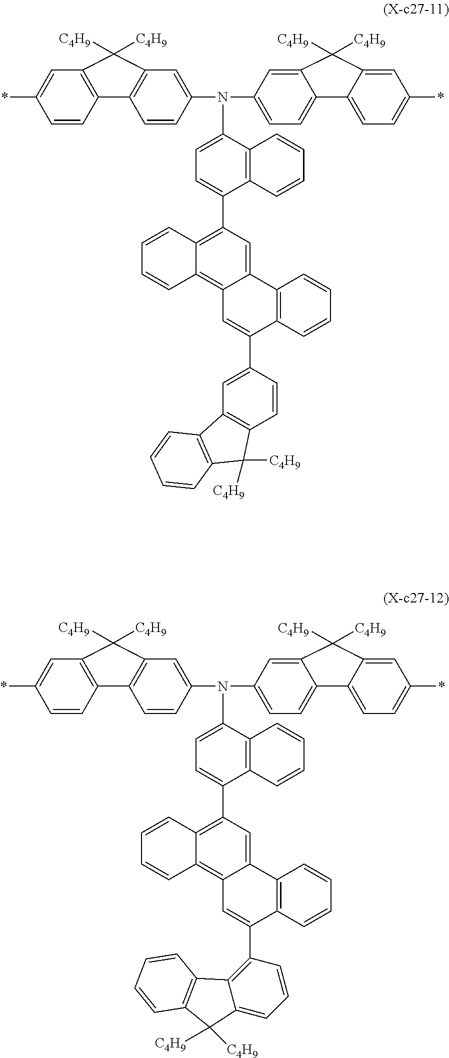

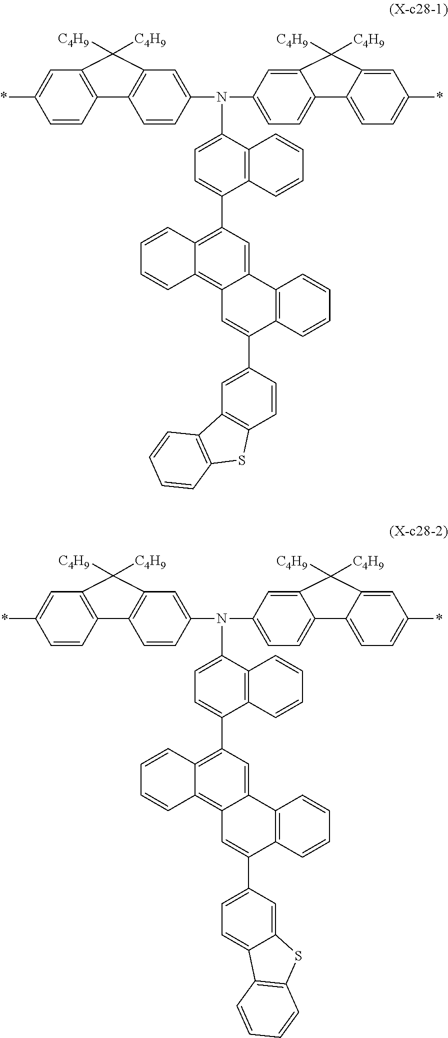

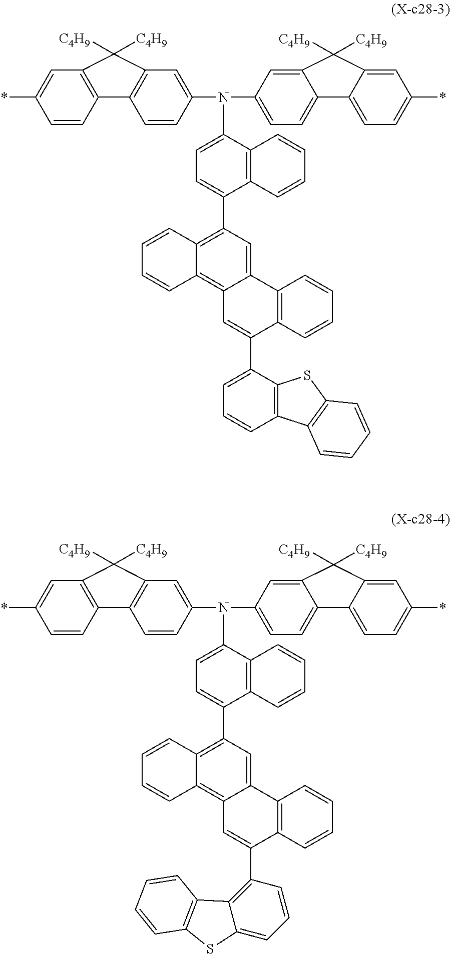

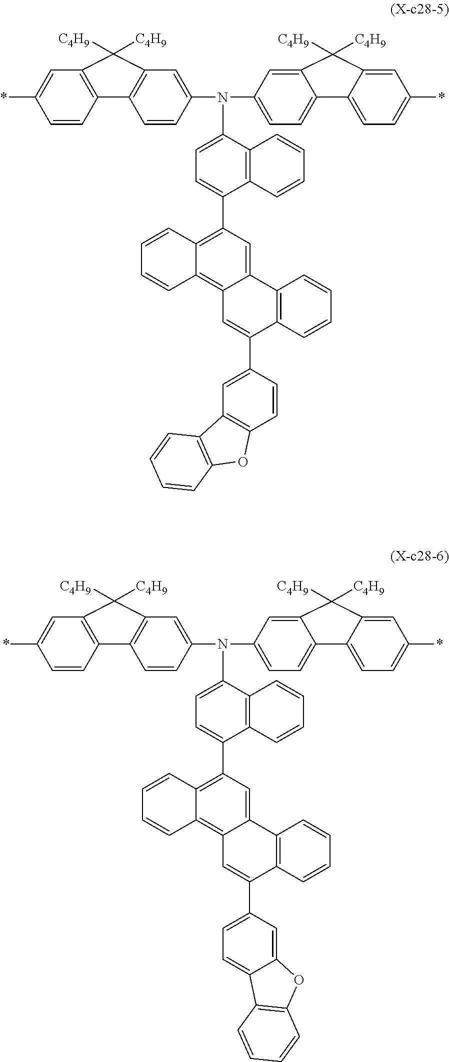

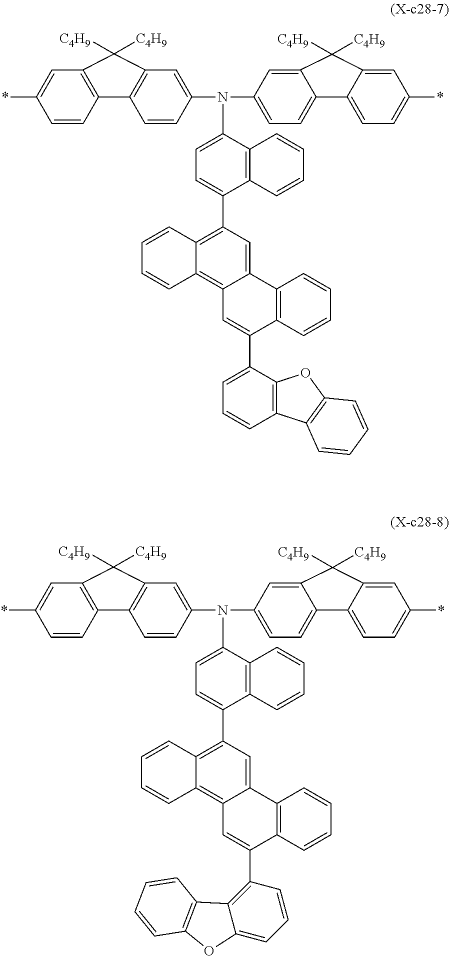

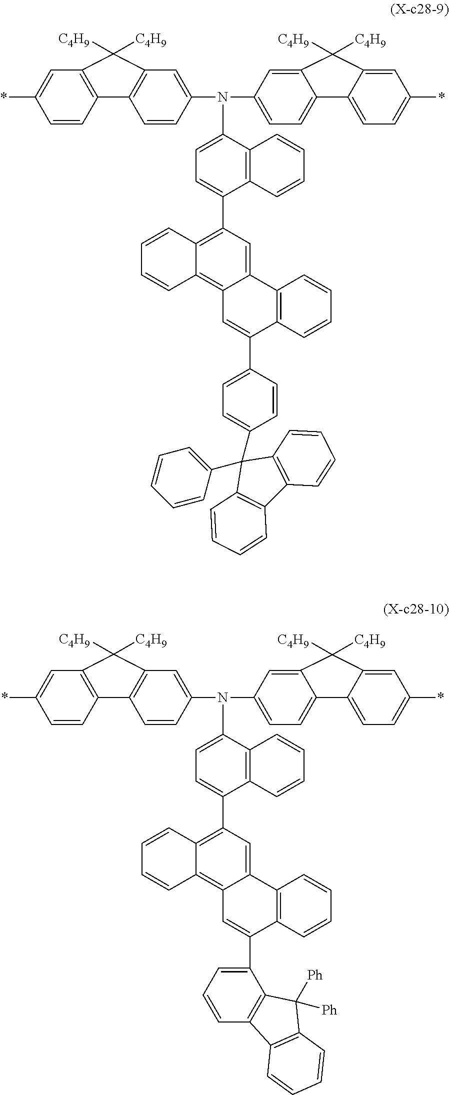

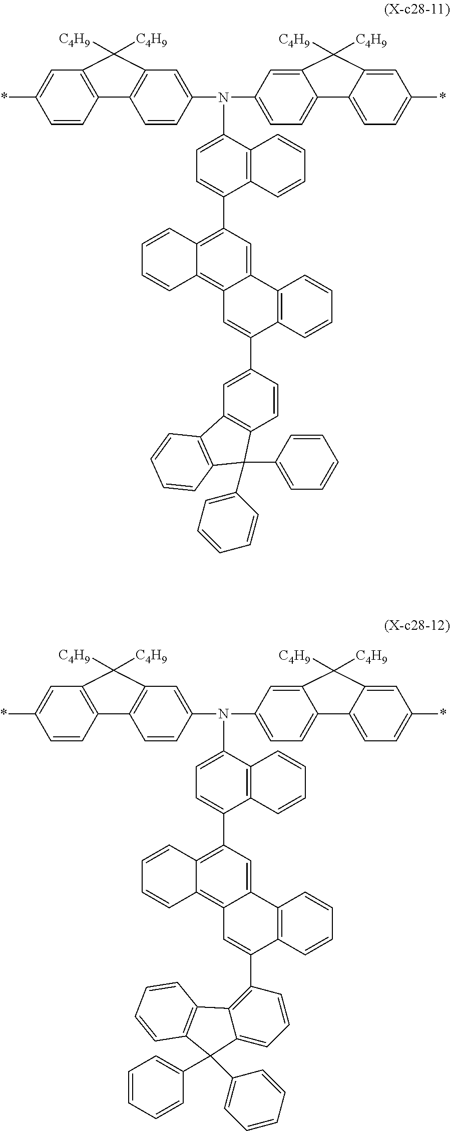

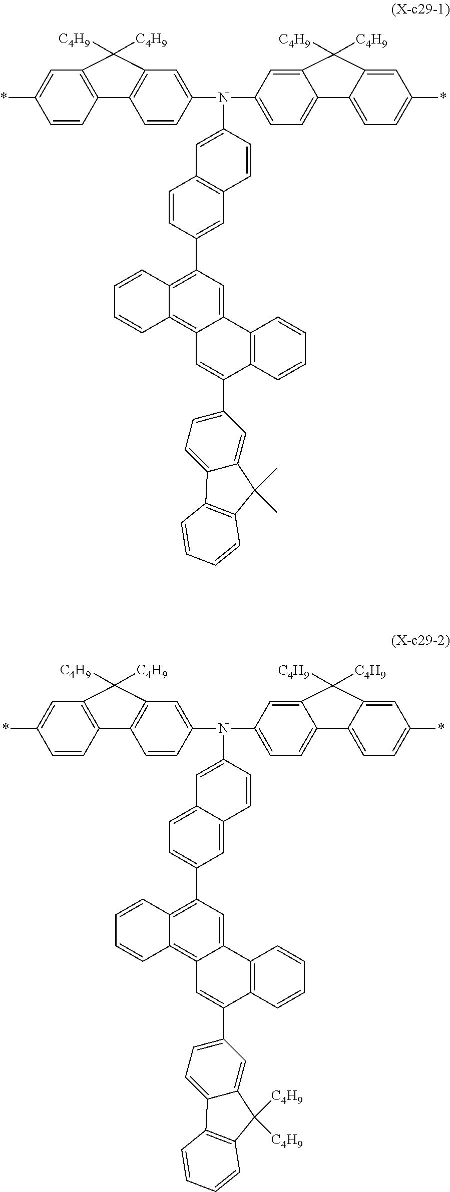

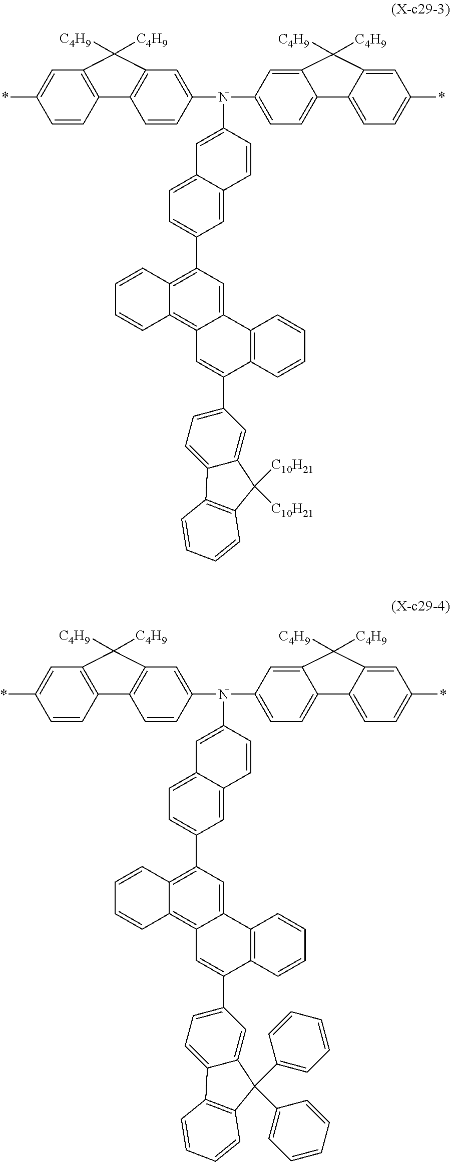

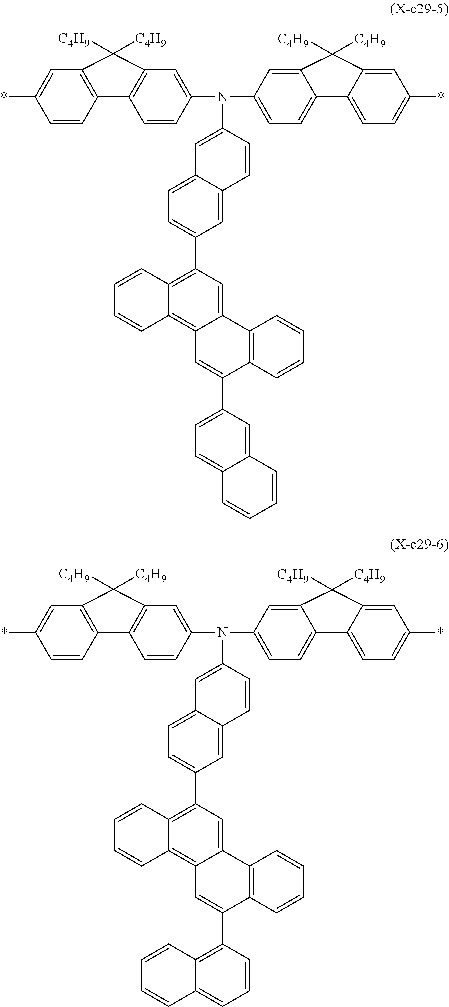

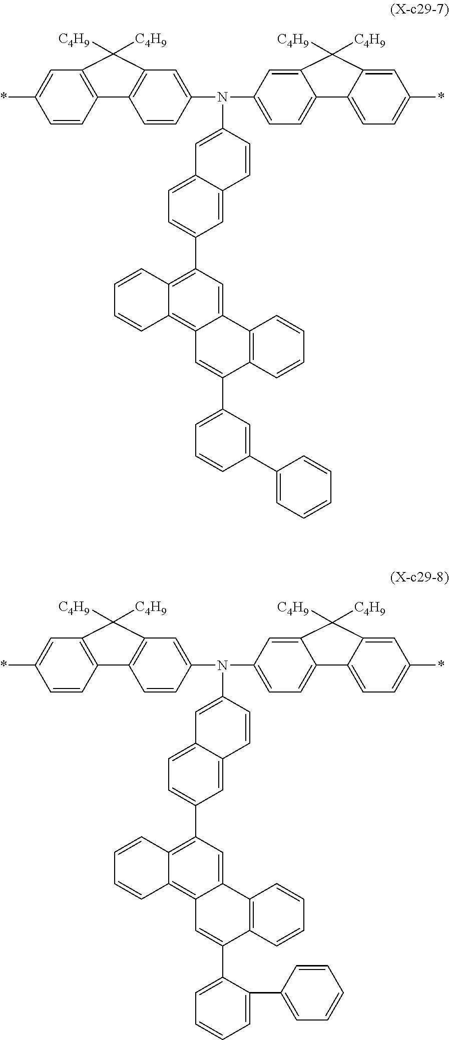

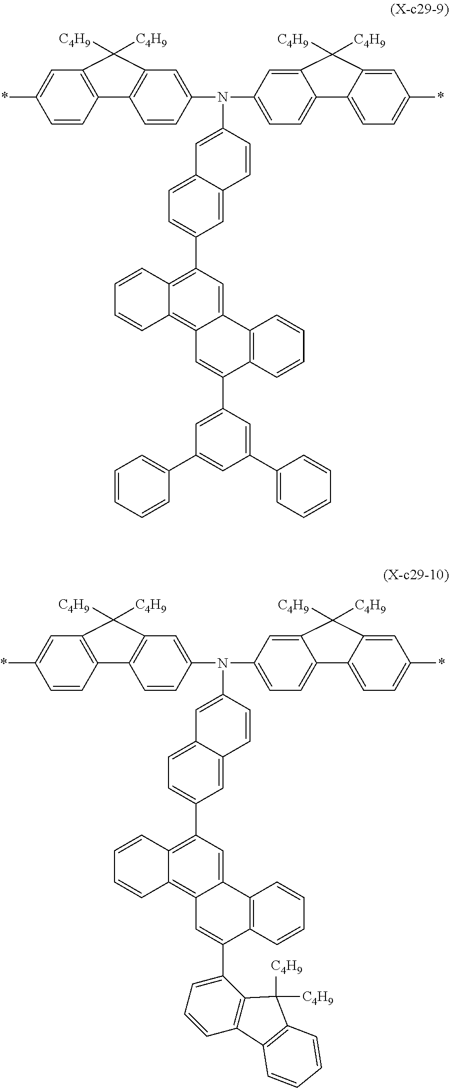

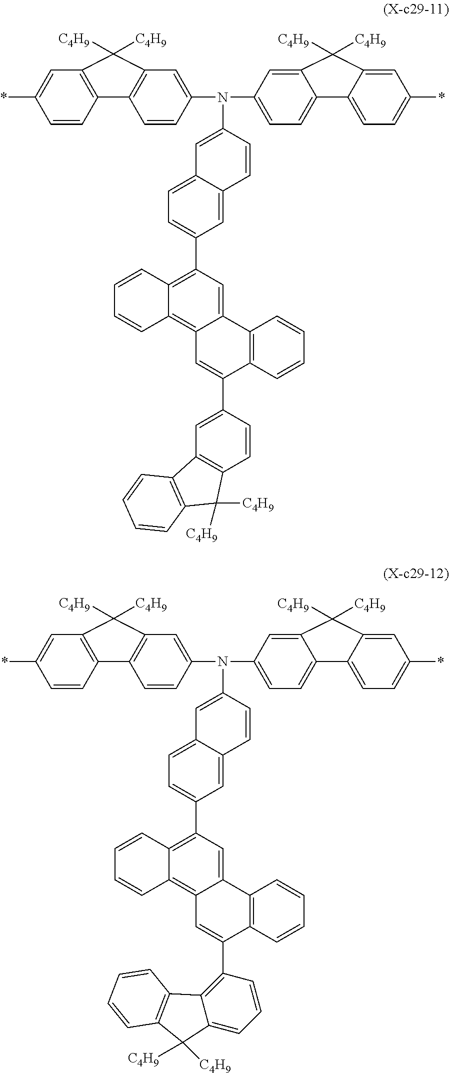

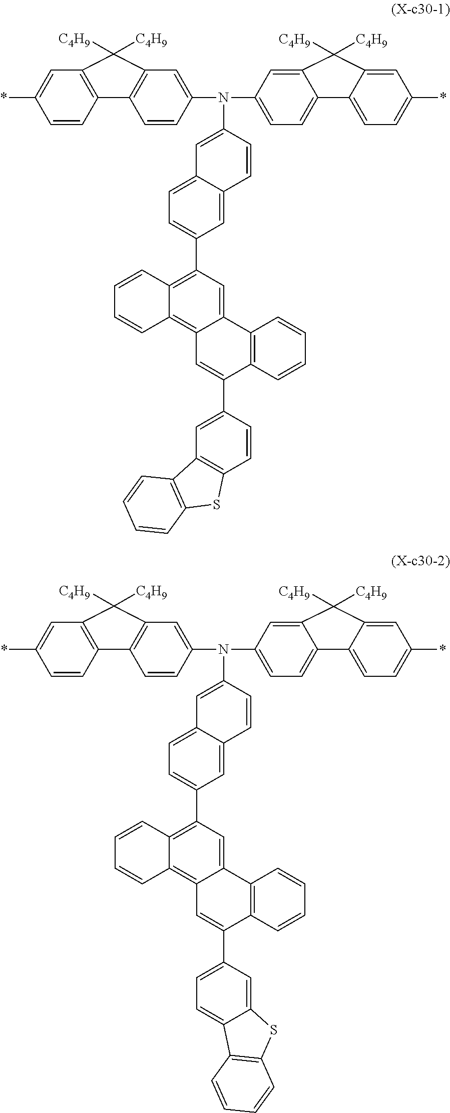

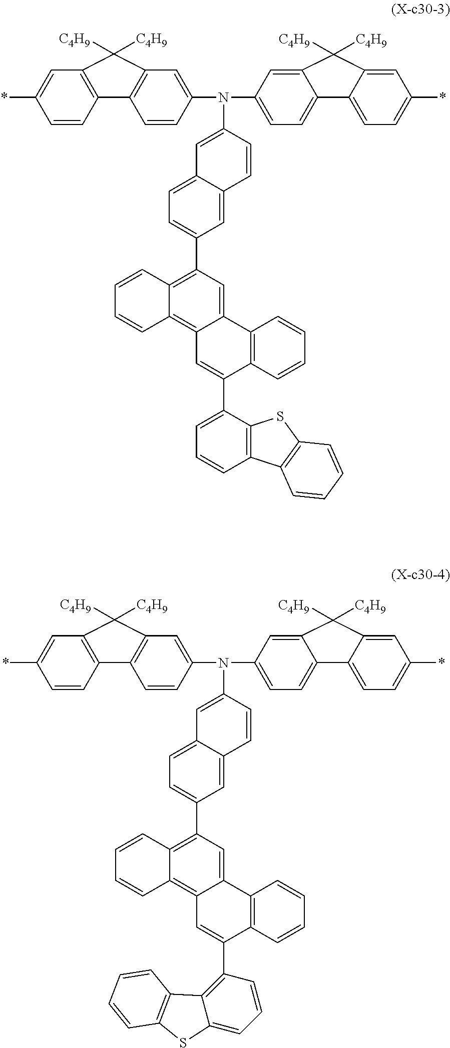

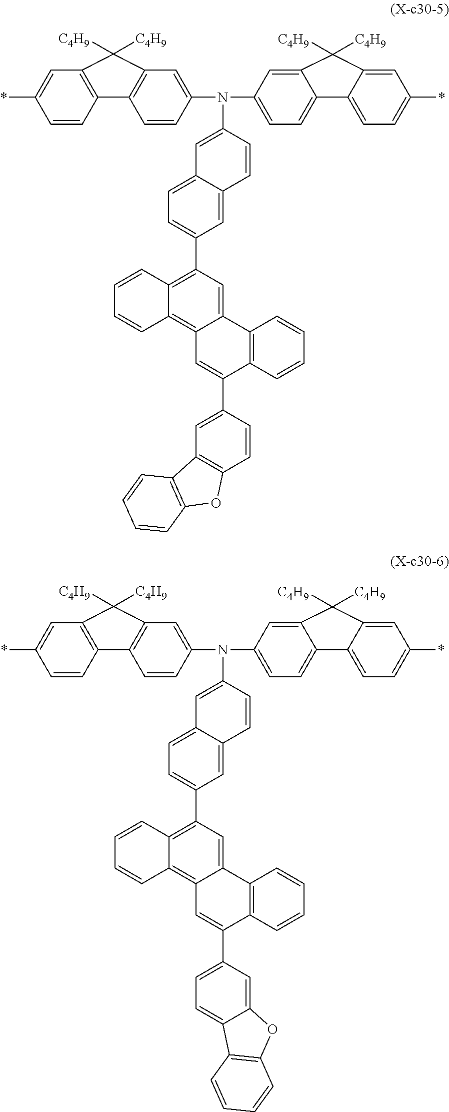

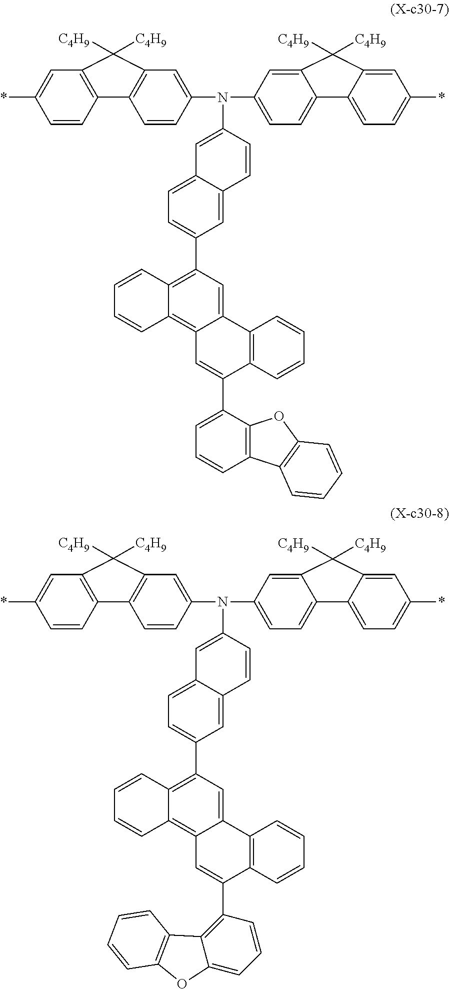

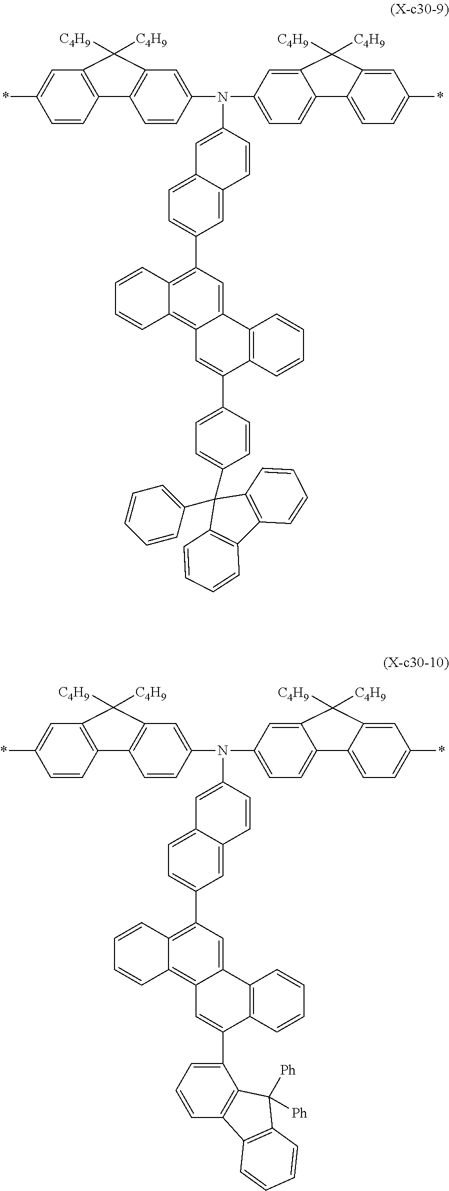

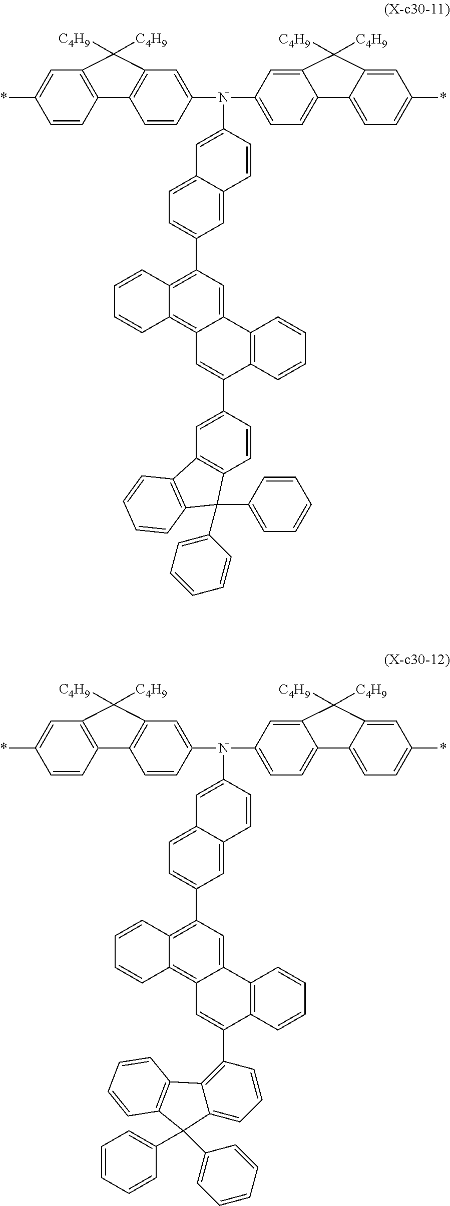

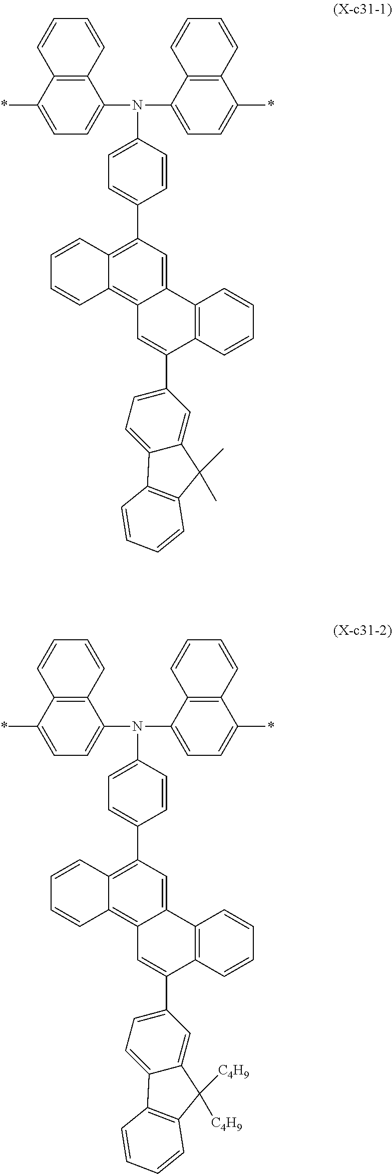

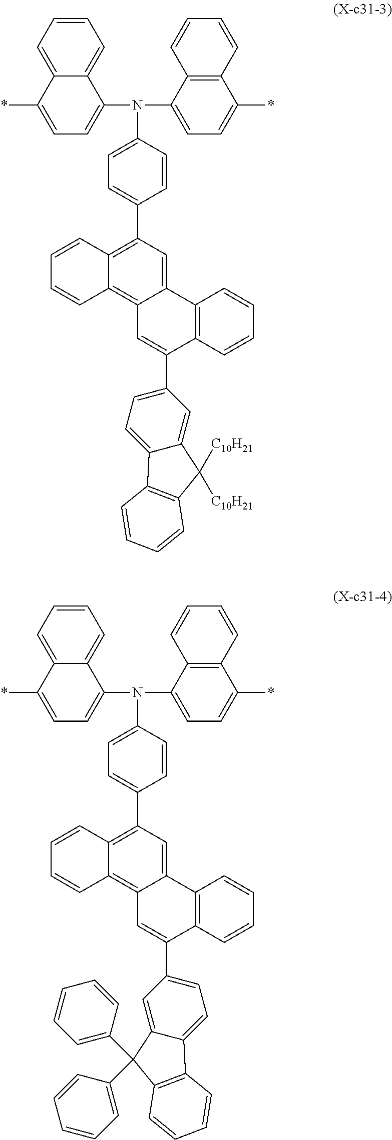

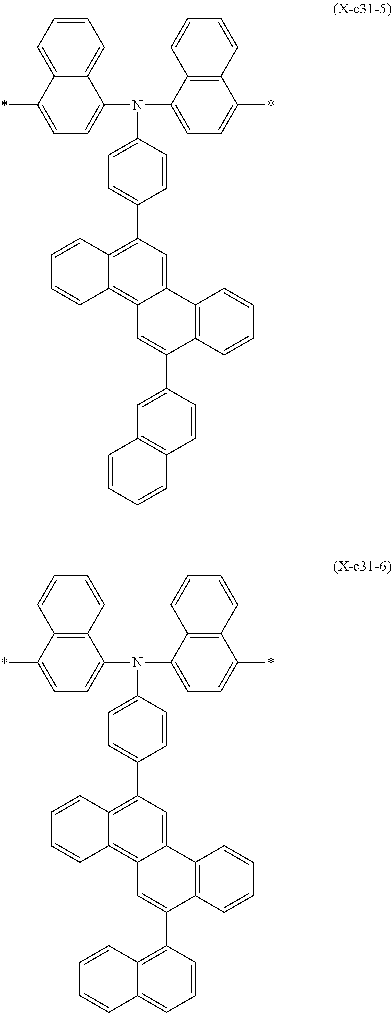

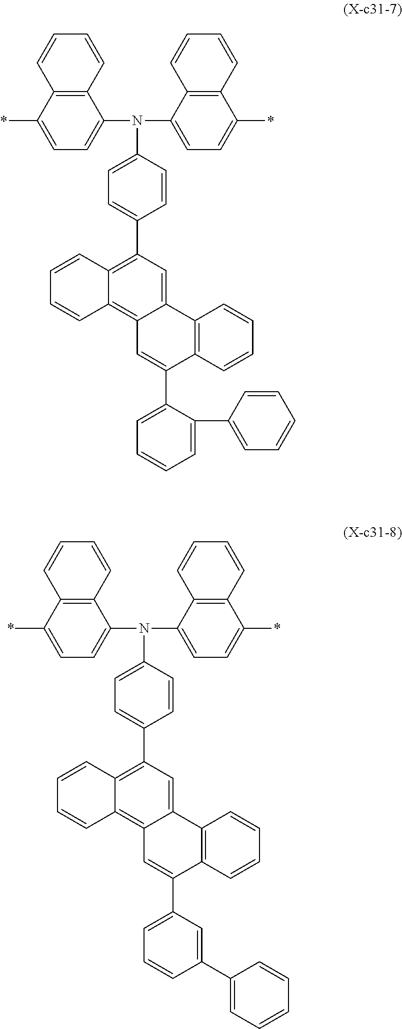

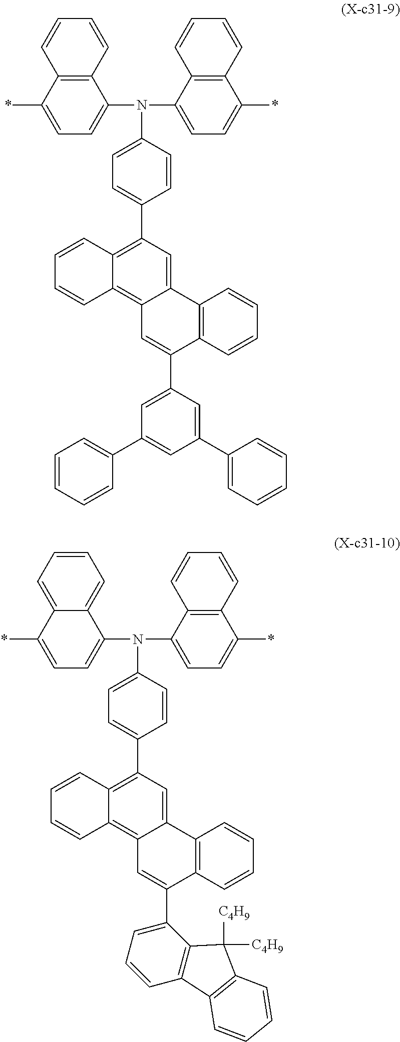

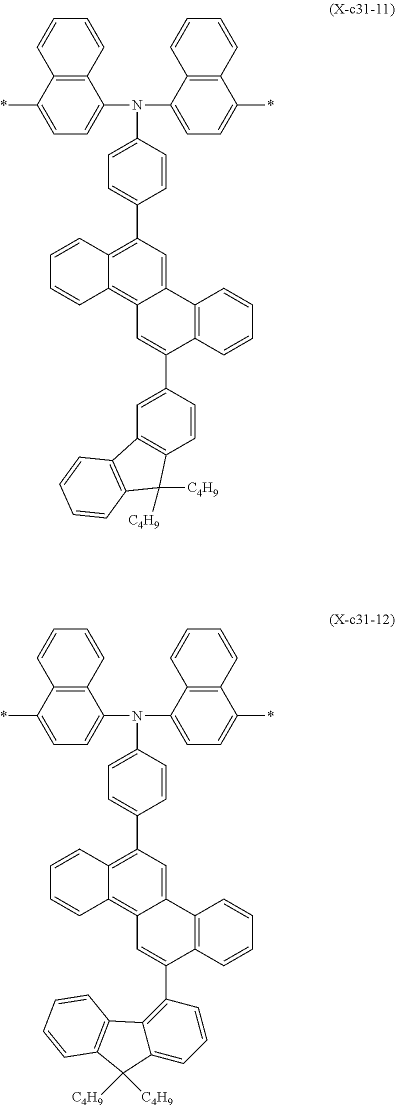

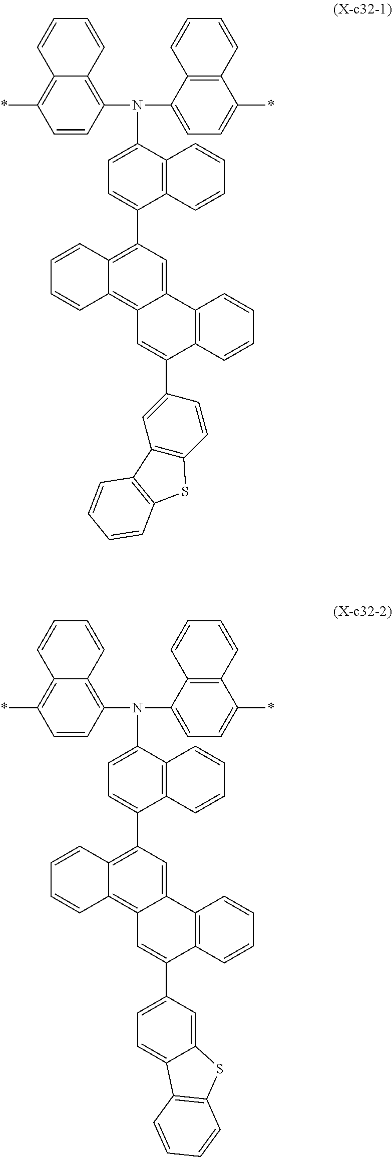

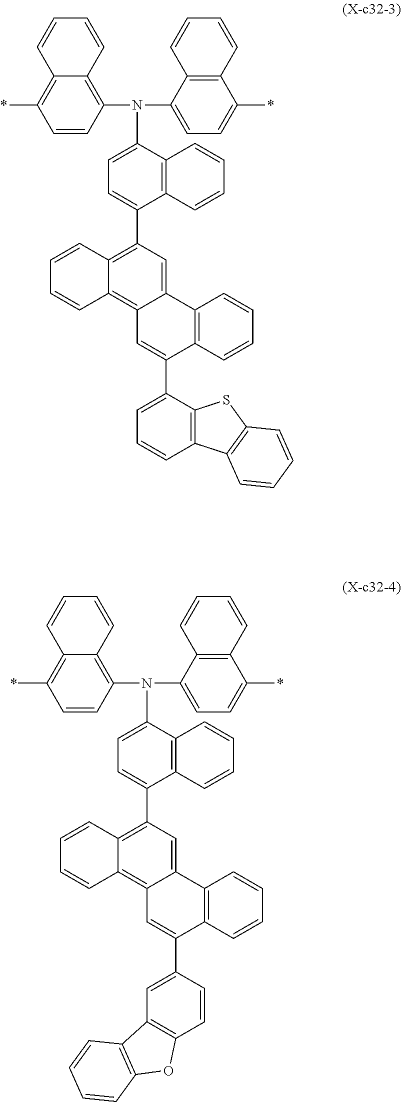

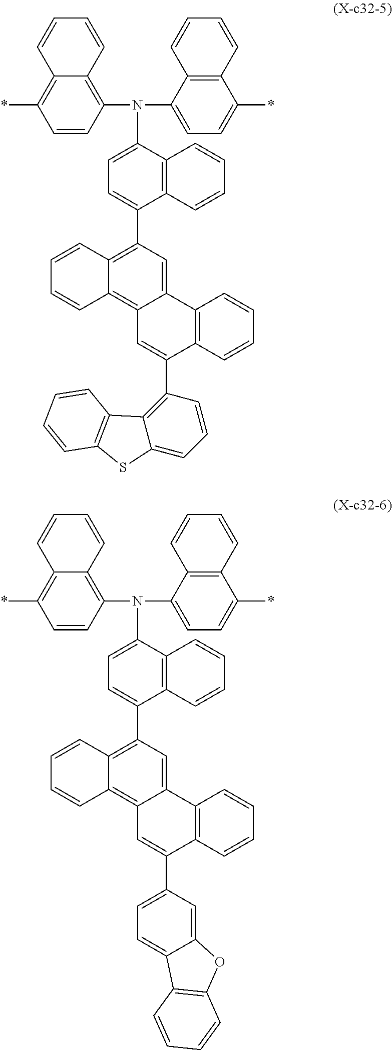

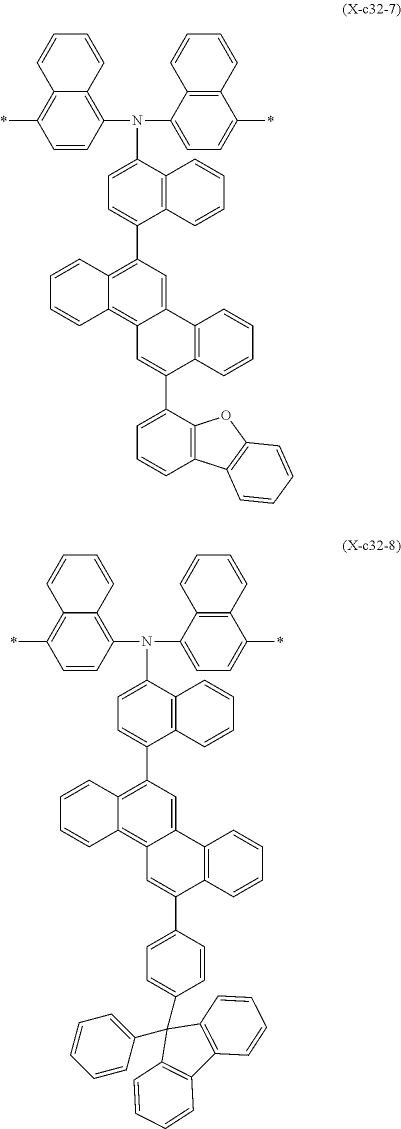

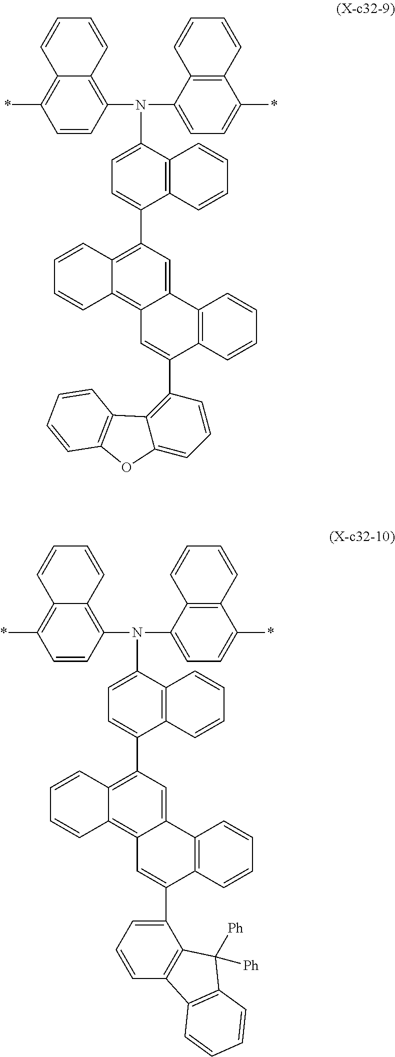

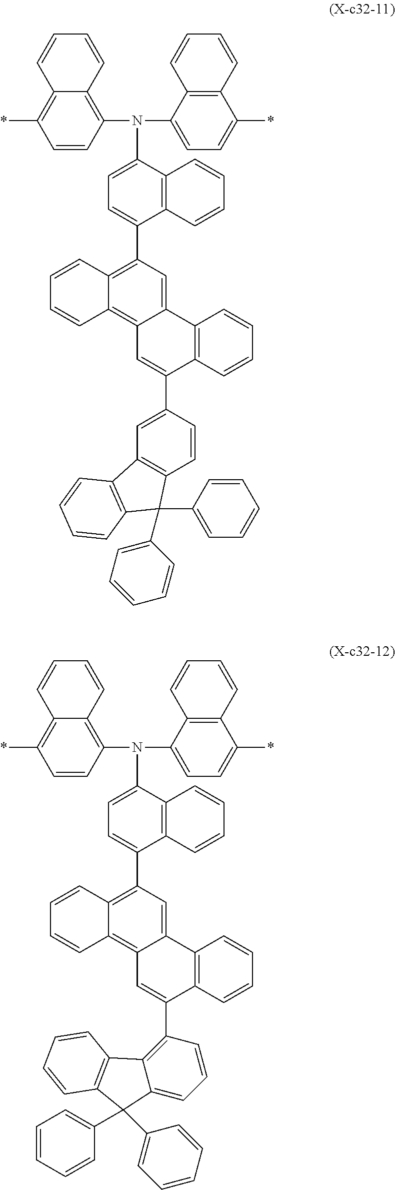

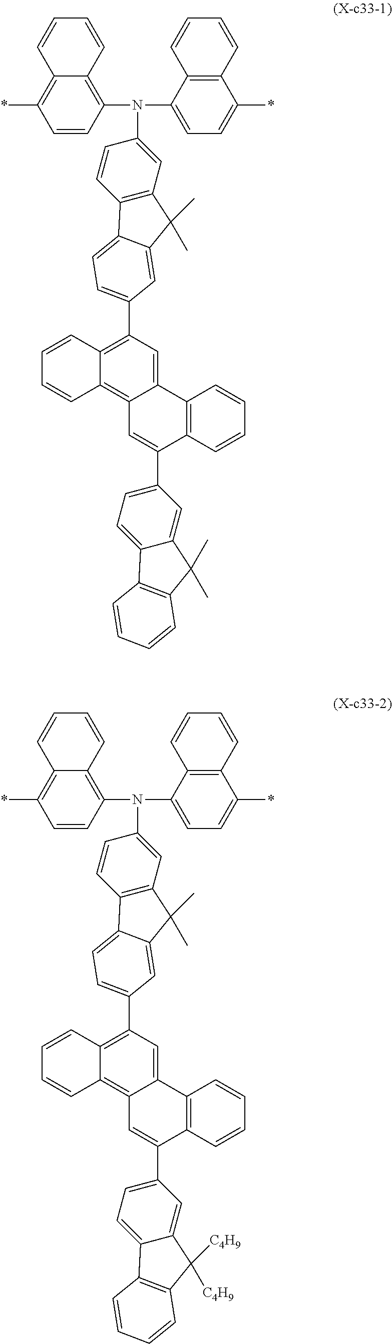

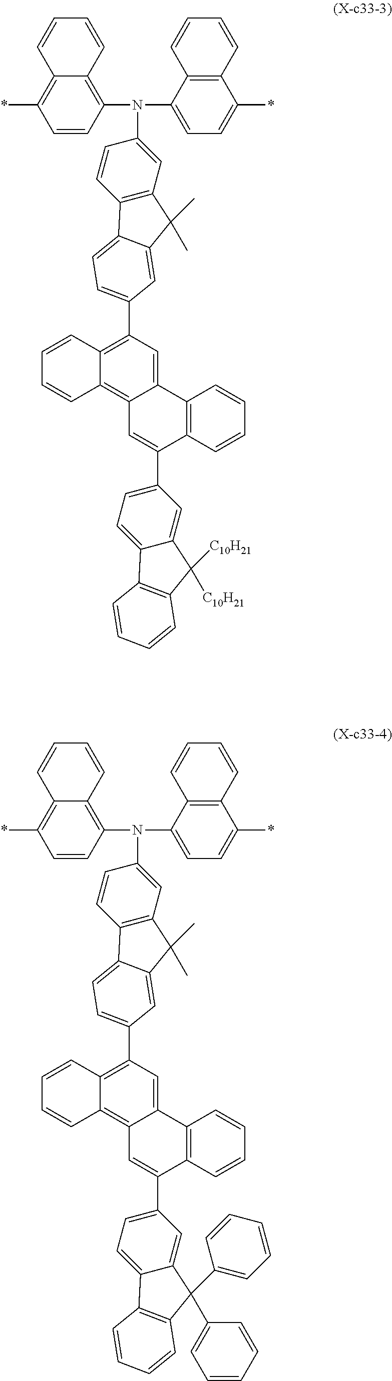

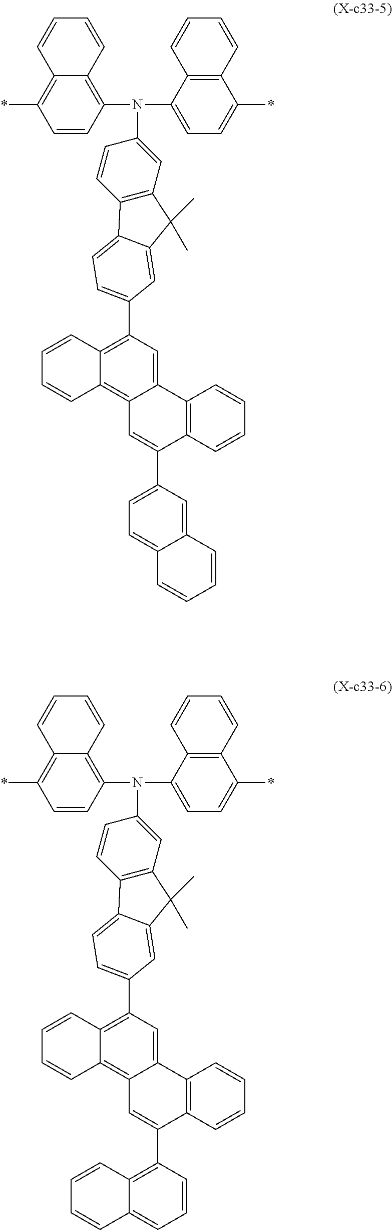

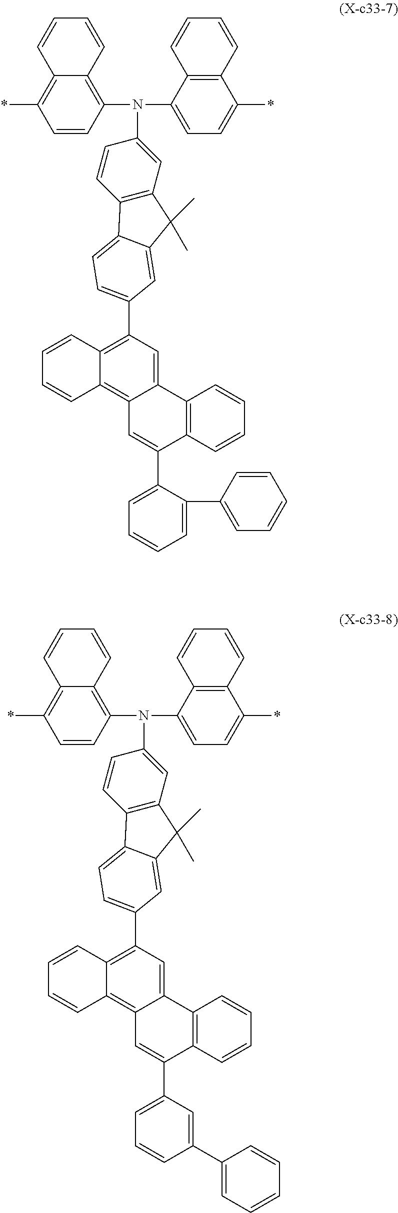

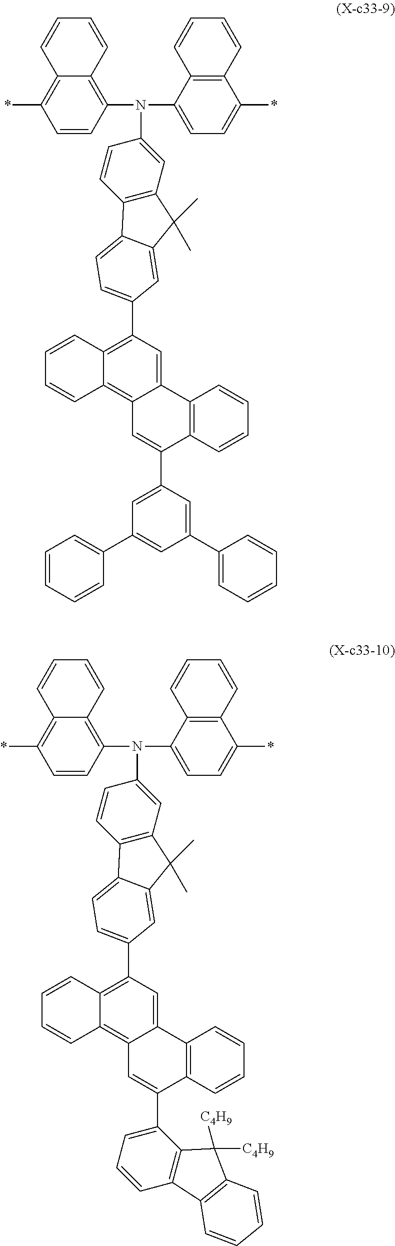

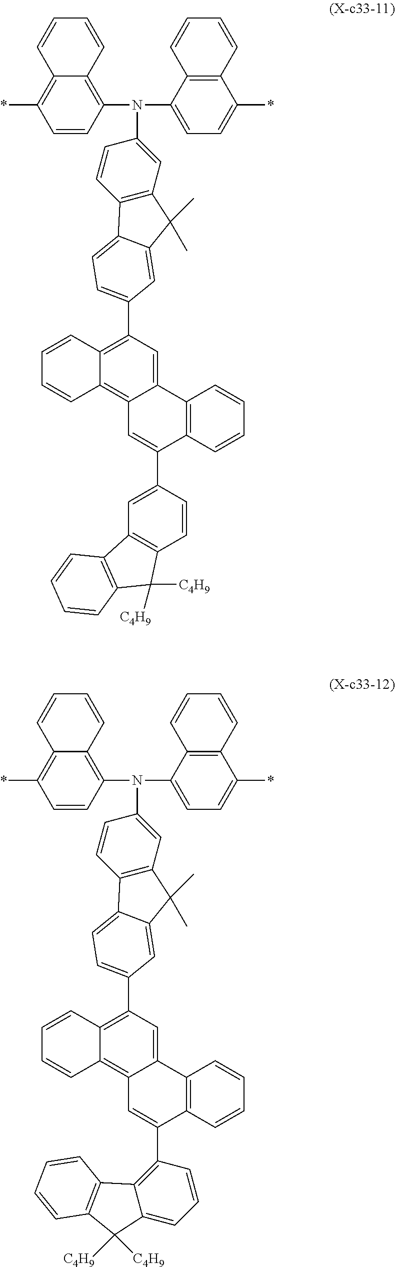

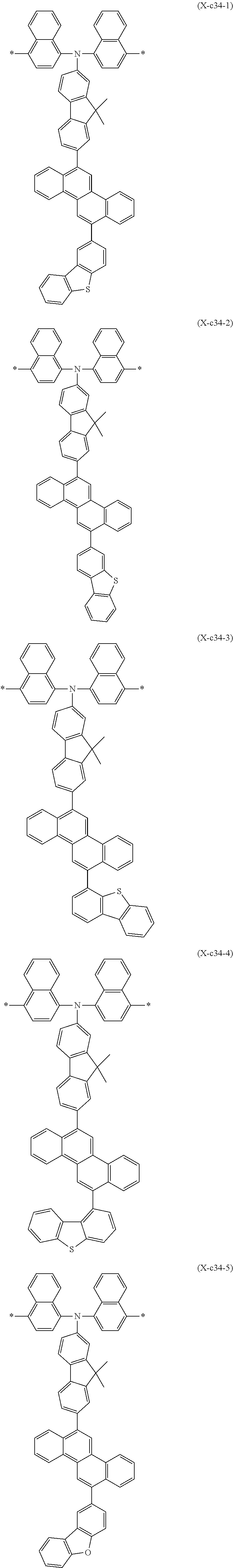

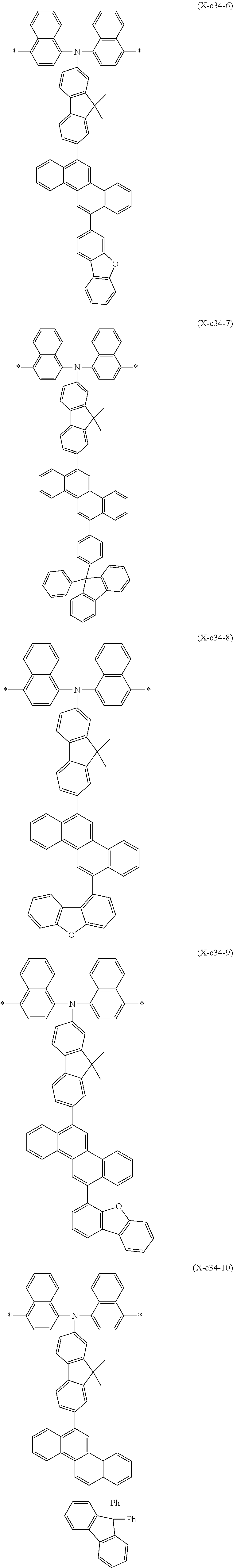

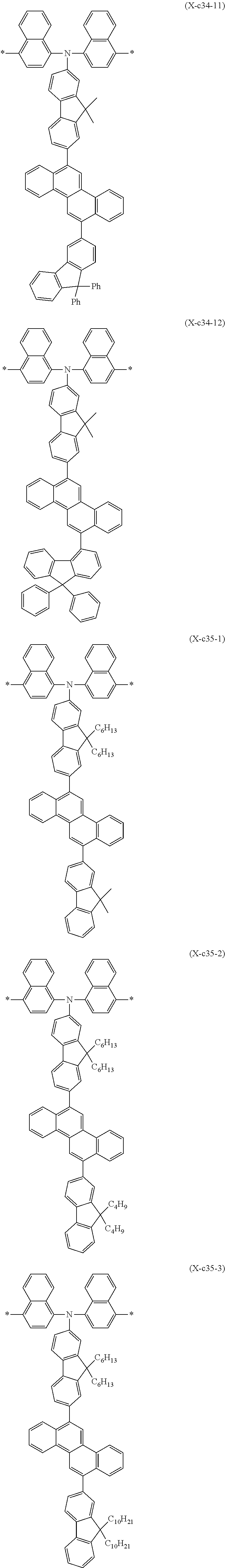

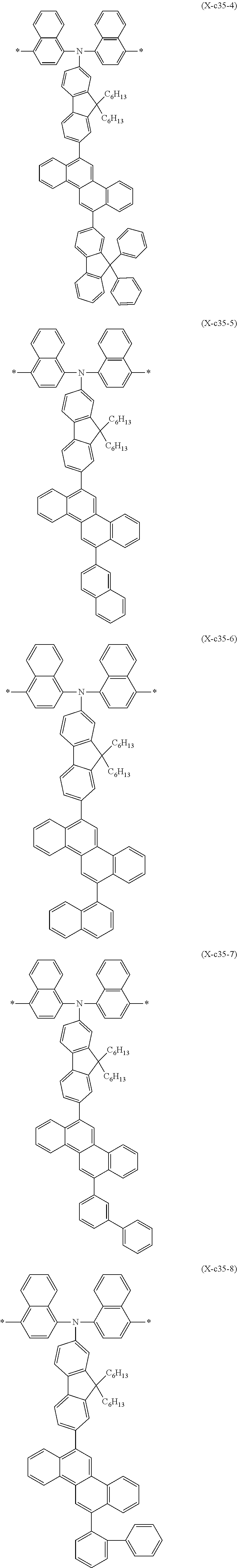

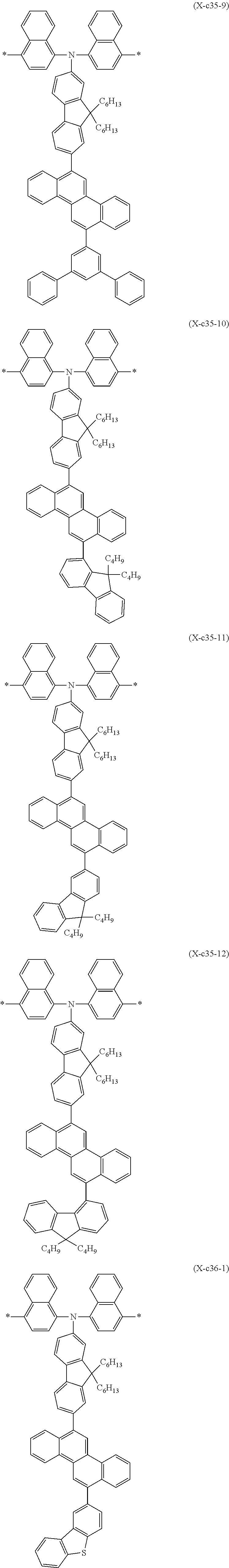

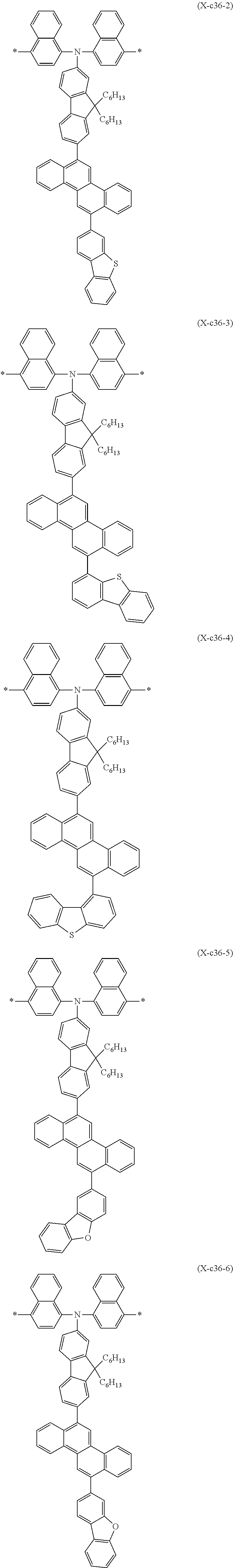

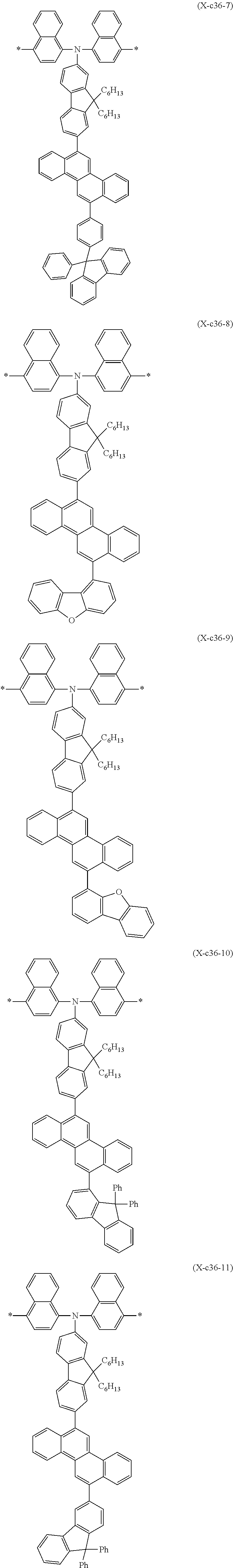

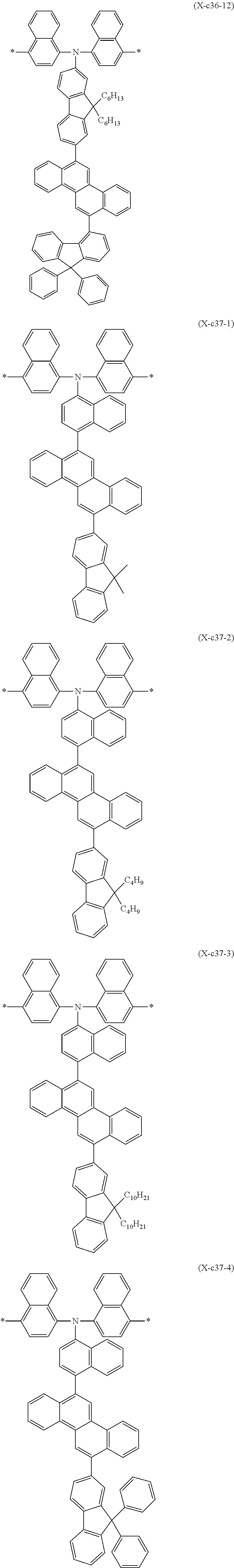

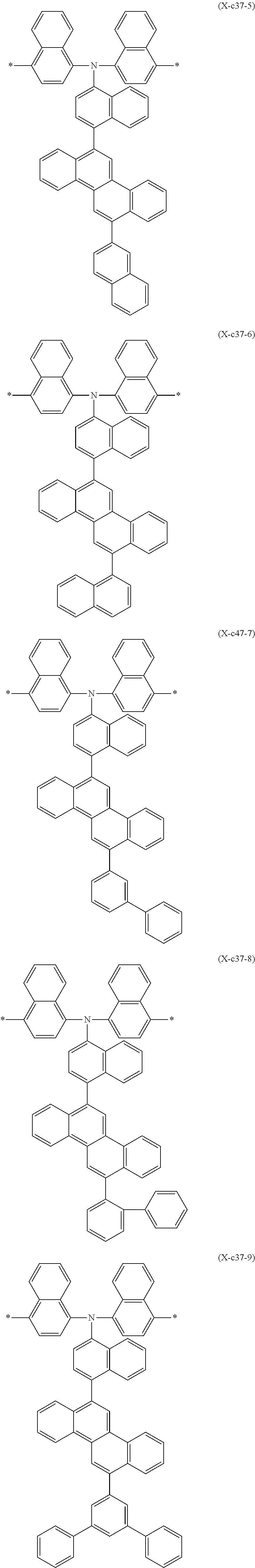

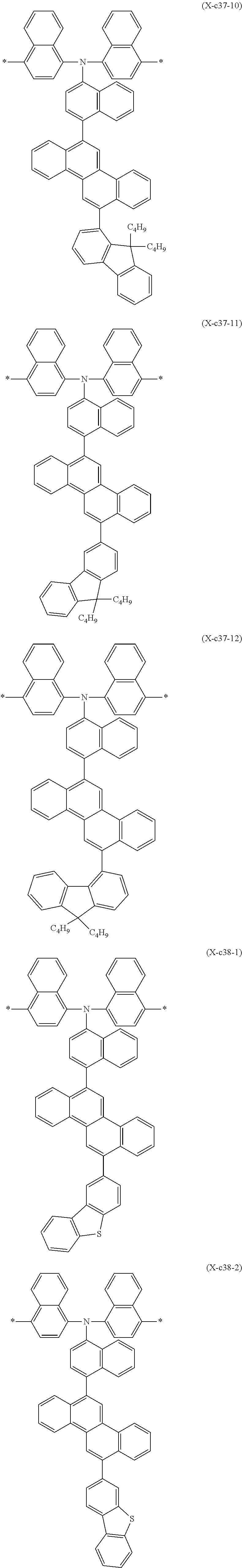

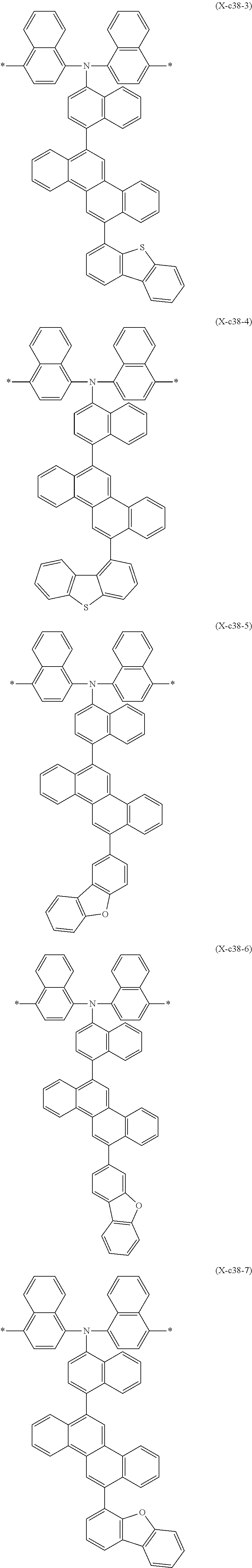

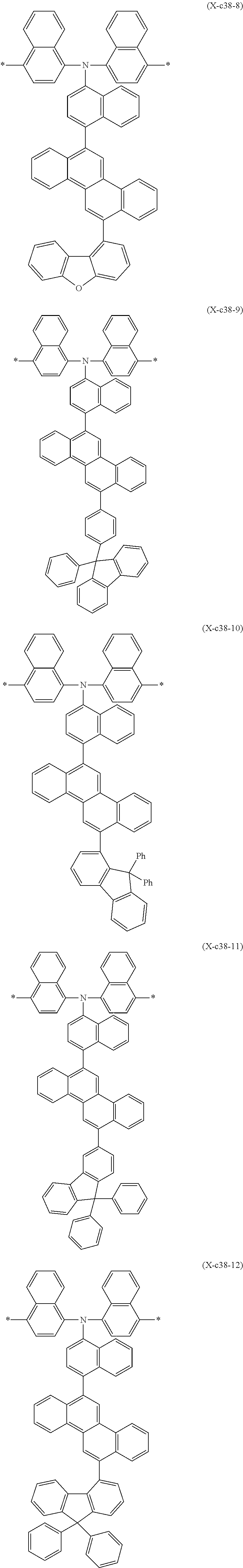

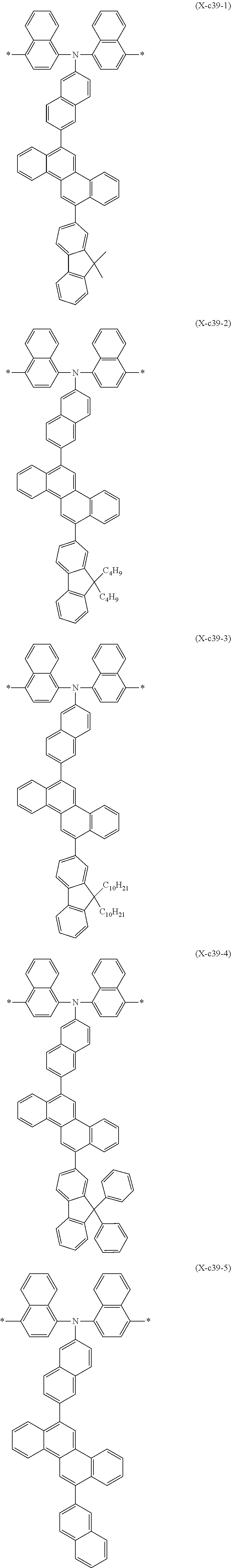

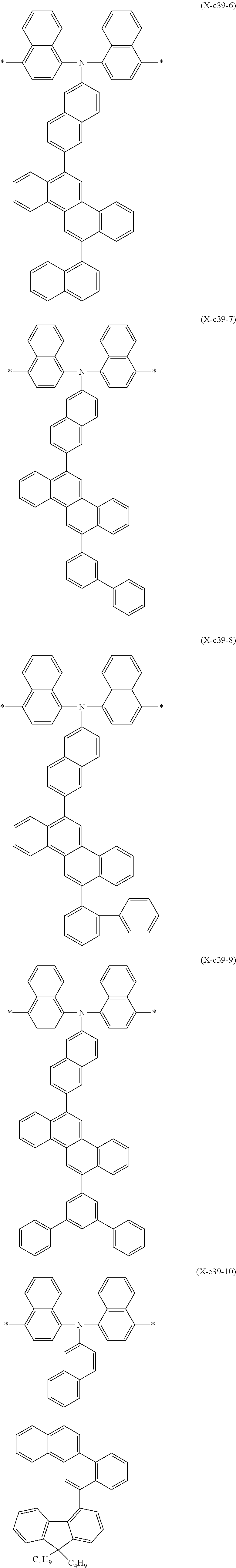

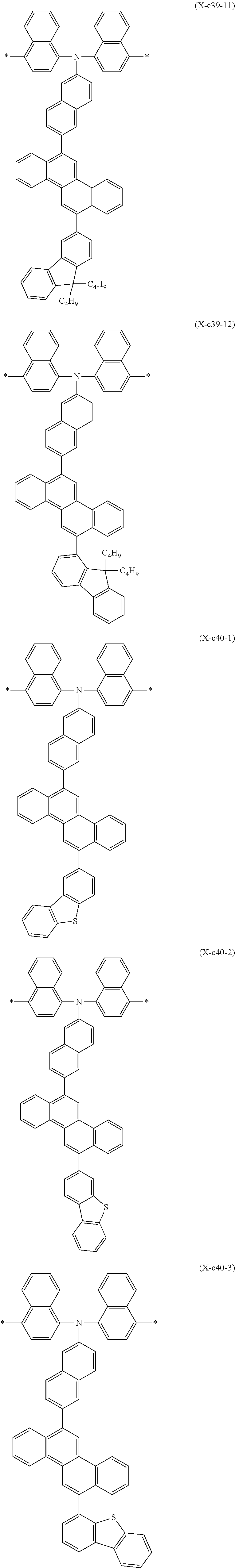

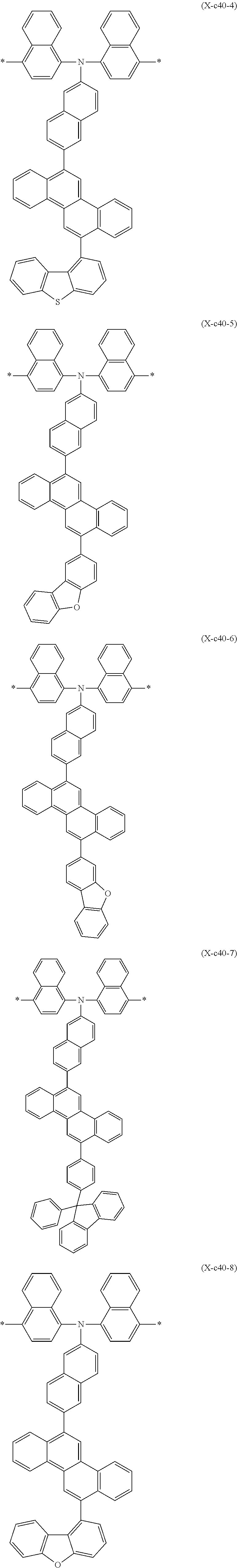

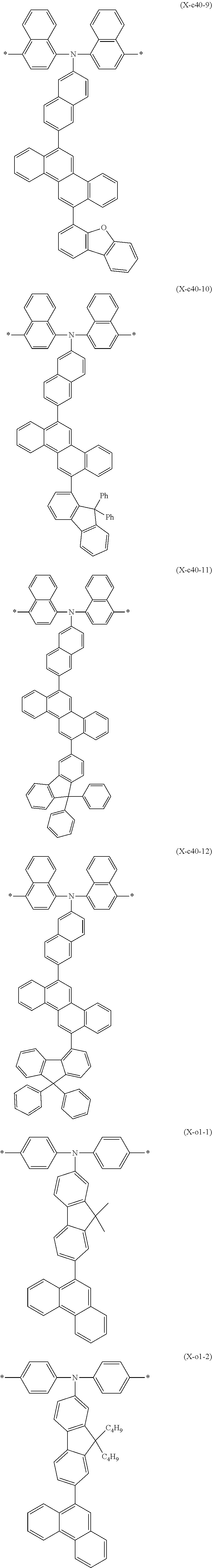

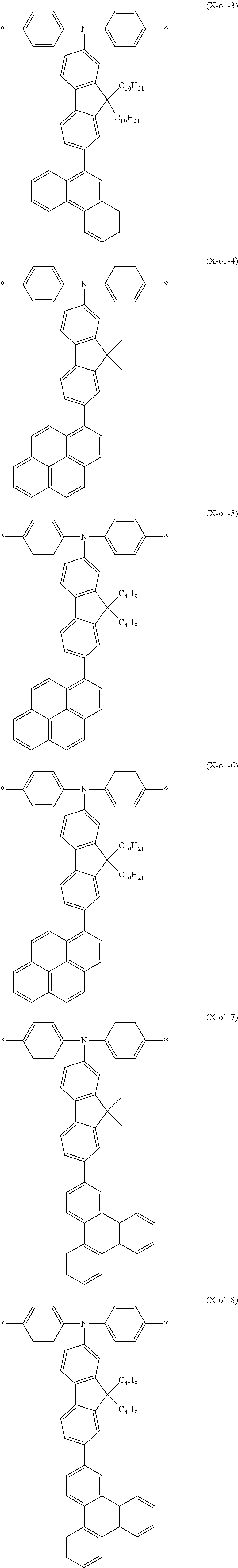

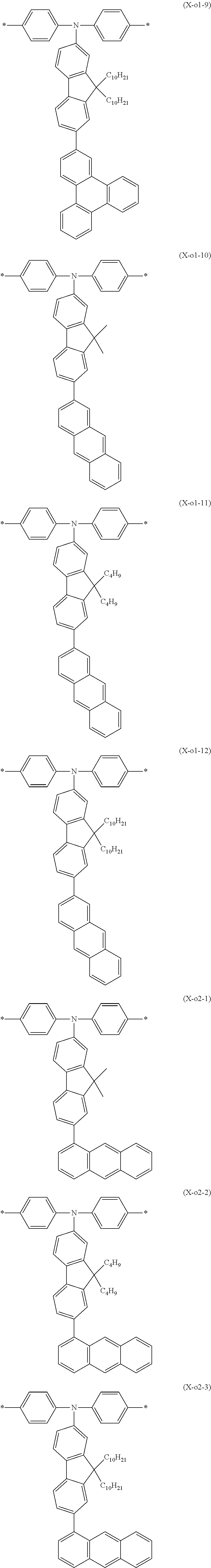

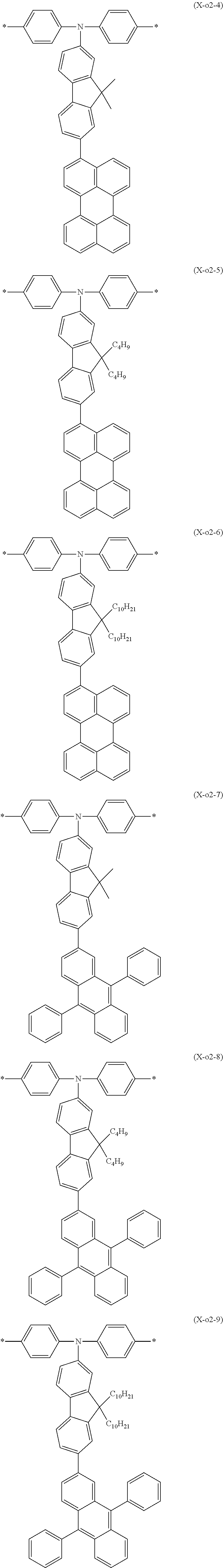

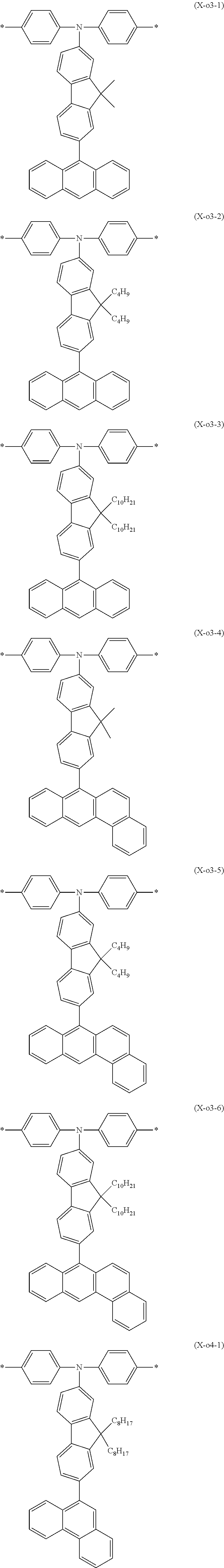

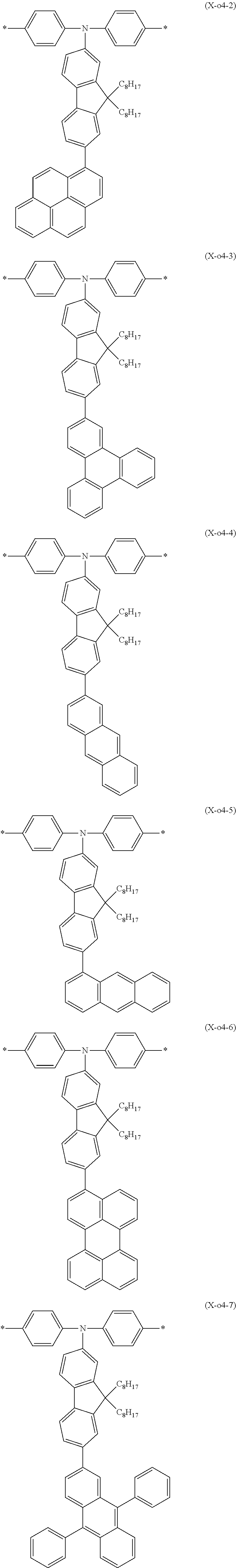

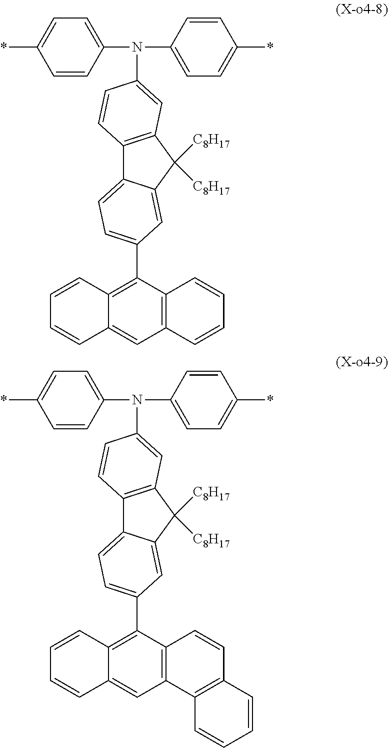

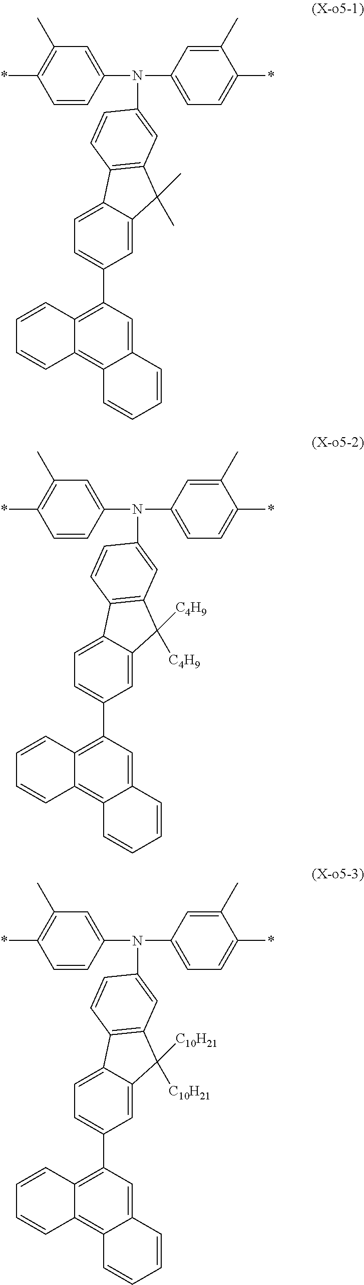

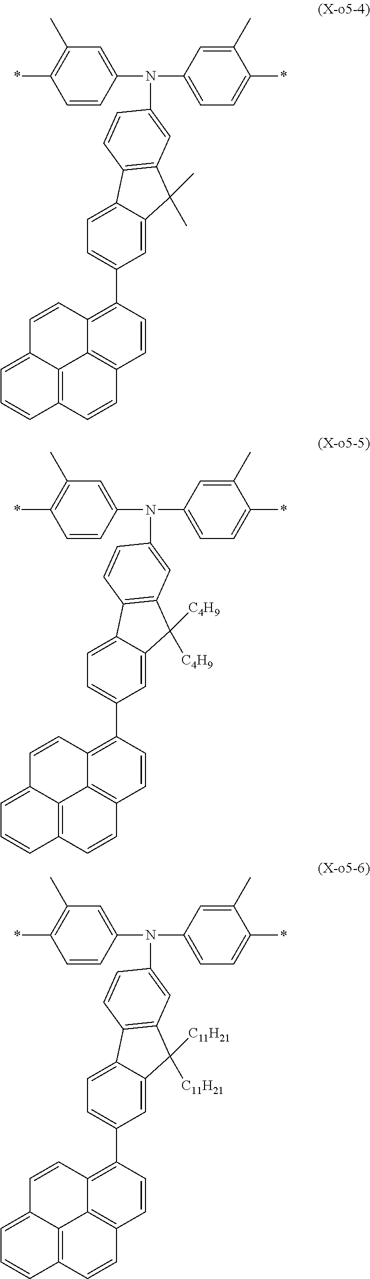

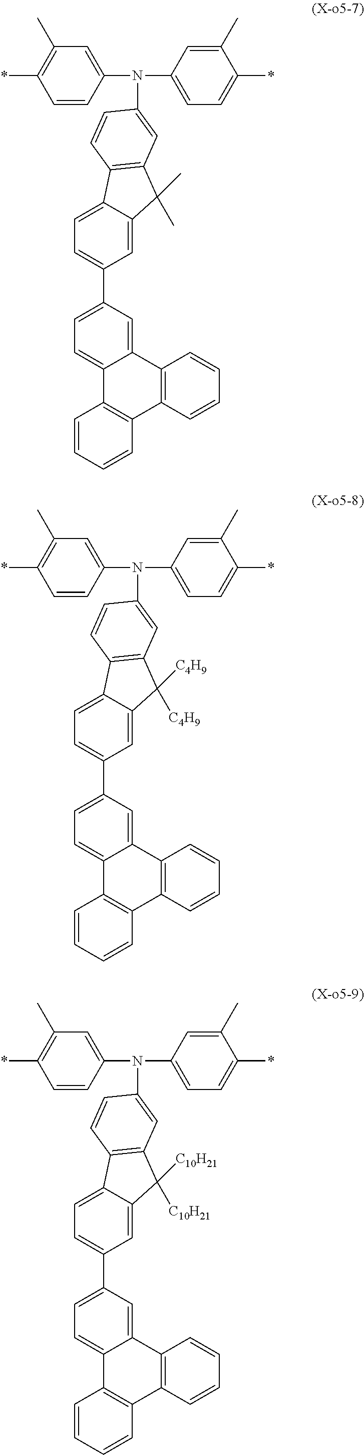

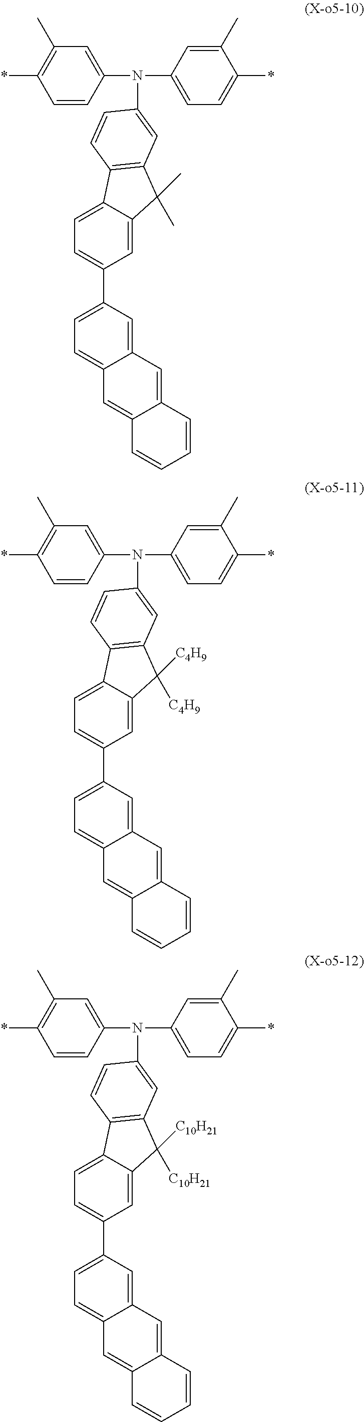

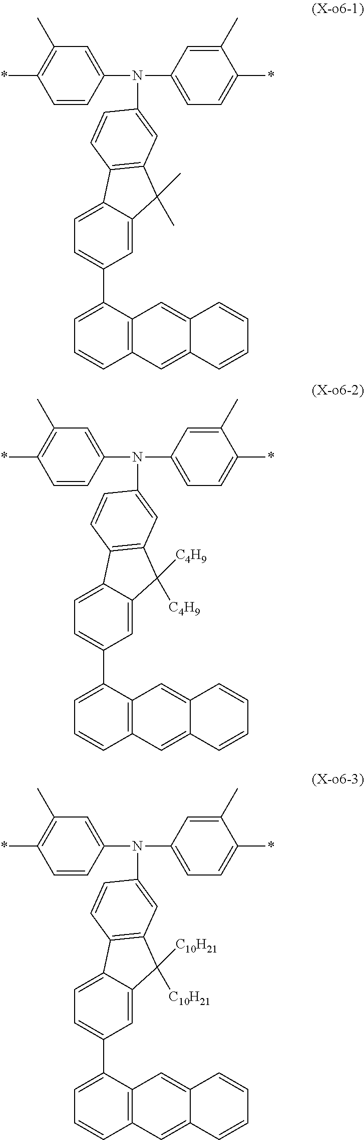

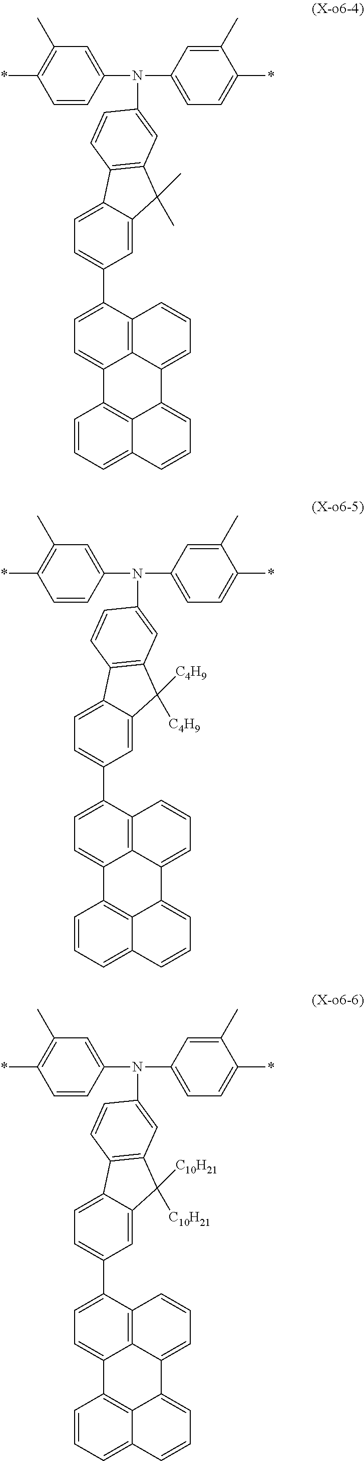

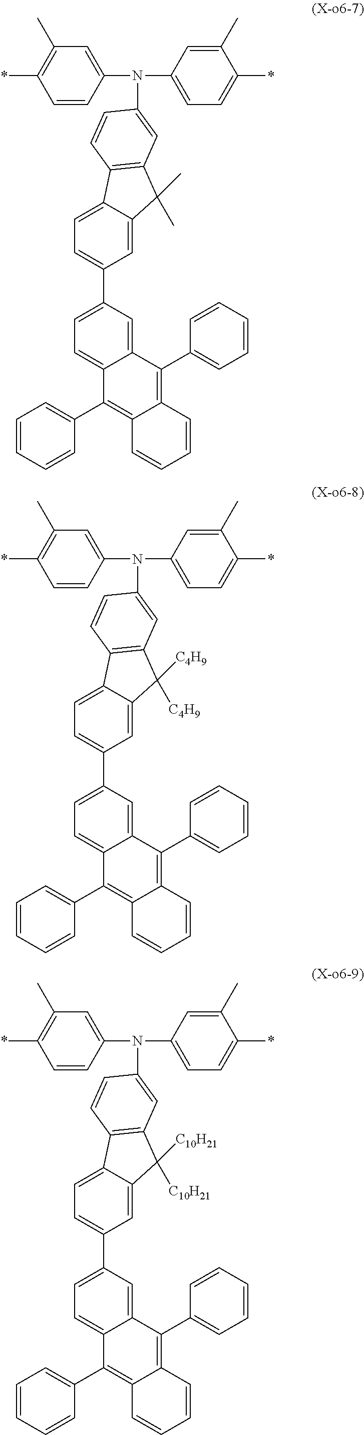

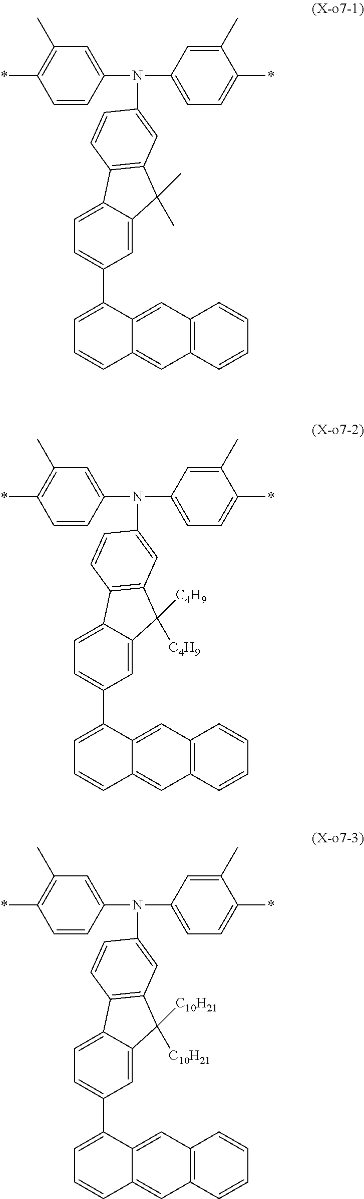

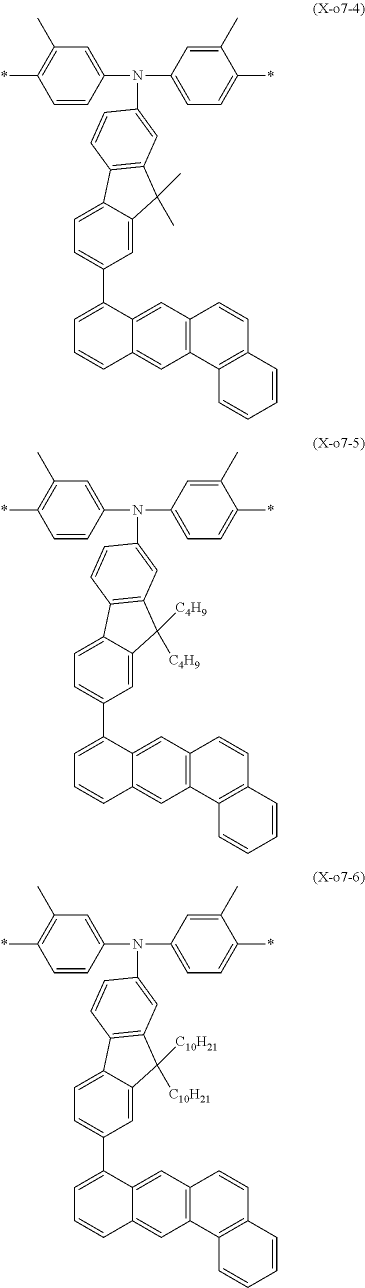

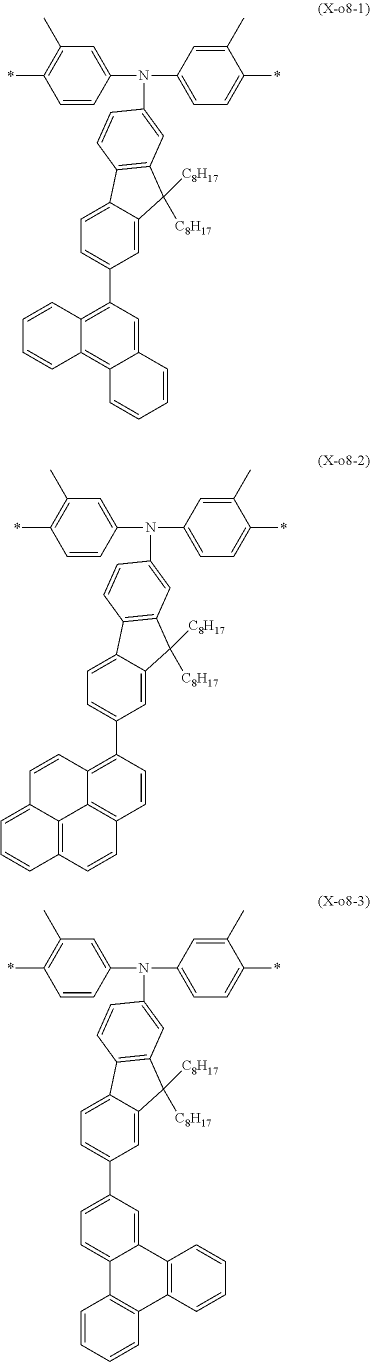

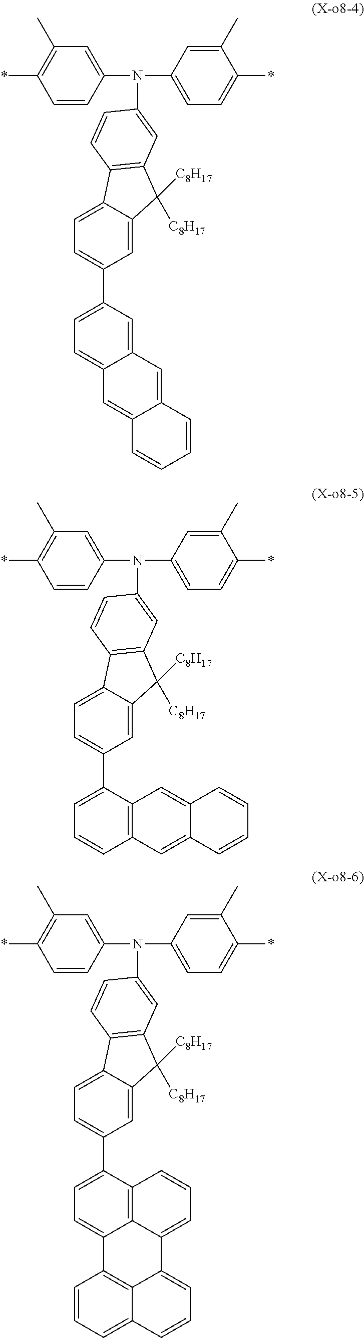

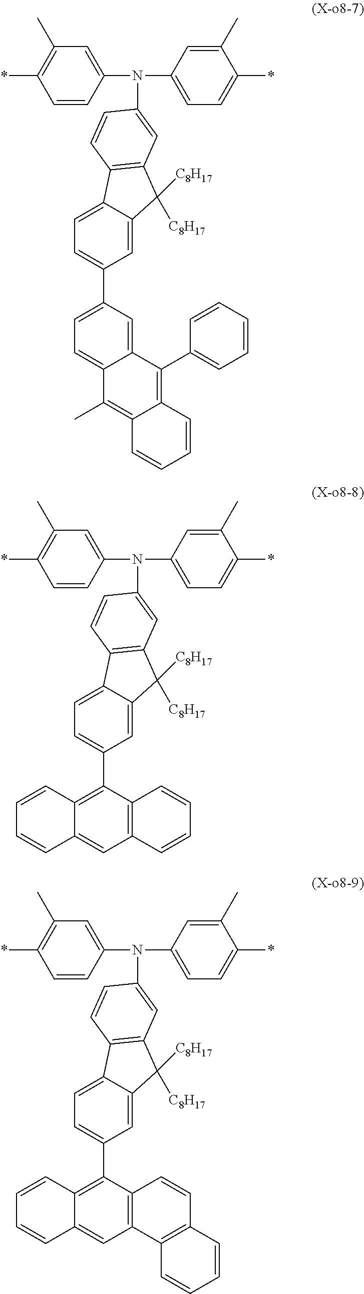

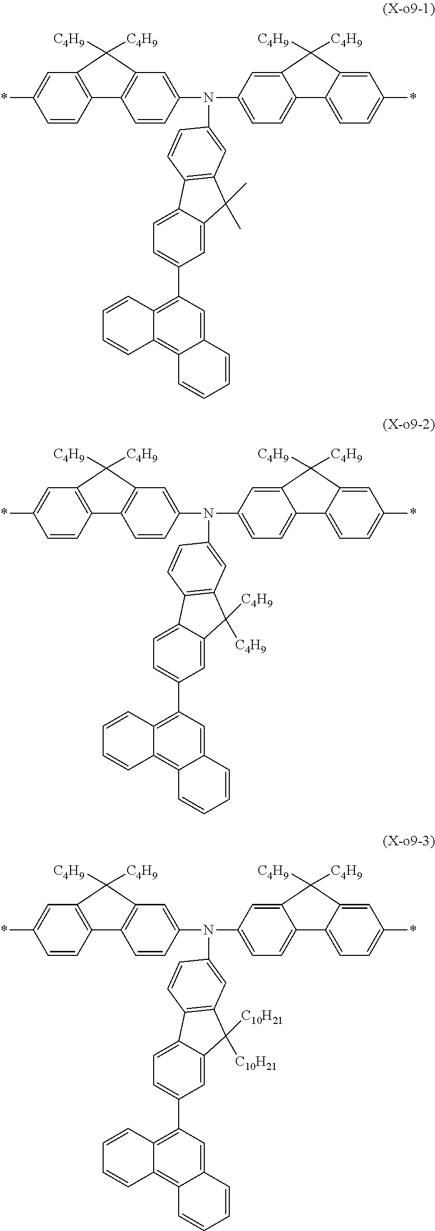

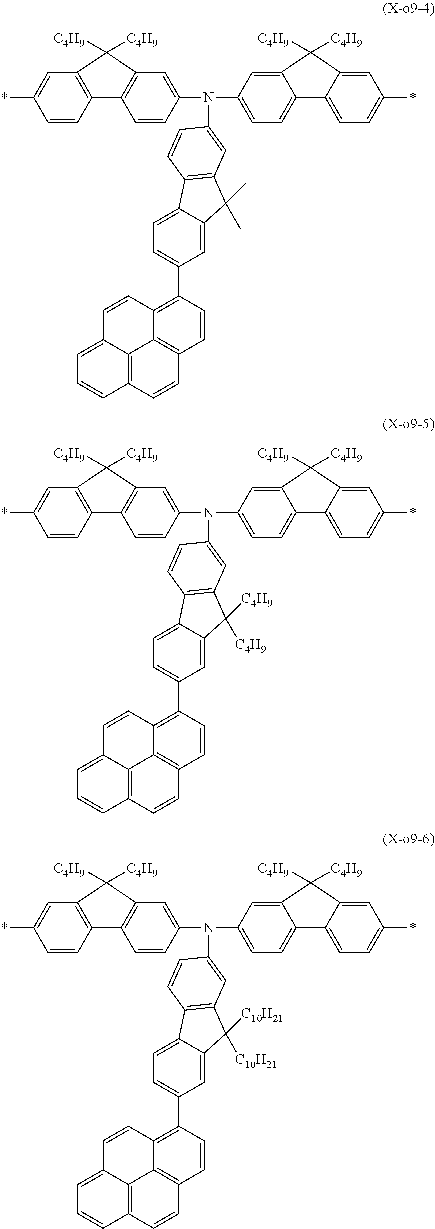

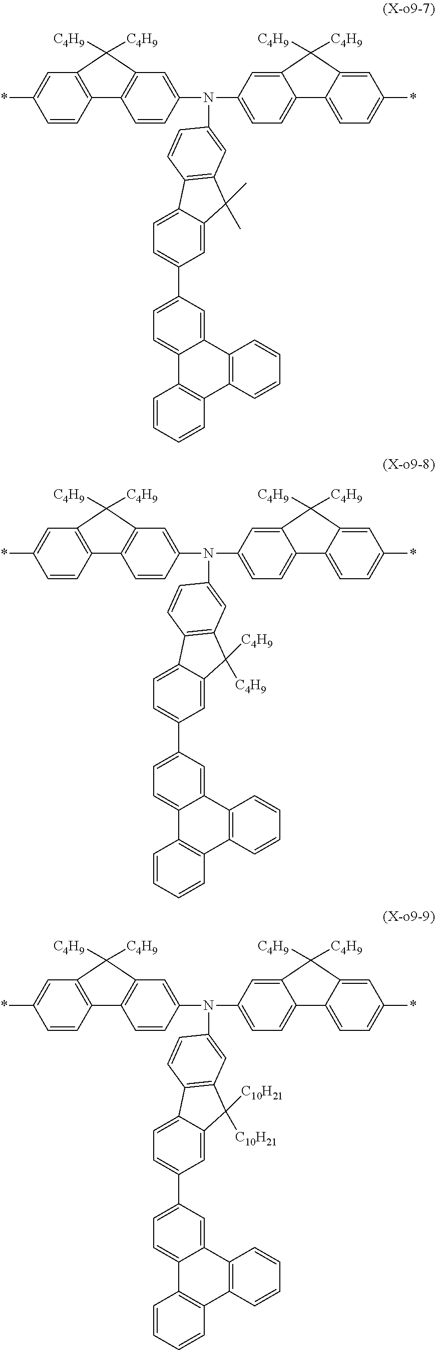

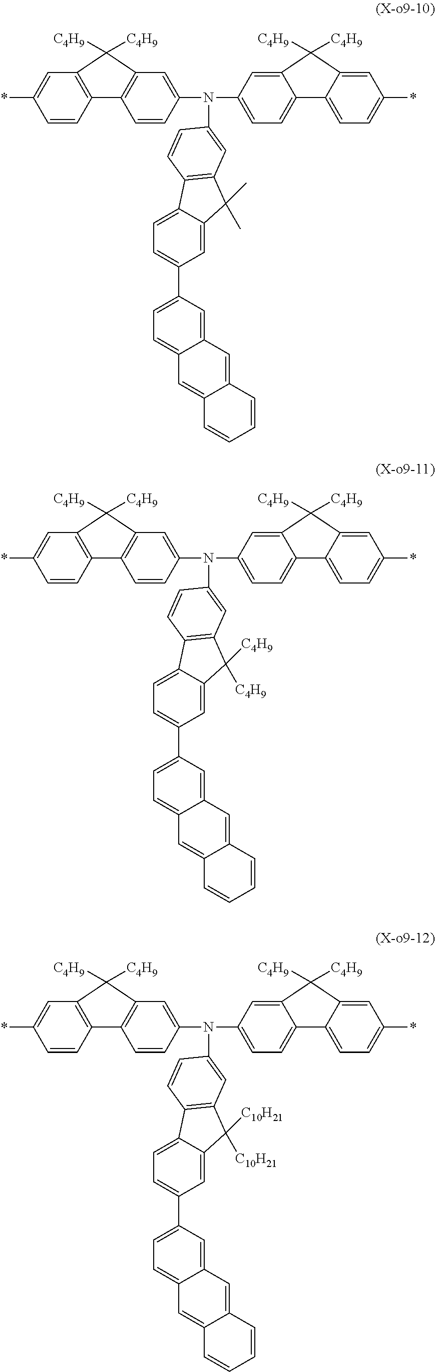

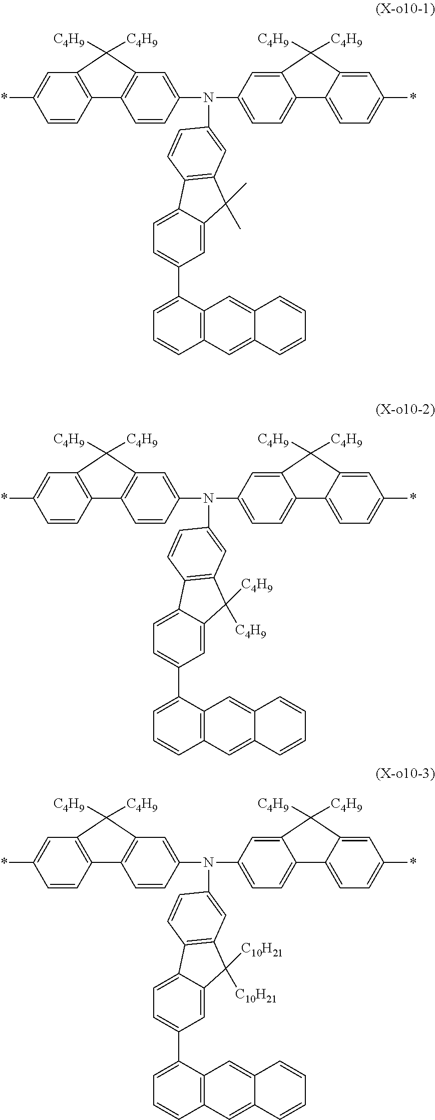

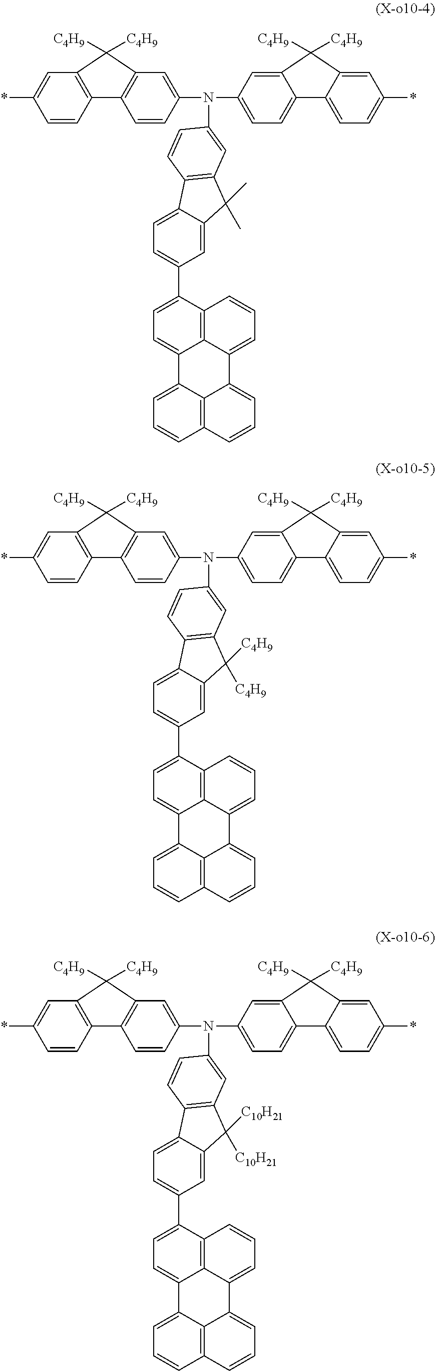

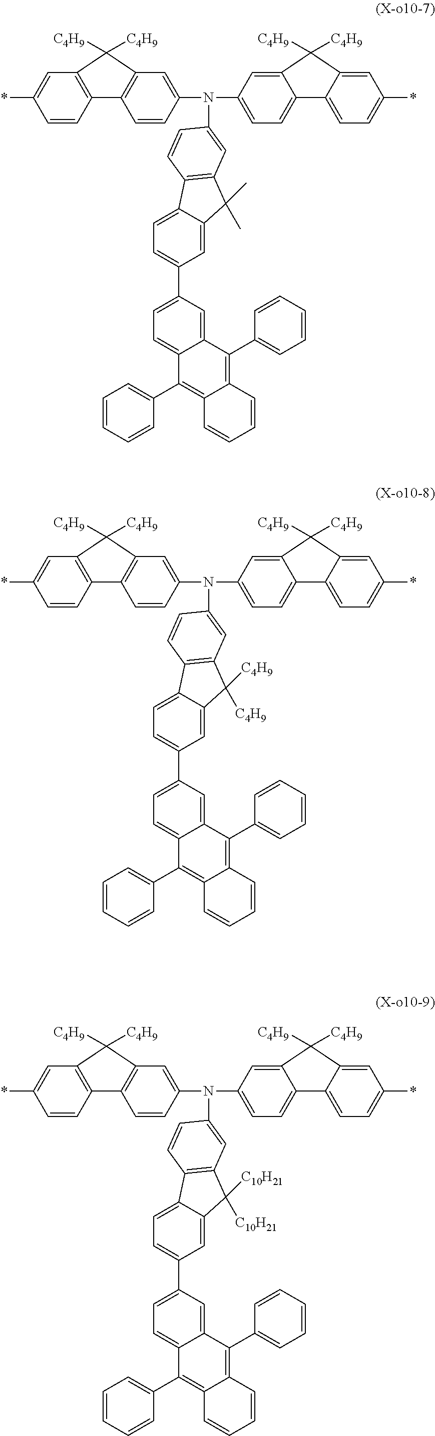

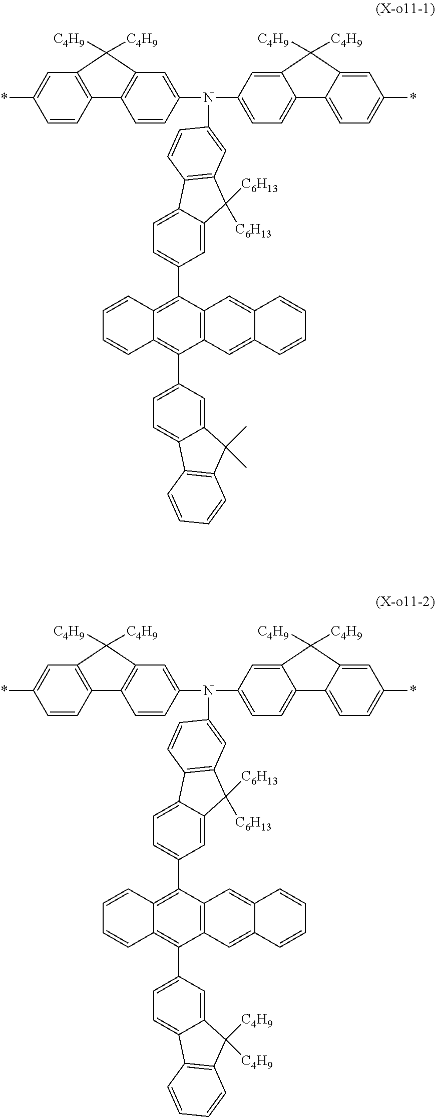

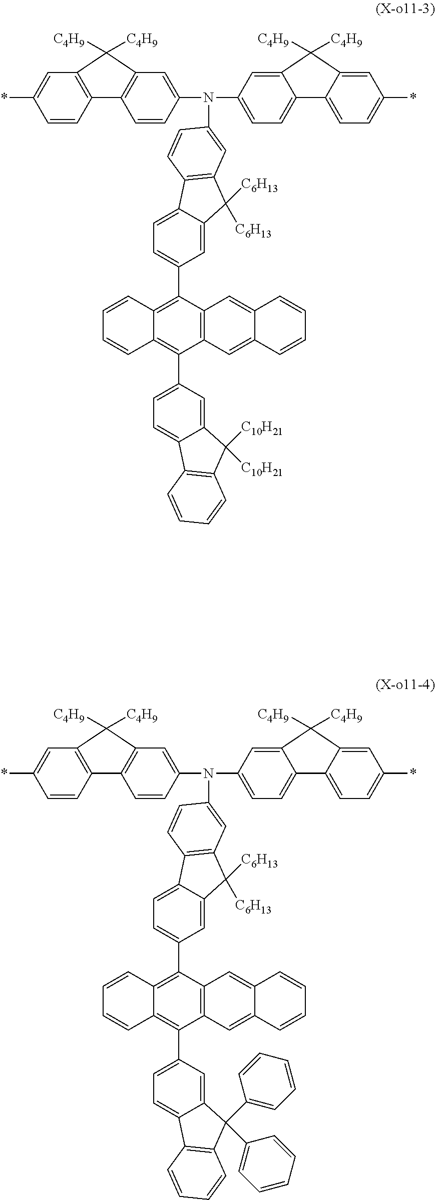

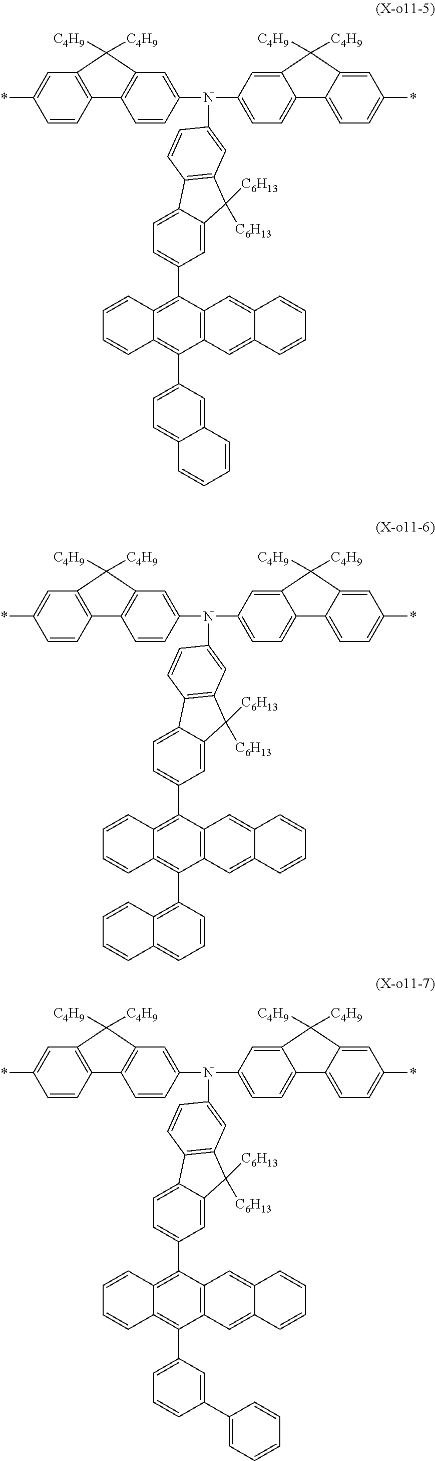

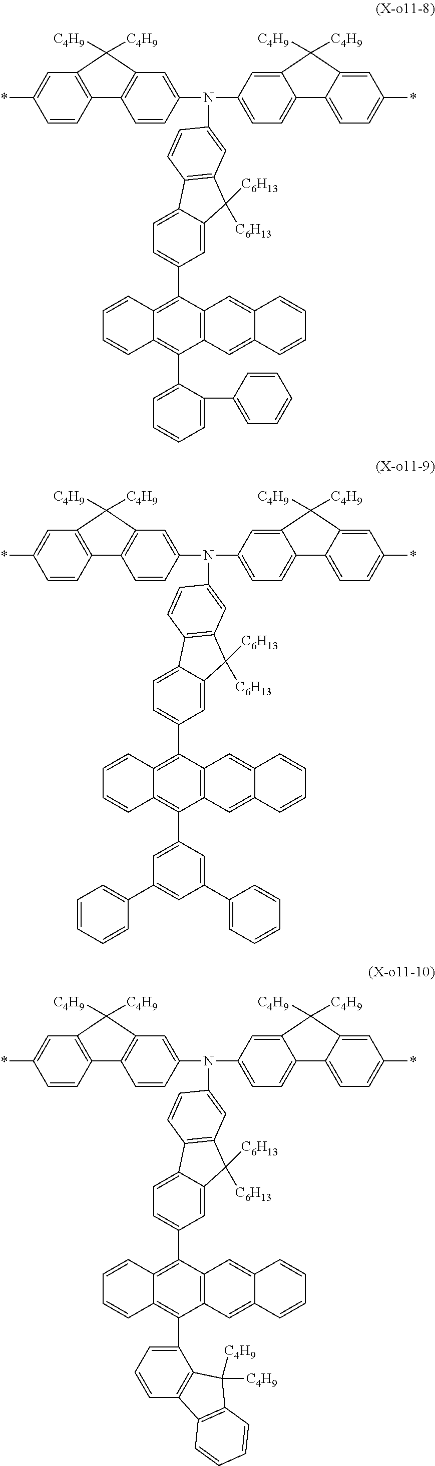

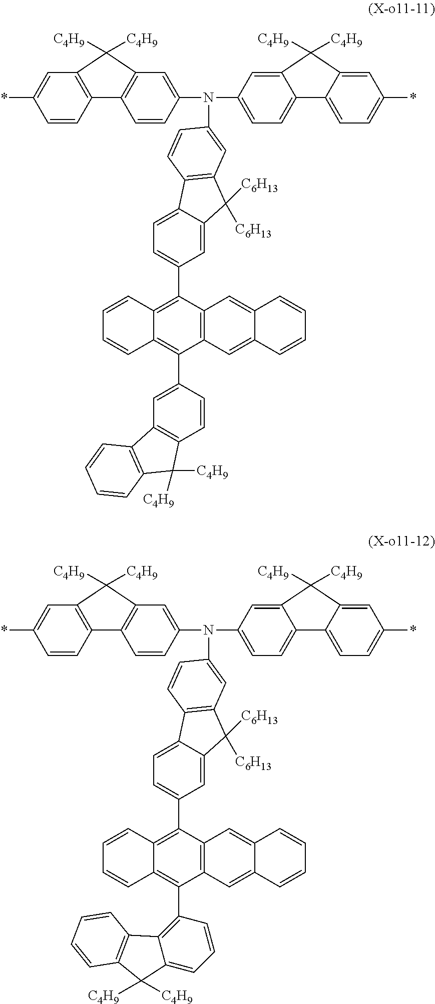

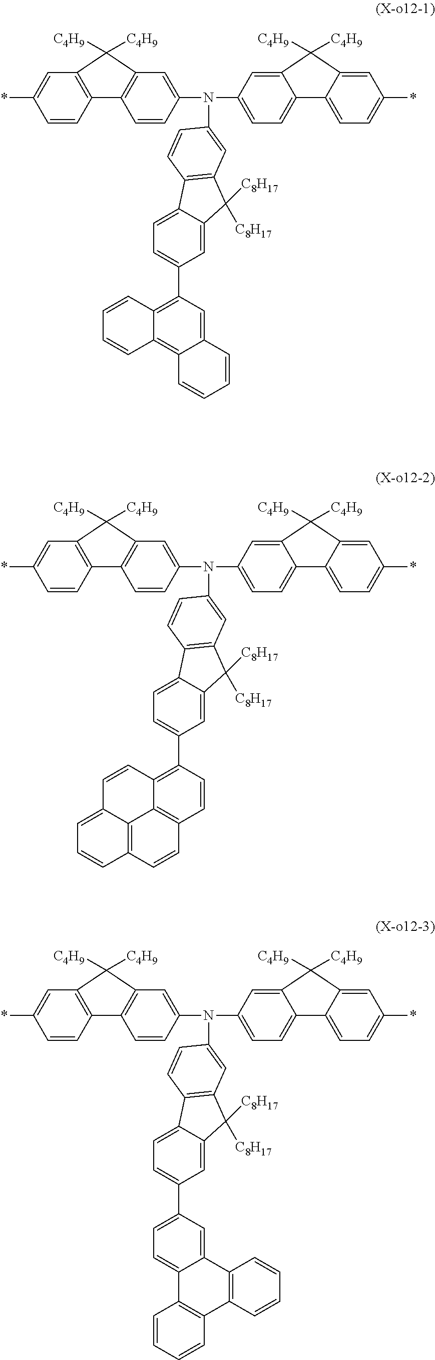

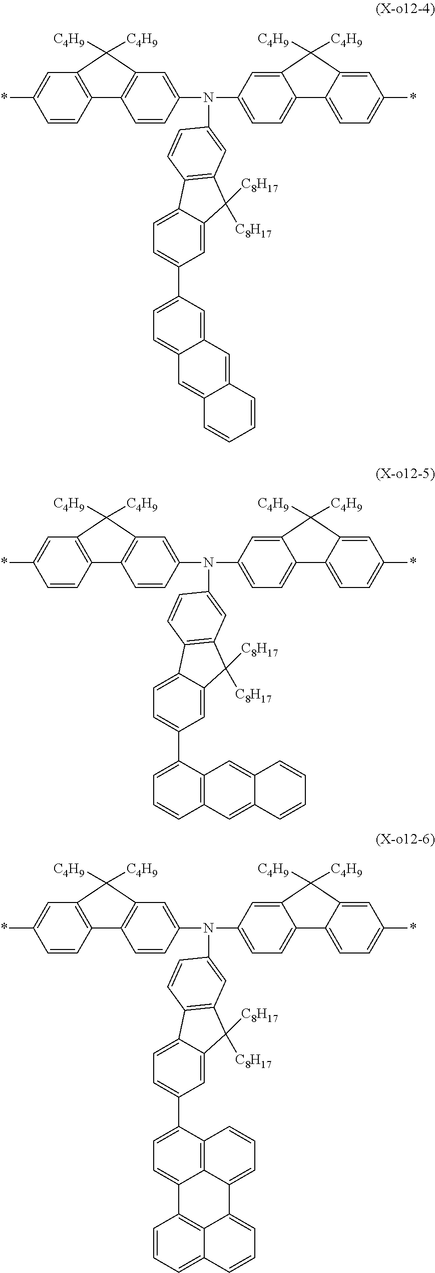

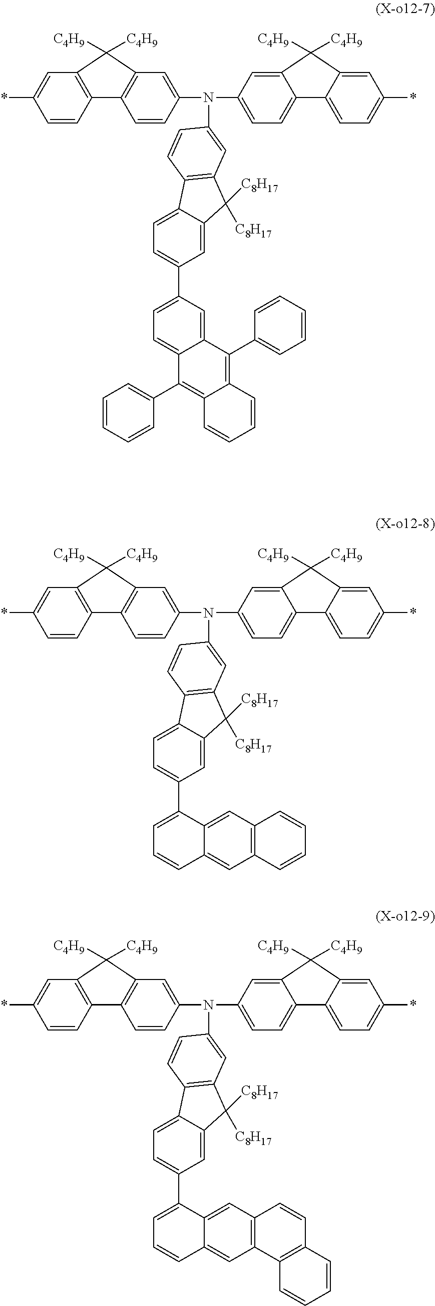

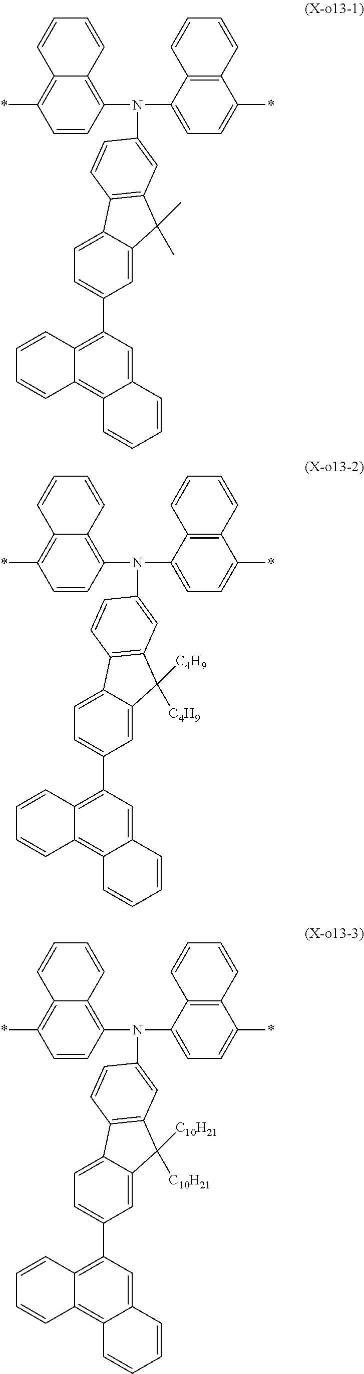

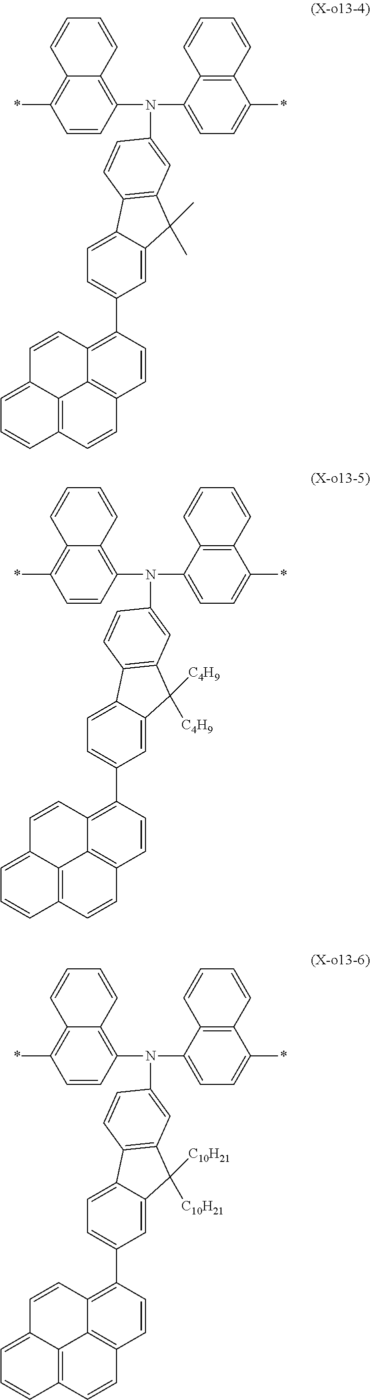

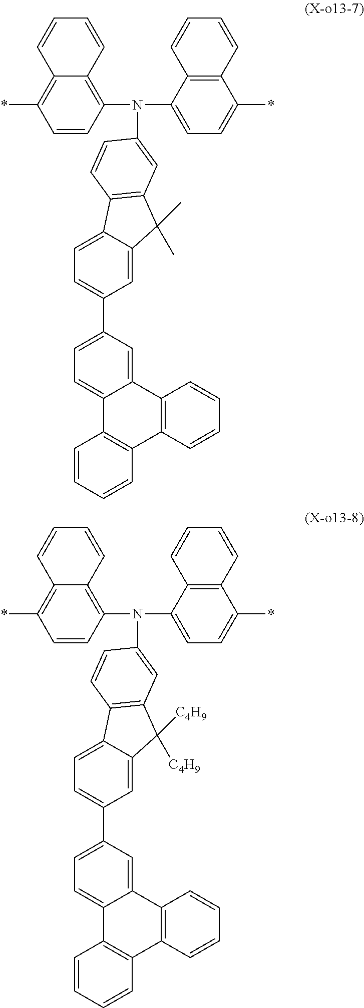

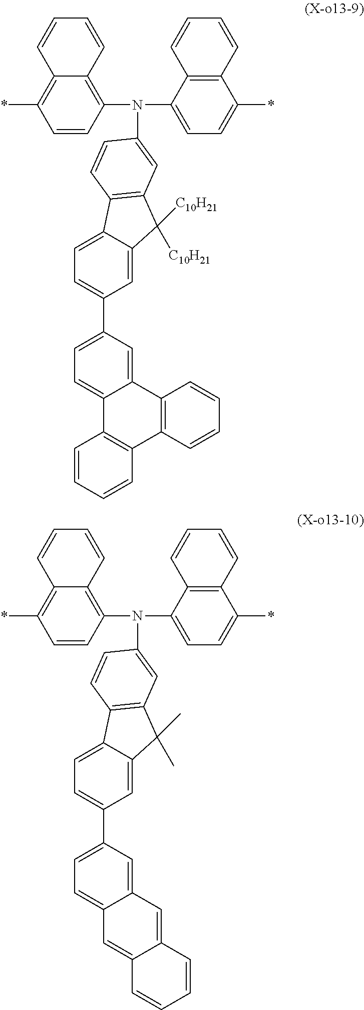

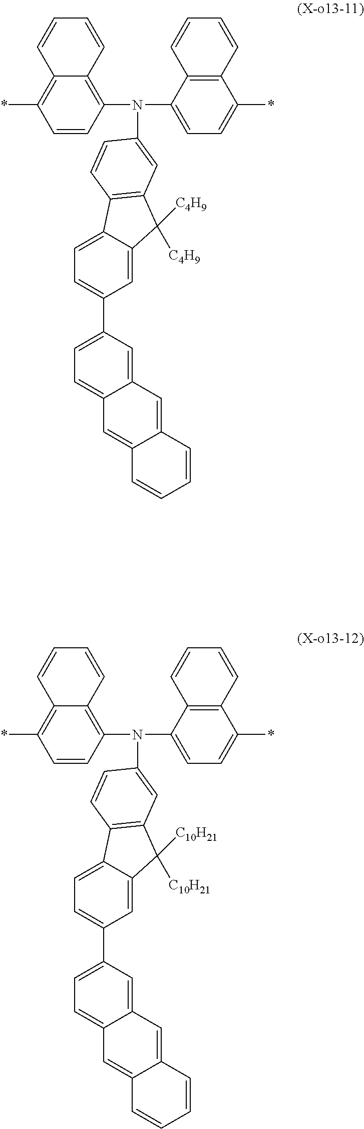

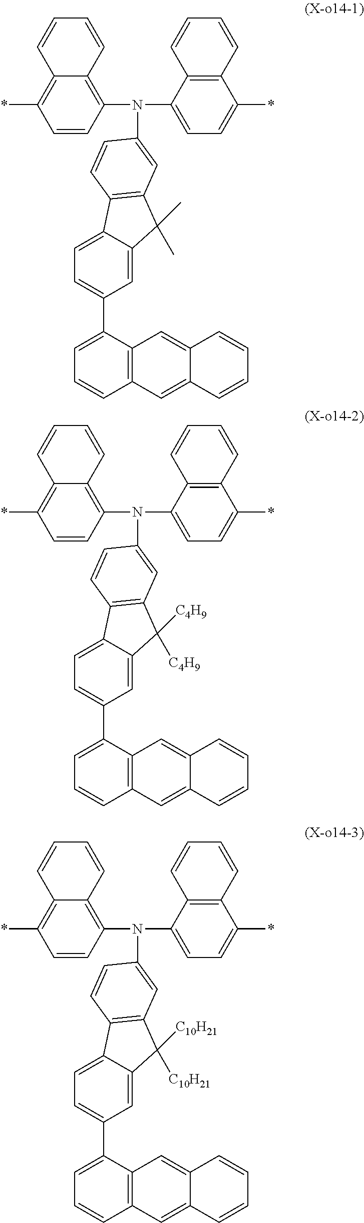

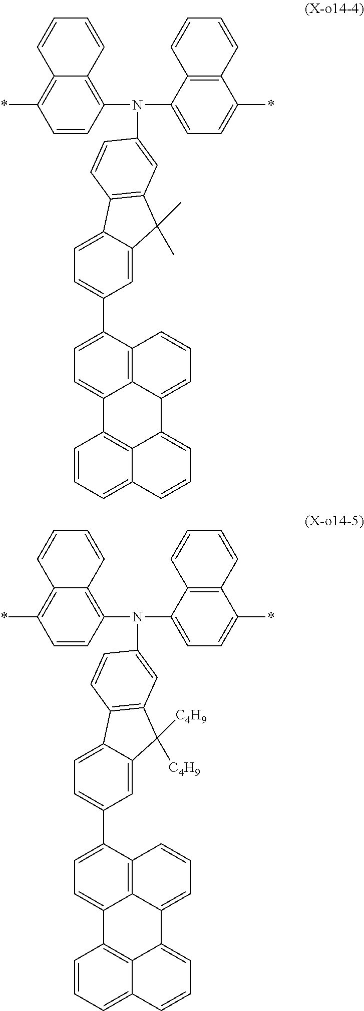

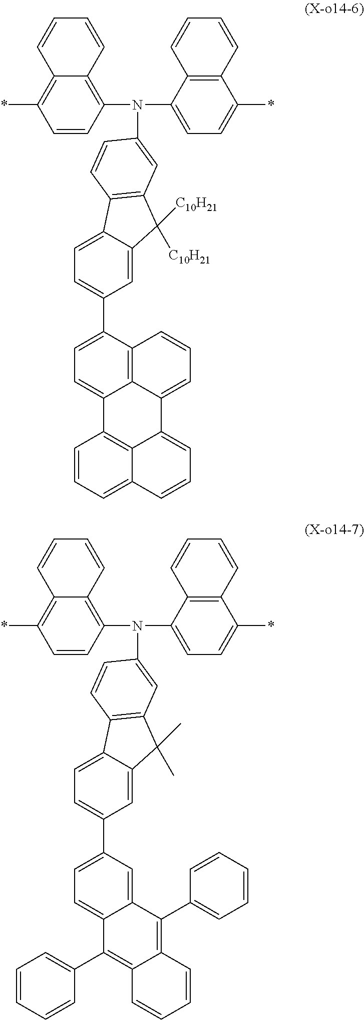

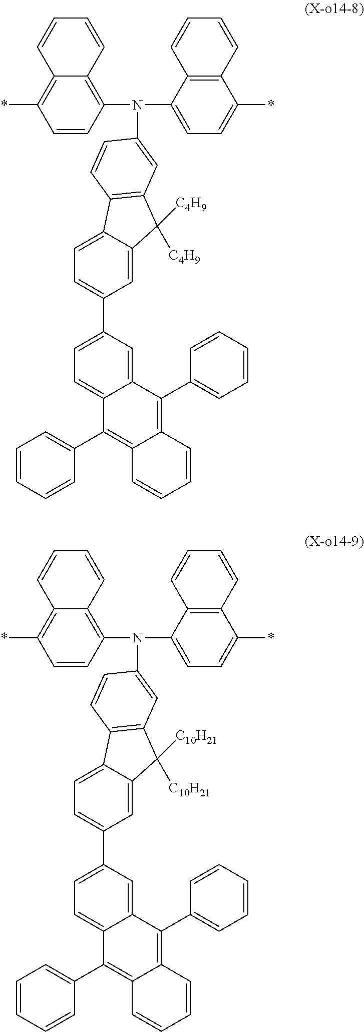

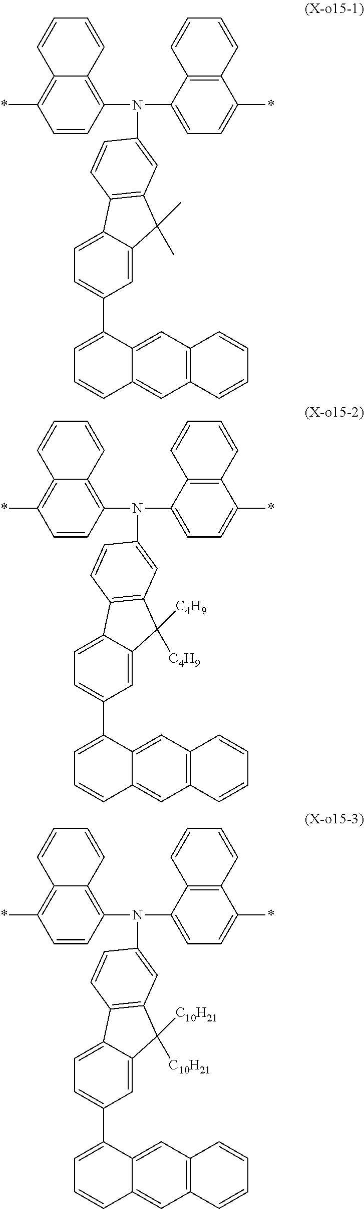

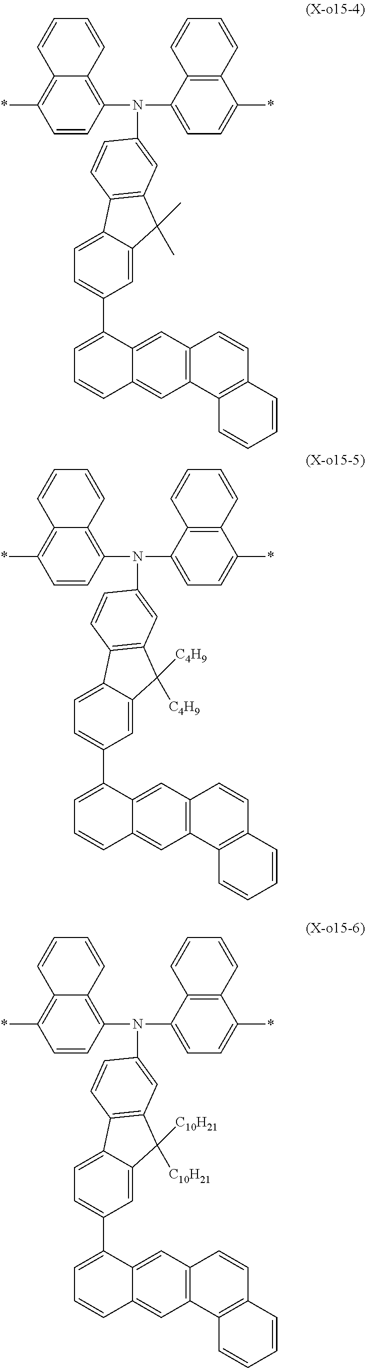

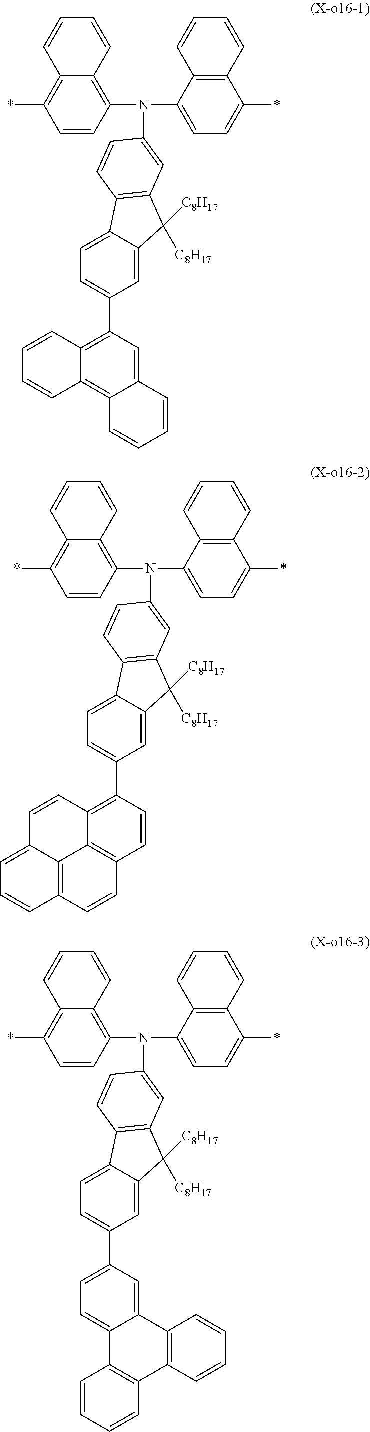

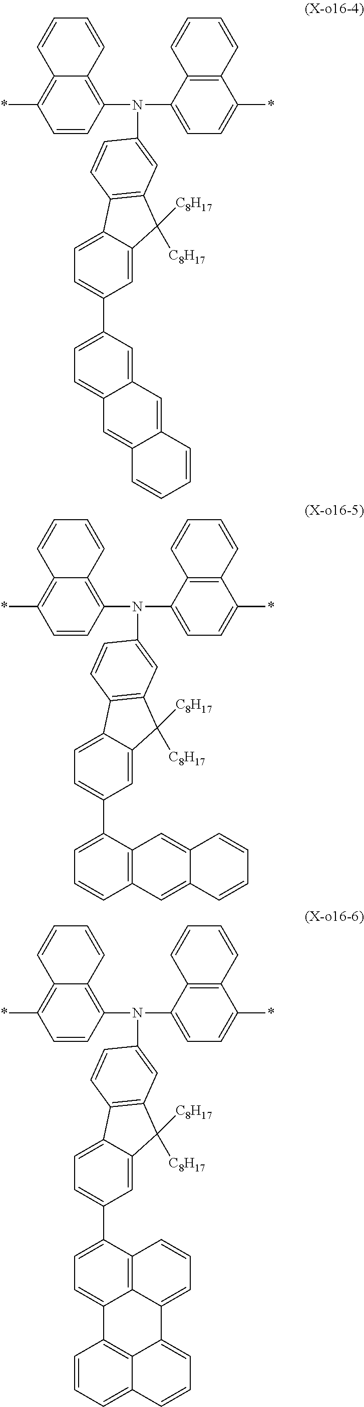

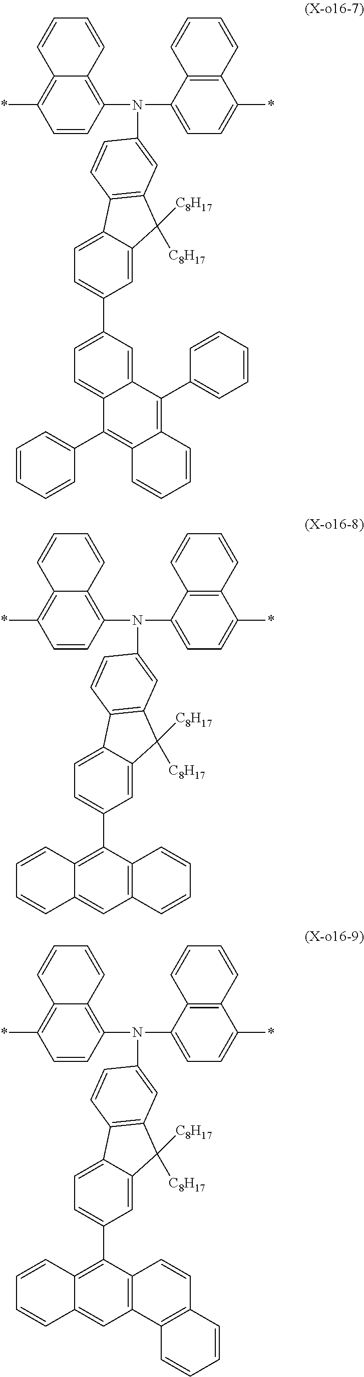

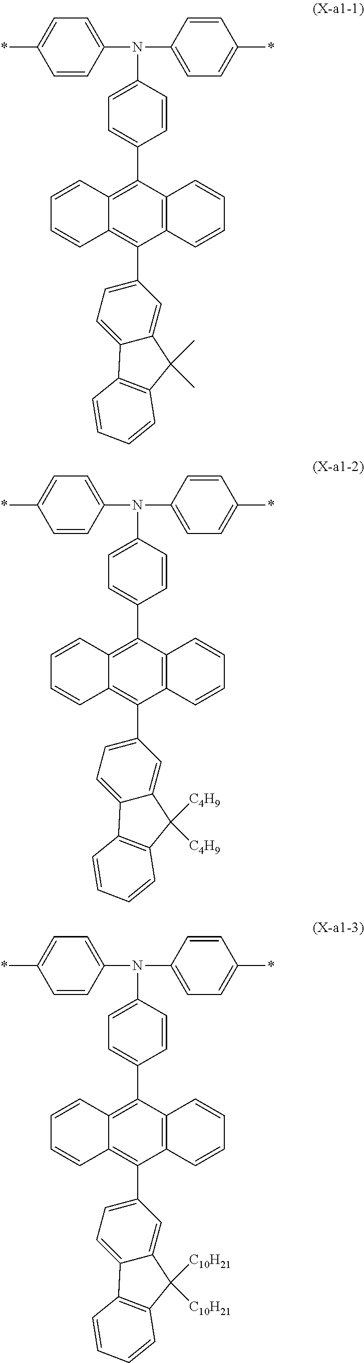

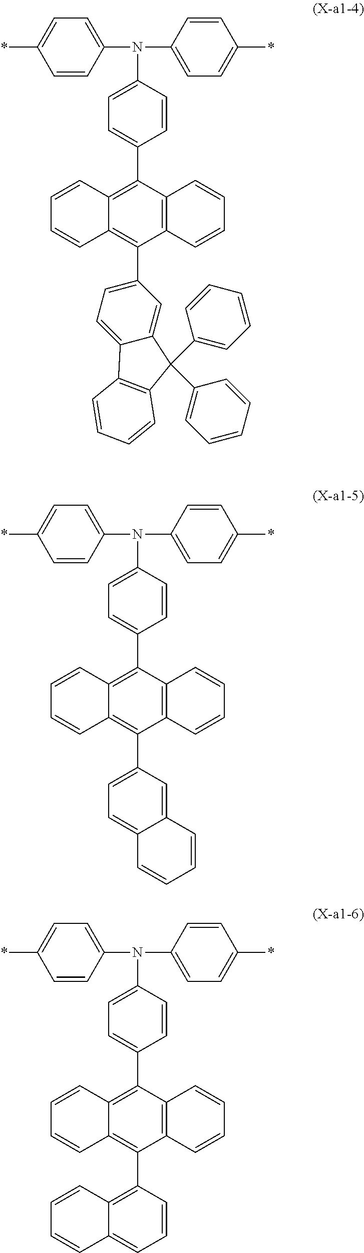

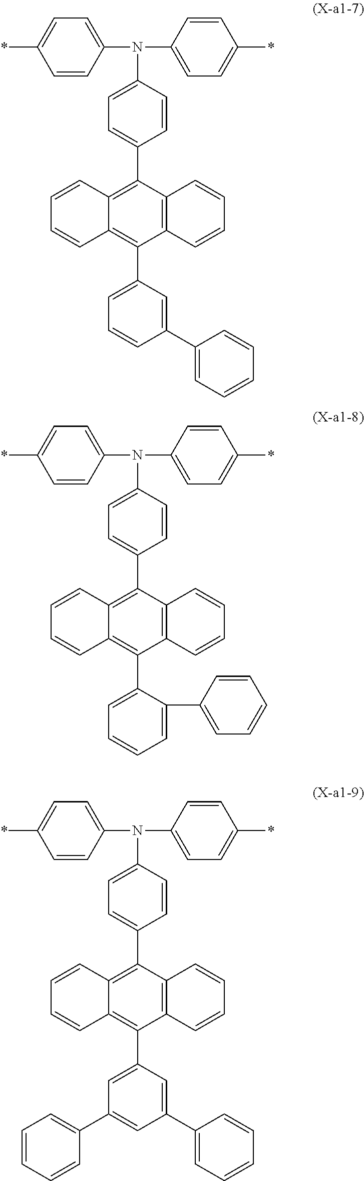

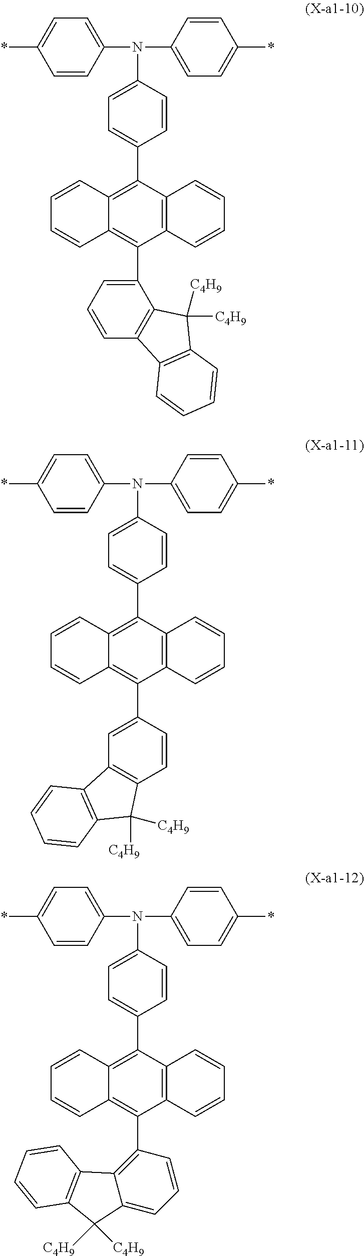

In the above structural formulas, a group represented by “—CₙH₂ₙ₊₁ (where n is a natural number)” represents a linear alkyl group.

Moreover, * is a binding site in a main chain of the polymer.

These are made the same with respect to the structural formulas described in this specification unless there is a description in particular.

Among the above structural units, for example, the structural unit X may be a structure (X-a1-1) to (X-a1-12), (X-a2-1) to (X-a2-12), (X-a2-12), a3-1) to (X-a3-12), (X-a5-1) to (X-a5-12), and (X-o4-1) to (X-o4-9).

In an embodiment, examples of the structural unit X according to an embodiment includes at least one of the following structures (X-1) to (X-8).

On the other hand, the following structures (X-1) to (X-8) correspond to the above structures (X-a1-5), (X-a1-1), (X-a2-1), (X-a1-2), (X-a3-5), (X-a3-2), (X-a5-5), and (X-o4-1), respectively.

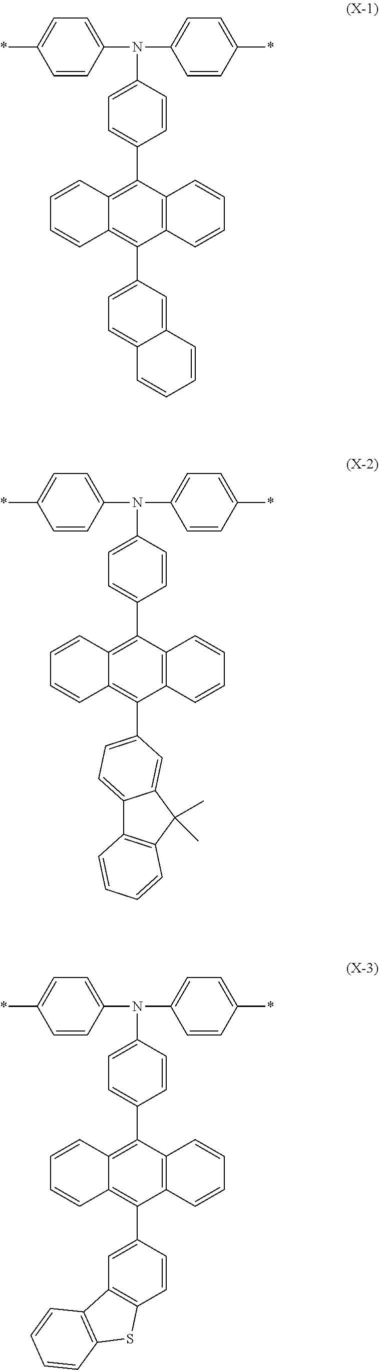 [SMILES: *c1ccc(N(c2ccc(*)cc2)c2ccc(-c3c4ccccc4c(-c4ccc5ccccc5c4)c4ccccc34)cc2)cc1 ; *c1ccc(N(c2ccc(*)cc2)c2ccc(-c3c4ccccc4c(-c4ccc5c(c4)C(C)(C)c4ccccc4-5)c4ccccc34)cc2)cc1 ; *c1ccc(N(c2ccc(*)cc2)c2ccc(-c3c4ccccc4c(-c4ccc5sc6ccccc6c5c4)c4ccccc34)cc2)cc1]

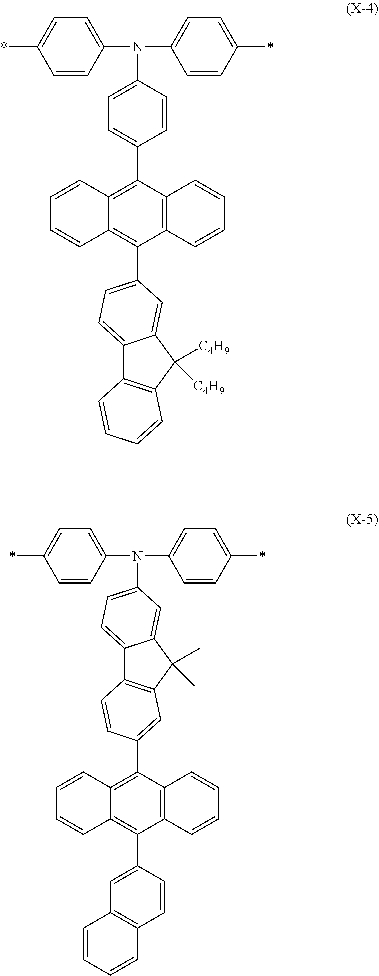

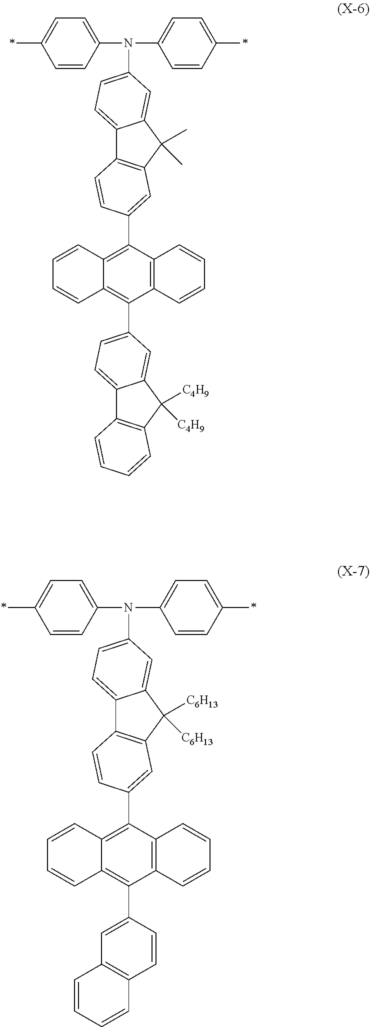

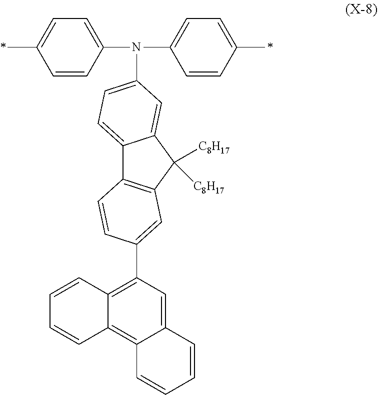

In Chemical Formula 1, Ar⁶ (i.e., structural unit Y), in addition to structural unit X, of the polymer according to an embodiment, is a substituted or unsubstituted aromatic carbocyclic group having 6 to 60 ring-forming atoms, or a substituted or unsubstituted aromatic heterocyclic group having 5 to 60 ring-forming atoms.

The aromatic carbocyclic group and aromatic heterocyclic group as Ar⁶ may be monocyclic or a condensed ring. Herein, specific examples of the aromatic carbocyclic group having 6 to 60 ring-forming atoms are the same as the groups derived from aromatic carbocyclic compounds exemplified for Ar¹, Ar², and Ar³, and thus descriptions thereof are omitted.

Ar⁶ may be a substituted or unsubstituted aromatic carbocyclic group having 6 to 30 ring-forming atoms, a substituted or unsubstituted aromatic heterocyclic group having 5 to 30 ring-forming atoms, for example, a substituted or unsubstituted aromatic carbocyclic group having 6 to 20 ring-forming atoms, or a substituted or unsubstituted monovalent aromatic heterocyclic group having 5 to 20 ring-forming atoms.

Among these, Ar⁶ may be represented by Chemical Formulas (7) to (22). In other words, in an embodiment, Ar⁶ of Chemical Formula 1 is a group represented by Chemical Formulas (7) to (22):

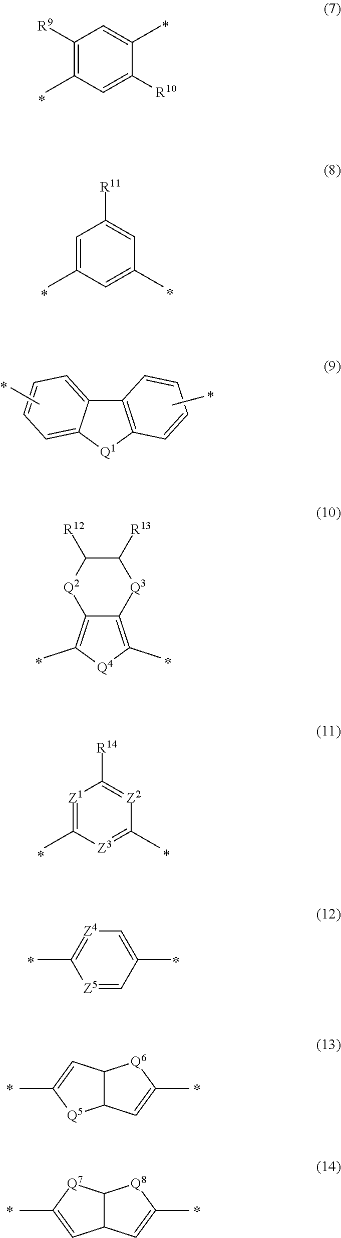

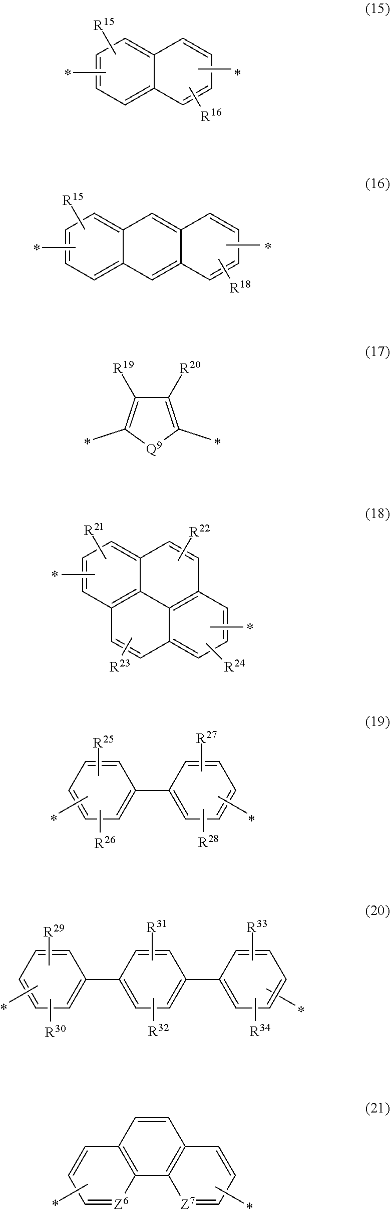

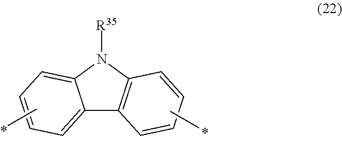

wherein, in Chemical Formulas (7) to (22),

R⁹ to R³⁵ are each independently a hydrogen atom, a substituted or unsubstituted aromatic carbocyclic group having 6 to 60 ring carbon atoms, a substituted or unsubstituted aromatic heterocyclic group having 5 to 60 ring-forming atoms, or an alkyl group having 1 to 60 carbon atoms.

In this case, each R⁹ to R³⁵ may be the same as or different from each other.

The aromatic carbocyclic group and aromatic heterocyclic group as R⁹ to R³⁵ may be monocyclic or condensed ring.

Herein, as an example of an aromatic carbocyclic group having 6 to 60 ring-forming atoms, a divalent group derived from aromatic hydrocarbon compounds exemplified for Ar¹ to Ar³ may be exemplified by converting the divalent group into a monovalent group.

In addition, specific examples of the monovalent aromatic heterocyclic group having 5 to 60 ring-forming atoms are the same as the specific examples of the aromatic heterocyclic group exemplified for Ar⁵, and thus descriptions thereof are omitted.

In addition, since specific examples of the alkyl group having 1 to 60 carbon atoms may be exemplified as the specific examples of the alkyl group exemplified for R¹ and R², the descriptions thereof are omitted.

The number of ring-forming atoms in the aromatic carbocyclic group as R⁹ to R³⁵ may be 6 to 20, for example, 6 to 15, or 6 to 10.

The number of ring-forming atoms of the aromatic heterocyclic group as R⁹ to R³⁵ may be 6 to 30, for example, 6 to 20, or 10 to 15.

The number of carbon atoms in the alkyl group as R⁹ to R³⁵ may be 1 to 30, for example, 3 to 20, or 5 to 15.

Among these, R⁹ to R³⁵ may each independently be a hydrogen atom, a substituted or unsubstituted aromatic heterocyclic group having 10 to 15 ring-forming atoms, a linear alkyl group having 3 to 20 carbon atoms, or a branched alkyl group having 3 to 20 carbon atoms, and may be a substituted or unsubstituted aromatic heterocyclic group having 10 to 15 ring-forming atoms, a linear alkyl group having 5 to 15 carbon atoms, and a hydrogen atom.

In addition, the aromatic heterocyclic group according to an embodiment as R⁹ to R³⁵ may be substituted, and for example, may be substituted with an alkyl group, a cycloalkyl group, an aryl group, or a combination thereof.

In Chemical Formulas (7) to (22), Q¹ to Q⁹ are each independently —O—, —S—, —Se—, —CRC³⁶R³⁷—, or —SIR³⁸R³⁹—, wherein R³⁶ to R³⁹ are each independently a hydrogen atom, a deuterium atom, a substituted or unsubstituted alkyl group, a substituted or unsubstituted aryl group, or a substituted or unsubstituted heteroaryl group.

R³⁶ and R³⁷ may be the same or different, although for example R³⁶ and R³⁷ may be the same.

Likewise, R³⁸ and R³⁹ may be the same or different, although R³⁸ and R³⁹ may be the same.

Herein, the alkyl group and the aryl group are the same as the specific examples of the alkyl group and the aromatic hydrocarbon group exemplified for R¹ and R², respectively, and thus descriptions thereof are omitted.

Examples of the aromatic heterocyclic groups (or heteroaryl groups) may include a 1-pyrrolyl group, a 2-pyrrolyl group, a 3-pyrrolyl group, a pyradinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-carbazolyl group, a 3-carbazolyl group, a 4-carbazolyl group, a 9-carbazolyl group, a 1-acridinyl group, a 2-acridinyl group, a 3-acridinyl group, a 4-acridinyl group, a 9-acridinyl group, a 1-phenadinyl group, a 2-phenazinyl group, a 1-phenothiazinyl group, a 2-phenothiazinyl group, a 3-phenothiazinyl group, a 4-phenothiazinyl group, a 10-phenothiazinyl group, a 1-phenoxazinyl group, a 2-phenoxazinyl group, a 3-phenoxazinyl group, a 4-phenoxazinyl group, a 10-phenoxazinyl group, and the like.

The number of carbon atoms in the alkyl group as R³⁶ and R³⁷ may be 1 to 30, for example, 3 to 20, 5 to 15, and 10 to 13. The number of ring-forming atoms in the aryl group as R³⁶ and R³⁷ may be 6 to 20, for example, 6 to 15, or 6 to 10. The number of ring-forming atoms in the heteroaryl group as R³⁶ and R³⁷ may be 6 to 20, for example, 6 to 15, or 6 to 10.

In Chemical Formulas (7) to (22), Z¹ to Z⁷ are each independently —CR⁴⁰═, —N═, or —SiR⁴¹═ wherein R⁴⁰ and R⁴¹ are each independently a hydrogen atom, a deuterium atom, a substituted or unsubstituted alkyl group, a substituted or unsubstituted aryl group, or a substituted or unsubstituted heteroaryl group, and R⁴⁰ and R⁴¹ may be the same or different.

Herein, the alkyl group and the aryl group are the same as the specific examples of the alkyl group and the aromatic hydrocarbon group exemplified for R¹ and R², respectively, and thus descriptions thereof are omitted.

Also, as the heteroaryl group, heteroaryl groups such as those listed in the descriptions of R³⁶ and R³⁷ may be exemplified.

In Chemical Formulas (7) to (22), * represents a binding site in the main chain of the polymer.

### Examples of Structural Unit Y

In Chemical Formula 1, an exemplary form of structural unit Y (i.e., Ar⁶) is a group represented by Chemical Formulas (7), (8), and (9), wherein R⁹ to R¹¹ are each independently a hydrogen atom, a substituted or unsubstituted, aromatic carbocyclic group having 6 to 30 ring carbon atoms, a substituted or unsubstituted, aromatic heterocyclic group having 5 to 30 ring-forming atoms, or a linear or branched alkyl group having 1 to 30 carbon atoms, and Q¹ is —CR³⁶R³⁷—, wherein R³⁶ and R³⁷ are each independently a substituted or unsubstituted linear or branched alkyl group having 3 to 20 carbon atoms.

For example, Ar⁶ is a group represented by Chemical Formulas (7), (8), and (9), wherein R⁹ to R¹¹ are each independently a hydrogen atom, a substituted or unsubstituted, aromatic heterocyclic group having 10 to 15 ring-forming atoms, or a linear or branched alkyl group having 5 to 15 carbon atoms, and Q¹ is —CR³⁶R³⁷—, wherein R³⁶ and R³⁷ are each independently a substituted or unsubstituted linear or a branched alkyl group having 5 to 15 carbon atoms.

In an example embodiment, Ar⁶ is a group represented by Chemical Formulas (7), (8), and (9), wherein R⁹ to R¹¹ are each independently a hydrogen atom, a substituted or unsubstituted aromatic heterocyclic group having 10 to 15 ring-forming atoms, a linear or branched alkyl group having 5 to 15 carbon atoms, and Q¹ is —CR³⁶R³⁷—, wherein R³⁶ and R³⁷ are each independently a substituted or unsubstituted linear or branched alkyl group having 10 to 13 carbon atoms.

In the polymer including the structural unit Y as described above, since the conjugate stabilization effect of Ar⁴ is more likely to spread throughout the molecule, durability may be further improved. In addition, the polymer having the above structure has a deep HOMO level. Therefore, the luminous efficiency of the LED using the polymer according to an embodiment, for example, QLED, may be improved.

Specific examples of the structural unit Y according to an embodiment may include the following structures (Y-1) to (Y-4):

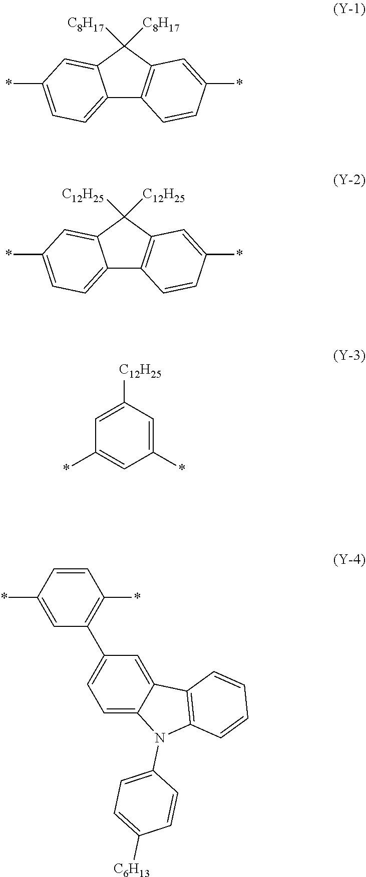

### Examples of Structural Unit A

Examples of the structural unit A constituting the polymer of an embodiment are shown below. That is, the structural unit A represented by Chemical Formula 1 may be one of Chemical Formulas (A-1) to (A-11):

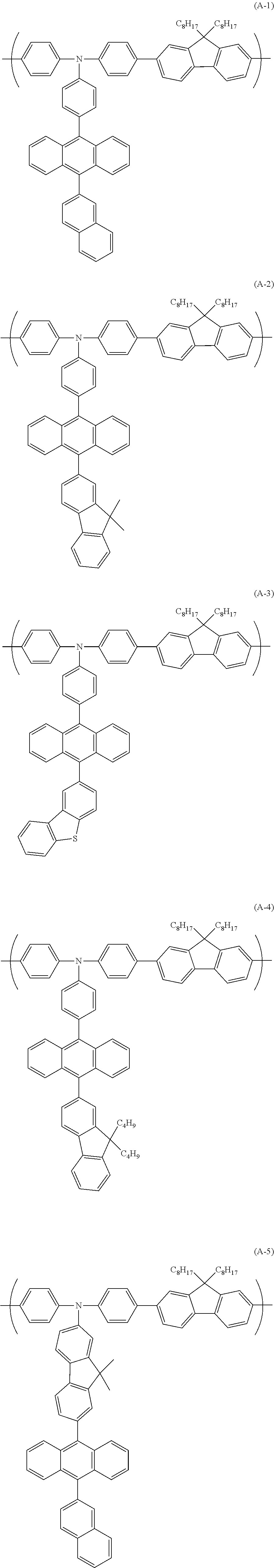

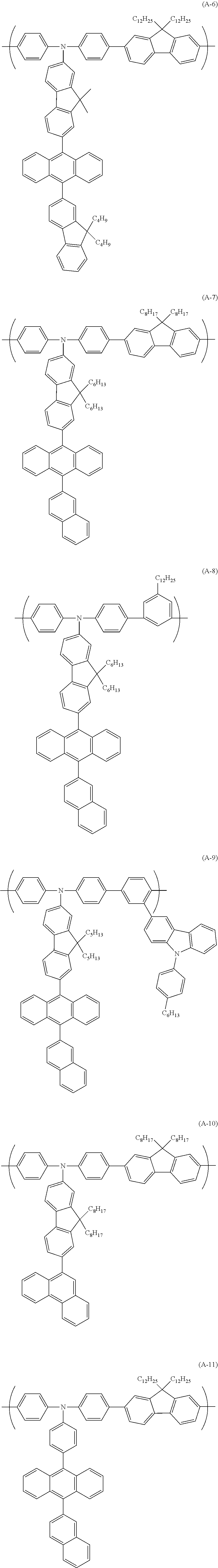

The polymer according to an embodiment includes the structural unit X and the structural unit Y, and may have other structural units (or comonomer unit) in addition to the structural units X and Y. Herein, the other structural units may be structural units derived from compounds, such as azulene, naphthalene, and anthracene. Herein, when the polymer according to an embodiment includes other structural (comonomer) units, the other structural units is not particularly limited.

Considering the durability and HOMO level of the polymer, and thus the hole transport ability of the layer formed using the polymer, such as a hole injection layer and a hole transport layer, and the effect of improving the luminous efficiency of a device that includes a polymer according to an embodiment in a hole injection layer or a hole transport layer, the other structural units may be for example included in an amount of greater than about 0 mol % and less than about 15 mol %, for example greater than or equal to about 0.5 mol % and less than or equal to about 10 mol % based on the total structural units in the polymer. A polymer that includes two or more types of different structural units A, then the mole content of structural units A means the total amount of the different structural units A.

The weight average molecular weight (Mw) of the polymer according to an embodiment is not particularly limited as long as the desired effect of the present disclosure is obtained. The weight average molecular weight (Mw) may be, for example, greater than or equal to about 5,000 g/mol and less than or equal to about 1,000,000 g/mol, for example, greater than or equal to about 8,000 g/mol and less than or equal to about 500,000 g/mol, or greater than or equal to about 10,000 g/mol and less than or equal to about 250,000 g/mol.

With such a weight average molecular weight, a viscosity of a coating liquid for forming layers such as a hole injection layer, a hole transport layer, and the like by using a polymer may be appropriately adjusted, and a layer having a uniform film thickness may be formed.

In addition, the number average molecular weight (Mn) of the polymer is not particularly limited as long as the desired effect of the present disclosure is obtained.

The number average molecular weight (Mn) may be, for example, greater than or equal to about 3,000 g/mol and less than or equal to about 500,000 g/mol, for example, greater than or equal to about 5,000 g/mol and less than or equal to about 300,000 g/mol, or greater than or equal to about 8,000 g/mol and less than or equal to about 100,000 g/mol.

With such a number average molecular weight, a viscosity of a coating solution for forming a layer (e.g., a hole injection layer, a hole transport layer, etc.) using the polymer may be appropriately adjusted, and a layer having a uniform film thickness may be formed.

Further, a polydispersity (weight average molecular weight/number average molecular weight) of the polymer of the present embodiment may be, for example, greater than or equal to about 1.10 and less than or equal to about 15.0, for example greater than or equal to about 1.30 and less than or equal to about 13.0, or for example greater than or equal to about 1.50 and less than or equal to about 5.00.

Herein, the measurement of the number average molecular weight (Mn) and the weight average molecular weight (Mw) is not particularly limited and may be obtained by using a known method or by appropriately modifying the known method.

As used herein, the number average molecular weight (Mn) and the weight average molecular weight (Mw) may be values measured by the following method. Also, the polydispersity (Mw/Mn) of the polymer is calculated by dividing the weight average molecular weight (Mw) by the number average molecular weight (Mn) measured by the following method.

Measurement of Number Average Molecular Weight (Mn) and Weight Average Molecular Weight (Mw) The number average molecular weight (Mn) and weight average molecular weight (Mw) of the polymer are measured under the following conditions by SEC (Size Exclusion Chromatography) using polystyrene as a standard material:

(SEC Measurement Conditions)

Analysis equipment (SEC): Shimadzu Corporation, Prominence

Column: Polymer Laboratories, PLgel MIXED-B

Column temperature: 40° C.

Flow rate: 1.0 mL/min

Injection amount of sample solution: 20 μL (polymer concentration: about 0.05 mass %)

Eluent: tetrahydrofuran (THF)

Detector (UV-VIS detector): Shimadzu Corporation, SPD-10AV

Standard sample: polystyrene.

The terminal of the main chain of the polymer of the present embodiment is not particularly limited and is appropriately defined depending on the type of raw material used, but it may be usually a hydrogen atom.

The polymer according to an embodiment may be synthesized using a known organic synthesis method.

A specific method of synthesizing the polymer according to an embodiment will be easily understood by those skilled in the art by referring to the examples to be described later.

For example, a polymer according to an embodiment may be prepared by a copolymerization reaction using one or more monomer X represented by Chemical Formula X′ or one or more monomers Y represented by Chemical Formula Y′. Further, if necessary, other monomers corresponding to the other structural units may be added thereby providing a polymer (or copolymer) according to an embodiment.

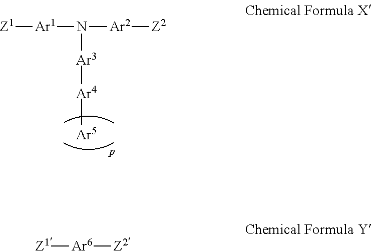

Alternatively, the polymer according to an embodiment may be prepared by a polymerization reaction using one or more monomers A represented by Chemical Formula A′.

At this time, if necessary, other monomers corresponding to the other structural units may be further added.

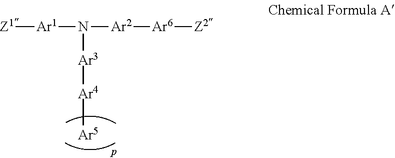

The monomers that are usable for the polymerization of the polymer according to an embodiment may be synthesized by appropriately combining known synthetic reactions, and their structures may also be confirmed by known methods, such as NMR and LC-MS.

In Chemical Formulas X′, Y′, and A′, AR¹, AR², AR³, AR⁴, AR⁵, and Ar⁶ are the same as those in Chemical Formula 1, respectively. In addition, in Chemical Formulas X′, Y′, and A′, Z′ and Z², Z¹′ and Z²′, and Z¹″ and Z²″ are each independently a halogen atom (a fluorine atom, a chlorine atom, a bromine atom, an iodine atom, for example, a bromine atom) or a group of the following structure:

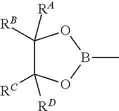

In the group of the above structure, R^{A} to RD are each independently an alkyl group having 1 to 3 carbon atoms. For example, R^{A} to RD may be a methyl group.

Meanwhile, Z¹ and Z² of Chemical Formula X′, Z¹ and Z²′ of Chemical Formula Y′, and Z¹″ and Z²″ of Chemical Formula A′ may be the same or different, respectively. However, in order to suppress polymerization of the monomers X, Z¹ and Z² of Chemical Formula X′ may be atoms or groups that do not react with each other. Similarly, in order to suppress polymerization of monomers Y, Z¹, and Z²′ of Chemical Formula Y′ may be atoms or groups that do not react with each other. For example, Z¹ and Z² of Chemical Formula X′ and Z¹″ and Z²′ of Chemical Formula Y′ may be the same. Also, for example, Z¹″ and Z²″ of Chemical Formula A′ may be different from each other.

The polymer according to an embodiment includes structural unit X and structural unit Y. Due to this, the polymer has a deep HOMO level. Therefore, when the polymer according to an embodiment is used as a hole injection material or a hole transport material, for example, a hole transport material, good luminous efficiency may be achieved.

The HOMO level of the polymer according to an embodiment is not particularly limited, but may be, for example, greater than or equal to about −5.8 eV and less than or equal to about −5.5 eV. Since the polymer including such a deep HOMO level is included, in the quantum dot electroluminescence device including the hole transport layer including the polymer according to an embodiment and the light emitting layer including quantum dots, band offset (barrier) of the hole transport layer and the light emitting layer is small, and the transport ability of holes from the hole transport layer to the light emitting layer may be improved. Accordingly, by using the polymer according to an embodiment, an electroluminescence device, for example a QLED, exhibiting good luminous efficiency may be provided.

A glass transition temperature (T_{g}) of the polymer according to an embodiment is not particularly limited, but may be greater than or equal to about 60° C., for example, greater than or equal to about 80° C., greater than or equal to about 90° C., or greater than or equal to about 100° C. The upper limit thereof is not particularly limited, but may be less than or equal to about 250° C., for example, less than or equal to about 240° C., or less than or equal to about 230° C.

When the glass transition temperature (T_{g}) of the polymer is within the above range, it is advantageous for device fabrication, and at the same time, a device with more improved characteristics may be obtained. The glass transition temperature (T_{g}) of the polymer may be measured using a differential scanning calorimeter (DSC) (manufactured by Seiko Scientific Co., Ltd., trade name: DSC6000). In addition, the detail of a measuring method is described in examples.

### Electroluminescence Device Material

The polymer according to an embodiment may be advantageously used as an electroluminescence device material. According to this embodiment, an electroluminescence device material having improved durability, for example, improved luminescence life-span is provided. In addition, according to the polymer according to an embodiment, an electroluminescence device material having good luminous efficiency may also be provided.

Therefore, according to a second embodiment of the present disclosure, an electroluminescence device material including the polymer of the first embodiment is provided. Alternatively, a use of the polymer according to the first embodiment as an electroluminescence device material is provided.

In addition, the polymer according to an embodiment has a deep HOMO level of less than or equal to about −5.5 eV. Because of this, the polymer according to an embodiment may be suitably used for, for example, a hole transport layer of a quantum dot electroluminescence device.

### Electroluminescence Device

As already described, the polymer according to an embodiment may be desirably used in an electroluminescence device. That is, provided is an electroluminescence device including a pair of electrodes and one or more layers of organic film disposed between the electrodes and including the polymer or electroluminescence device material of an embodiment. Accordingly, an electroluminescence device may exhibit improved durability (luminescence life-span). In addition, the electroluminescence device may exhibit good luminous efficiency, for example, good luminous efficiency at a low driving voltage.

According to a third embodiment of the present disclosure, an electroluminescence device includes a first electrode, a second electrode, and one or more layers of organic film disposed between the first electrode and the second electrode, wherein at least one layer of the organic film includes the polymer of an embodiment.

The object or effect of the present disclosure may also be achieved by the electroluminescence device according to this embodiment. As an example of the above embodiment, the electroluminescence device further includes a light emitting layer between the electrodes and including a light emitting material capable of emitting light as a triplet exciton. Meanwhile, the electroluminescence device of the present embodiment is an example of an electroluminescence device according to an embodiment.

Further, an embodiment of the present disclosure provides a method for manufacturing an electroluminescence device including a pair of electrodes and one or more layers of organic films disposed between the electrodes and including the polymer of an embodiment, wherein at least one of the organic films is formed by a coating method. Further, according to this method, the embodiment of the present disclosure provides an electroluminescence device in which at least one layer of the organic films is formed by a coating method.

The polymer of an embodiment of the present disclosure and the electroluminescence device material (EL device material) according to an embodiment (hereinafter collectively referred to as “polymer/EL device material”) also have good solubility in organic solvents. Because of this, the polymer/EL device material according to an embodiment may be advantageously used for manufacturing a device, for example, applied as a thin film by a coating method (wet process). Accordingly, an embodiment of the present disclosure provides a liquid composition including the polymer of an embodiment, and a solvent or dispersion medium. Meanwhile, the liquid composition of the present embodiment is an example of the liquid composition according to an embodiment.

In addition, the electroluminescence device material according to the above embodiments may be advantageously used for manufacturing a device, for example, a thin film, by a coating method (wet process). In view of the above, an embodiment of the present invention provides a thin film including the polymer of an embodiment. Meanwhile, the thin film of this embodiment is one example of the thin film according to an embodiment.

In addition, the EL device material according to the embodiment has improved hole injectability and hole mobility. For this reason, it can be advantageously used in the formation of any organic film such as a hole injection material, a hole transport material, or a light emitting material (host). Among these, since it can be advantageously used as a hole injection material or a hole transport material from the viewpoint of hole transport properties, it may be advantageously used as a hole transport material.

In other words, an embodiment of the present invention provides a composition including the polymer and at least one material selected from a hole transport material, an electron transport material, and a light emitting host material. Herein, the light emitting material included in the composition is not particularly limited but may include organometallic complexes (luminescent organometallic complex compounds, e.g., phosphorescent emitter compounds) or semiconductor nanoparticles (semiconductor inorganic nanoparticles or quantum dots).

Hereinafter, an electroluminescence device according to an embodiment will be described in detail with reference the drawing. The drawing is a schematic view showing an electroluminescence device according to the present embodiment. As shown, an EL device 100 according to an embodiment includes a substrate 110, a first electrode 120 on the substrate 110, a hole injection layer 130 on the first electrode 120, a hole transport layer 140 on the hole injection layer 130, a light emitting layer 150 on the hole transport layer 140, an electron transport layer 160 on the light emitting layer 150, an electron injection layer 170 on the electron transport layer 160, and a second electrode 180 on the electron injection layer 170.

Herein, the polymer/EL device material of this embodiment is included in any one organic film (organic layer) between the first electrode 120 and the second electrode 180. For example, the polymer/EL device material may be included in the hole injection layer 130 as a hole injection material, in the hole transport layer 140 as a hole transport material, or in the light emitting layer 150 as a light emitting material (host). For example, the polymer/EL device material may be included in the hole injection layer 130 as a hole injection material or in the hole transport layer 140 as a hole transport material. For example, the polymer/EL device material may be included in the hole transport layer 140 as a hole transport material. In other words, in an embodiment, the organic film including the polymer/EL device material may be a hole transport layer, a hole injection layer, or a light emitting layer material (host).

In an embodiment of the present disclosure, the organic film including the polymer/EL device material is a hole transport layer or a hole injection layer.

In an embodiment of the present disclosure, the organic film including the polymer/EL device material is a hole transport layer.

In addition, the organic film including the polymer/EL device material of the present embodiment may be formed by a coating method (solution coating method). For example, the organic film may be formed by using a solution coating method such as a spin coating method, a casting/casting method, a micro gravure coating method, a gravure coating method, a bar coating method, a roll coating method, a wire bar coating method, a dip coating method, a spray coating method, a screen printing method, a flexographic printing method, an offset printing method, or an ink jet printing method. However, the method for forming a layer other than the organic film including the polymer/EL device material is not particularly limited.

Meanwhile, the solvent used in the solution coating method is not particularly limited as long as it can dissolve the polymer/EL device material and may be appropriately selected depending on the type of used polymer/EL device material. For example, it may be toluene, xylene, ethyl benzene, diethylbenzene, mesitylene, propyl benzene, cyclohexyl benzene, dimethoxy benzene, anisole, ethoxy toluene, phenoxy toluene, isopropyl biphenyl, dimethyl anisole, phenyl acetate, phenyl propionate, methyl benzoate, ethyl benzoate, cyclohexane, and the like.

In addition, the amount of the solvent used is not particularly limited, but considering the ease of coating and the like, a concentration of the polymer/EL device material may be, for example, greater than or equal to about 0.1 weight percent (wt %) and less than or equal to about 10 wt %, for example, greater than or equal to about 0.5 wt % and less than or equal to about 5 wt %.

Layers other than the organic film including the polymer/EL device material of the present embodiment may be formed, for example, by a vacuum deposition method or a solution coating method.

The substrate 110 may be a substrate used in a general EL device. For example, the substrate 110 may be a semiconductor substrate such as a glass substrate, a silicon substrate, and the like, or a transparent plastic substrate. The first electrode 120 is formed on the substrate 110. The first electrode 120 is specifically an anode, and is formed by a material having a large work function among a metal, an alloy, or a conductive compound. For example, the first electrode 120 may be formed as a transmissive electrode by indium tin oxide (In₂O₃—SnO₂: ITO), indium zinc oxide (In₂O₃—ZnO), tin oxide (SnO₂), zinc oxide (ZnO) or the like due to improved transparency and conductivity.

The first electrode 120 may be formed as a reflective electrode by laminating magnesium (Mg), aluminum (Al), or the like on the transparent conductive layer. Further, after forming the first electrode 120 on the substrate 110, cleaning and UV-ozone treatment may be performed, if necessary.

On the first electrode 120, the hole injection layer 130 is formed. The hole injection layer 130 is a layer that facilitates injection of holes from the first electrode 120, and may be formed to have a thickness (dry film thickness; the same below) of specifically greater than or equal to about 10 nanometers (nm) and less than or equal to about 1000 nm, or greater than or equal to about 20 nm and less than or equal to about 50 nm.

The hole injection layer 130 may be formed of a known hole injection material. The known hole injection material of the hole injection layer 130 may include, for example, triphenylamine-containing poly(ether ketone) (TPAPEK), 4-isopropyl-4′-methyldiphenyl iodonium tetrakis(pentafluorophenyl)borate (PPBI), N,N′-diphenyl-N,N′-bis-[4-(phenyl-m-tolyl-amino)-phenyl]-biphenyl-4,4′-diamine (DNTPD), copper phthalocyanine, 4,4′,4″-tris(3-methylphenylphenylamino)triphenylamine (m-MTDATA), N,N′-di(1-naphthyl)-N,N′-diphenylbenzidine (NPB), 4,4′,4″-tris(diphenylamino)triphenylamine (TDATA), 4,4′,4″-tris(N,N-2-naphthylphenylamino)triphenylamine (2-TNATA), polyaniline/dodecylbenzenesulphonic acid, poly(3,4-ethylenedioxythiophene)/poly(4-styrenesulfonate) (PEDOT/PSS), polyaniline/10-camphorsulfonic acid, and the like.

The hole transport layer 140 is formed on the hole injection layer 130. The hole transport layer 140 is a layer having a function of transporting holes, and may be formed with a thickness of, for example, greater than or equal to about 10 nm and less than or equal to about 150 nm, and for example greater than or equal to about 20 nm and less than or equal to about 50 nm. In an embodiment, the hole transport layer 140 may be formed by a solution coating method using the polymer/EL device material according to the present embodiment. According to this method, the durability of the EL device 100 (device life-span, luminescence life-span, etc.) may be further improved. It is also possible to improve the current efficiency of the EL device 100 and reduce the driving voltage. In addition, since the hole transport layer may be formed by the solution coating method, a large area may be formed efficiently.

When any one other organic film of the EL device 100 includes the polymer/EL device material according to the present embodiment, the hole transport layer 140 may be formed of a known hole transport material. The known hole transport material may be, for example, 1,1-bis[(di-4-tolylamino)phenyl]cyclohexane (TAPC), carbazole derivatives such as N-phenylcarbazole and polyvinyl carbazole, and the like, N,N′-bis (3-methylphenyl)-N,N′-diphenyl-[1,1-biphenyl]-4,4′-diamine (TPD), 4,4′,4″-tris(N-carbazolyl) triphenylamine (TCTA), N,N′-di (1-naphthyl)-N, N′-diphenylbenzidine (NPB), and the like.

The light emitting layer 150 is formed on the hole transport layer 140. The light emitting layer 150 is a layer that emits light by fluorescence or phosphorescence, and may be formed using a vacuum deposition method, a spin coating method, an inkjet printing method, or the like. The light emitting layer 150 may have a thickness of, for example, greater than or equal to about 10 nm and less than or equal to about 60 nm, for example, greater than or equal to about 20 nm and less than or equal to about 50 nm. The light emitting material of the light emitting layer 150 is not particularly limited and a well-known light emitting material may be used. The light emitting material included in the light emitting layer 150 may be, for example, a light emitting material capable of emitting light from triplet excitons (i.e., phosphorescent light emission). In this case, the driving life-span of the EL device 100 may also be improved.

The light emitting layer 150 is not particularly limited and may have a known configuration. For example, the light emitting layer may include semiconductor nanoparticles or organometallic complexes. In other words, in an embodiment, the organic film has a light emitting layer including semiconductor nanoparticles or organometallic complexes. Meanwhile, when the light emitting layer includes the semiconductor nanoparticles, the EL device is a quantum dot electroluminescence device (QLED) or a quantum dot light emitting device. In the case where the light emitting layer includes the organometallic complexes, the EL device is an organic electroluminescence device (OLED).

In in the embodiment (OLED) in which the light emitting layer includes semiconductor nanoparticles, the light emitting layer may include a plurality of semiconductor nanoparticles (quantum dots) arranged in a single layer or a plurality of layers. Herein, the semiconductor nanoparticles (quantum dots) are particles of a predetermined size having a quantum confinement effect. The diameter (average diameter) of the semiconductor nanoparticles (quantum dots) is not particularly limited but may be greater than or equal to about 1 nm and less than or equal to about 20 nm.

The semiconductor nanoparticles (quantum dots) arranged in the light emitting layer may be synthesized by a wet chemical process, an organometallic chemical vapor deposition process, a molecular beam epitaxy process, or other similar processes. Among them, the wet chemical process is a method of growing particles by adding a precursor material to an organic solvent.

In the wet chemical process, when the crystal is grown, the organic solvent is naturally coordinated on the surface of the quantum dot crystal to act as a dispersant, thereby controlling the growth of the crystal. For this reason, the wet chemical processes may be more facile than vapor deposition methods such as metal organic chemical vapor deposition (MOCVD) or molecular beam epitaxy (MBE), and the growth of semiconductor nanoparticles may be controlled at considerably lower cost.

By controlling the size of semiconductor nanoparticles (quantum dots), an energy band gap may be adjusted, and light in various wavelength bands may be obtained from the light emitting layer (quantum dot light emitting layer). Therefore, by using a plurality of quantum dots of different sizes, a display that emits (or emits light) light of a plurality of wavelengths may be manufactured. The size of the quantum dots may be selected to emit red, green, or blue light to constitute a color display. In addition, the size of the quantum dots may be combined to emit white light with various color light (e.g., collectively, blue, green and red).

The semiconductor nanoparticles (quantum dots) may be semiconductor material selected from a Group II-VI semiconductor compound; a Group III-V semiconductor compound; a Group IV-VI semiconductor compound; a Group IV element or compound; and a combination thereof.

The Group II-VI semiconductor compound is not particularly limited, but includes, for example, a binary compound selected from CdSe, CdTe, ZnS, ZnSe, ZnTe, ZnO, HgS, HgSe, HgTe, and a mixture thereof; a ternary compound selected from CdSeS, CdSeTe, CdSTe, ZnSeS, ZnTeSe, ZnSTe, HgSeS, HgSeTe, HgSTe, CdZnS, CdZnSe, CdZnTe, CdHgS, CdHgSe, CdHgTe, HgZnS, HgZnSe, HgZnTe, and a mixture thereof; or a quaternary compound selected from CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-V semiconductor compound is not particularly limited, but includes, for example, a binary compound selected from GaN, GaP, GaAs, GaSb, AlN, AlP, AlAs, AlSb, InN, InP, InAs, InSb, and a mixture thereof; a ternary compound selected from GaNP, GaNAs, GaNSb, GaPAs, GaPSb, AlNP, AlNAs, AlNSb, AlPAs, AlPSb, InNP, InNAs, InNSb, InPAs, InPSb, GaAlNP, and a mixture thereof; or a quaternary compound selected from GaAlNAs, GaAlNSb, GaAlPAs, GaAlPSb, GaInNP, GaInNAs, GalnNSb, GaInPAs, GalnPSb, InAlNP, InAlNAs, InAlNSb, InAlPAs, InAlPSb, and a mixture thereof.

The Group IV-VI semiconductor compound is not particularly limited, but includes, for example, a binary compound selected from SnS, SnSe, SnTe, PbS, PbSe, PbTe, and a mixture thereof; a ternary compound selected from SnSeS, SnSeTe, SnSTe, PbSeS, PbSeTe, PbSTe, SnPbS, SnPbSe, SnPbTe, and a mixture thereof; or a quaternary compound selected from SnPbSSe, SnPbSeTe, SnPbSTe, and a mixture thereof.

The Group IV element or compound is not particularly limited, but includes, for example, a single element compound selected from Si, Ge, and a mixture thereof; or a binary compound selected from SiC, SiGe, and a mixture thereof.

The semiconductor nanoparticles (quantum dots) may have a homogeneous single structure or a double structure of a core-shell.

The core-shell may include different materials. The materials constituting each core and shell may be made of different semiconductor compounds. However, an energy bandgap of the shell material is larger than an energy bandgap of the core material. For example, it may have a structure of ZnTeSe/ZnSe/ZnS, InP/ZnSe/ZnS, CdSe/ZnS, InP/ZnS, and the like.

For example, a process of producing a quantum dot having a core (CdSe)-shell (ZnS) structure. First, trioctylphosphine oxide (TOPO) is used as a surfactant. A precursor material of the core (CdSe), such as (CH₃)₂Cd (dimethylcadmium) or TOPSe (trioctylphosphine selenide), is injected into an organic solvent to form crystals. At this time, after maintaining a certain time at high temperature so that the crystals grow to a certain size, the precursor materials of the shell (ZnS) are injected, to form a shell on the surface of the core already produced. As a result, a quantum dot of CdSe/ZnS capped with TOPO may be produced.

In addition, in the embodiment (OLED) in which the light emitting layer includes an organometallic complex, the light emitting layer 150 may include, for example, 6,9-diphenyl-9′-(5′-phenyl-[1,1′: 3′,1″-terphenyl]-3-yl) 3,3′-bi[9H-carbazole], 3,9-biphenyl-5-(3-(4-phenyl-6-(5′-phenyl-[1,1′: 3′,1″-terphenyl]-3-yl)-1,3,5,-triazin-2-yl)phenyl)-9H-carbazole, 9,9′-diphenyl-3,3′-bi[9H-carbazole], tris (8-quinolinato)aluminium (Alq3), 4,4′-bis(carbazol-9-yl)biphenyl (CBP), poly(n-vinyl carbazole) (PVK), 9,10-di(naphthalene)anthracene (ADN), 4,4′,4″-tris(N-carbazolyl) triphenylamine (TCTA), 1,3,5-tris(N-phenyl-benzimidazol-2-yl)benzene (TPBI), 3-tert-butyl-9,10-di(naphth-2-yl)anthracene (TBADN), distyrylarylene (DSA), 4,4′-bis (9-carbazole)2,2′-dimethyl-bipheny (dmCBP), and the like, as a host material.

The light emitting layer 150 may include, for example, perylene and a derivative thereof, rubrene and a derivative thereof, coumarin and a derivative thereof, 4-dicyanomethylene-2-(pdimethylaminostyryl)-6-methyl-4H-pyran (DCM) and a derivative thereof, an iridium (Ir) complex such as bis[2-(4,6-difluorophenyl)pyridinate]picolinate iridium(III) (Flrpic)), bis(1-phenylisoquinoline) (acetylacetonate)iridium(III) (Ir(piq)₂(acac)), tris(2-phenylpyridine)iridium(III) (Ir(ppy)₃), tris(2-(3-p-xylylphenyl)pyridine iridium (III), an osmium (Os) complex, a platinum complex, and the like, as a dopant material. Among these, for example, the light emitting material may be a light emitting organometallic complex compound.

A method for forming the light emitting layer is not particularly limited. It may be formed by coating (solution coating method) coating liquid including the semiconductor nanoparticles or organometallic complex. At this time, a solvent constituting the coating liquid may be a solvent which does not dissolve the materials (hole transport material, particularly polymer compound) in the hole transport layer.

The electron transport layer 160 is formed on the light emitting layer 150. The electron transport layer 160 is a layer having a function of transporting electrons. The electron transport layer is formed using a vacuum deposition method, a spin coating method, an inkjet method.

The electron transport layer 160 may be formed to have a thickness of greater than or equal to about 15 nm and less than or equal to about 50 nm.

The electron transport layer 160 may be formed of a known electron transport material. The known electron transport material may include, for example, ZnCl₂, ZnMgO, 8-lithium(lithium quinolate) (Liq), tris 8-aluminum (Alq3), and a compound having a nitrogen-containing aromatic ring. Examples of the compound having the nitrogen-containing aromatic ring may include, for example, a compound including a pyridine ring such as 1,3,5-tri[(3-pyridyl)-phen-3-yl]benzene), a compound including a triazine ring such as 2,4,6-tris(3′-(pyridin-3-yl)biphenyl-3-yl)-1,3,5-triazine), a compound including an imidazole ring such as 2-(4-(N-phenylbenzoimidazolyl-1-yl-phenyl)-9,10-dinaphthylanthracene or 1,3,5-tris(N-phenyl-benzimidazol-2-yl)benzene (TPBI). The electron transport material may be used alone or as a mixture of two or more.

The electron injection layer 170 is formed on the electron transport layer 160. The electron injection layer 170 is a layer having a function of facilitating injection of electrons from the second electrode 180. The electron injection layer 170 is formed using a vacuum deposition method or the like. The electron injection layer 170 may be formed to have a thickness of greater than or equal to about 0.1 nm and less than or equal to about 5 nm, and more specifically, greater than or equal to about 0.3 nm and less than or equal to about 2 nm.

As a material for forming the electron injection layer 170, any known material may be used. For example, the electron injection layer 170 may be formed of a lithium compound such as (8-quinolinato) lithium (lithium quinolate, Liq) and lithium fluoride (LiF), sodium chloride (NaCl), cesium fluoride (CsF), lithium oxide (Li₂O), or barium oxide (BaO).

The second electrode 180 is formed on the electron injection layer 170. The second electrode 180 is formed using a vacuum deposition method or the like. The second electrode 180 may be, for example, a cathode, and may be formed of a metal, an alloy, or a conductive compound having a small work function. For example, the second electrode 180 may be formed as a reflective electrode with a metal such as lithium (Li), magnesium (Mg), aluminum (Al), calcium (Ca), or an alloy such as aluminum-lithium (Al—Li), magnesium-indium (Mg—In), magnesium-silver (Mg—Ag), or the like. The second electrode 180 may be formed to have a thickness of greater than or equal to about 10 nm and less than or equal to about 200 nm, and more and specifically, greater than or equal to about 50 nm and less than or equal to about 150 nm. Alternatively, the second electrode 180 may be formed as a transmissive electrode by a thin film of less than or equal to about 20 nm of a metal material or a transparent conductive layer such as indium tin oxide (In₂O₃—SnO₂), and indium zinc oxide (In₂O₃—ZnO).

In the above, the EL device 100 according to an embodiment has been described as an example of an electroluminescence device according to an embodiment. In the EL device 100 according to an embodiment, durability (device life-span, luminescence life-span, etc.) may be further improved by disposing an organic film (particularly, a hole transport layer or a hole injection layer) including the polymer. In addition, the luminous efficiency (current efficiency) may be further improved and the driving voltage may be reduced.

Meanwhile, the stacked structure of the EL device 100 according to an embodiment is not limited to the above embodiments.

The EL device 100 according to an embodiment may also be formed in other known stacked structures. For example, in the EL device 100, one or more of the hole injection layer 130, the hole transport layer 140, the electron transport layer 160, and the electron injection layer 170 may be omitted, or an additional layer may be further provided. In addition, each layer of the EL device 100 may be formed as a single layer or may be formed as a plurality of layers.

For example, the EL device 100 may further include a hole blocking layer between the hole transport layer 140 and the light emitting layer 150 to prevent excitons or holes from diffusing into the electron transport layer 160. The hole blocking layer may be formed of, for example, an oxadiazole derivative, a triazole derivative, or a phenanthroline derivative.

In addition, the polymer according to an embodiment may be applied to electroluminescence devices other than the QLED or OLED. Examples of other electroluminescence devices to which the polymer according to an embodiment is applicable are not particularly limited, but examples thereof include organic-inorganic perovskite light emitting devices and the like.

### EXAMPLES

The effects of the present disclosure will be described with reference to the following examples and comparative examples. However, the technical scope of the present disclosure is not limited only to the following examples. Unless otherwise specified in the following examples, the operation stated is performed at room temperature (25° C.). In addition, unless otherwise indicated, “%” and “part” mean “wt %” and “part of a total mass,” respectively.

### Synthesis Example 1

### Synthesis of Intermediate 1-1

Intermediate 1-1 is synthesized according to the following reaction scheme.

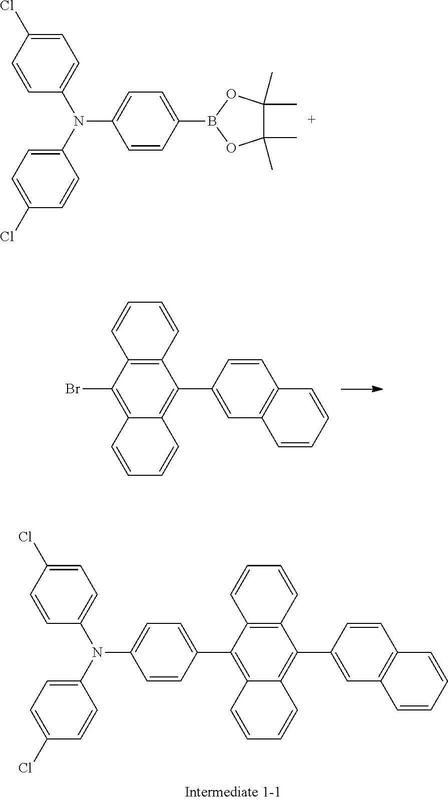 [SMILES: CC1(C)OB(c2ccc(N(c3ccc(Cl)cc3)c3ccc(Cl)cc3)cc2)OC1(C)C ; Brc1c2ccccc2c(-c2ccc3ccccc3c2)c2ccccc12 ; Clc1ccc(N(c2ccc(Cl)cc2)c2ccc(-c3c4ccccc4c(-c4ccc5ccccc5c4)c4ccccc34)cc2)cc1]

Under an argon atmosphere, N,N-bis(4-chlorophenyl)-2,5-dimethyl-4-(4,4,5,5-tetramethyl-1,3,2-dioxaborolan-2-yl)-benzene amine (6.3 g, 14.3 mmol), 9-bromo-10-(2-naphthyl)anthracene (5.0 g, 13.0 mmol), sodium carbonate (1.38 g, 13.0 mmol), toluene (100 mL), and water (50 mL) are added to a reaction vessel and the reaction mixture is stirred for 30 minutes. Subsequently, palladium acetate (0.058 g, 0.26 mmol) and 2-dicyclohexylphosphino-2′,4′,6′-triisopropylbiphenyl (XPhos, 0.21 g, 0.52 mmol) are added to the reaction mixture and the mixture is heated and stirred under reflux for 9 hours.

After completion of the reaction, the sample is transferred to a separatory funnel and extracted with volume portions of toluene. After drying the separated organic layer using MgSO₄, the resultant extract is filtered and concentrated. The concentrated residue is purified by silica gel column chromatography to obtain 6.25 g of a white solid (Intermediate 1-1), yield: 77%.

### Synthesis of Compound 1

Compound 1 is synthesized according to the following scheme.

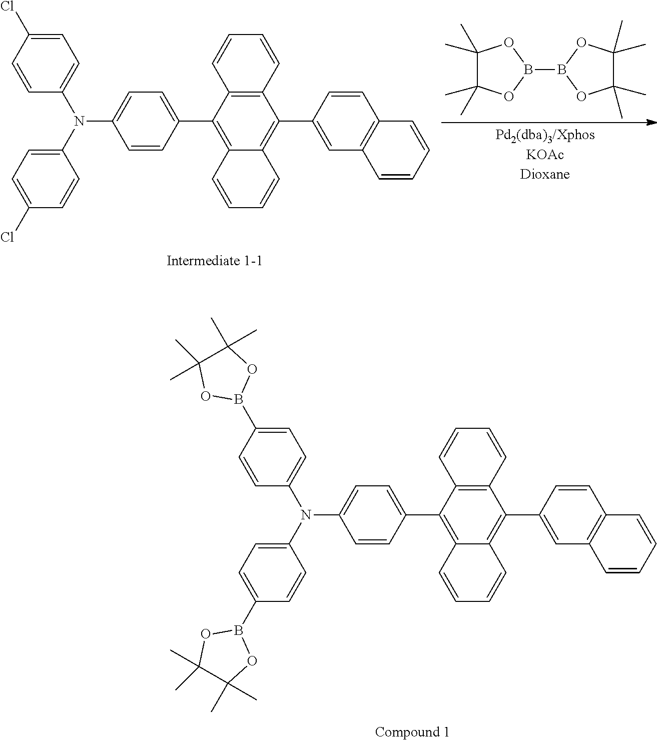

Under the argon atmosphere, Intermediate 1-1 (5.0 g, 8.1 mmol), bis(pinacolato) diboron (8.2 g, 32.4 mmol), potassium acetate (4.8 g, 32.4 mmol), and dioxane (100 ml) are added to a reaction vessel and the mixture stirred for 30 minutes. Subsequently, tris(dibenzylideneacetone) dipalladium (0) (Pd₂(dba)₃, 0.22 g, 0.24 mmol) and XPhos (0.46 g, 0.97 mmol) are added to the reaction mixture, which is then heated and stirred under reflux for 5 hours.

After completion of the reaction, the reaction liquid mixture is allowed to cool to room temperature. Thereafter, the reaction mixture is filtered using Celite®, and impurities are separated by filtration. After distilling off the solvent under vacuo from the filtrate, the resultant is purified by column chromatography to obtain Compound 1, 5.35 g, yield: 83%.

### Synthesis Example 2

### Synthesis of Intermediate 2-1

Intermediate 2-1 is synthesized according to the following reaction scheme.

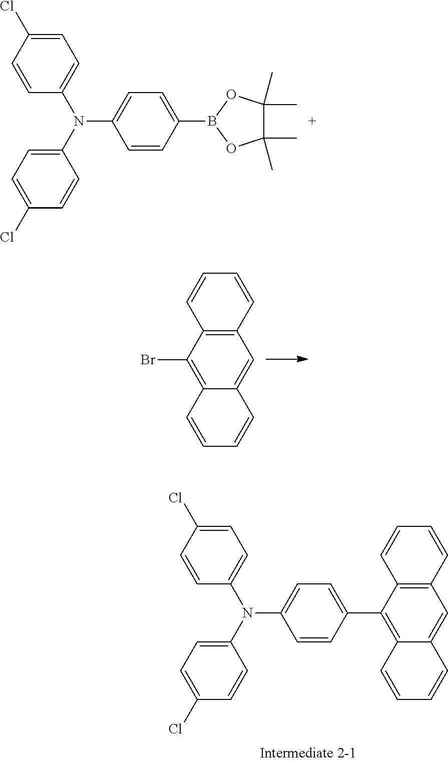

Under an argon atmosphere, N,N-bis(4-chlorophenyl)-2,5-dimethyl-4-(4,4,5,5-tetramethyl-1,3,2-dioxaborolan-2-yl)-benzene amine (11.3 g, 25.7 mmol), 9-bromo anthracene (6.0 g, 23.3 mmol), sodium carbonate (2.47 g, 23.3 mmol), toluene (100 mL), and water (50 mL) are added to a reaction vessel and stirred for 30 minutes. Subsequently, palladium acetate (0.104 g, 0.46 mmol) and XPhos (0.38 g, 0.93 mmol) are added to the reaction mixture and stirred under reflux for 12 hours.

After completion of the reaction, the sample is transferred to a separatory funnel and extracted with toluene. The organic layer is separated and dried using MgSO₄, and then the resultant is filtered and concentrated. The concentrated residue is purified by silica gel column chromatography to obtain 6.60 g of white solid (Intermediate 2-1), yield: 58%.

### Synthesis of Intermediate 2-2

Intermediate 2-2 is synthesized according to the following reaction scheme.

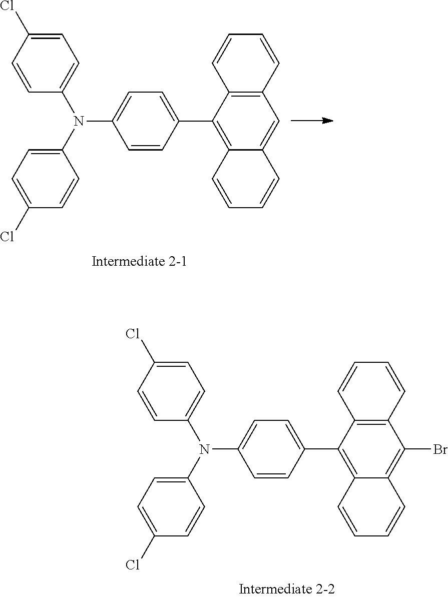 [SMILES: Clc1ccc(N(c2ccc(Cl)cc2)c2ccc(-c3c4ccccc4cc4ccccc34)cc2)cc1 ; Clc1ccc(N(c2ccc(Cl)cc2)c2ccc(-c3c4ccccc4c(Br)c4ccccc34)cc2)cc1]

Under the argon atmosphere, Intermediate 2-1 (6.6 g, 13.4 mmol) and dimethyl formamide (DMF, 100 mL) are added to a reaction vessel and stirred at 50° C. Subsequently, N-bromo succinimide (2.3 g, 12.8 mmol) dissolved in DMF (200 mL) is added dropwise to the reaction mixture and stirred for 5 hours. Then, water (50 mL) is added to precipitate a solid.

The obtained solid is washed with methanol, obtaining 7.35 g of Intermediate 2-2 (yield: 96%).

### Synthesis of Intermediate 2-3

Intermediate 2-3 is synthesized according to the following reaction scheme.

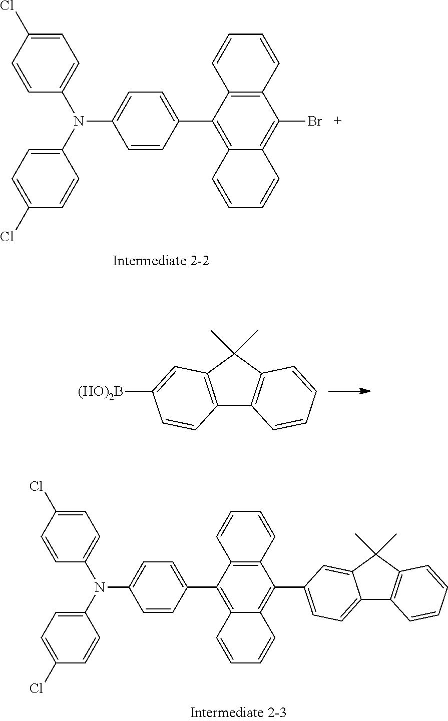

Under the argon atmosphere, Intermediate 2-2 (7.35 g, 12.9 mmol), 9,9-dimethyl fluorene-2-boronic acid (3.4 g, 14.2 mmol), sodium carbonate (1.64 g, 15.4 mmol), toluene (100 mL), and water (50 mL) are added to a reaction vessel and stirred for 30 minutes. Subsequently, palladium acetate (0.057 g, 0.25 mmol) and XPhos (0.21 g, 0.51 mmol) are added to the reaction mixture and heated and stirred under reflux for 5 hours.

After completion of the reaction, the sample is transferred to a separatory funnel and extracted with toluene. The organic layer is separated and dried using MgSO₄, and then the resultant is filtered and concentrated. The concentrated residue is purified by silica gel column chromatography to obtain 6.45 g of a white solid (Intermediate 2-3) (yield: 73%).

### Synthesis of Compound 2

Compound 2 is synthesized according to the following reaction scheme.

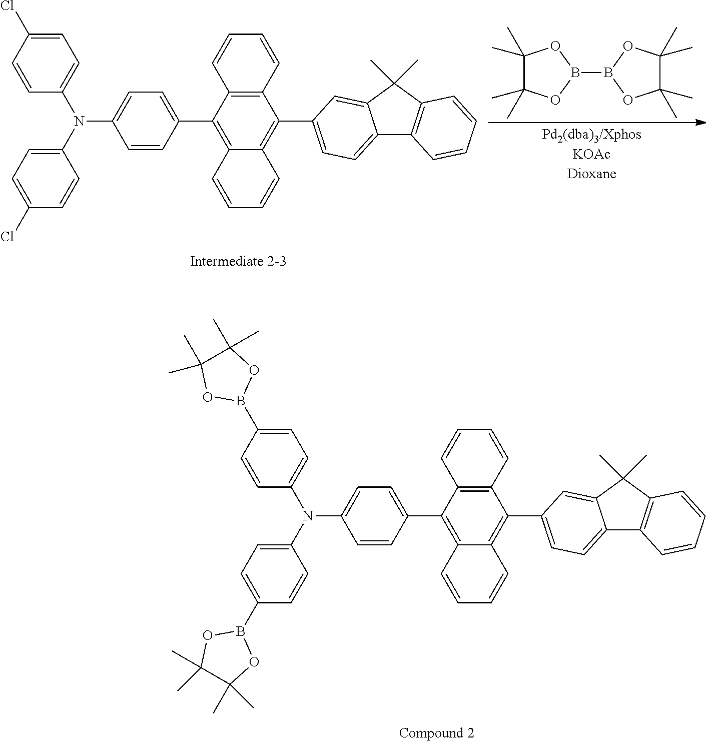

Under the argon atmosphere, Intermediate 2-3 (6.4 g, 9.3 mmol), bispinacolate diboron (9.5 g, 37.4 mmol), potassium acetate (5.5 g, 56.2 mmol), and dioxane (100 ml) are added to a reaction vessel and stirred for 30 minutes. Subsequently, tris(dibenzylideneacetone) dipalladium (0) (Pd₂(dba)₃, 0.25 g, 0.28 mmol) and XPhos (0.53 g, 1.12 mmol) are added to the reaction mixture and heated and stirred under reflux for 5 hours.

After completion of the reaction, the reaction liquid mixture is allowed to cool to room temperature. Thereafter, the reaction mixture is filtered using Celite®, and impurities are separated by filtration. Then, after distilling off the solvent in vacuo from the filtrate, the resultant is purified by column chromatography to obtain Compound 2 (7.64 g, yield: 94%).

### Synthesis Example 3

### Synthesis of Intermediate 3-1

Intermediate 3-1 is synthesized according to the following reaction scheme.

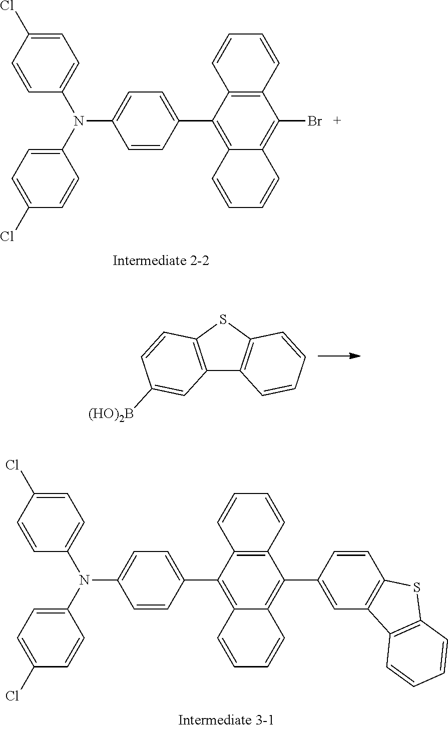

Under an argon atmosphere, Intermediate 2-2 (10.0 g, 17.5 mmol), dibenzothiophene-2-boronic acid (4.4 g, 19.3 mmol), sodium carbonate (2.23 g, 21.0 mmol), toluene (100 mL), and water (50 mL) are added to a reaction vessel and stirred for 30 minutes. Subsequently, palladium acetate (0.057 g, 0.25 mmol) and XPhos (0.21 g, 0.51 mmol) are added to the reaction mixture and heated and stirred under reflux for 5 hours.

After completion of the reaction, the sample is transferred to a separatory funnel and extracted with toluene. The organic layer is separated and dried using MgSO₄, and then the resultant is filtered and concentrated. The concentrated residue is purified by silica gel column chromatography to obtain 5.18 g of a white solid (Intermediate 3-1) (yield: 44%).

### Synthesis of Compound 3

Compound 3 is synthesized according to the reaction scheme.

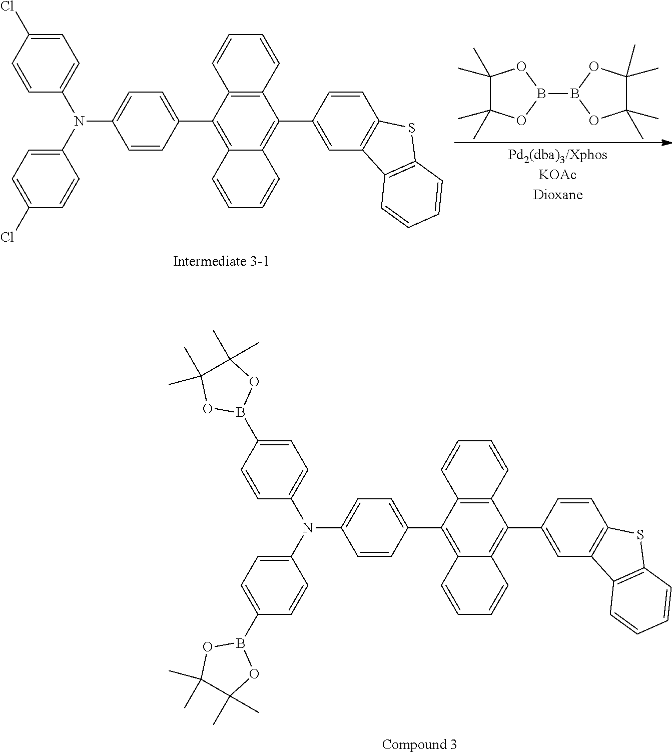

Under an argon atmosphere, Intermediate 3-1 (5.2 g, 7.3 mmol), bispinacolate diboron (7.8 g, 30.9 mmol), potassium acetate (4.5 g, 46.3 mmol), and dioxane (80 ml) are added to a reaction vessel and stirred for 30 minutes. Subsequently, tris(dibenzylideneacetone) dipalladium (0) (Pd₂(dba)₃, 0.21 g, 0.23 mmol) and XPhos (0.44 g, 0.92 mmol) are added to the reaction mixture and heated and stirred under reflux for 5 hours.

After completion of the reaction, the reaction liquid mixture is allowed to cool to room temperature. Thereafter, the reaction mixture is filtered using Celite®, and impurities are separated by filtration. Then, after distilling off the solvent in vacuo from the filtrate, the resultant is purified by column chromatography to obtain Compound 3 (5.17 g, yield: 78%).

### Synthesis Example 4

### Synthesis of Intermediate 4-1

Intermediate 4-1 is synthesized according to the reaction scheme.

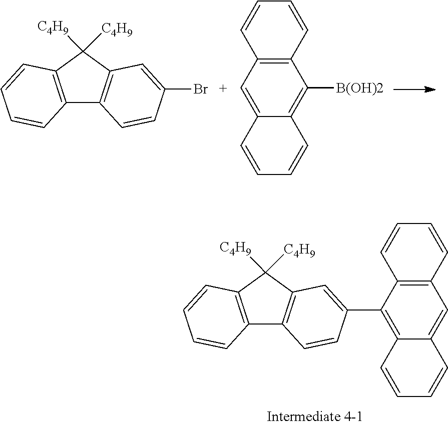

Under an argon atmosphere, 2-bromo-9,9-dibutyl fluorene (10.0 g, 27.9 mmol), 9-anthracene boronic acid (6.8 g, 30.7 mmol), sodium carbonate (3.55 g, 33.5 mmol), toluene (100 mL), and water (50 mL) are added to a reaction vessel and stirred for 30 minutes. Subsequently, palladium acetate (0.12 g, 0.56 mmol) and XPhos (0.46 g, 1.12 mmol) are added to the reaction mixture and heated and stirred under reflux for 12 hours.

After completion of the reaction, the sample is transferred to a separatory funnel and extracted with toluene. The organic layer is separated and dried using MgSO₄, and then the resultant is filtered and concentrated. The concentrated residue is purified by silica gel column chromatography to obtain 13.66 g of a solid (Intermediate 4-1) (yield: 100%).

### Synthesis of Intermediate 4-2

Intermediate 4-2 is synthesized according to the reaction scheme.

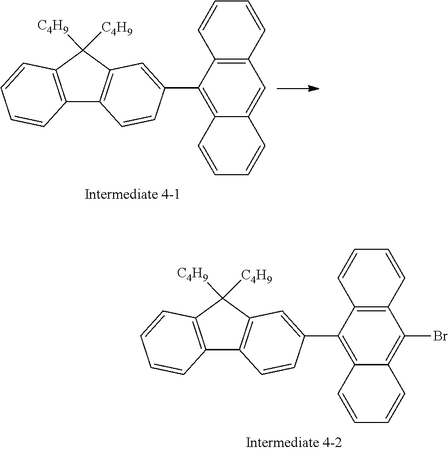

Under an argon atmosphere, Intermediate 4-1 (13.7 g, 30.0 mmol) and dimethyl formamide (DMF, 100 mL) are added to a reaction vessel and stirred at 50° C. N-bromo succinimide dissolved in DMF (200 mL) is added dropwise to the reaction mixture and stirred for 5 hours. Water (50 mL) is added to precipitate a solid. The obtained solid is washed with methanol, obtaining 13.2 g of Intermediate 4-2 (yield: 82%).

### Synthesis of Intermediate 4-3

Intermediate 4-3 is synthesized according to the reaction scheme.

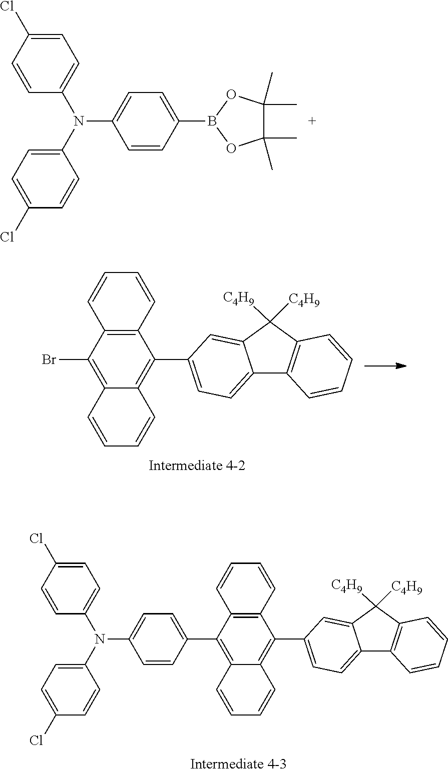

Under an argon atmosphere, N,N-bis(4-chlorophenyl)-2,5-dimethyl-4-(4,4,5,5-tetramethyl-1,3,2-dioxaborolan-2-yl)-benzene amine (4.5 g, 10.3 mmol), Intermediate 4-2 (5.0 g, 9.3 mmol), sodium carbonate (0.99 g, 9.3 mmol), toluene (80 mL), and water (40 mL) are added to a reaction vessel and stirred for 30 minutes. Subsequently, palladium acetate (0.042 g, 0.18 mmol) and XPhos (0.15 g, 0.37 mmol) are added to the reaction mixture and heated and stirred under reflux for 18 hours.

After completion of the reaction, the sample is transferred to a separatory funnel and extracted with toluene. The organic layer is separated and dried using MgSO₄, and then the resultant is filtered and concentrated. The concentrated residue is purified by silica gel column chromatography to obtain 4.36 g of a solid (Intermediate 4-3) (yield: 60%).

### Synthesis of Compound 4

Compound 4 is synthesized according to the reaction scheme.

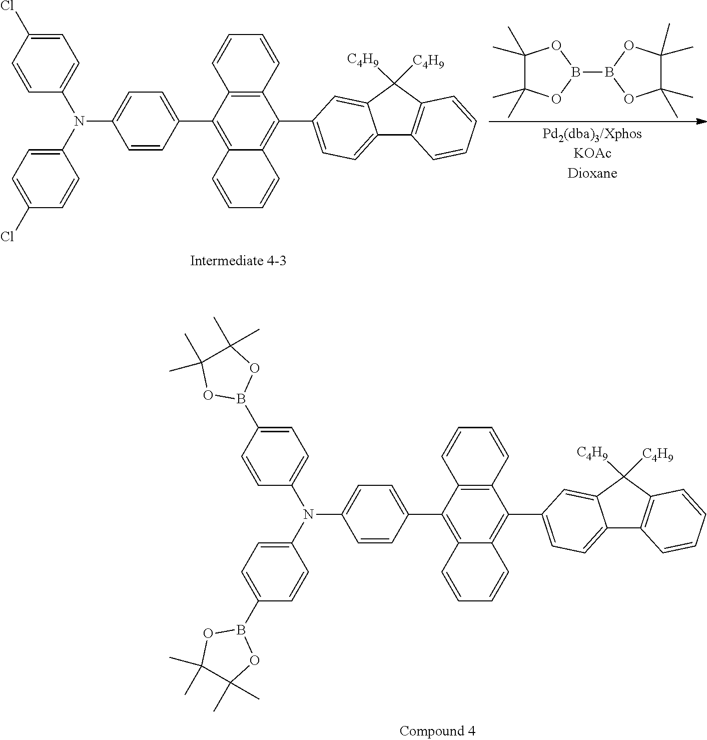

Under an argon atmosphere, Intermediate 4-3 (4.3 g, 5.6 mmol), bispinacolate diboron (5.7 g, 22.7 mmol), potassium acetate (3.3 g, 34.1 mmol), and dioxane (100 ml) are added to a reaction vessel and stirred for 30 minutes. Subsequently, tris(dibenzylideneacetone) dipalladium (0) (Pd₂(dba)₃, 0.15 g, 0.17 mmol) and XPhos (0.32 g, 0.68 mmol) are added to the reaction mixture and heated and stirred under reflux for 5 hours.

After completion of the reaction, the reaction liquid mixture is allowed to cool to room temperature. Thereafter, the reaction mixed solution is filtered using Celite® (and impurities are separated by filtration. Then, after distilling off the solvent in vacuo from the filtrate, the resultant is purified by column chromatography to obtain Compound 4 (5.0 g, yield: 92%).

### Synthesis Example 5

### Synthesis of Intermediate 5-1

Intermediate 5-1 is synthesized according to the reaction scheme.

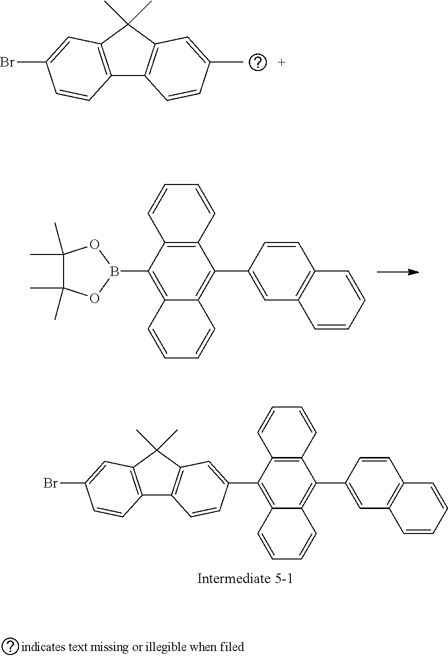 [SMILES: Cc1ccc2c(c1)C(C)(C)c1cc(Br)ccc1-2 ; CC1(C)OB(c2c3ccccc3c(-c3ccc4ccccc4c3)c3ccccc23)OC1(C)C ; CC1(C)c2cc(Br)ccc2-c2ccc(-c3c4ccccc4c(-c4ccc5ccccc5c4)c4ccccc34)cc21]

Under an argon atmosphere, 2-bromo-7-iodo-9,9-dimethyl fluorene (9.0 g, 22.6 mmol), 4,4,5,5-tetramethyl-2-[10-(2-naphthyl)anthracene-9-yl]-1,3,2-dioxaborolane (10.7 g, 24.8 mmol), sodium carbonate (2.86 g, 27.0 mmol), toluene (120 mL), and water (60 mL) are added in a reaction vessel and then, stirred for 30 minutes. Subsequently, palladium acetate (0.10 g, 0.45 mmol) and XPhos (0.37 g, 0.90 mmol) are added thereto and then, heated and stirred under reflux for 17 hours.

After completion of the reaction, the sample is transferred to a separatory funnel and extracted with toluene. The organic layer is separated and dried using MgSO₄, and then the resultant is filtered and concentrated. The concentrated residue is purified by silica gel column chromatography to obtain 10.98 g of a white solid (Intermediate 5-1) (yield: 84%).

### Synthesis of Intermediate 5-2

Intermediate 5-2 is synthesized according to the reaction scheme.

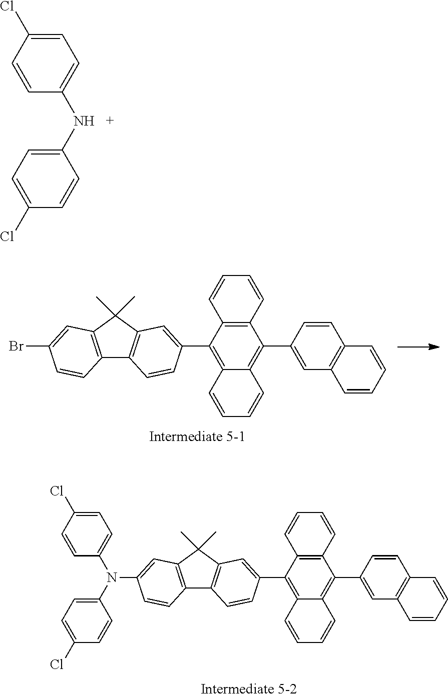

Under an argon atmosphere, Intermediate 5-1 (11.0 g, 19.1 mmol), bis(4-chlorophenyl)amine (5.0 g, 21.0 mmol), t-butoxy sodium (2.2 g, 22.9 mmol), and toluene (160 mL) are added to a reaction vessel and, stirred for 30 minutes. Subsequently, tris(dibenzylideneacetone) dipalladium (0) (Pd₂(dba)₃, 0.17 g, 0.19 mmol) and 1,1′-bis(diphenyl phosphino)ferrocene (dppf, 0.42 g, 0.76 mmol) are added to the reaction mixture and heated and stirred under reflux for 4 hours.

After completion of the reaction, the reaction liquid mixture is allowed to cool to room temperature. Thereafter, the reaction mixture is filtered using Celite®, and impurities are separated by filtration. Then, after distilling off the solvent in vacuo from the filtrate, the resultant is purified by column chromatography to obtain a solid of Intermediate 5-2 (3.75 g, yield: 26%).

### Synthesis of Compound 5

Compound 5 is synthesized according to the reaction scheme.

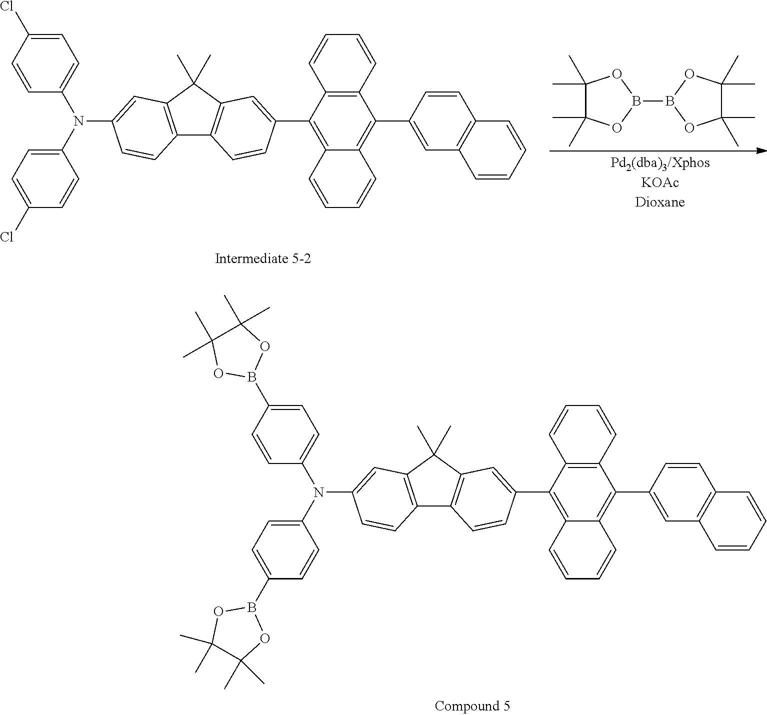

Under an argon atmosphere, Intermediate 5-2 (3.75 g, 5.1 mmol), bispinacolate diboron (5.2 g, 20.4 mmol), potassium acetate (3.0 g, 30.7 mmol), and dioxane (80 ml) are added to a reaction vessel and stirred for 30 minutes. Subsequently, tris(dibenzylideneacetone)dipalladium (0) (Pd₂(dba)₃, 0.14 g, 0.15 mmol) and XPhos (0.29 g, 0.61 mmol) are added to the reaction mixture and heated and stirred under reflux for 5 hours.

After completion of the reaction, the reaction liquid mixture is allowed to cool to room temperature. Thereafter, the reaction mixture is filtered using Celite®, and impurities are separated by filtration. Then, after distilling off the solvent in vacuo from the filtrate, the resultant is purified by column chromatography to obtain Compound 5 (3.8 g, yield: 81%).

### Synthesis Example 6

### Synthesis of Intermediate 6-1

Intermediate 6-1 is synthesized according to the reaction scheme.

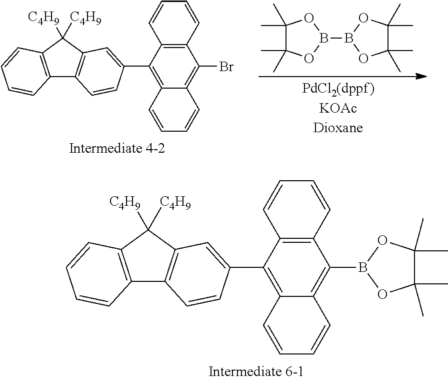

Under an argon atmosphere, Intermediate 4-2 (8.2 g, 15.3 mmol), bispinacolate diboron (11.7 g, 46.1 mmol), potassium acetate (9.1 g, 92.2 mmol), and dioxane (80 ml) are added to a reaction vessel and stirred for 30 minutes. Subsequently, [1,1′-bis(diphenyl phosphino)ferrocene]dichloro palladium(II) (PdCl₂(dppf), 0.67 g, 0.922 mmol) is added to the reaction mixture and heated and stirred under reflux for 5 hours.

After completion of the reaction, the reaction liquid mixture is allowed to cool to room temperature. Thereafter, the reaction mixed solution is filtered using Celite® and impurities are separated by filtration. Then, after distilling off the solvent in vacuo from the filtrate, the resultant is purified by column chromatography to obtain Intermediate 6-1 (7.05 g, yield: 79%).

### Synthesis of Intermediate 6-2

Intermediate 6-2 is synthesized according to the reaction scheme.

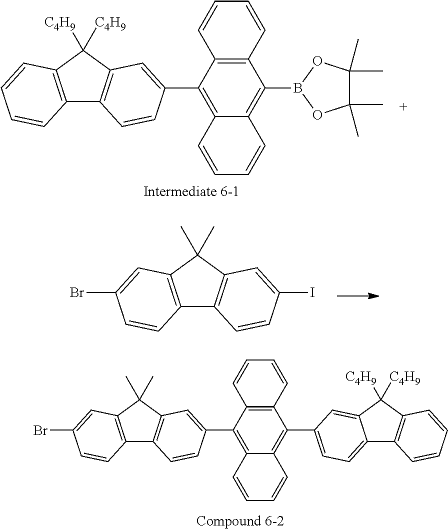

Under an argon atmosphere, 2-bromo-7-iodine-9,9-dimethyl fluorene (4.4 g, 11.0 mmol), Intermediate 6-1 (7.0 g, 12.1 mmol), sodium carbonate (1.4 g, 13.2 mmol), toluene (100 mL), and water (50 mL) added to a reaction vessel and stirred for 30 minutes. Subsequently, palladium acetate (0.098 g, 0.44 mmol) and XPhos (0.36 g, 0.88 mmol) are added to the reaction mixture and heated and stirred under reflux for 12 hours.

After completion of the reaction, the sample is transferred to a separatory funnel and extracted with toluene. The organic layer is separated and dried using MgSO₄, and then the resultant is filtered and concentrated. The concentrated residue is purified by silica gel column chromatography to obtain Intermediate 6-2 (6.96 g, yield: 87%).

### Synthesis of Intermediate 6-3

Intermediate 6-3 is synthesized according to the reaction scheme.

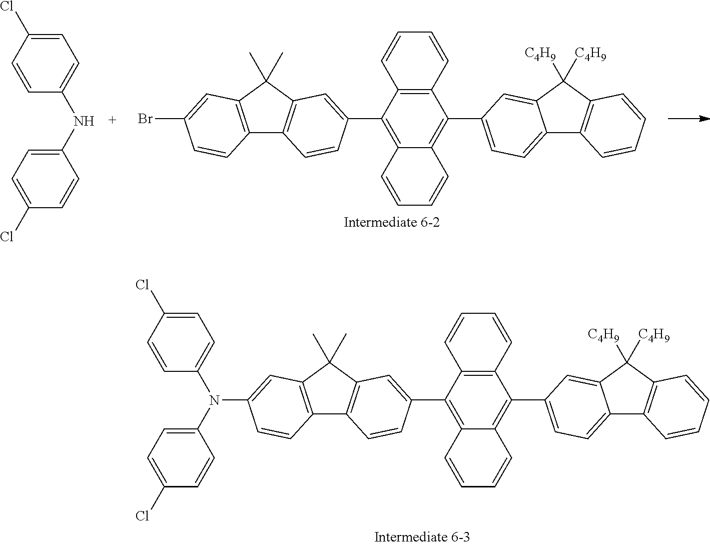

Under an argon atmosphere, Intermediate 6-2 (7.0 g, 9.6 mmol), bis(4-chlorophenyl)amine (2.3 g, 9.6 mmol), t-butoxy sodium (1.1 g, 11.5 mmol), and toluene (200 mL) are added to a reaction vessel and stirred for 30 minutes. Subsequently, tris(dibenzylideneacetone) dipalladium (0) (Pd₂(dba)₃, 0.044 g, 0.048 mmol), and (±)-2,2′-bis(diphenyl phosphino)-1,1′-binaphthyl (rac-BINAP, 0.090 g, 0.144 mmol) are added to the reaction mixture and heated and stirred under reflux for 4 hours.

After completion of the reaction, the reaction liquid mixture is allowed to cool to room temperature. Thereafter, the reaction mixed solution is filtered using Celite® and impurities are separated by filtration. Then, after distilling off the solvent in vacuo from the filtrate, the resultant is purified by column chromatography to obtain a solid of Intermediate 6-3 (2.07 g, yield: 24%).

### Synthesis of Compound 6

Compound 6 is synthesized according to the reaction scheme.

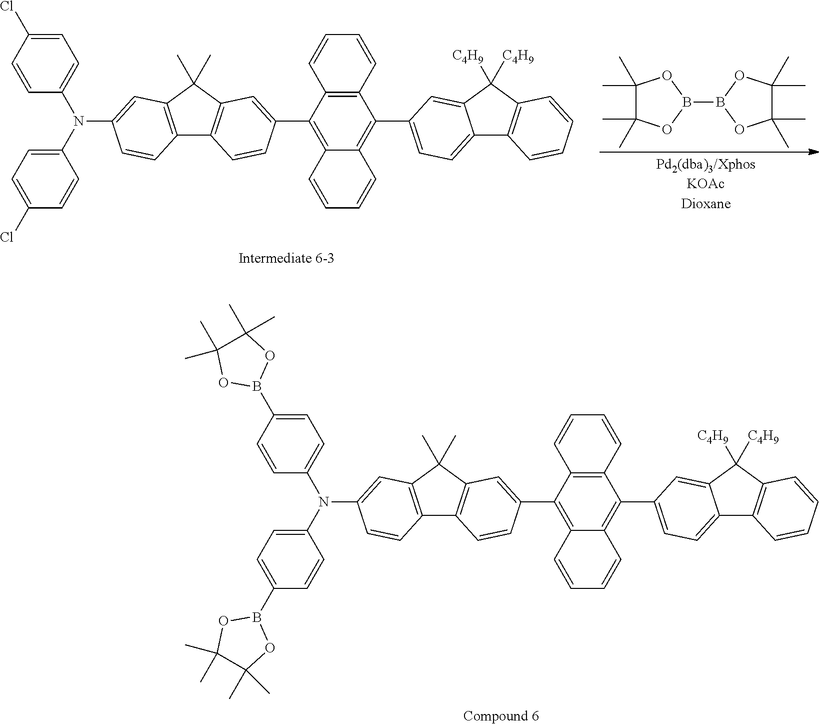

Under an argon atmosphere, Intermediate 6-3 (2.10 g, 2.4 mmol), bispinacolate diboron (2.4 g, 9.5 mmol), potassium acetate (1.4 g, 14.3 mmol), and dioxane (80 ml) are added to a reaction vessel and stirred for 30 minutes. Subsequently, tris(dibenzylideneacetone) dipalladium (0) (Pd₂(dba)₃, 0.065 g, 0.07 mmol) and XPhos (0.13 g, 0.28 mmol) are added to the reaction mixture and heated and stirred under reflux for 6 hours.

After completion of the reaction, the reaction liquid mixture is allowed to cool to room temperature. Thereafter, the reaction mixture is filtered using Celite®, and impurities are separated by filtration. Then, after distilling off the solvent in vacuo from the filtrate, the resultant is purified by column chromatography to obtain Compound 6 (2.2 g, yield: 88%).

### Synthesis Example 7

### Synthesis of Intermediate 7-1

Intermediate 7-1 is synthesized according to the reaction scheme.

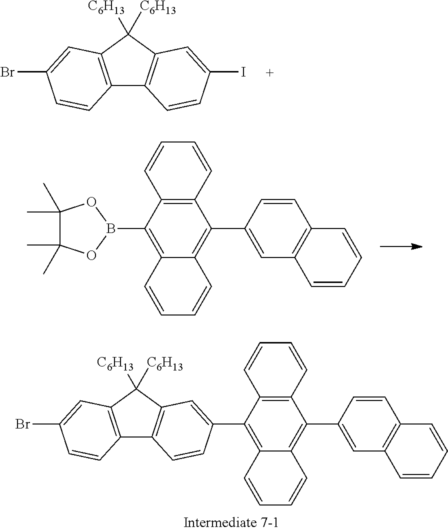

Under an argon atmosphere, 2-bromo-7-iodo-9,9-dihexylfluorene (6.0 g, 11.1 mmol), 4,4,5,5-tetramethyl-2-[10-(2-naphthyl)anthracene-9-yl]-1,3,2-dioxaborolane (4.5 g, 10.6 mmol), sodium carbonate (1.4 g, 13.3 mmol), toluene (100 mL), EtOH (10 mL), and water (50 mL) are added to a reaction vessel and stirred for 30 minutes. Subsequently, tetrakis(triphenylphosphine)palladium (0) (Pd[PPh₃]4) (0.77 g, 0.067 mmol) is added to the reaction mixture and heated and stirred under reflux for 8 hours.

After completion of the reaction, the sample is transferred to a separatory funnel and extracted with toluene. The organic layer is separated and dried using MgSO₄, and then the resultant is filtered and concentrated. The concentrated residue is purified by silica gel column chromatography to obtain Intermediate 7-1 (4.87 g, yield: 61%).

### Synthesis of Intermediate 7-2

Intermediate 7-2 is synthesized according to the reaction scheme.

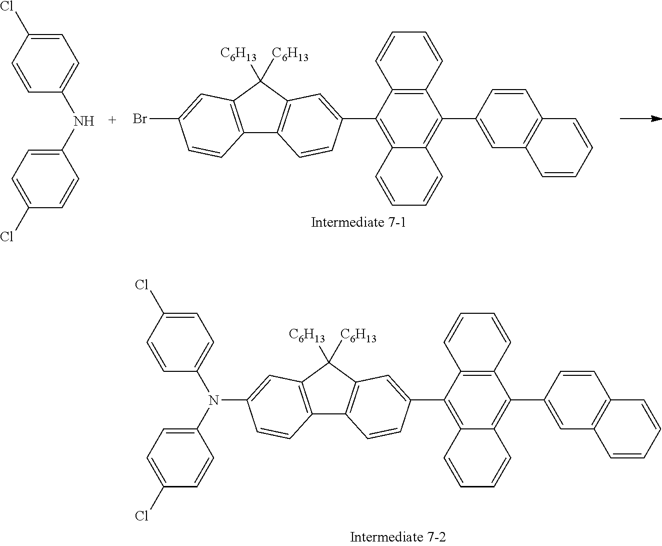

Under an argon atmosphere, Intermediate 7-1 (4.9 g, 6.8 mmol), bis(4-chlorophenyl)amine (1.6 g, 6.8 mmol), t-butoxy sodium (0.78 g, 8.1 mmol), and toluene (100 mL) are added to a reaction vessel and stirred for 30 minutes. Subsequently, tris(dibenzylideneacetone) dipalladium (0) (Pd₂(dba)₃, 0.016 g, 0.017 mmol) and (±)-2,2′-bis(diphenyl phosphino)-1,1′-binaphthyl (rac-BINAP, 0.032 g, 0.051 mmol) are added to the reaction mixture and heated and stirred under reflux for 25 hours.

After completion of the reaction, the reaction liquid mixture is allowed to cool to room temperature. Thereafter, the reaction mixed solution is filtered using Celite® and impurities are separated by filtration. Then, after distilling off the solvent in vacuo from the filtrate, the resultant is purified by column chromatography to obtain a solid of Intermediate 7-2 (3.91 g, yield: 65%).

### Synthesis of Compound 7

Compound 7 is synthesized according to the reaction scheme.

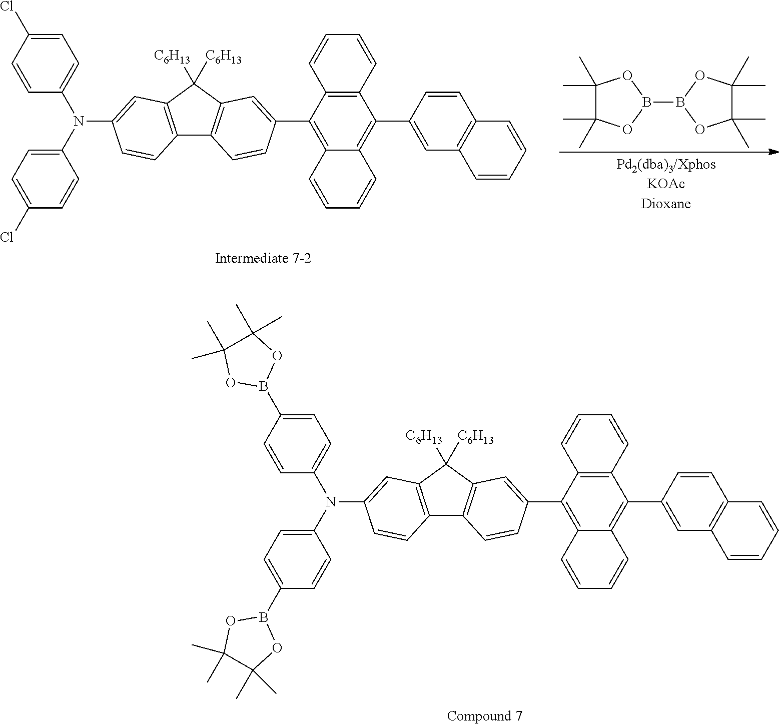

Under an argon atmosphere, Intermediate 7-2 (6.35 g, 7.3 mmol) bispinacolate diboron (9.2 g, 36.4 mmol), potassium acetate (4.3 g, 43.6 mmol), and dioxane (150 ml) are added to a reaction vessel and then, stirred for 30 minutes. Subsequently, tris(dibenzylideneacetone) dipalladium (0) (Pd₂(dba)₃, 0.19 g, 0.22 mmol) and XPhos (0.42 g, 0.87 mmol) are added to the reaction mixture and heated and stirred under reflux for 5 hours.

After completion of the reaction, the reaction liquid mixture is allowed to cool to room temperature. Thereafter, the reaction mixed solution is filtered using Celite® and impurities are separated by filtration. Then, after distilling off the solvent in vacuo from the filtrate, the resultant is purified by column chromatography to obtain Compound 7 (6.7 g, yield: 87%).

### Synthesis Example 8

### Synthesis of Intermediate 8-1

Intermediate 8-1 is synthesized according to the reaction scheme.

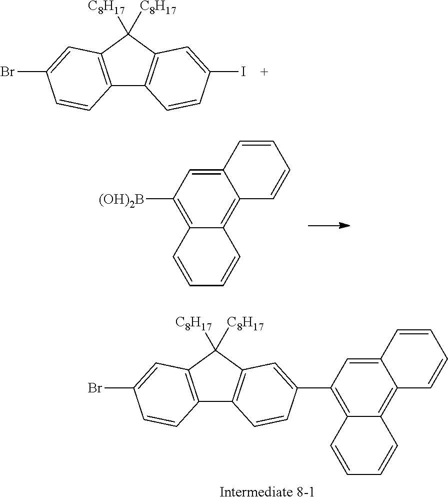

Under an argon atmosphere, 2-bromo-7-iodo-9,9-dioctyl fluorene (6.0 g, 10.1 mmol), 9-phenanthrene boronic acid (2.1 g, 9.6 mmol), sodium carbonate (1.4 g, 13.3 mmol), toluene (100 mL), EtOH (10 mL), and water (50 mL) are added to a reaction vessel and stirred for 30 minutes.

Subsequently, tetrakis(triphenylphosphine)palladium (0) (Pd[PPh₃]4) (0.70 g, 0.061 mmol) is added to the reaction mixture and heated and stirred under reflux for 5 hours.

After completion of the reaction, the sample is transferred to a separatory funnel and extracted with toluene. The organic layer is separated and dried using MgSO₄, and then the resultant is filtered and concentrated. The concentrated residue is purified by silica gel column chromatography to obtain Intermediate 8-1 (6.21 g, yield: 95%).

### Synthesis of Intermediate 8-2

Intermediate 8-2 is synthesized according to the reaction scheme.

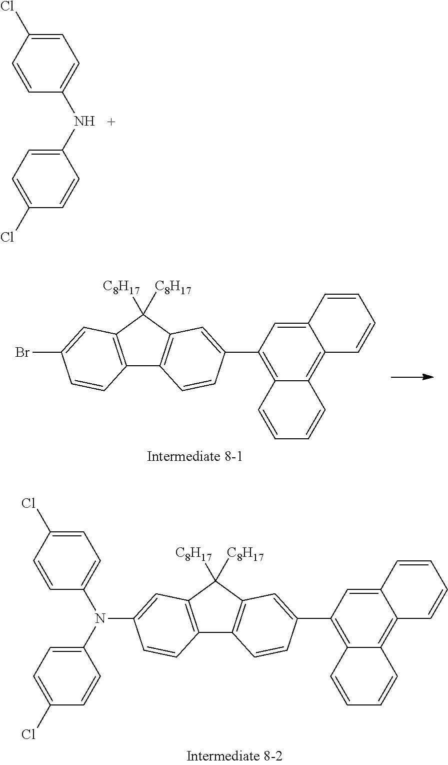

Under an argon atmosphere, Intermediate 8-1 (6.2 g, 9.6 mmol), bis(4-chlorophenyl)amine (2.3 g, 9.6 mmol), t-butoxy sodium (1.11 g, 11.5 mmol), and toluene (150 mL) are added to a reaction vessel and stirred for 30 minutes. Subsequently, tris(dibenzylideneacetone)dipalladium (0) (Pd₂(dba)₃, 0.11 g, 0.12 mmol), and 1,1′-bis(diphenyl phosphino)ferrocene (dppf, 0.27 g, 0.48 mmol) are added to the reaction mixture and heated and stirred under reflux for 7 hours.

After completion of the reaction, the reaction liquid mixture is allowed to cool to room temperature. Thereafter, the reaction mixed solution is filtered using Celite® and impurities are separated by filtration. Then, after distilling off the solvent in vacuo from the filtrate, the resultant is purified by column chromatography to obtain a solid of Intermediate 8-2 (3.71 g, yield: 48%).

### Synthesis of Compound 8

Compound 8 is synthesized according to the reaction scheme.

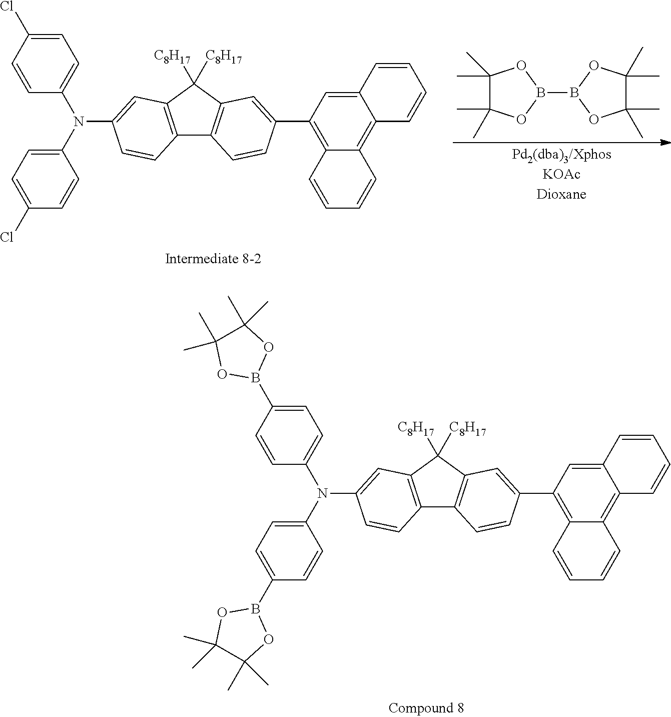

Under an argon atmosphere, Intermediate 8-2 (3.71 g, 4.6 mmol), bispinacolate diboron (4.7 g, 18.4 mmol), potassium acetate (2.7 g, 27.7 mmol), and dioxane (100 ml) are added to a reaction vessel and stirred for 30 minutes. Subsequently, tris(dibenzylideneacetone) dipalladium (0) (Pd₂(dba)₃, 0.13 g, 0.14 mmol) and XPhos (0.26 g, 0.55 mmol) are added to the reaction mixture and heated and stirred under reflux for 5 hours.

After completion of the reaction, the reaction liquid mixture is allowed to cool to room temperature. Thereafter, the reaction mixture is filtered using Celite® and impurities are separated by filtration. Then, after distilling off the solvent in vacuo from the filtrate, the resultant is purified by column chromatography to obtain Compound 8 (4.2 g, yield: 91%).

### Synthesis Example 9

### Synthesis of Intermediate 9-1

Intermediate 9-1 is synthesized according to the reaction scheme.

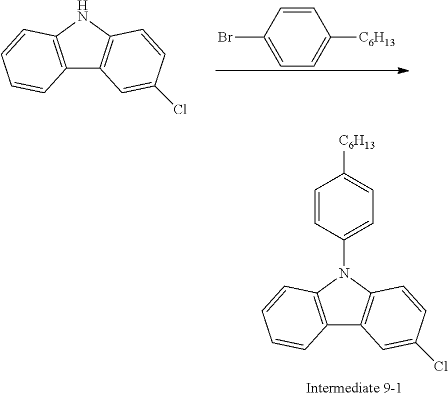

In a 1 L-four-necked flask, 3-chloro-carbazole (42.2 g, 0.209 mol), 4-bromohexylbenzene (50.2 g, 0.208 mol), tris(dibenzylideneacetone)dipalladium (Pd₂(dba)₃) (9.57 g), tri-tert-butylphosphonium tetrafluoroborate (P(t-Bu)₃·BF4) (4.55 g), t-butoxy sodium (40.2 g), and toluene (500 mL) are added to the reaction flask, and heated and stirred at 100° C. for 8 hours under a nitrogen atmosphere. The resultant mixture is allowed to cool to room temperature (25° C.), and insoluble matters are removed using Celite®. The solvent is removed from the filtrate by distillation under reduced pressure, and purified by column chromatography to obtain Intermediate 9-1 (56.5 g, 0.157 mol).

### Synthesis of Intermediate 9-2

Intermediate 9-2 is synthesized according to the reaction scheme.

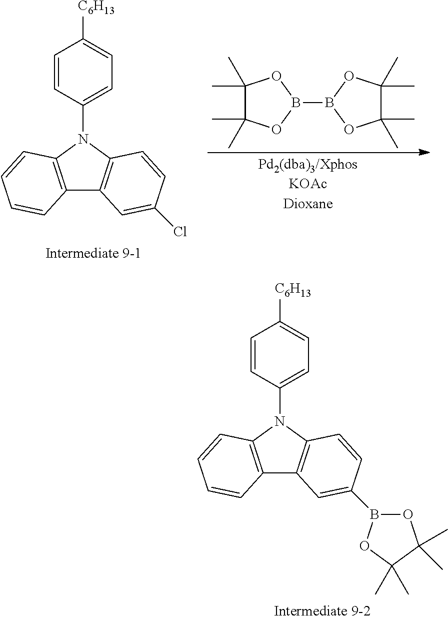

Under an argon atmosphere, Intermediate 9-1 (6.3 g, 17.3 mmol), bispinacolate diboron (8.8 g, 34.6 mmol), potassium acetate (5.1 g, 51.9 mmol), and dioxane (80 ml) are added to a reaction vessel and stirred for 30 minutes. Subsequently, tris(dibenzylideneacetone)dipalladium (Pd₂(dba)₃) (0.47 g, 0.52 mmol) and Xphos (0.99 g, 2.08 mmol) are added to the reaction mixture and heated and stirred under reflux for 8 hours.

After the reaction is completed, the reaction liquid mixture is allowed to cool to room temperature. Thereafter, the reaction mixture is filtered using Celite® and impurities are separated by filtration. Then, after distilling off the solvent in vacuo from the filtrate, the resultant is purified by column chromatography to obtain Intermediate 9-2 (4.7 g, yield: 60%).

### Synthesis of Compound 9

Compound 9 is synthesized according to the reaction scheme.

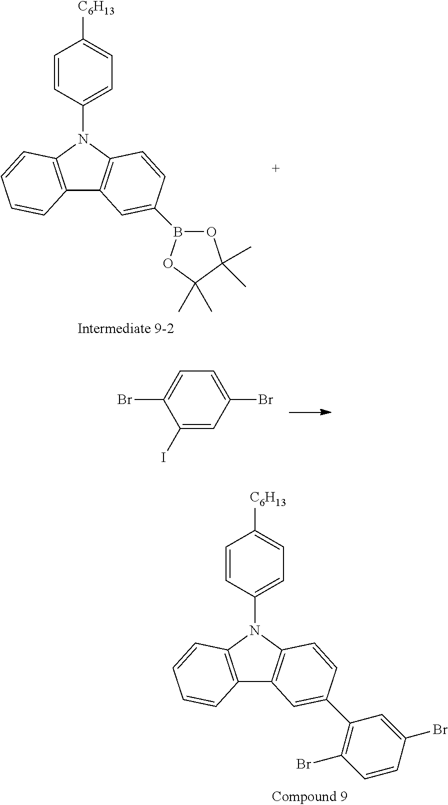

Under an argon atmosphere, Intermediate 9-2 (9.0 g, 19.8 mmol), 1,4-dibromo-2-iodobenzene (10.8 g, 29.8 mmol), sodium carbonate (3.2 g, 29.8 mmol), dioxane (120 mL), and water (60 mL) are added to a reaction vessel and stirred for 30 minutes. Subsequently, tetrakis(triphenylphosphine)palladium (0) (Pd[PPh₃]₄) (1.15 g, 0.99 mmol) is added to the reaction mixture and heated and stirred under reflux for 12 hours.

After completion of the reaction, the sample is cooled to room temperature and then is transferred to a separatory funnel and extracted with toluene. The organic layer is separated and dried using MgSO₄, and then the resultant is filtered and concentrated. The concentrated residue is purified by silica gel column chromatography to obtain 4.5 g of a white solid (Compound 9) (yield: 73%).

### Example 1-1

### Synthesis of Polymer Compound A-1

Under an argon atmosphere, Compound 1 (1.575 g) according to Synthesis Example 1, 2,7-dibromo-9,9-di-n-octyl fluorene (1.080 g), palladium acetate (8.8 mg), tris(2-methoxy phenyl)phosphine (83.3 mg), toluene (53 mL), and a 20 wt % tetraethylammonium hydroxide aqueous solution (10.15 g) are added to a reaction vessel and then, refluxed for 6 hours. Subsequently, phenyl boronic acid (238.4 mg), bis(triphenylphosphine)palladium(II) dichloride (83.0 mg), and a 20 wt % tetraethylammonium hydroxide aqueous solution (10.15 g) are added to the reaction mixture and heated under reflux for 6 hours. After removing an aqueous layer, sodium N,N-diethyldithiocarbamate trihydrate (6.53 g), and ion-exchanged water (60 mL) are added to the reaction mixture and stirred at 85° C. for 6 hours.

After separating the organic layer from the aqueous layer, the organic layer is washed with water, a 3 wt % aqueous acetic acid solution, and water. The organic layer is added dropwise to methanol to precipitate and separate the polymer compound, and dried to obtain a solid.

The obtained solid is dissolved in toluene, passed through column chromatography packed with silica gel/alumina, and the solvent is distilled off under reduced pressure. The resulting liquid is added dropwise to methanol, and the precipitated solid is separated and dried to obtain Polymer Compound A-1 (0.90 g).

The weight average molecular weight (Mw) and polydispersity (Mw/Mn) of the obtained Polymer Compound A-1 are measured by SEC. The weight average molecular weight (Mw) and polydispersity (Mw/Mn) of Polymer Compound A-1 are 138,900 g/mol and 3.34, respectively.

Polymer Compound A-1 obtained in this way is presumed to be a polymer compound obtained by alternately polymerizing the structural unit X and the structural unit Y according to an embodiment, having the following repeating units from the structures of the monomers.

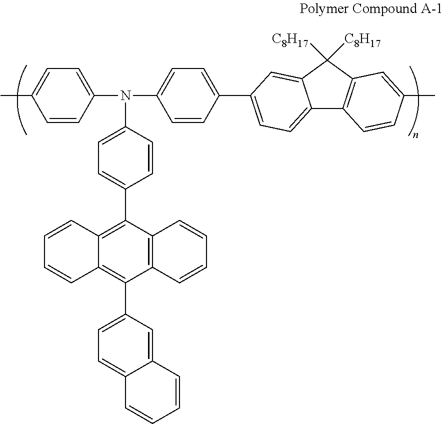

### Example 1-2

### Synthesis of Polymer Compound A-2

Under an argon atmosphere, Compound 2 (1.727 g) according to Synthesis Example 2, 2,7-dibromo-9,9-di-n-octyl fluorene (1.094 g), palladium acetate (9.0 mg), tris (2-methoxy phenyl)phosphine (84.4 mg), toluene (56 mL), and a 20 mass % tetraethylammonium hydroxide aqueous solution (10.28 g) are added to a reaction vessel and refluxed for 6 hours. Subsequently, phenyl boronic acid (241.1 mg), bis(triphenylphosphine)palladium(II) dichloride (84.0 mg), and a 20 wt % tetraethylammonium hydroxide aqueous solution (10.28 g) are added to the reaction mixture and heated under reflux for 7 hours. After removing an aqueous layer, sodium N,N-diethyldithiocarbamate trihydrate (6.53 g) and ion-exchanged water (60 mL) are added to the reaction mixture and then, stirred at 85° C. for 2 hours. After separating the organic layer from the aqueous layer, the organic layer is washed with water, a 3 wt % aqueous acetic acid solution, and water. The organic layer is added dropwise to methanol to precipitate the polymer compound, and dried to obtain a solid. This solid is dissolved in toluene, passed through column chromatography packed with silica gel/alumina, and the solvent is distilled off under reduced pressure. The resulting liquid is added dropwise to methanol, and the precipitated solid is separated and dried to obtain Polymer Compound A-2 (1.06 g).

The weight average molecular weight (Mw) and polydispersity (Mw/Mn) of the obtained Polymer Compound A-2 are measured by SEC. As a result, the weight average molecular weight (Mw) and polydispersity (Mw/Mn) of Polymer Compound A-2 are 40,900 g/mol and 2.49, respectively.

Polymer Compound A-2 obtained in this way is presumed to be a polymer compound obtained by alternately polymerizing the structural unit X and the structural unit Y according to an embodiment, having the following repeating units from the structures of the monomers.

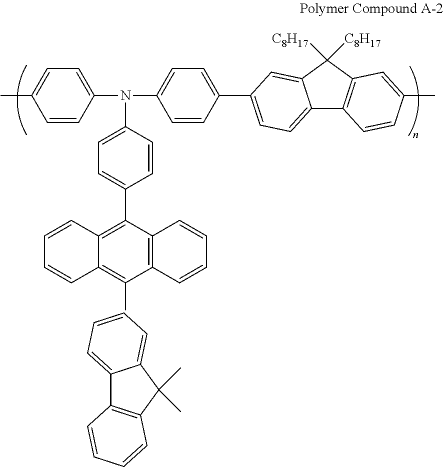

### Example 1-3

### Synthesis of Polymer Compound A-3

Under an argon atmosphere, Compound 3 (1.724 g) according to Synthesis Example 3, 2,7-dibromo-9,9-di-n-octyl fluorene (1.105 g), palladium acetate (9.0 mg), tris(2-methoxy phenyl)phosphine (85.2 mg), toluene (57 mL), and a 20 wt % tetraethylammonium hydroxide aqueous solution (10.39 g) are added to a reaction vessel and refluxed for 6 hours. Subsequently, phenyl boronic acid (243.8 mg), bis(triphenylphosphine)palladium(II) dichloride (84.9 mg), and a 20 wt % tetraethylammonium hydroxide aqueous solution (10.39 g) are added to the reaction mixture and heated under reflux for 7 hours. After removing an aqueous layer, sodium N,N-diethyldithiocarbamate trihydrate (6.59 g) and ion-exchanged water (60 mL) are added to the reaction mixture and stirred at 85° C. for 2 hours. After separating the organic layer from the aqueous layer, the organic layer is washed with water, a 3 wt % aqueous acetic acid solution, and water. The organic layer is added dropwise to methanol to precipitate the polymer compound, and dried to obtain a solid. This solid is dissolved in toluene, passed through column chromatography packed with silica gel/alumina, and the solvent is distilled off under reduced pressure. The resulting liquid is added dropwise to methanol, and the precipitated solid is separated and dried to obtain Polymer Compound A-3 (1.40 g).

The weight average molecular weight (Mw) and polydispersity (Mw/Mn) of the obtained Polymer Compound A-3 are measured by SEC. As a result, the weight average molecular weight (Mw) and polydispersity (Mw/Mn) of Polymer Compound A-3 are 132,900 g/mol and 3.20, respectively.

Polymer Compound A-3 obtained in this way is presumed to be a polymer compound obtained by alternately polymerizing the structural unit X and the structural unit Y according to an embodiment, having the following repeating units from the structures of the monomers.

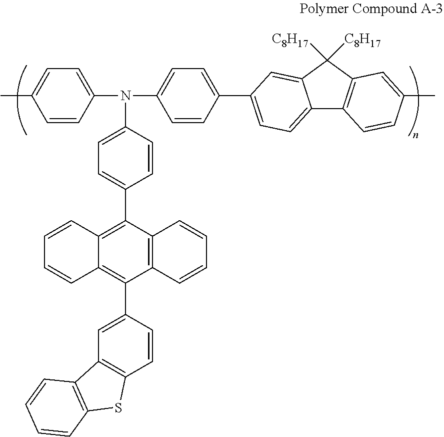

### Example 1-4

### Synthesis of Polymer Compound A-4

Under an argon atmosphere, Compound 4 (1.748 g) according to Synthesis Example 4, 2,7-dibromo-9,9-di-n-octyl fluorene (1.009 g), palladium acetate (8.3 mg), tris(2-methoxy phenyl)phosphine (77.8 mg), toluene (55 mL), and a 20 mass % tetraethylammonium hydroxide aqueous solution (9.49 g) are added to a reaction vessel and refluxed for 6 hours. Subsequently, phenyl boron (222.7 mg), bis(triphenylphosphine)palladium(II) dichloride (77.5 mg), and a 20 wt % tetraethylammonium hydroxide aqueous solution (9.49 g) are added to the reaction mixture and then, heated under reflux for 6 hours. After removing an aqueous layer, sodium N,N-diethyldithiocarbamate trihydrate (6.53 g) and ion-exchanged water (60 mL) are added to the reaction mixture and then, stirred at 85° C. for 2 hours. After separating the organic layer from the aqueous layer, the organic layer is washed with water, a 3 wt % aqueous acetic acid solution, and water. The organic layer is added dropwise to methanol to precipitate and separate the polymer compound, and dried to obtain a solid. This solid is dissolved in toluene, passed through column chromatography packed with silica gel/alumina, and the solvent is distilled off under reduced pressure. The resulting liquid is added dropwise to methanol, and the precipitated solid is separated and dried to obtain Polymer Compound A-4 (1.22 g).

The weight average molecular weight (Mw) and polydispersity (Mw/Mn) of the obtained Polymer Compound A-4 are measured by SEC. As a result, the weight average molecular weight (Mw) and polydispersity (Mw/Mn) of Polymer Compound A-4 are 76,900 g/mol and 2.38, respectively.

Polymer Compound A-4 obtained in this way is presumed to be a polymer compound obtained by alternately polymerizing the structural unit X and the structural unit Y according to an embodiment, having the following repeating units from the structures of the monomers.

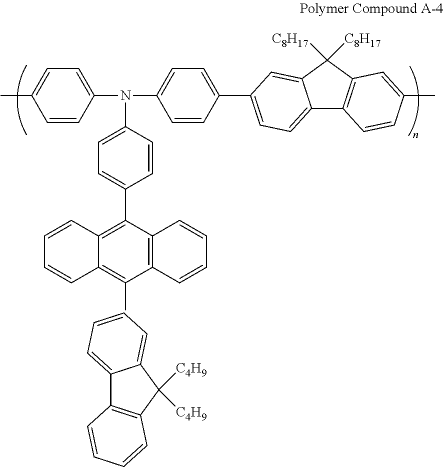

### Example 1-5

### Synthesis of Polymer Compound A-5

Under an argon atmosphere, Compound 5 (1.740 g) according to Synthesis Example 5, 2,7-dibromo-9,9-di-n-octyl fluorene (1.042 g), palladium acetate (8.5 mg), tris(2-methoxy phenyl)phosphine (80.3 mg), toluene (56 mL), and a 20 mass % tetraethylammonium hydroxide aqueous solution (9.79 g) are added to a reaction vessel and then, refluxed for 6 hours. Subsequently, phenyl boronic acid (229.9 mg), bis(triphenylphosphine)palladium(II) dichloride (80 mg), and a 20 wt % tetraethylammonium hydroxide aqueous solution (9.79 g) are added to the reaction mixture and then, heated under reflux for 7 hours. After removing an aqueous layer, sodium N,N-diethyldithiocarbamate trihydrate (6.55 g) and ion-exchanged water (60 mL) are added to the reaction mixture and stirred at 85° C. for 2 hours. After separating the organic layer from the aqueous layer, the organic layer is washed with water, a 3 wt % aqueous acetic acid solution, and water. The organic layer is added dropwise to methanol to precipitate and separate the polymer compound, and dried to obtain a solid. This solid is dissolved in toluene, passed through column chromatography packed with silica gel/alumina, and the solvent is distilled off under reduced pressure. The resulting liquid is added dropwise to methanol, and the precipitated solid is separated and dried to obtain Polymer Compound A-5 (1.21 g).

The weight average molecular weight (Mw) and polydispersity (Mw/Mn) of the obtained Polymer Compound A-5 are measured by SEC. As a result, the weight average molecular weight (Mw) and polydispersity (Mw/Mn) of Polymer Compound A-5 are 90,000 g/mol and 2.50, respectively.

Polymer Compound A-5 obtained in this way is presumed to be a polymer compound obtained by alternately polymerizing the structural unit X and the structural unit Y according to an embodiment, having the following repeating units from the structures of the monomers.

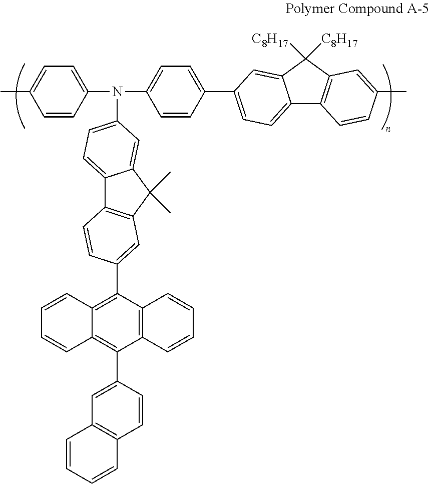

### Example 1-6

### Synthesis of Polymer Compound A-6

Under an argon atmosphere, Compound 6 (1.621 g) according to Synthesis Example 6, 2,7-dibromo-9,9-di-n-dodecyl fluorene (1.005 g), palladium acetate (6.8 mg), tris(2-methoxy phenyl)phosphine (64.3 mg), toluene (53 mL), and a 20 wt % tetraethylammonium hydroxide aqueous solution (7.84 g) are added to a reaction vessel and refluxed for 6 hours. Subsequently, phenyl boronic acid (184 mg), bis(triphenylphosphine)palladium(II) dichloride (64.1 mg), and a 20 wt % tetraethylammonium hydroxide aqueous solution (7.84 g) are added to the reaction mixture and heated under reflux for 7 hours. After removing an aqueous layer, sodium N,N-diethyldithiocarbamate trihydrate (6.53 g) and ion-exchanged water (60 mL) are added to the reaction mixture and then, stirred at 85° C. for 2 hours. After separating the organic layer from the aqueous layer, the organic layer is washed with water, a 3 wt % aqueous acetic acid solution, and water. The organic layer is added dropwise to methanol to precipitate and separate the polymer compound, and dried to obtain a solid. This solid is dissolved in toluene, passed through column chromatography packed with silica gel/alumina, and the solvent is distilled off under reduced pressure. The resulting liquid is added dropwise to methanol, and the precipitated solid is separated and dried to obtain Polymer Compound A-6 (1.01 g).

The weight average molecular weight (Mw) and polydispersity (Mw/Mn) of the obtained Polymer Compound A-6 are measured by SEC. As a result, the weight average molecular weight (Mw) and polydispersity (Mw/Mn) of Polymer Compound A-6 are 53,500 g/mol and 2.81, respectively.

Polymer Compound A-6 obtained in this way is presumed to be a polymer compound obtained by alternately polymerizing the structural unit X and the structural unit Y according to an embodiment, having the following repeating units from the structures of the monomers.

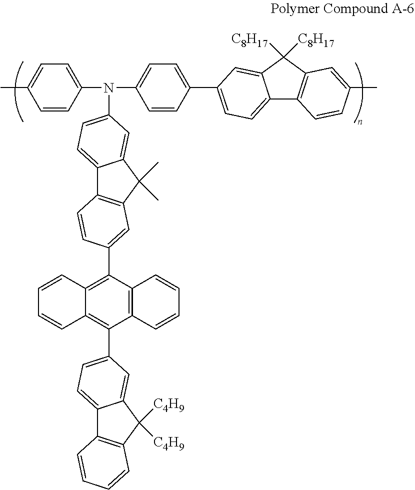

### Example 1-7

### Synthesis of Polymer Compound A-7

Under an argon atmosphere, Compound 7 (1.771 g) according to Synthesis Example 7, 2,7-dibromo-9,9-di-n-octyl fluorene (0.920 g), palladium acetate (7.5 mg), tris(2-methoxy phenyl)phosphine (70.9 mg), toluene (54 mL), and a 20 mass % tetraethylammonium hydroxide aqueous solution (8.64 g) are added to a reaction vessel and refluxed for 6 hours. Subsequently, phenyl boronic acid (202.9 mg), bis(triphenylphosphine)palladium(II) dichloride (70.6 mg), and a 20 wt % tetraethylammonium hydroxide aqueous solution (8.64 g) are added to the reaction mixture and heated under reflux for 7 hours. After removing an aqueous layer, sodium N,N-diethyldithiocarbamate trihydrate (6.53 g) and ion-exchanged water (60 mL) are added to the reaction mixture and then, stirred at 85° C. for 2 hours. After separating the organic layer from the aqueous layer, the organic layer is washed with water, a 3 wt % aqueous acetic acid solution, and water. The organic layer is added dropwise to methanol to precipitate and separate the polymer compound, and dried to obtain a solid. This solid is dissolved in toluene, passed through column chromatography packed with silica gel/alumina, and the solvent is distilled off under reduced pressure. The resulting liquid is added dropwise to methanol, and the precipitated solid is separated and dried to obtain Polymer Compound A-7 (1.02 g).

The weight average molecular weight (Mw) and polydispersity (Mw/Mn) of the obtained Polymer Compound A-7 are measured by SEC. As a result, the weight average molecular weight (Mw) and polydispersity (Mw/Mn) of Polymer Compound A-7 are 51,800 g/mol and 2.04 respectively.

Polymer Compound A-7 obtained in this way is presumed to be a polymer compound obtained by alternately polymerizing the structural unit X and the structural unit Y according to an embodiment, having the following repeating units from the structures of the monomers.

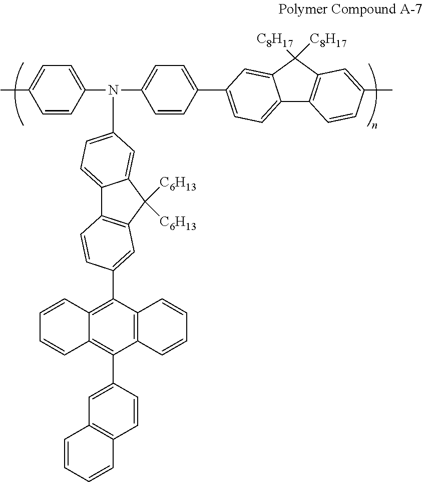

### Example 1-8

### Synthesis of Polymer Compound A-8

Under an argon atmosphere, Compound 7 (2.014 g) according to Synthesis Example 7, 1,3-dibromo-5-dodecyl benzene (0.771 g), palladium acetate (8.6 mg), tris (2-methoxy phenyl)phosphine (80.7 mg), toluene (56 mL), and a 20 mass % tetraethylammonium hydroxide aqueous solution (9.83 g) are added to a reaction vessel and refluxed for 6 hours.

Subsequently, phenylboronic acid (230.8 mg), bis(triphenylphosphine) palladium(II) dichloride (80.3 mg), and a 20 wt % tetraethylammonium hydroxide aqueous solution (9.83 g) are added to the reaction mixture and heated under reflux for 7 hours. After removing an aqueous layer, sodium N,N-diethyldithiocarbamate trihydrate (9.67 g) and ion-exchanged water (60 mL) are added to the reaction mixture and then, stirred at 85° C. for 2 hours. After separating the organic layer from the aqueous layer, the organic layer is washed with water, a 3 wt % aqueous acetic acid solution, and water. The organic layer is added dropwise to methanol to precipitate and separate the polymer compound, and dried to obtain a solid. This solid is dissolved in toluene, passed through column chromatography packed with silica gel/alumina, and the solvent is distilled off under reduced pressure. The obtained liquid is added dropwise to methanol, and the precipitated solid is separated and dried to obtain Polymer Compound A-8 (1.19 g).

The weight average molecular weight (Mw) and polydispersity (Mw/Mn) of the obtained Polymer Compound A-8 are measured by SEC. As a result, the weight average molecular weight (Mw) and polydispersity (Mw/Mn) of Polymer Compound A-8 are 14,300 g/mol and 1.73, respectively.

Polymer Compound A-8 obtained in this way is presumed to be a polymer compound obtained by alternately polymerizing the structural unit X and the structural unit Y according to an embodiment, having the following repeating units from the structures of the monomers.

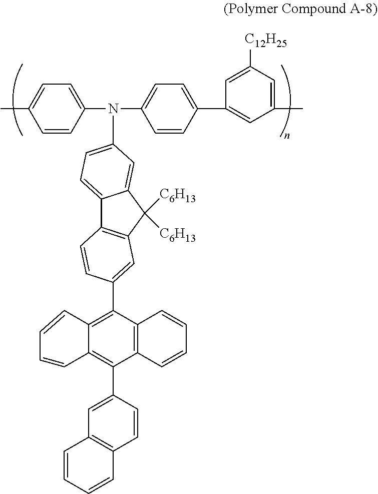

### Example 1-9

### Synthesis of Polymer Compound A-9

Under an argon atmosphere, Compound 7 (1.752 g) according to Synthesis Example 7, Compound 9 (0.931 g), palladium acetate (7.4 mg), tris(2-methoxy phenyl)phosphine (35.1 mg), toluene 54 mL, and a 20 mass % tetraethylammonium hydroxide aqueous solution (8.55 g) are added to a reaction vessel and refluxed for 6 hours. Subsequently, phenyl boronic acid (200.7 mg), bis(triphenylphosphine)palladium(II) dichloride (69.9 mg), and a 20 wt % tetraethylammonium hydroxide aqueous solution (8.55 g) are added to the reaction mixture and heated under reflux for 7 hours. After removing an aqueous layer, sodium N,N-diethyldithiocarbamate trihydrate (8.41 g) and ion-exchanged water (53 mL) are added to the reaction mixture and then, stirred at 85° C. for 2 hours. After separating the organic layer from the aqueous layer, the organic layer is washed with water, a 3 wt % aqueous acetic acid solution, and water. The organic layer is added dropwise to methanol to precipitate and separate the polymer compound, and dried to obtain a solid. This solid is dissolved in toluene, passed through column chromatography packed with silica gel/alumina, and the solvent is distilled off under reduced pressure. The obtained liquid is added dropwise to methanol, and the precipitated solid is separated and dried to obtain Polymer Compound A-9 (1.37 g).

The weight average molecular weight (Mw) and polydispersity (Mw/Mn) of the obtained Polymer Compound A-9 are measured by SEC. As a result, the weight average molecular weight (Mw) and polydispersity (Mw/Mn) of Polymer Compound A-9 are 38,000 g/mol and 1.97, respectively.

Polymer Compound A-9 obtained in this way is presumed to be a polymer compound obtained by alternately polymerizing the structural unit X and the structural unit Y according to an embodiment, having the following repeating units from the structures of the monomers.

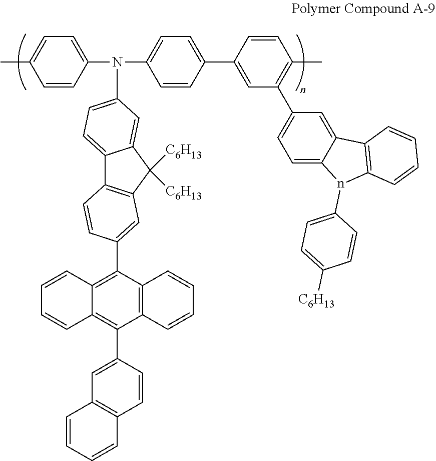

### Example 1-10

### Synthesis of Polymer Compound A-10

Under an argon atmosphere, Compound 8 (1.581 g) according to Synthesis Example 8, 2,7-dibromo-9,9-di-n-octyl fluorene (0.879 g), palladium acetate (7.2 mg), tris(2-methoxy phenyl)phosphine (67.8 mg), toluene (49 mL), and a 20 mass % tetraethylammonium hydroxide aqueous solution (8.26 g) are added to a reaction vessel and refluxed for 6 hours. Subsequently, phenyl boronic acid (194 mg), bis(triphenylphosphine)palladium(II) dichloride (67.5 mg), and a 20 wt % tetraethylammonium hydroxide aqueous solution (8.26 g) are added to the reaction mixture and heated under reflux for 7 hours. After removing an aqueous layer, sodium N,N-diethyldithiocarbamate trihydrate (5.46 g) and ion-exchanged water (54 mL) are added to the reaction mixture and then, stirred at 85° C. for 2 hours. After separating the organic layer from the aqueous layer, the organic layer is washed with water, a 3 wt % aqueous acetic acid solution, and water. The organic layer is added dropwise to methanol to precipitate and separate the polymer compound, and dried to obtain a solid. This solid is dissolved in toluene, passed through column chromatography packed with silica gel/alumina, and the solvent is distilled off under reduced pressure. The resulting liquid is added dropwise to methanol, and the precipitated solid is separated and dried to obtain Polymer Compound A-10 (1.02 g).

The weight average molecular weight (Mw) and polydispersity (Mw/Mn) of the obtained Polymer Compound A-10 are measured by SEC. As a result, the weight average molecular weight (Mw) and polydispersity (Mw/Mn) of Polymer Compound A-10 are 226,900 g/mol and 10.68, respectively.

Polymer Compound A-10 obtained in this way is presumed to be a polymer compound obtained by alternately polymerizing the structural unit X and the structural unit Y according to an embodiment, having the following repeating units from the structures of the monomers.

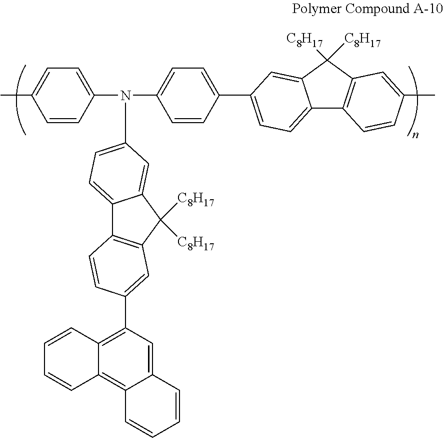

### Example 1-11

### Synthesis of Polymer Compound A-11

Under an argon atmosphere, Compound 1 (1.525 g) according to Synthesis Example 1, 2,7-dibromo-9,9-di-n-dodecyl fluorene (1.260 g), palladium acetate (8.6 mg), tris(2-methoxy phenyl)phosphine (80.7 mg), toluene (56 mL), and a 20 mass % tetraethylammonium hydroxide aqueous solution (9.83 g) are added to a reaction vessel and refluxed for 6 hours. Subsequently, phenyl boronic acid (230.8 mg), bis(triphenylphosphine)palladium(II) dichloride (80.3 mg), and a 20 wt % tetraethylammonium hydroxide aqueous solution (9.83 g) are added to the reaction mixture and heated under reflux for 7 hours. After removing an aqueous layer, sodium N,N-diethyldithiocarbamate trihydrate (6.53 g) and ion-exchanged water (60 mL) are added to the reaction mixture and then, stirred at 85° C. for 2 hours. After separating the organic layer from the aqueous layer, the organic layer is washed with water, a 3 wt % aqueous acetic acid solution, and water. The organic layer is added dropwise to methanol to precipitate and separate the polymer compound, and dried to obtain a solid. This solid is dissolved in toluene, passed through column chromatography packed with silica gel/alumina, and the solvent is distilled off under reduced pressure. The obtained liquid is added dropwise to methanol, and the precipitated solid is separated and dried to obtain Polymer Compound A-11 (1.23 g).

The weight average molecular weight (Mw) and polydispersity (Mw/Mn) of the obtained Polymer Compound A-11 are measured by SEC. As a result, the weight average molecular weight (Mw) and polydispersity (Mw/Mn) of Polymer Compound A-11 are 59,900 g/mol and 2.26, respectively.

Polymer Compound A-11 obtained in this way is presumed to be a polymer compound obtained by alternately polymerizing the structural unit X and the structural unit Y according to an embodiment, having the following repeating units from the structures of the monomers.

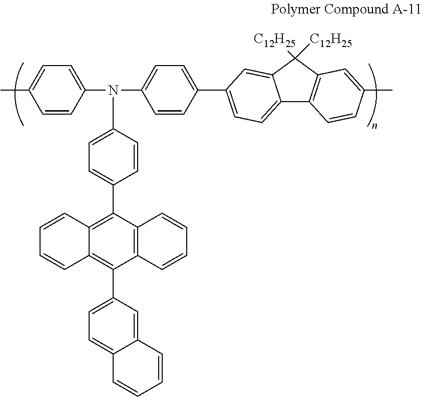

### Evaluation of Characteristics of Each Polymer Compound

For the Polymer Compounds A-1 to A-11 of Examples 1-1 to 1-11, the HOMO levels (eV) and glass transition temperatures (T_{g}) (° C.) are measured by the following methods, and the results are shown in Table 1.

### Measurement of HOMO Level

Each polymer compound is dissolved in xylene at a concentration of 1 wt %, preparing a coating solution. The coating solution is spin-coated at 2000 rpm on a glass substrate attached with ITO and cleaned with UV to form a film, which is dried on a hot plate at 150° C. for 30 minutes to provide a sample film. The sample film is measured with respect to HOMO level in the air by using a photoelectron spectroscopy device (AC-3, Riken Keiki Co., Ltd.). Herein, a rising tangential intersection calculated from the measurement is regarded as the HOMO level (eV). The HOMO level is, in general, negative.

### Glass Transition Temperature (T_{g})

A glass transition temperature (T_{g}) of each polymer compound is measured with a differential scanning calorimeter (DSC) (DSC6000, Seiko Scientific Co., Ltd.) by heating the sample to 300° C. at 10° C./min and maintaining the temperature at 300° C. for 10 minutes. The sample is then cooled to 25° C. at 10° C./min and maintaining the temperature at 25° C. for 10 minutes. The sample is then heated again to 300° C. at 10° C./min. After the measurement, the temperature is cooled to room temperature (25° C.) at 10° C./min.

TABLE 1

| | Polymer | Mw | | HOMO | Tg |
|---|---|---|---|---|---|
| | compound | (g/mol) (Mw/Mn) | | (eV) | (° C.) |
| Example 1-1 | A-1 | 138,900 | 3.34 | −5.67 | 228 |
| Example 1-2 | A-2 | 40,900 | 2.49 | −5.64 | 200 |
| Example 1-3 | A-3 | 132,900 | 3.20 | −5.72 | 227 |
| Example 1-4 | A-4 | 76,900 | 2.38 | −5.66 | 195 |
| Example 1-5 | A-5 | 90,000 | 2.50 | −5.58 | 226 |
| Example 1-6 | A-6 | 53,500 | 2.81 | −5.59 | 148 |
| Example 1-7 | A-7 | 51,800 | 2.04 | −5.59 | 182 |
| Example 1-8 | A-8 | 14,300 | 1.73 | −5.68 | 149 |
| Example 1-9 | A-9 | 38,000 | 1.97 | −5.51 | 204 |
| Example 1-10 | A-10 | 226,900 | 10.68 | −5.62 | 65 |
| Example 1-11 | A-11 | 58,900 | 2.26 | −5.67 | 162 |

### Reference Example Device

A first electrode (anode) is prepared on a glass substrate on which a stripe-shaped indium tin oxide (ITO) is formed as a film with a thickness of about 150 nm. On the glass substrate, PEDOT-PSS (Sigma-Aldrich Co., Ltd.) is spin-coated to have a dry film thickness of about 30 nm and dried, forming a hole injection layer with a film thickness of about 30 nm.

Subsequently, Polymer Compound A-7 of Example 1 (hole transport material) is dissolved in xylene as a solvent at a concentration of 1 wt %, preparing a polymer coating solution. The polymer coating solution is spin-coated to have a dry film thickness of about 30 nm on the hole injection layer and then, dried by heating at 150° C. for 30 minutes. Accordingly, a hole transport layer with a dry film thickness of about 30 nm is formed.

Blue quantum dots of ZnTeSe/ZnSe/ZnS (core/shell/shell; average diameter=about 10 nm) having the following structure are dispersed in octane at 2.0 wt % to provide a quantum dot dispersion:

[symbol]

The hole transport layer (particularly, Polymer Compound P-1) does not dissolve in octane. This quantum dot dispersion is spin-coated and dried by heating at 80° C. for 30 minutes to provide a dry film thickness of about 20 nm on the hole transport layer. Accordingly, a quantum dot light emitting layer (QD layer) with a dry film thickness of about 20 nm is formed.

Subsequently, ZnCl₂ is dissolved in ethanol as a solvent at a concentration of 0.7 mol/L, preparing a ZnCl₂ coating solution. The prepared ZnCl₂ coating solution is slowly dripped so as to cover the light emitting surface formed above, allowed to stand for 60 seconds, rotated at 1,000 rpm for 40 seconds with a spin coating method, and dried by heating at 80° C. for 20 minutes. Continuously, ethanol also is slowly dripped so as to cover the light emitting surface formed above, repeatedly twice rotated at 1,000 rpm with the spin coating method, and dried by heating at 80° C. for 20 minutes.

α-NPD (N,N′-di-1-naphthyl-N,N′-diphenyl benzidine) and HAT-CN (dipyrazino[2,3-f:2′,3′-h]quinoxaline-2,3,6,7,10,11-hexacarbonitrile) are sequentially vacuum deposited on the hole transport layer to respectively form electron blocking layers with each thickness about 36 nm and about 10 nm, manufacturing Hole Only Device 1.

### Comparative Example 1-1 Device

A hole only device is manufactured in the same manner as in the Reference Example except that poly[(9,9-dioctyl fluorenyl-2,7-diyl)-co-(4,4′-(N-(4-sec-butyl phenyl)diphenyl amine)](TFB) (Luminescence Technology Corp.) is used instead of Polymer Compound A-7. The weight average molecular weight (Mw) and polydispersity (Mw/Mn) of TFB are measured by SEC. As a result, the weight average molecular weight (Mw) and the polydispersity (Mw/Mn) of TFB are respectively 359,000 g/mol and 3.4.

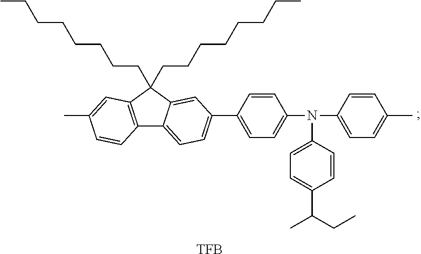 [SMILES: CCCCCCCCC1(CCCCCCCC)c2cc(C)ccc2-c2ccc(-c3ccc(N(c4ccc(C)cc4)c4ccc(C(C)CC)cc4)cc3)cc21 ; "TFB"]

### Evaluation of Hole Only Device

The hole only devices according to Reference Example Device and Comparative Example 1-1 Device are measured with respect to a current value (current density amperes per square meters (A/m²)) at 8 V by gradually increasing a voltage with a DC constant voltage power source (source meter, KEYENCE Corporation), which is provided as “current value at 8 V.” The results of the two devices are shown in Table 2.

TABLE 2

| | Polymer compound | Current value at 8 V |
|---|---|---|
| | (polymer) | (relative value) |
| Reference Example | A-7 | 1.28 |
| Comparative Example 1-1 | TFB | 1.00 |

Referring to the results of Table 2, the hole only device of Reference Example exhibits a higher current value at 8 V than the device of Comparative Example 1-1. Accordingly, Polymer Compound A-7 (which includes a alkyl substituted fluorene as Ar³) one of the polymers (polymer compounds) according to an embodiment, exhibits improved hole mobility toward the QD layer, a light emitting layer.

### Example 2-1

### Manufacture of Quantum Dot Electroluminescence Device 1

As for a first electrode (an anode), a glass substrate adhered with indium tin oxide (ITO) which is patterned to have a film thickness of 150 nm is used. This ITO-adhered glass substrate is sequentially washed with a neutral detergent, deionized water, water, and isopropyl alcohol and then, treated with UV-ozone. Subsequently, on this ITO-adhered glass substrate, poly(3,4-ethylenedioxythiophene)/poly(4-styrenesulfonate) (PEDOT/PSS) (Sigma-Aldrich Co., Ltd.) is spin-coated and dried to have a dry film thickness of 30 nm. As a result, a hole injection layer having a thickness (dry film thickness) of 30 nm is formed on the ITO-adhered glass substrate.

Thereafter, Polymer Compound A-1 (hole transport material) synthesized in Example 1-1 is dissolved in toluene (solvent) at a concentration of 1 wt % to prepare Coating Liquid 1 for forming a hole transport layer. On the hole injection layer formed above, Coating Liquid 1 for forming a hole transport layer is coated by spin coating followed by heating at 230° C. for 1 hour to form an about 30 nm-thick hole transport layer on the hole injection layer.

A quantum dot dispersion is prepared by dispersing green quantum dots of InP/ZnSe/ZnS (core/shell/shell; average diameter=about 15 nm) having the following structure in cyclohexane at 1.0 wt %.

[symbol]

The hole transport layer (particularly, Polymer Compound A-1) does not dissolve in cyclohexane. This quantum dot dispersion is coated on the hole transport layer by spin coating to a dry film thickness of about 30 nm. As a result, a quantum dot light emitting layer having a thickness (dry film thickness) of about 30 nm is formed on the hole transport layer. The light generated by irradiating the quantum dot dispersion with ultraviolet light has a central wavelength of 550 nm and a full width at half maximum of 45 nm.

The quantum dot light emitting layer is completely dried. On this quantum dot light emitting layer, lithium quinolate (Liq) and 1,3,5-tris(N-phenylbenzimidazol-2-yl)benzene (TPBI) (Sigma-Aldrich Co., Ltd.) as an electron transport material are co-deposited by using a vacuum deposition apparatus. As a result, a 36 nm-thick electron transport layer is formed on the quantum dot light emitting layer.

Using a vacuum deposition apparatus, (8-quinolato)lithium (lithium quinolate, Liq) is deposited on this electron transport layer. As a result, a 0.5 nm-thick electron injection layer is formed on the electron transport layer. On the electron injection layer formed above, aluminum (hereinafter, Al) is deposited using a vacuum deposition apparatus to form a second electrode (cathode) having a thickness of about 100 nm on the electron injection layer. In this way, Quantum Dot Electroluminescence Device 1 is obtained.

### Example 2-2. Manufacture of Quantum Dot Electroluminescence Device 2

Quantum Dot Electroluminescence Device 2 is manufactured in the same manner as in Example 2-1, except that Polymer Compound A-2 of Example 2 is used instead of Polymer Compound A-1 in Example 2-1.

### Example 2-3. Manufacture of Quantum Dot Electroluminescence Device 3

Quantum Dot Electroluminescence Device 3 is manufactured in the same manner as in Example 2-1, except that Polymer Compound A-3 of Example 3 is used instead of Polymer Compound A-1 in Example 2-1.

### Example 2-4. Manufacture of Quantum Dot Electroluminescence Device 4

Quantum Dot Electroluminescence Device 4 is manufactured in the same manner as in Example 2-1, except that Polymer Compound A-4 of Example 4 is used instead of Polymer Compound A-1 in Example 2-1.

### Example 2-5. Manufacture of Quantum Dot Electroluminescence Device 5

Quantum Dot Electroluminescence Device 5 is manufactured in the same manner as in Example 2-1, except that Polymer Compound A-5 of Example 5 is used instead of Polymer Compound A-1 in Example 2-1.

### Example 2-6. Manufacture of Quantum Dot Electroluminescence Device 6

Quantum Dot Electroluminescence Device 6 is manufactured in the same manner as in Example 2-1, except that Polymer Compound A-6 of Example 6 is used instead of Polymer Compound A-1 in Example 2-1.

### Example 2-7. Manufacture of Quantum Dot Electroluminescence Device 7

Quantum Dot Electroluminescence Device 7 is manufactured in the same manner as in Example 2-1, except that Polymer Compound A-7 of Example 7 is used instead of Polymer Compound A-1 in Example 2-1.

### Example 2-8. Manufacture of Quantum Dot Electroluminescence Device 8

Quantum Dot Electroluminescence Device 8 is manufactured in the same manner as in Example 2-1, except that Polymer Compound A-8 of Example 8 is used instead of Polymer Compound A-1 in Example 2-1.

### Example 2-9. Manufacture of Quantum Dot Electroluminescence Device 9

Quantum Dot Electroluminescence Device 9 is manufactured in the same manner as in Example 2-1, except that Polymer Compound A-9 of Example 9 is used instead of Polymer Compound A-1 in Example 2-1.

### Example 2-10. Manufacture of Quantum Dot Electroluminescence Device 10

Quantum Dot Electroluminescence Device 10 is manufactured in the same manner as in Example 2-1, except that Polymer Compound A-10 of Example 10 is used instead of Polymer Compound A-1 in Example 2-1.

### Example 2-11. Manufacture of Quantum Dot Electroluminescence Device 11

Quantum Dot Electroluminescence Device 11 is manufactured in the same manner as in Example 2-1, except that Polymer Compound A-11 of Example 11 is used instead of Polymer Compound A-1 in Example 2-1.

### Comparative Example 2-1. Comparative Quantum Dot Electroluminescence Device 1

Comparative Quantum Dot Electroluminescence Device 1 is manufactured in the same manner as in Example 2-1, except that TFB used in Comparative Example 1-1 is used instead of Polymer Compound A-1 in Example 2-1.

### Evaluation of Quantum Dot Electroluminescence Devices

For Quantum Dot Electroluminescence Devices 1 to 11 manufactured in Examples 2-1 to 2-11 and Comparative Quantum Dot Electroluminescence Device 1 manufactured in Comparative Example 2-1, luminous efficiency is determined by the following method and luminescence life-span are evaluated, and the results are shown in Table 3.

Luminous Efficiency: When a voltage is applied to each quantum dot electroluminescence device, a current begins to flow at a constant voltage, and the quantum dot electroluminescence device emits light. A DC constant voltage power source (a source meter, KEYENCE Corporation) is used to gradually increase a voltage, at which a current of each device is measured, and a luminance measuring device (SR-3, Topcom Technology Co., Ltd.) is used to measure luminance during the light emission. The measurement is completed when the luminance starts to decline. An area of each device is used to calculate a current per unit area (current density), and the luminance in candela per square meters (cd/m²) is divided by the current density (A/m²) to obtain current efficiency in candela per ampere (cd/A).

In addition, from a spectral radiation luminance spectrum measured by a luminance-measuring device, assuming that Lambertian radiation is performed, external quantum efficiency (EQE) (%) at cd/A max is calculated, which is used to evaluate luminous efficiency.

Luminescence Life-span: Using a DC constant voltage power source (source meter manufactured by KEYENCE Corporation), a predetermined voltage is applied to each quantum dot electroluminescence device to cause the quantum dot electroluminescence device to emit light. While the light emission of the quantum dot electroluminescence device is measured by using the luminance-measuring device (SR-3, Topcom Technology Co., Ltd.), a current is gradually increased and then, is made constant, when the luminance reached 5400 nit (cd/m²), and then, the device is left alone. Overtime the luminance measured by using the luminance-measuring device is gradually deteriorated and “LT50 (hr)” value is obtained, which is the time it takes for the luminance to be reduced to 50% of the initial luminance.

TABLE 3

| | Polymer compound | EQE | LT50@5400 nit |
|---|---|---|---|
| | (polymer) | [%] | [hr] |
| Example 2-1 | A-1 | 8.7 | 211 |
| Example 2-2 | A-2 | 9.5 | 208 |
| Example 2-4 | A-4 | 7.6 | 175 |
| Example 2-5 | A-5 | 8.5 | 220 |
| Example 2-6 | A-6 | 8.3 | 206 |
| Example 2-7 | A-7 | 8.9 | 289 |
| Example 2-11 | A-11 | 10.1 | 251 |
| Comparative | TFB | 8.7 | 144 |
| Example 2-1 | | | |

From the results of Table 3, Quantum Dot Electroluminescence Devices 1 to 11 of the examples exhibit significantly higher durability (significantly longer luminescence life-span) than Comparative Quantum Dot Electroluminescence Device 1. It is also understood that Quantum Dot Electroluminescence Devices 1 to 11 exhibit an acceptable luminous efficiency (EQE).

In accordance with the above, and the present example embodiments, green quantum dot electroluminescence devices are evaluated, and the same results as above may be obtained in red quantum dot electroluminescence devices and the like.

While this invention has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A polymer comprising a structural unit represented by Chemical Formula 1:
Chemical Formula 1 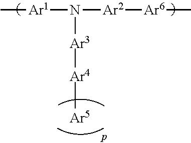
wherein, in Chemical Formula 1,
Ar¹, Ar², and Ar³ are each independently a substituted or unsubstituted, aromatic carbocyclic group having 6 to 60 ring-forming atoms,
Ar⁴ is a substituted or unsubstituted, aromatic carbocyclic group with three or more condensed benzene rings,
Ar⁵ is a substituted or unsubstituted, aromatic carbocyclic group having 6 to 60 ring-forming atoms, or a substituted or unsubstituted, aromatic heterocyclic group having 5 to 60 ring-forming atoms,
Ar⁶ is a substituted or unsubstituted, aromatic carbocyclic group having 6 to 60 ring-forming atoms, or a substituted or unsubstituted, aromatic heterocyclic group having 5 to 60 ring-forming atoms, and
p is 0 or 1.

2. The polymer of claim 1, wherein Ar¹, Ar², and Ar³ are each independently a phenylene group, an indenylene group, a naphthalenylene group, an anthracenylene group, an azulenylene group, an acenaphthenylene group, a phenalenylene group, a fluorenylene group, a phenanthrenylene group, a biphenylene group, a terphenylene group, a quaterphenylene group, a quinquephenylene group, a pyrenylene group, a spirobifluorene group, or a combination thereof.

3. The polymer of claim 1, wherein in Chemical Formula 1,
when p is 0, Ar⁴ is a substituted or unsubstituted anthracenyl group, a substituted or unsubstituted phenanthrenyl group, a substituted or unsubstituted tetracenyl group, a substituted or unsubstituted chrysenyl group, a substituted or unsubstituted pyrenylene group, a substituted or unsubstituted triphenyl group, or a substituted or unsubstituted benzo[a]anthracenyl group, and
when p is 1, Ar⁴ is a substituted or unsubstituted anthracenylene group, a substituted or unsubstituted phenanthrenylene group, a substituted or unsubstituted tetracenyl ene group, a substituted or unsubstituted chrysenylene group, a substituted or unsubstituted pyrenylene group, a substituted or unsubstituted triphenylene group, or a substituted or unsubstituted benzo[a]anthracenylene group.

4. The polymer of claim 1, wherein Ar³ is represented by Chemical Formula 2, Chemical Formula 3, or Chemical Formula 4: 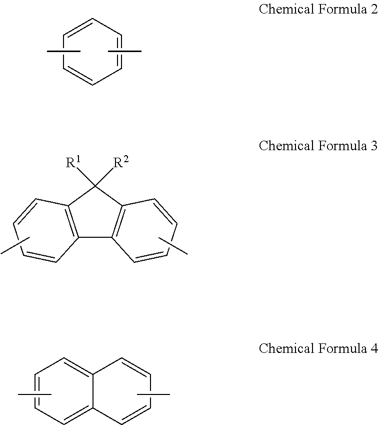
wherein, in Chemical Formula 3,
R¹ and R² are each independently a substituted or unsubstituted, aromatic carbocyclic group having 6 to 30 ring-forming atoms, a substituted or unsubstituted alkyl group having 1 to 50 carbon atoms, or R¹ and R² are joined to form a ring.

5. The polymer of claim 1, wherein in Chemical Formula 1, p is 1 and, Ar⁵ is represented by Chemical Formula 5 or Chemical Formula 6: 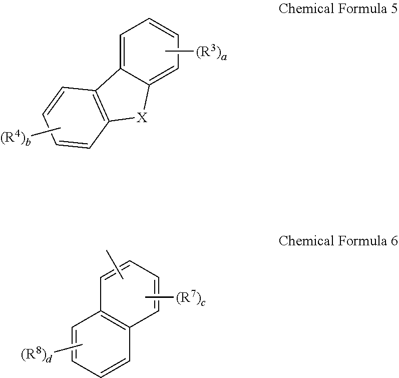
wherein, in Chemical Formula 5,
X is a group selected from —C(R⁵)(R⁶)—, —O—, and —S—,
R³ and R⁴ are each independently a substituted or unsubstituted, aromatic carbocyclic group having 6 to 30 ring-forming atoms, a substituted or unsubstituted alkyl group having 1 to 50 carbon atoms, or two adjacent R³ and two adjacent R⁴ are joined to form a ring,
R⁵ and R⁶ are each independently a substituted or unsubstituted aromatic carbocyclic group having 6 to 30 ring-forming atoms, a substituted or unsubstituted alkyl group having 1 to 50 carbon atoms, or R⁵ and R⁶ are joined to form a ring,
a is 0, 1, 2, or 3, and b is 0, 1, 2, 3, or 4, and
when a or b is 2 or more, each R³ or each R⁴, respectively, is the same or different;
in Chemical Formula 6,
R⁷ and R⁸ are each independently a substituted or unsubstituted, aromatic carbocyclic group having 6 to 30 ring-forming atoms, a substituted or unsubstituted alkyl group having 1 to 50 carbon atoms, or two adjacent R⁷ or two adjacent R⁸ are joined to form a ring, or R⁷ and R⁸ join to form a ring,
c is 0, 1, 2, or 3, and d is 0, 1, 2, 3, or 4, and
when c or d is 2 or more, each R⁷ or each R⁸ is the same or different.

6. The polymer of claim 5, wherein the group represented by Chemical Formula 5 is a group represented by Chemical Formulas (501) to (515): 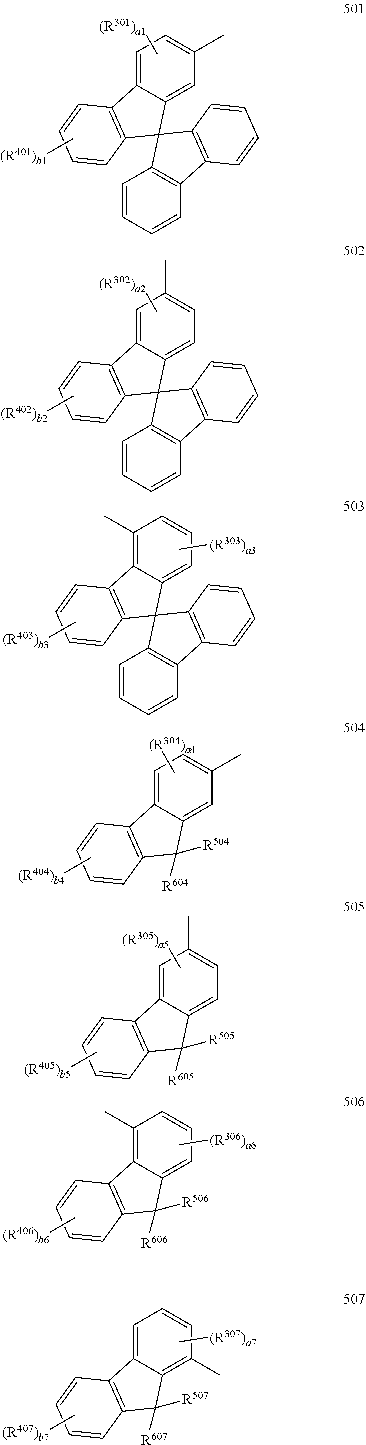 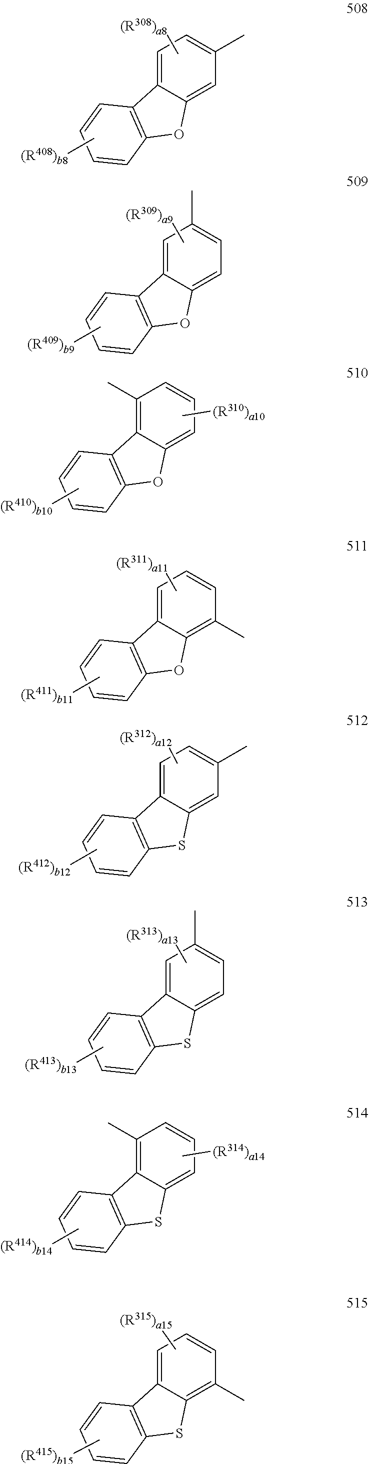
wherein, in Chemical Formulas (501) to (515),
R³⁰¹ to R³¹⁵ and R⁴⁰¹ to R⁴¹⁵ are each independently a substituted or unsubstituted, aromatic carbocyclic group having 6 to 30 ring-forming atoms, a substituted or unsubstituted alkyl group having 1 to 50 carbon atoms, or two adjacent R³⁰¹ or R⁴⁰¹, two adjacent R³⁰² or R⁴⁰², two adjacent R³⁰³ or R⁴⁰³, two adjacent R³⁰⁴ or R⁴⁰⁴, two adjacent R³⁰⁵ or R⁴⁰⁵, two adjacent R³⁰⁶ or R⁴⁰⁶, two adjacent R³⁰⁷ or R⁴⁰⁷, two adjacent R³⁰⁸ or R⁴⁰⁸, two adjacent R³⁰⁹ or R⁴⁰⁹, two adjacent R³¹⁰ or R⁴¹⁰, two adjacent R³¹¹ or R⁴¹¹, two adjacent R³¹² or R⁴¹², two adjacent R³¹³ or R⁴¹³, two adjacent R³¹⁴ or R⁴¹⁴, or two adjacent R³¹⁵ and R⁴¹⁵, are joined form a ring,
R⁵⁰⁴ to R⁵⁰⁷ and R⁶⁰⁴ to R⁶⁰⁷ are each independently a substituted or unsubstituted, aromatic carbocyclic group having 6 to 30 ring-forming atoms, a substituted or unsubstituted having an alkyl group having 1 to 50 carbon atoms, or R⁵⁰⁴ and R⁶⁰⁴, R⁵⁰⁵ and R⁶⁰⁵, R⁵⁰⁶ and R⁶⁰⁶, and R⁵⁰⁷ and R⁶⁰⁷, join to form a ring, respectively,
a1 to a15 are each independently 0, 1, 2, or 3, and b1 to b15 are each independently 0, 1, 2, 3, or 4, and
when any one of a1 to a15 or b1 to b15 is 2 or more, each R³⁰¹, each R³⁰², each R³⁰³, each R³⁰⁴, each R³⁰⁵, each R³⁰⁶, each R³⁰⁷, each R³⁰⁸, each R³⁰⁹, each R³¹⁰, each R³¹¹, each R³¹², each R³¹³, each R³¹⁴, each R³¹⁵, each R⁴⁰¹, each R⁴⁰², each R⁴⁰³, each R⁴⁰⁴, each R⁴⁰⁵, each R⁴⁰⁶, each R⁴⁰⁷, each R⁴⁰⁸, each R⁴⁰⁹, each R⁴¹⁰, each R⁴¹¹, each R⁴¹², each R⁴¹³, each R⁴¹⁴, or each R⁴¹⁵ is the same or different.

7. The polymer of claim 6, wherein Ar¹, Ar², and Ar³ are groups independently represented by Chemical Formula 2 or Chemical Formula 3, Ar⁴ is a substituted or unsubstituted anthracenylene group or a substituted or unsubstituted phenanthrenylene group, and Ar⁵ is a group represented by (504) to (507) or a group represented by (512) to (515): 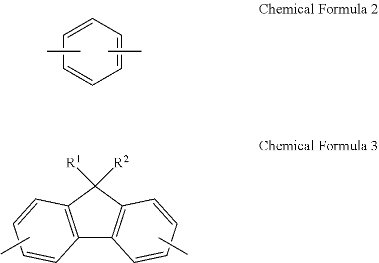
wherein, in Chemical Formula 3,
R¹ and R² are each independently substituted or unsubstituted, aromatic carbocyclic group having 6 to 30 ring-forming atoms, a substituted or unsubstituted alkyl group having 1 to 50 carbon atoms, or R¹ and R² join to form a ring.

8. The polymer of claim 6, wherein Ar¹ and Ar² are groups represented by Chemical Formula 2, Ar³ is a group represented by Chemical Formula 2 or Chemical Formula 3, Ar⁴ is a substituted or unsubstituted anthracenylene group or a substituted or unsubstituted phenanthrenylene group, and Ar⁵ is a group represented by (504) to (507) or a group represented by (512) to (515): 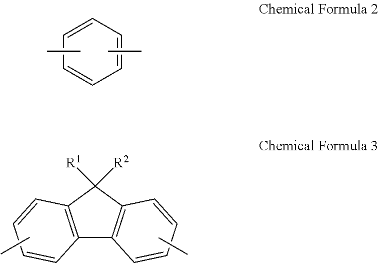
wherein, in Chemical Formula 3,
R¹ and R² are each independently substituted or unsubstituted, aromatic carbocyclic group having 6 to 30 ring-forming atoms, a substituted or unsubstituted alkyl group having 1 to 50 carbon atoms, or R¹ and R² join to form a ring.

9. The polymer of claim 8, wherein Ar⁴ is an unsubstituted anthracenylene group or an unsubstituted phenanthrenylene group, Ar⁵ is a represented by a group represented (504) to (507) or a group represented by (512) to (515), wherein in the groups represented by (504) to (507) and the groups represented by (512) to (515), each of a4 to a7, a12 to a15, b4 to b7, and b12 to b15 is zero.

10. The polymer of claim 1, wherein Ar¹, Ar², and Ar³ are groups independently represented by Chemical Formula 2 or Chemical Formula 3, and Ar⁴ is a substituted or unsubstituted anthracenyl group or a substituted or unsubstituted phenanthrenyl group, and p is 0: 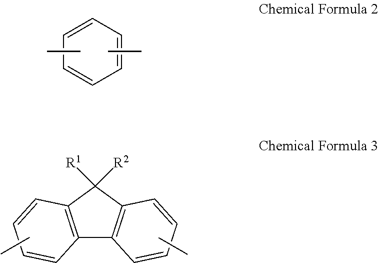
wherein, in Chemical Formula 3,
R¹ and R² are each independently a substituted or unsubstituted, aromatic carbocyclic group having 6 to 30 ring-forming atoms, a substituted or unsubstituted alkyl group having 1 to 50 carbon atoms, or R¹ and R² join to form a ring.

11. The polymer of claim 10, wherein Ar¹ and Ar² are groups represented by Chemical Formula 2, and Ar³ is a group represented by Chemical Formula 2 or Chemical Formula 3.

12. The polymer of claim 11, wherein Ar⁴ is an unsubstituted anthracenyl group or an unsubstituted phenanthrenyl group.

13. The polymer of claim 1, wherein Ar⁶ of Chemical Formula 1 is a group represented by Chemical Formulas (7) to (22): 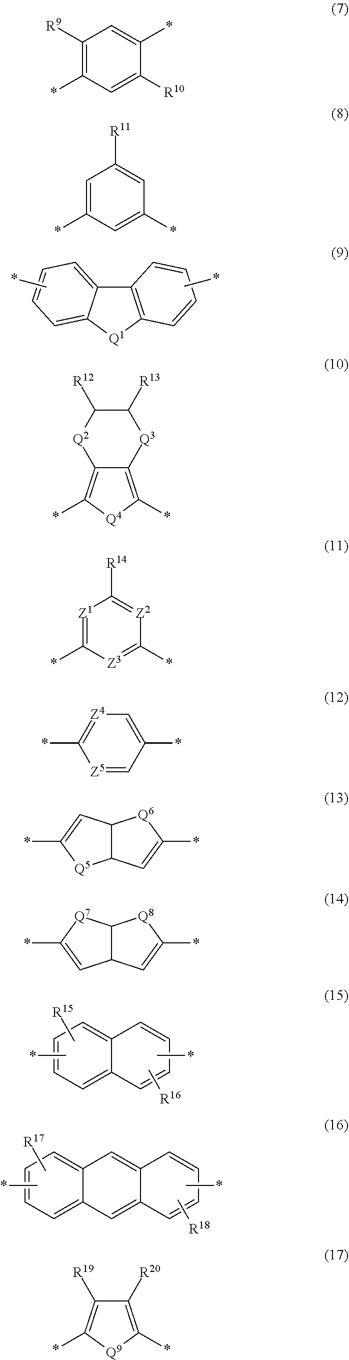 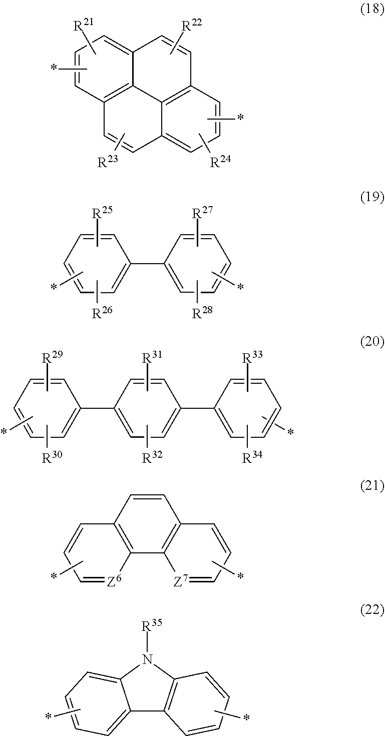
wherein, in Chemical Formulas (7) to (22),
R⁹ to R³⁵ are each independently a hydrogen atom, a substituted or unsubstituted, aromatic carbocyclic group having 6 to 60 ring carbon atoms, a substituted or unsubstituted, aromatic heterocyclic group having 5 to 60 ring-forming atoms, or an alkyl group having 1 to 60 carbon atoms,
Q¹ to Q⁹ are each independently —O—, —S—, —Se—, —CR³⁶R³⁷—, or —SiR³⁸R³⁹— wherein R³⁶ to R³⁹ are each independently a hydrogen atom, a deuterium atom, a substituted or unsubstituted alkyl group, a substituted or unsubstituted aryl group, or a substituted or unsubstituted heteroaryl group,
Z¹ to Z⁷ are each independently —CR⁴⁰═, —N═, or —SiR⁴¹═, wherein R⁴⁰ and R⁴¹ are each independently a hydrogen atom, a deuterium atom, a substituted or unsubstituted alkyl group, a substituted or unsubstituted aryl group, or a substituted or unsubstituted heteroaryl group, and
* is a binding site in a main chain of the polymer.

14. The polymer of claim 1, wherein the structural unit A represented by Chemical Formula 1 is represented by Chemical Formulas (A-1) to (A-11):

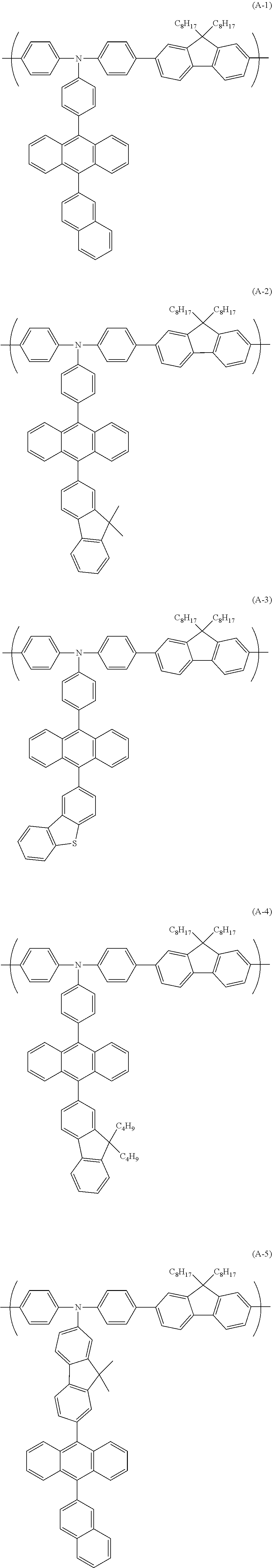

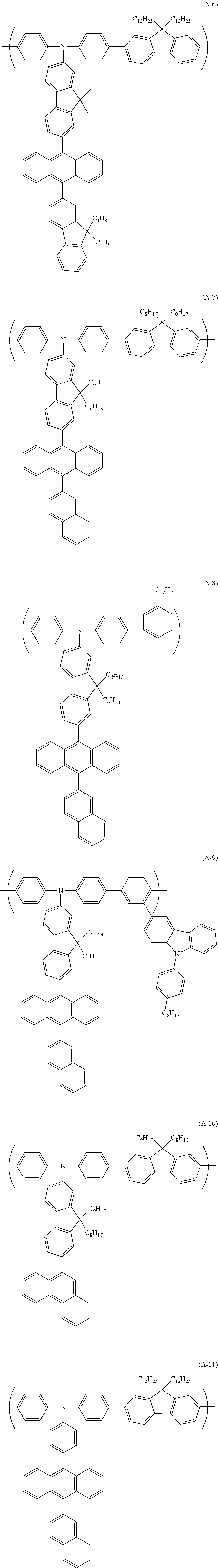

15. An electroluminescence device material comprising the polymer compound of claim 1.

16. An electroluminescence device, comprising
a first electrode, a second electrode, and at least one organic film disposed between the first electrode and the second electrode,
wherein the at least one organic film comprises the polymer of claim 1.

17. The electroluminescence device of claim 16, wherein the at least one organic film comprising the polymer is a hole transport layer or a hole injection layer.

18. The electroluminescence device of claim 16, wherein the at least one organic film further comprises a light emitting layer comprising semiconductor nanoparticles or an organometallic complex.

19. The electroluminescence device of claim 18, wherein the light emitting layer comprises semiconductor nanoparticles.

20. An electronic device comprising the electroluminescence device of claim 16.
